(19) United States
(12) Patent Application Publication
(10) Pub. No.: US 2026/0239807 A1
(43) Pub. Date: Aug. 13, 2026

(54) ORGANIC LIGHT EMITTING DEVICE

(71) Applicant: LG CHEM, LTD., Seoul (KR)

(72) Inventors: Minjun Kim, Daejeon (KR); Sung Kil Hong, Daejeon (KR); Sang Duk Suh, Daejeon (KR); Young Seok Kim, Daejeon (KR); Jongsoo Song, Daejeon (KR)

(21) Appl. No.: 19/148,270

(22) PCT Filed: Jun. 10, 2024
(86) PCT No.: PCT/KR2024/007841

§ 371 Date: Jul. 15, 2025

(30) Foreign Application Priority Data
Jun. 8, 2023 (KR) 10-2023-0073841
Jun. 7, 2024 (KR) 10-2024-0074510

(51) Int. Cl. H10K 50/11; H10K 85/30; H10K 85/40; H10K 85/60

(52) U.S. Cl. CPC H10K 50/11; H10K 85/342; H10K 85/40; H10K 85/622; H10K 85/626; H10K 85/633; H10K 85/636; H10K 85/654; H10K 85/6572; H10K 85/6574; H10K 85/6576

(57) ABSTRACT

An organic light emitting device having improved driving voltage, efficiency, and lifetime. The device includes an anode; a cathode; and a light emitting layer between the anode and the cathode, wherein the light emitting layer includes a compound of Chemical Formula 1 and a compound of Chemical Formula 2:

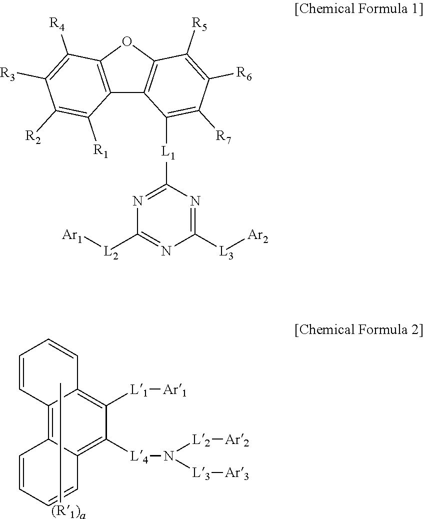

where Ar₁ and Ar₂ and Ar′₂ and Ar′₃ are each independently a substituted or unsubstituted C₆₋₆₀ aryl; or a substituted or unsubstituted C₂₋₆₀ heteroaryl containing at least one selected from the group consisting of N, O and S; Ar′₁ is hydrogen, deuterium, a substituted or unsubstituted C₆₋₆₀ aryl, or a substituted or unsubstituted C₂₋₆₀ heteroaryl containing at least one selected from the group consisting of N, O and S; and the other substituents are as defined in the specification, wherein the compound of Chemical Formula 2 has a deuterium substitution rate of 50% or more.

### CROSS-REFERENCE TO RELATED APPLICATION(S)

This application is a National Stage Application of International Application No. PCT/KR2024/007841 filed on Jun. 10, 2024, which claims priority to and the benefit of Korean Patent Application No. 10-2023-0073841 filed on Jun. 8, 2023, and Korean Patent Application No. 10-2024-0074510 filed on Jun. 7, 2024 in the Korean Intellectual Property Office, the disclosures of which are incorporated herein by reference in their entirety.

### TECHNICAL FIELD

The present disclosure relates to an organic light emitting device having improved driving voltage, efficiency and lifetime.

### BACKGROUND ART

In general, an organic light emitting phenomenon refers to a phenomenon where electric energy is converted into light energy by using an organic material. The organic light emitting device using the organic light emitting phenomenon has characteristics such as a wide viewing angle, an excellent contrast, a fast response time, an excellent luminance, driving voltage and response speed, and thus many studies have proceeded.

The organic light emitting device generally has a structure which comprises an anode, a cathode, and an organic material layer interposed between the anode and the cathode. The organic material layer frequently has a multilayered structure that comprises different materials in order to enhance efficiency and stability of the organic light emitting device, and for example, the organic material layer may be formed of a hole injection layer, a hole transport layer, a light emitting layer, an electron transport layer, an electron injection layer and the like. In the structure of the organic light emitting device, if a voltage is applied between two electrodes, the holes are injected from an anode into the organic material layer and the electrons are injected from the cathode into the organic material layer, and when the injected holes and electrons meet each other, an exciton is formed, and light is emitted when the exciton falls to a ground state again.

In the organic light emitting device as described above, there is a continued need to develop an organic light emitting device having improved driving voltage, efficiency and lifetime.

### PRIOR ART LITERATURE

### Patent Literature

(Patent Literature 1) Korean Unexamined Patent Publication No. 10-2000-0051826

### DETAILED DESCRIPTION OF THE INVENTION

### Technical Problem

It is an object of the present disclosure to provide an organic light emitting device having improved driving voltage, efficiency and lifetime.

### Technical Solution

According to the present disclosure, there is provided the following organic light emitting device:

An organic light emitting device comprising: an anode, a cathode, and a light emitting layer interposed between the anode and the cathode,
wherein the light emitting layer includes a compound represented by the following Chemical Formula 1, and a compound represented by the following Chemical Formula 2,

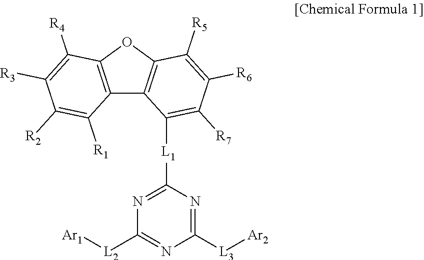

in Chemical Formula 1,
Ar₁ and Ar₂ are each independently a substituted or unsubstituted C₆₋₆₀ aryl; or a substituted or unsubstituted C₂₋₆₀ heteroaryl containing at least one selected from the group consisting of N, O and S,
L₁ is a single bond; or a substituted or unsubstituted C₆₋₆₀ arylene,
L₂ and L₃ are each independently a single bond; a substituted or unsubstituted C₆₋₆₀ arylene; or a substituted or unsubstituted C₂₋₆₀ heteroarylene containing at least one selected from the group consisting of N, O and S, and
R₁ to R₇ are each independently hydrogen or deuterium,

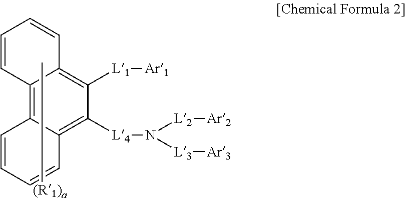

in Chemical Formula 2,
Ar′₁ is hydrogen; deuterium; a substituted or unsubstituted C₆₋₆₀ aryl; or a substituted or unsubstituted C₂₋₆₀ heteroaryl containing at least one selected from the group consisting of N, O and S,
Ar′₂ and Ar′₃ are each independently a substituted or unsubstituted C₆₋₆₀ aryl; or a substituted or unsubstituted C₂₋₆₀ heteroaryl containing at least one selected from the group consisting of N, O and S,
L′₁ to L′₃ are each independently a single bond; a substituted or unsubstituted C₆₋₆₀ arylene; or a substituted or unsubstituted C₂₋₆₀ heteroarylene containing at least one selected from the group consisting of N, O and S,
L′₄ is a single bond or a substituted or unsubstituted C₆₋₆₀ arylene,
R′₁ is hydrogen or deuterium,
a is an integer of 1 to 8, and
at least one of -L′₁-Ar′₁ and R′₁ is deuterium,
wherein the compound represented by Chemical Formula 2 has a deuterium substitution rate of 50% or more.

### Advantageous Effects

The organic light emitting device described above includes the compound represented by Chemical Formula 1 and the compound represented by Chemical Formula 2 in a light emitting layer, and thus can improve the efficiency, achieve low driving voltage and/or improve lifetime characteristics in the organic light emitting device.

### BRIEF DESCRIPTION OF THE DRAWINGS

FIG. 1 shows an example of an organic light emitting device comprising a substrate 1, an anode 2, a light emitting layer 3, and a cathode 4.

FIG. 2 shows an example of an organic light emitting device comprising a substrate 1, an anode 2, a hole injection layer 5, a hole transport layer 6, an electron blocking layer 7, a light emitting layer 3, a hole blocking layer 8, an electron injection and transport layer 9, and a cathode 4.

### DETAILED DESCRIPTION OF THE EMBODIMENTS

Hereinafter, embodiments of the present disclosure will be described in more detail to help understanding of the invention.

In the present disclosure, the notation [symbol] or [symbol] means a bond linked to another substituent group.

In the present disclosure, the term “substituted or unsubstituted” means being unsubstituted or substituted with one or more substituents selected from the group consisting of deuterium; a halogen group; a nitrile group, a nitro group; a hydroxy group; a carbonyl group; an ester group; an imide group; an amino group; a phosphine oxide group; an alkoxy group; an aryloxy group; an alkylthioxy group; an arylthioxy group; an alkylsulfoxy group; an arylsulfoxy group; a silyl group; a boron group; an alkyl group; a cycloalkyl group; an alkenyl group; an aryl group; an aralkyl group; an aralkenyl group; an alkylaryl group; an alkylamine group; an aralkylamine group; a heteroarylamine group; an arylamine group; an arylphosphine group; and a heterocyclic group containing at least one of N, O and S atoms, or being unsubstituted or substituted with a substituent group to which two or more substituent groups of the above-exemplified substituent groups are linked. For example, “a substituent in which two or more substituents are linked” may be a biphenyl group. Namely, a biphenyl group may be an aryl group, or it may be interpreted as a substituent formed by linking two phenyl groups

In the present disclosure, the carbon number of a carbonyl group is not particularly limited, but is preferably 1 to 40. Specifically, the carbonyl group may be a compound having the following structural formulas, but is not limited thereto.

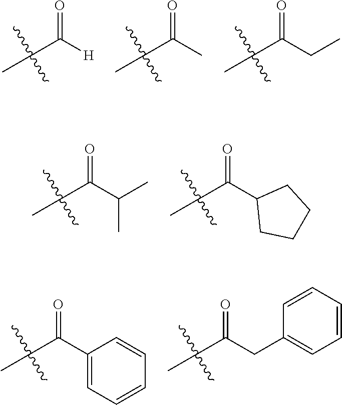

In the present disclosure, an ester group may have a structure in which oxygen of the ester group may be substituted by a straight-chain, branched-chain, or cyclic alkyl group having 1 to 25 carbon atoms, or an aryl group having 6 to 25 carbon atoms. Specifically, the ester group may be a compound having the following structural formulas, but is not limited thereto.

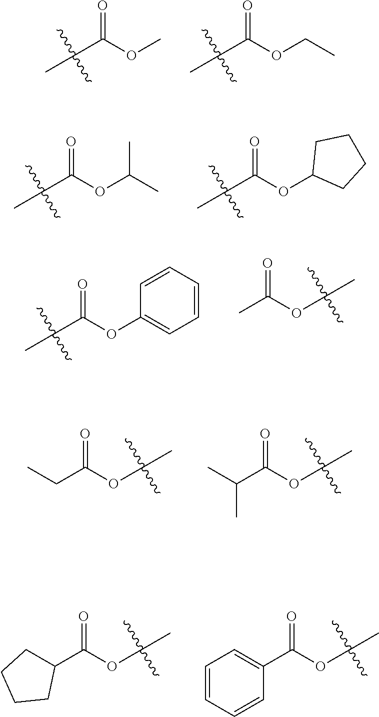

In the present disclosure, the carbon number of an imide group is not particularly limited, but is preferably 1 to 25. Specifically, the imide group may be a compound having the following structural formulas, but is not limited thereto.

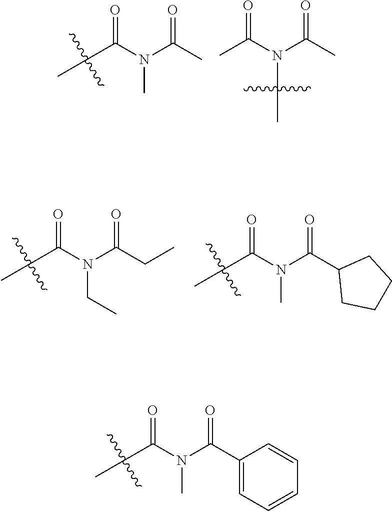

In the present disclosure, a silyl group specifically include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group and the like, but are not limited thereto.

In the present disclosure, a boron group specifically includes a trimethylboron group, a triethylboron group, a t-butyldimethylboron group, a triphenylboron group, and a phenylboron group, but is not limited thereto.

In the present disclosure, examples of a halogen group include fluoro, chloro, bromo, or iodo.

In the present disclosure, the alkyl group may be straight-chain or branched-chain, and the carbon number thereof is not particularly limited, but is preferably 1 to 40. According to one embodiment, the carbon number of the alkyl group is 1 to 20. According to another embodiment, the carbon number of the alkyl group is 1 to 10. According to another embodiment, the carbon number of the alkyl group is 1 to 6. Specific examples of the alkyl group include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, 5-methylhexyl, and the like, but are not limited thereto.

In the present disclosure, the alkenyl group may be straight-chain or branched-chain, and the carbon number thereof is not particularly limited, but is preferably 2 to 40. According to one embodiment, the carbon number of the alkenyl group is 2 to 20. According to another embodiment, the carbon number of the alkenyl group is 2 to 10. According to still another embodiment, the carbon number of the alkenyl group is 2 to 6. Specific examples thereof include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group, and the like, but are not limited thereto.

In the present disclosure, a cycloalkyl group is not particularly limited, but the carbon number thereof is preferably 3 to 60. According to one embodiment, the carbon number of the cycloalkyl group is 3 to 30. According to another embodiment, the carbon number of the cycloalkyl group is 3 to 20. According to still another embodiment, the carbon number of the cycloalkyl group is 3 to 6. Specific examples thereof include cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, cyclooctyl, and the like, but are not limited thereto.

In the present disclosure, an aryl group is not particularly limited, but the carbon number thereof is preferably 6 to 60, and it may be a monocyclic aryl group or a polycyclic aryl group. According to one embodiment, the carbon number of the aryl group is 6 to 30. According to one embodiment, the carbon number of the aryl group is 6 to 20. The aryl group may be a phenyl group, a biphenyl group, a terphenyl group or the like as the monocyclic aryl group, but is not limited thereto. The polycyclic aryl group includes a naphthyl group, an anthracenyl group, a phenanthrenyl group, a pyrenyl group, a perylenyl group, a chrysenyl group, a fluorenyl group, or the like, but is not limited thereto.

In the present disclosure, the fluorenyl group may be substituted, and two substituent groups may be linked with each other to form a spiro structure. In the case where the fluorenyl group is substituted,

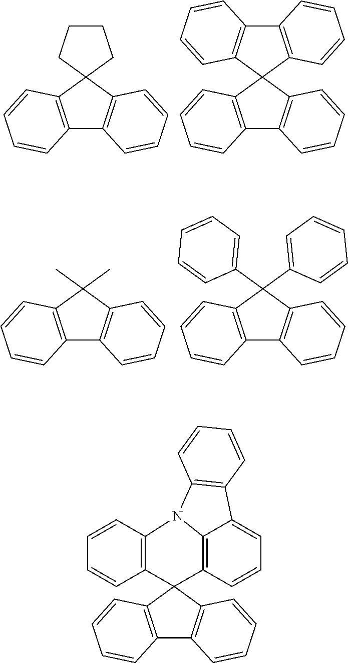

and the like can be formed. However, the structure is not limited thereto.

In the present disclosure, a heterocyclic group is a heterocyclic group containing one or more of O, N, Si and S as a heteroatom, and the carbon number thereof is not particularly limited, but is preferably 2 to 60. Examples of the heterocyclic group include a thiophene group, a furan group, a pyrrole group, an imidazole group, a thiazole group, an oxazol group, an oxadiazol group, a triazol group, a pyridyl group, a bipyridyl group, a pyrimidyl group, a triazine group, an acridyl group, a pyridazine group, a pyrazinyl group, a quinolinyl group, a quinazoline group, a quinoxalinyl group, a phthalazinyl group, a pyridopyrimidinyl group, a pyridopyrazinyl group, a pyrazinopyrazinyl group, an isoquinoline group, an indole group, a carbazole group, a benzoxazole group, a benzoimidazole group, a benzothiazol group, a benzocarbazole group, a benzothiophene group, a dibenzothiophene group, a benzofuranyl group, a phenanthroline group, an isoxazolyl group, a thiadiazolyl group, a phenothiazinyl group, a dibenzofuranyl group, and the like, but are not limited thereto.

In the present disclosure, the aryl group in the aralkyl group, the aralkenyl group, the alkylaryl group and the arylamine group is the same as the examples of the aryl group as defined above. In the present disclosure, the alkyl group in the aralkyl group, the alkylaryl group and the alkylamine group is the same as the examples of the alkyl group as defined above. In the present disclosure, the heteroaryl in the heteroarylamine can be applied to the description of the heterocyclic group as defined above. In the present disclosure, the alkenyl group in the aralkenyl group is the same as the examples of the alkenyl group as defined above. In the present disclosure, the description of the aryl group as defined above may be applied except that the arylene is a divalent group. In the present disclosure, the description of the heterocyclic group as defined above can be applied except that the heteroarylene is a divalent group. In the present disclosure, the description of the aryl group or heterocycloalkyl group as defined above can be applied except that the hydrocarbon ring is not a monovalent group but formed by combining two substituent groups. In the present disclosure, the description of the heterocyclic group as defined above can be applied, except that the heterocycle is not a monovalent group but formed by combining two substituent groups.

In the present disclosure, the term “deuterated or substituted with deuterium” means that at least one of the substitutable hydrogens in a compound, a divalent linking group, or a monovalent substituent has been substituted with deuterium.

Further, the term “unsubstituted or substituted with deuterium” or “substituted or unsubstituted with deuterium” means that “mono to the maximum number of unsubstituted or substitutable hydrogens have been substituted with deuterium.” In one example, the term “phenanthryl unsubstituted or substituted with deuterium” may be understood as meaning “phenanthryl unsubstituted or substituted with 1 to 9 deuterium atoms”, considering that the maximum number of hydrogens that can be substituted with deuterium in the phenanthryl structure is 9.

Further, the term “deuterated structure” is meant to encompass a compound, a divalent linking group or a monovalent substituent of all structures in which at least one hydrogen is replaced with deuterium. In one example, a deuterated structure of phenyl may be understood to refer to monovalent substituents of all structures in which at least one substitutable hydrogen in a phenyl group is replaced with a deuterium as follows.

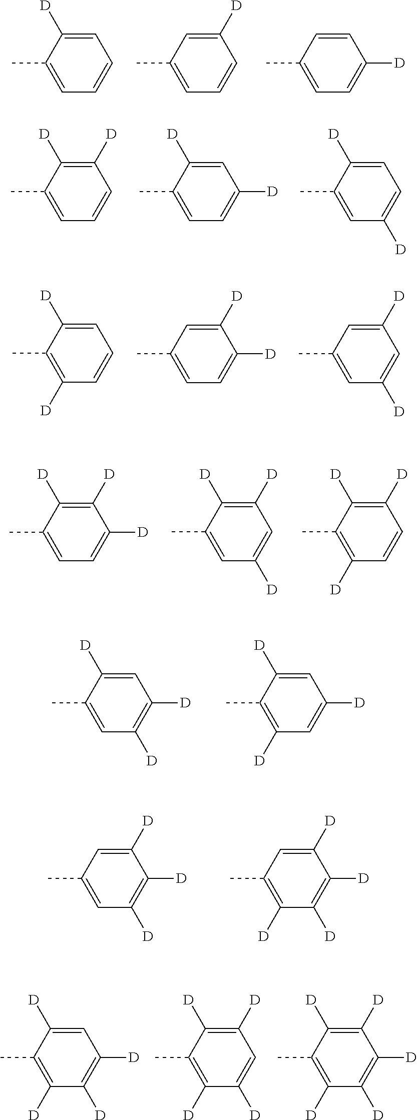

In the present disclosure, the deuterium substitution rate of a compound means that the ratio of the number of Compound substituted deuterium atoms to the total number of hydrogen atoms (the sum of the number of hydrogen atoms substitutable with deuterium and the number of Compound substituted deuterium atoms in a compound) that can be present in the compound is calculated as a percentage. Therefore, when the deuterium substitution rate of a compound is “K %”, it means that K % of the hydrogen atoms substitutable with deuterium in the compound are substituted with deuterium.

At this time, the “deuterium substitution rate” or “degree of deuteration” can be measured according to a commonly known method using MALDI-TOF MS (Matrix-Assisted Laser Desorption/Ionization Time-of-Flight Mass Spectrometer), a nuclear magnetic resonance spectroscopy (¹H NMR), TLC/MS (Thin-Layer Chromatography/Mass Spectrometry), GO/MS (Gas Chromatography/Mass Spectrometry), or the like.

More specifically, when using MALDI-TOF MS, the “deuterium substitution rate” or “degree of deuteration” may be obtained by determining the number of Compound substituted deuterium atoms in the compound through MALDI-TOF MS analysis, and then calculating the ratio of the number of Compound substituted deuterium atoms to the total number of hydrogen atoms that can be present in the compound as a percentage. Therefore, when the deuterium substitution rate of a compound is “K %”, it means that K % of the hydrogen atoms substitutable with deuterium in the compound are substituted with deuterium.

In addition, when analyzed using TLC/MS, the “deuterium substitution rate” or “degree of deuteration” may be obtained by calculating the substitution rate based on the maximum value (max. value) of distribution that molecular weights form at the end of the reaction.

Further, when analyzed using nuclear magnetic resonance (¹H NMR), the “deuterium substitution rate” or “degree of deuteration” may be calculated from the integrated quantity of total peaks through the integration ratio in ¹H NMR.

Meanwhile, in the present disclosure, “deuterium does not exist at a specific position” means that the deuterium substitution rate at that position is 10% or less, and does not mean that the deuterium substitution rate is 0%. In addition, in the present disclosure, “deuterium exists at a specific position” means that the deuterium substitution rate at that position is greater than 1%, and does not mean that the deuterium substitution rate at that position is 100%. In this way, the “deuterium substitution rate at a specific position” may be calculated by comparing the ¹H NMR spectrum of a compound not substituted with deuterium with the ¹H NMR spectrum of a compound substituted with deuterium, and confirming the rate at which the integrated quantity of the peak for each hydrogen (proton) position decreases.

Hereinafter, the present disclosure will be described in detail for each configuration.

### Anode and Cathode

The anode and cathode used in the present disclosure refer to electrodes used in an organic light emitting device.

As the anode material, generally, a material having a large work function is preferably used so that holes can be smoothly injected into the organic material layer. Specific examples of the anode material include metals such as vanadium, chrome, copper, zinc, and gold, or an alloy thereof; metal oxides such as zinc oxides, indium oxides, indium tin oxides (ITO), and indium zinc oxides (IZO); a combination of metals and oxides, such as ZnO:Al or SnO₂:Sb; conductive polymers such as poly(3-methylthiophene), poly[3,4-(ethylene-1,2-dioxy)thiophene](PEDOT), polypyrrole, and polyaniline, and the like, but are not limited thereto.

As the cathode material, generally, a material having a small work function is preferably used so that electrons can be easily injected into the organic material layer. Specific examples of the cathode material include metals such as magnesium, calcium, sodium, potassium, titanium, indium, yttrium, lithium, gadolinium, aluminum, silver, tin, and lead, or an alloy thereof; a multilayered structure material such as LiF/Al or LiO₂/Al, and the like, but are not limited thereto.

### Hole Injection Layer

The organic light emitting device according to the present disclosure may further include a hole injection layer on the anode, if necessary.

The hole injection layer is a layer that injects holes from the electrode, and a hole injection material is preferably a compound which has a capability of transporting the holes, a hole injection effect in the anode and an excellent hole injection effect to the light emitting layer or the light emitting material, prevents movement of an exciton generated in the light emitting layer to the electron injection layer or the electron injection material, and has an excellent thin film forming ability. Further, it is suitable that a HOMO (highest occupied molecular orbital) of the hole injection material is between the work function of the anode material and a HOMO of a peripheral organic material layer.

Specific examples of the hole injection material include metal porphyrine, oligothiophene, an arylamine-based organic material, a hexanitrilehexaazatriphenylene-based organic material, a quinacridone-based organic material, a perylene-based organic material, anthraquinone, polyaniline and polythiophene-based conductive polymer, and the like, but are not limited thereto.

### Hole Transport Layer

The organic light emitting device according to the present disclosure may include a hole transport layer on the anode (or on the hole injection layer if the hole injection layer exists), if necessary.

The hole transport layer is a layer that receives holes from an anode or a hole injection layer and transports the holes to the light emitting layer. The hole transport material is suitably a material having large mobility to the holes, which can receive holes from the anode or the hole injection layer and transfer the holes to the light emitting layer.

Specific examples of the hole transport material include an arylamine-based organic material, a conductive polymer, a block copolymer in which a conjugate portion and a non-conjugate portion are present together, and the like, but are not limited thereto.

### Electron Blocking Layer

The electron blocking layer means a layer provided between the hole transport layer and the light emitting layer in order to prevent the electrons injected in the cathode from being transferred to the hole transport layer without being recombined in the light emitting layer, which may also be referred to as an electron stopping layer or an electron inhibition layer. The electron blocking layer is preferably a material having the smaller electron affinity than the electron transport layer.

### Light Emitting Layer

The light emitting layer used in the present disclosure is a layer that can emit light in the visible light region by combining holes and electrons transported from the anode and the cathode. Generally, the light emitting layer includes a host material and a dopant material, and in the present disclosure, the compound represented by Chemical Formula 1 and the compound represented by Chemical Formula 2 are included as a host.

Preferably, Ar₁ and Ar₂ may be each independently a substituted or unsubstituted C₆₋₂₀ aryl; or a substituted or unsubstituted C₂₋₂₀ heteroaryl containing at least one selected from the group consisting of N, O and S, and

more preferably, Ar₁ and Ar₂ may be each independently phenyl, biphenylyl, terphenylyl, triphenylsilyl phenyl, naphthyl, phenanthrenyl, dibenzofuranyl, or dibenzothiophenyl, wherein the phenyl, biphenylyl, terphenylyl, triphenylsilyl phenyl, naphthyl, phenanthrenyl, dibenzofuranyl, and dibenzothiophenyl may be each independently unsubstituted or substituted with at least one deuterium.

More preferably, Ar₁ and Ar₂ may be each independently any one selected from the group consisting of the following compounds, wherein the Ar₁ and Ar₂ may be each independently unsubstituted or substituted with at least one deuterium:

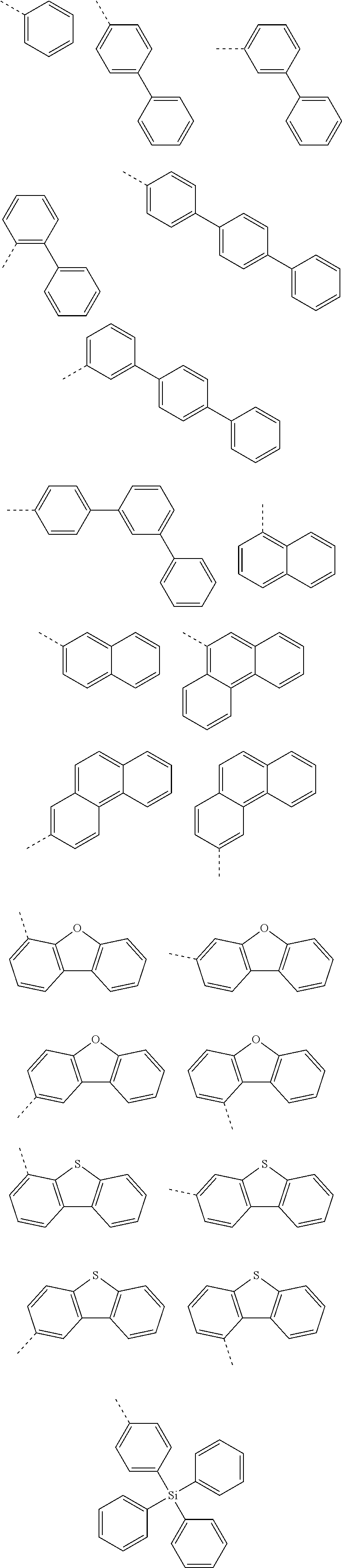

Preferably, L₁ may be a single bond; or a substituted or unsubstituted C₆₋₂₀ arylene,
more preferably, L₁ may be a single bond, a substituted or unsubstituted phenylene, or a substituted or unsubstituted naphthalenediyl, and
most preferably, L₁ may be a single bond, phenylene, or naphthalenediyl, wherein the phenylene and naphthalenediyl may be each independently unsubstituted or substituted with at least one deuterium.

Preferably, L₂ and L₃ may be each independently a single bond; or a substituted or unsubstituted C₆₋₂₀ arylene; or a substituted or unsubstituted C₂₋₂₀ heteroarylene containing at least one selected from the group consisting of N, O and S,
more preferably, L₂ and L₃ may be each independently a single bond, a substituted or unsubstituted phenylene, a substituted or unsubstituted biphenyldiyl, or a substituted or unsubstituted naphthalenediyl, and
more preferably, L₂ and L₃ may be each independently a single bond, phenylene, biphenyldiyl, or naphthalenediyl, wherein the phenylene, biphenyldiyl, and naphthalenediyl may be each independently unsubstituted or substituted with at least one deuterium.

More preferably, L₂ and L₃ may be each independently a single bond, or any one selected from the group consisting of the following compounds, wherein the L₂ and L₃ may be each independently unsubstituted or substituted with at least one deuterium:

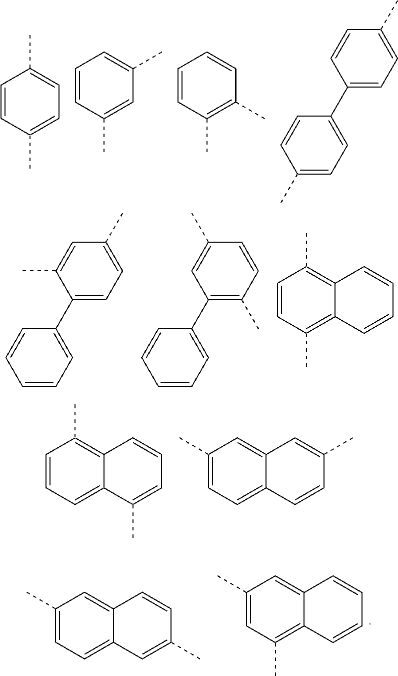

Preferably, at least one of Ar₁ and Ar₂ may be naphthyl, phenyl naphthyl, naphthyl phenyl, phenanthrenyl, fluoranthenyl, dibenzofuranyl, dibenzothiophenyl, benzonaphthofuranyl, or benzonaphthothiophenyl, wherein the naphthyl, phenyl naphthyl, naphthyl phenyl, phenanthrenyl, fluoranthenyl, dibenzofuranyl, dibenzothiophenyl, benzonaphthofuranyl, or benzonaphthothiophenyl may be unsubstituted or substituted with at least one deuterium.

More preferably, at least one of Ar₁ and Ar₂ may be naphthyl, phenyl naphthyl, naphthyl phenyl, fluoranthenyl, dibenzofuranyl, benzonaphthofuranyl, or benzonaphthothiophenyl, wherein the naphthyl, phenyl naphthyl, naphthyl phenyl, fluoranthenyl, dibenzofuranyl, benzonaphthofuranyl, or benzonaphthothiophenyl may be each independently unsubstituted or substituted with at least one deuterium.

Meanwhile, when the number of deuterium substitutions in the compound is to be represented, it may be represented by the following Chemical Formula 1D:

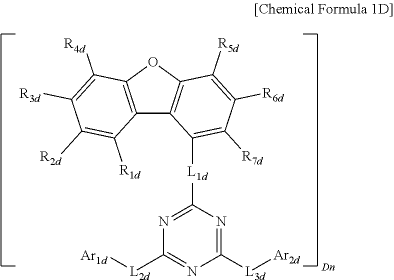

in Chemical Formula 1D,
Dn means that n hydrogens have been replaced by deuterium,
wherein n is an integer of 13 or more, and
Ar_{1d}, Ar_{2d}, L_{1d} to L_{3d} and R_{1d} to R_{7d} mean substituents Ar₁, Ar₂, L₁ to L₃ and R₁ to R₇ which are not substituted with deuterium, respectively.

In one example, in Chemical Formula 1D, n of the Dn may be 13 or more, 14 or more, 15 or more, 16 or more, 17 or more, 18 or more, or 19 or more, and 50 or less, 45 or less, 40 or less, 38 or less, 36 or less, 34 or less, 32 or less, 30 or less, 28 or less, 26 or less, 24 or less, 23 or less, 22 or less, 21 or less, or 20 or less.

Representative examples of the compound represented by Chemical Formula 1 are as follows:

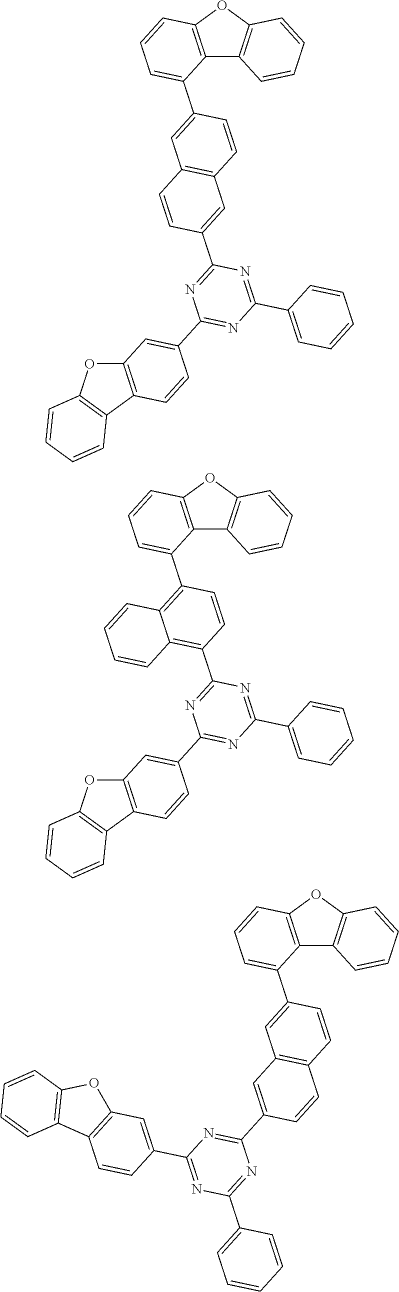 [SMILES: c1ccc(-c2nc(-c3ccc4cc(-c5cccc6oc7ccccc7c56)ccc4c3)nc(-c3ccc4c(c3)oc3ccccc34)n2)cc1 ; c1ccc(-c2nc(-c3ccc4c(c3)oc3ccccc34)nc(-c3ccc(-c4cccc5oc6ccccc6c45)c4ccccc34)n2)cc1 ; c1ccc(-c2nc(-c3ccc4ccc(-c5cccc6oc7ccccc7c56)cc4c3)nc(-c3ccc4c(c3)oc3ccccc34)n2)cc1]

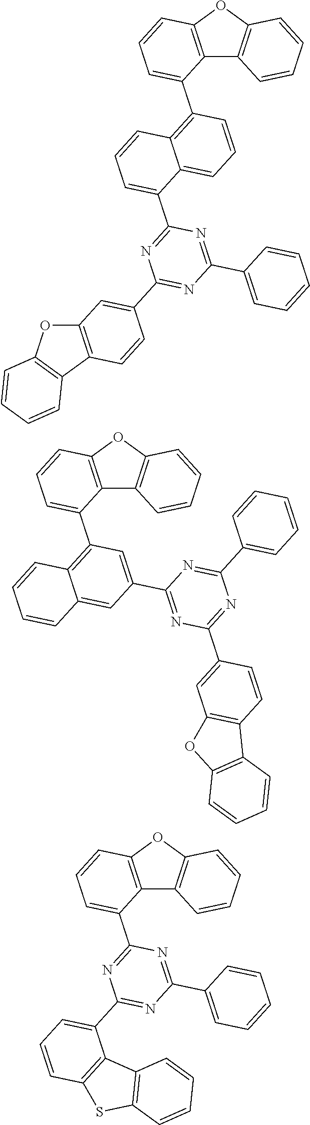

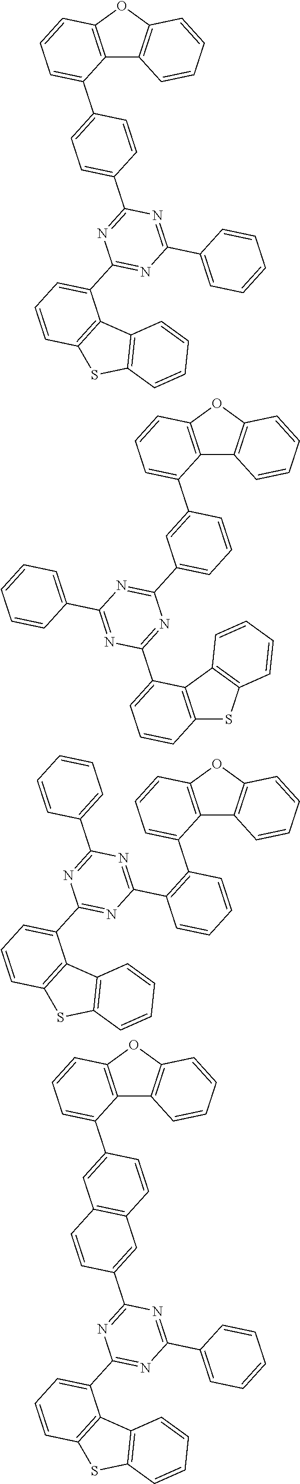

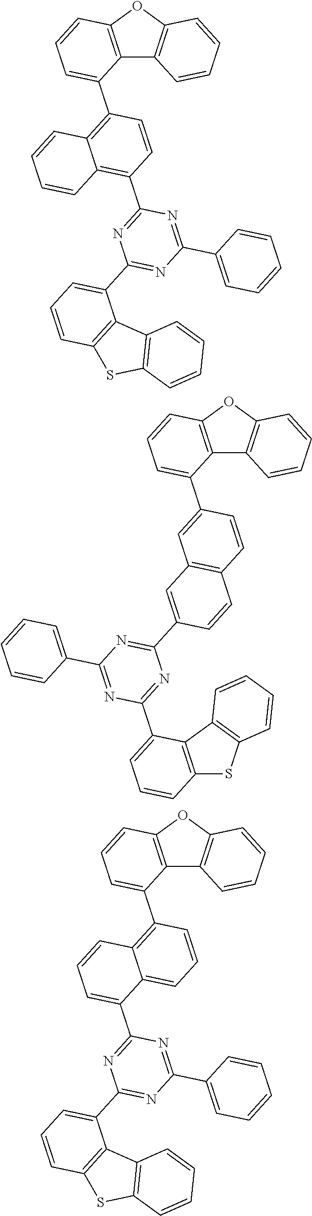

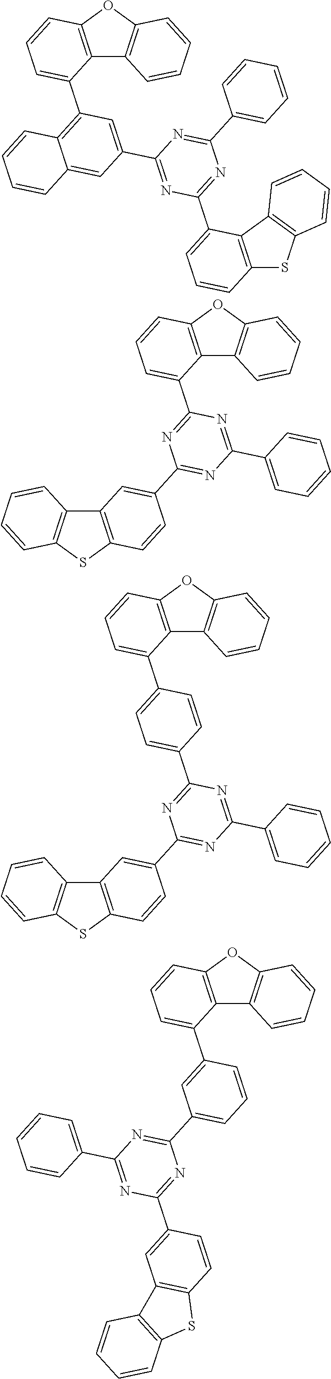

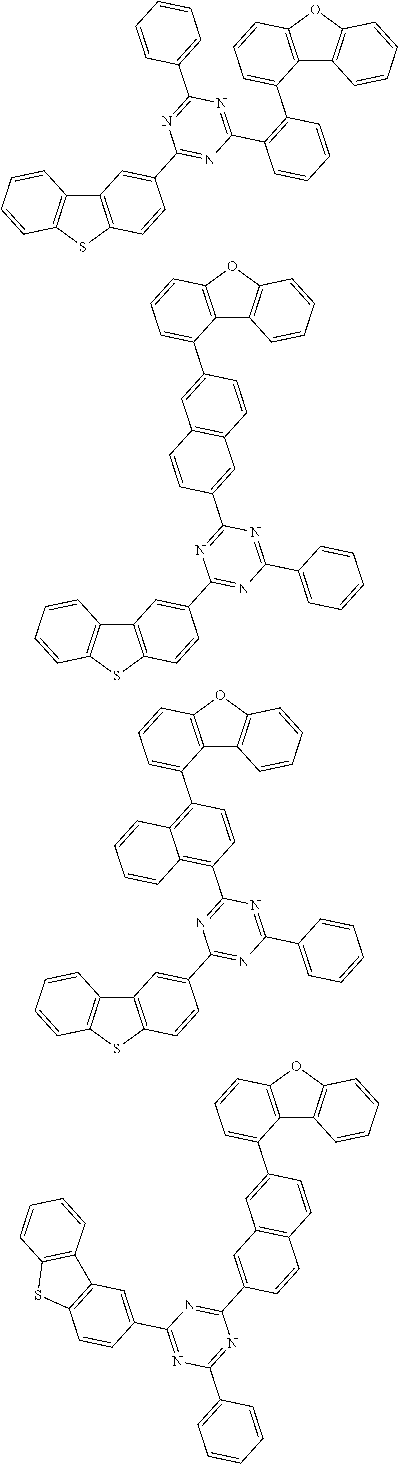 [SMILES: c1ccc(-c2nc(-c3ccc4sc5ccccc5c4c3)nc(-c3ccccc3-c3cccc4oc5ccccc5c34)n2)cc1 ; c1ccc(-c2nc(-c3ccc4cc(-c5cccc6oc7ccccc7c56)ccc4c3)nc(-c3ccc4sc5ccccc5c4c3)n2)cc1 ; c1ccc(-c2nc(-c3ccc4sc5ccccc5c4c3)nc(-c3ccc(-c4cccc5oc6ccccc6c45)c4ccccc34)n2)cc1 ; c1ccc(-c2nc(-c3ccc4ccc(-c5cccc6oc7ccccc7c56)cc4c3)nc(-c3ccc4sc5ccccc5c4c3)n2)cc1]

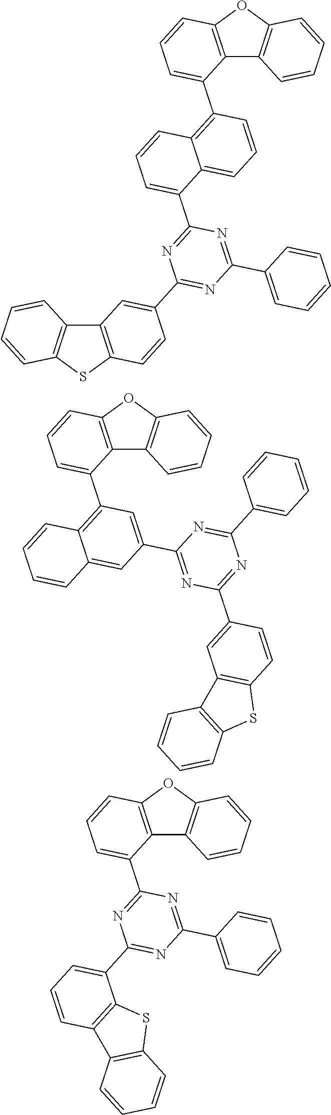

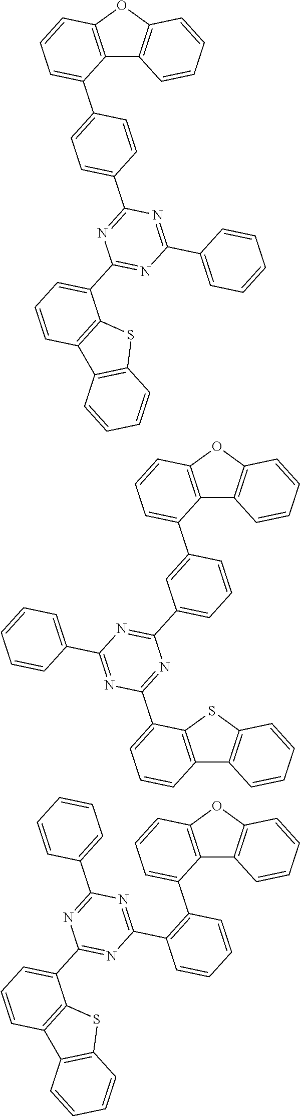

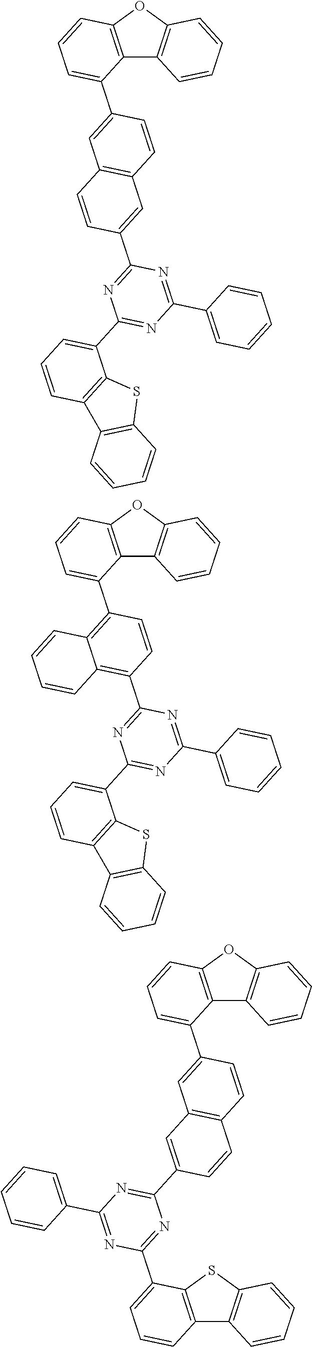

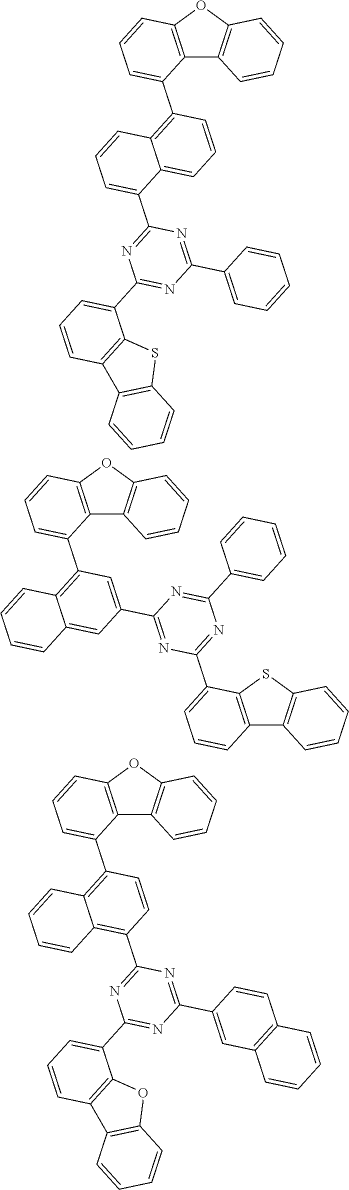

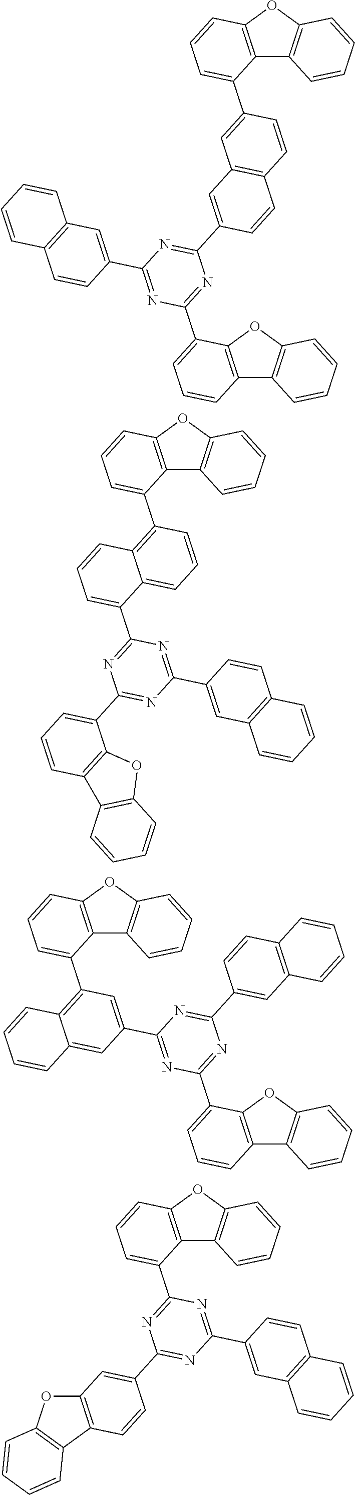

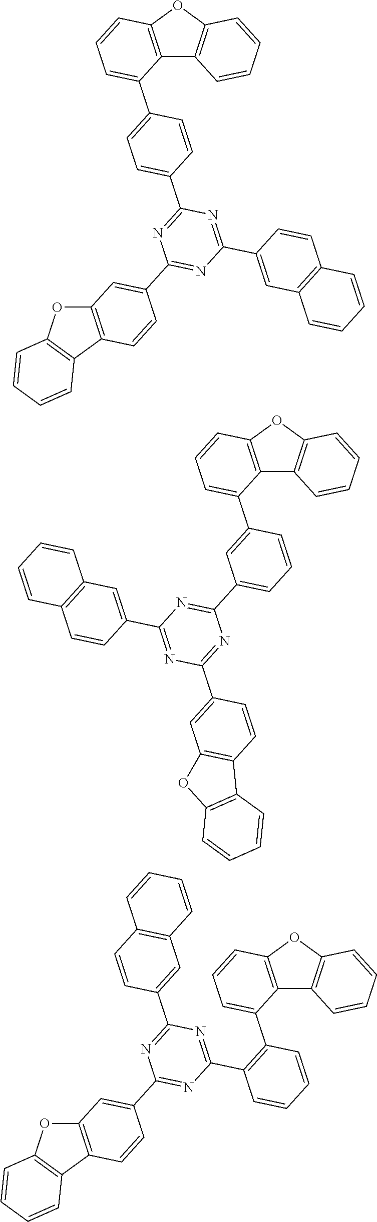

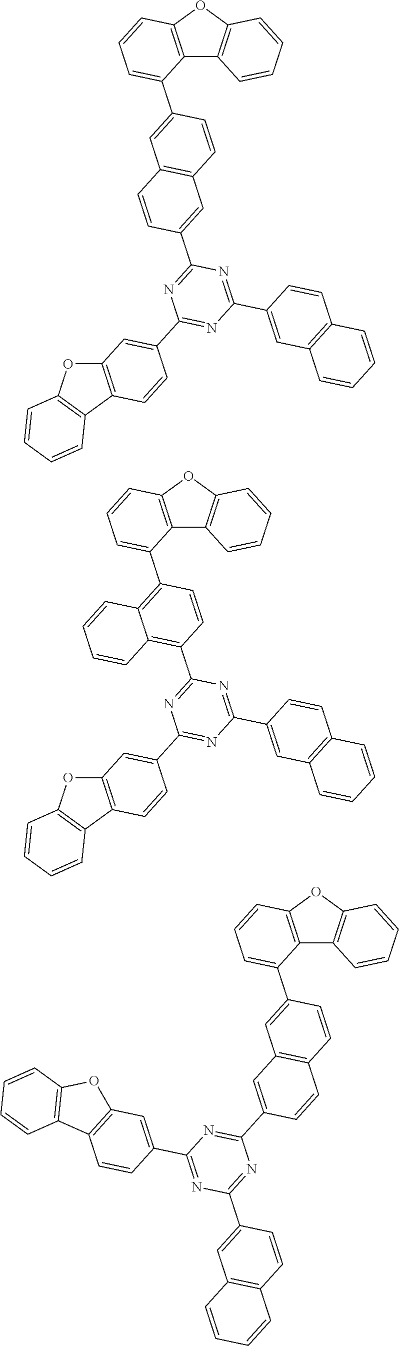 [SMILES: c1ccc2cc(-c3nc(-c4ccc5cc(-c6cccc7oc8ccccc8c67)ccc5c4)nc(-c4ccc5c(c4)oc4ccccc45)n3)ccc2c1 ; c1ccc2cc(-c3nc(-c4ccc5c(c4)oc4ccccc45)nc(-c4ccc(-c5cccc6oc7ccccc7c56)c5ccccc45)n3)ccc2c1 ; c1ccc2cc(-c3nc(-c4ccc5ccc(-c6cccc7oc8ccccc8c67)cc5c4)nc(-c4ccc5c(c4)oc4ccccc45)n3)ccc2c1]

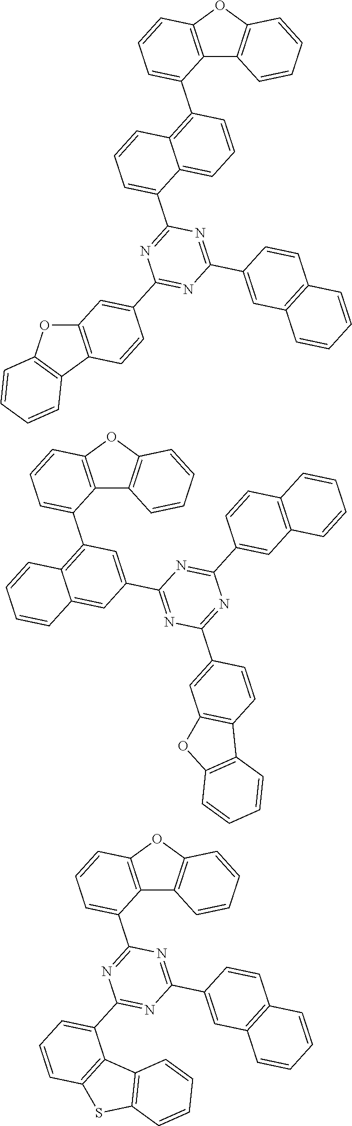

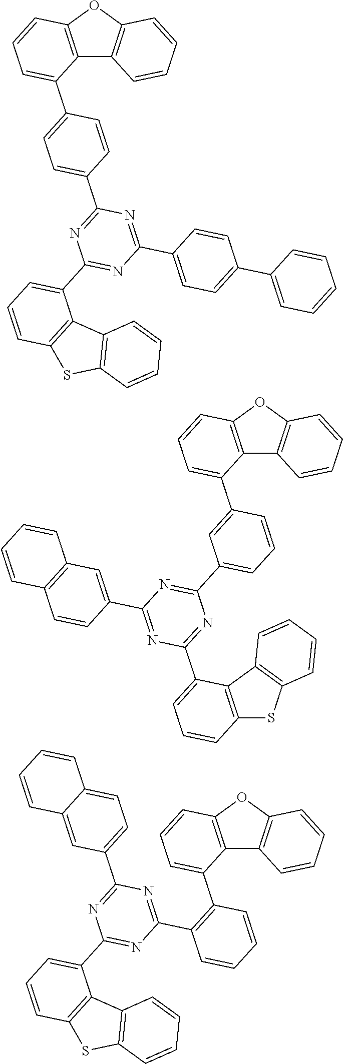 [SMILES: c1ccc(-c2ccc(-c3nc(-c4ccc(-c5cccc6oc7ccccc7c56)cc4)nc(-c4cccc5sc6ccccc6c45)n3)cc2)cc1 ; c1cc(-c2nc(-c3ccc4ccccc4c3)nc(-c3cccc4sc5ccccc5c34)n2)cc(-c2cccc3oc4ccccc4c23)c1 ; c1ccc(-c2cccc3oc4ccccc4c23)c(-c2nc(-c3ccc4ccccc4c3)nc(-c3cccc4sc5ccccc5c34)n2)c1]

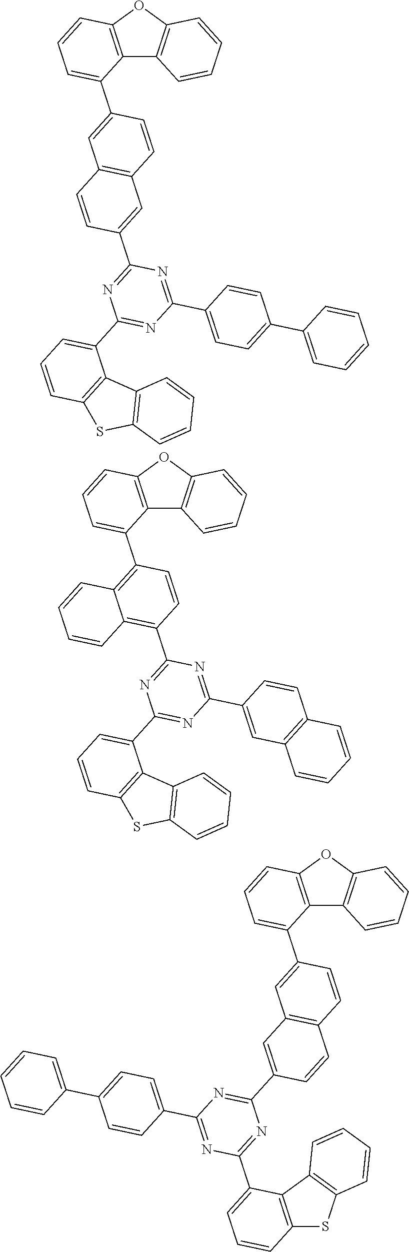

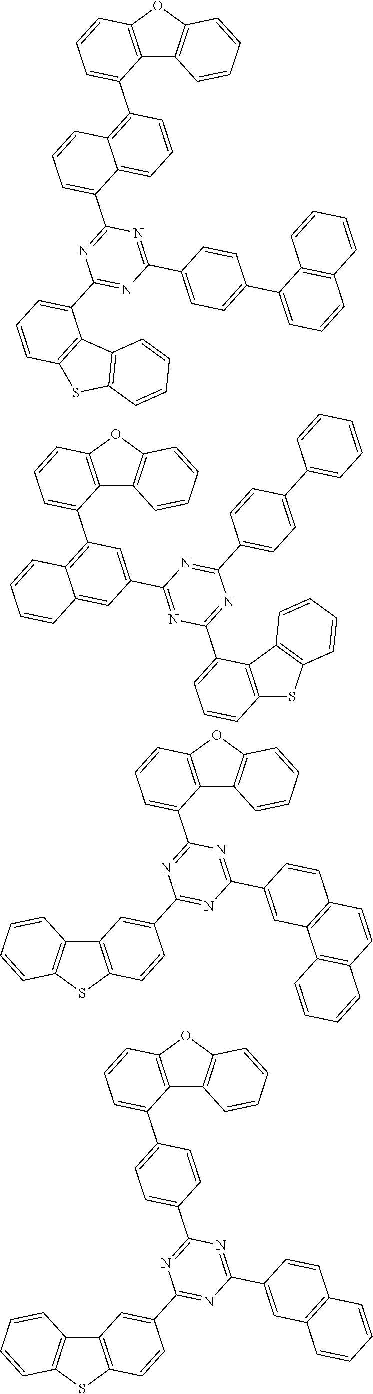

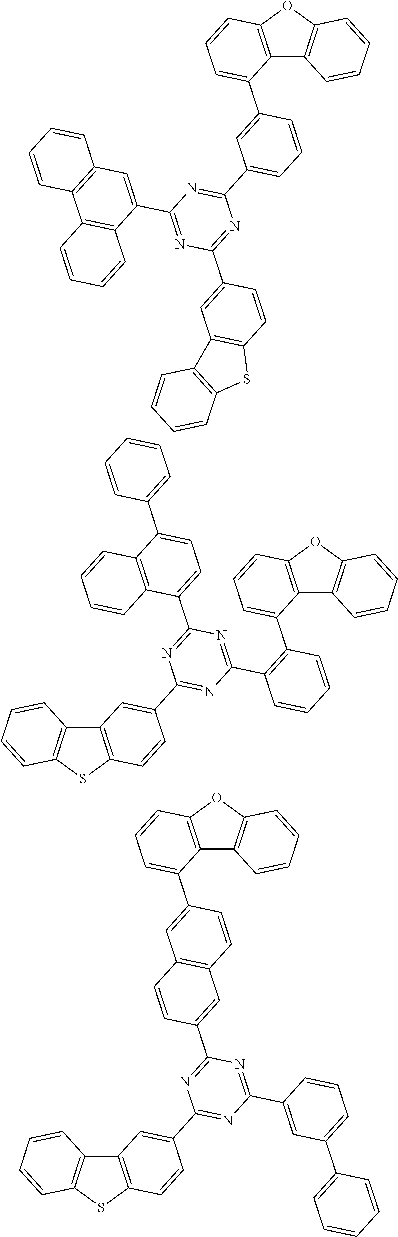

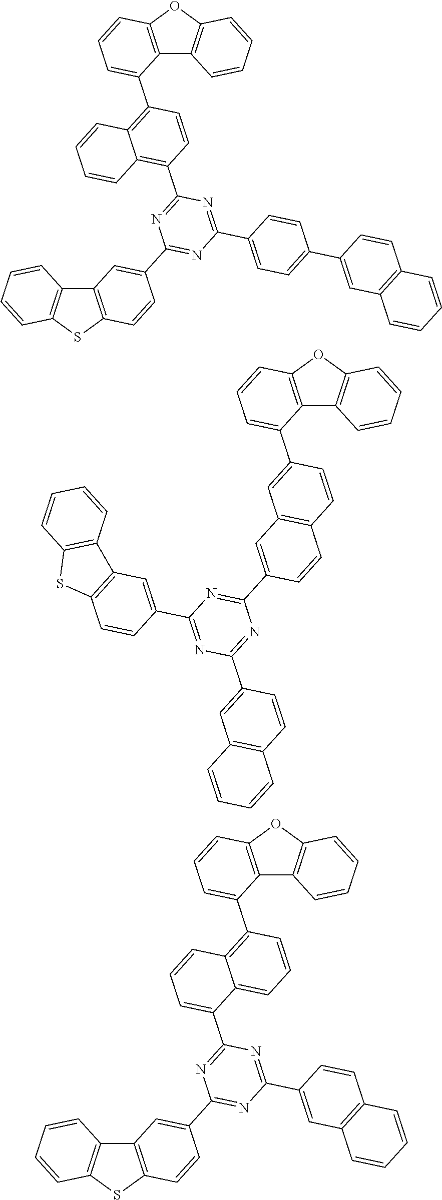

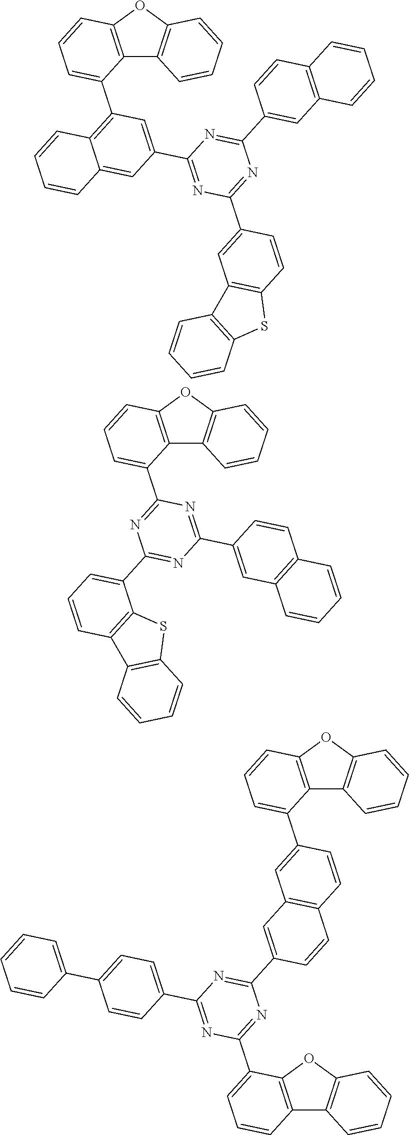

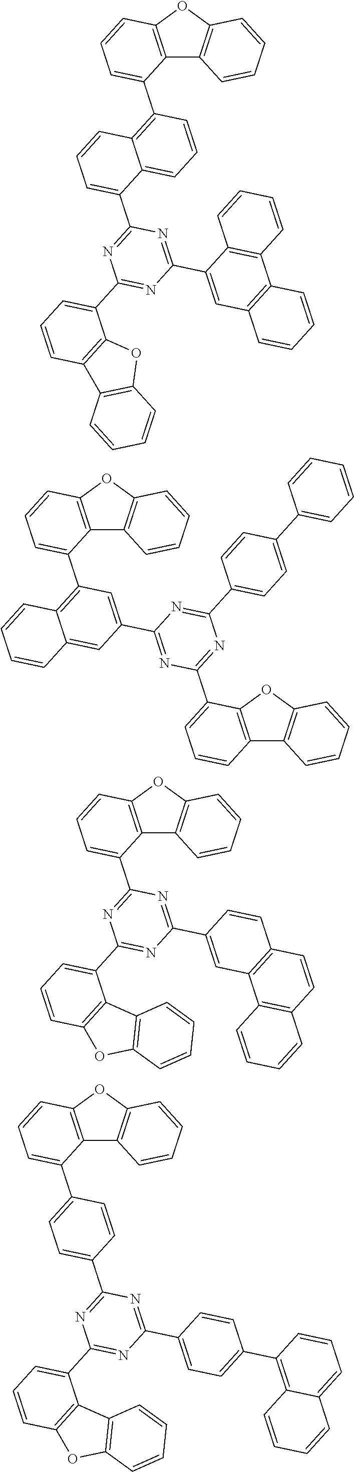

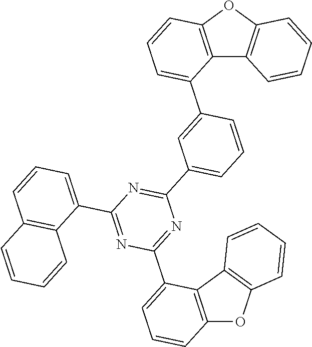 [SMILES: c1cc(-c2nc(-c3cccc4ccccc34)nc(-c3cccc4oc5ccccc5c34)n2)cc(-c2cccc3oc4ccccc4c23)c1]

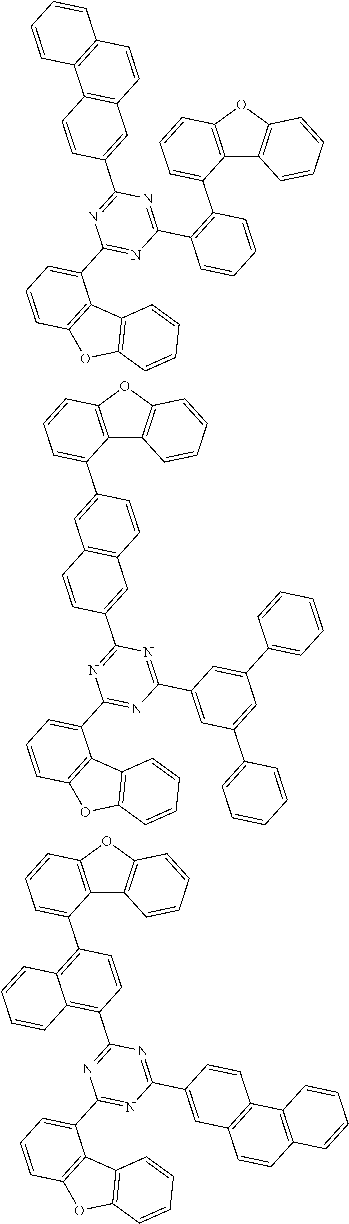

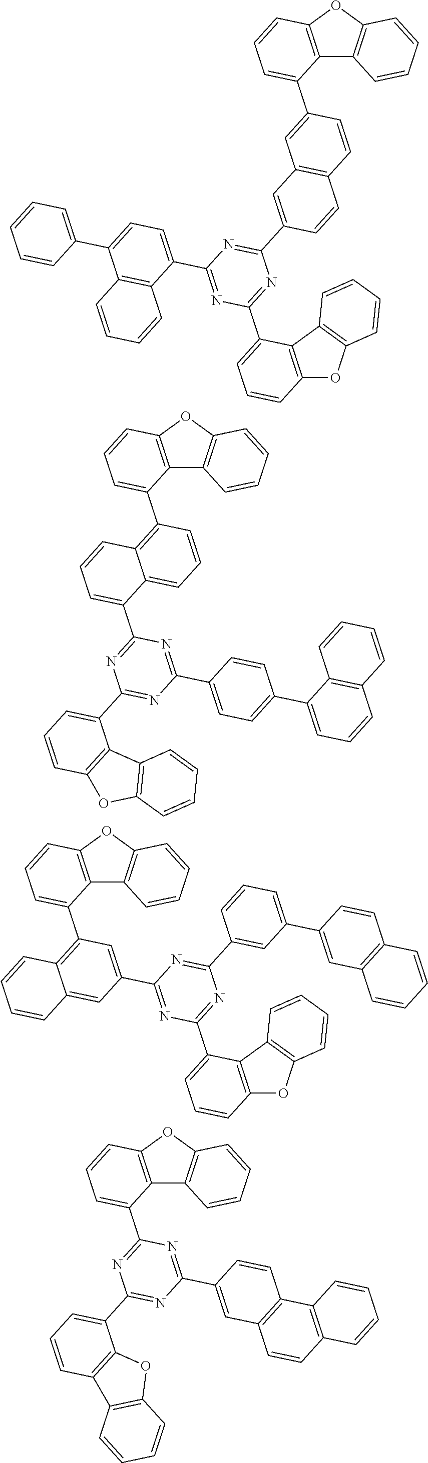

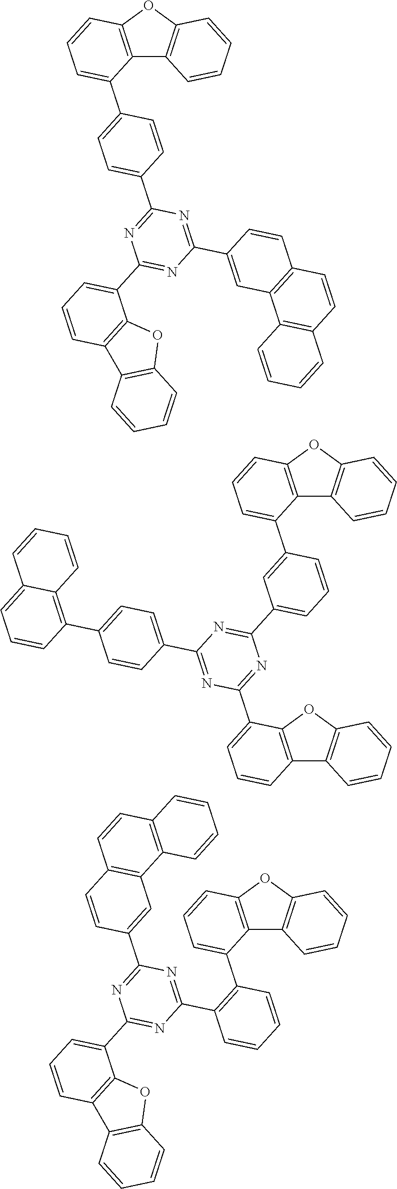

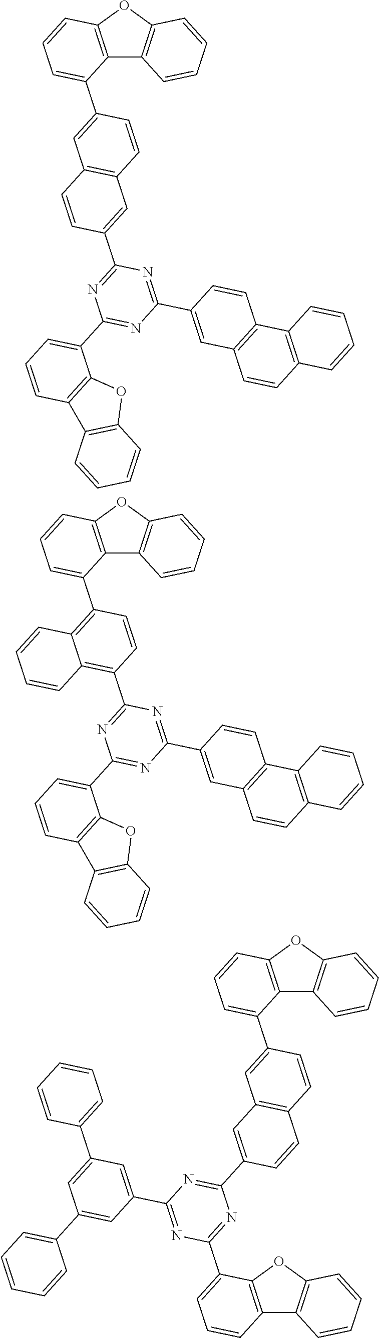

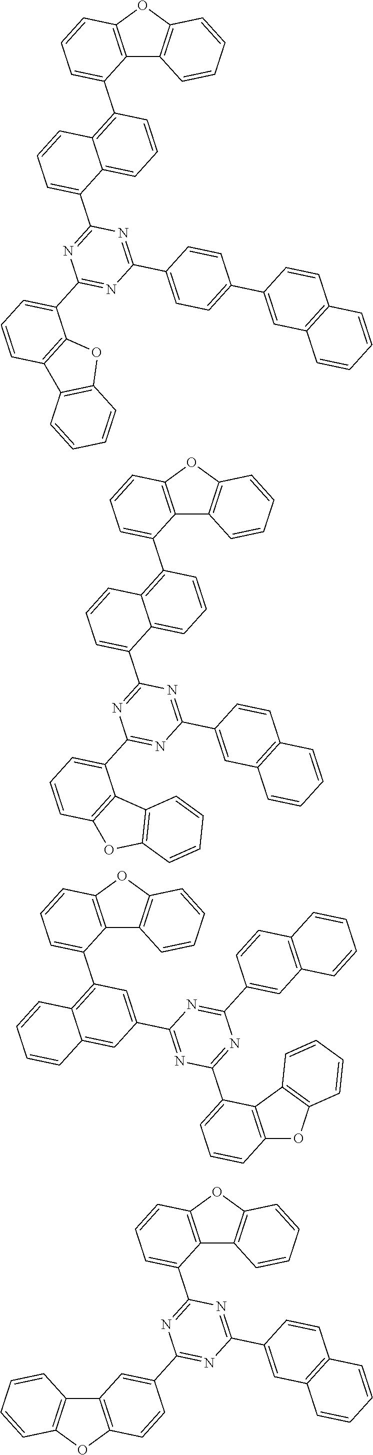

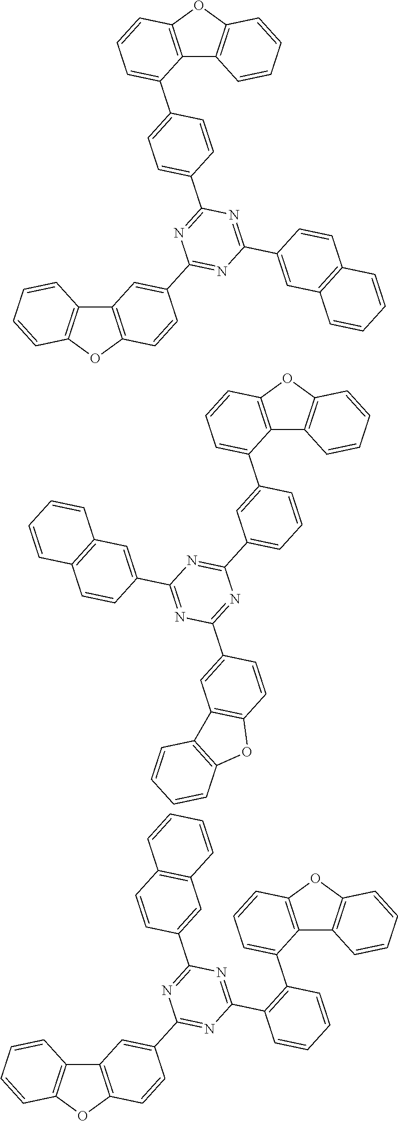

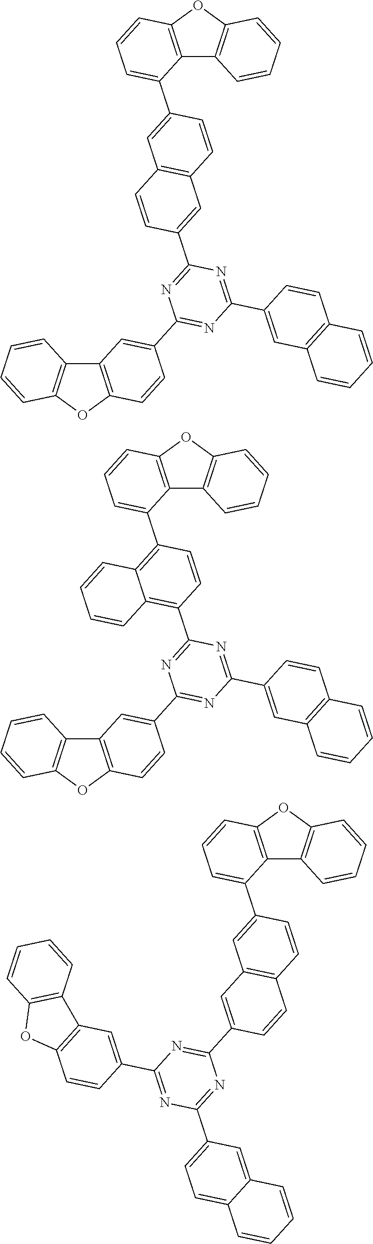 [SMILES: c1ccc2cc(-c3nc(-c4ccc5cc(-c6cccc7oc8ccccc8c67)ccc5c4)nc(-c4ccc5oc6ccccc6c5c4)n3)ccc2c1 ; c1ccc2cc(-c3nc(-c4ccc5oc6ccccc6c5c4)nc(-c4ccc(-c5cccc6oc7ccccc7c56)c5ccccc45)n3)ccc2c1 ; c1ccc2cc(-c3nc(-c4ccc5ccc(-c6cccc7oc8ccccc8c67)cc5c4)nc(-c4ccc5oc6ccccc6c5c4)n3)ccc2c1]

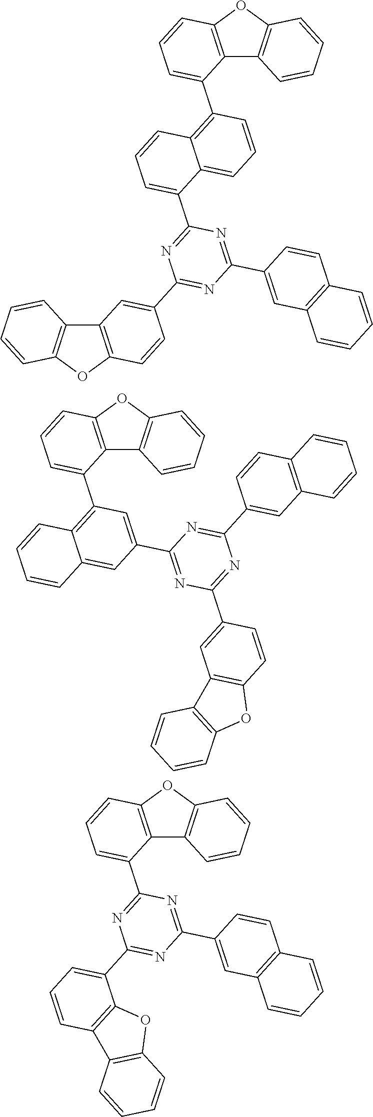

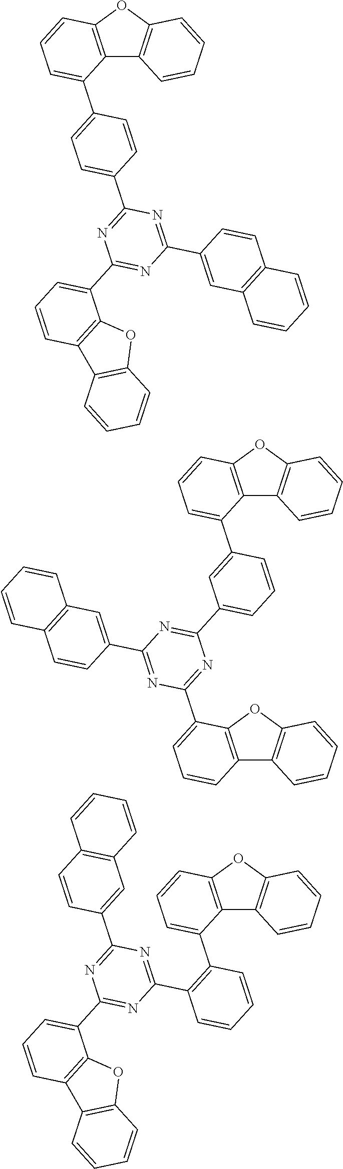 [SMILES: c1ccc2cc(-c3nc(-c4ccc(-c5cccc6oc7ccccc7c56)cc4)nc(-c4cccc5c4oc4ccccc45)n3)ccc2c1 ; c1cc(-c2nc(-c3ccc4ccccc4c3)nc(-c3cccc4c3oc3ccccc34)n2)cc(-c2cccc3oc4ccccc4c23)c1 ; c1ccc(-c2cccc3oc4ccccc4c23)c(-c2nc(-c3ccc4ccccc4c3)nc(-c3cccc4c3oc3ccccc34)n2)c1]

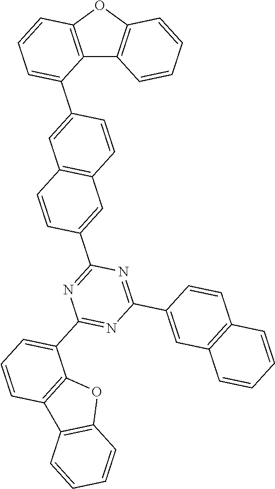 [SMILES: c1ccc2cc(-c3nc(-c4ccc5cc(-c6cccc7oc8ccccc8c67)ccc5c4)nc(-c4cccc5c4oc4ccccc45)n3)ccc2c1]

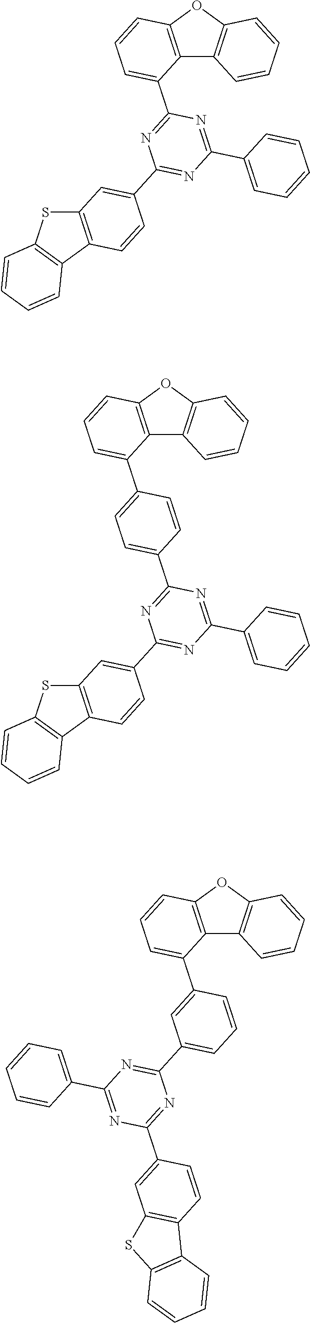 [SMILES: c1ccc(-c2nc(-c3ccc4c(c3)sc3ccccc34)nc(-c3cccc4oc5ccccc5c34)n2)cc1 ; c1ccc(-c2nc(-c3ccc(-c4cccc5oc6ccccc6c45)cc3)nc(-c3ccc4c(c3)sc3ccccc34)n2)cc1 ; c1ccc(-c2nc(-c3cccc(-c4cccc5oc6ccccc6c45)c3)nc(-c3ccc4c(c3)sc3ccccc34)n2)cc1]

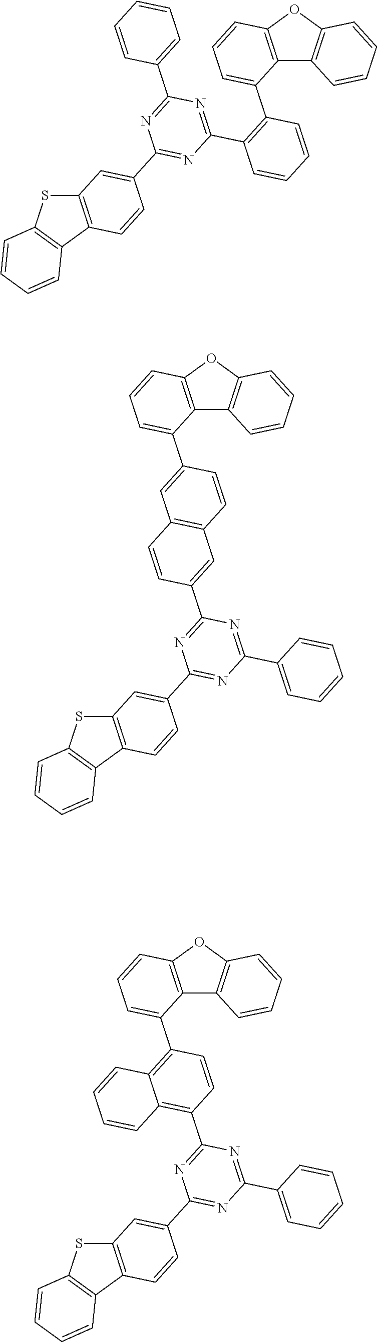 [SMILES: c1ccc(-c2nc(-c3ccc4c(c3)sc3ccccc34)nc(-c3ccccc3-c3cccc4oc5ccccc5c34)n2)cc1 ; c1ccc(-c2nc(-c3ccc4cc(-c5cccc6oc7ccccc7c56)ccc4c3)nc(-c3ccc4c(c3)sc3ccccc34)n2)cc1 ; c1ccc(-c2nc(-c3ccc4c(c3)sc3ccccc34)nc(-c3ccc(-c4cccc5oc6ccccc6c45)c4ccccc34)n2)cc1]

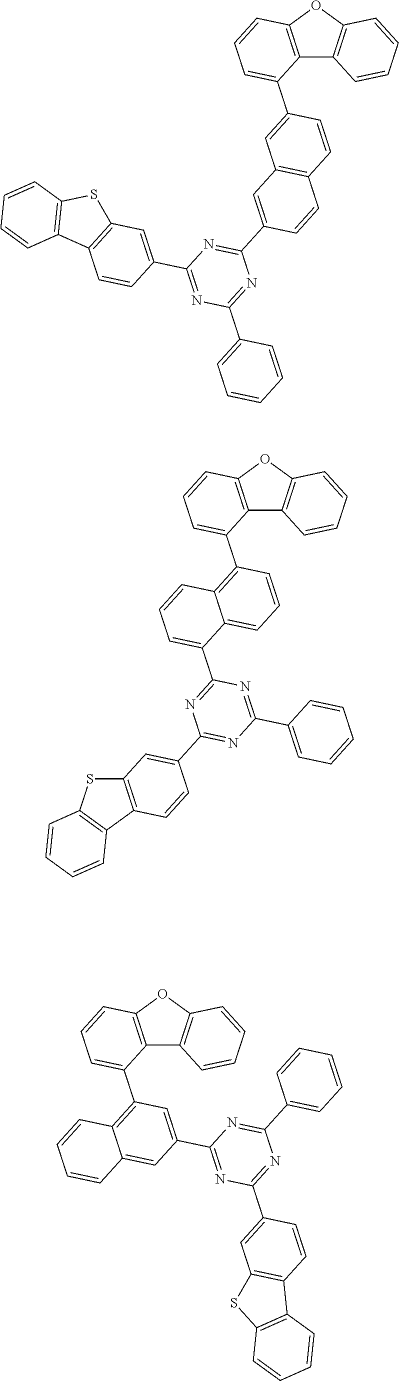 [SMILES: c1ccc(-c2nc(-c3ccc4ccc(-c5cccc6oc7ccccc7c56)cc4c3)nc(-c3ccc4c(c3)sc3ccccc34)n2)cc1 ; c1ccc(-c2nc(-c3ccc4c(c3)sc3ccccc34)nc(-c3cccc4c(-c5cccc6oc7ccccc7c56)cccc34)n2)cc1 ; c1ccc(-c2nc(-c3cc(-c4cccc5oc6ccccc6c45)c4ccccc4c3)nc(-c3ccc4c(c3)sc3ccccc34)n2)cc1]

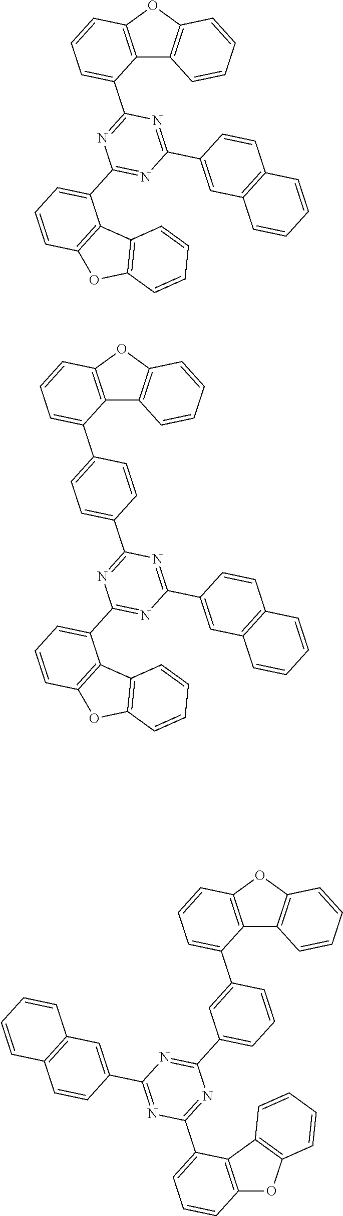 [SMILES: c1ccc2cc(-c3nc(-c4cccc5oc6ccccc6c45)nc(-c4cccc5oc6ccccc6c45)n3)ccc2c1 ; c1ccc2cc(-c3nc(-c4ccc(-c5cccc6oc7ccccc7c56)cc4)nc(-c4cccc5oc6ccccc6c45)n3)ccc2c1 ; c1cc(-c2nc(-c3ccc4ccccc4c3)nc(-c3cccc4oc5ccccc5c34)n2)cc(-c2cccc3oc4ccccc4c23)c1]

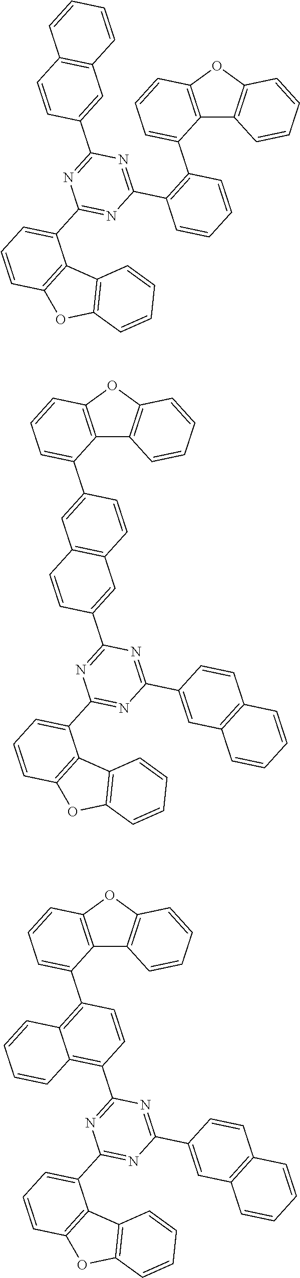 [SMILES: c1ccc(-c2cccc3oc4ccccc4c23)c(-c2nc(-c3ccc4ccccc4c3)nc(-c3cccc4oc5ccccc5c34)n2)c1 ; c1ccc2cc(-c3nc(-c4ccc5cc(-c6cccc7oc8ccccc8c67)ccc5c4)nc(-c4cccc5oc6ccccc6c45)n3)ccc2c1 ; c1ccc2cc(-c3nc(-c4ccc(-c5cccc6oc7ccccc7c56)c5ccccc45)nc(-c4cccc5oc6ccccc6c45)n3)ccc2c1]

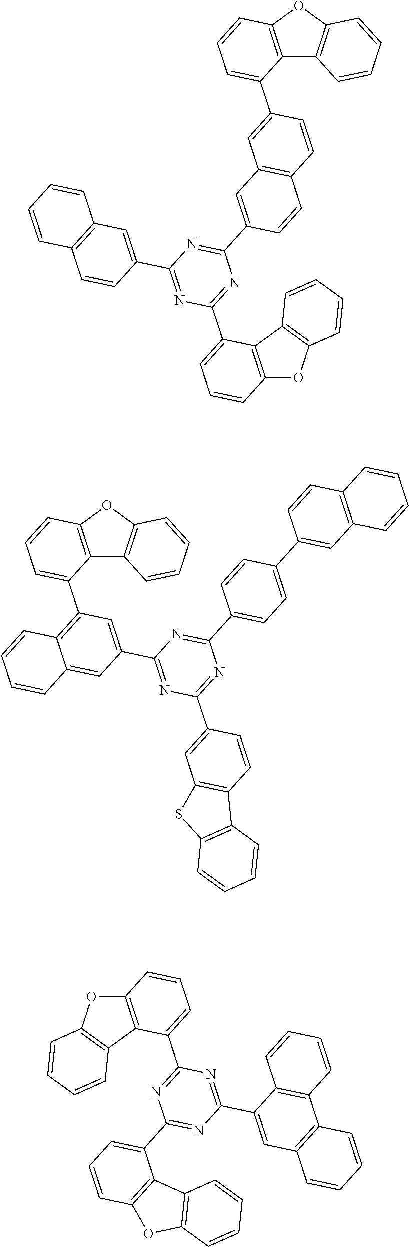 [SMILES: c1ccc2cc(-c3nc(-c4ccc5ccc(-c6cccc7oc8ccccc8c67)cc5c4)nc(-c4cccc5oc6ccccc6c45)n3)ccc2c1 ; c1ccc2cc(-c3ccc(-c4nc(-c5cc(-c6cccc7oc8ccccc8c67)c6ccccc6c5)nc(-c5ccc6c(c5)sc5ccccc56)n4)cc3)ccc2c1 ; c1ccc2c(c1)cc(-c1nc(-c3cccc4oc5ccccc5c34)nc(-c3cccc4oc5ccccc5c34)n1)c1ccccc12]

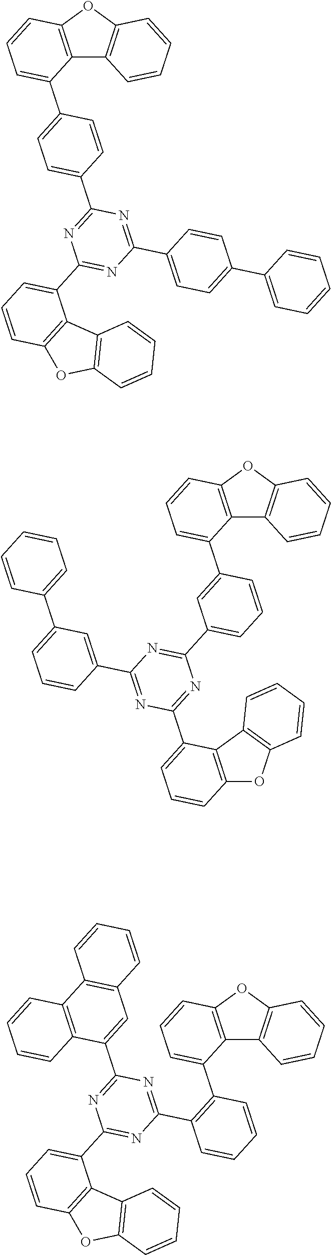 [SMILES: c1ccc(-c2ccc(-c3nc(-c4ccc(-c5cccc6oc7ccccc7c56)cc4)nc(-c4cccc5oc6ccccc6c45)n3)cc2)cc1 ; c1ccc(-c2cccc(-c3nc(-c4cccc(-c5cccc6oc7ccccc7c56)c4)nc(-c4cccc5oc6ccccc6c45)n3)c2)cc1 ; c1ccc(-c2cccc3oc4ccccc4c23)c(-c2nc(-c3cc4ccccc4c4ccccc34)nc(-c3cccc4oc5ccccc5c34)n2)c1]

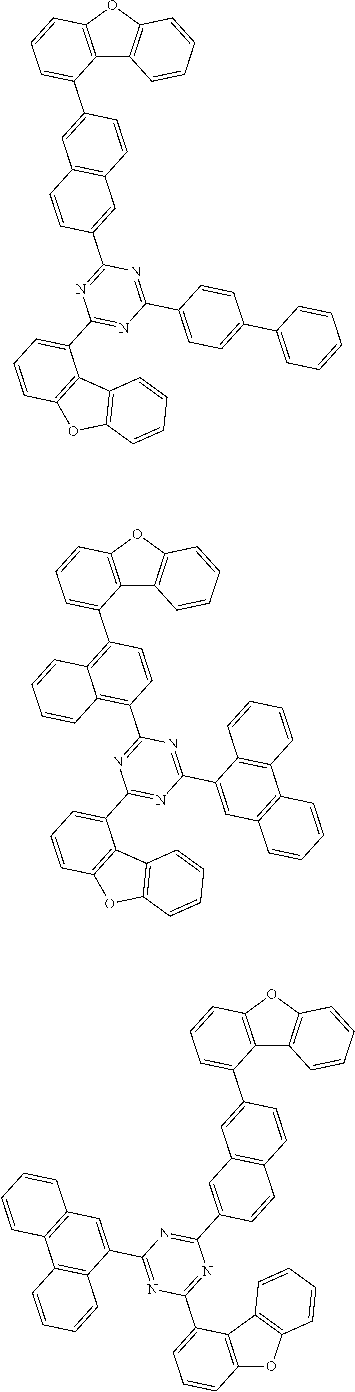 [SMILES: c1ccc(-c2ccc(-c3nc(-c4ccc5cc(-c6cccc7oc8ccccc8c67)ccc5c4)nc(-c4cccc5oc6ccccc6c45)n3)cc2)cc1 ; c1ccc2c(c1)cc(-c1nc(-c3ccc(-c4cccc5oc6ccccc6c45)c4ccccc34)nc(-c3cccc4oc5ccccc5c34)n1)c1ccccc12 ; c1ccc2c(c1)cc(-c1nc(-c3ccc4ccc(-c5cccc6oc7ccccc7c56)cc4c3)nc(-c3cccc4oc5ccccc5c34)n1)c1ccccc12]

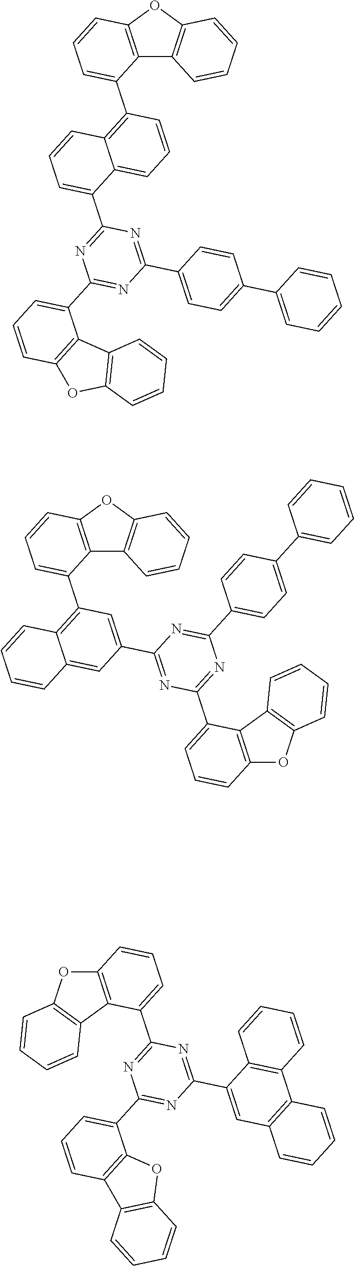 [SMILES: c1ccc(-c2ccc(-c3nc(-c4cccc5c(-c6cccc7oc8ccccc8c67)cccc45)nc(-c4cccc5oc6ccccc6c45)n3)cc2)cc1 ; c1ccc(-c2ccc(-c3nc(-c4cc(-c5cccc6oc7ccccc7c56)c5ccccc5c4)nc(-c4cccc5oc6ccccc6c45)n3)cc2)cc1 ; c1ccc2c(c1)cc(-c1nc(-c3cccc4c3oc3ccccc34)nc(-c3cccc4oc5ccccc5c34)n1)c1ccccc12]

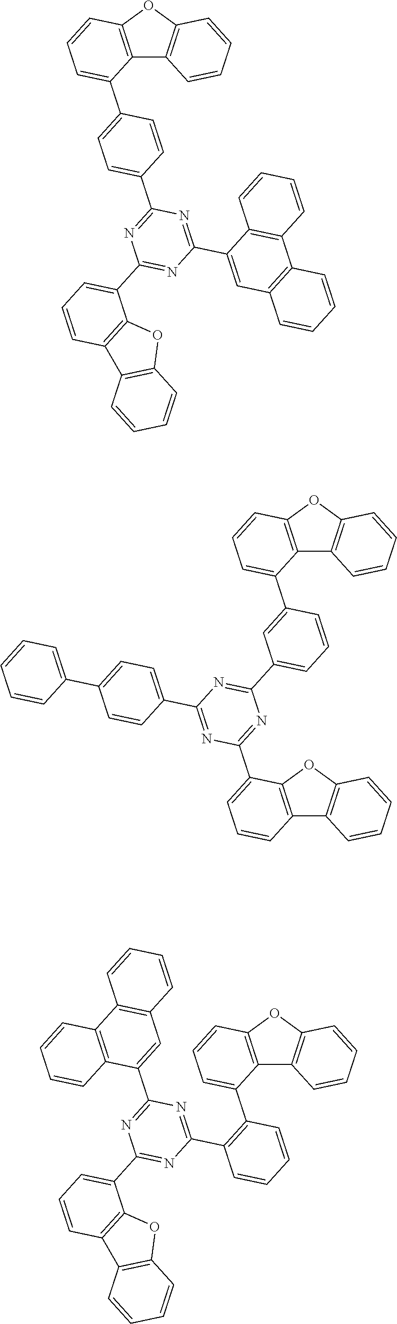 [SMILES: c1ccc2c(c1)cc(-c1nc(-c3ccc(-c4cccc5oc6ccccc6c45)cc3)nc(-c3cccc4c3oc3ccccc34)n1)c1ccccc12 ; c1ccc(-c2ccc(-c3nc(-c4cccc(-c5cccc6oc7ccccc7c56)c4)nc(-c4cccc5c4oc4ccccc45)n3)cc2)cc1 ; c1ccc(-c2cccc3oc4ccccc4c23)c(-c2nc(-c3cc4ccccc4c4ccccc34)nc(-c3cccc4c3oc3ccccc34)n2)c1]

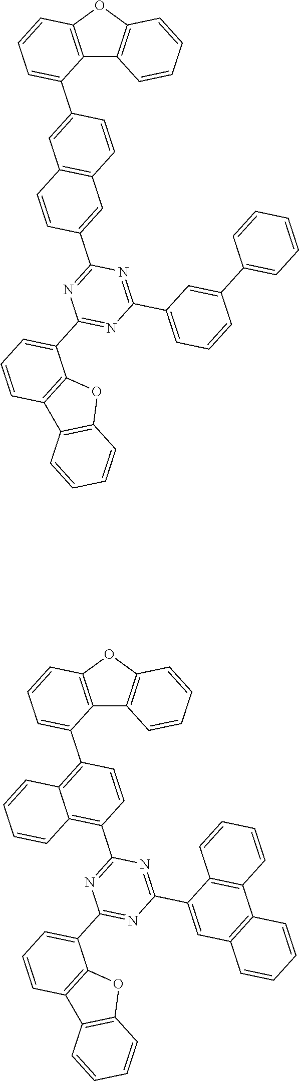 [SMILES: c1ccc(-c2cccc(-c3nc(-c4ccc5cc(-c6cccc7oc8ccccc8c67)ccc5c4)nc(-c4cccc5c4oc4ccccc45)n3)c2)cc1 ; c1ccc2c(c1)cc(-c1nc(-c3ccc(-c4cccc5oc6ccccc6c45)c4ccccc34)nc(-c3cccc4c3oc3ccccc34)n1)c1ccccc12]

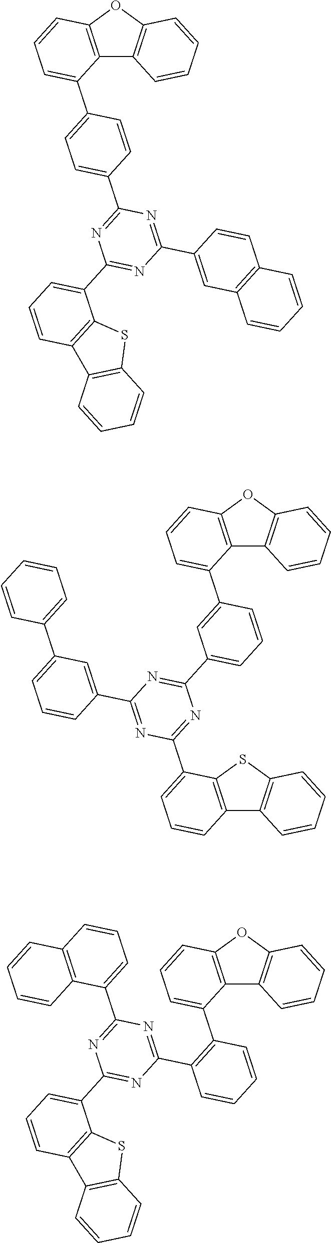 [SMILES: c1ccc2cc(-c3nc(-c4ccc(-c5cccc6oc7ccccc7c56)cc4)nc(-c4cccc5c4sc4ccccc45)n3)ccc2c1 ; c1ccc(-c2cccc(-c3nc(-c4cccc(-c5cccc6oc7ccccc7c56)c4)nc(-c4cccc5c4sc4ccccc45)n3)c2)cc1 ; c1ccc(-c2cccc3oc4ccccc4c23)c(-c2nc(-c3cccc4ccccc34)nc(-c3cccc4c3sc3ccccc34)n2)c1]

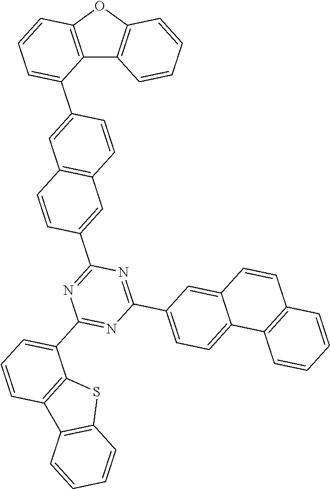 [SMILES: c1ccc2c(c1)ccc1cc(-c3nc(-c4ccc5cc(-c6cccc7oc8ccccc8c67)ccc5c4)nc(-c4cccc5c4sc4ccccc45)n3)ccc12]

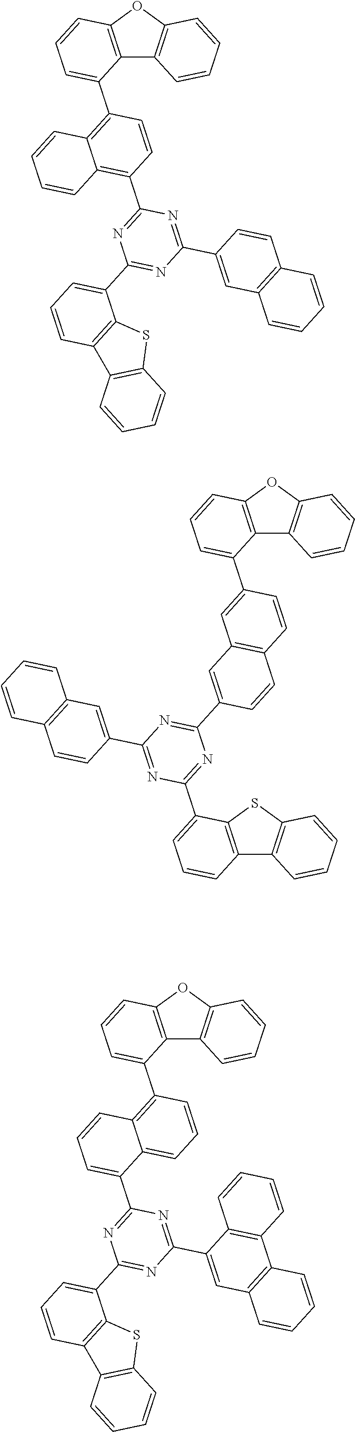 [SMILES: c1ccc2cc(-c3nc(-c4ccc(-c5cccc6oc7ccccc7c56)c5ccccc45)nc(-c4cccc5c4sc4ccccc45)n3)ccc2c1 ; c1ccc2cc(-c3nc(-c4ccc5ccc(-c6cccc7oc8ccccc8c67)cc5c4)nc(-c4cccc5c4sc4ccccc45)n3)ccc2c1 ; c1ccc2c(c1)cc(-c1nc(-c3cccc4c(-c5cccc6oc7ccccc7c56)cccc34)nc(-c3cccc4c3sc3ccccc34)n1)c1ccccc12]

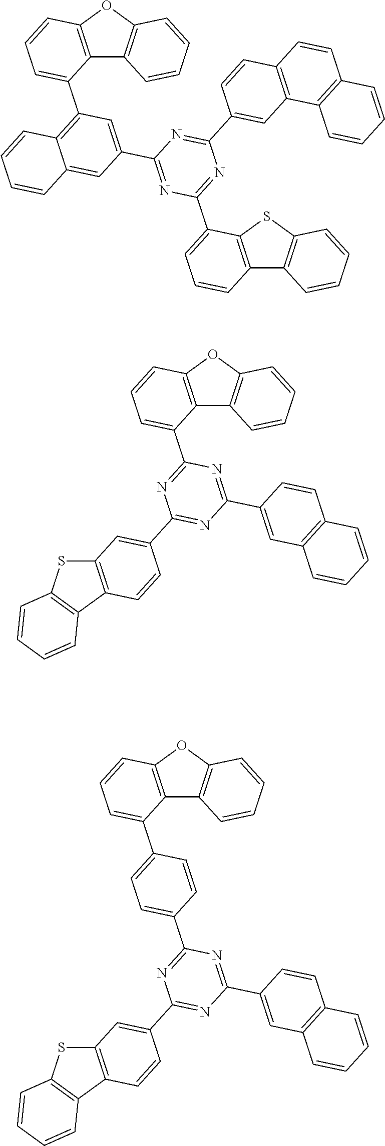 [SMILES: c1ccc2c(-c3cccc4oc5ccccc5c34)cc(-c3nc(-c4ccc5ccc6ccccc6c5c4)nc(-c4cccc5c4sc4ccccc45)n3)cc2c1 ; c1ccc2cc(-c3nc(-c4ccc5c(c4)sc4ccccc45)nc(-c4cccc5oc6ccccc6c45)n3)ccc2c1 ; c1ccc2cc(-c3nc(-c4ccc(-c5cccc6oc7ccccc7c56)cc4)nc(-c4ccc5c(c4)sc4ccccc45)n3)ccc2c1]

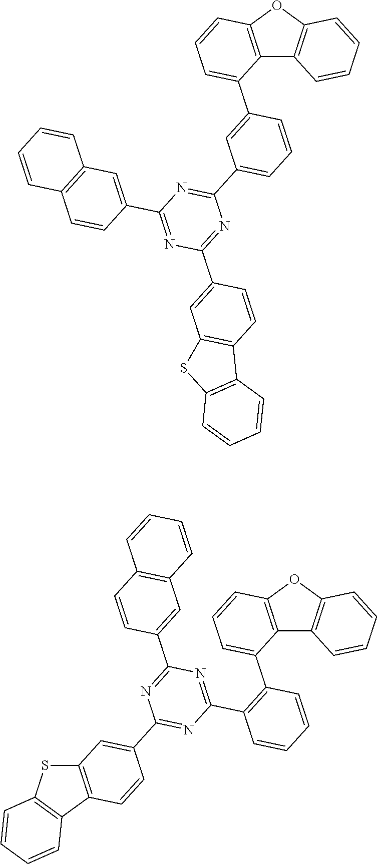 [SMILES: c1cc(-c2nc(-c3ccc4ccccc4c3)nc(-c3ccc4c(c3)sc3ccccc34)n2)cc(-c2cccc3oc4ccccc4c23)c1 ; c1ccc(-c2cccc3oc4ccccc4c23)c(-c2nc(-c3ccc4ccccc4c3)nc(-c3ccc4c(c3)sc3ccccc34)n2)c1]

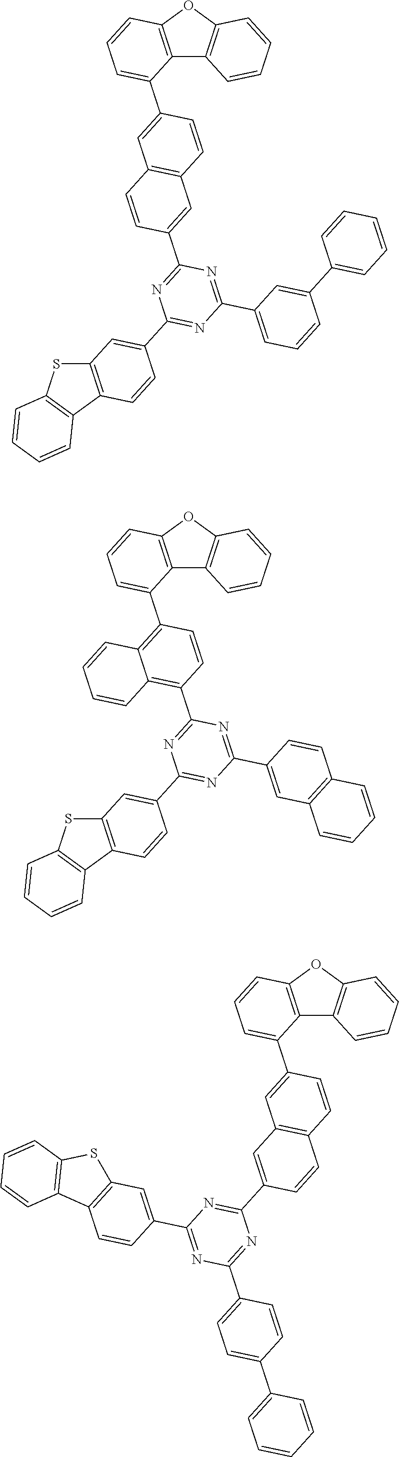 [SMILES: c1ccc(-c2cccc(-c3nc(-c4ccc5cc(-c6cccc7oc8ccccc8c67)ccc5c4)nc(-c4ccc5c(c4)sc4ccccc45)n3)c2)cc1 ; c1ccc2cc(-c3nc(-c4ccc5c(c4)sc4ccccc45)nc(-c4ccc(-c5cccc6oc7ccccc7c56)c5ccccc45)n3)ccc2c1 ; c1ccc(-c2ccc(-c3nc(-c4ccc5ccc(-c6cccc7oc8ccccc8c67)cc5c4)nc(-c4ccc5c(c4)sc4ccccc45)n3)cc2)cc1]

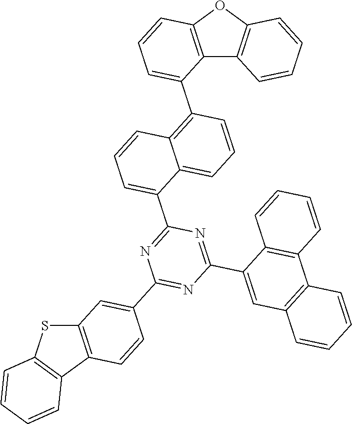 [SMILES: c1ccc2c(c1)cc(-c1nc(-c3ccc4c(c3)sc3ccccc34)nc(-c3cccc4c(-c5cccc6oc7ccccc7c56)cccc34)n1)c1ccccc12]

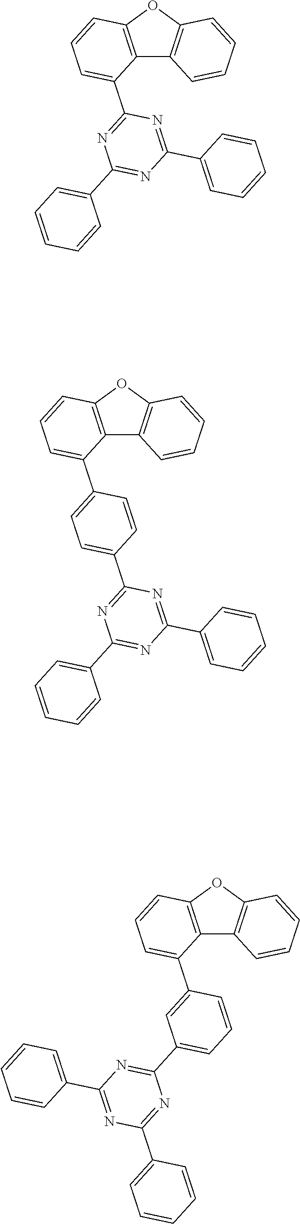 [SMILES: c1ccc(-c2nc(-c3ccccc3)nc(-c3cccc4oc5ccccc5c34)n2)cc1 ; c1ccc(-c2nc(-c3ccccc3)nc(-c3ccc(-c4cccc5oc6ccccc6c45)cc3)n2)cc1 ; c1ccc(-c2nc(-c3ccccc3)nc(-c3cccc(-c4cccc5oc6ccccc6c45)c3)n2)cc1]

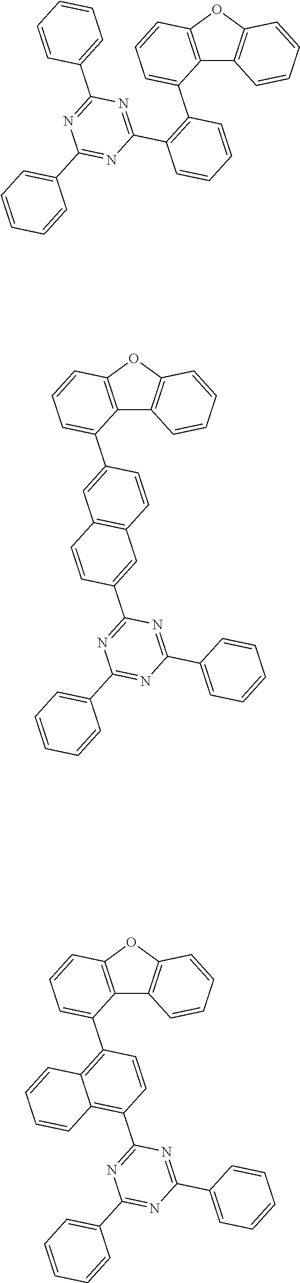 [SMILES: c1ccc(-c2nc(-c3ccccc3)nc(-c3ccccc3-c3cccc4oc5ccccc5c34)n2)cc1 ; c1ccc(-c2nc(-c3ccccc3)nc(-c3ccc4cc(-c5cccc6oc7ccccc7c56)ccc4c3)n2)cc1 ; c1ccc(-c2nc(-c3ccccc3)nc(-c3ccc(-c4cccc5oc6ccccc6c45)c4ccccc34)n2)cc1]

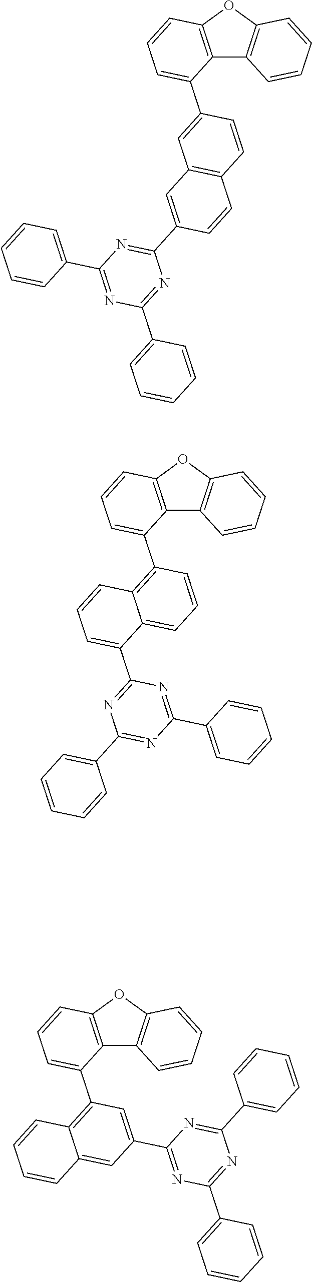 [SMILES: c1ccc(-c2nc(-c3ccccc3)nc(-c3ccc4ccc(-c5cccc6oc7ccccc7c56)cc4c3)n2)cc1 ; c1ccc(-c2nc(-c3ccccc3)nc(-c3cccc4c(-c5cccc6oc7ccccc7c56)cccc34)n2)cc1 ; c1ccc(-c2nc(-c3ccccc3)nc(-c3cc(-c4cccc5oc6ccccc6c45)c4ccccc4c3)n2)cc1]

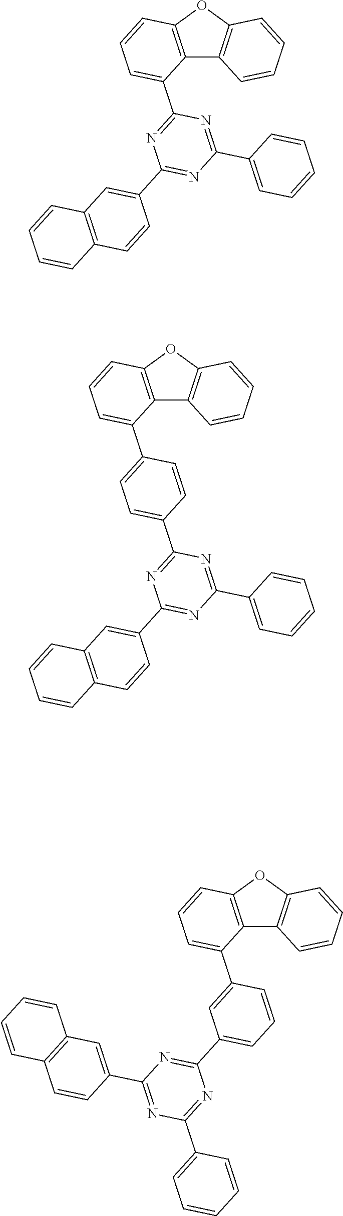 [SMILES: c1ccc(-c2nc(-c3ccc4ccccc4c3)nc(-c3cccc4oc5ccccc5c34)n2)cc1 ; c1ccc(-c2nc(-c3ccc(-c4cccc5oc6ccccc6c45)cc3)nc(-c3ccc4ccccc4c3)n2)cc1 ; c1ccc(-c2nc(-c3cccc(-c4cccc5oc6ccccc6c45)c3)nc(-c3ccc4ccccc4c3)n2)cc1]

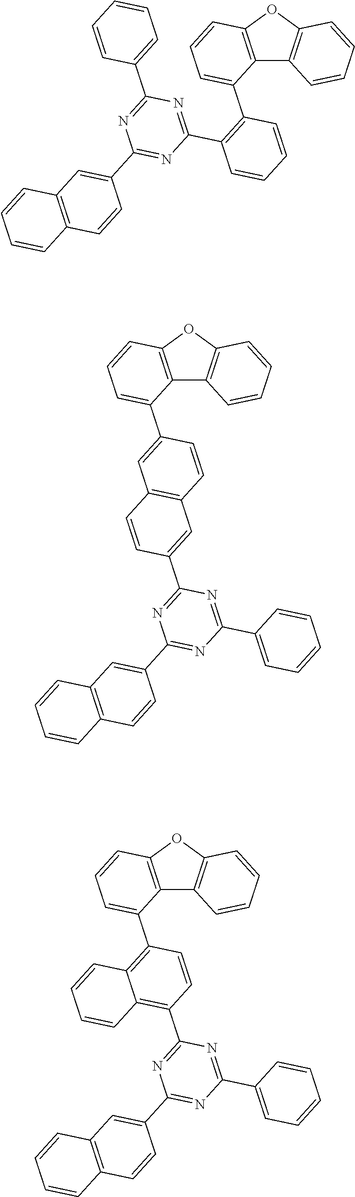 [SMILES: c1ccc(-c2nc(-c3ccc4ccccc4c3)nc(-c3ccccc3-c3cccc4oc5ccccc5c34)n2)cc1 ; c1ccc(-c2nc(-c3ccc4ccccc4c3)nc(-c3ccc4cc(-c5cccc6oc7ccccc7c56)ccc4c3)n2)cc1 ; c1ccc(-c2nc(-c3ccc4ccccc4c3)nc(-c3ccc(-c4cccc5oc6ccccc6c45)c4ccccc34)n2)cc1]

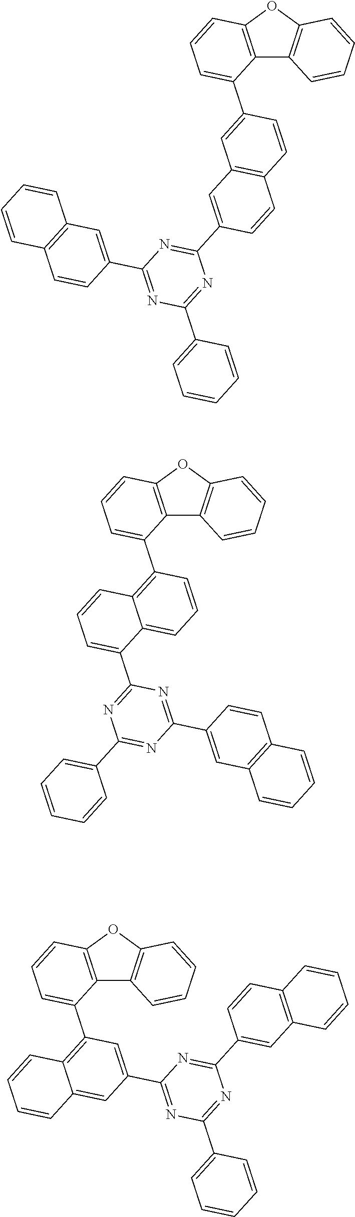 [SMILES: c1ccc(-c2nc(-c3ccc4ccccc4c3)nc(-c3ccc4ccc(-c5cccc6oc7ccccc7c56)cc4c3)n2)cc1 ; c1ccc(-c2nc(-c3ccc4ccccc4c3)nc(-c3cccc4c(-c5cccc6oc7ccccc7c56)cccc34)n2)cc1 ; c1ccc(-c2nc(-c3ccc4ccccc4c3)nc(-c3cc(-c4cccc5oc6ccccc6c45)c4ccccc4c3)n2)cc1]

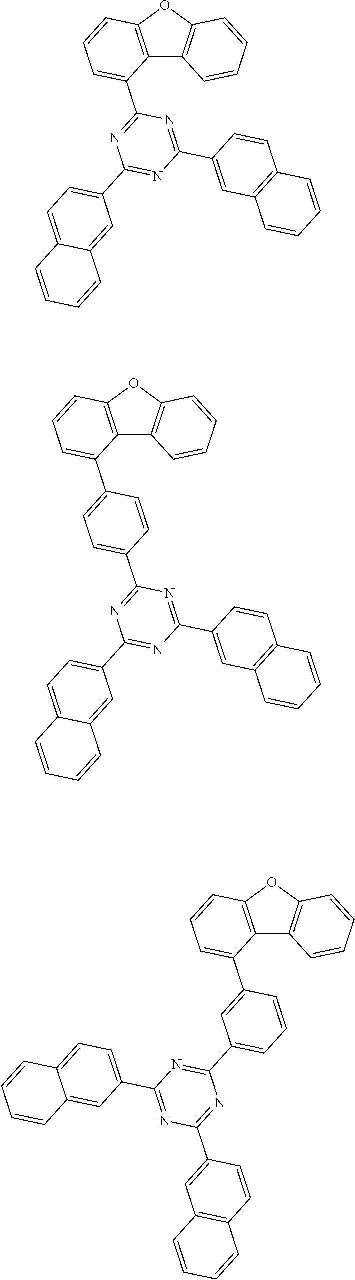 [SMILES: c1ccc2cc(-c3nc(-c4ccc5ccccc5c4)nc(-c4cccc5oc6ccccc6c45)n3)ccc2c1 ; c1ccc2cc(-c3nc(-c4ccc(-c5cccc6oc7ccccc7c56)cc4)nc(-c4ccc5ccccc5c4)n3)ccc2c1 ; c1cc(-c2nc(-c3ccc4ccccc4c3)nc(-c3ccc4ccccc4c3)n2)cc(-c2cccc3oc4ccccc4c23)c1]

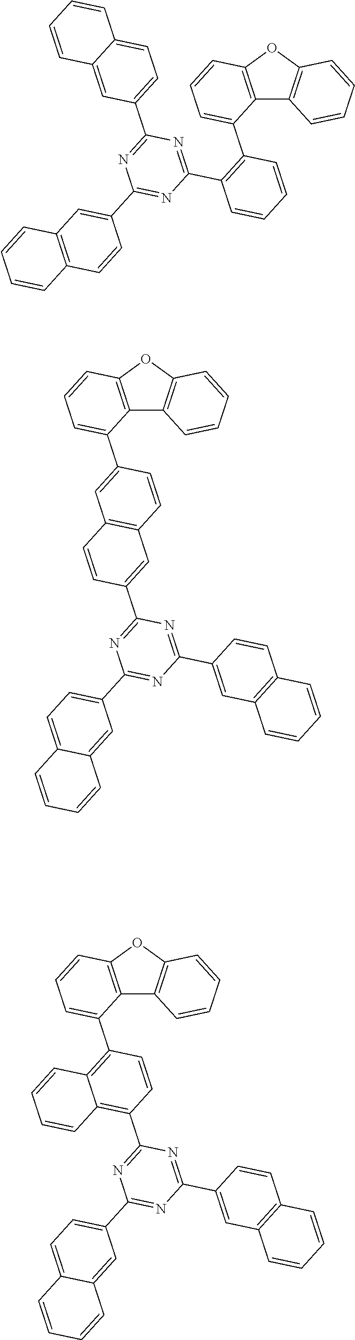 [SMILES: c1ccc(-c2cccc3oc4ccccc4c23)c(-c2nc(-c3ccc4ccccc4c3)nc(-c3ccc4ccccc4c3)n2)c1 ; c1ccc2cc(-c3nc(-c4ccc5ccccc5c4)nc(-c4ccc5cc(-c6cccc7oc8ccccc8c67)ccc5c4)n3)ccc2c1 ; c1ccc2cc(-c3nc(-c4ccc5ccccc5c4)nc(-c4ccc(-c5cccc6oc7ccccc7c56)c5ccccc45)n3)ccc2c1]

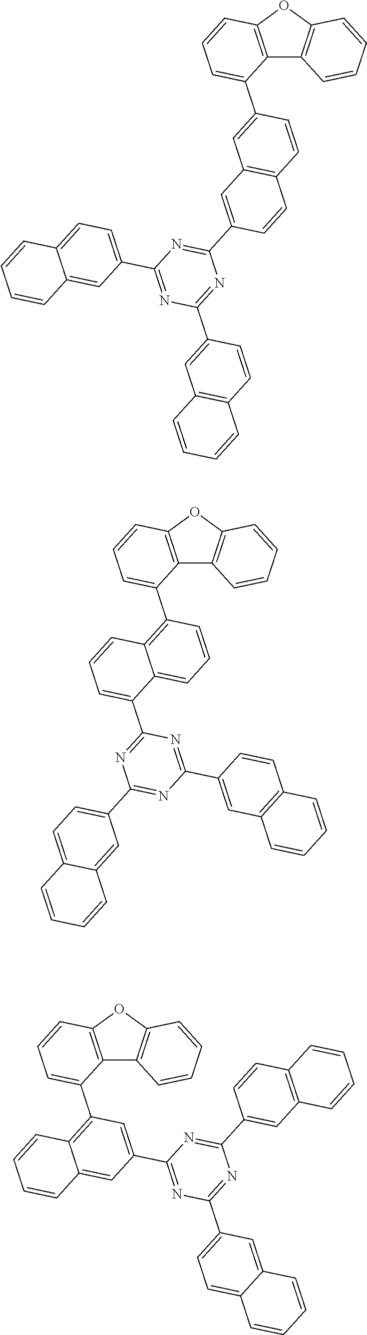 [SMILES: c1ccc2cc(-c3nc(-c4ccc5ccccc5c4)nc(-c4ccc5ccc(-c6cccc7oc8ccccc8c67)cc5c4)n3)ccc2c1 ; c1ccc2cc(-c3nc(-c4ccc5ccccc5c4)nc(-c4cccc5c(-c6cccc7oc8ccccc8c67)cccc45)n3)ccc2c1 ; c1ccc2cc(-c3nc(-c4ccc5ccccc5c4)nc(-c4cc(-c5cccc6oc7ccccc7c56)c5ccccc5c4)n3)ccc2c1]

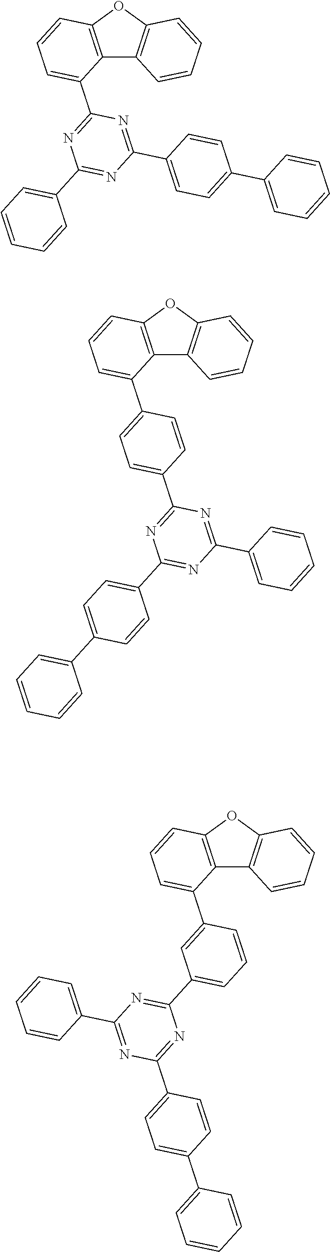 [SMILES: c1ccc(-c2ccc(-c3nc(-c4ccccc4)nc(-c4cccc5oc6ccccc6c45)n3)cc2)cc1 ; c1ccc(-c2ccc(-c3nc(-c4ccccc4)nc(-c4ccc(-c5cccc6oc7ccccc7c56)cc4)n3)cc2)cc1 ; c1ccc(-c2ccc(-c3nc(-c4ccccc4)nc(-c4cccc(-c5cccc6oc7ccccc7c56)c4)n3)cc2)cc1]

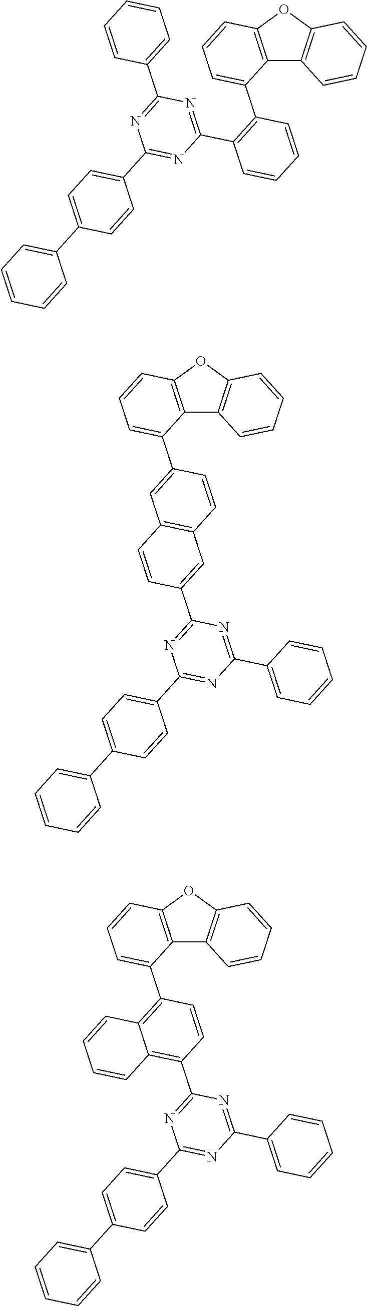 [SMILES: c1ccc(-c2ccc(-c3nc(-c4ccccc4)nc(-c4ccccc4-c4cccc5oc6ccccc6c45)n3)cc2)cc1 ; c1ccc(-c2ccc(-c3nc(-c4ccccc4)nc(-c4ccc5cc(-c6cccc7oc8ccccc8c67)ccc5c4)n3)cc2)cc1 ; c1ccc(-c2ccc(-c3nc(-c4ccccc4)nc(-c4ccc(-c5cccc6oc7ccccc7c56)c5ccccc45)n3)cc2)cc1]

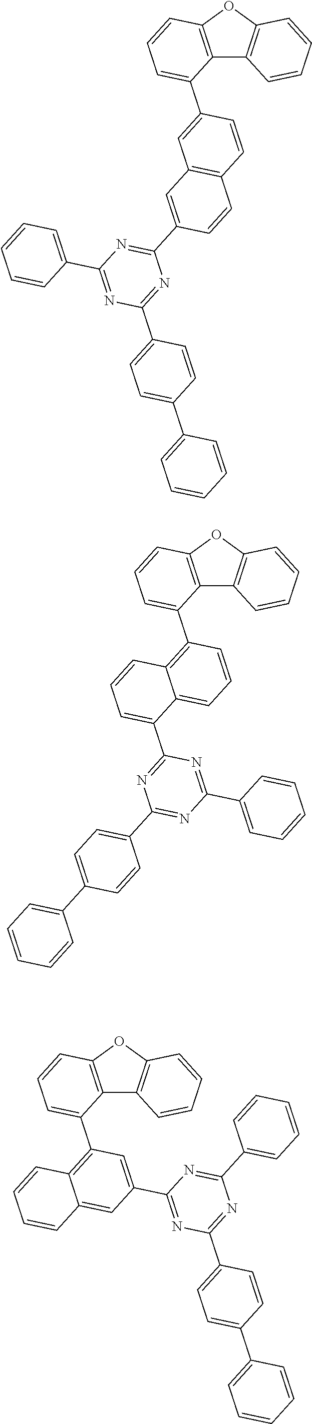

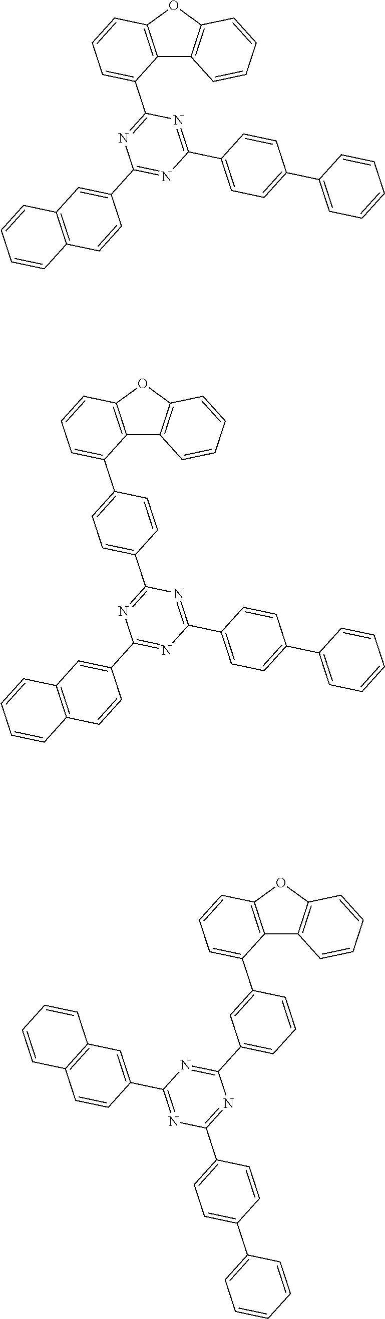 [SMILES: c1ccc(-c2ccc(-c3nc(-c4ccc5ccccc5c4)nc(-c4cccc5oc6ccccc6c45)n3)cc2)cc1 ; c1ccc(-c2ccc(-c3nc(-c4ccc(-c5cccc6oc7ccccc7c56)cc4)nc(-c4ccc5ccccc5c4)n3)cc2)cc1 ; c1ccc(-c2ccc(-c3nc(-c4cccc(-c5cccc6oc7ccccc7c56)c4)nc(-c4ccc5ccccc5c4)n3)cc2)cc1]

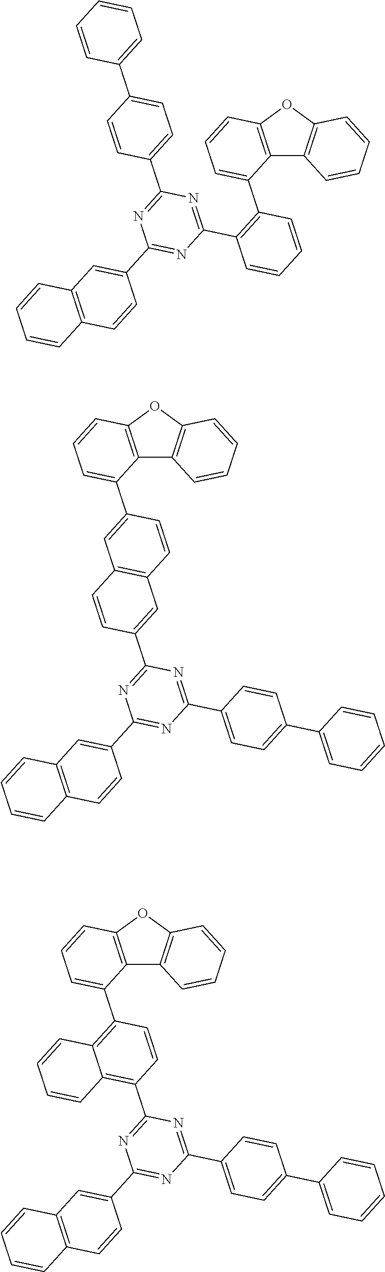 [SMILES: c1ccc(-c2ccc(-c3nc(-c4ccc5ccccc5c4)nc(-c4ccccc4-c4cccc5oc6ccccc6c45)n3)cc2)cc1 ; c1ccc(-c2ccc(-c3nc(-c4ccc5ccccc5c4)nc(-c4ccc5cc(-c6cccc7oc8ccccc8c67)ccc5c4)n3)cc2)cc1 ; c1ccc(-c2ccc(-c3nc(-c4ccc5ccccc5c4)nc(-c4ccc(-c5cccc6oc7ccccc7c56)c5ccccc45)n3)cc2)cc1]

[chemical structure]

[chemical structure]

[chemical structure]

[chemical structure]

[chemical structure]

[chemical structure]

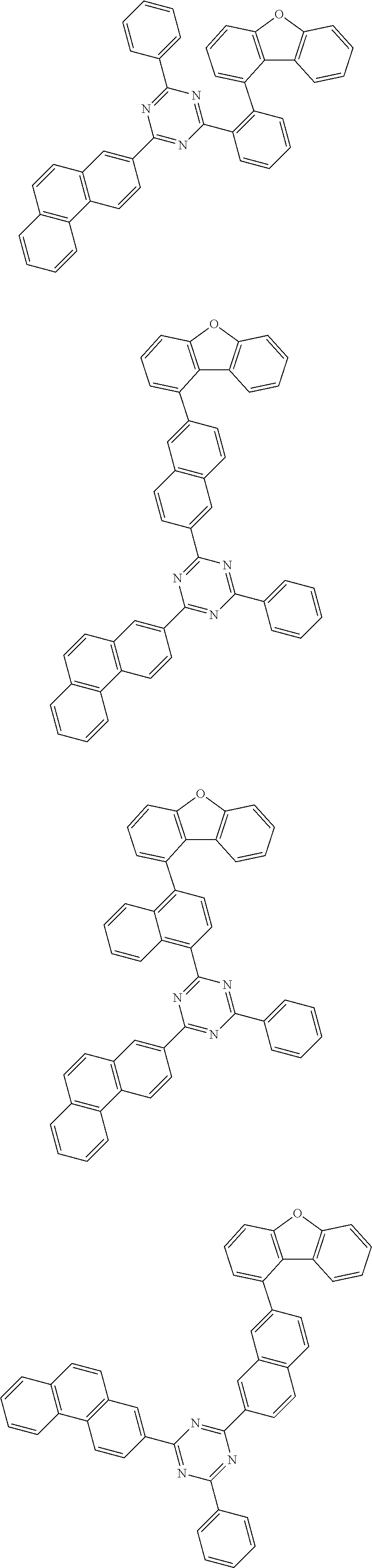 [SMILES: c1ccc(-c2nc(-c3ccc4c(ccc5ccccc54)c3)nc(-c3ccccc3-c3cccc4oc5ccccc5c34)n2)cc1 ; c1ccc(-c2nc(-c3ccc4cc(-c5cccc6oc7ccccc7c56)ccc4c3)nc(-c3ccc4c(ccc5ccccc54)c3)n2)cc1 ; c1ccc(-c2nc(-c3ccc4c(ccc5ccccc54)c3)nc(-c3ccc(-c4cccc5oc6ccccc6c45)c4ccccc34)n2)cc1 ; c1ccc(-c2nc(-c3ccc4ccc(-c5cccc6oc7ccccc7c56)cc4c3)nc(-c3ccc4c(ccc5ccccc54)c3)n2)cc1]

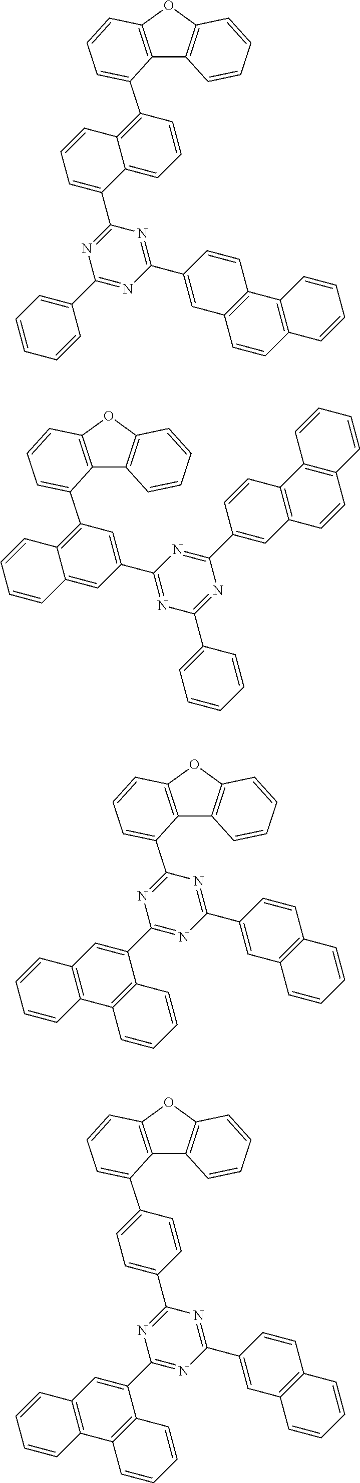 [SMILES: c1ccc(-c2nc(-c3ccc4c(ccc5ccccc54)c3)nc(-c3cccc4c(-c5cccc6oc7ccccc7c56)cccc34)n2)cc1 ; c1ccc(-c2nc(-c3cc(-c4cccc5oc6ccccc6c45)c4ccccc4c3)nc(-c3ccc4c(ccc5ccccc54)c3)n2)cc1 ; c1ccc2cc(-c3nc(-c4cc5ccccc5c5ccccc45)nc(-c4cccc5oc6ccccc6c45)n3)ccc2c1 ; c1ccc2cc(-c3nc(-c4ccc(-c5cccc6oc7ccccc7c56)cc4)nc(-c4cc5ccccc5c5ccccc45)n3)ccc2c1]

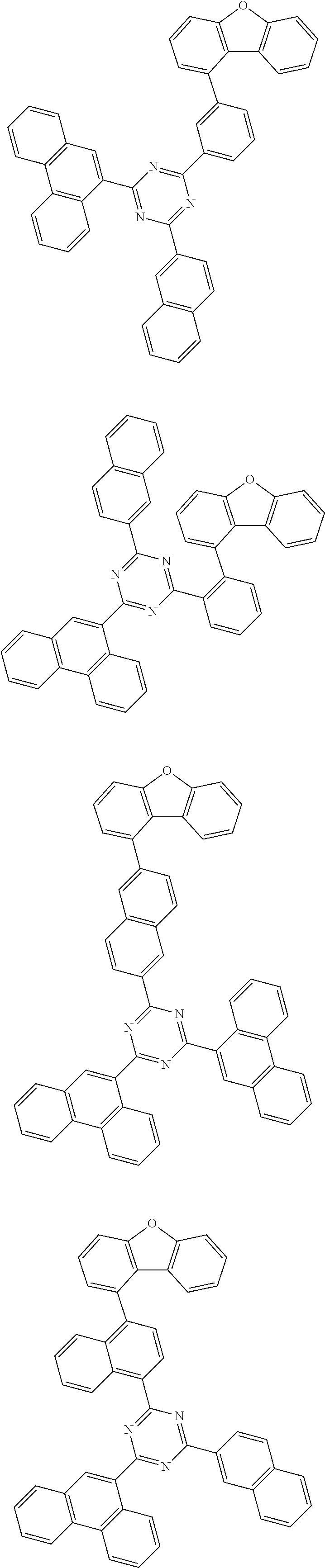 [SMILES: c1cc(-c2nc(-c3ccc4ccccc4c3)nc(-c3cc4ccccc4c4ccccc34)n2)cc(-c2cccc3oc4ccccc4c23)c1 ; c1ccc(-c2cccc3oc4ccccc4c23)c(-c2nc(-c3ccc4ccccc4c3)nc(-c3cc4ccccc4c4ccccc34)n2)c1 ; c1ccc2c(c1)cc(-c1nc(-c3ccc4cc(-c5cccc6oc7ccccc7c56)ccc4c3)nc(-c3cc4ccccc4c4ccccc34)n1)c1ccccc12 ; c1ccc2cc(-c3nc(-c4ccc(-c5cccc6oc7ccccc7c56)c5ccccc45)nc(-c4cc5ccccc5c5ccccc45)n3)ccc2c1]

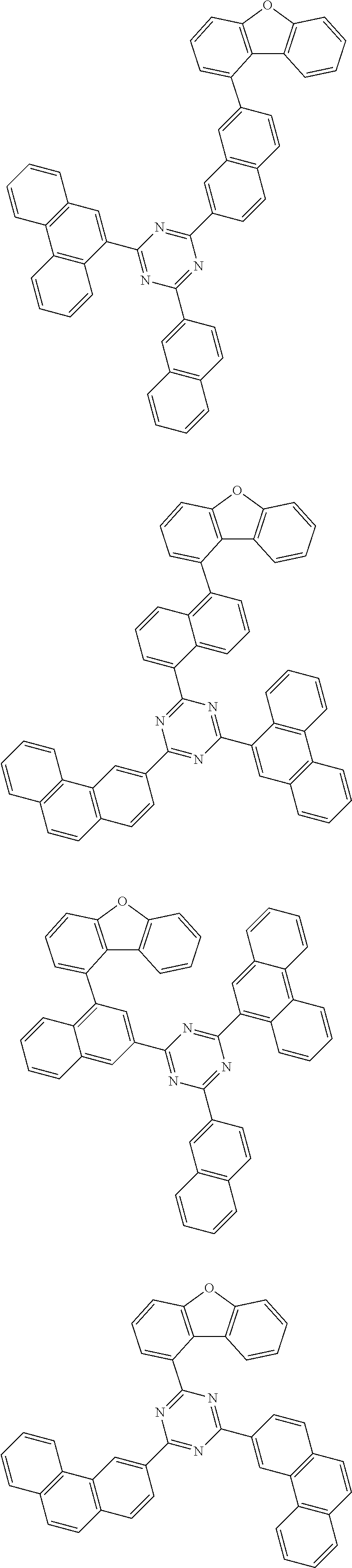 [SMILES: c1ccc2cc(-c3nc(-c4ccc5ccc(-c6cccc7oc8ccccc8c67)cc5c4)nc(-c4cc5ccccc5c5ccccc45)n3)ccc2c1 ; c1ccc2c(c1)ccc1ccc(-c3nc(-c4cccc5c(-c6cccc7oc8ccccc8c67)cccc45)nc(-c4cc5ccccc5c5ccccc45)n3)cc12 ; c1ccc2cc(-c3nc(-c4cc(-c5cccc6oc7ccccc7c56)c5ccccc5c4)nc(-c4cc5ccccc5c5ccccc45)n3)ccc2c1 ; c1ccc2c(c1)ccc1ccc(-c3nc(-c4ccc5ccc6ccccc6c5c4)nc(-c4cccc5oc6ccccc6c45)n3)cc12]

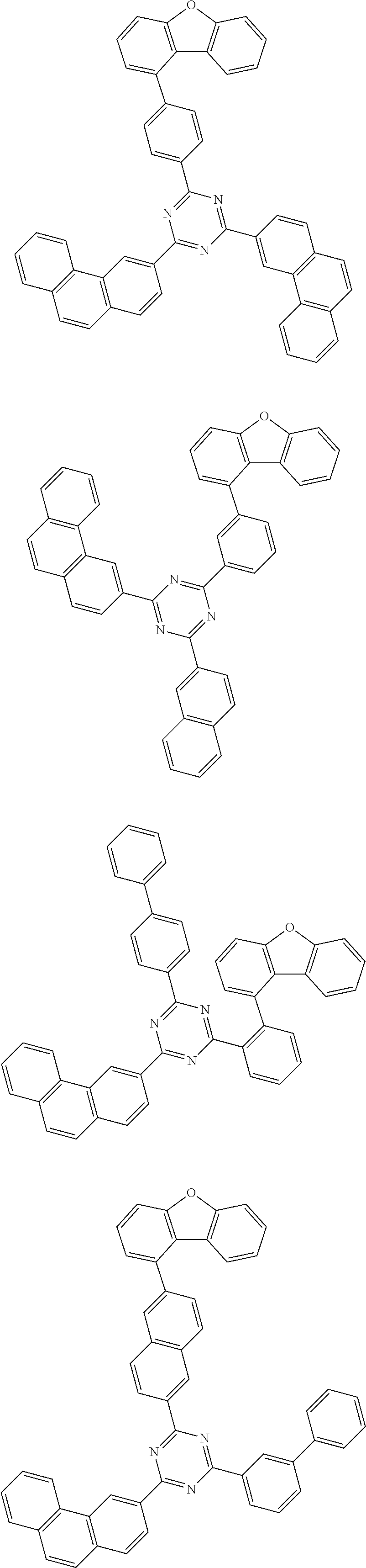 [SMILES: c1ccc2c(c1)ccc1ccc(-c3nc(-c4ccc(-c5cccc6oc7ccccc7c56)cc4)nc(-c4ccc5ccc6ccccc6c5c4)n3)cc12 ; c1cc(-c2nc(-c3ccc4ccccc4c3)nc(-c3ccc4ccc5ccccc5c4c3)n2)cc(-c2cccc3oc4ccccc4c23)c1 ; c1ccc(-c2ccc(-c3nc(-c4ccc5ccc6ccccc6c5c4)nc(-c4ccccc4-c4cccc5oc6ccccc6c45)n3)cc2)cc1 ; c1ccc(-c2cccc(-c3nc(-c4ccc5cc(-c6cccc7oc8ccccc8c67)ccc5c4)nc(-c4ccc5ccc6ccccc6c5c4)n3)c2)cc1]

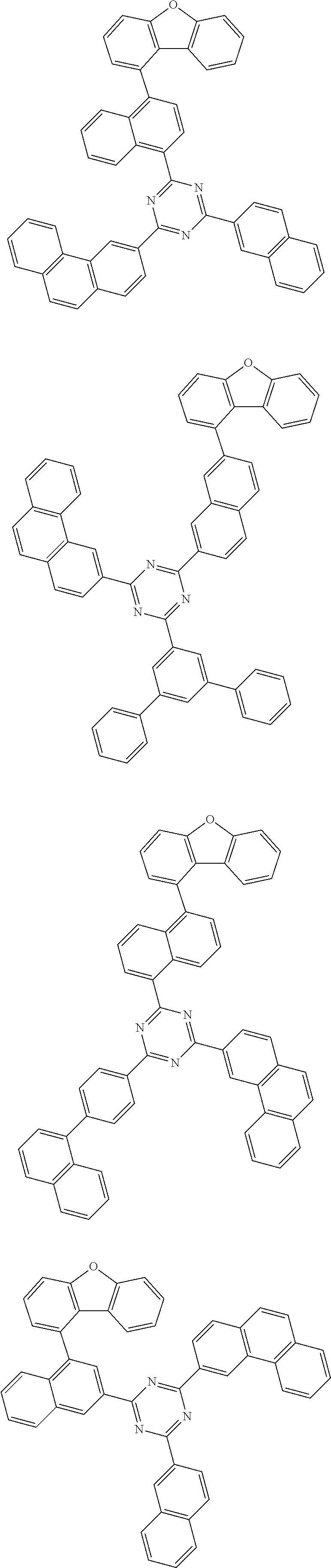 [SMILES: c1ccc2cc(-c3nc(-c4ccc5ccc6ccccc6c5c4)nc(-c4ccc(-c5cccc6oc7ccccc7c56)c5ccccc45)n3)ccc2c1 ; c1ccc(-c2cc(-c3ccccc3)cc(-c3nc(-c4ccc5ccc(-c6cccc7oc8ccccc8c67)cc5c4)nc(-c4ccc5ccc6ccccc6c5c4)n3)c2)cc1 ; c1ccc2c(-c3ccc(-c4nc(-c5ccc6ccc7ccccc7c6c5)nc(-c5cccc6c(-c7cccc8oc9ccccc9c78)cccc56)n4)cc3)cccc2c1 ; c1ccc2cc(-c3nc(-c4cc(-c5cccc6oc7ccccc7c56)c5ccccc5c4)nc(-c4ccc5ccc6ccccc6c5c4)n3)ccc2c1]

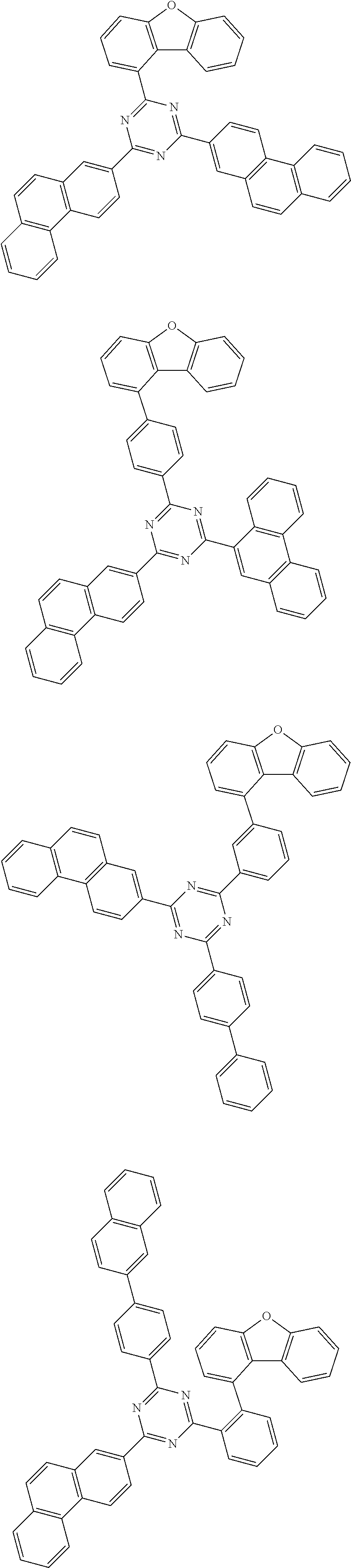 [SMILES: c1ccc2c(c1)ccc1cc(-c3nc(-c4ccc5c(ccc6ccccc65)c4)nc(-c4cccc5oc6ccccc6c45)n3)ccc12 ; c1ccc2c(c1)ccc1cc(-c3nc(-c4ccc(-c5cccc6oc7ccccc7c56)cc4)nc(-c4cc5ccccc5c5ccccc45)n3)ccc12 ; c1ccc(-c2ccc(-c3nc(-c4cccc(-c5cccc6oc7ccccc7c56)c4)nc(-c4ccc5c(ccc6ccccc65)c4)n3)cc2)cc1 ; c1ccc(-c2cccc3oc4ccccc4c23)c(-c2nc(-c3ccc(-c4ccc5ccccc5c4)cc3)nc(-c3ccc4c(ccc5ccccc54)c3)n2)c1]

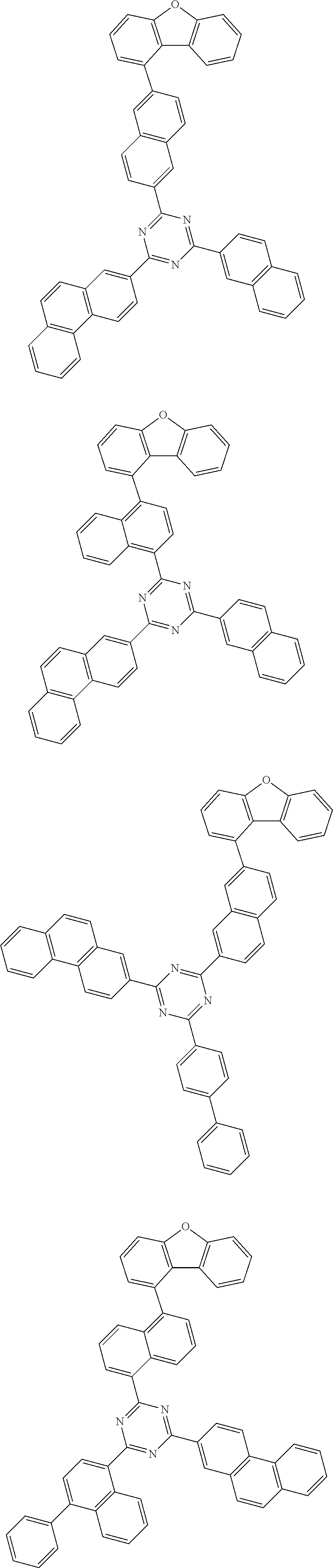 [SMILES: c1ccc2cc(-c3nc(-c4ccc5cc(-c6cccc7oc8ccccc8c67)ccc5c4)nc(-c4ccc5c(ccc6ccccc65)c4)n3)ccc2c1 ; c1ccc2cc(-c3nc(-c4ccc5c(ccc6ccccc65)c4)nc(-c4ccc(-c5cccc6oc7ccccc7c56)c5ccccc45)n3)ccc2c1 ; c1ccc(-c2ccc(-c3nc(-c4ccc5ccc(-c6cccc7oc8ccccc8c67)cc5c4)nc(-c4ccc5c(ccc6ccccc65)c4)n3)cc2)cc1 ; c1ccc(-c2ccc(-c3nc(-c4ccc5c(ccc6ccccc65)c4)nc(-c4cccc5c(-c6cccc7oc8ccccc8c67)cccc45)n3)c3ccccc23)cc1]

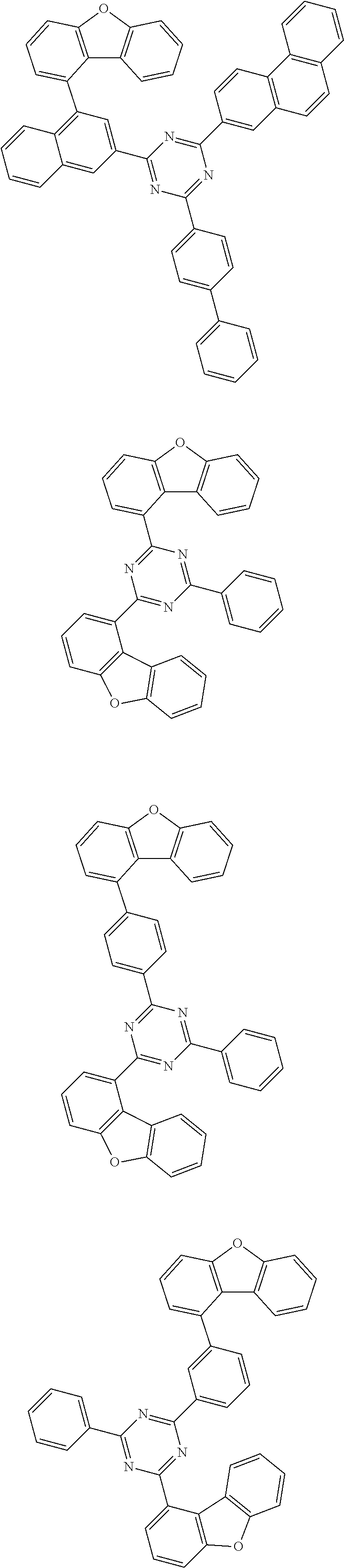 [SMILES: c1ccc(-c2ccc(-c3nc(-c4cc(-c5cccc6oc7ccccc7c56)c5ccccc5c4)nc(-c4ccc5c(ccc6ccccc65)c4)n3)cc2)cc1 ; c1ccc(-c2nc(-c3cccc4oc5ccccc5c34)nc(-c3cccc4oc5ccccc5c34)n2)cc1 ; c1ccc(-c2nc(-c3ccc(-c4cccc5oc6ccccc6c45)cc3)nc(-c3cccc4oc5ccccc5c34)n2)cc1 ; c1ccc(-c2nc(-c3cccc(-c4cccc5oc6ccccc6c45)c3)nc(-c3cccc4oc5ccccc5c34)n2)cc1]

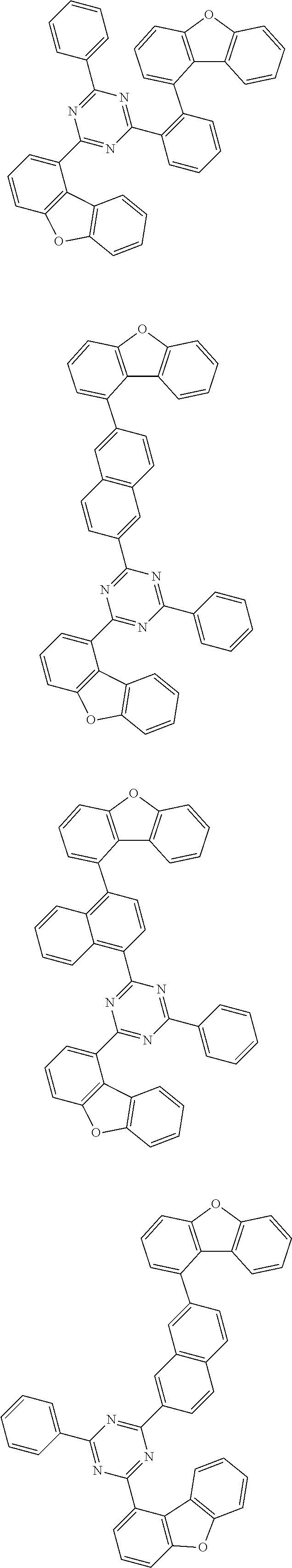 [SMILES: c1ccc(-c2nc(-c3ccccc3-c3cccc4oc5ccccc5c34)nc(-c3cccc4oc5ccccc5c34)n2)cc1 ; c1ccc(-c2nc(-c3ccc4cc(-c5cccc6oc7ccccc7c56)ccc4c3)nc(-c3cccc4oc5ccccc5c34)n2)cc1 ; c1ccc(-c2nc(-c3ccc(-c4cccc5oc6ccccc6c45)c4ccccc34)nc(-c3cccc4oc5ccccc5c34)n2)cc1 ; c1ccc(-c2nc(-c3ccc4ccc(-c5cccc6oc7ccccc7c56)cc4c3)nc(-c3cccc4oc5ccccc5c34)n2)cc1]

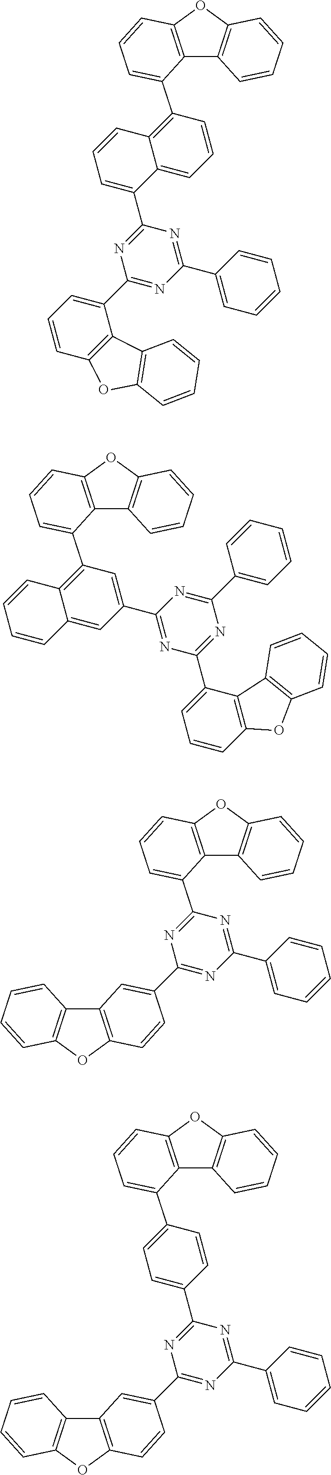 [SMILES: c1ccc(-c2nc(-c3cccc4c(-c5cccc6oc7ccccc7c56)cccc34)nc(-c3cccc4oc5ccccc5c34)n2)cc1 ; c1ccc(-c2nc(-c3cc(-c4cccc5oc6ccccc6c45)c4ccccc4c3)nc(-c3cccc4oc5ccccc5c34)n2)cc1 ; c1ccc(-c2nc(-c3ccc4oc5ccccc5c4c3)nc(-c3cccc4oc5ccccc5c34)n2)cc1 ; c1ccc(-c2nc(-c3ccc(-c4cccc5oc6ccccc6c45)cc3)nc(-c3ccc4oc5ccccc5c4c3)n2)cc1]

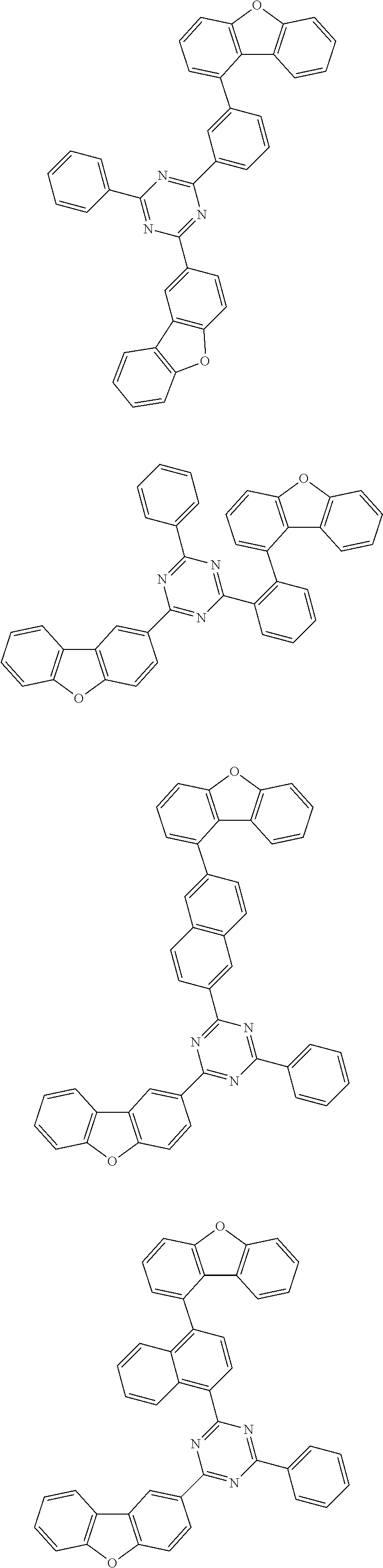 [SMILES: c1ccc(-c2nc(-c3cccc(-c4cccc5oc6ccccc6c45)c3)nc(-c3ccc4oc5ccccc5c4c3)n2)cc1 ; c1ccc(-c2nc(-c3ccc4oc5ccccc5c4c3)nc(-c3ccccc3-c3cccc4oc5ccccc5c34)n2)cc1 ; c1ccc(-c2nc(-c3ccc4cc(-c5cccc6oc7ccccc7c56)ccc4c3)nc(-c3ccc4oc5ccccc5c4c3)n2)cc1 ; c1ccc(-c2nc(-c3ccc4oc5ccccc5c4c3)nc(-c3ccc(-c4cccc5oc6ccccc6c45)c4ccccc34)n2)cc1]

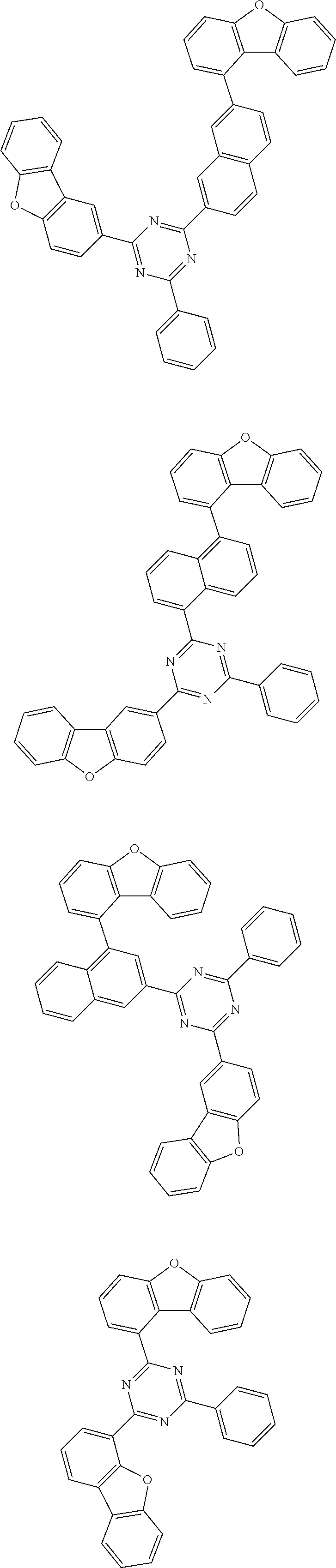 [SMILES: c1ccc(-c2nc(-c3ccc4ccc(-c5cccc6oc7ccccc7c56)cc4c3)nc(-c3ccc4oc5ccccc5c4c3)n2)cc1 ; c1ccc(-c2nc(-c3ccc4oc5ccccc5c4c3)nc(-c3cccc4c(-c5cccc6oc7ccccc7c56)cccc34)n2)cc1 ; c1ccc(-c2nc(-c3cc(-c4cccc5oc6ccccc6c45)c4ccccc4c3)nc(-c3ccc4oc5ccccc5c4c3)n2)cc1 ; c1ccc(-c2nc(-c3cccc4c3oc3ccccc34)nc(-c3cccc4oc5ccccc5c34)n2)cc1]

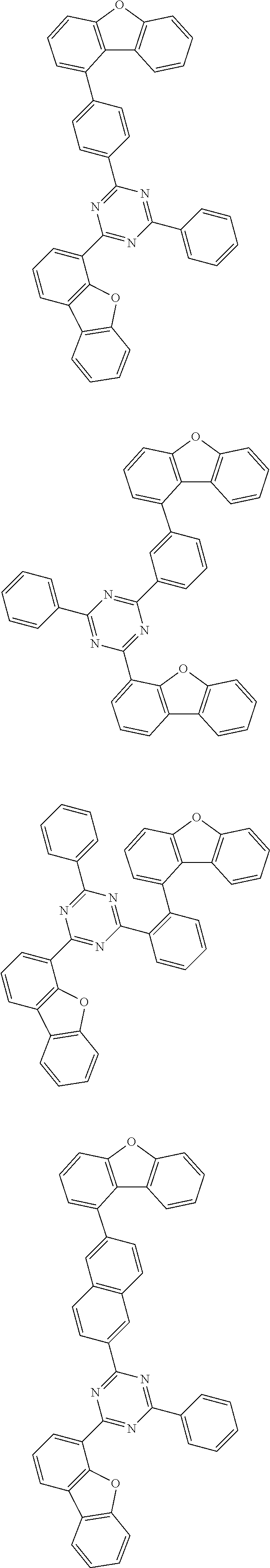 [SMILES: c1ccc(-c2nc(-c3ccc(-c4cccc5oc6ccccc6c45)cc3)nc(-c3cccc4c3oc3ccccc34)n2)cc1 ; c1ccc(-c2nc(-c3cccc(-c4cccc5oc6ccccc6c45)c3)nc(-c3cccc4c3oc3ccccc34)n2)cc1 ; c1ccc(-c2nc(-c3ccccc3-c3cccc4oc5ccccc5c34)nc(-c3cccc4c3oc3ccccc34)n2)cc1 ; c1ccc(-c2nc(-c3ccc4cc(-c5cccc6oc7ccccc7c56)ccc4c3)nc(-c3cccc4c3oc3ccccc34)n2)cc1]

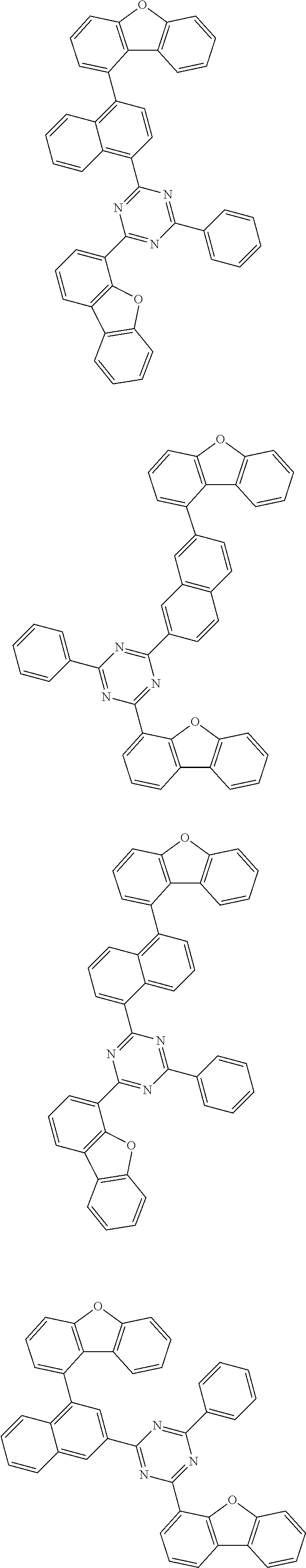 [SMILES: c1ccc(-c2nc(-c3ccc(-c4cccc5oc6ccccc6c45)c4ccccc34)nc(-c3cccc4c3oc3ccccc34)n2)cc1 ; c1ccc(-c2nc(-c3ccc4ccc(-c5cccc6oc7ccccc7c56)cc4c3)nc(-c3cccc4c3oc3ccccc34)n2)cc1 ; c1ccc(-c2nc(-c3cccc4c(-c5cccc6oc7ccccc7c56)cccc34)nc(-c3cccc4c3oc3ccccc34)n2)cc1 ; c1ccc(-c2nc(-c3cc(-c4cccc5oc6ccccc6c45)c4ccccc4c3)nc(-c3cccc4c3oc3ccccc34)n2)cc1]

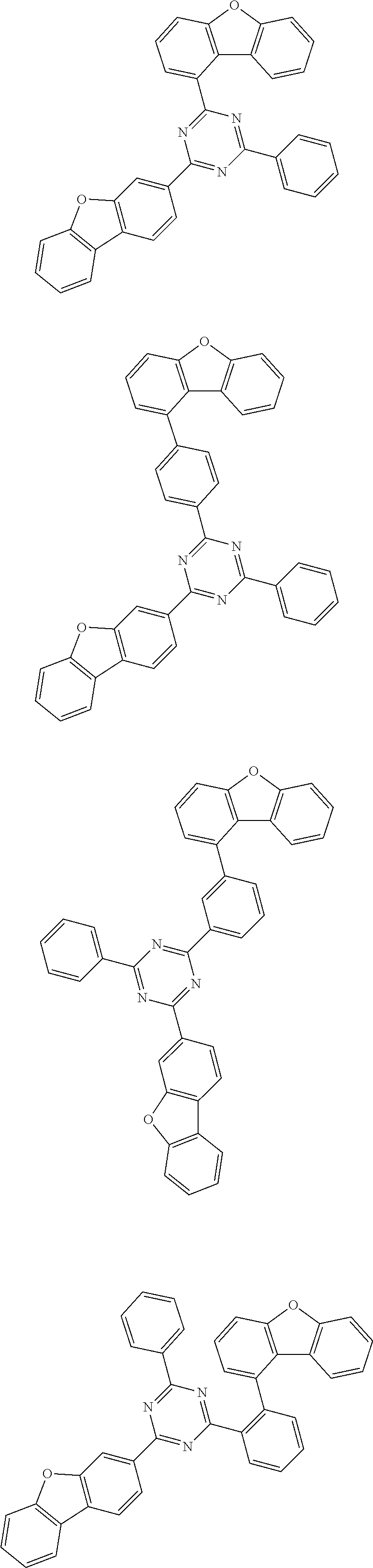 [SMILES: c1ccc(-c2nc(-c3ccc4c(c3)oc3ccccc34)nc(-c3cccc4oc5ccccc5c34)n2)cc1 ; c1ccc(-c2nc(-c3ccc(-c4cccc5oc6ccccc6c45)cc3)nc(-c3ccc4c(c3)oc3ccccc34)n2)cc1 ; c1ccc(-c2nc(-c3cccc(-c4cccc5oc6ccccc6c45)c3)nc(-c3ccc4c(c3)oc3ccccc34)n2)cc1 ; c1ccc(-c2nc(-c3ccc4c(c3)oc3ccccc34)nc(-c3ccccc3-c3cccc4oc5ccccc5c34)n2)cc1]

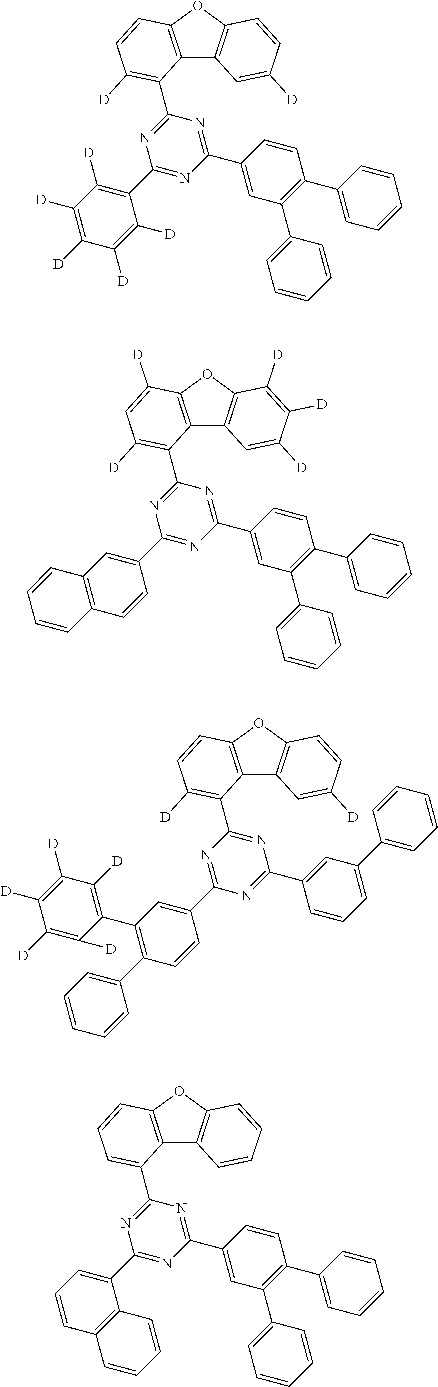 [SMILES: [2H]c1ccc2oc3ccc([2H])c(-c4nc(-c5ccc(-c6ccccc6)c(-c6ccccc6)c5)nc(-c5c([2H])c([2H])c([2H])c([2H])c5[2H])n4)c3c2c1 ; [2H]c1cc2c(oc3c([2H])cc([2H])c(-c4nc(-c5ccc(-c6ccccc6)c(-c6ccccc6)c5)nc(-c5ccc6ccccc6c5)n4)c32)c([2H])c1[2H] ; [2H]c1ccc2oc3ccc([2H])c(-c4nc(-c5cccc(-c6ccccc6)c5)nc(-c5ccc(-c6ccccc6)c(-c6c([2H])c([2H])c([2H])c([2H])c6[2H])c5)n4)c3c2c1 ; c1ccc(-c2ccc(-c3nc(-c4cccc5ccccc45)nc(-c4cccc5oc6ccccc6c45)n3)cc2-c2ccccc2)cc1]

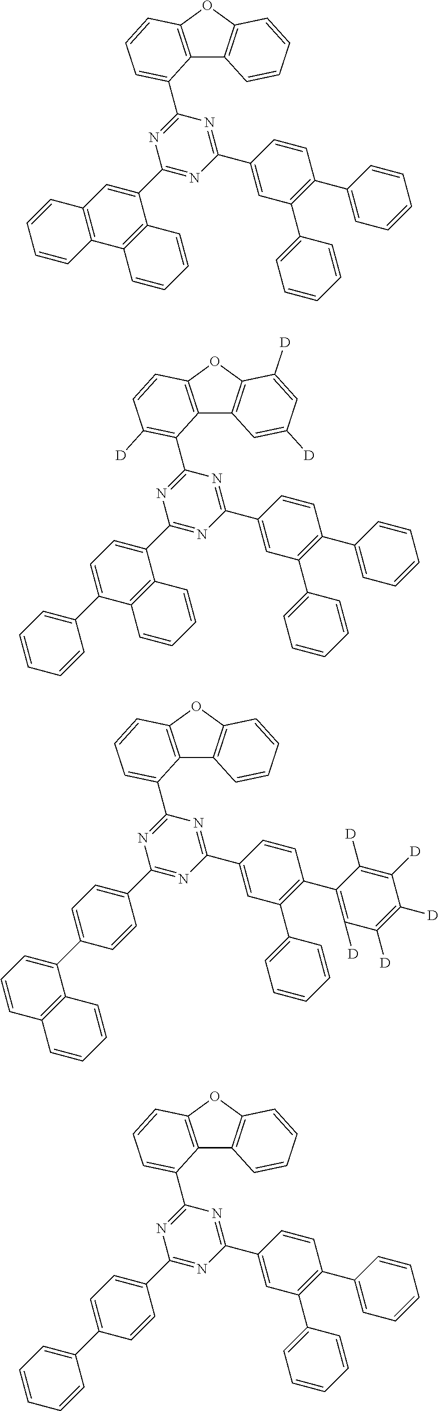 [SMILES: c1ccc(-c2ccc(-c3nc(-c4cc5ccccc5c5ccccc45)nc(-c4cccc5oc6ccccc6c45)n3)cc2-c2ccccc2)cc1 ; [2H]c1cc([2H])c2oc3ccc([2H])c(-c4nc(-c5ccc(-c6ccccc6)c(-c6ccccc6)c5)nc(-c5ccc(-c6ccccc6)c6ccccc56)n4)c3c2c1 ; [2H]c1c([2H])c([2H])c(-c2ccc(-c3nc(-c4ccc(-c5cccc6ccccc56)cc4)nc(-c4cccc5oc6ccccc6c45)n3)cc2-c2ccccc2)c([2H])c1[2H] ; c1ccc(-c2ccc(-c3nc(-c4ccc(-c5ccccc5)c(-c5ccccc5)c4)nc(-c4cccc5oc6ccccc6c45)n3)cc2)cc1]

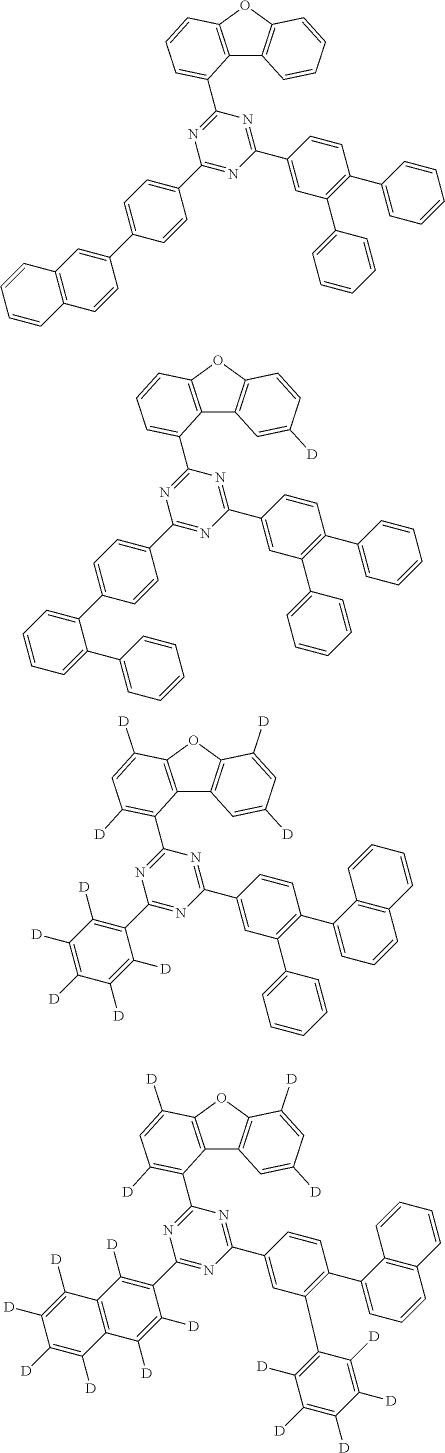

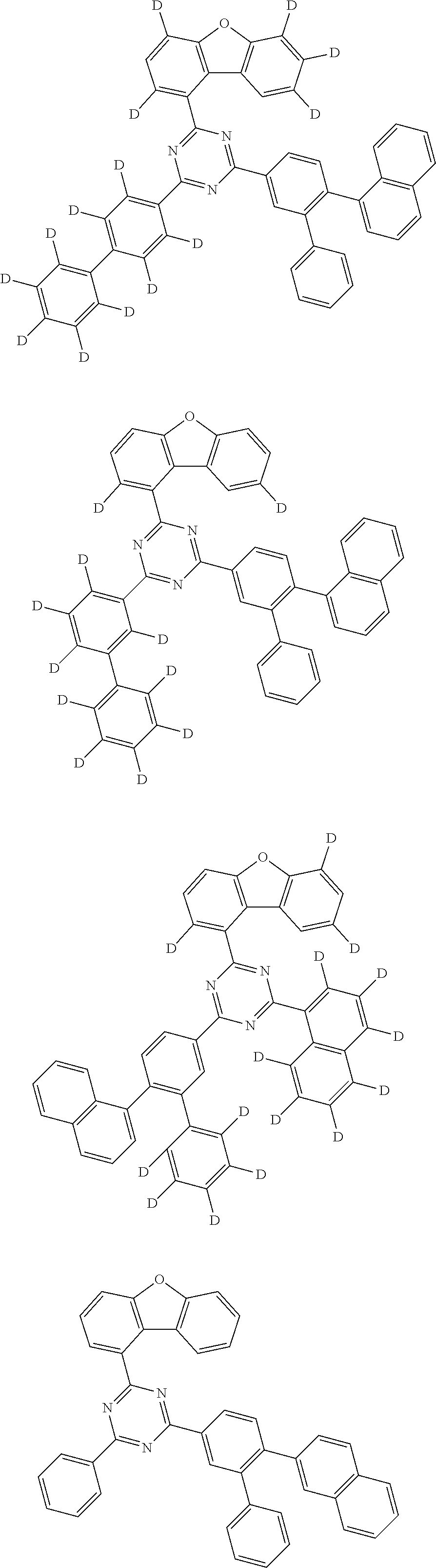

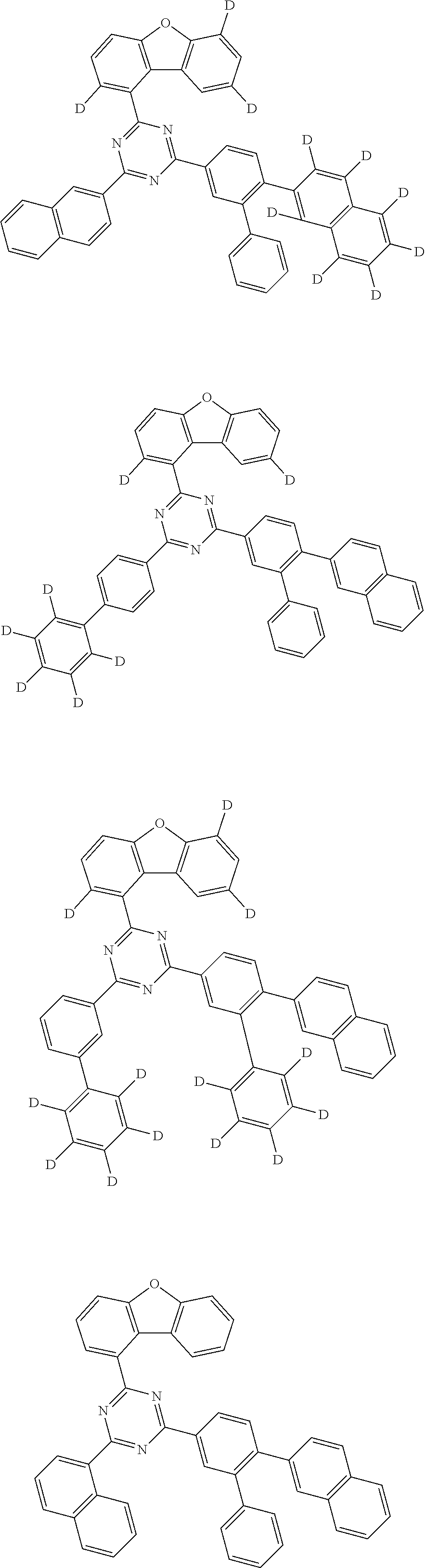

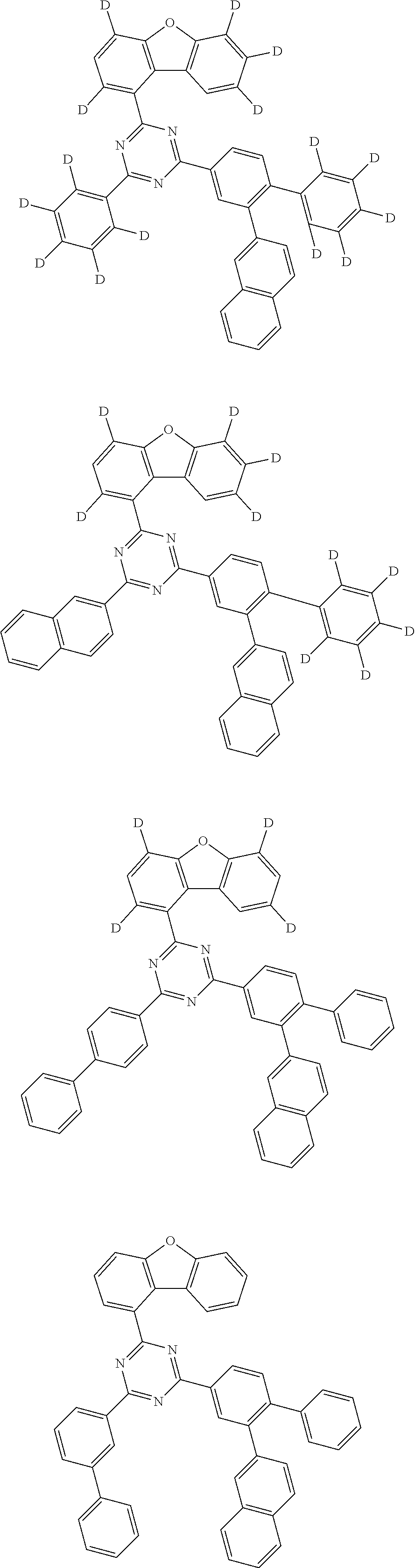

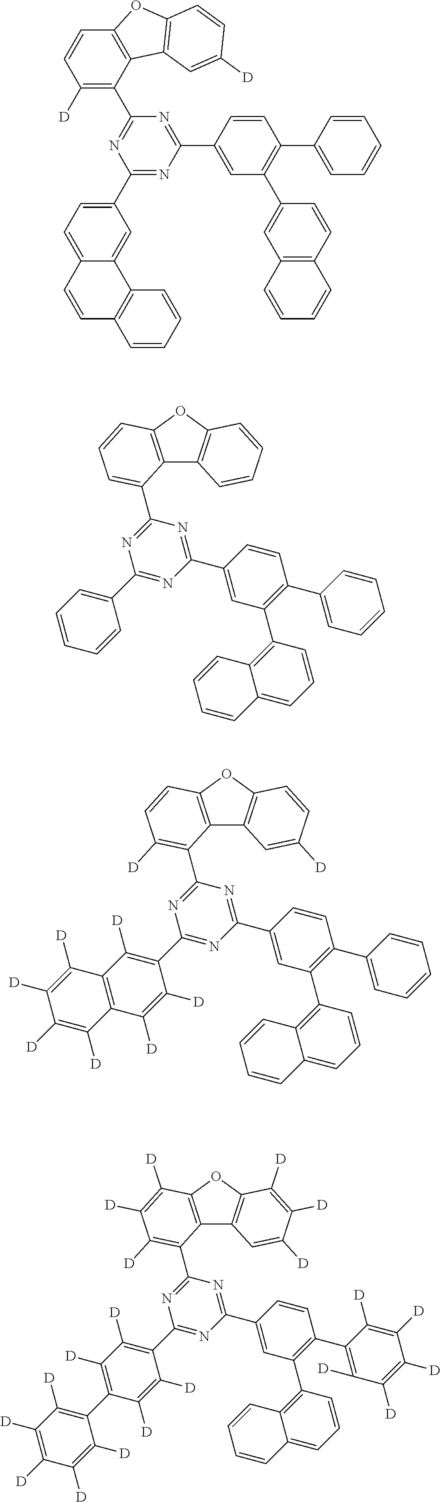

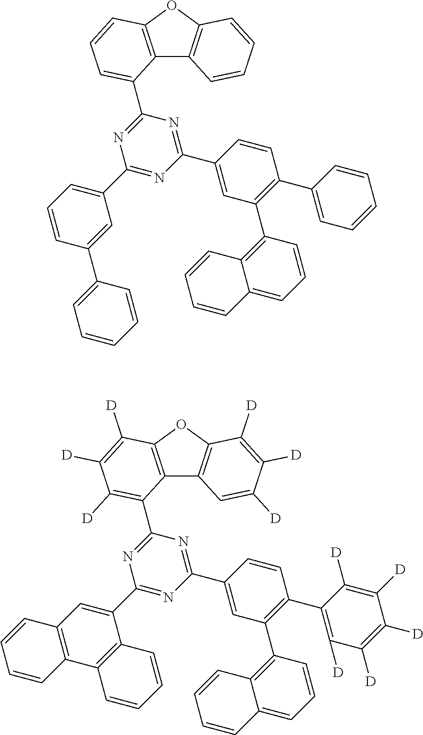 [SMILES: c1ccc(-c2cccc(-c3nc(-c4ccc(-c5ccccc5)c(-c5cccc6ccccc56)c4)nc(-c4cccc5oc6ccccc6c45)n3)c2)cc1 ; [2H]c1cc2c(oc3c([2H])c([2H])c([2H])c(-c4nc(-c5ccc(-c6c([2H])c([2H])c([2H])c([2H])c6[2H])c(-c6cccc7ccccc67)c5)nc(-c5cc6ccccc6c6ccccc56)n4)c32)c([2H])c1[2H]]

[chemical structure]

[chemical structure]

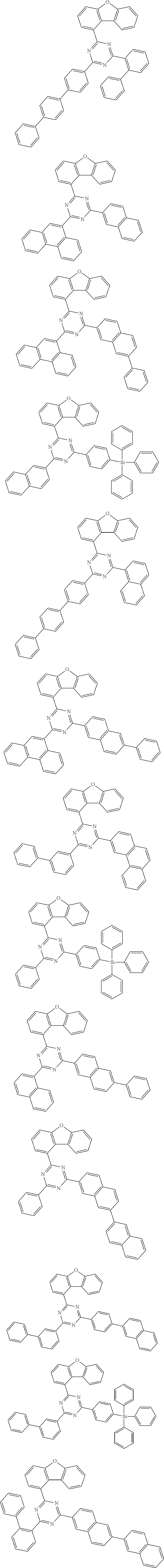

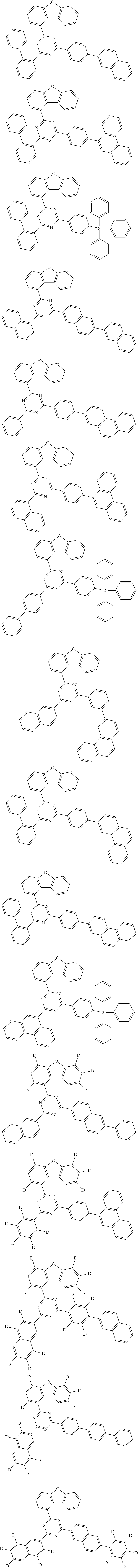

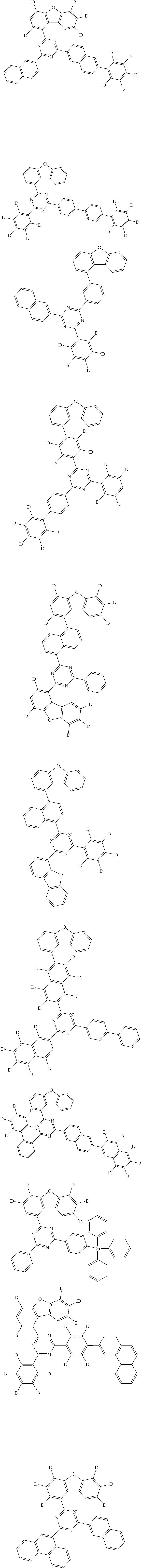

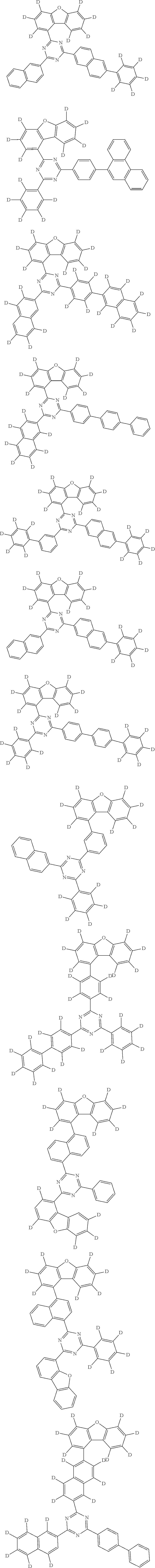

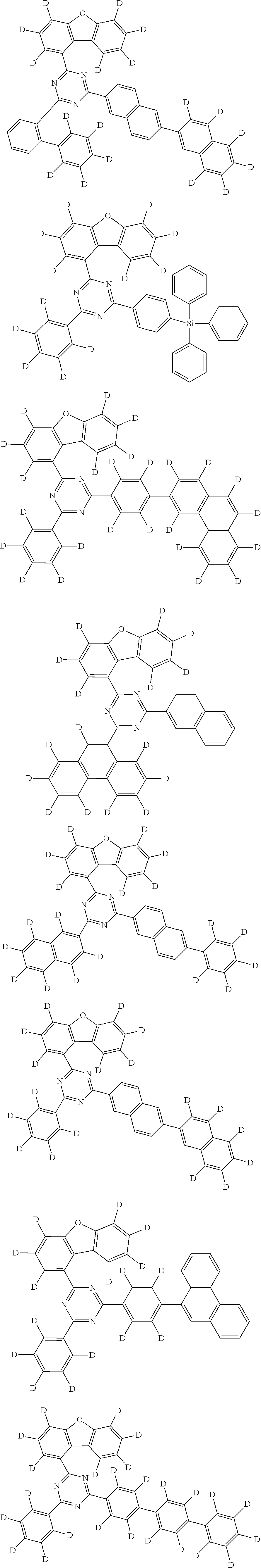

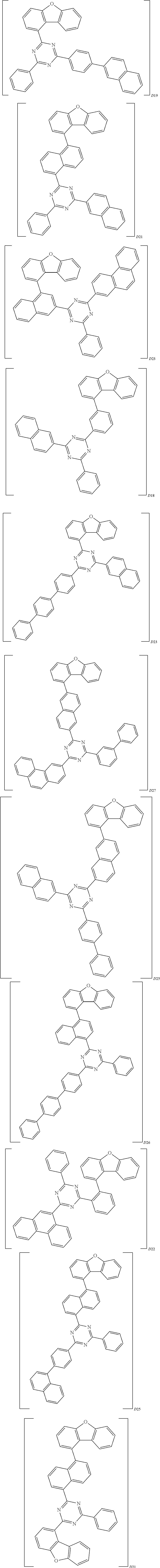

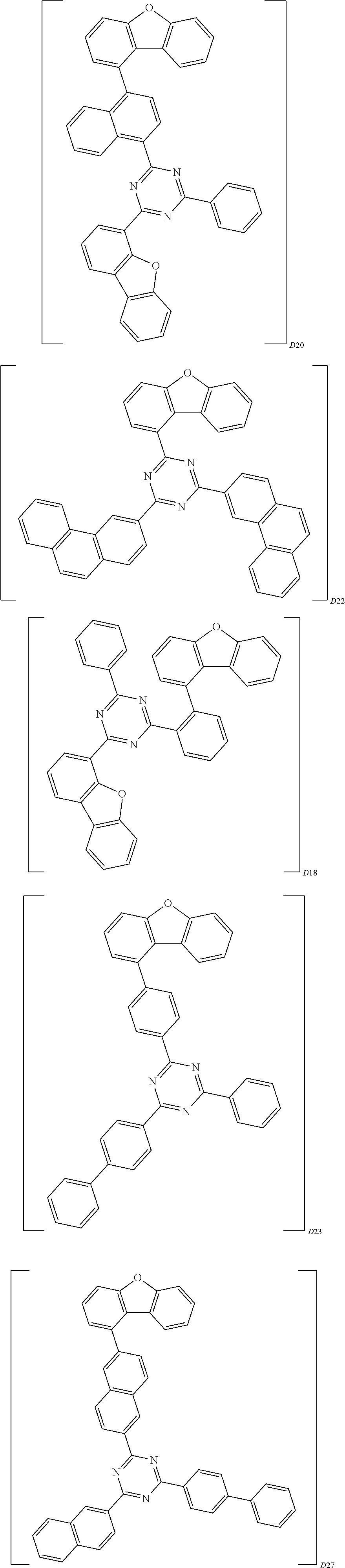

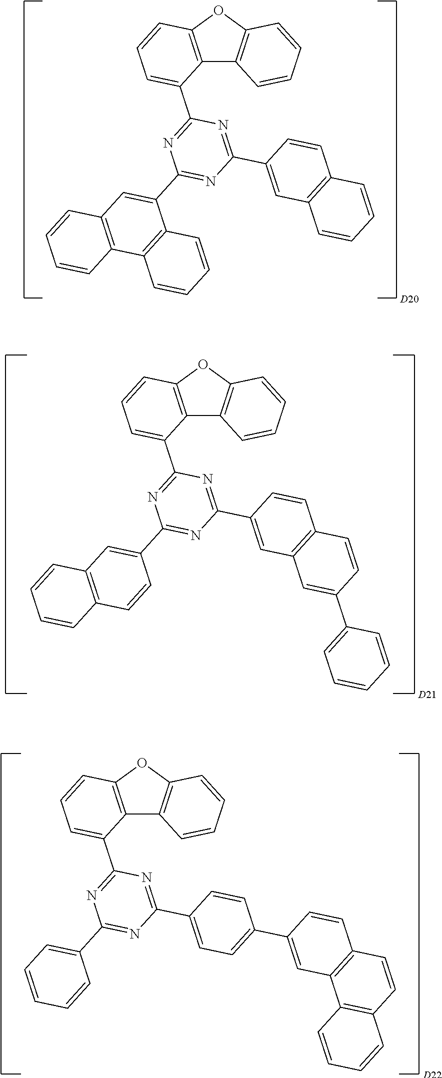

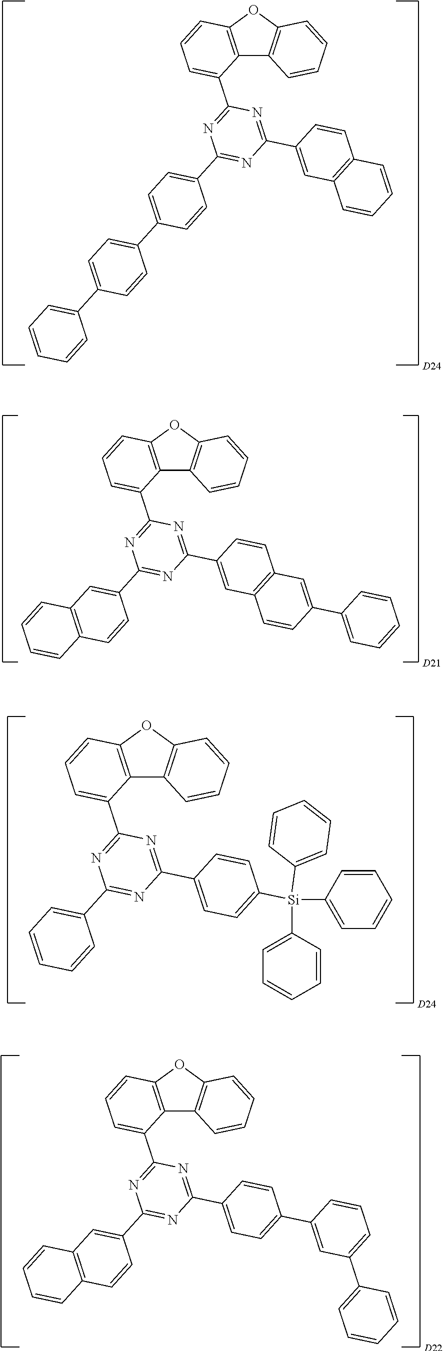

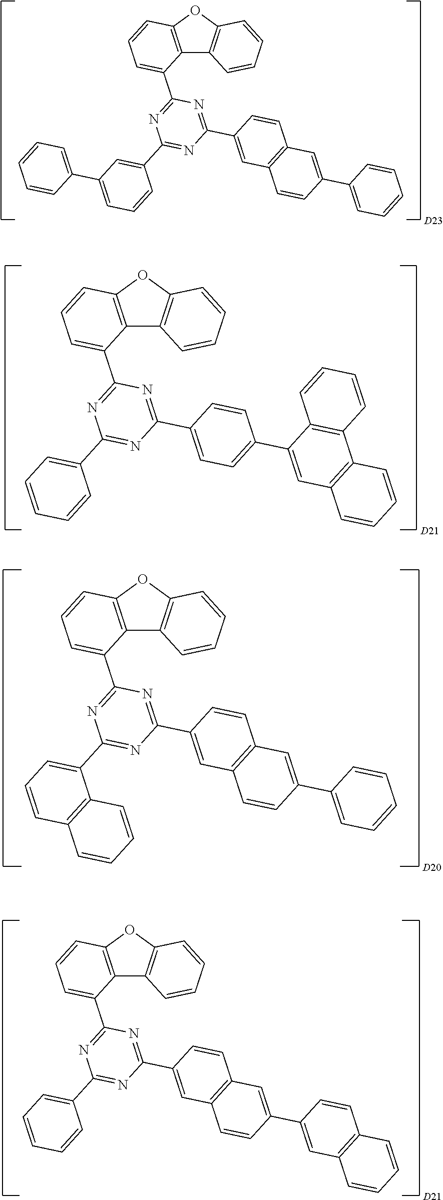

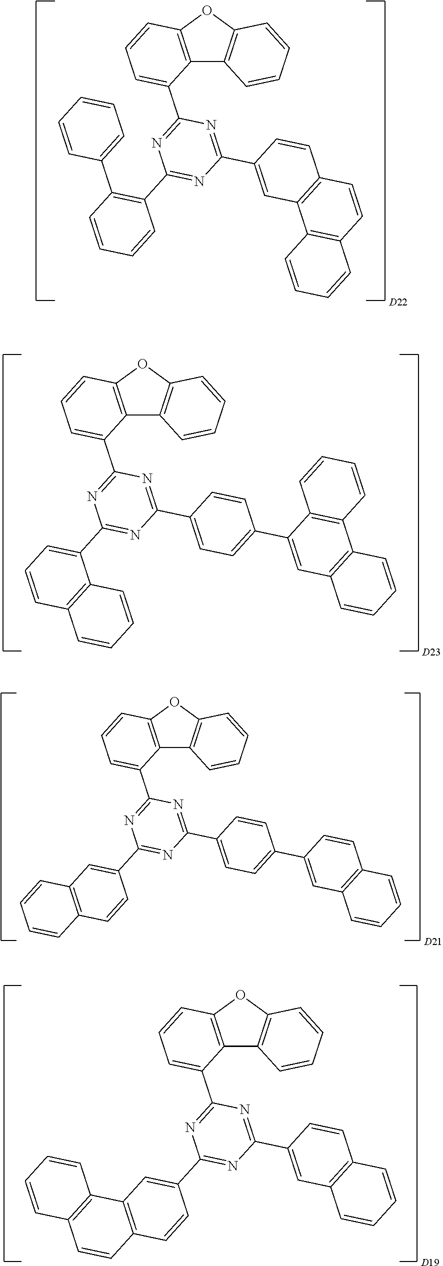

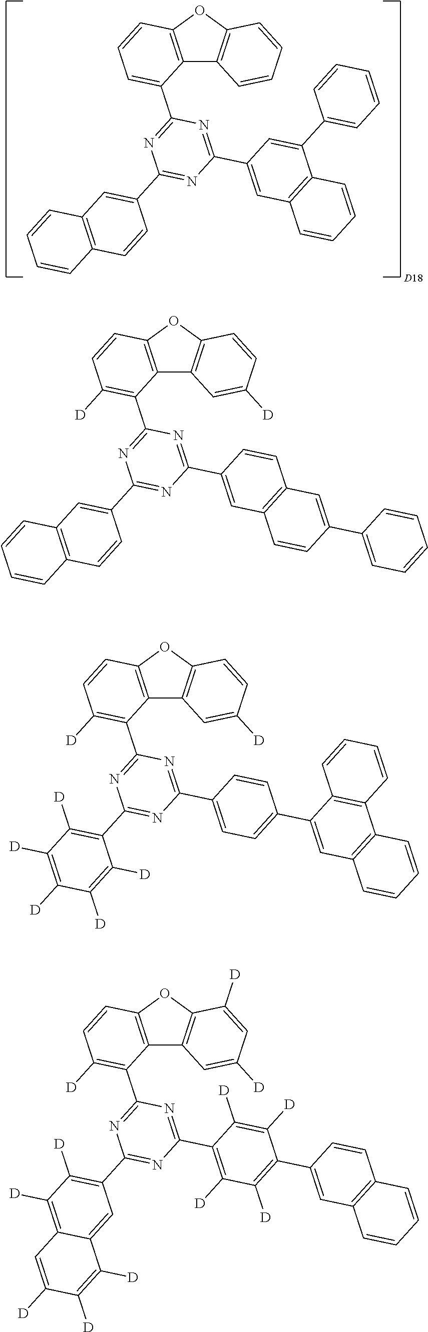

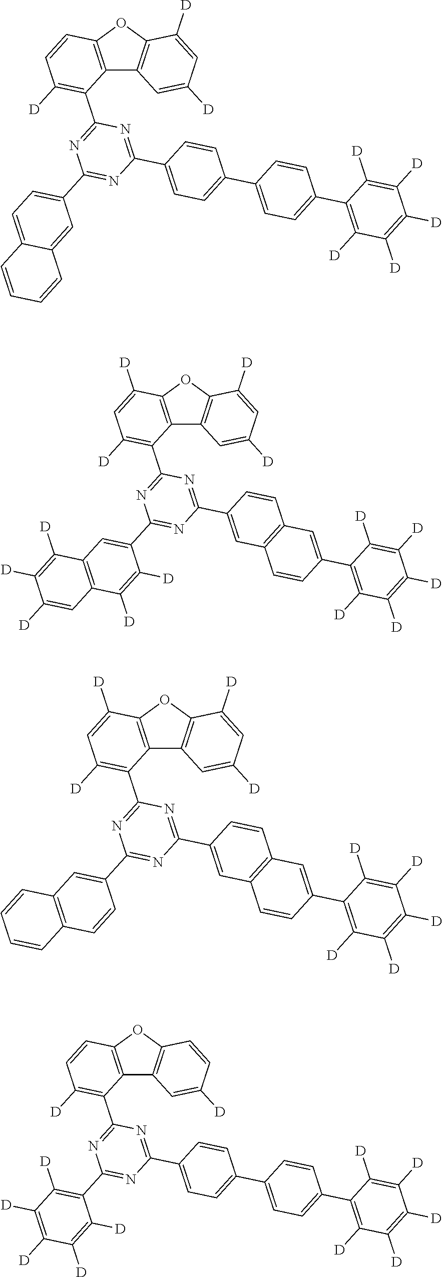

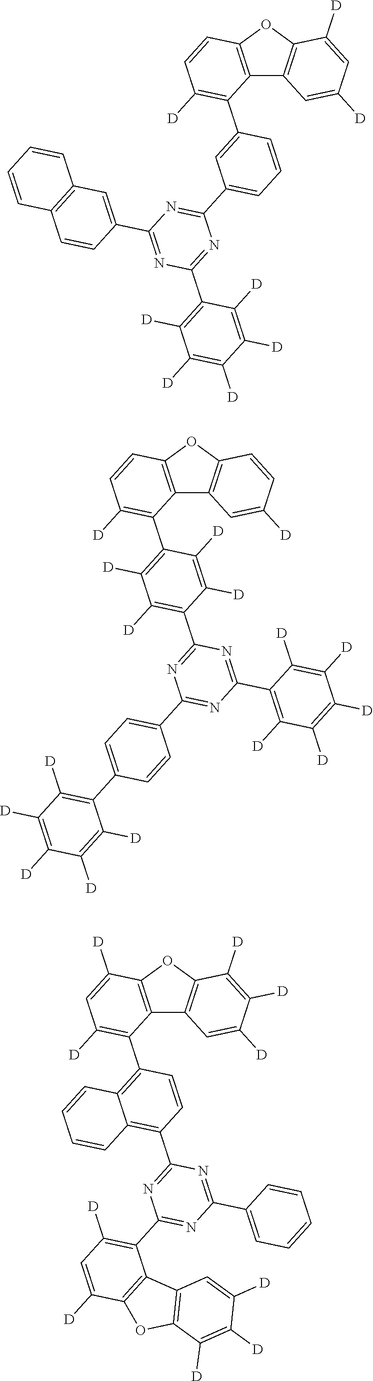 [SMILES: [2H]c1cc([2H])c2oc3ccc([2H])c(-c4cccc(-c5nc(-c6ccc7ccccc7c6)nc(-c6c([2H])c([2H])c([2H])c([2H])c6[2H])n5)c4)c3c2c1 ; [2H]c1ccc2oc3ccc([2H])c(-c4c([2H])c([2H])c(-c5nc(-c6ccc(-c7c([2H])c([2H])c([2H])c([2H])c7[2H])cc6)nc(-c6c([2H])c([2H])c([2H])c([2H])c6[2H])n5)c([2H])c4[2H])c3c2c1 ; [2H]c1cc2c(oc3c([2H])cc([2H])c(-c4nc(-c5ccccc5)nc(-c5ccc(-c6c([2H])cc([2H])c7oc8c([2H])c([2H])c([2H])cc8c67)c6ccccc56)n4)c32)c([2H])c1[2H]]

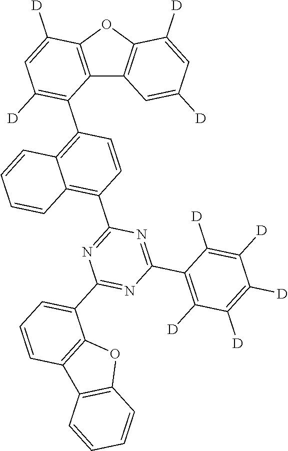 [SMILES: [2H]c1cc([2H])c2oc3c([2H])cc([2H])c(-c4ccc(-c5nc(-c6c([2H])c([2H])c([2H])c([2H])c6[2H])nc(-c6cccc7c6oc6ccccc67)n5)c5ccccc45)c3c2c1]

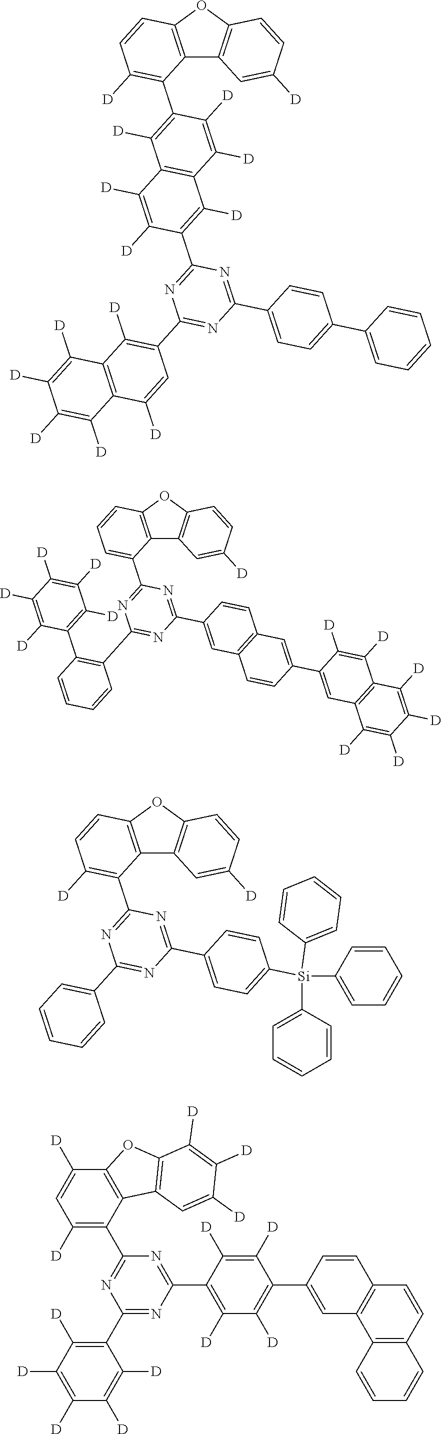

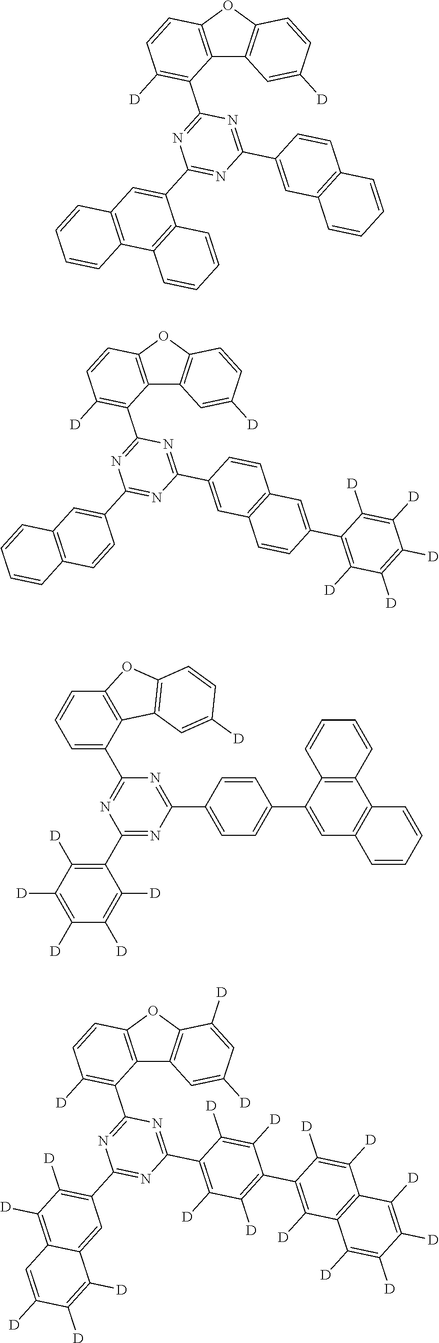 [SMILES: [2H]c1ccc2oc3ccc([2H])c(-c4nc(-c5ccc6ccccc6c5)nc(-c5cc6ccccc6c6ccccc56)n4)c3c2c1 ; [2H]c1ccc2oc3ccc([2H])c(-c4nc(-c5ccc6ccccc6c5)nc(-c5ccc6cc(-c7c([2H])c([2H])c([2H])c([2H])c7[2H])ccc6c5)n4)c3c2c1 ; [2H]c1ccc2oc3cccc(-c4nc(-c5ccc(-c6cc7ccccc7c7ccccc67)cc5)nc(-c5c([2H])c([2H])c([2H])c([2H])c5[2H])n4)c3c2c1 ; [2H]c1cc([2H])c2oc3ccc([2H])c(-c4nc(-c5cc6c([2H])c([2H])c([2H])cc6c([2H])c5[2H])nc(-c5c([2H])c([2H])c(-c6c([2H])c([2H])c7c([2H])c([2H])c([2H])c([2H])c7c6[2H])c([2H])c5[2H])n4)c3c2c1]

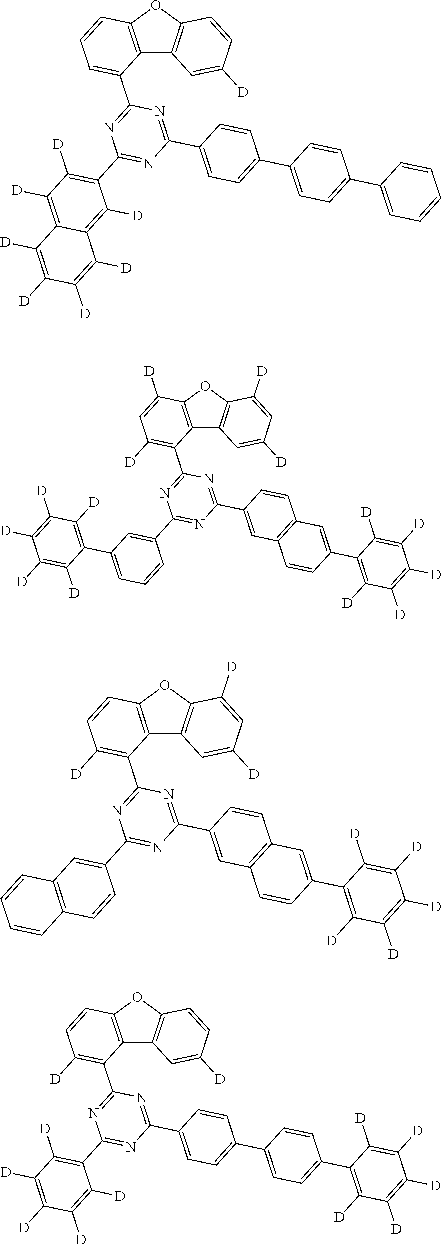

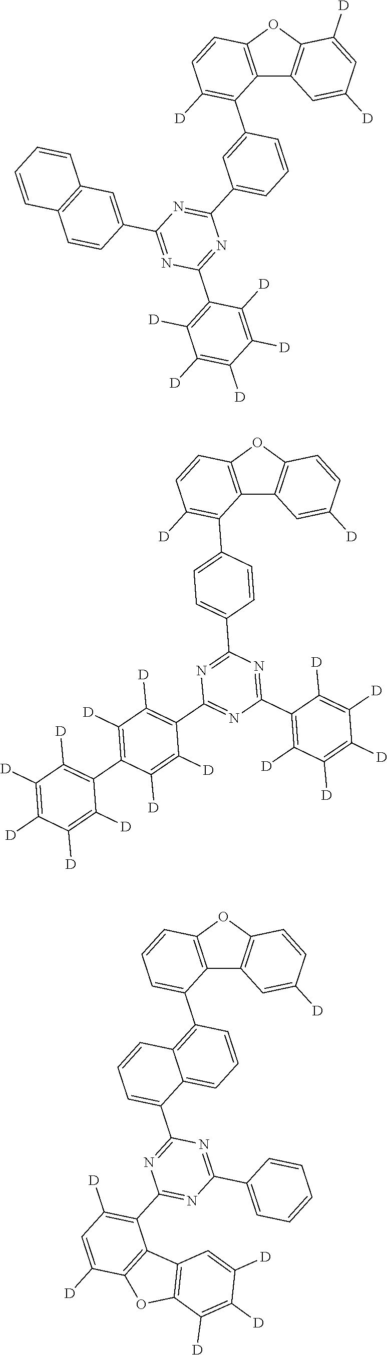

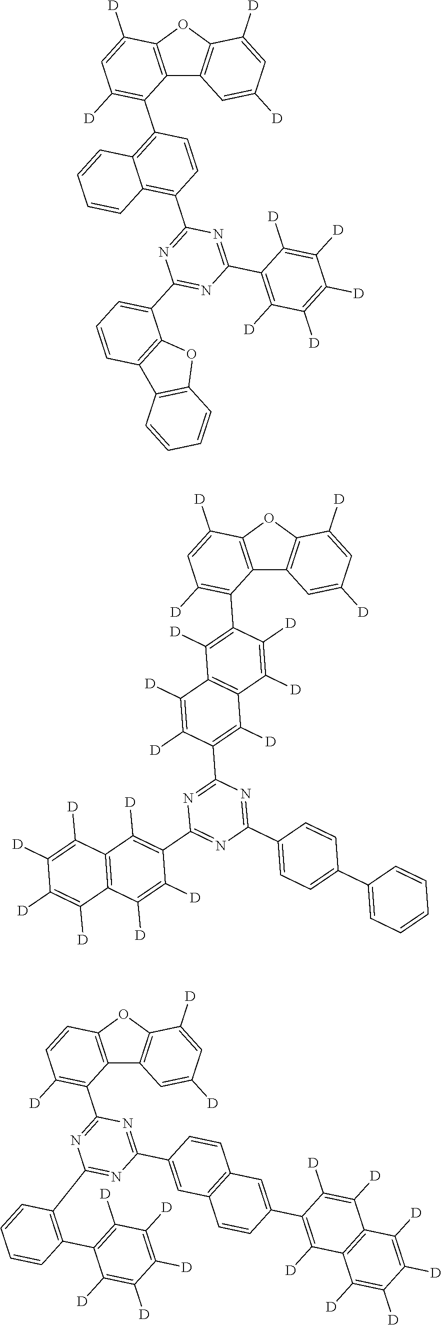

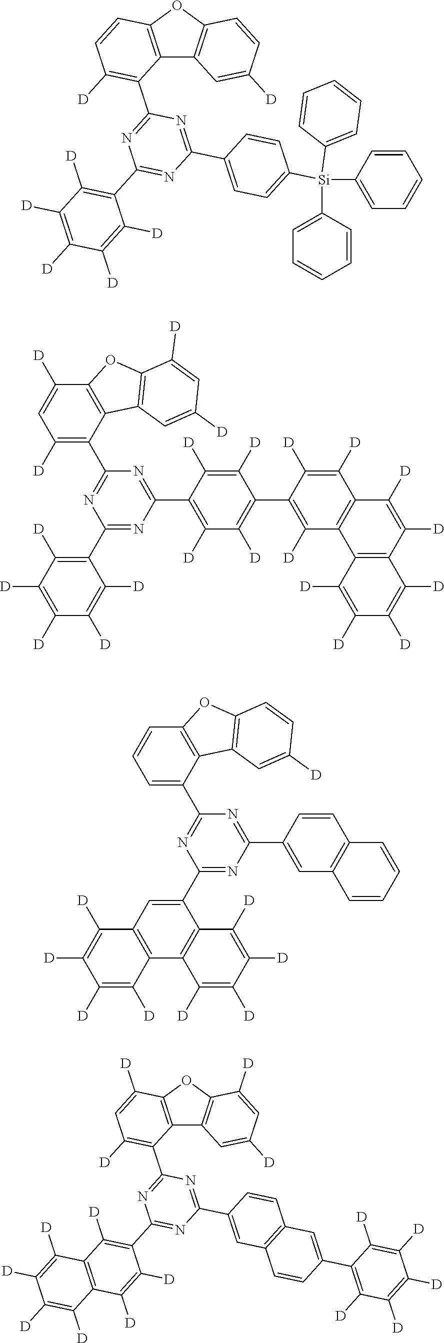

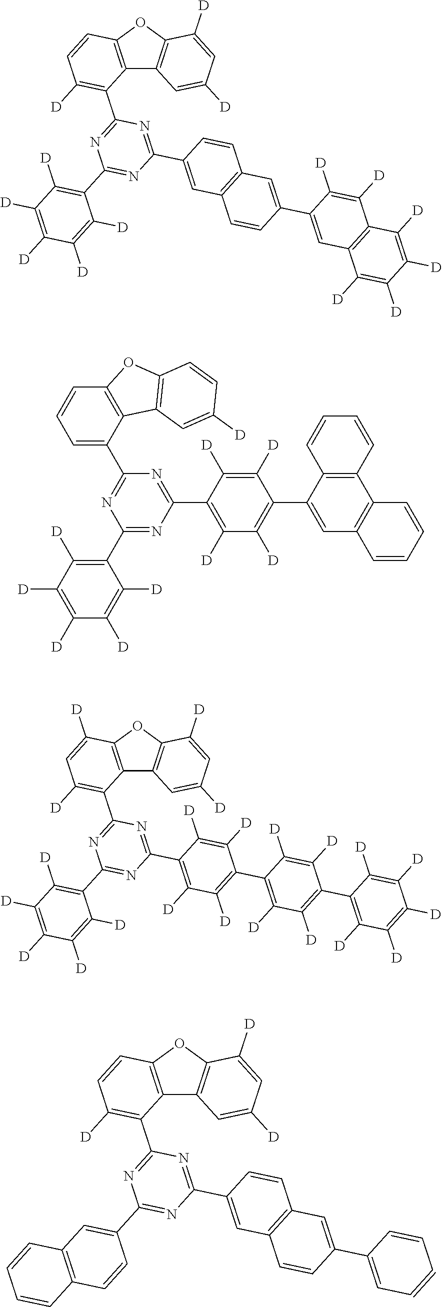

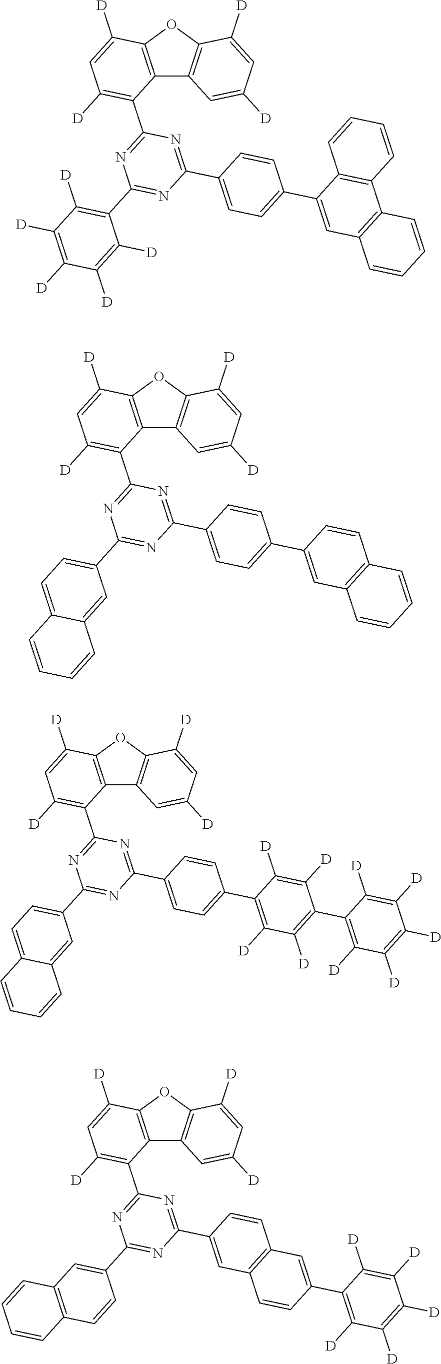

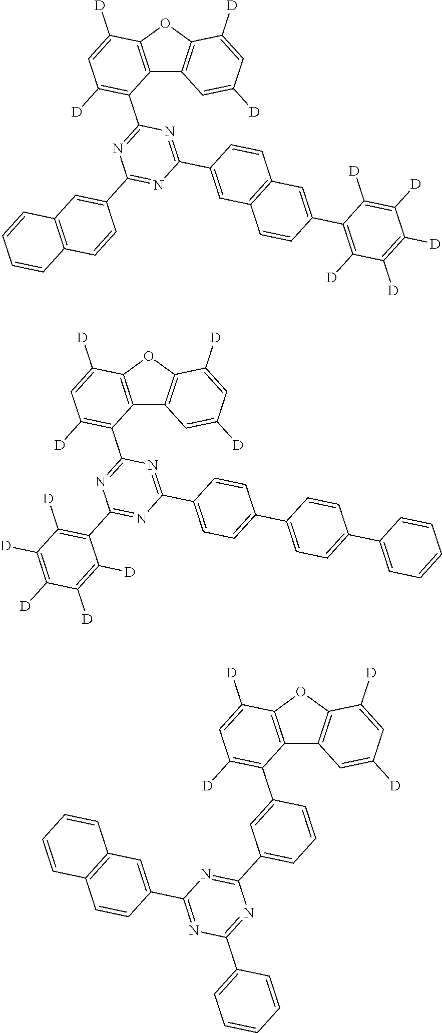 [SMILES: [2H]c1cc([2H])c2oc3c([2H])cc([2H])c(-c4nc(-c5ccc6ccccc6c5)nc(-c5ccc6cc(-c7c([2H])c([2H])c([2H])c([2H])c7[2H])ccc6c5)n4)c3c2c1 ; [2H]c1cc([2H])c2oc3c([2H])cc([2H])c(-c4nc(-c5ccc(-c6ccc(-c7ccccc7)cc6)cc5)nc(-c5c([2H])c([2H])c([2H])c([2H])c5[2H])n4)c3c2c1 ; [2H]c1cc([2H])c2oc3c([2H])cc([2H])c(-c4cccc(-c5nc(-c6ccccc6)nc(-c6ccc7ccccc7c6)n5)c4)c3c2c1]

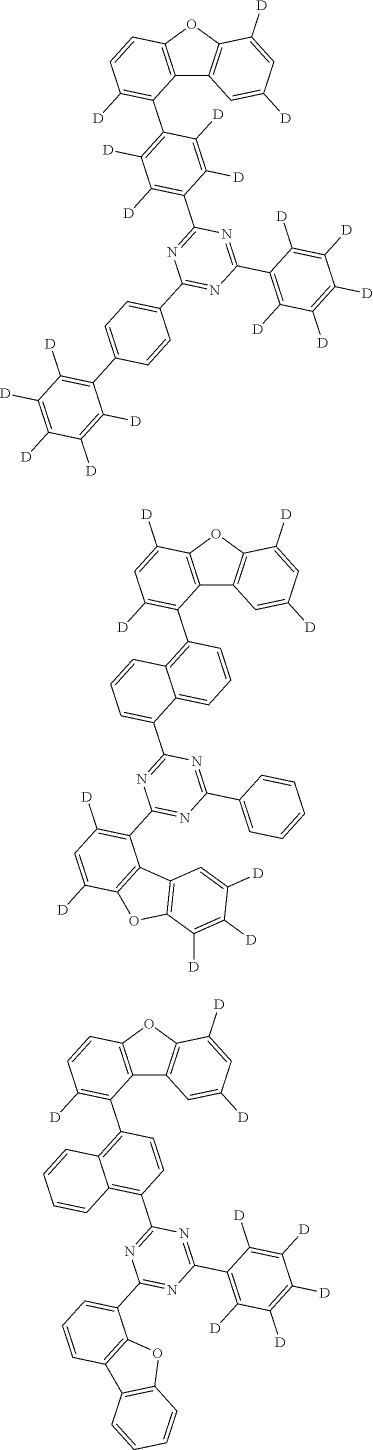

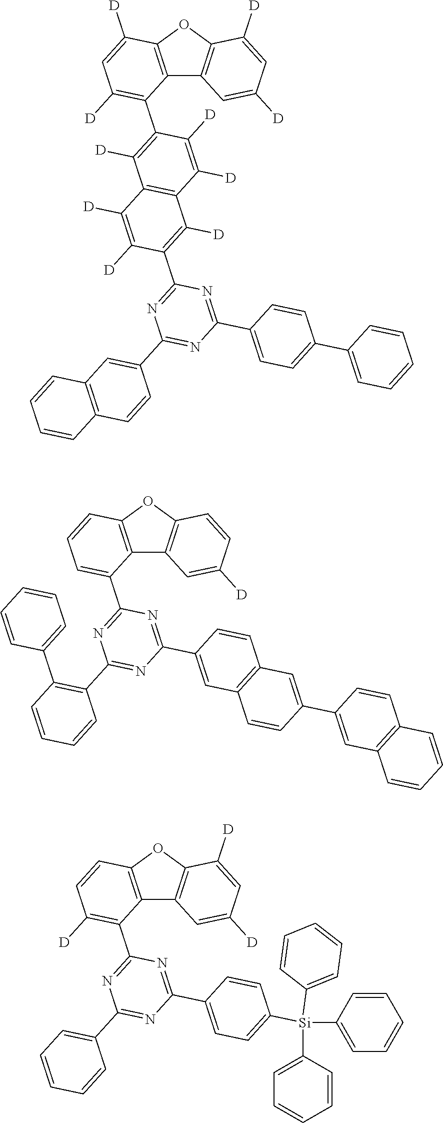 [SMILES: [2H]c1cc([2H])c2oc3c([2H])cc([2H])c(-c4c([2H])c([2H])c5c([2H])c(-c6nc(-c7ccc(-c8ccccc8)cc7)nc(-c7ccc8ccccc8c7)n6)c([2H])c([2H])c5c4[2H])c3c2c1 ; [2H]c1ccc2oc3cccc(-c4nc(-c5ccc6cc(-c7ccc8ccccc8c7)ccc6c5)nc(-c5ccccc5-c5ccccc5)n4)c3c2c1 ; [2H]c1cc([2H])c2oc3ccc([2H])c(-c4nc(-c5ccccc5)nc(-c5ccc([Si](c6ccccc6)(c6ccccc6)c6ccccc6)cc5)n4)c3c2c1]

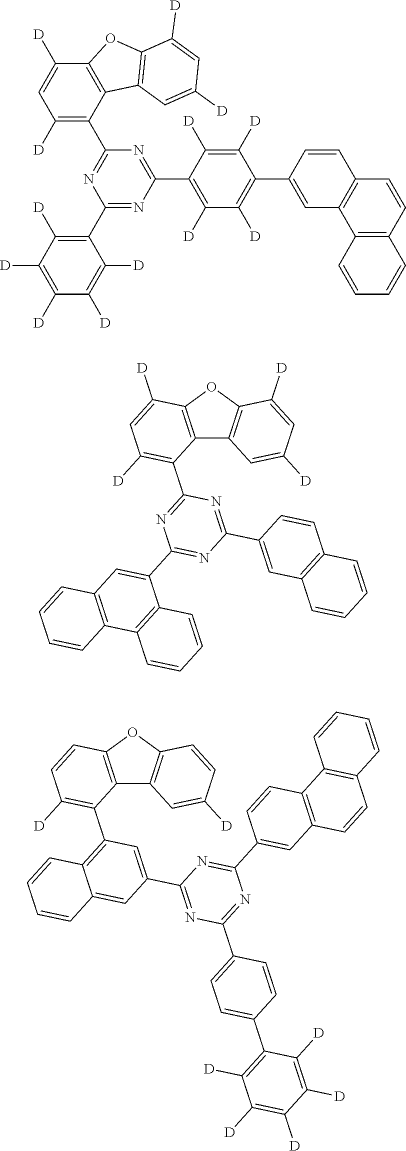 [SMILES: [2H]c1cc([2H])c2oc3c([2H])cc([2H])c(-c4nc(-c5c([2H])c([2H])c([2H])c([2H])c5[2H])nc(-c5c([2H])c([2H])c(-c6ccc7ccc8ccccc8c7c6)c([2H])c5[2H])n4)c3c2c1 ; [2H]c1cc([2H])c2oc3c([2H])cc([2H])c(-c4nc(-c5ccc6ccccc6c5)nc(-c5cc6ccccc6c6ccccc56)n4)c3c2c1 ; [2H]c1ccc2oc3ccc([2H])c(-c4cc(-c5nc(-c6ccc(-c7c([2H])c([2H])c([2H])c([2H])c7[2H])cc6)nc(-c6ccc7c(ccc8ccccc87)c6)n5)cc5ccccc45)c3c2c1]

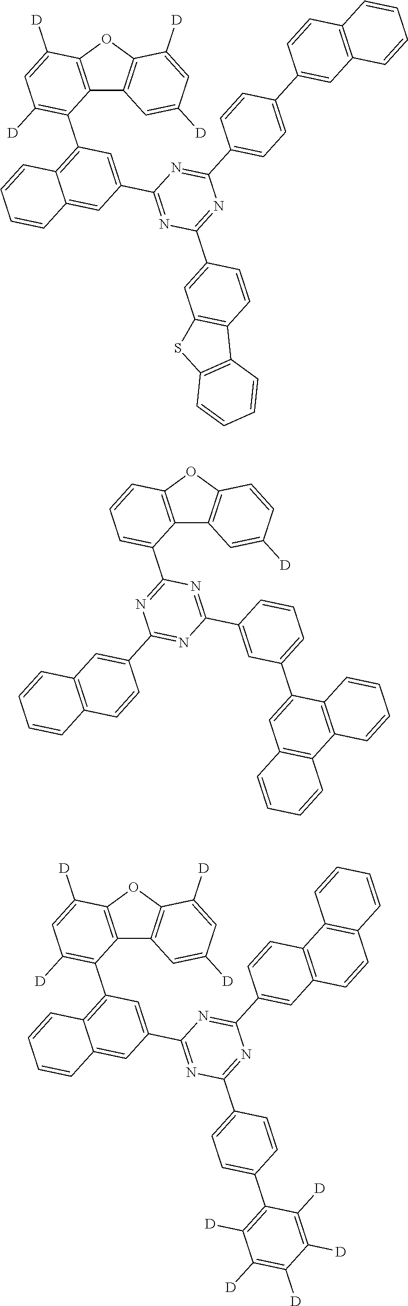 [SMILES: [2H]c1cc([2H])c2oc3c([2H])cc([2H])c(-c4cc(-c5nc(-c6ccc(-c7ccc8ccccc8c7)cc6)nc(-c6ccc7c(c6)sc6ccccc67)n5)cc5ccccc45)c3c2c1 ; [2H]c1ccc2oc3cccc(-c4nc(-c5cccc(-c6cc7ccccc7c7ccccc67)c5)nc(-c5ccc6ccccc6c5)n4)c3c2c1 ; [2H]c1cc([2H])c2oc3c([2H])cc([2H])c(-c4cc(-c5nc(-c6ccc(-c7c([2H])c([2H])c([2H])c([2H])c7[2H])cc6)nc(-c6ccc7c(ccc8ccccc87)c6)n5)cc5ccccc45)c3c2c1]

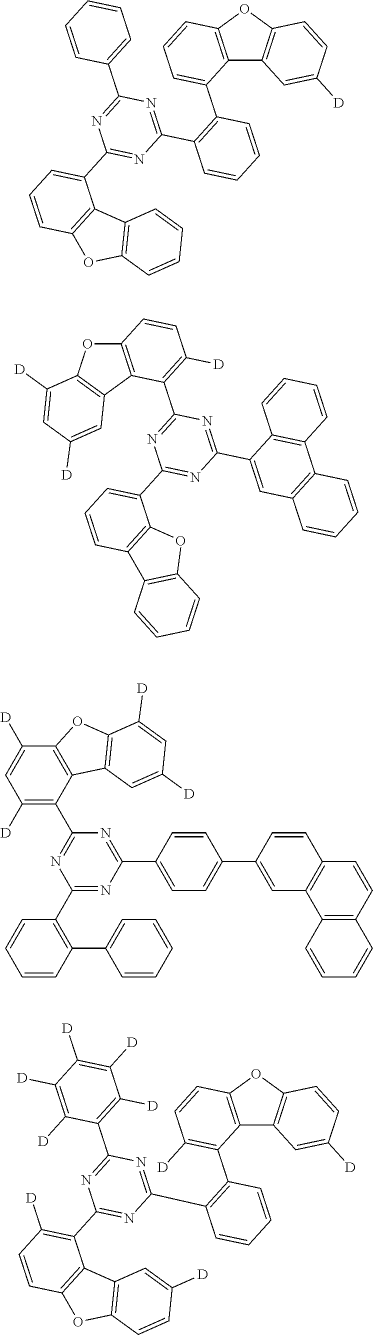

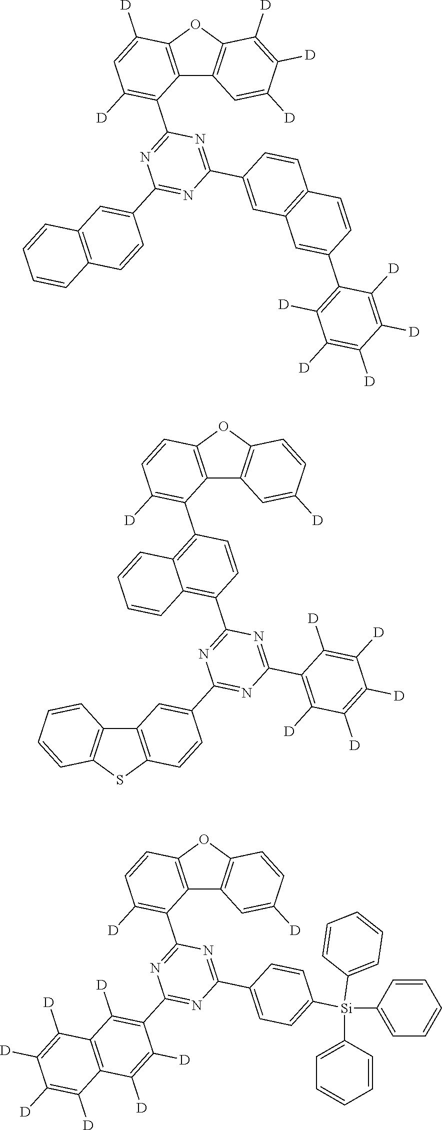 [SMILES: [2H]c1cc2c(oc3c([2H])cc([2H])c(-c4nc(-c5ccc6ccccc6c5)nc(-c5ccc6ccc(-c7c([2H])c([2H])c([2H])c([2H])c7[2H])cc6c5)n4)c32)c([2H])c1[2H] ; [2H]c1ccc2oc3ccc([2H])c(-c4ccc(-c5nc(-c6ccc7sc8ccccc8c7c6)nc(-c6c([2H])c([2H])c([2H])c([2H])c6[2H])n5)c5ccccc45)c3c2c1 ; [2H]c1ccc2oc3ccc([2H])c(-c4nc(-c5ccc([Si](c6ccccc6)(c6ccccc6)c6ccccc6)cc5)nc(-c5c([2H])c([2H])c6c([2H])c([2H])c([2H])c([2H])c6c5[2H])n4)c3c2c1]

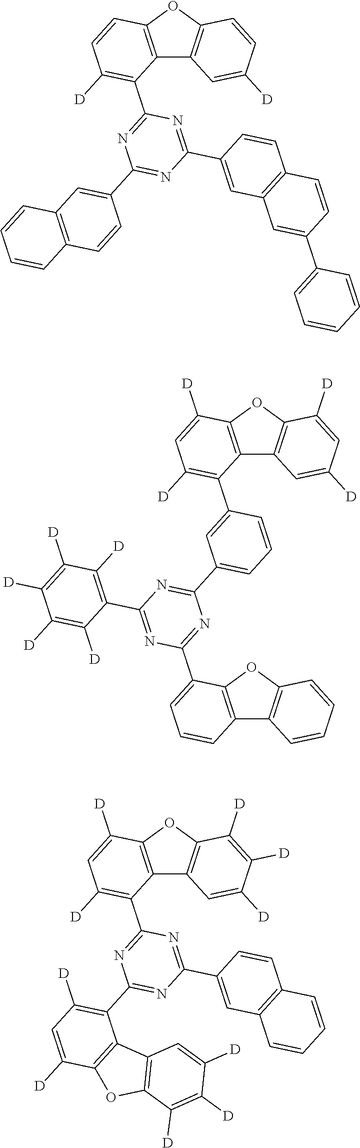 [SMILES: [2H]c1ccc2oc3ccc([2H])c(-c4nc(-c5ccc6ccccc6c5)nc(-c5ccc6ccc(-c7ccccc7)cc6c5)n4)c3c2c1 ; [2H]c1cc([2H])c2oc3c([2H])cc([2H])c(-c4cccc(-c5nc(-c6c([2H])c([2H])c([2H])c([2H])c6[2H])nc(-c6cccc7c6oc6ccccc67)n5)c4)c3c2c1 ; [2H]c1cc2c(oc3c([2H])cc([2H])c(-c4nc(-c5ccc6ccccc6c5)nc(-c5c([2H])cc([2H])c6oc7c([2H])c([2H])c([2H])cc7c56)n4)c32)c([2H])c1[2H]]

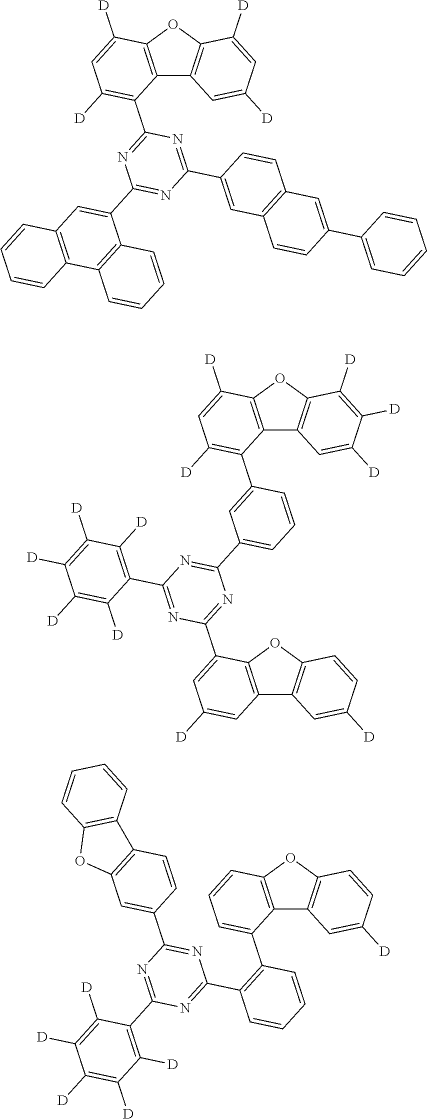 [SMILES: [2H]c1cc([2H])c2oc3c([2H])cc([2H])c(-c4nc(-c5ccc6cc(-c7ccccc7)ccc6c5)nc(-c5cc6ccccc6c6ccccc56)n4)c3c2c1 ; [2H]c1ccc2oc3c(-c4nc(-c5cccc(-c6c([2H])cc([2H])c7oc8c([2H])c([2H])c([2H])cc8c67)c5)nc(-c5c([2H])c([2H])c([2H])c([2H])c5[2H])n4)cc([2H])cc3c2c1 ; [2H]c1ccc2oc3cccc(-c4ccccc4-c4nc(-c5ccc6c(c5)oc5ccccc56)nc(-c5c([2H])c([2H])c([2H])c([2H])c5[2H])n4)c3c2c1]

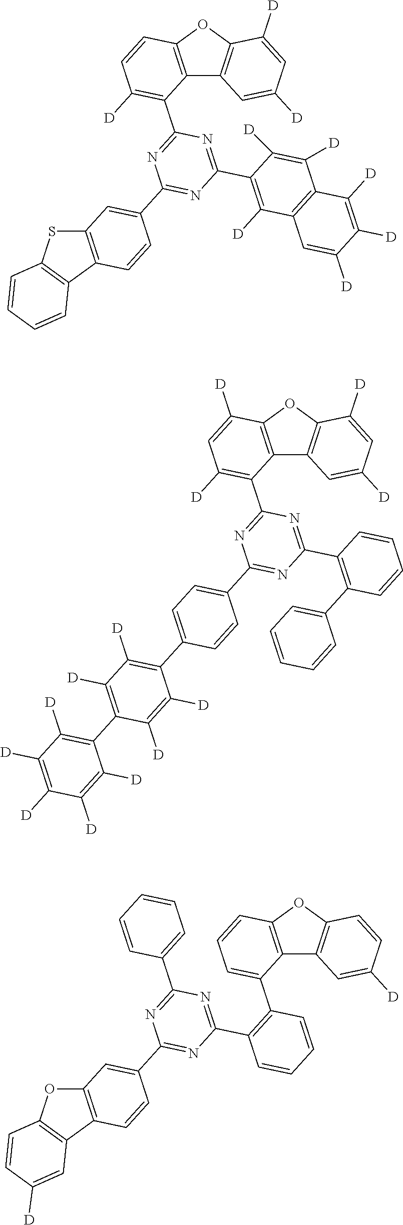 [SMILES: [2H]c1cc([2H])c2oc3ccc([2H])c(-c4nc(-c5ccc6c(c5)sc5ccccc56)nc(-c5c([2H])c([2H])c6c([2H])c([2H])c([2H])cc6c5[2H])n4)c3c2c1 ; [2H]c1cc([2H])c2oc3c([2H])cc([2H])c(-c4nc(-c5ccc(-c6c([2H])c([2H])c(-c7c([2H])c([2H])c([2H])c([2H])c7[2H])c([2H])c6[2H])cc5)nc(-c5ccccc5-c5ccccc5)n4)c3c2c1 ; [2H]c1ccc2oc3cc(-c4nc(-c5ccccc5)nc(-c5ccccc5-c5cccc6oc7ccc([2H])cc7c56)n4)ccc3c2c1]

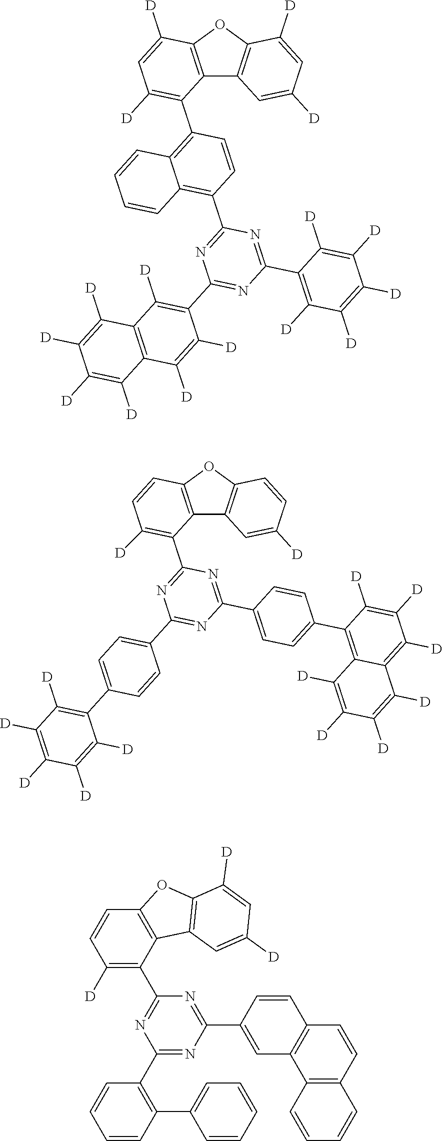 [SMILES: [2H]c1cc([2H])c2oc3c([2H])cc([2H])c(-c4ccc(-c5nc(-c6c([2H])c([2H])c([2H])c([2H])c6[2H])nc(-c6c([2H])c([2H])c7c([2H])c([2H])c([2H])c([2H])c7c6[2H])n5)c5ccccc45)c3c2c1 ; [2H]c1ccc2oc3ccc([2H])c(-c4nc(-c5ccc(-c6c([2H])c([2H])c([2H])c([2H])c6[2H])cc5)nc(-c5ccc(-c6c([2H])c([2H])c([2H])c7c([2H])c([2H])c([2H])c([2H])c67)cc5)n4)c3c2c1 ; [2H]c1cc([2H])c2oc3ccc([2H])c(-c4nc(-c5ccc6ccc7ccccc7c6c5)nc(-c5ccccc5-c5ccccc5)n4)c3c2c1]

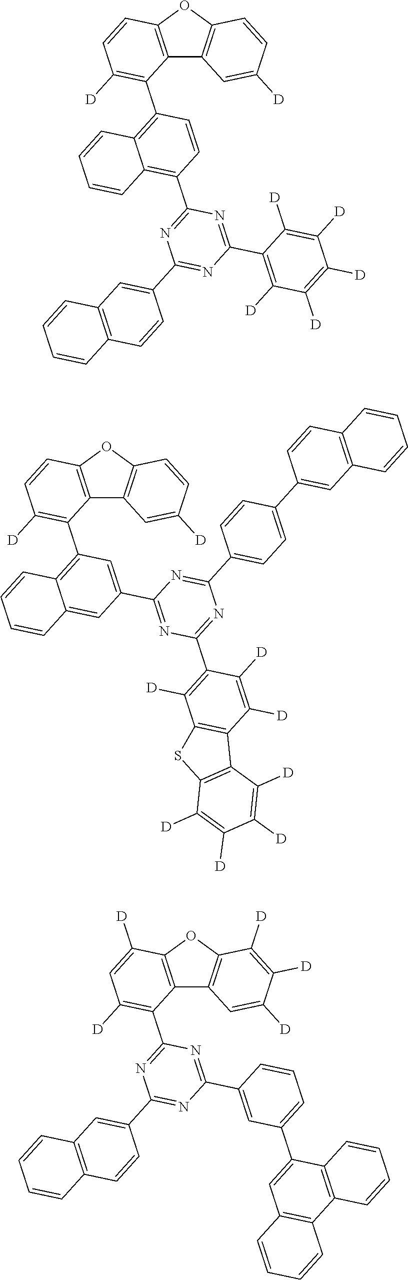 [SMILES: [2H]c1ccc2oc3ccc([2H])c(-c4ccc(-c5nc(-c6ccc7ccccc7c6)nc(-c6c([2H])c([2H])c([2H])c([2H])c6[2H])n5)c5ccccc45)c3c2c1 ; [2H]c1ccc2oc3ccc([2H])c(-c4cc(-c5nc(-c6ccc(-c7ccc8ccccc8c7)cc6)nc(-c6c([2H])c([2H])c7c(sc8c([2H])c([2H])c([2H])c([2H])c87)c6[2H])n5)cc5ccccc45)c3c2c1 ; [2H]c1cc2c(oc3c([2H])cc([2H])c(-c4nc(-c5cccc(-c6cc7ccccc7c7ccccc67)c5)nc(-c5ccc6ccccc6c5)n4)c32)c([2H])c1[2H]]

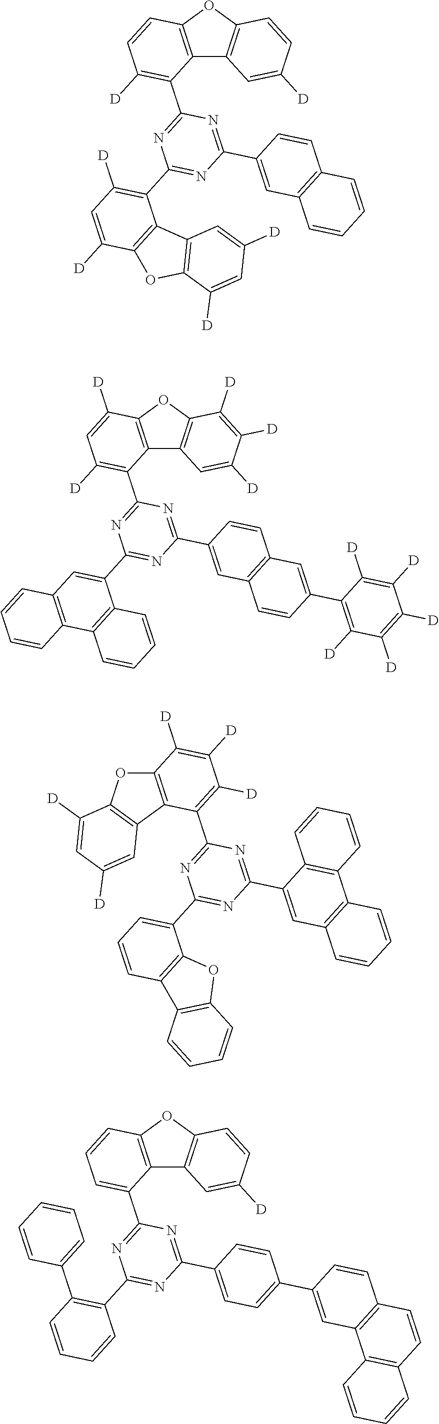 [SMILES: [2H]c1ccc2oc3ccc([2H])c(-c4nc(-c5ccc6ccccc6c5)nc(-c5c([2H])cc([2H])c6oc7c([2H])cc([2H])cc7c56)n4)c3c2c1 ; [2H]c1cc2c(oc3c([2H])cc([2H])c(-c4nc(-c5ccc6cc(-c7c([2H])c([2H])c([2H])c([2H])c7[2H])ccc6c5)nc(-c5cc6ccccc6c6ccccc56)n4)c32)c([2H])c1[2H] ; [2H]c1cc([2H])c2oc3c([2H])c([2H])c([2H])c(-c4nc(-c5cc6ccccc6c6ccccc56)nc(-c5cccc6c5oc5ccccc56)n4)c3c2c1 ; [2H]c1ccc2oc3cccc(-c4nc(-c5ccc(-c6ccc7ccc8ccccc8c7c6)cc5)nc(-c5ccccc5-c5ccccc5)n4)c3c2c1]

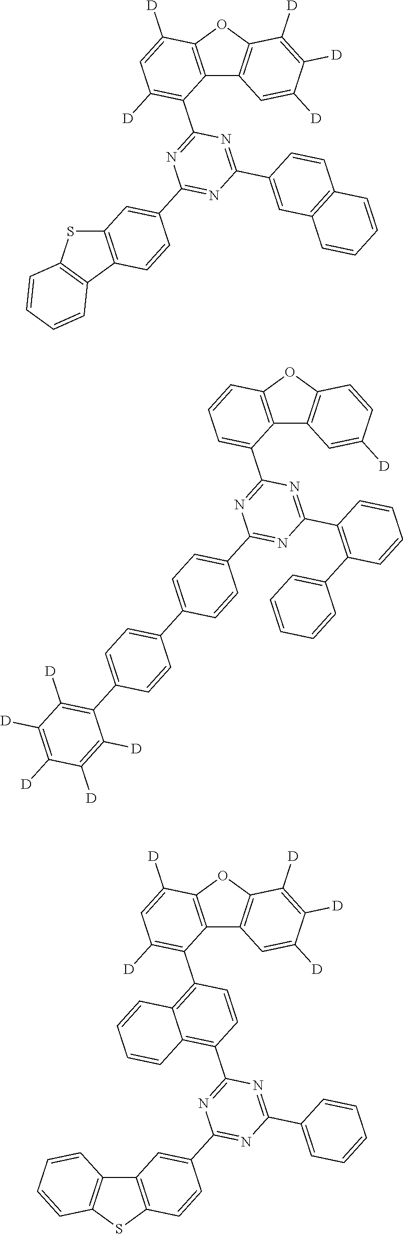 [SMILES: [2H]c1cc2c(oc3c([2H])cc([2H])c(-c4nc(-c5ccc6ccccc6c5)nc(-c5ccc6c(c5)sc5ccccc56)n4)c32)c([2H])c1[2H] ; [2H]c1ccc2oc3cccc(-c4nc(-c5ccc(-c6ccc(-c7c([2H])c([2H])c([2H])c([2H])c7[2H])cc6)cc5)nc(-c5ccccc5-c5ccccc5)n4)c3c2c1 ; [2H]c1cc2c(oc3c([2H])cc([2H])c(-c4ccc(-c5nc(-c6ccccc6)nc(-c6ccc7sc8ccccc8c7c6)n5)c5ccccc45)c32)c([2H])c1[2H]]

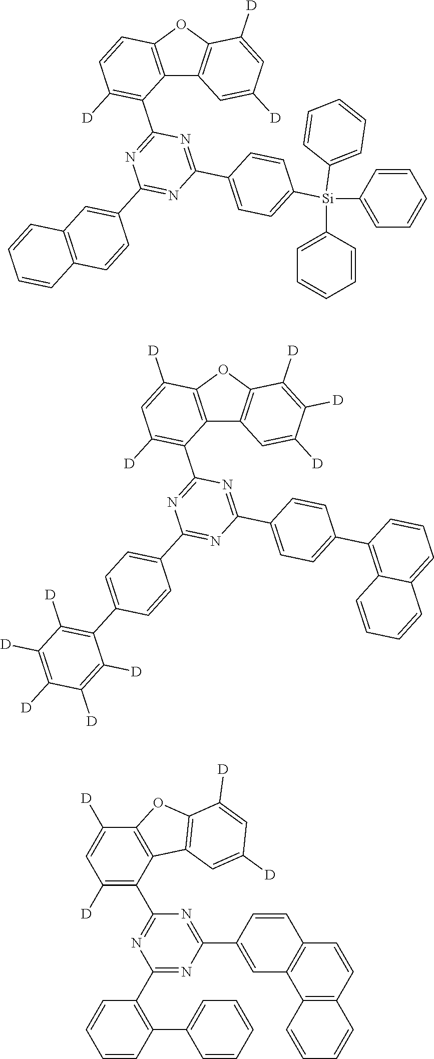 [SMILES: [2H]c1cc([2H])c2oc3ccc([2H])c(-c4nc(-c5ccc([Si](c6ccccc6)(c6ccccc6)c6ccccc6)cc5)nc(-c5ccc6ccccc6c5)n4)c3c2c1 ; [2H]c1cc2c(oc3c([2H])cc([2H])c(-c4nc(-c5ccc(-c6c([2H])c([2H])c([2H])c([2H])c6[2H])cc5)nc(-c5ccc(-c6cccc7ccccc67)cc5)n4)c32)c([2H])c1[2H] ; [2H]c1cc([2H])c2oc3c([2H])cc([2H])c(-c4nc(-c5ccc6ccc7ccccc7c6c5)nc(-c5ccccc5-c5ccccc5)n4)c3c2c1]

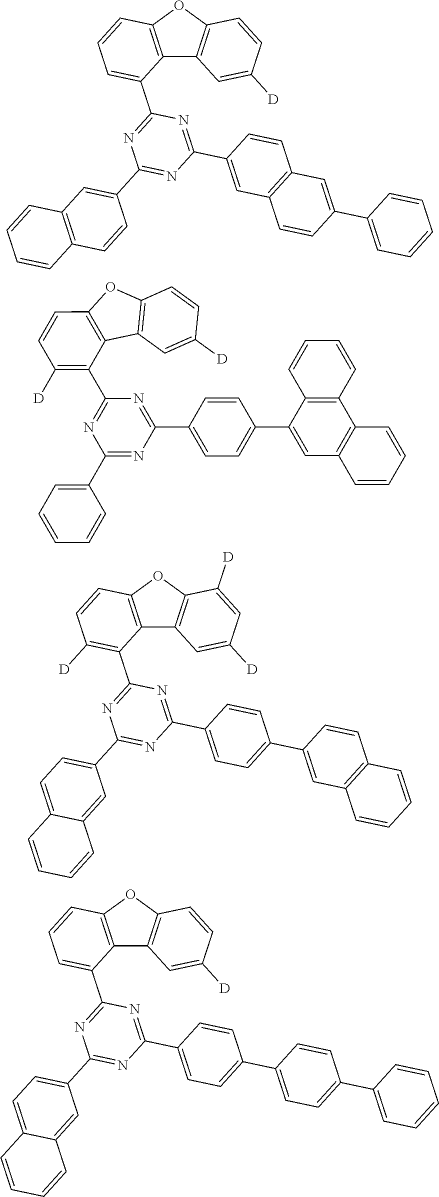

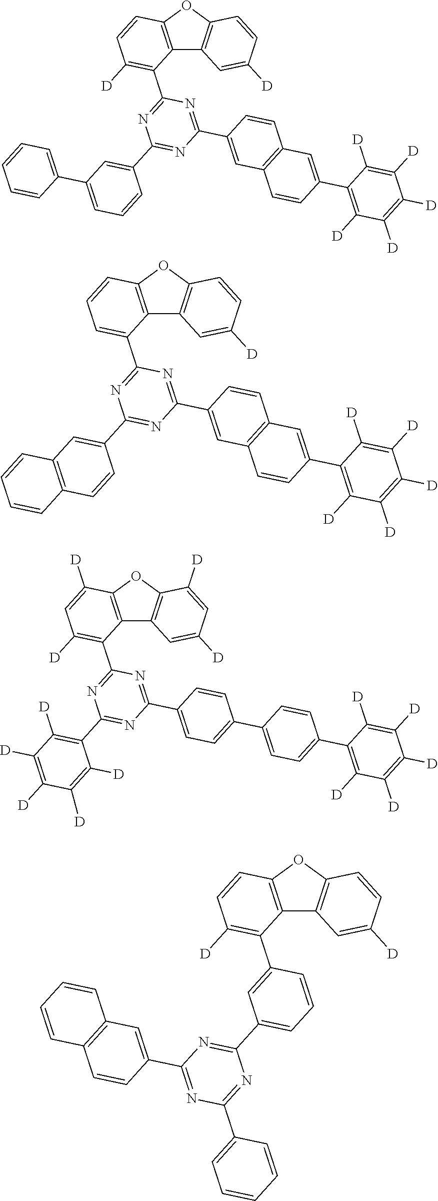 [SMILES: [2H]c1ccc2oc3ccc([2H])c(-c4nc(-c5cccc(-c6ccccc6)c5)nc(-c5ccc6cc(-c7c([2H])c([2H])c([2H])c([2H])c7[2H])ccc6c5)n4)c3c2c1 ; [2H]c1ccc2oc3cccc(-c4nc(-c5ccc6ccccc6c5)nc(-c5ccc6cc(-c7c([2H])c([2H])c([2H])c([2H])c7[2H])ccc6c5)n4)c3c2c1 ; [2H]c1cc([2H])c2oc3c([2H])cc([2H])c(-c4nc(-c5ccc(-c6ccc(-c7c([2H])c([2H])c([2H])c([2H])c7[2H])cc6)cc5)nc(-c5c([2H])c([2H])c([2H])c([2H])c5[2H])n4)c3c2c1 ; [2H]c1ccc2oc3ccc([2H])c(-c4cccc(-c5nc(-c6ccccc6)nc(-c6ccc7ccccc7c6)n5)c4)c3c2c1]

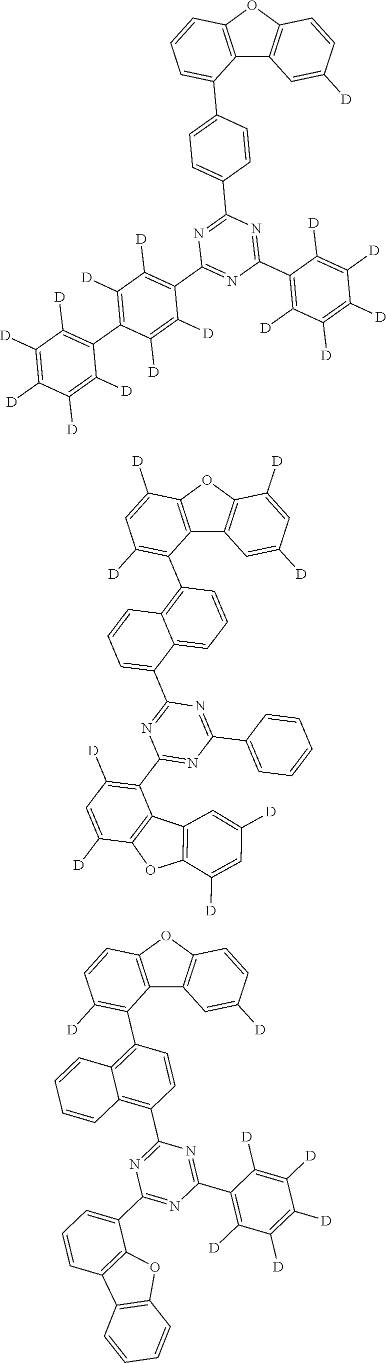

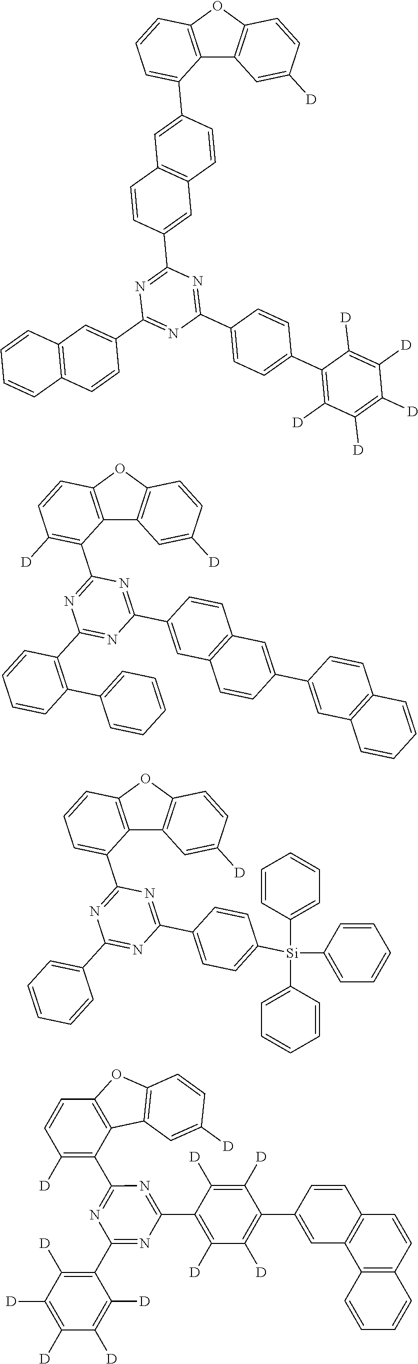

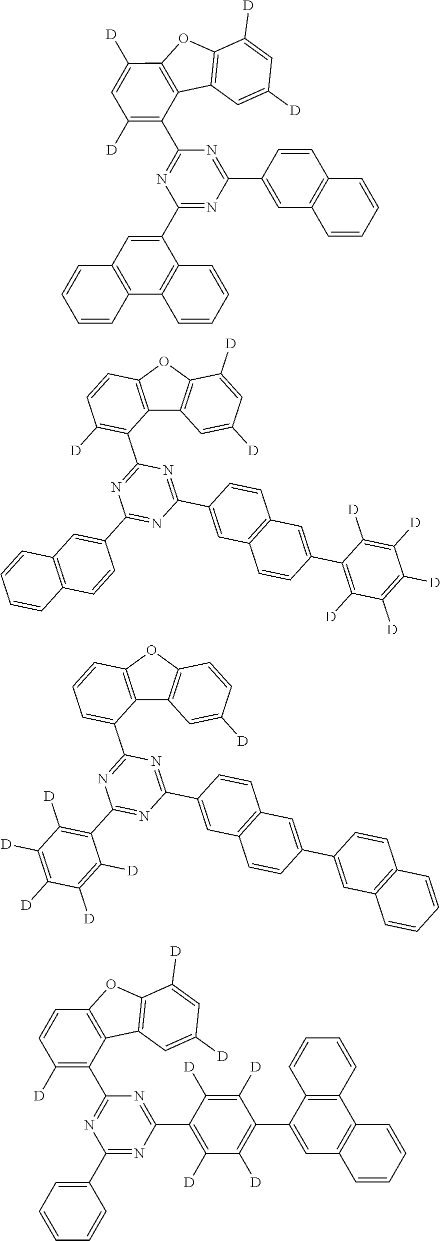

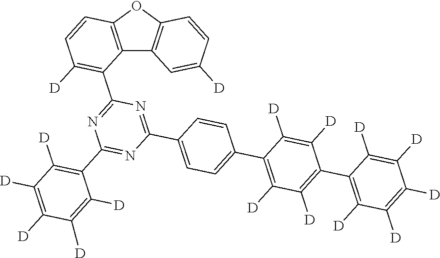 [SMILES: [2H]c1ccc2oc3ccc([2H])c(-c4nc(-c5ccc(-c6c([2H])c([2H])c(-c7c([2H])c([2H])c([2H])c([2H])c7[2H])c([2H])c6[2H])cc5)nc(-c5c([2H])c([2H])c([2H])c([2H])c5[2H])n4)c3c2c1]

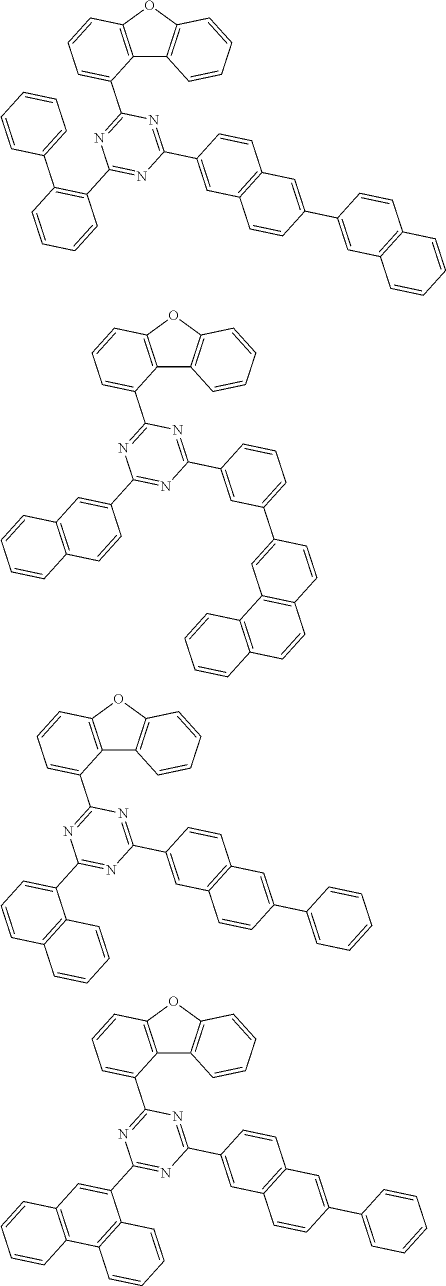

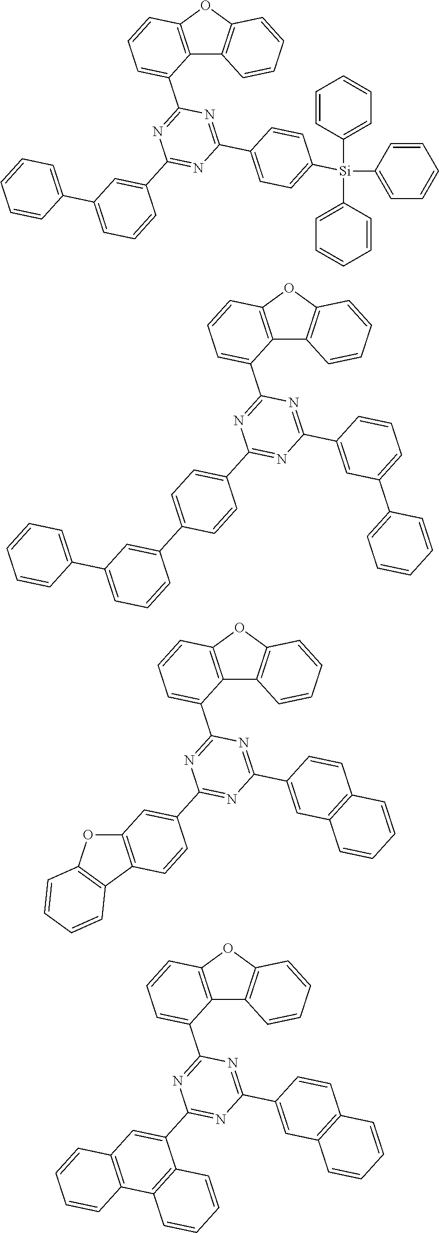

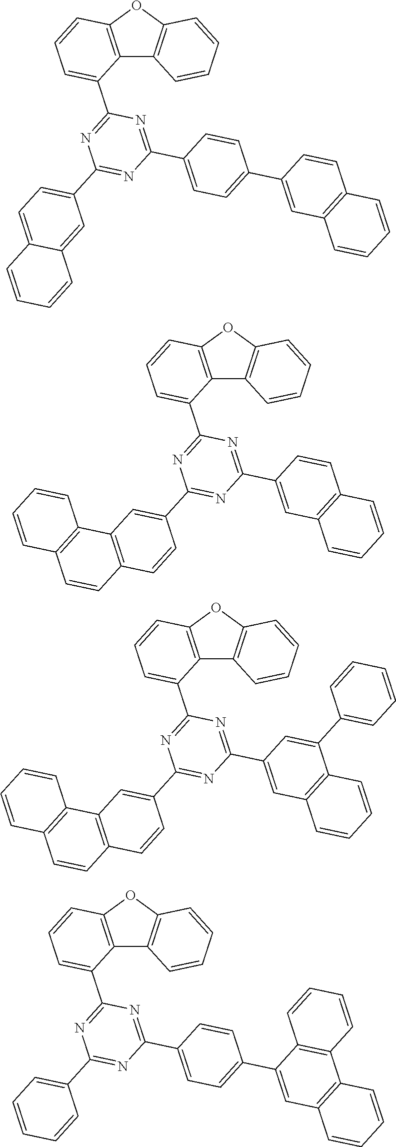

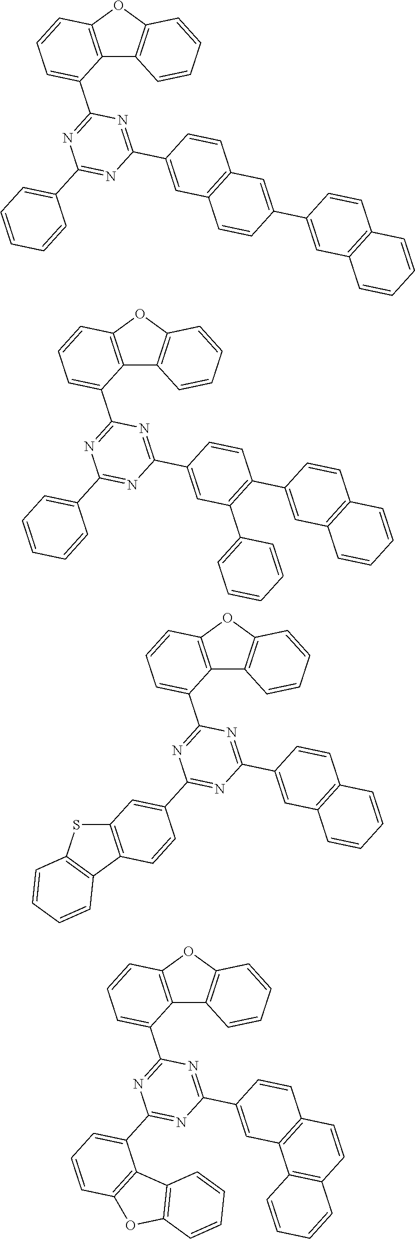

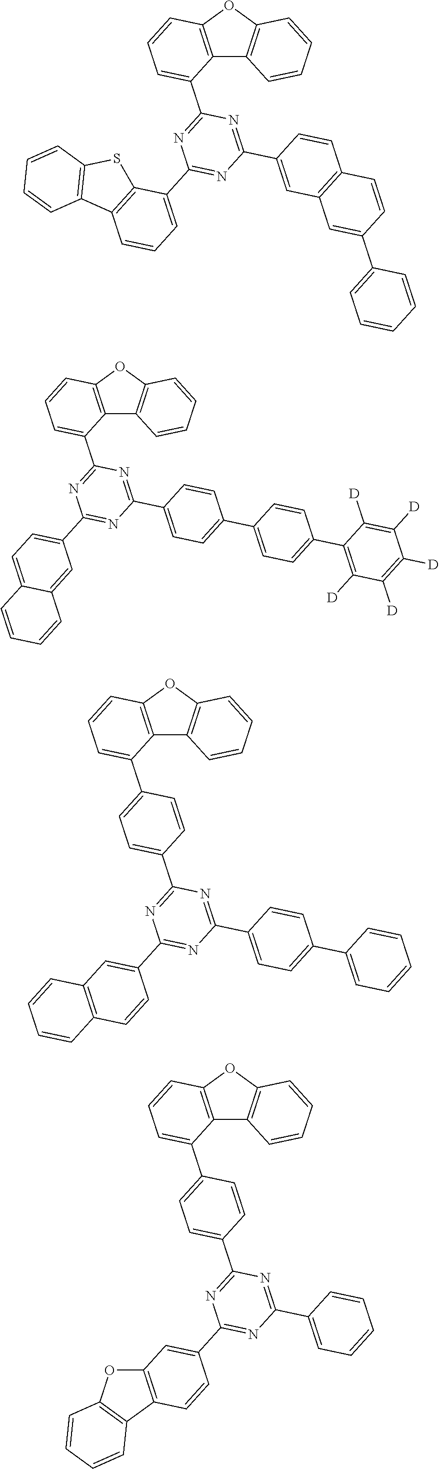 [SMILES: c1ccc(-c2ccc3ccc(-c4nc(-c5cccc6c5sc5ccccc56)nc(-c5cccc6oc7ccccc7c56)n4)cc3c2)cc1 ; [2H]c1c([2H])c([2H])c(-c2ccc(-c3ccc(-c4nc(-c5ccc6ccccc6c5)nc(-c5cccc6oc7ccccc7c56)n4)cc3)cc2)c([2H])c1[2H] ; c1ccc(-c2ccc(-c3nc(-c4ccc(-c5cccc6oc7ccccc7c56)cc4)nc(-c4ccc5ccccc5c4)n3)cc2)cc1 ; c1ccc(-c2nc(-c3ccc(-c4cccc5oc6ccccc6c45)cc3)nc(-c3ccc4c(c3)oc3ccccc34)n2)cc1]

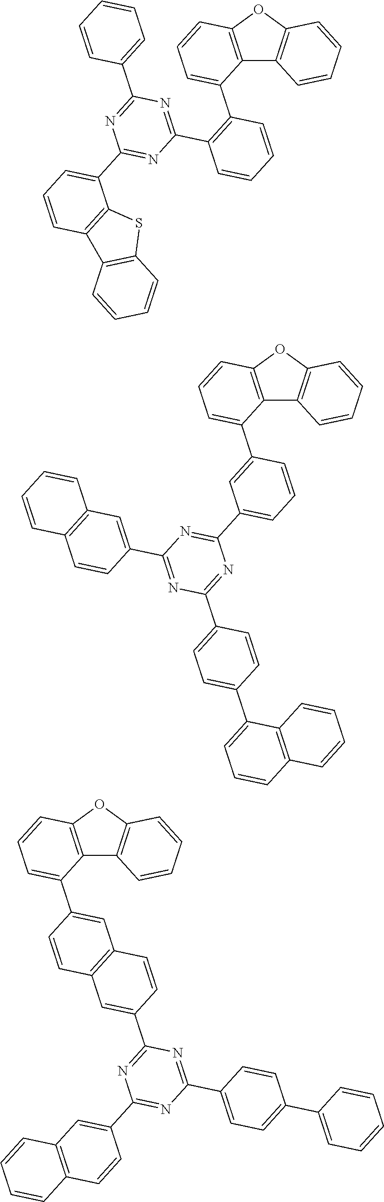 [SMILES: c1ccc(-c2nc(-c3ccccc3-c3cccc4oc5ccccc5c34)nc(-c3cccc4c3sc3ccccc34)n2)cc1 ; c1cc(-c2nc(-c3ccc(-c4cccc5ccccc45)cc3)nc(-c3ccc4ccccc4c3)n2)cc(-c2cccc3oc4ccccc4c23)c1 ; c1ccc(-c2ccc(-c3nc(-c4ccc5ccccc5c4)nc(-c4ccc5cc(-c6cccc7oc8ccccc8c67)ccc5c4)n3)cc2)cc1]

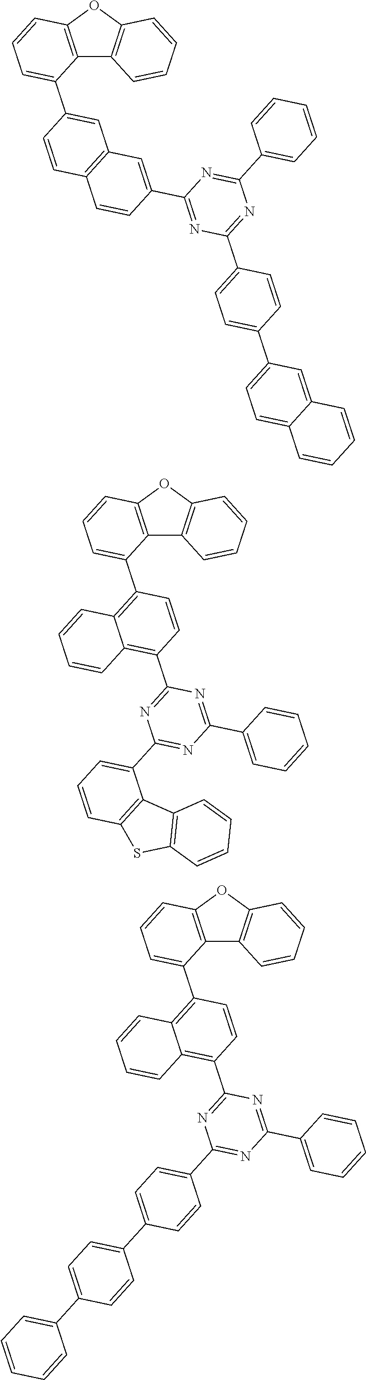

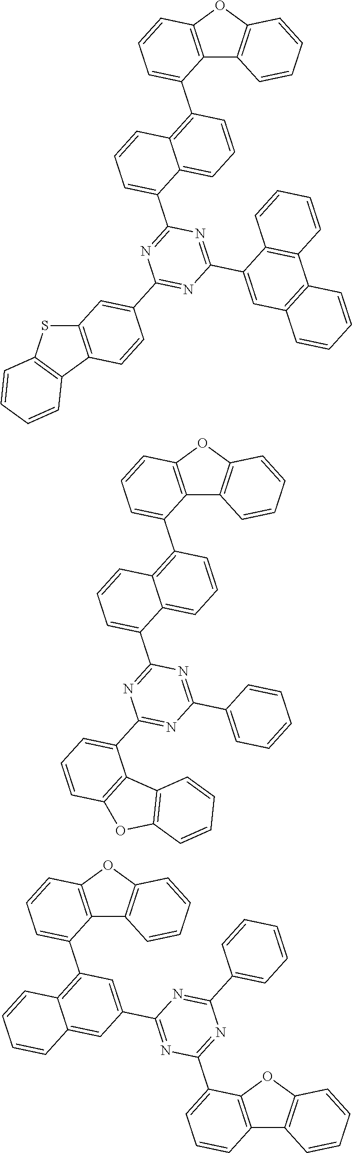

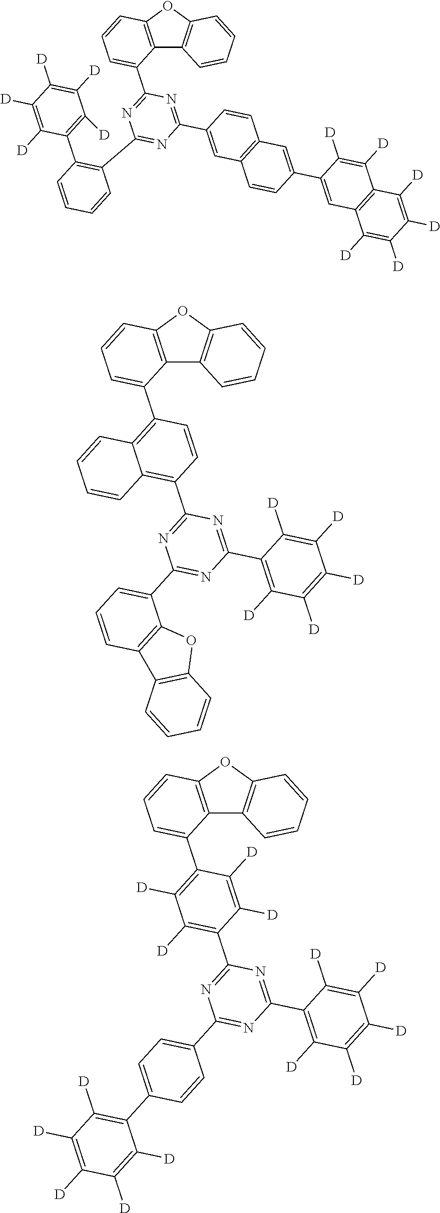

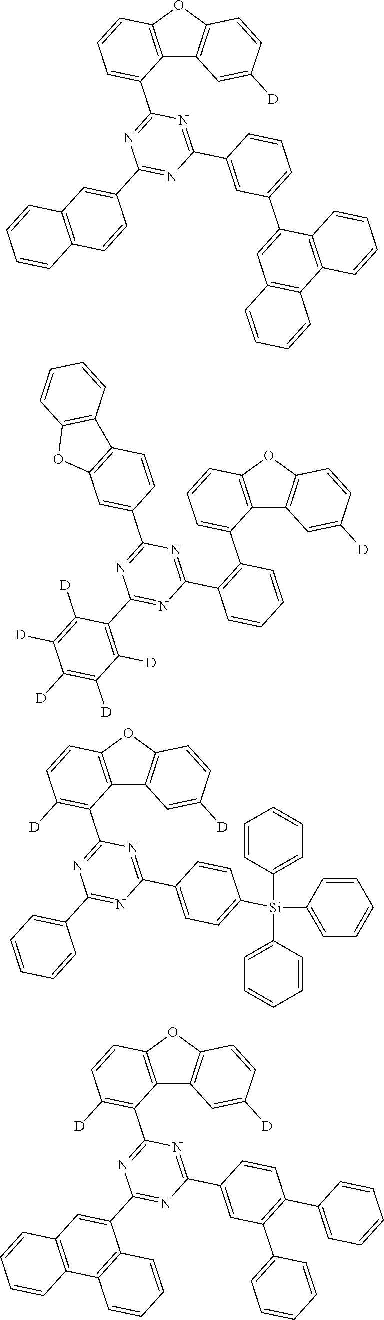

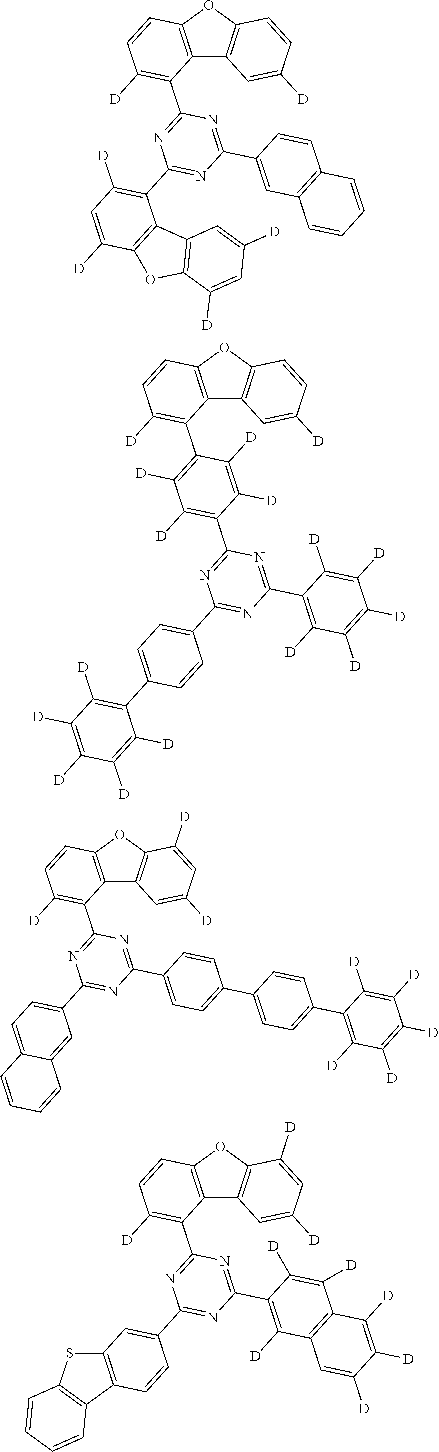

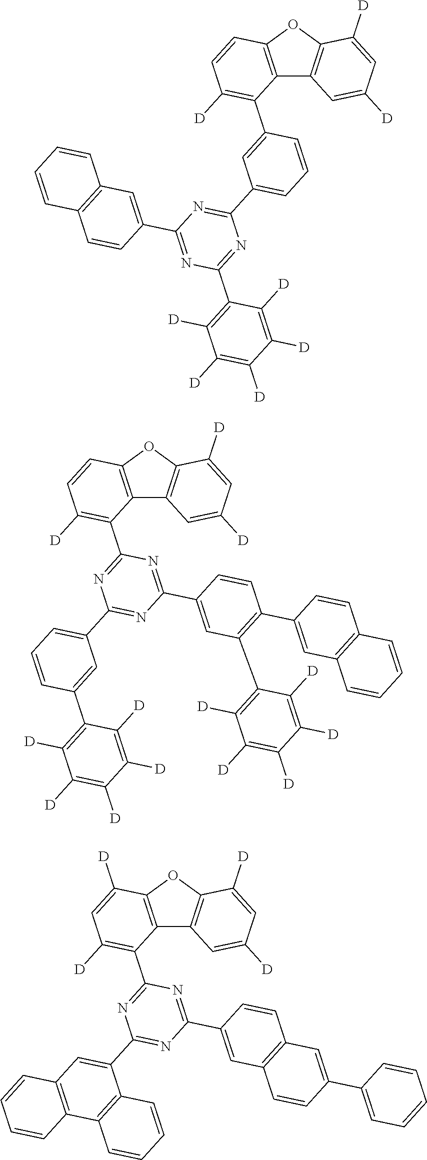

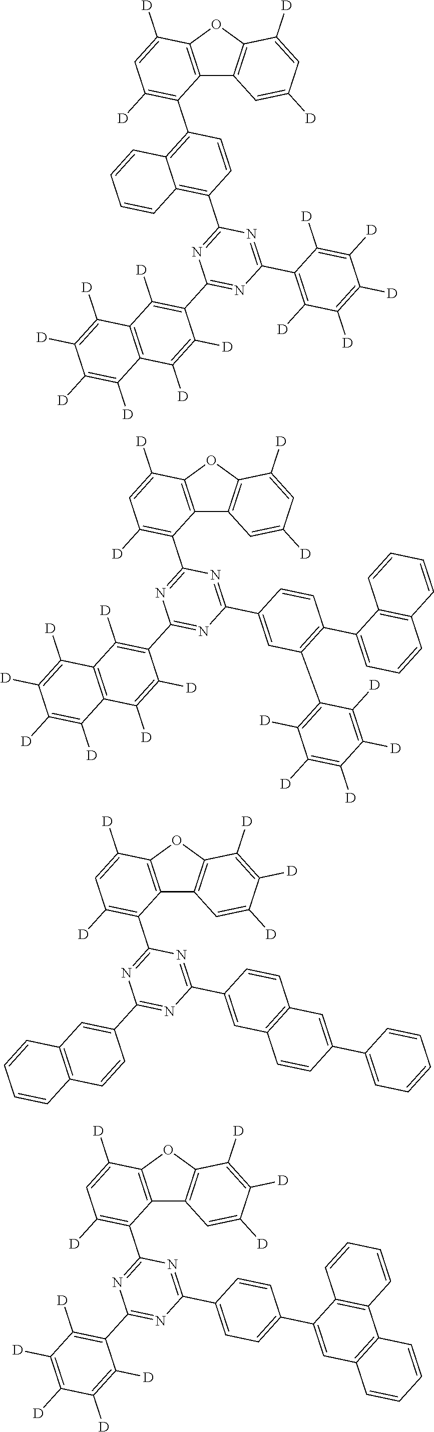

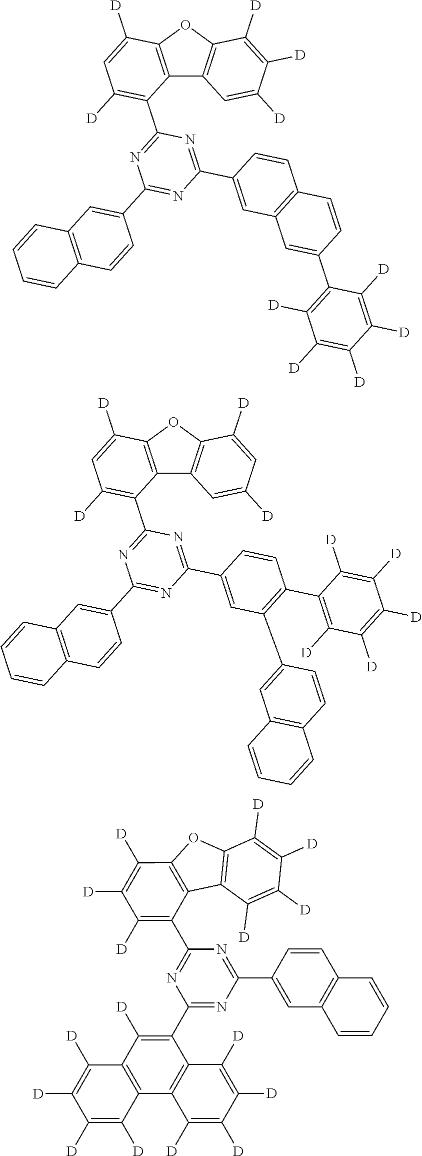

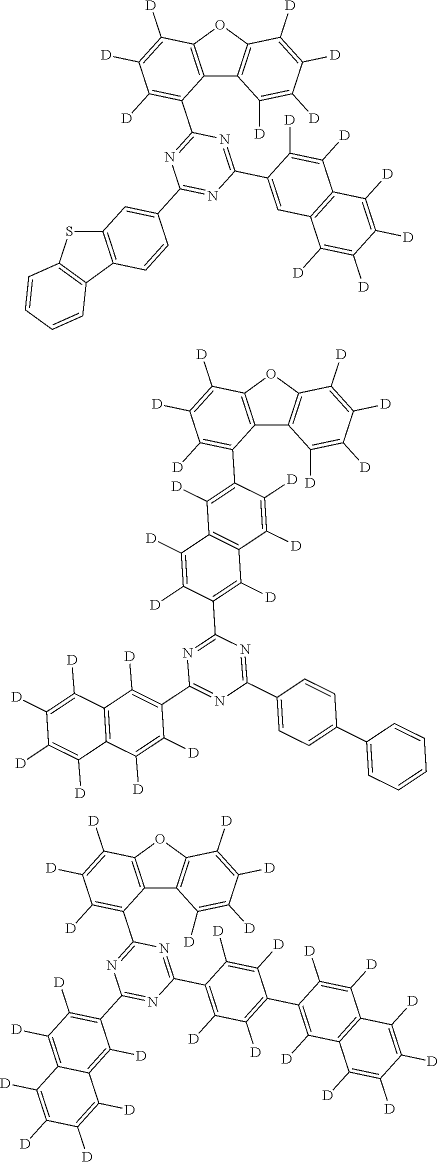

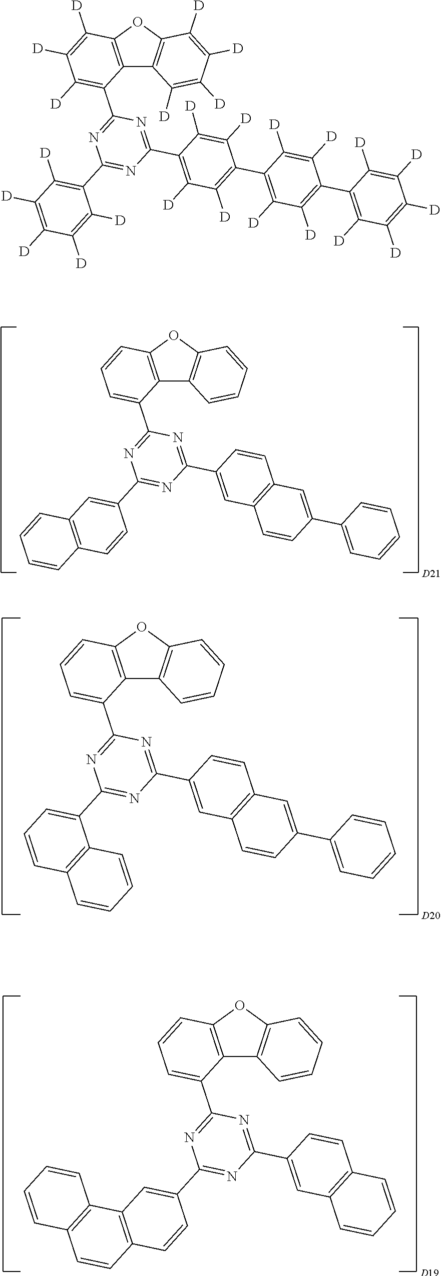

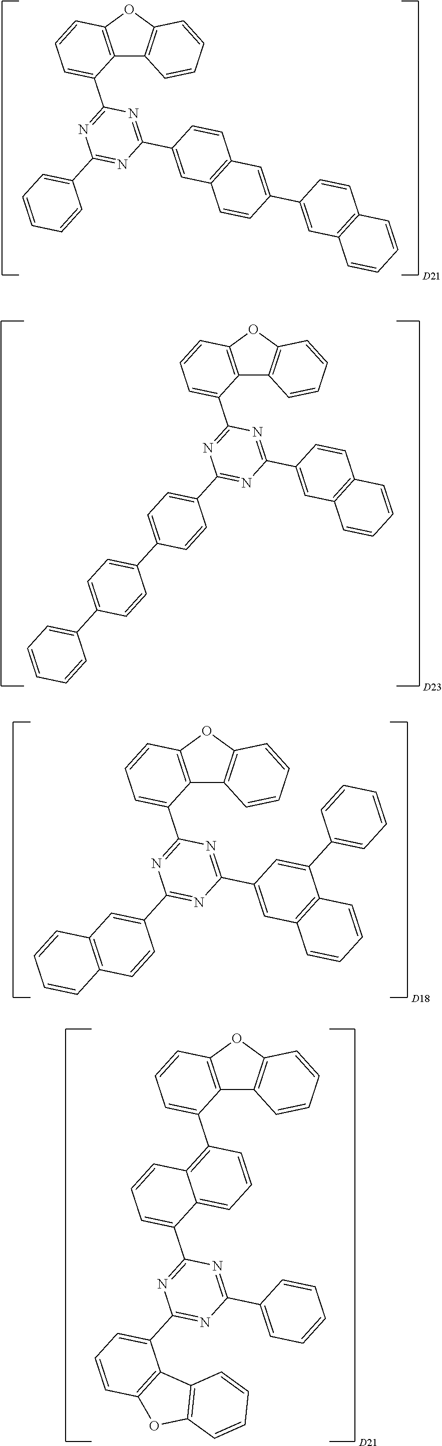

In one example, the compound represented by Chemical Formula 1 can be prepared according to the preparation method as shown in Reaction Scheme 1 below, or may be prepared by further proceeding a deuterium substitution reaction after carrying out the Reaction Scheme 1, and the remaining compounds can also be prepared in a similar manner.

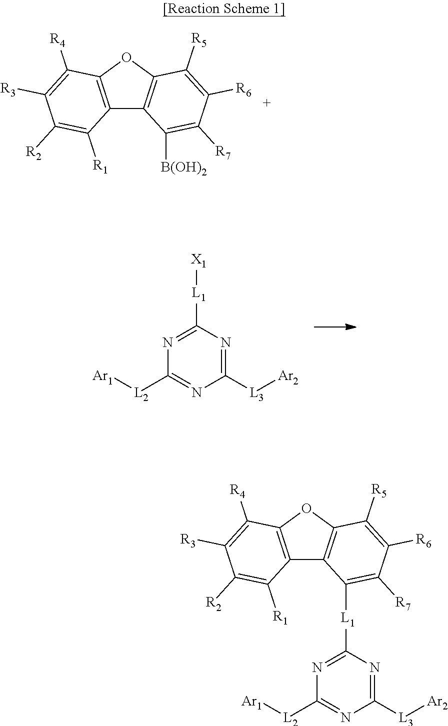

in Reaction Scheme 1, Ar₁, Ar₂, L₁ to L₃ and R₁ to R₇ are the same as defined in Chemical Formula 1, and X₁ is halogen, preferably X₁ is chloro or bromo.

Reaction Scheme 1 is a Suzuki coupling reaction, which is preferably carried out in the presence of a palladium catalyst and a base, and a reactive group for the Suzuki coupling reaction can be appropriately changed as known in the art. The above-mentioned deuterium substitution reaction is preferably carried out in the presence of D₂O, and the reactive group, catalyst, solvent, and the like for the deuterium substitution reaction can be changed to suit the desired product as known in the art. The preparation method can be more specifically described in Preparation Examples described hereinafter.

The compound represented by Chemical Formula 2 has a structure in which at least one of -L′₁-Ar′₁ and R′₁ is deuterium and therefore phenanthrenyl of Chemical Formula 2 is substituted with at least one hydrogen. Herein, ‘phenanthrenyl is substituted with at least one hydrogen’ means that ‘deuterium but no hydrogen is positioned on at least one of the nine carbons on which deuterium can be substituted in phenanthrenyl of Chemical Formula 2.’ More specifically, it means that one carbon of each of phenanthrenyl carbons contained in the compound represented by Chemical Formula 1 is substituted with deuterium, wherein the deuterium substitution rate at each of the remaining eight carbons is greater than 1%. The deuterium substitution rate at each carbon of the phenanthrenyl may be calculated by comparing the ¹H NMR spectrum of a compound not substituted with deuterium with the ¹H NMR spectrum of a compound substituted with deuterium.

Preferably, the Chemical Formula 2 may be represented by any one of the following Chemical Formulas 2A to 2I.

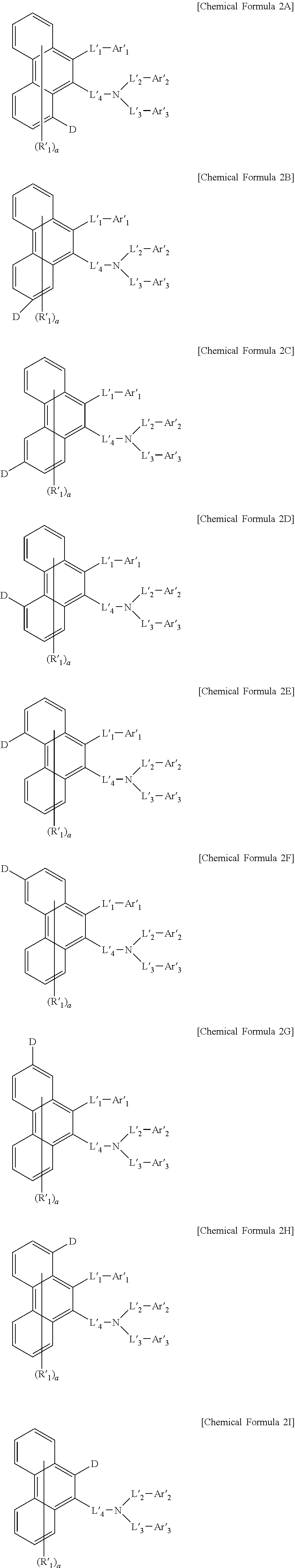

in Chemical Formulas 2A to 2I,
D is deuterium,
a′ is an integer of 0 to 7, and

Ar′₁ to Ar′₃, L′₁ to L′₄ and R′₁ are as defined in Chemical Formula 2.

Preferably, Ar′₁ may be hydrogen; deuterium; a substituted or unsubstituted C₆₋₂₀ aryl; or a substituted or unsubstituted C₂₋₂₀ heteroaryl containing at least one selected from the group consisting of N, O and S, and
more preferably, Ar′₁ may be hydrogen; deuterium; or a substituted or unsubstituted C₆₋₂₀ aryl.

More preferably, Ar′₁ may be hydrogen; deuterium; or phenyl which is unsubstituted or substituted with at least one deuterium.

Preferably, Ar′₂ and Ar′₃ may be each independently a substituted or unsubstituted C₆₋₂₀ aryl; or a substituted or unsubstituted C₂₋₂₀ heteroaryl containing at least one selected from the group consisting of N, O and S, and
more preferably, Ar′₂ and Ar′₃ may be each independently phenyl, biphenylyl, terphenylyl, quarterphenylyl, naphthyl, phenyl naphthyl, naphthyl phenyl, tetrahydronaphthyl, phenanthrenyl, phenyl phenanthrenyl, triphenylenyl, dimethylfluorenyl, diphenylfluorenyl, carbazolyl, phenyl carbazolyl, dibenzofuranyl, dibenzothiophenyl, or phenyl dibenzofuranyl, wherein the phenyl, biphenylyl, terphenylyl, quarterphenylyl, naphthyl, phenyl naphthyl, naphthyl phenyl, tetrahydronaphthyl, phenanthrenyl, phenyl phenanthrenyl, triphenylenyl, dimethylfluorenyl, diphenylfluorenyl, carbazolyl, phenyl carbazolyl, dibenzofuranyl, dibenzothiophenyl, and phenyl dibenzofuranyl may be each independently unsubstituted or substituted with at least one deuterium, or at least one C₁₋₁₀ alkyl.

Most preferably, Ar′₂ and Ar′₃ may be each independently phenyl, biphenylyl, terphenylyl, quarterphenylyl, naphthyl, phenyl naphthyl, naphthyl phenyl, tetrahydronaphthyl, phenanthrenyl, phenyl phenanthrenyl, triphenylenyl, dimethylfluorenyl, diphenylfluorenyl, carbazolyl, phenyl carbazolyl, dibenzofuranyl, dibenzothiophenyl, phenyl dibenzofuranyl, tetramethyl tetrahydronaphthyl, methyl phenyl, isopropyl phenyl, tert-butyl phenyl, di-tert-butyl phenyl, methyl biphenylyl, isopropyl biphenylyl, tert-butyl biphenylyl, dimethyl biphenylyl, diisopropyl biphenylyl, di-tert-butyl biphenylyl, methyl terphenylyl, isopropyl terphenylyl, or tertbutyl terphenylyl, wherein the phenyl, biphenylyl, terphenylyl, quarterphenylyl, naphthyl, phenyl naphthyl, naphthyl phenyl, tetrahydronaphthyl, phenanthrenyl, phenyl phenanthrenyl, triphenylenyl, dimethylfluorenyl, diphenylfluorenyl, carbazolyl, phenyl carbazolyl, dibenzofuranyl, dibenzothiophenyl, phenyl dibenzofuranyl, tetramethyl tetrahydronaphthyl, methyl phenyl, isopropyl phenyl, tert-butyl phenyl, di-tert-butyl phenyl, methyl biphenylyl, isopropyl biphenylyl, tert-butyl biphenylyl, dimethyl biphenylyl, diisopropyl biphenylyl, di-tert-butyl biphenylyl, methyl terphenylyl, isopropyl terphenylyl, and tertbutyl terphenylyl may be each independently unsubstituted or substituted with at least one deuterium.

Most preferably, Ar′₂ and Ar′₃ may be each independently phenyl, biphenylyl, terphenylyl, naphthyl, phenanthrenyl, tetrahydronaphthyl, tetramethyltetrahydronaphthyl, phenyl substituted with one or two methyl groups, phenyl substituted with one or two isopropyl groups, phenyl substituted with one or two tertbutyl groups, dibenzofuranyl, or dibenzothiophenyl, wherein the phenyl, biphenylyl, terphenylyl, naphthyl, phenanthrenyl, tetrahydronaphthyl, tetramethyltetrahydronaphthyl, phenyl substituted with one or two methyl groups, phenyl substituted with one or two isopropyl groups, phenyl substituted with one or two tertbutyl groups, dibenzofuranyl, and dibenzothiophenyl may be each independently unsubstituted or substituted with at least one deuterium.

Preferably, L′₁ to L′₃ are each independently a single bond; a substituted or unsubstituted C₆₋₂₀ arylene; or a substituted or unsubstituted C₂₋₂₀ heteroarylene containing at least one selected from the group consisting of N, O and S, and
more preferably, L′₁ to L′₃ may be each independently a single bond, phenylene, biphenylylene, naphthylene, phenyl naphthylene, phenanthrenylene, carbazolylene, phenyl carbazolylene, dibenzofuranylene, phenyl dibenzofuranylene, or dimethylfluorenylene, wherein the phenylene, biphenylylene, naphthylene, phenyl naphthylene, phenanthrenylene, carbazolylene, phenyl carbazolylene, dibenzofuranylene, phenyl dibenzofuranylene, and dimethylfluorenylene may be each independently unsubstituted or substituted with at least one deuterium.

Preferably, L′₁ may be a single bond, and L′₂ and L′₃ may be each independently a single bond; a substituted or unsubstituted C₆₋₂₀ arylene; or a substituted or unsubstituted C₂₋₂₀ heteroarylene containing at least one selected from the group consisting of N, O and S, and
more preferably, L′₁ may be a single bond, and L′₂ and L′₃ may be each independently a single bond, phenylene, biphenylylene, naphthylene, phenyl naphthylene, phenanthrenylene, carbazolylene, phenyl carbazolylene, dibenzofuranylene, phenyl dibenzofuranylene, or dimethylfluorenylene, wherein the phenylene, biphenylylene, naphthylene, phenyl naphthylene, phenanthrenylene, carbazolylene, phenyl carbazolylene, dibenzofuranylene, phenyl dibenzofuranylene, and dimethylfluorenylene may be each independently unsubstituted or substituted with at least one deuterium.

Most preferably, L′₁ may be a single bond, and L′₂ and L′₃ may be each independently a single bond, phenylene, biphenylylene, naphthylene, or phenyl naphthylene, wherein the phenylene, biphenylylene, naphthylene, and phenyl naphthylene may be each independently unsubstituted or substituted with at least one deuterium.

Preferably, L′₄ may be a single bond or a substituted or unsubstituted C₆₋₂₀ arylene,
more preferably, L′₄ may be a single bond, a substituted or unsubstituted phenylene, a substituted or unsubstituted biphenylylene, or a substituted or unsubstituted naphthylene,
most preferably, L′₄ may be a single bond, phenylene, biphenylylene or naphthylene, wherein the phenylene, biphenylylene and naphthylene may be each independently unsubstituted or substituted with at least one deuterium.

Preferably, the compound represented by Chemical Formula 2 may be represented by the following Chemical Formula 2-1:

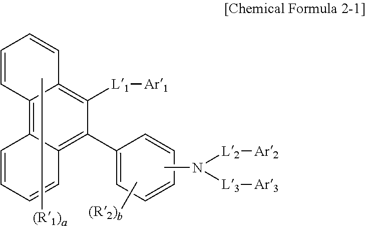

in Chemical Formula 2-1,
Ar′₁ to Ar′₃, L′₁ to L′₃, R′₁ and a are as defined in Chemical Formula 2,
R′₂ is hydrogen; deuterium; or a substituted or unsubstituted C₆₋₆₀ aryl, and
b is an integer of 0 to 4.

Preferably, R′₂ is hydrogen; deuterium; or a substituted or unsubstituted C₆₋₂₀ aryl, and
more preferably, R′₂ may be hydrogen, deuterium, or phenyl which is unsubstituted or substituted with deuterium.

The deuterium substitution rate of the compound represented by Chemical Formula 2 may be 50% to 100%. Specifically, the deuterium substitution rate of the compound may be 50% or more, 60% or more, 70% or more, 75% or more, 80% or more, or 90% or more, and 100% or less.

In one example, the compound represented by Chemical Formula 2 may include 16 to 50 deuteriums, but is not limited thereto. More specifically, the compound may include 16 or more, 17 or more, 18 or more, or 19 or more, and 50 or less, 45 or less, 40 or less, 38 or less, 36 or less, 34 or less, 32 or less, 30 or less, 28 or less, 26 or less, 24 or less, 23 or less, 22 or less, 21 or less, or 20 or less deuteriums.

In this case, when the number of deuterium substitutions in the compound is to be represented, it may be represented by the following Chemical Formula 2-D:

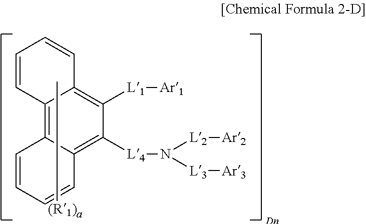

in Chemical Formula 2-D,
   Dn means that the total number of substituted deuterium (D) in the entire compound is n,
R′₁ and a are as defined in Chemical Formula 2,
the n is a value including a,
Ar′_{1d} to Ar′_{3d} and L′_{1d} to L′_{4d} mean substituents Ar′₁ to Ar′₃ and L′₁ to L′₄ that are not substituted with deuterium, respectively, and
at least one of -L′_{1d}-Ar′_{1d} and R′₁ is deuterium.

That is, in the Chemical Formula 2-D, n is the total number of deuterium substituted in the compound, which is an integer whose deuterium substitution rate of the compound is 50% or more, and is a value including a or a+1, which is the number of deuterium substituted in phenanthrenyl. The compound represented by Chemical Formula 2-D means a compound in which phenanthrenyl is substituted with a or a+1 deuterium atoms and the entire compound is substituted with n deuterium atoms. The reason why the number of deuteriums substituted on the phenanthrenyl is a or a+1 is because -L′_{1d}-Ar′_{1d} may be deuterium.

In one example, in Chemical Formula 2-D, n of the Dn may be 16 or more, 17 or more, or 18 or more, or 19 or more, and 50 or less, 45 or less, 40 or less, 38 or less, 36 or less, 34 or less, 32 or less, 30 or less, 28 or less, 26 or less, 24 or less, 23 or less, 22 or less, 21 or less, or 20 or less.

Representative examples of the compound represented by Chemical Formula 2 are as follows:

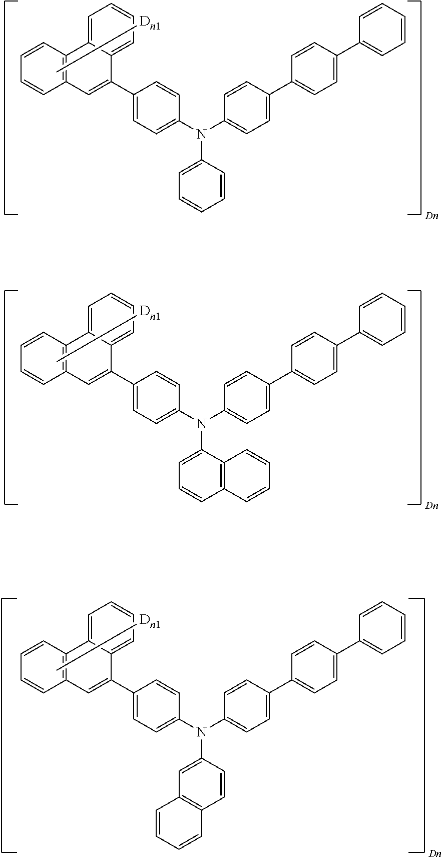

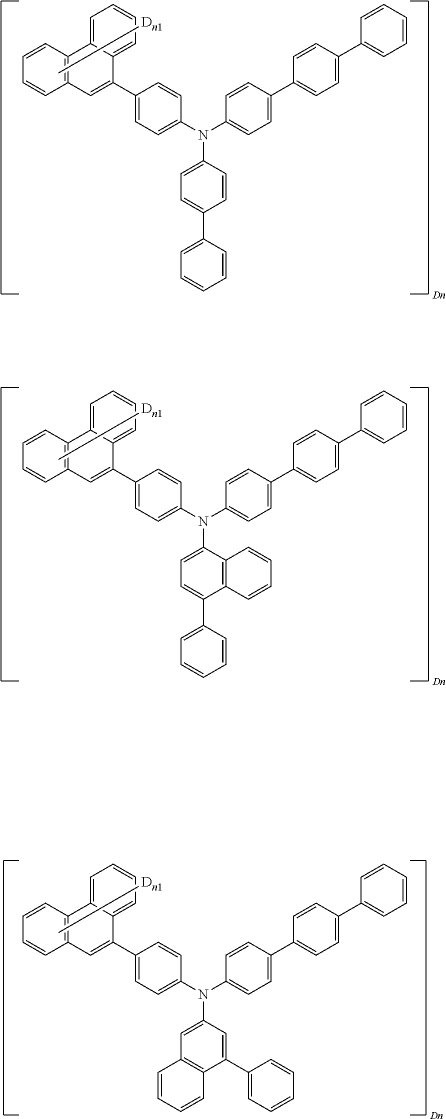

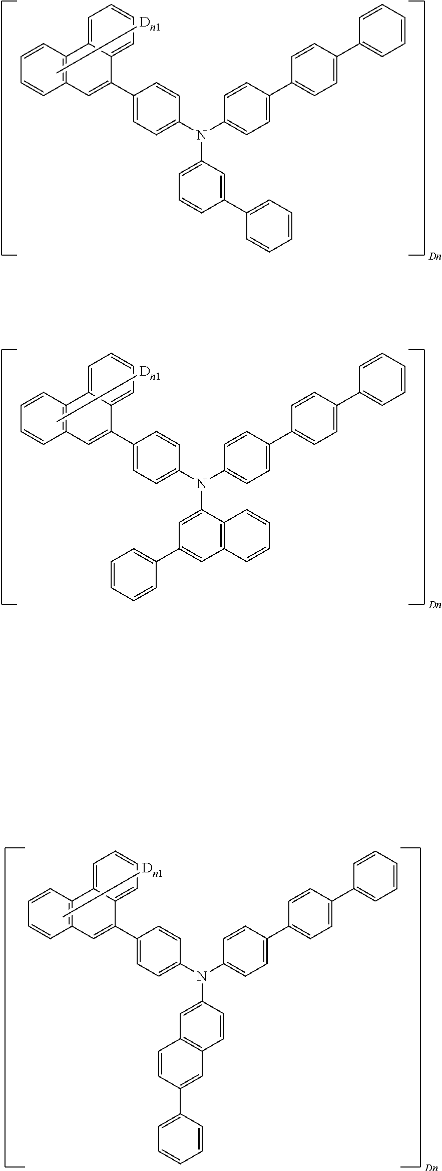

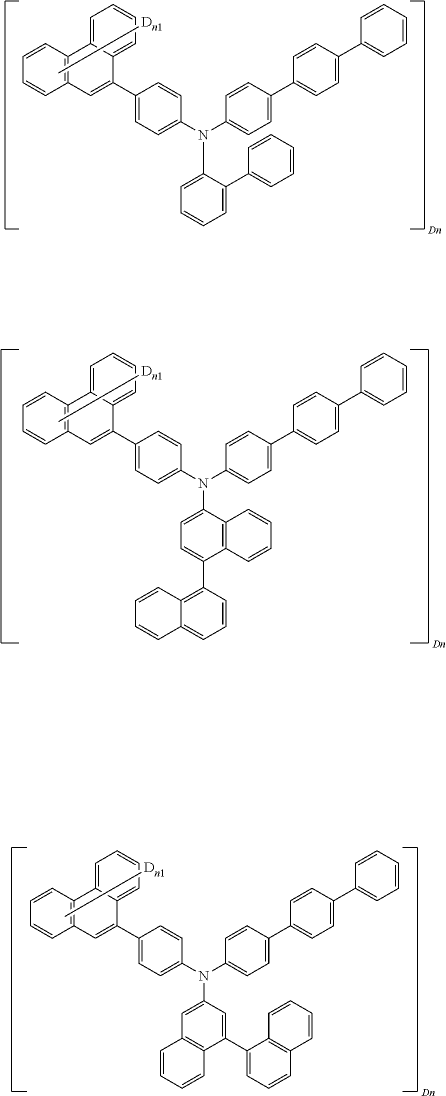

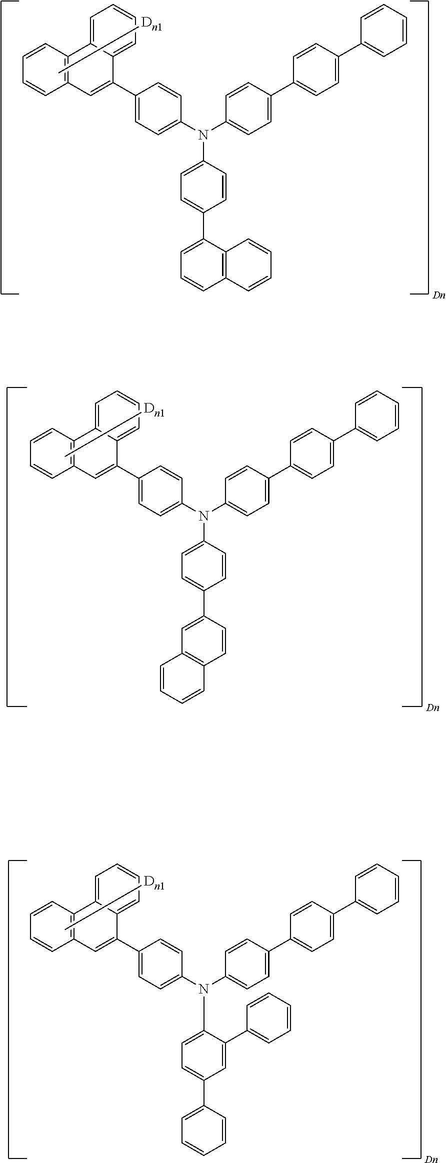

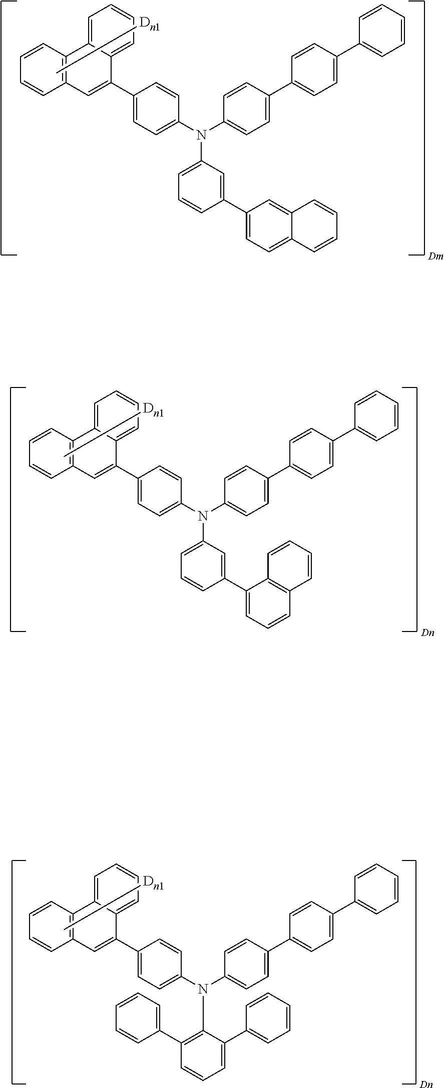

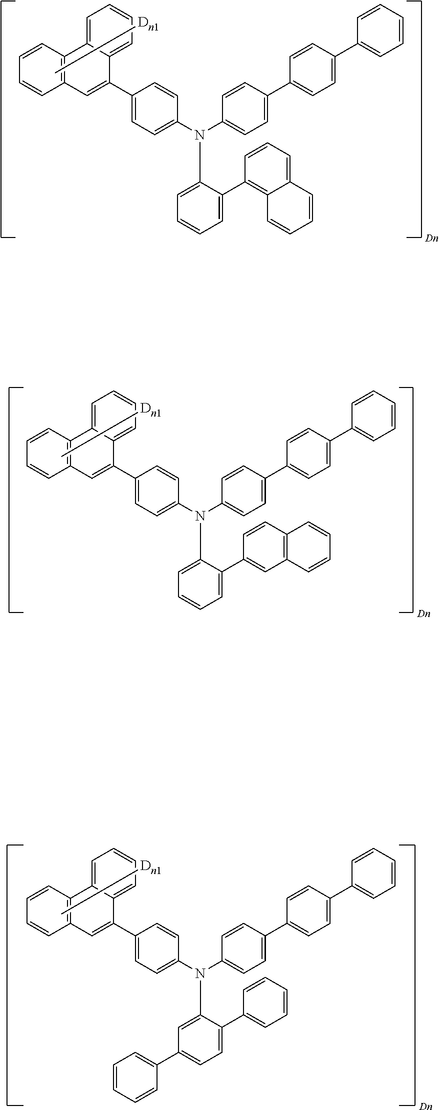

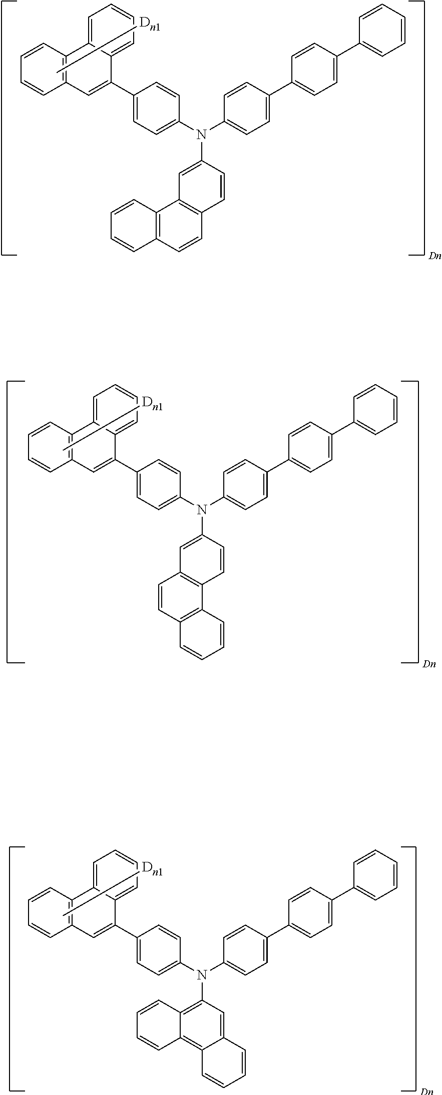

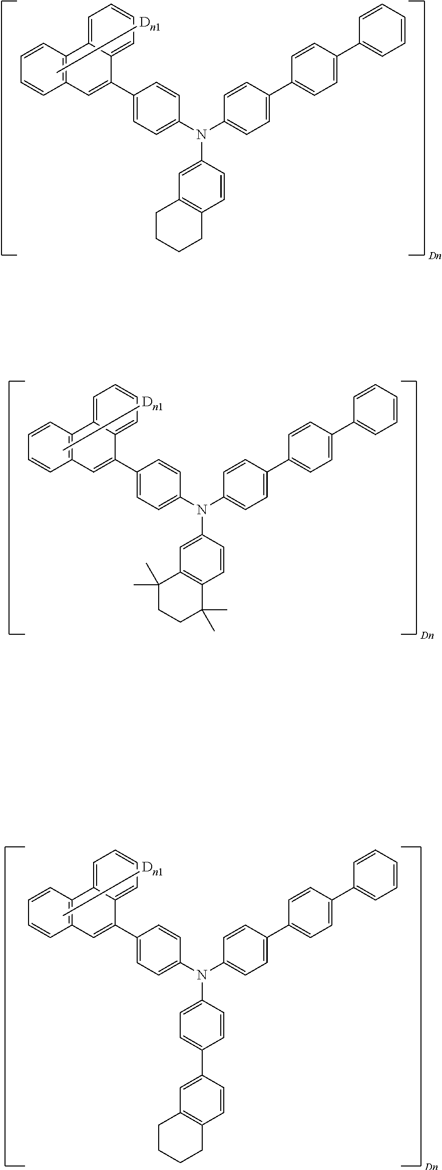

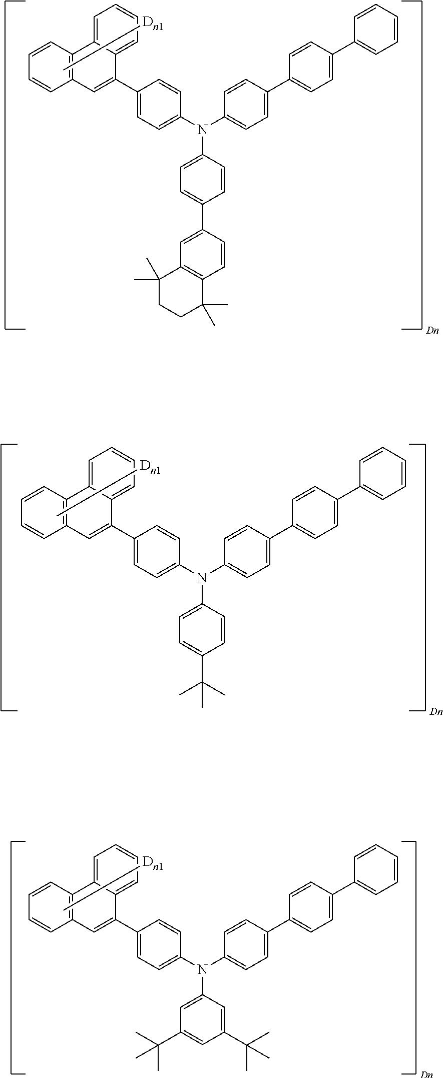

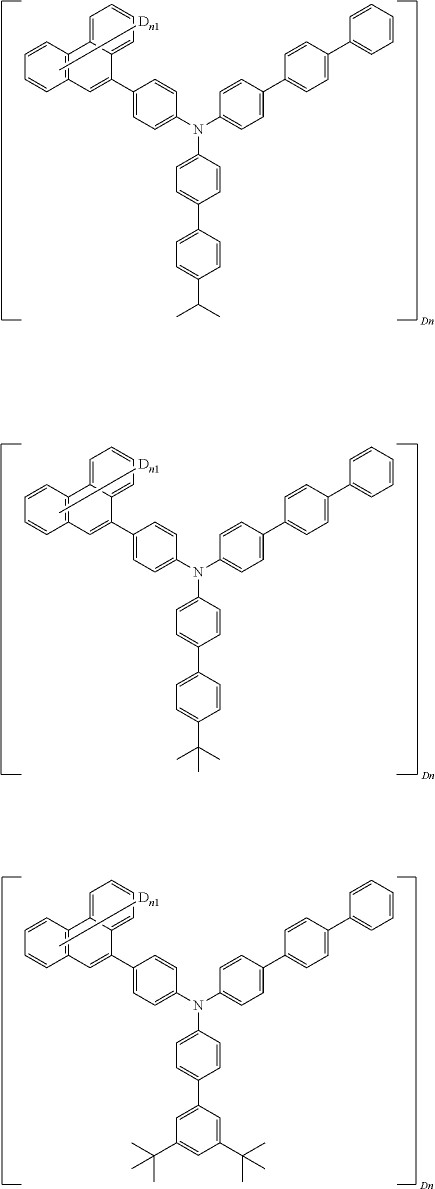

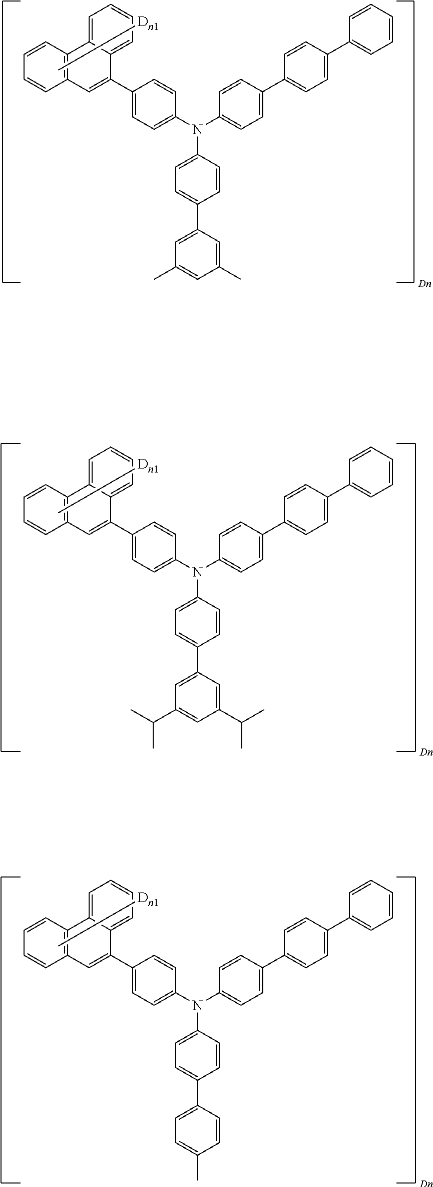

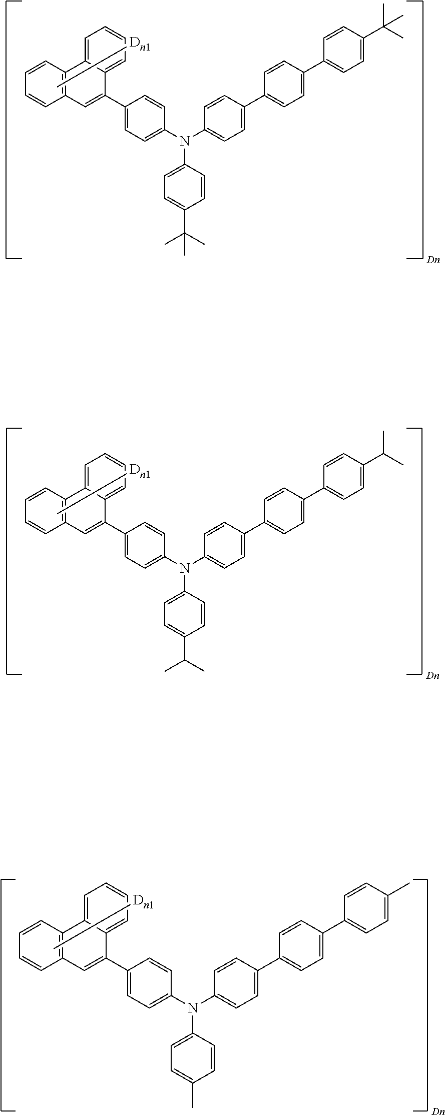

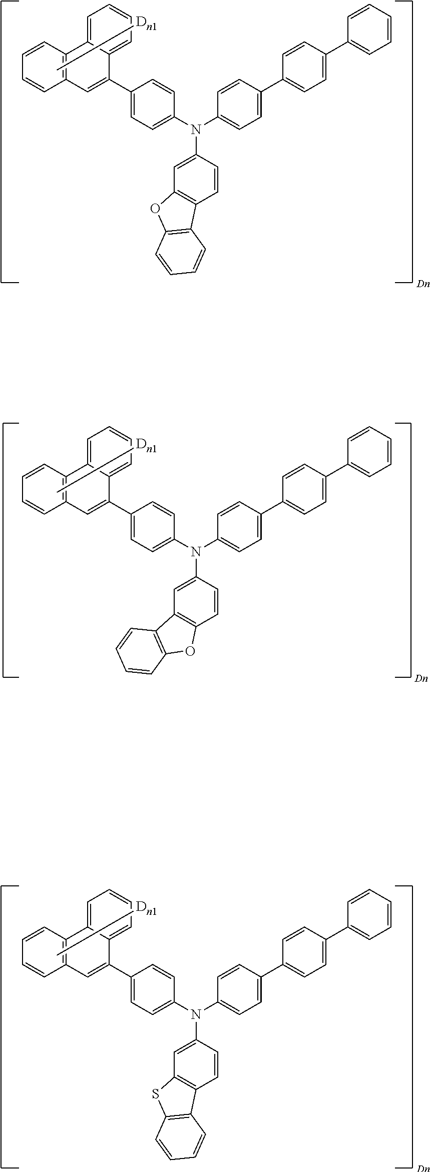

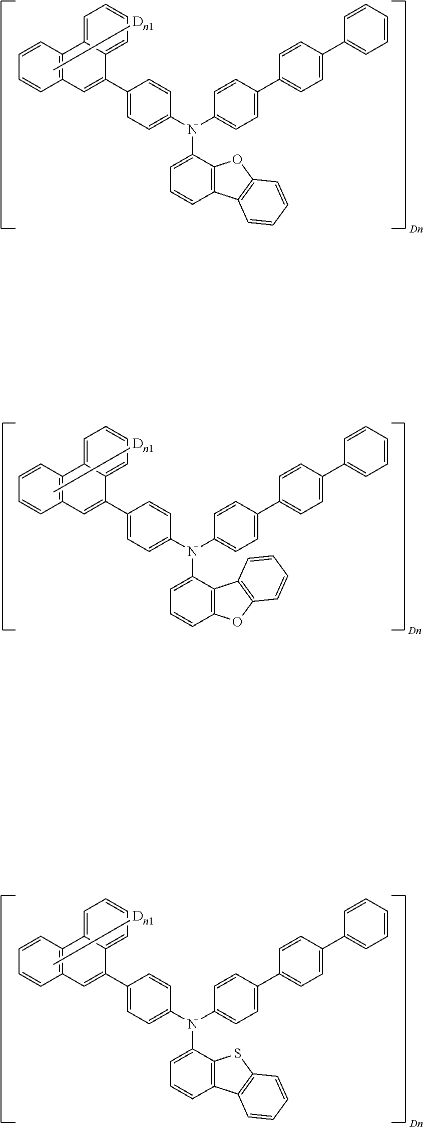

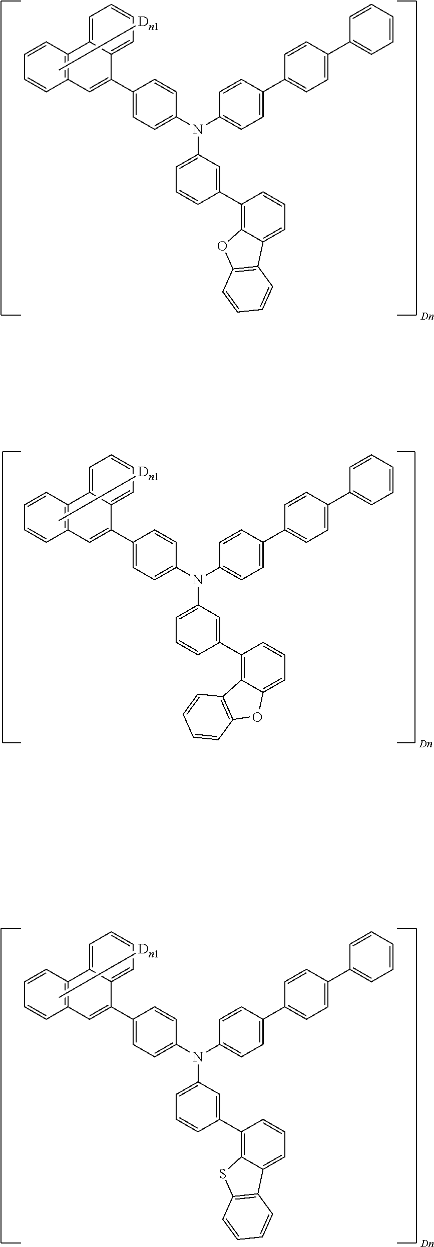

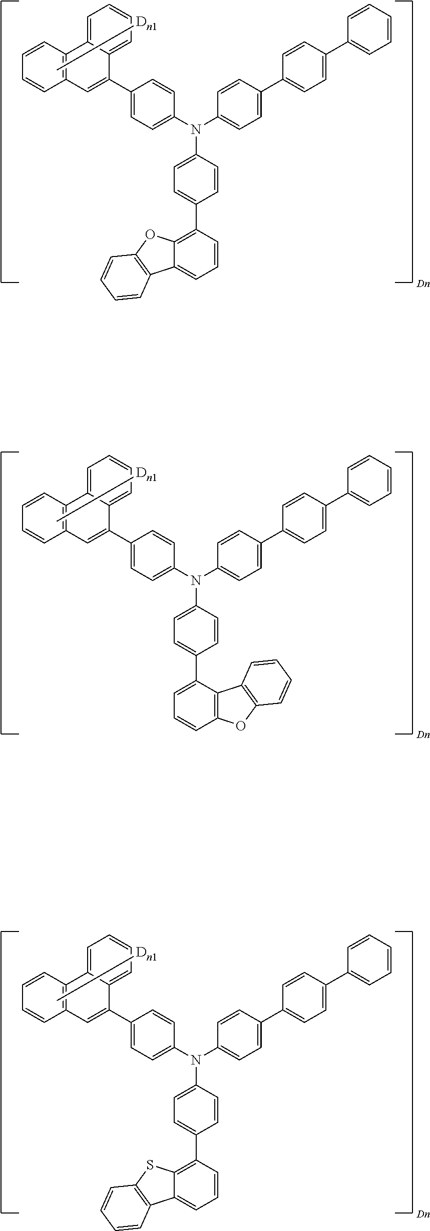

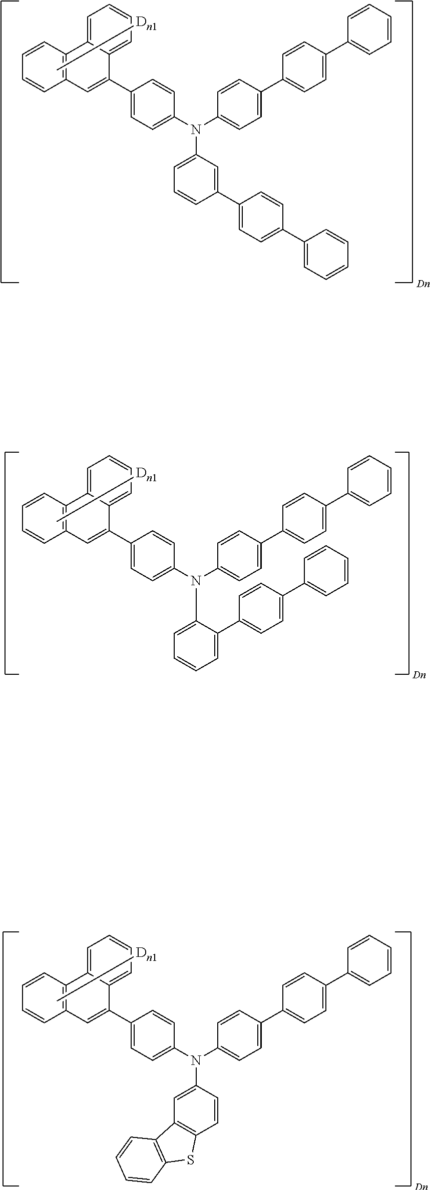

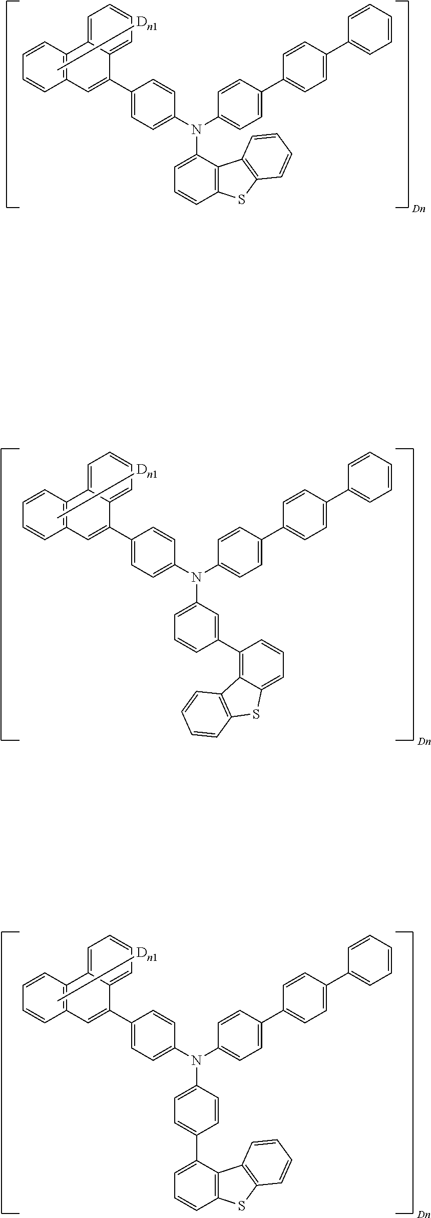

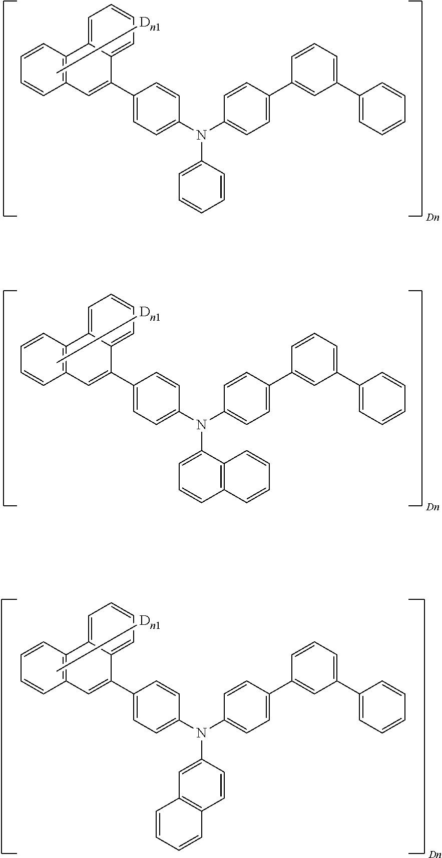

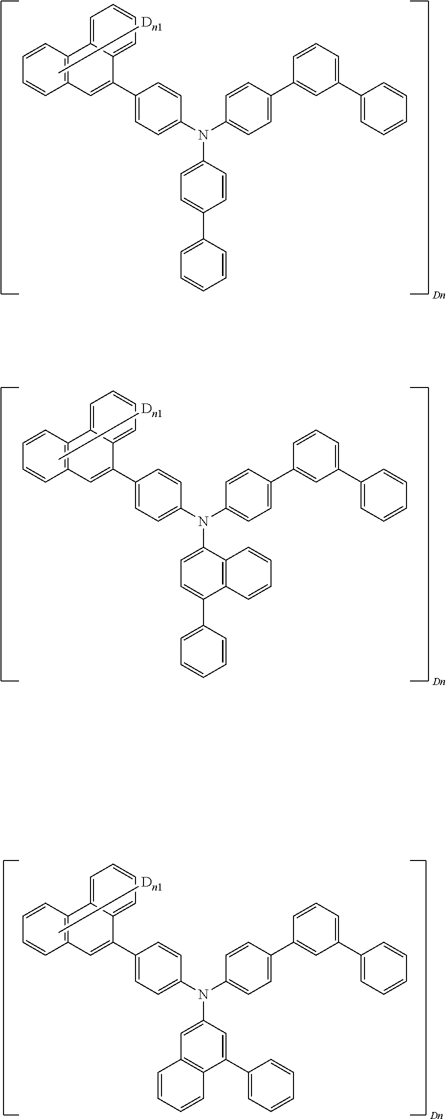

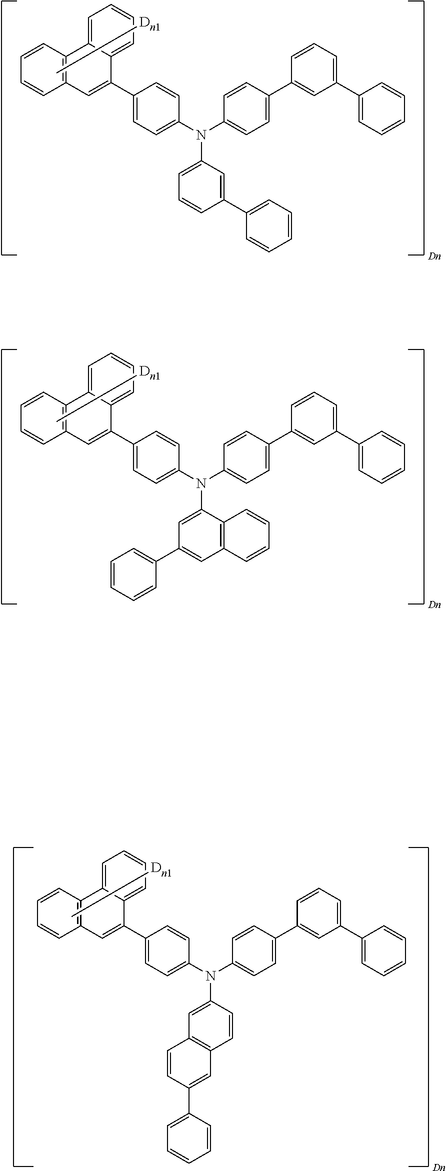

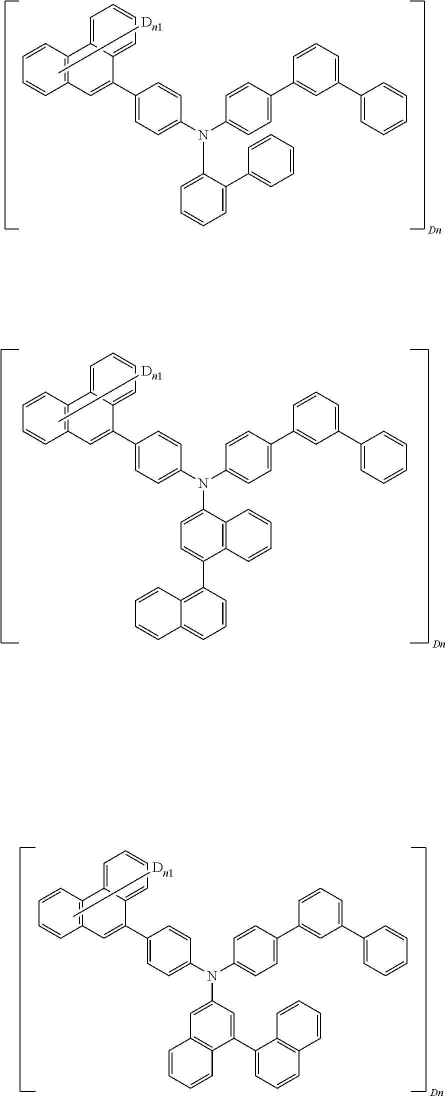

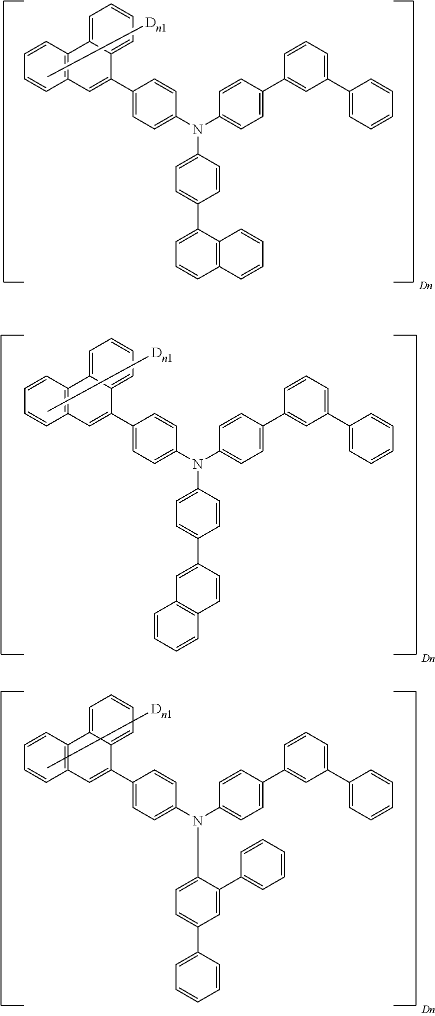

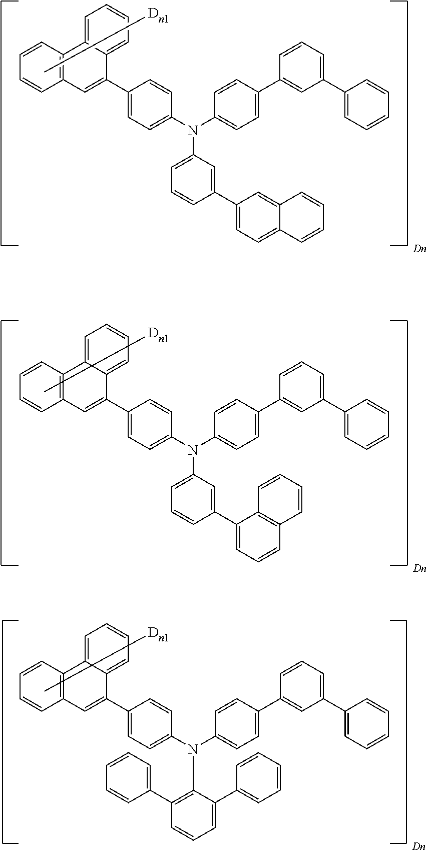

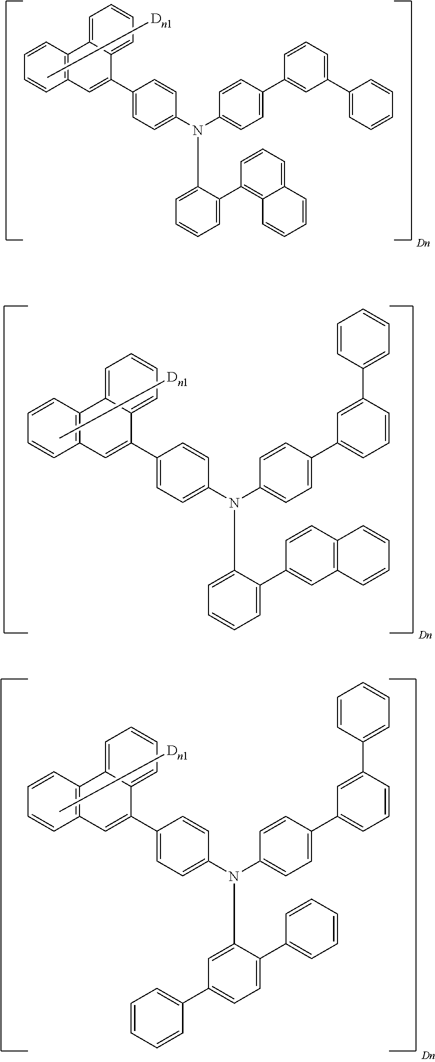

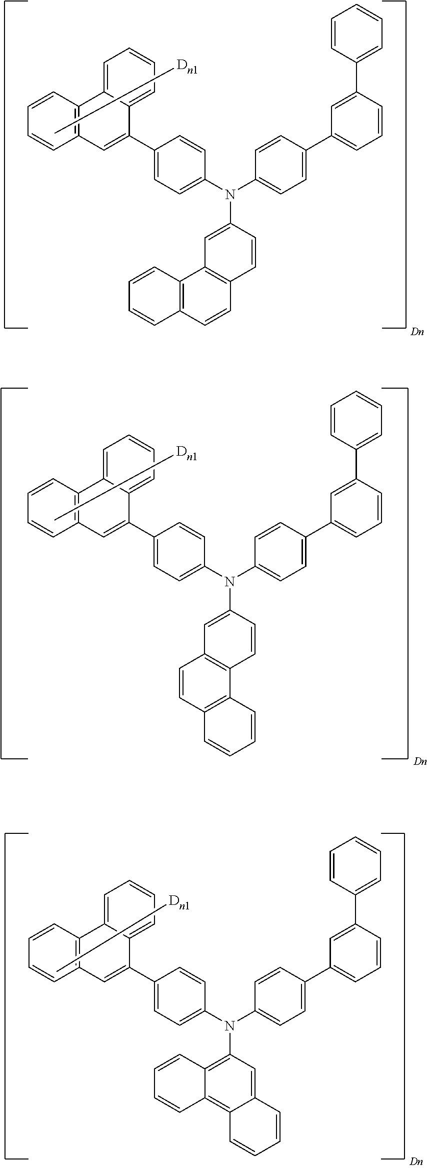

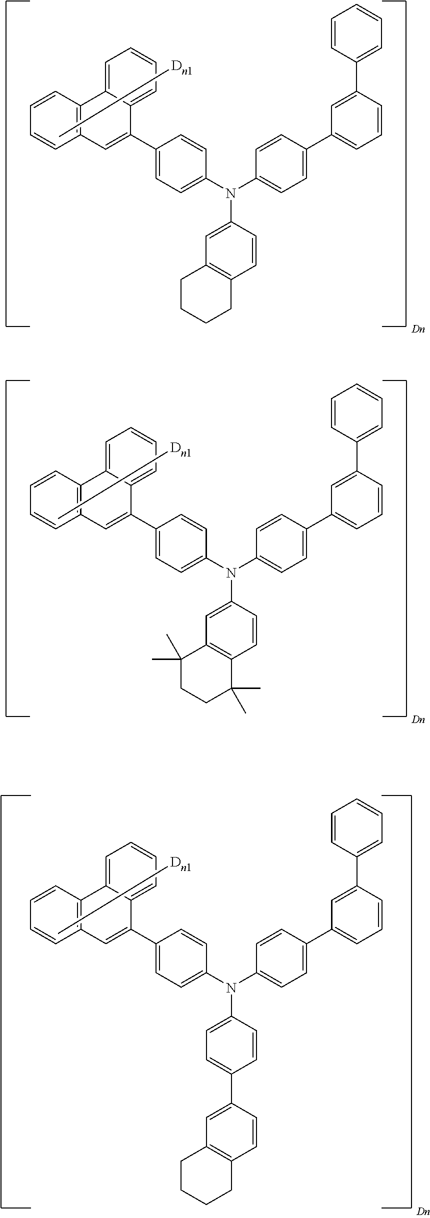

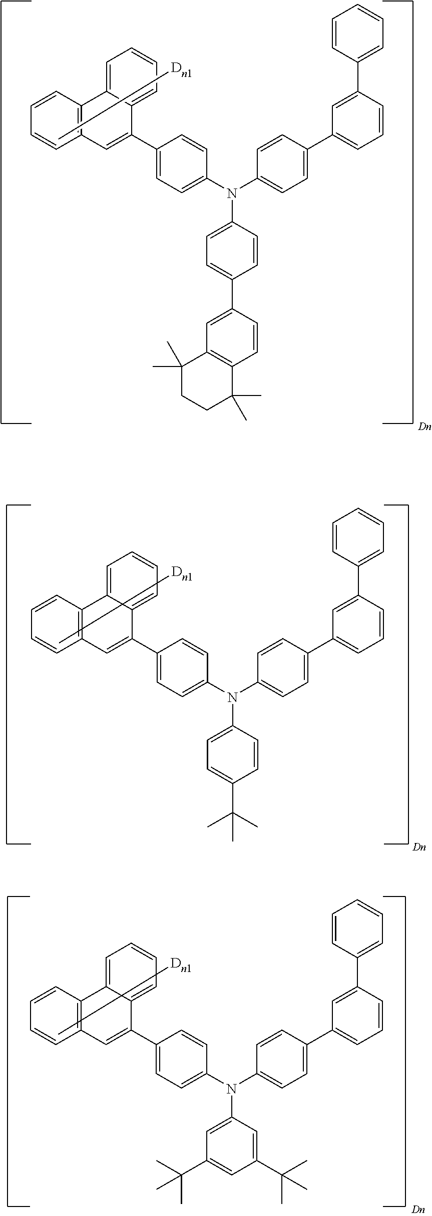

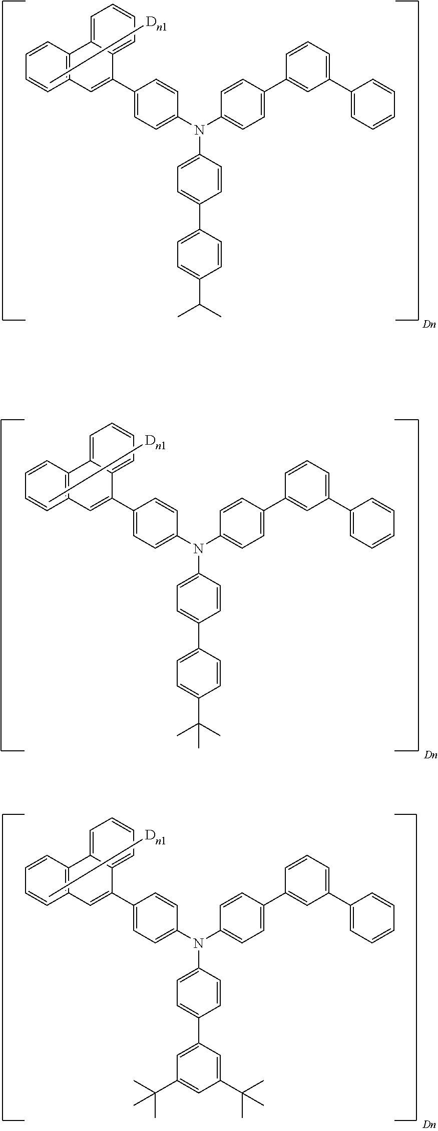

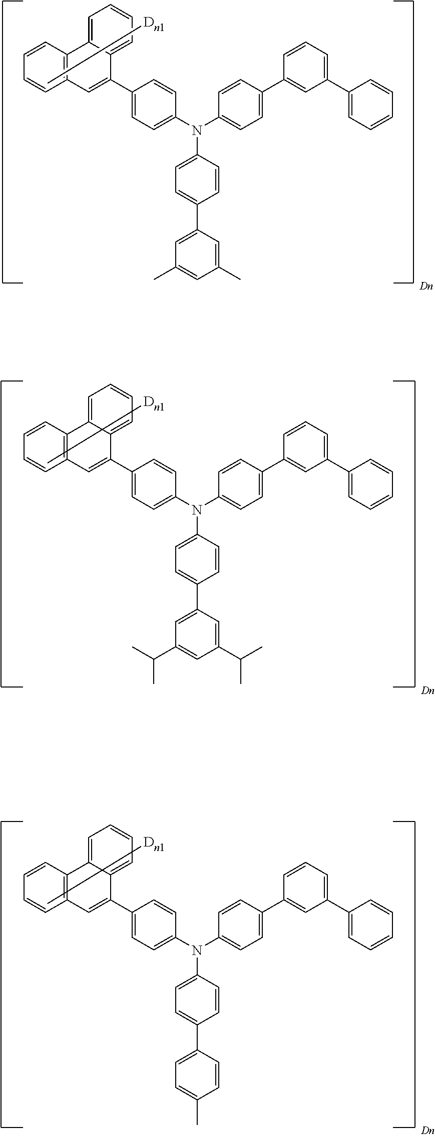

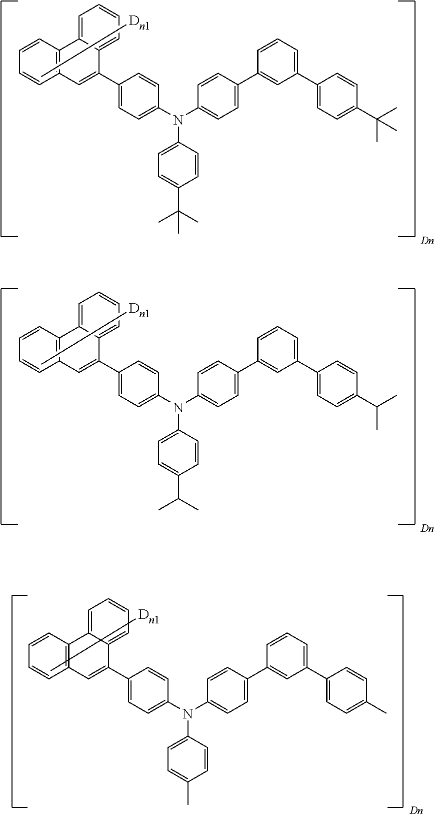

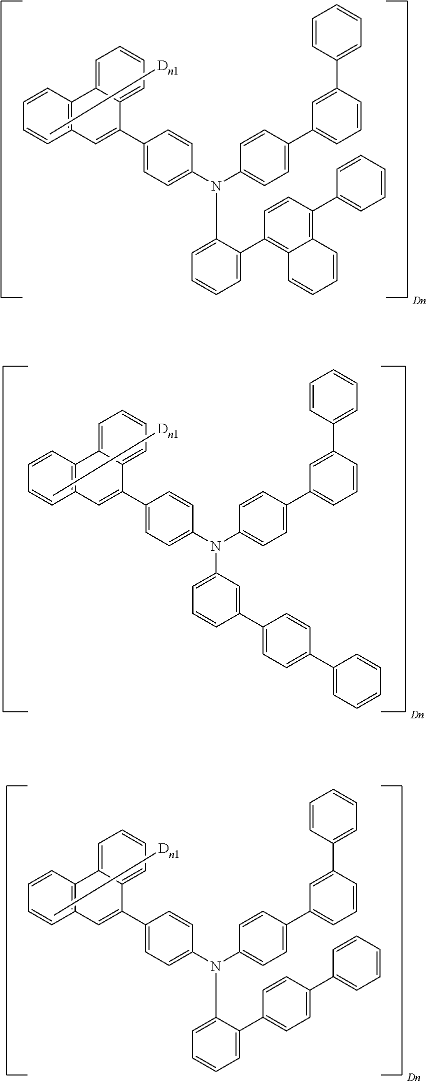

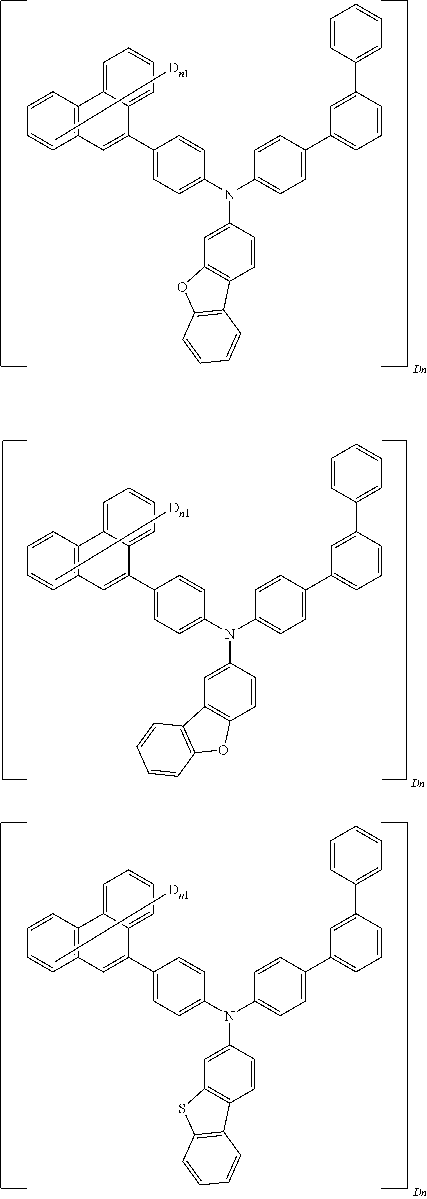

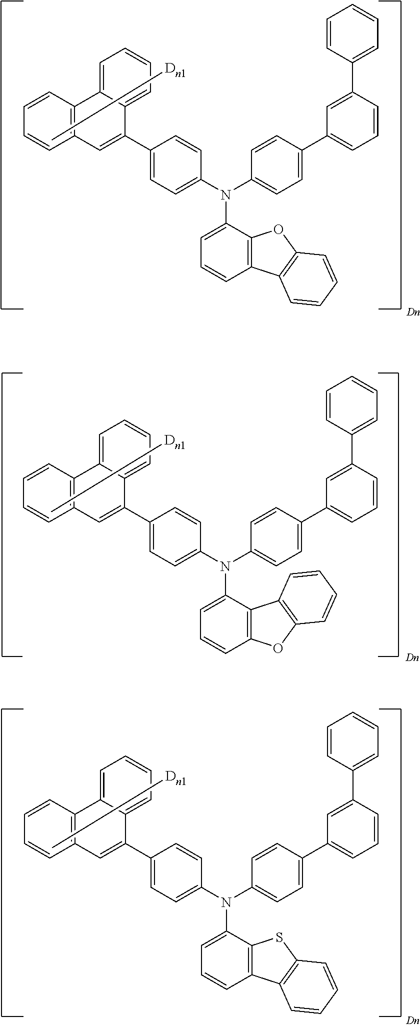

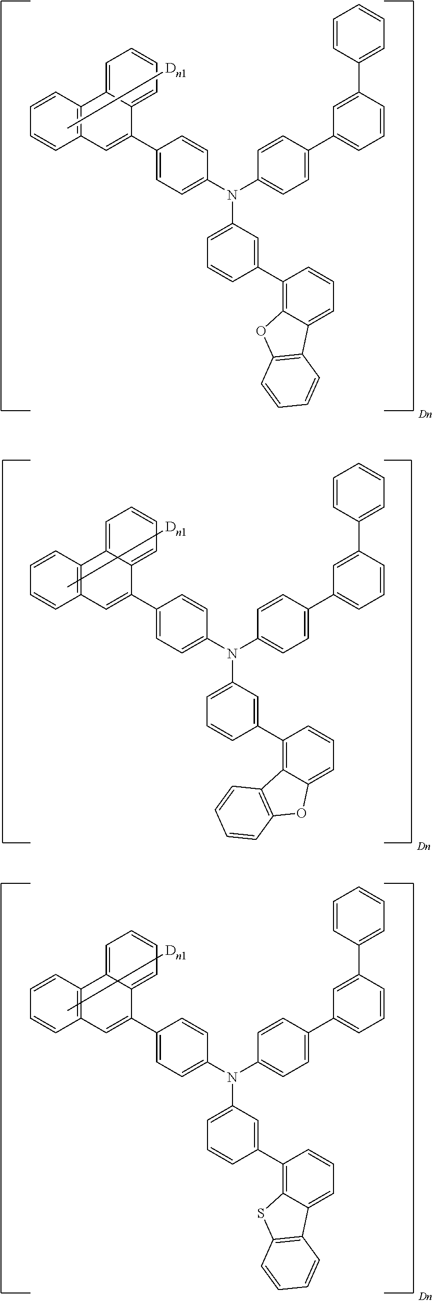

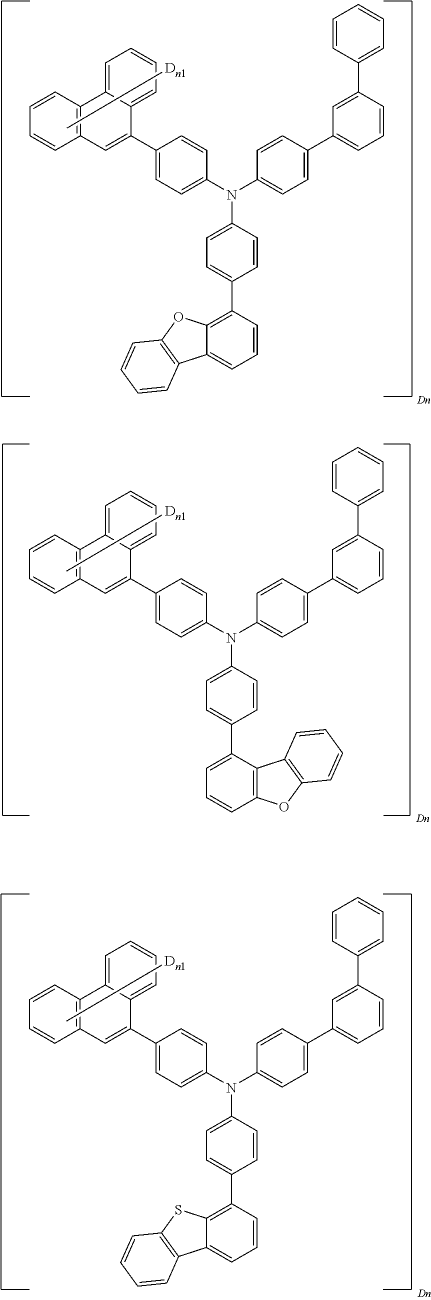

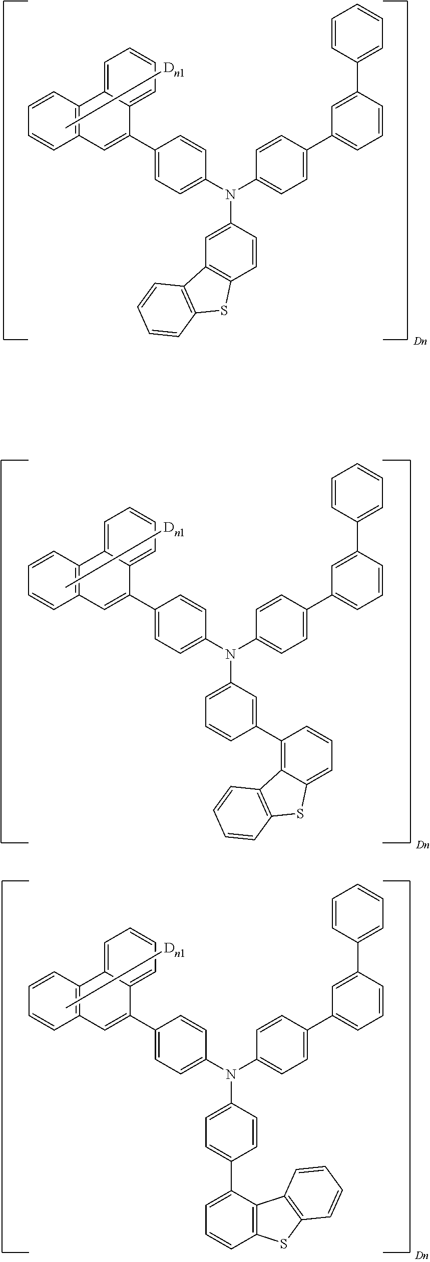

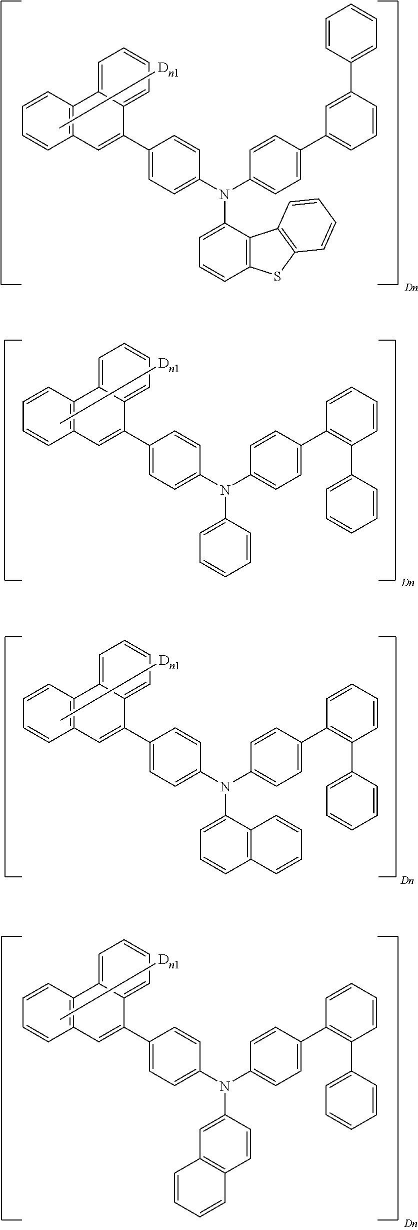

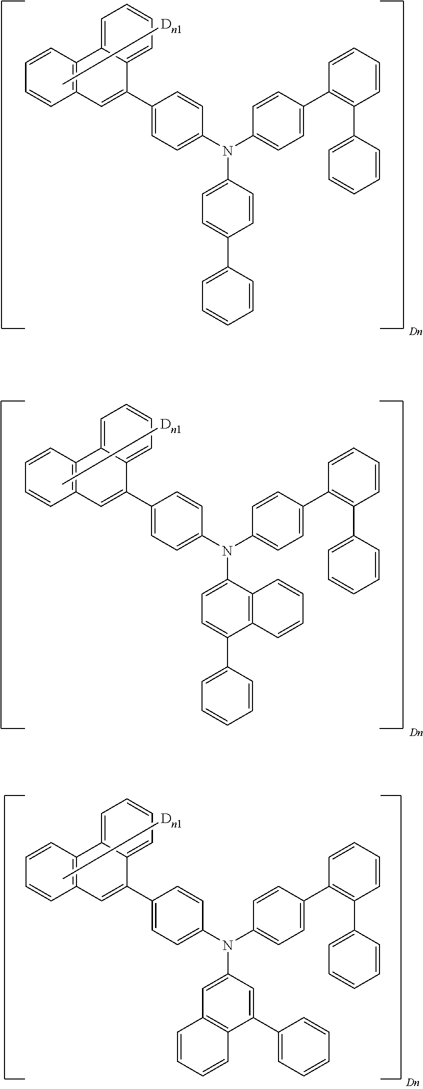

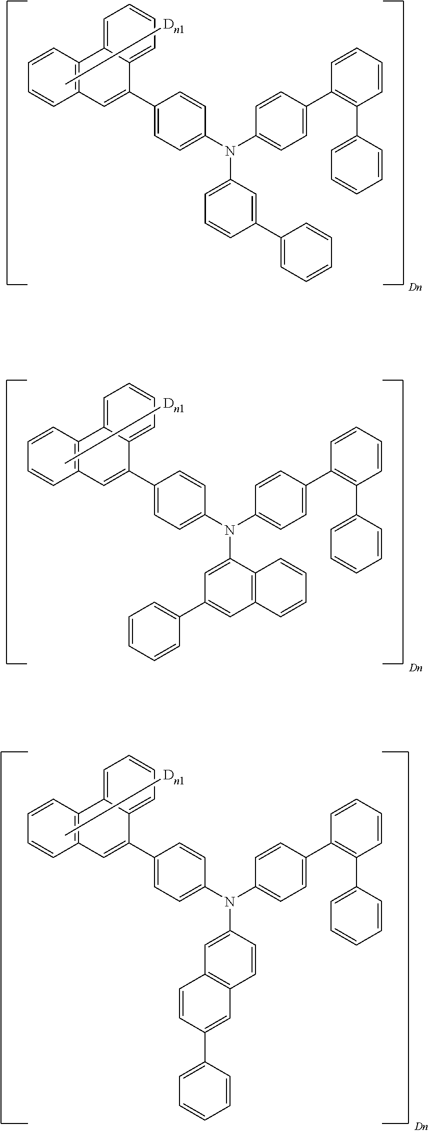

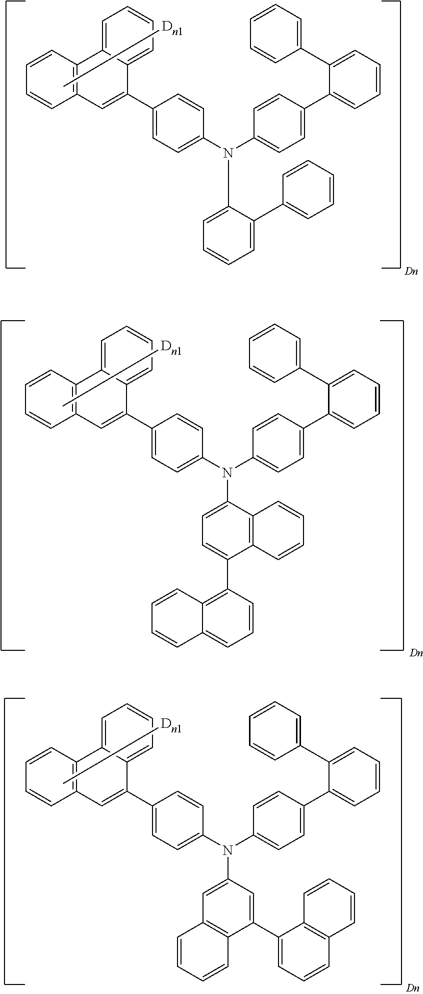

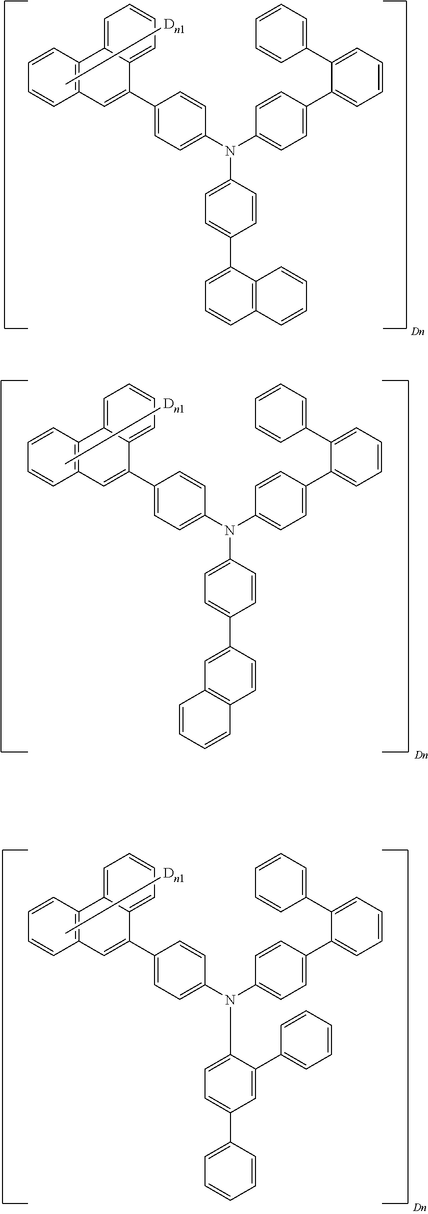

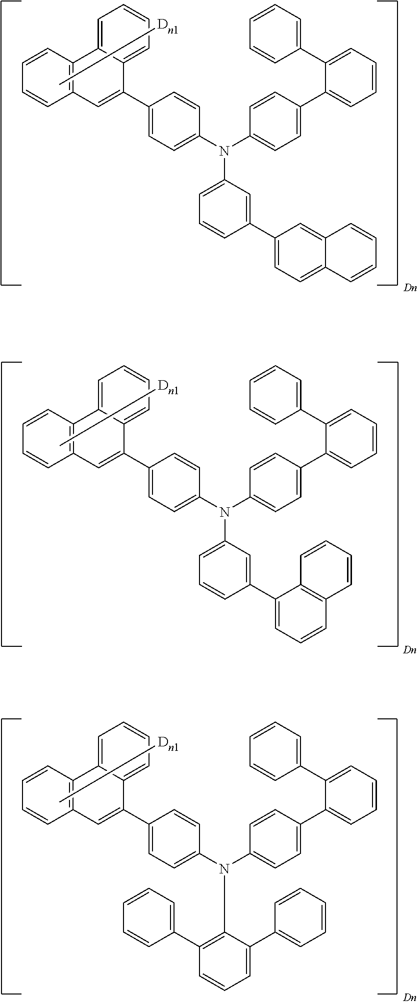

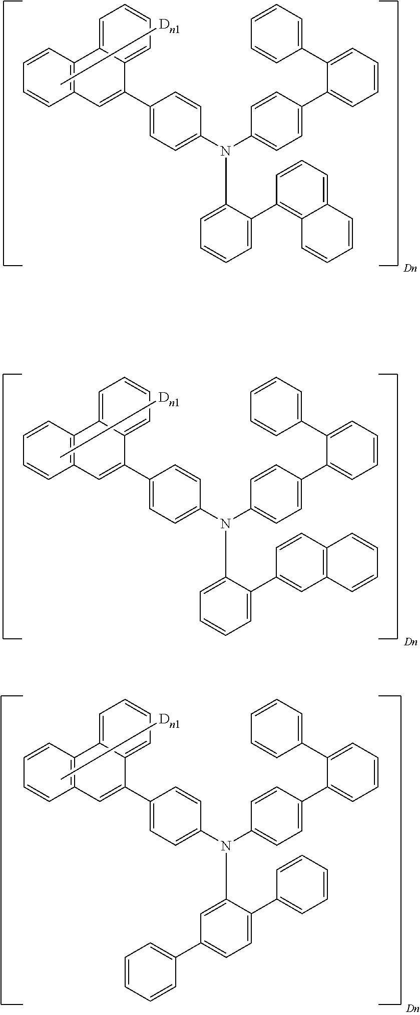

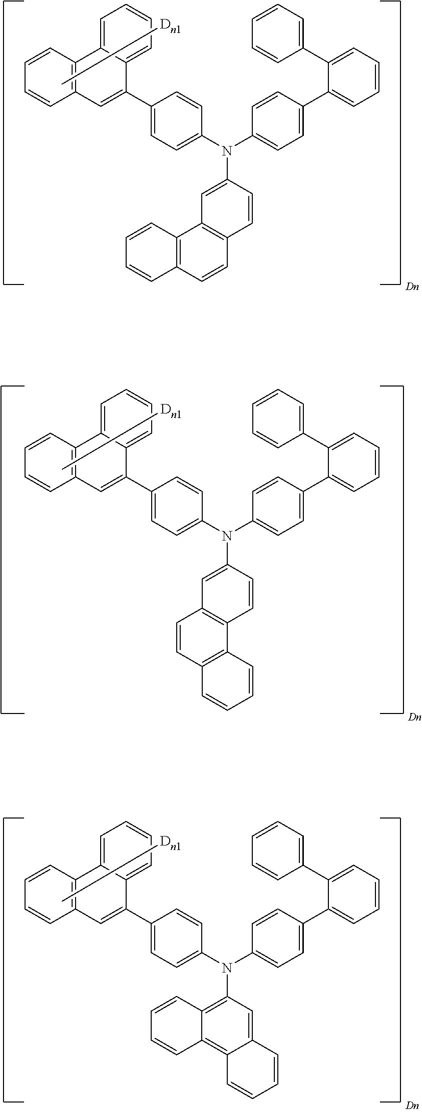

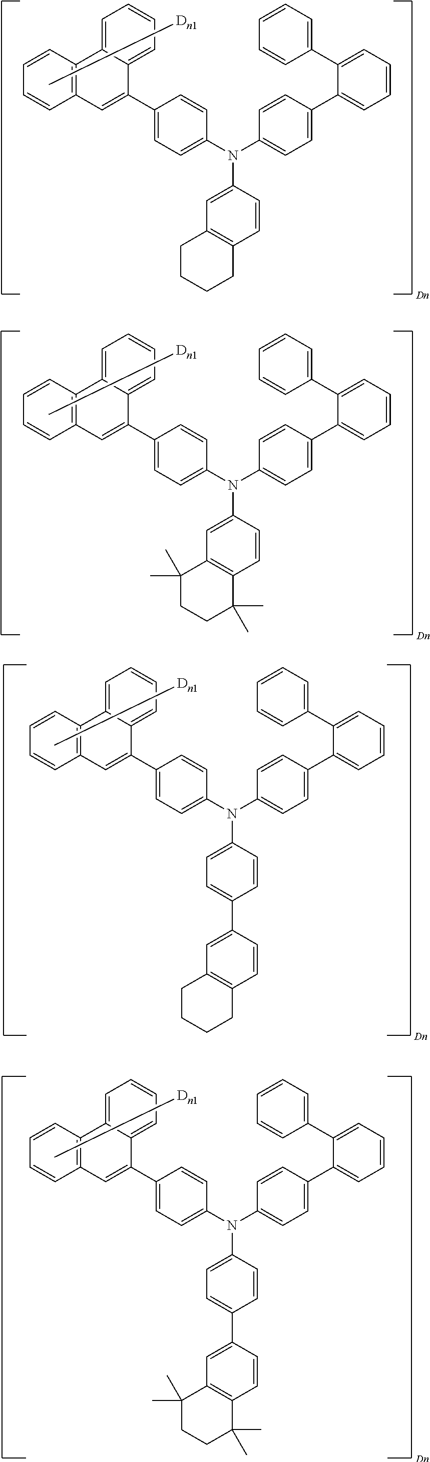

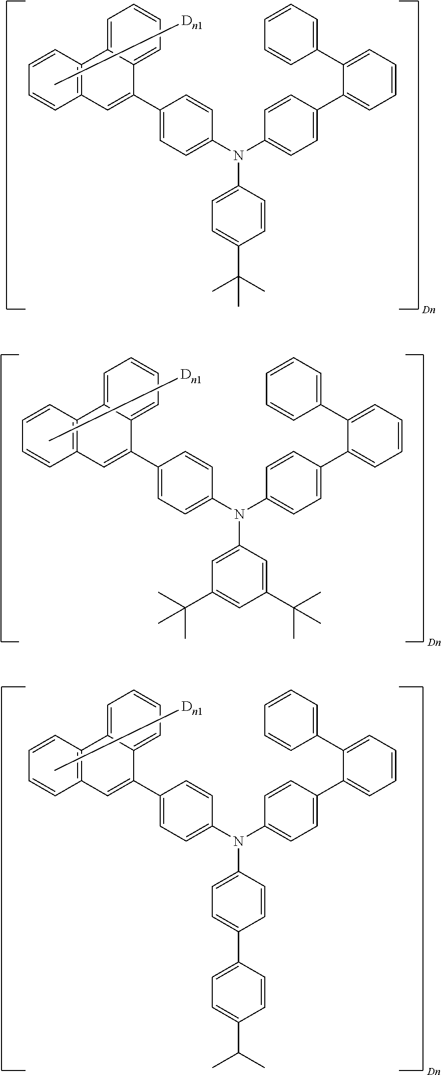

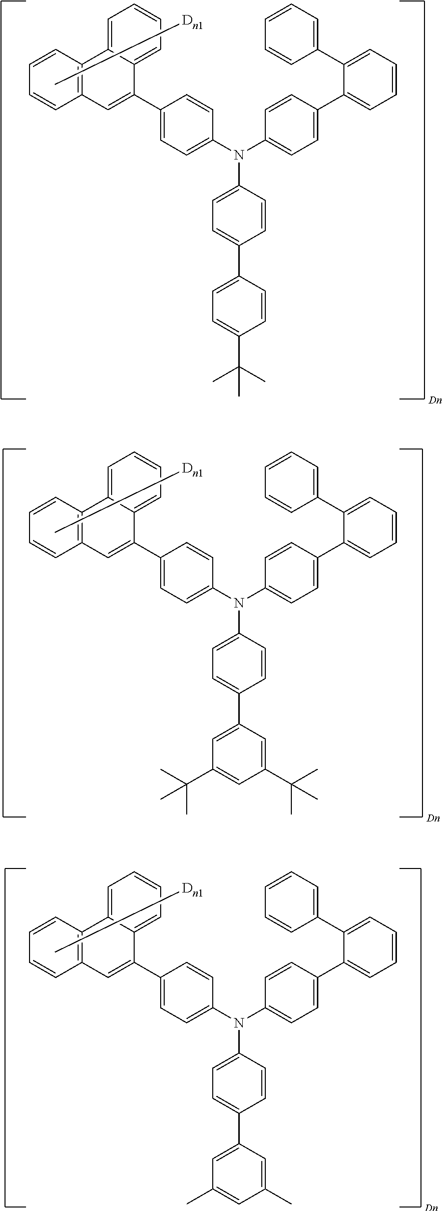

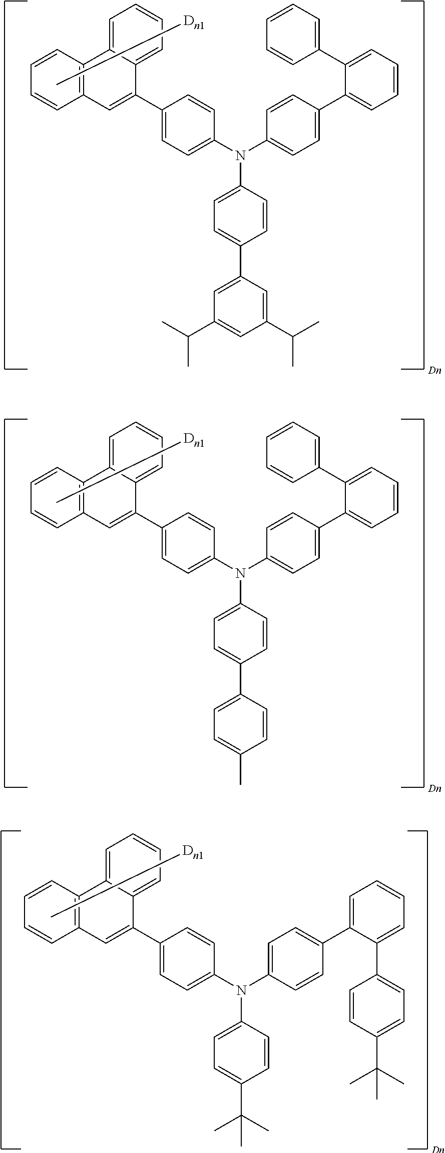

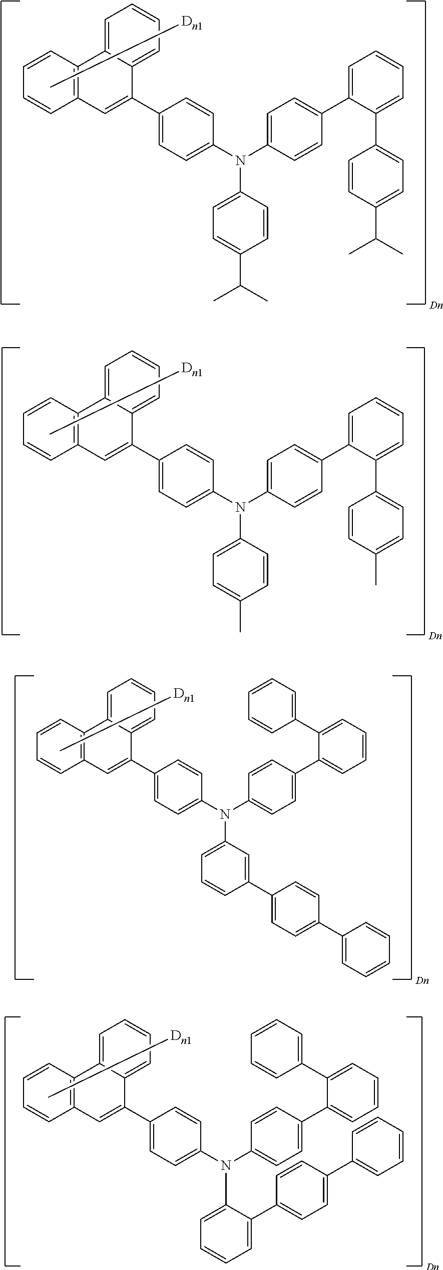

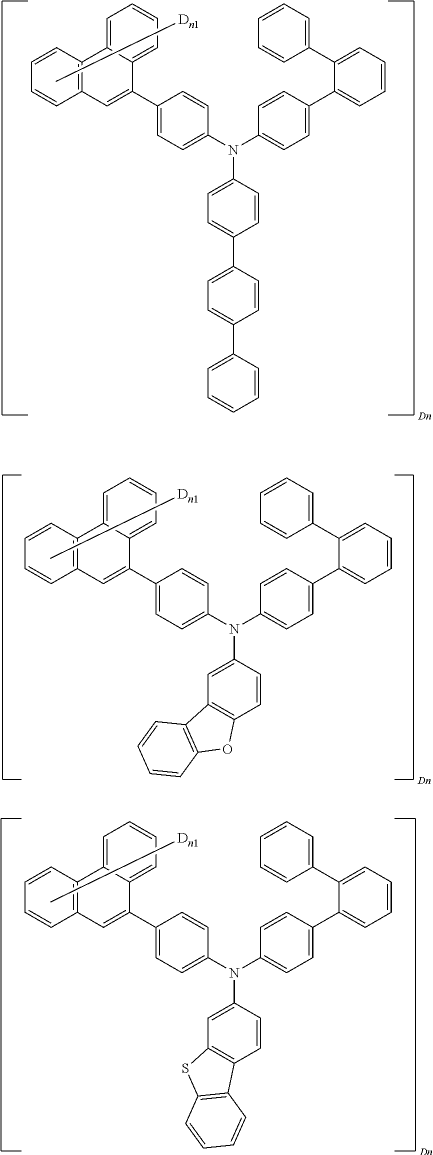

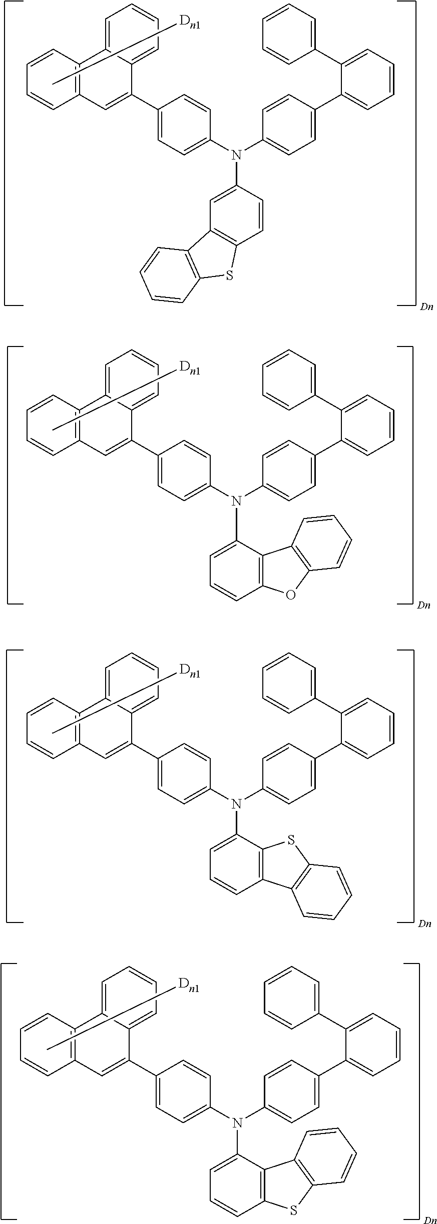

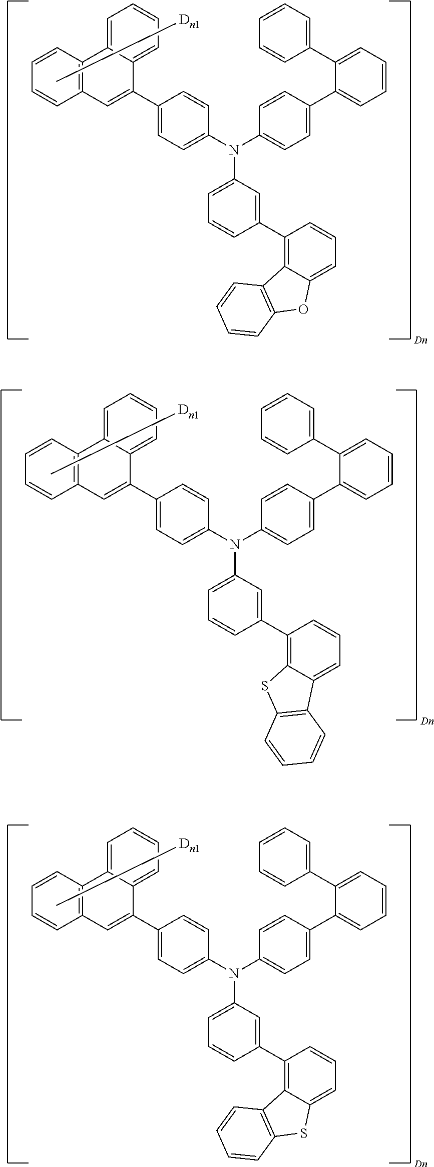

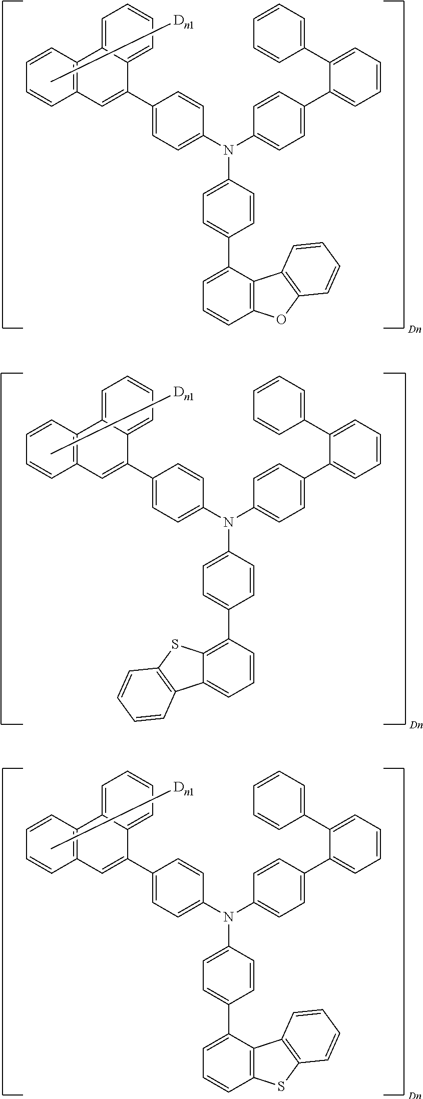

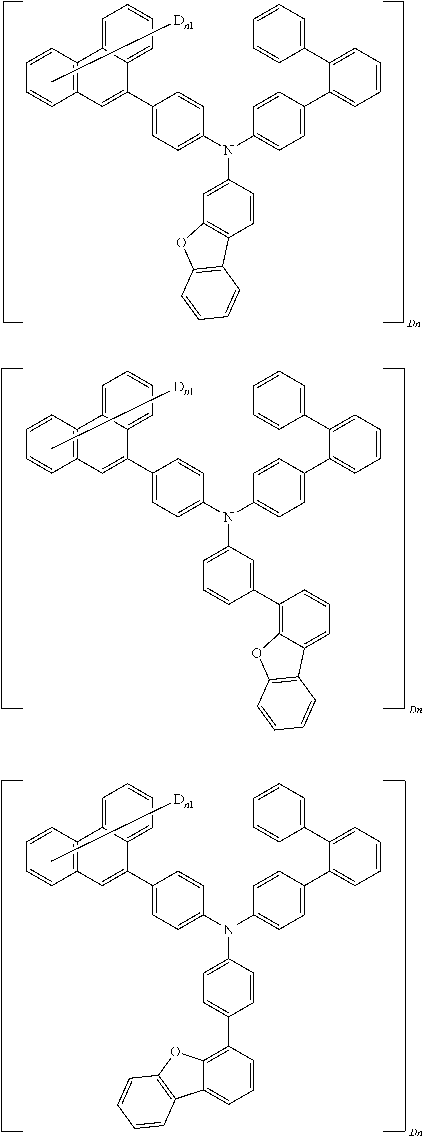

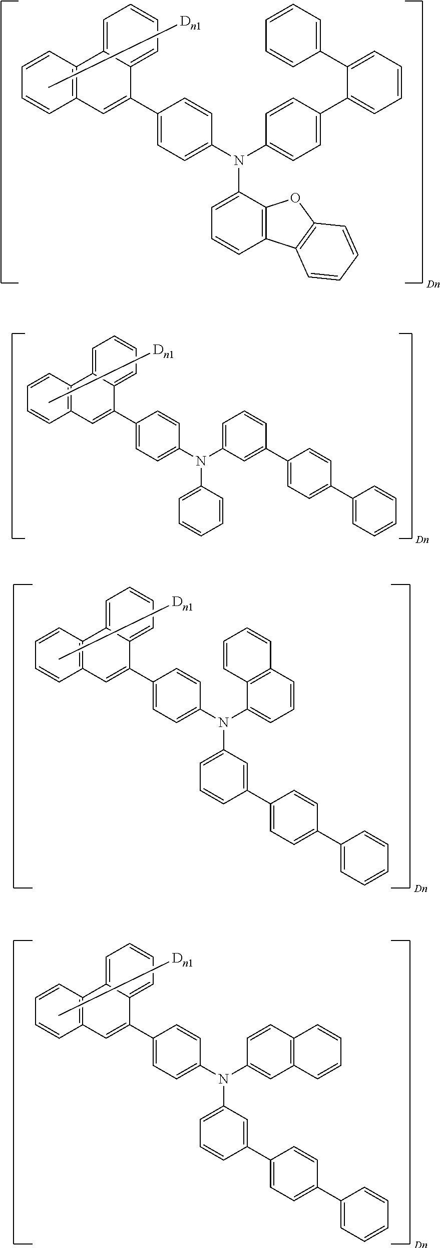

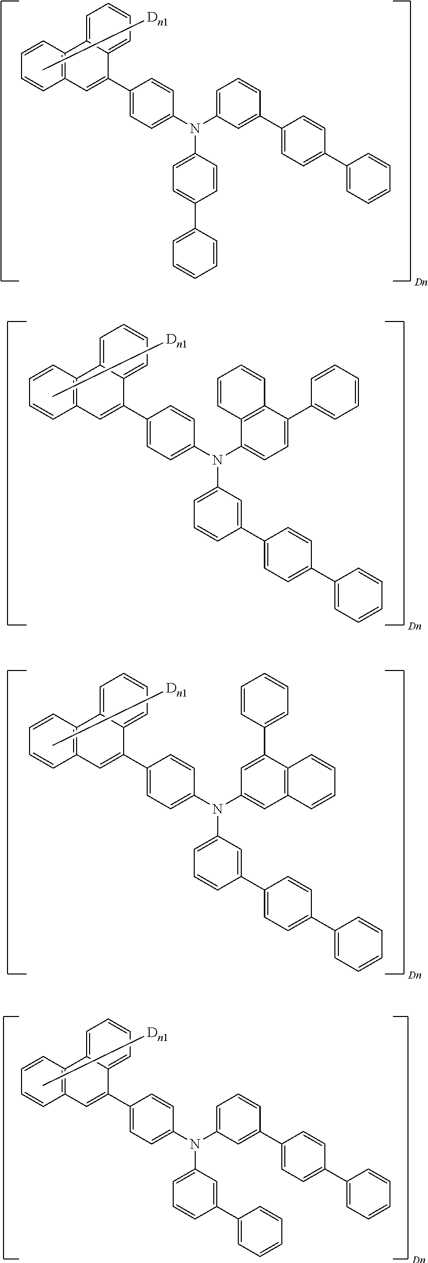

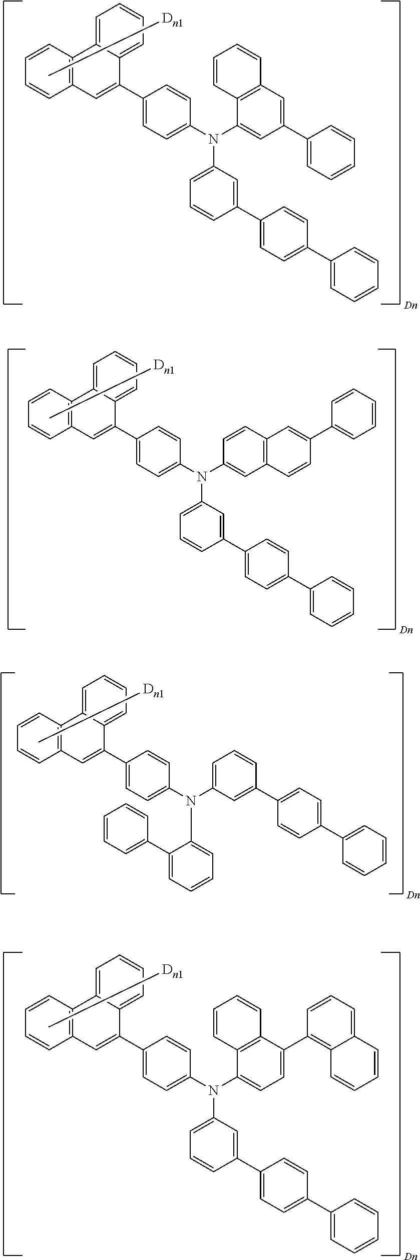

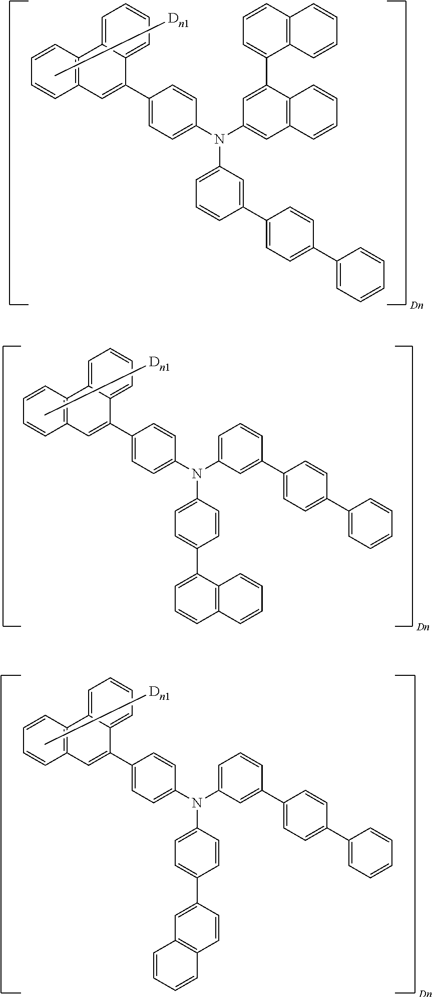

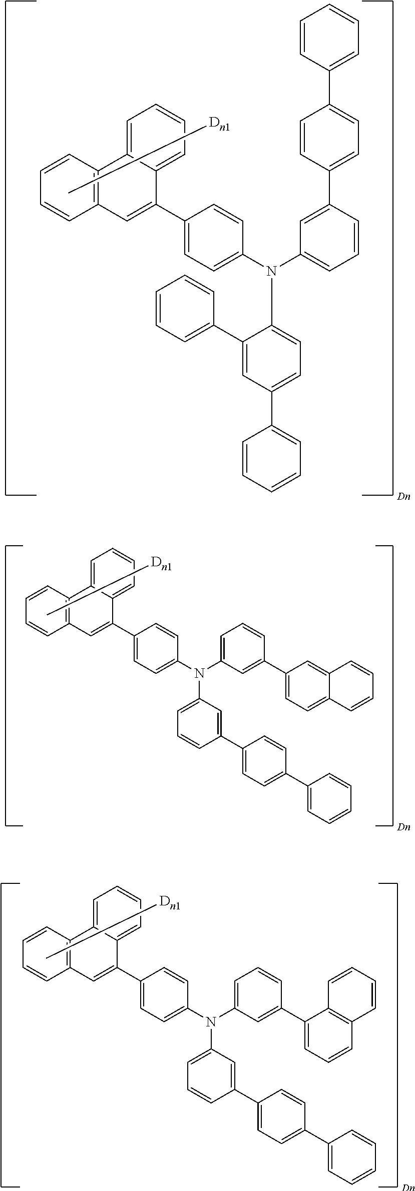

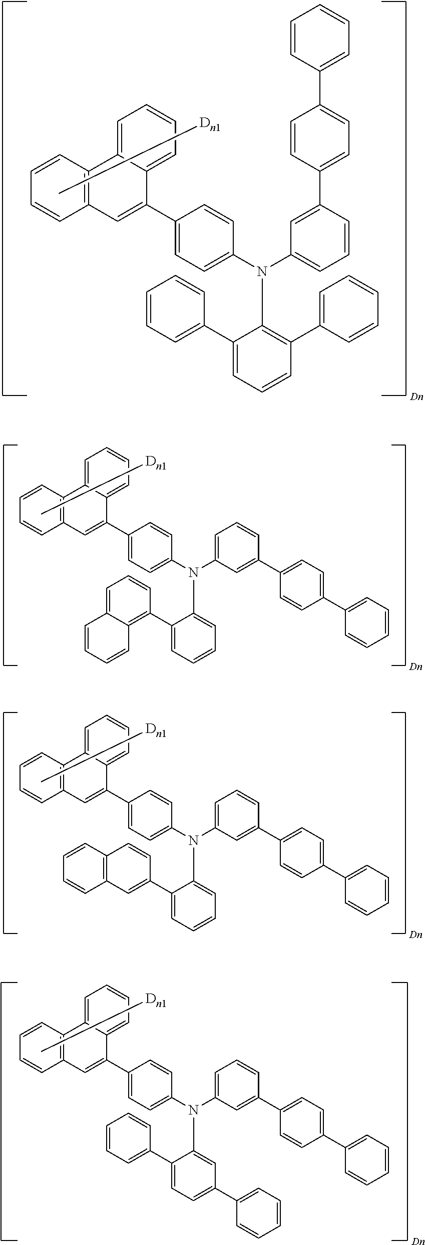

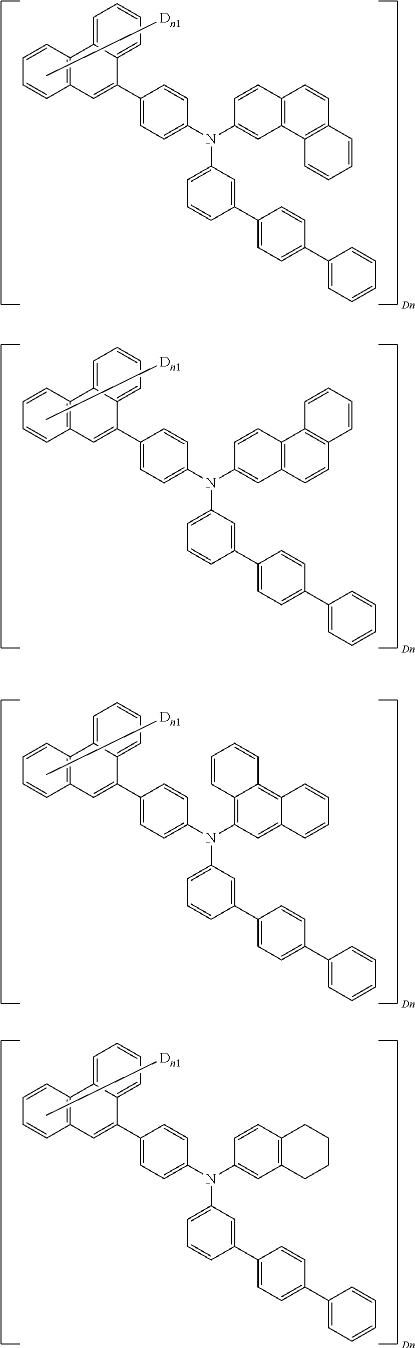

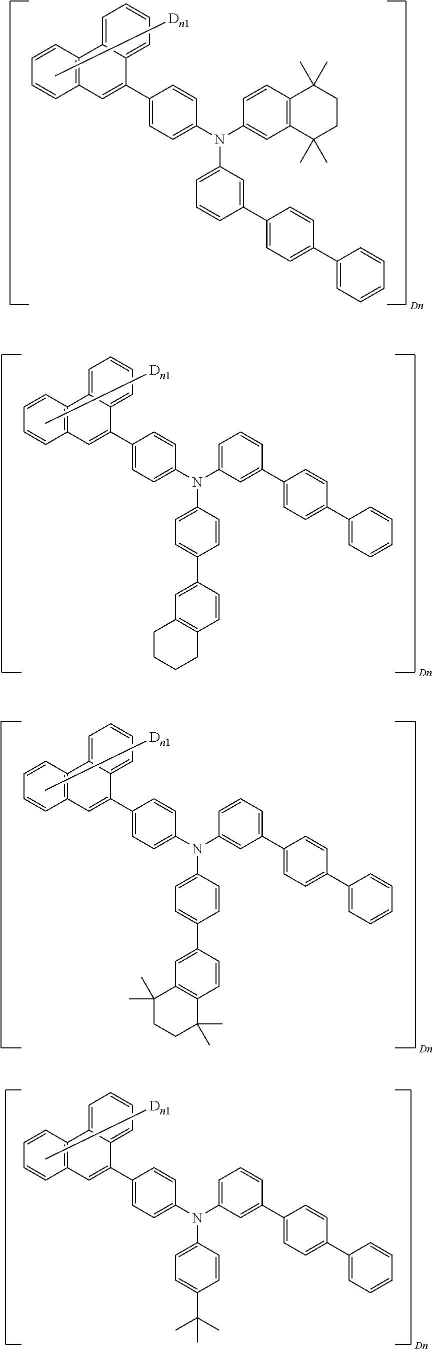

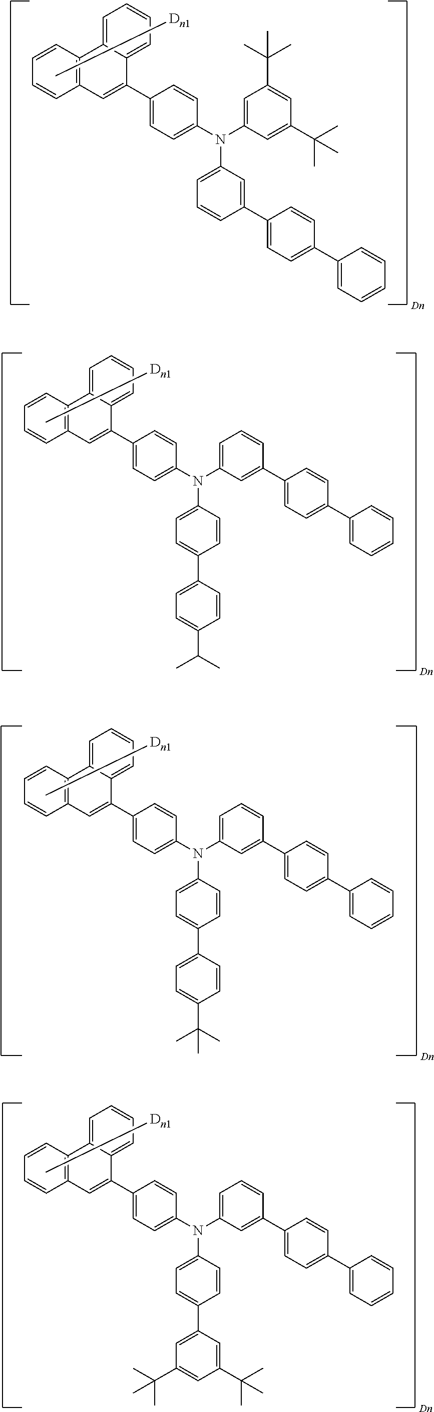

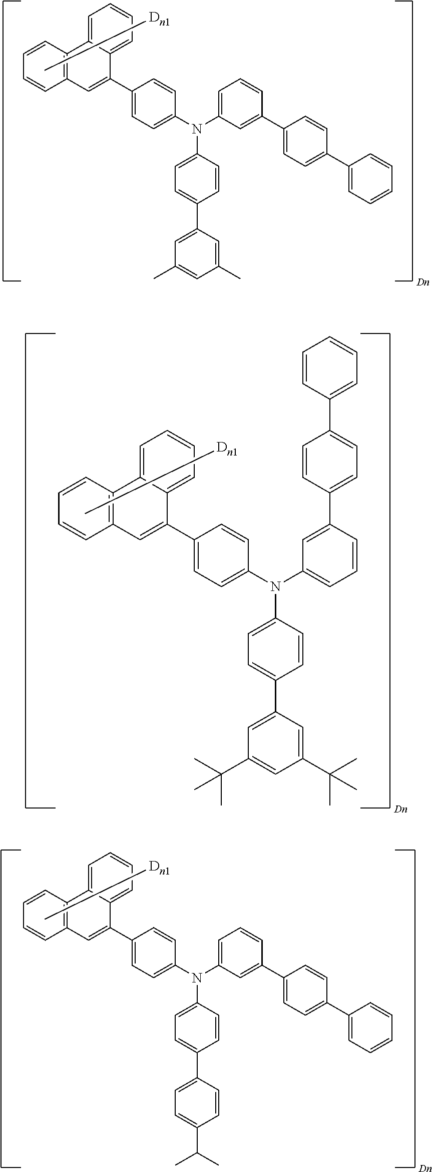

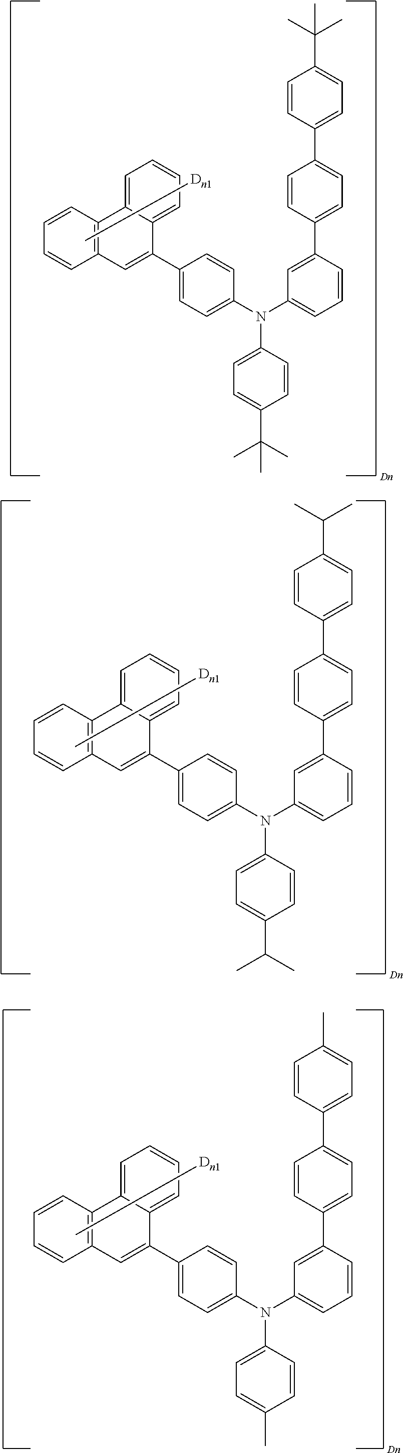

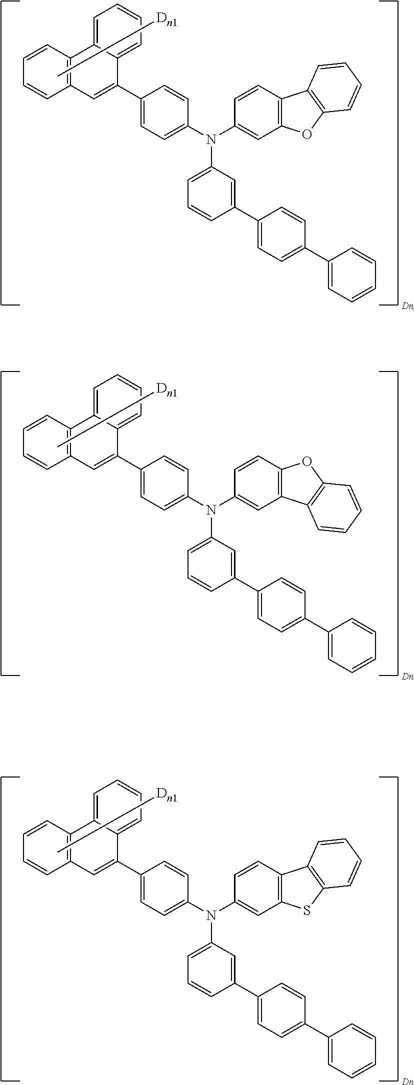

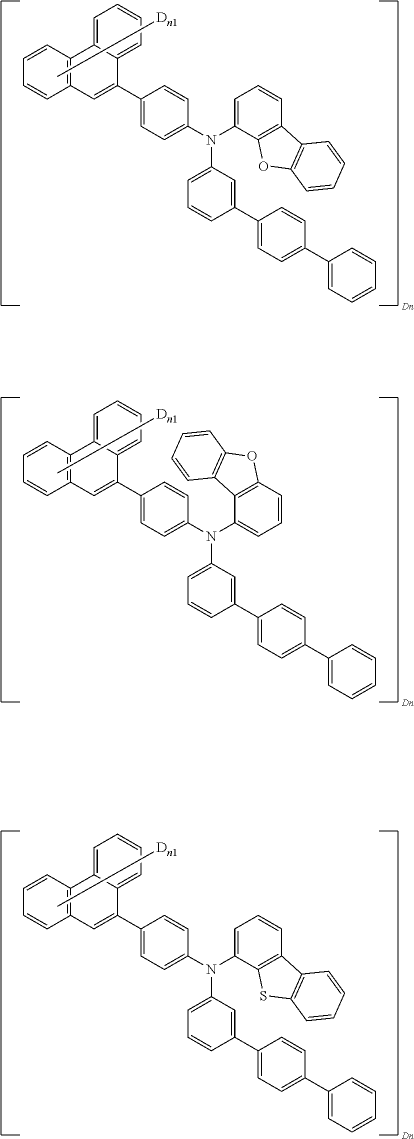

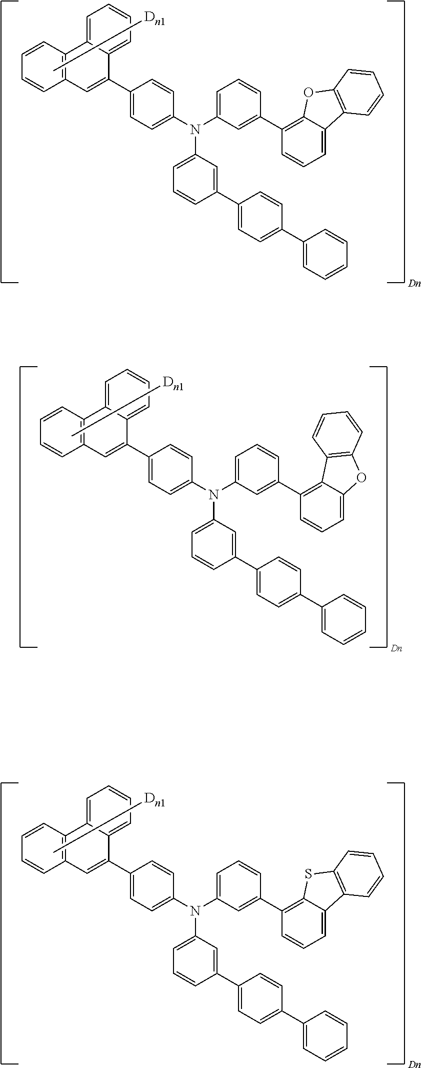

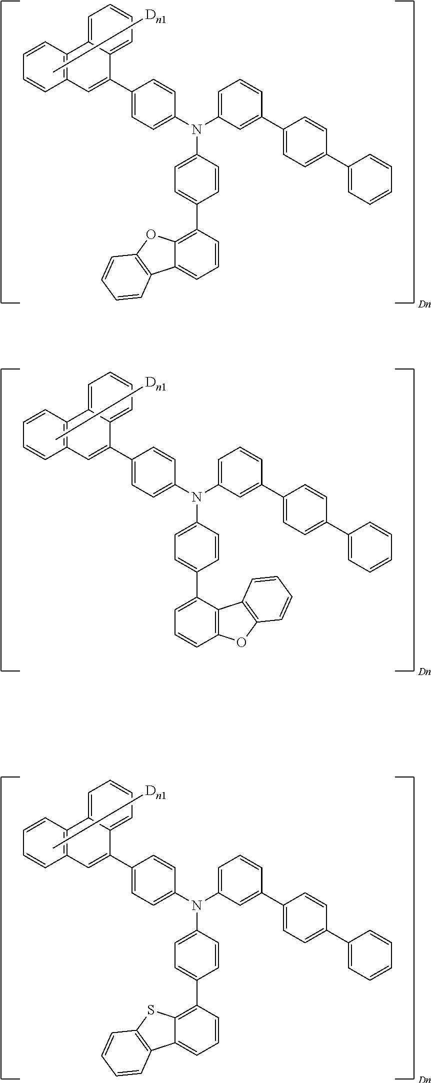

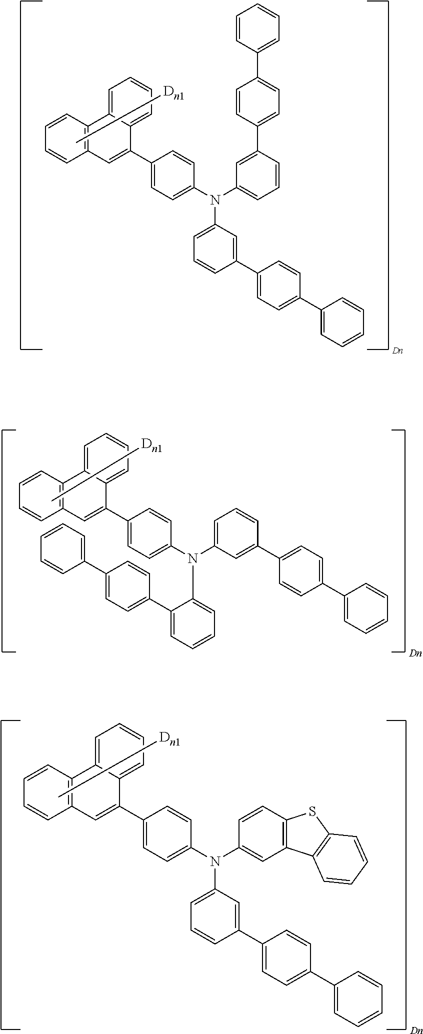

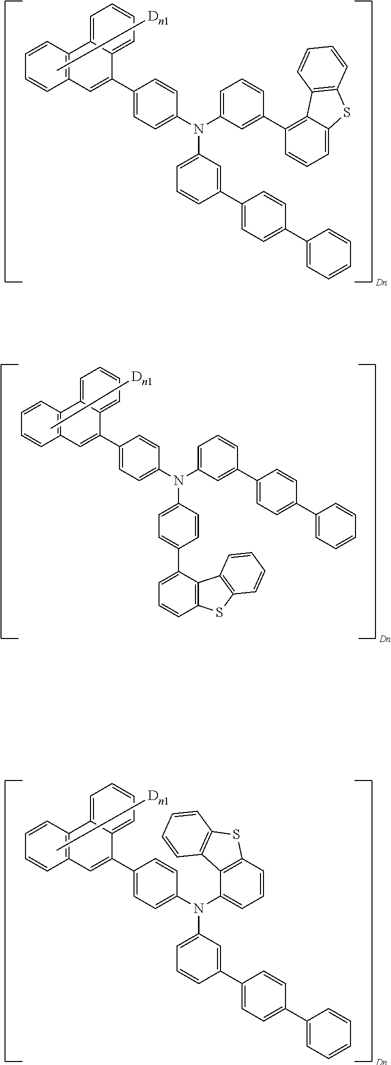

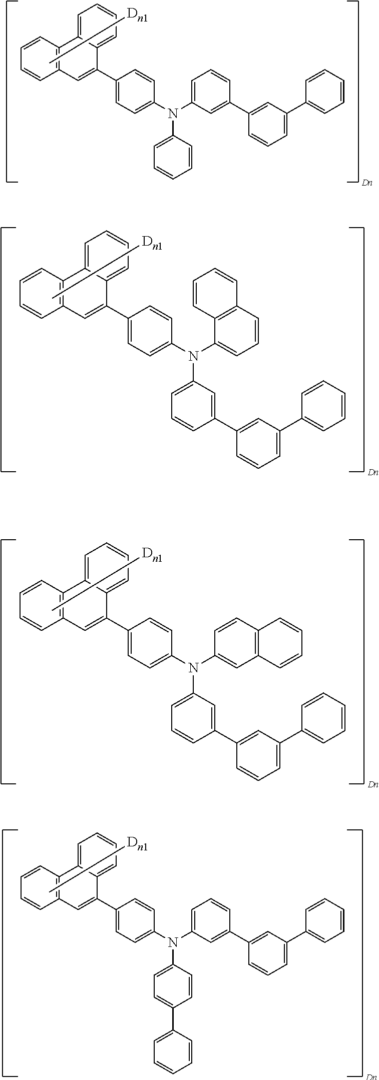

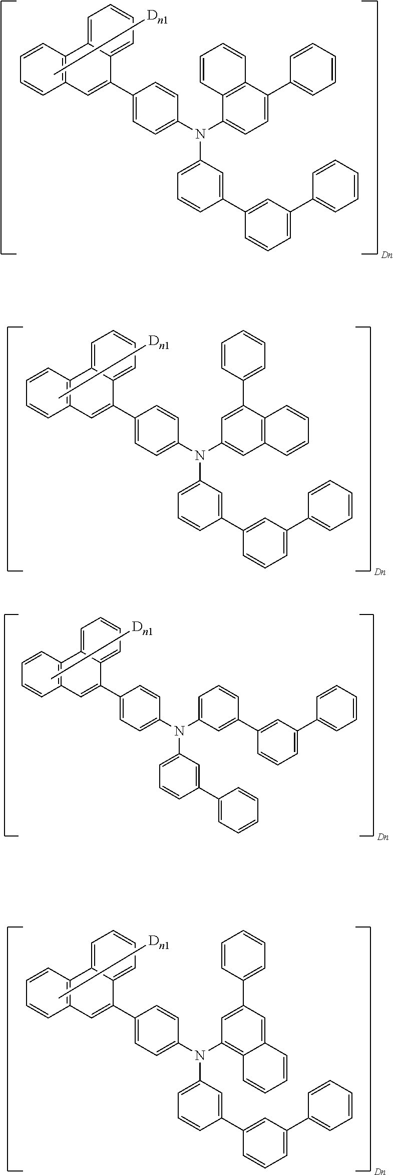

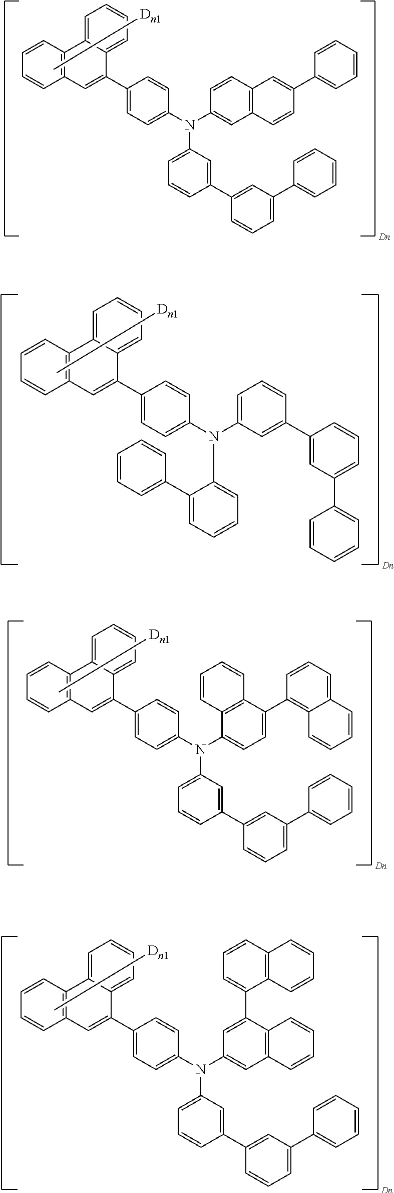

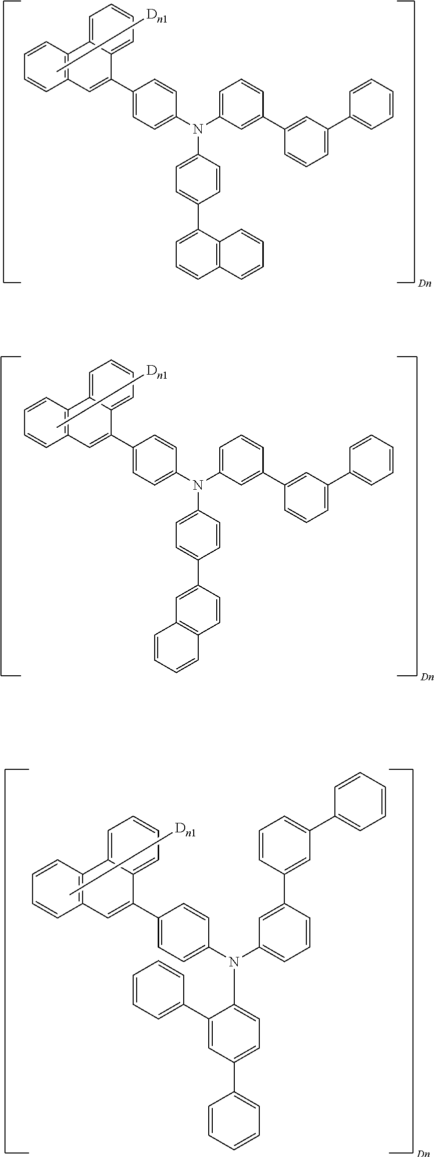

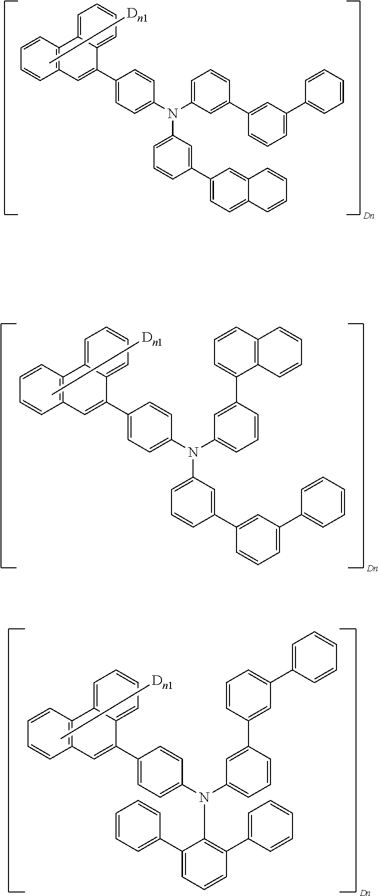

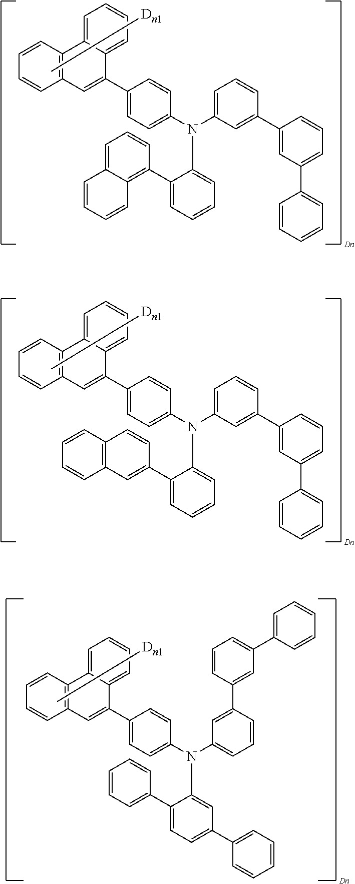

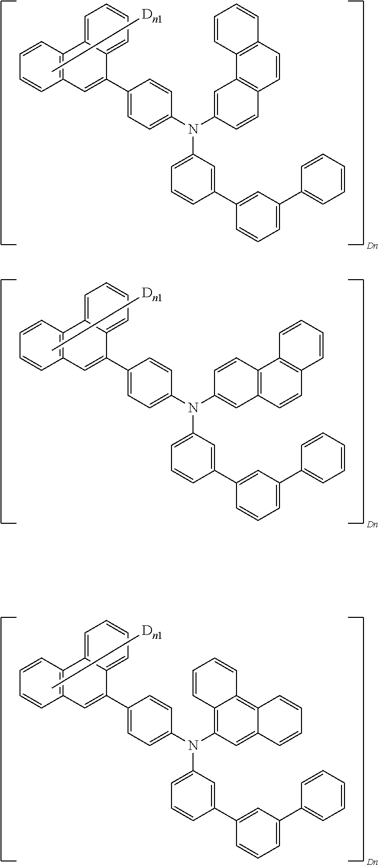

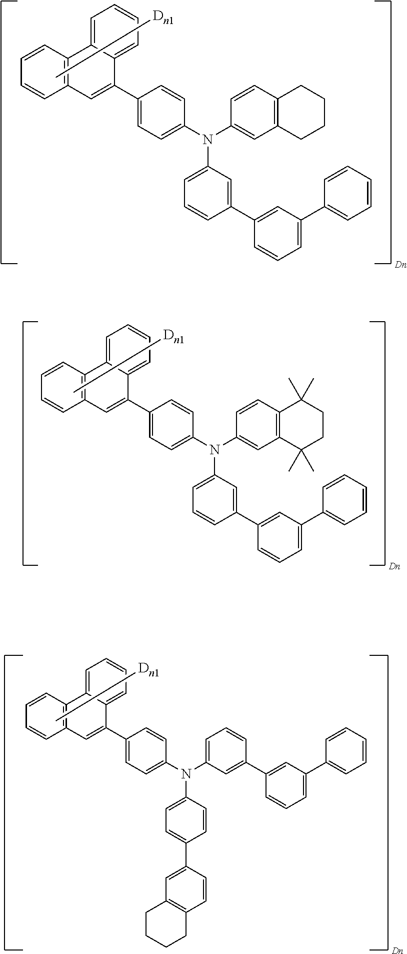

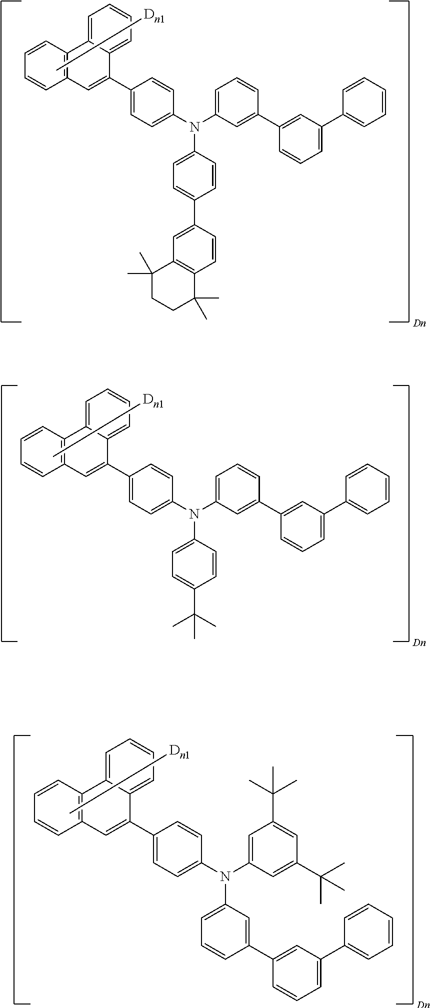

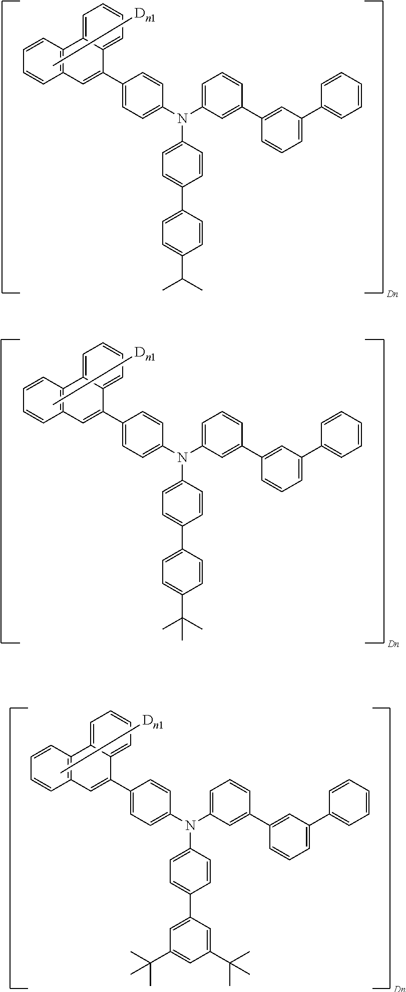

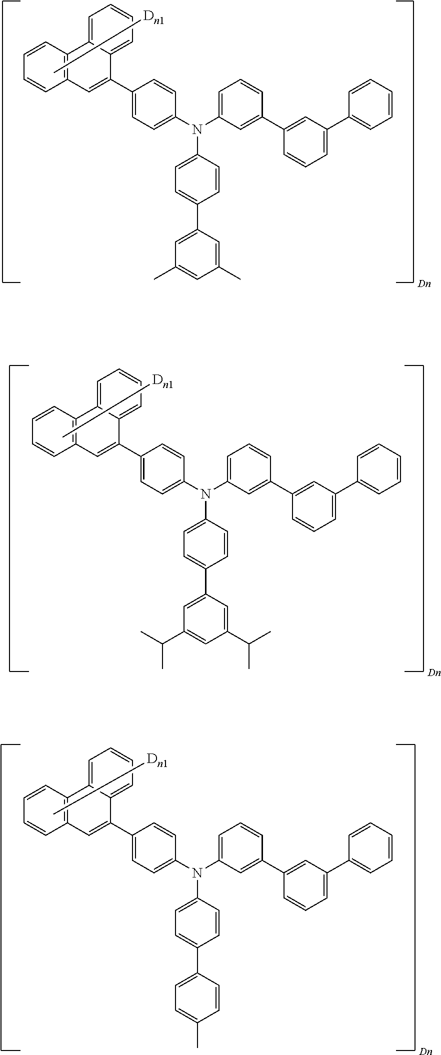

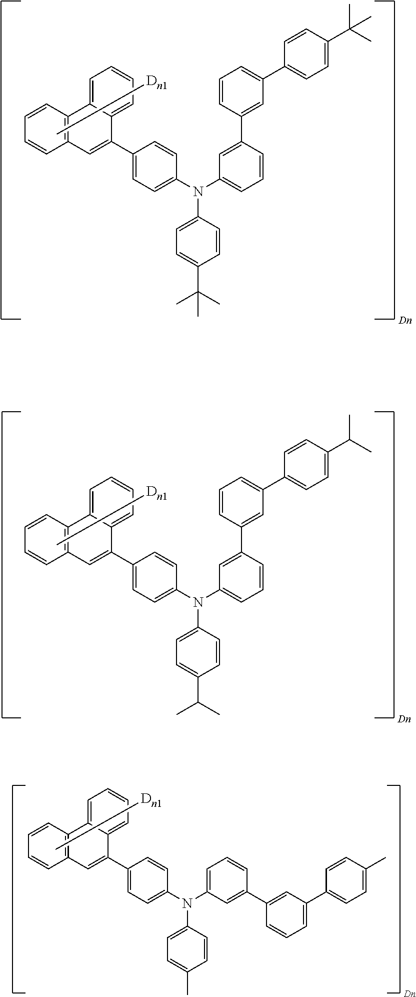

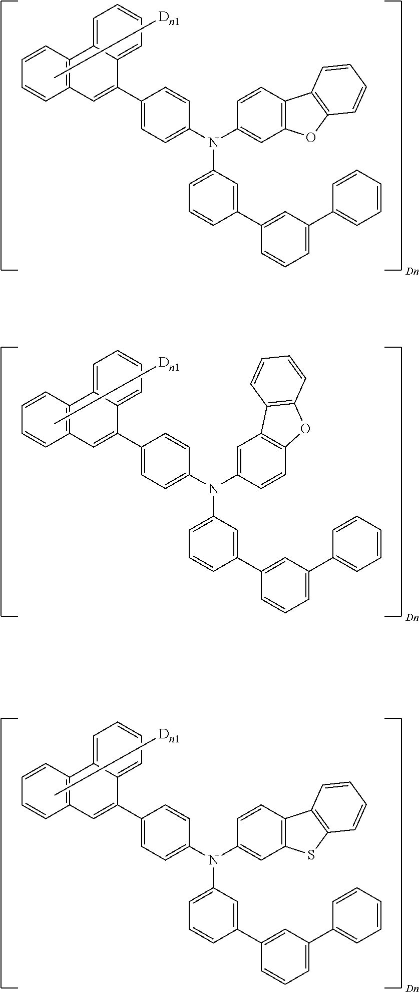

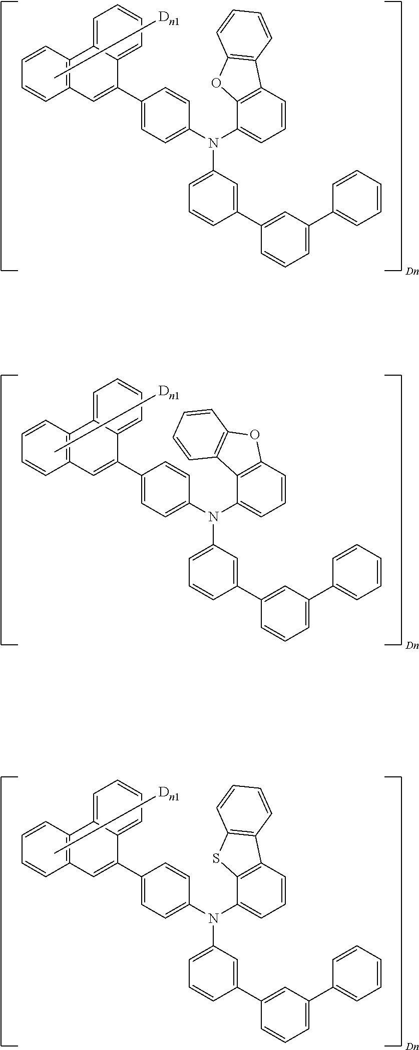

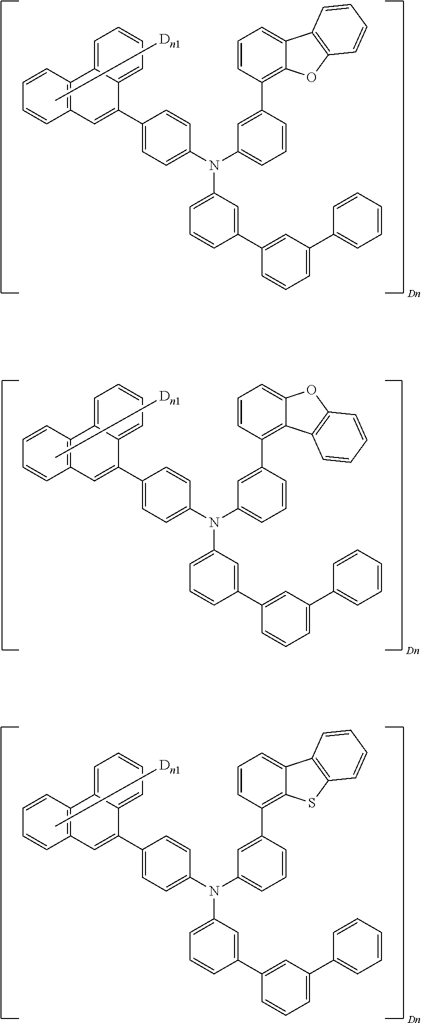

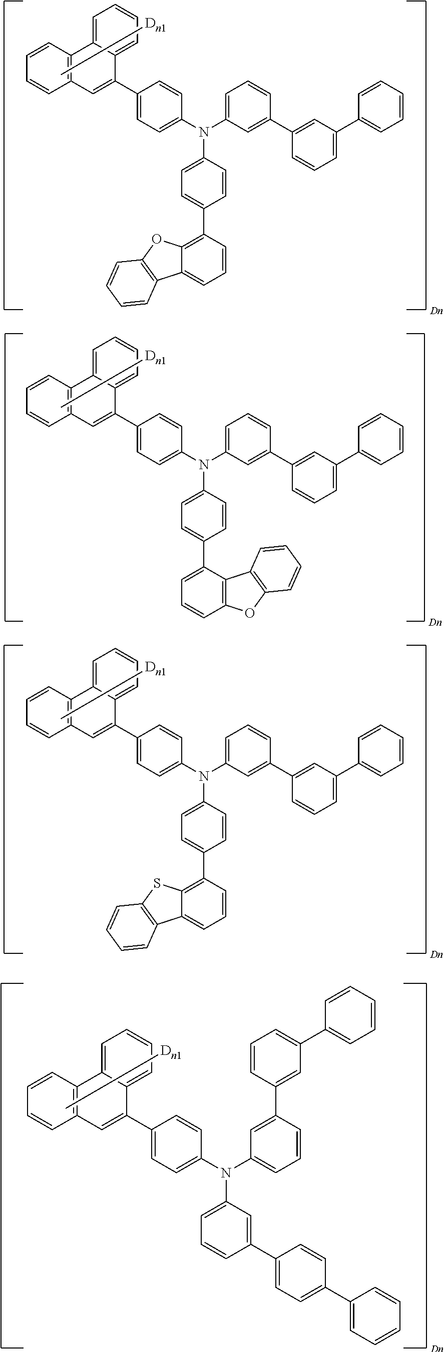

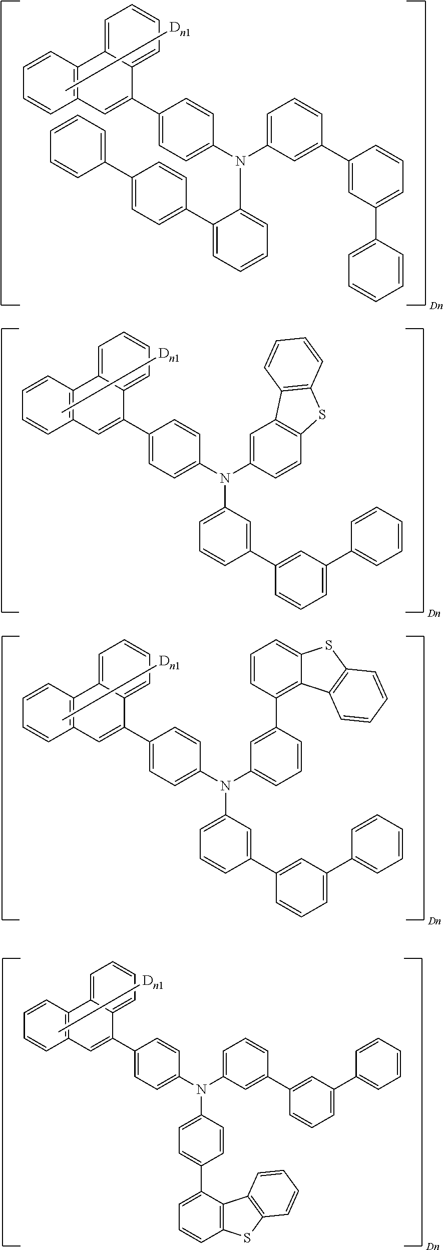

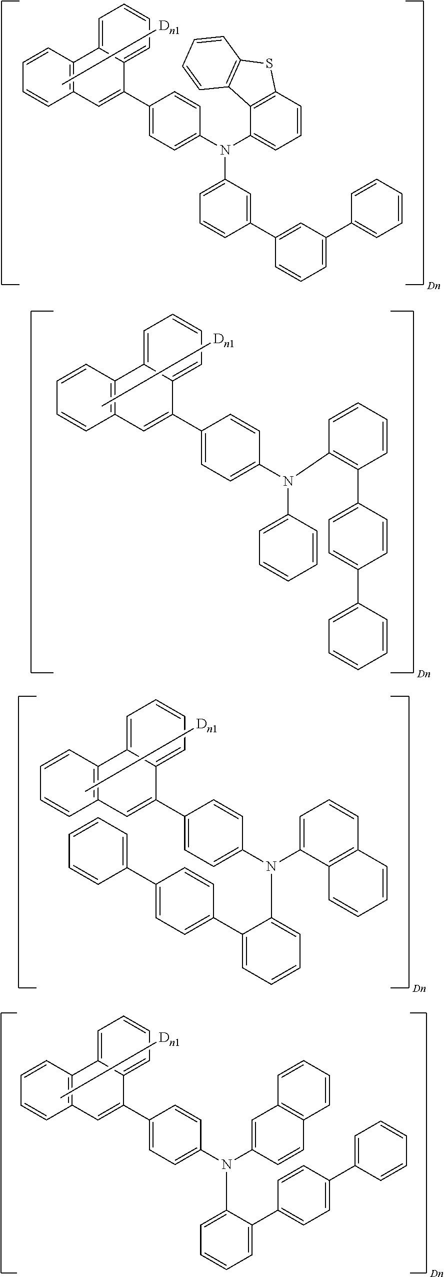

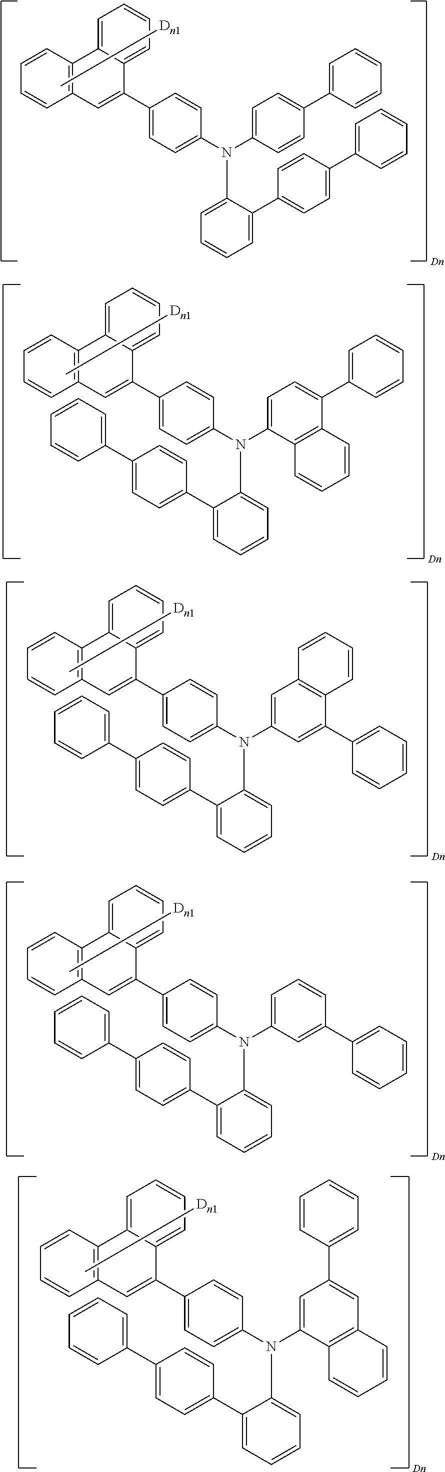

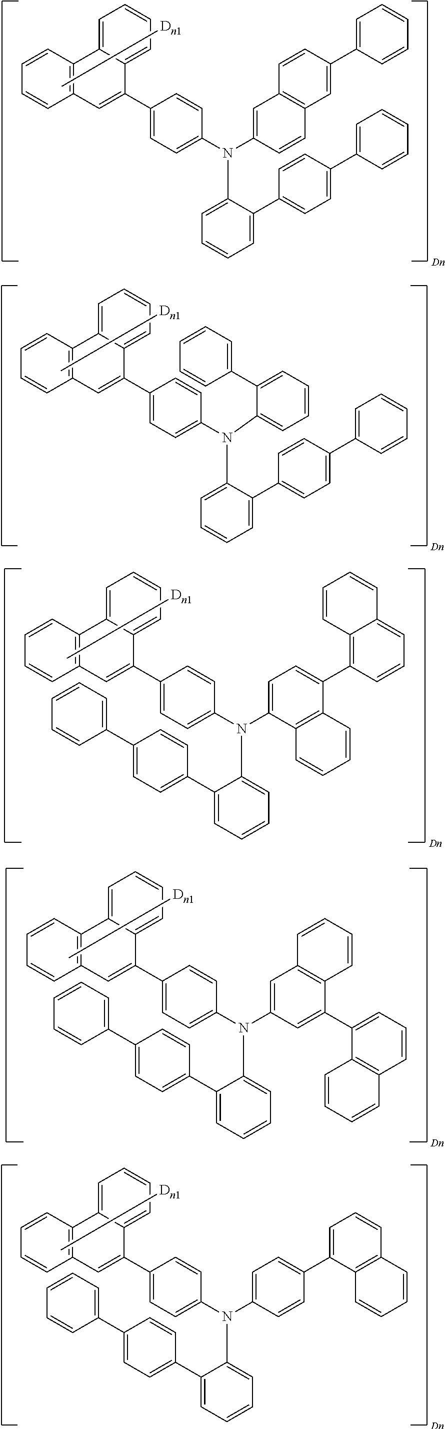

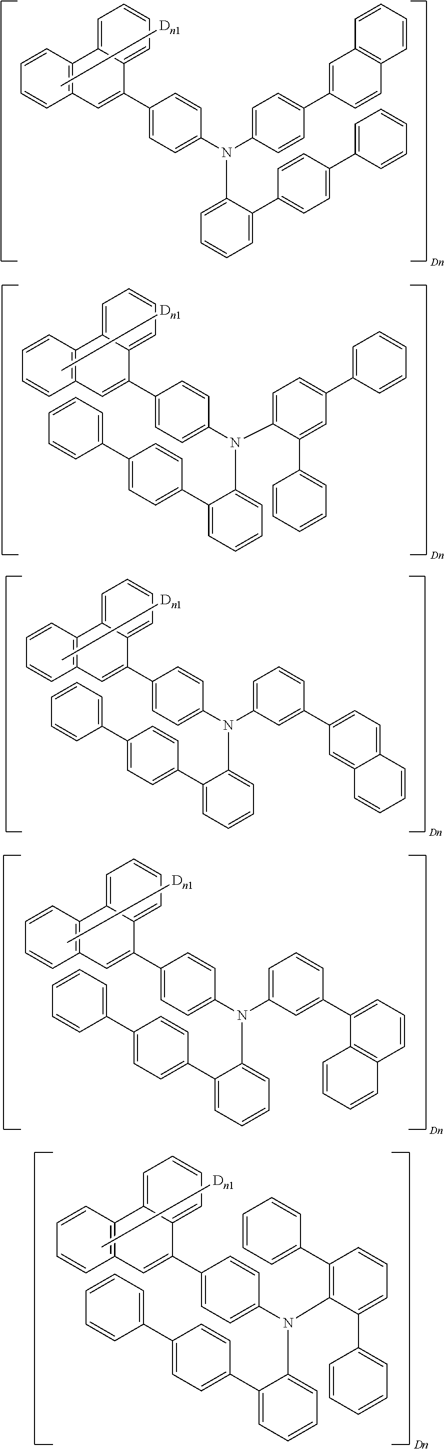

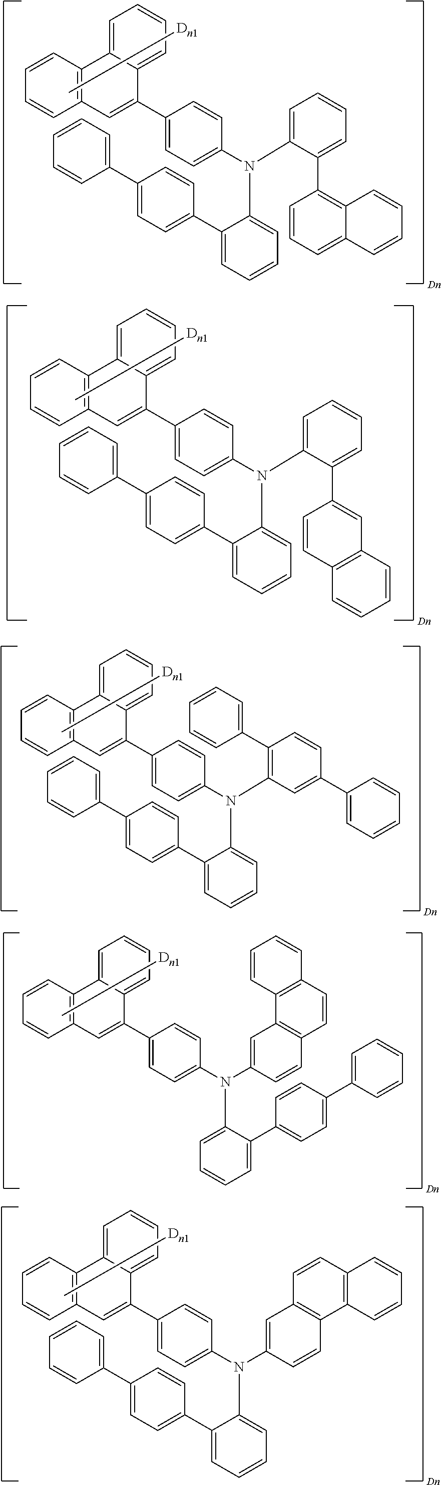

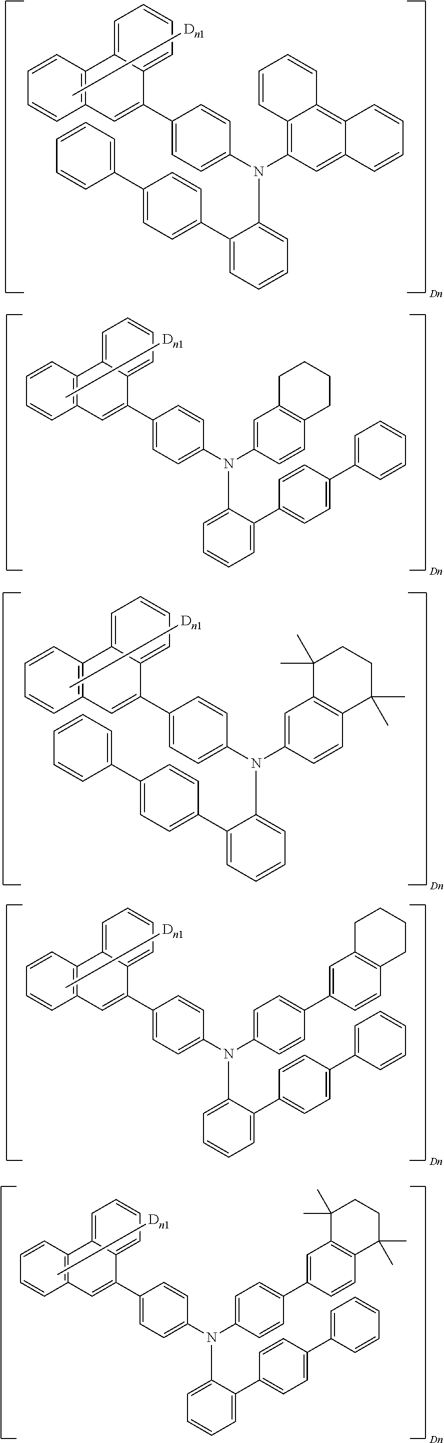

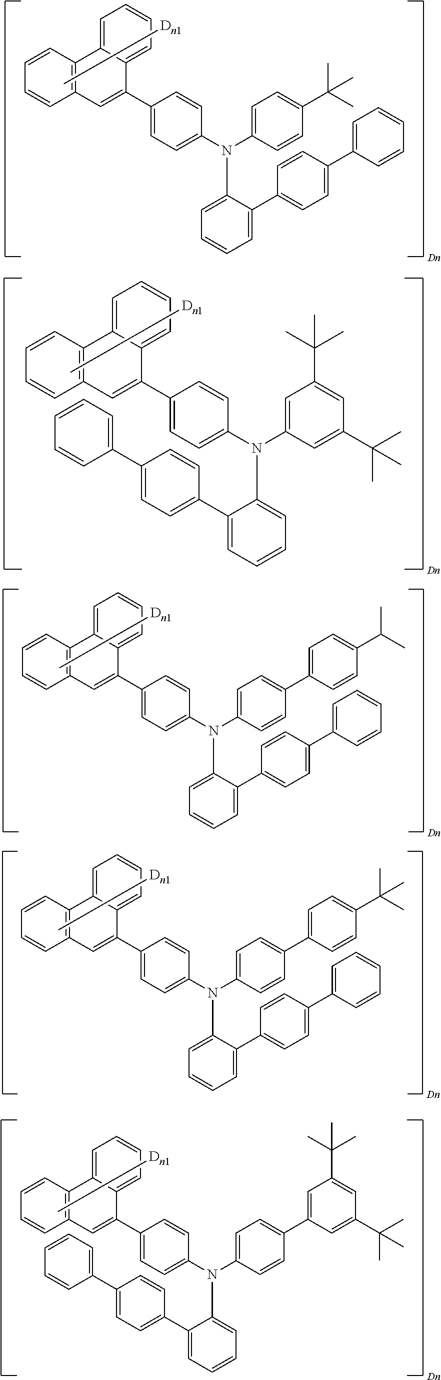

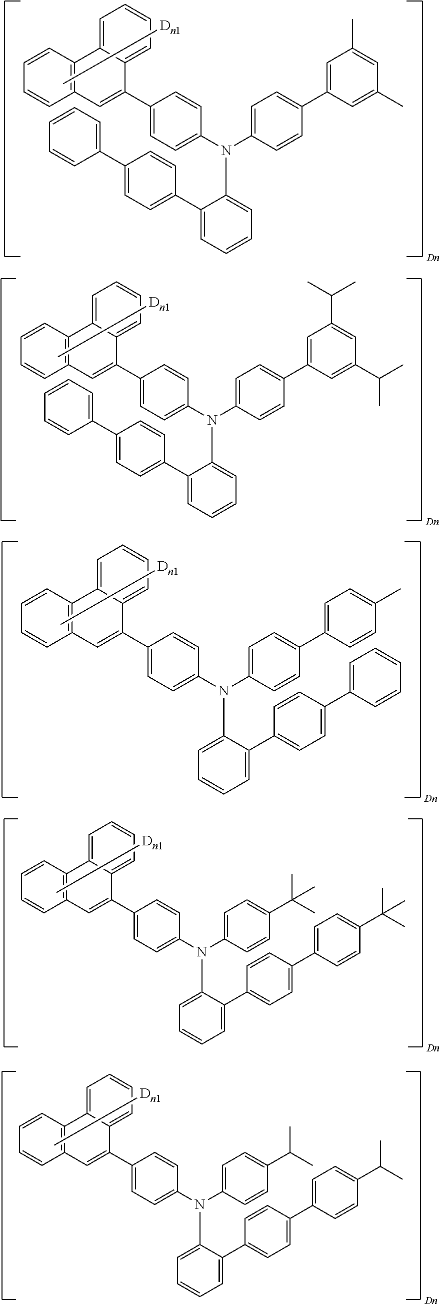

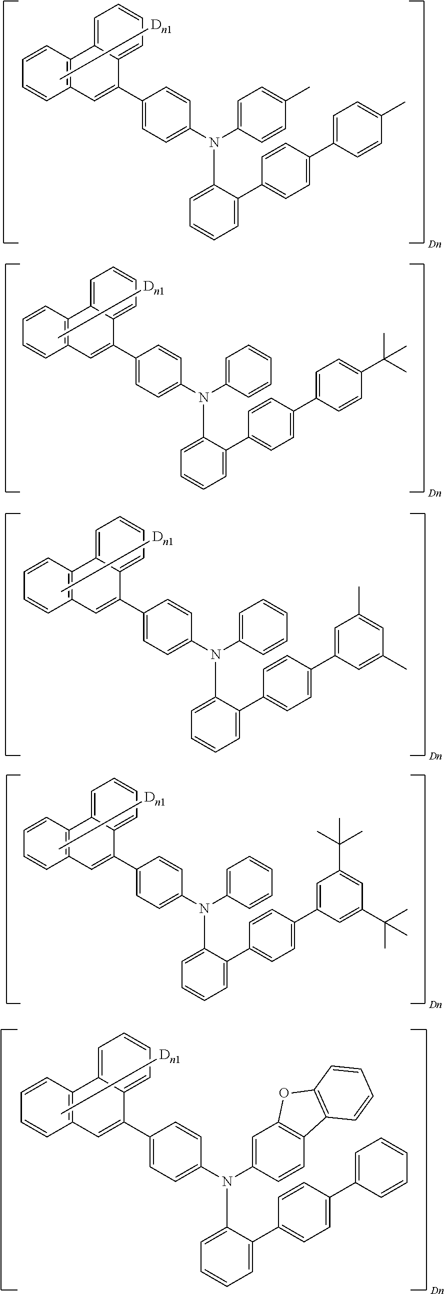

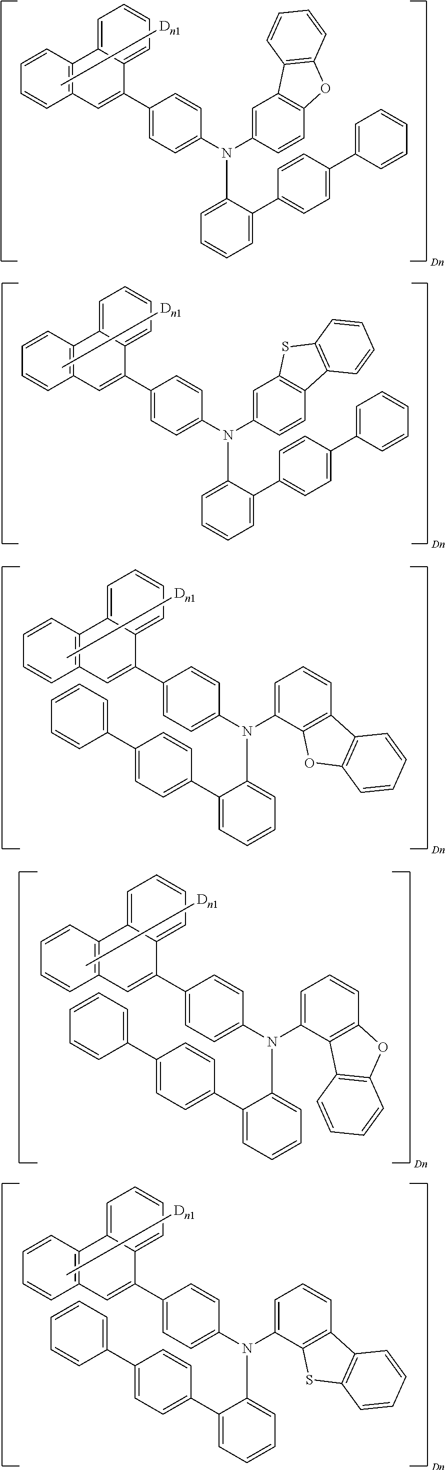

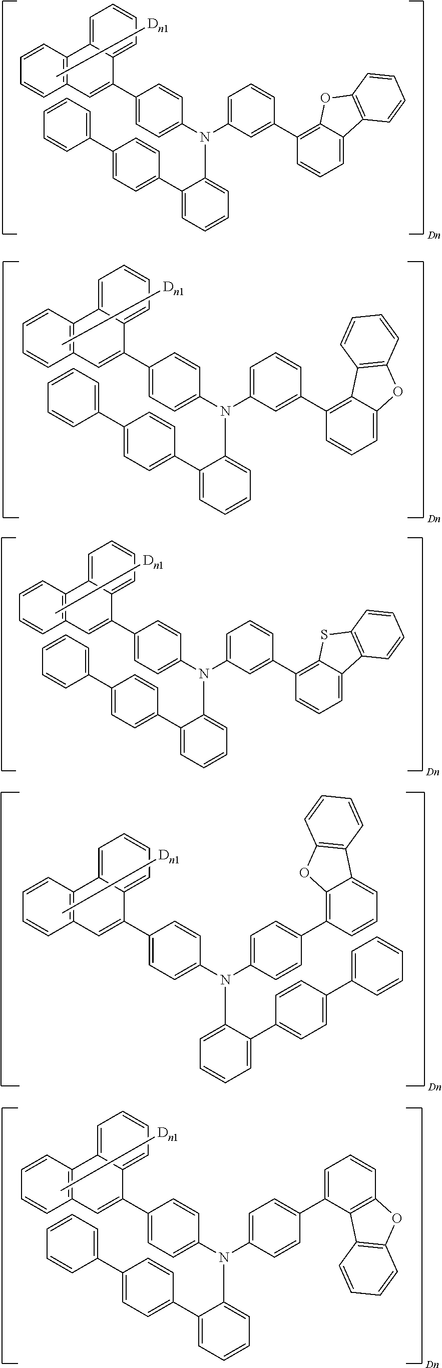

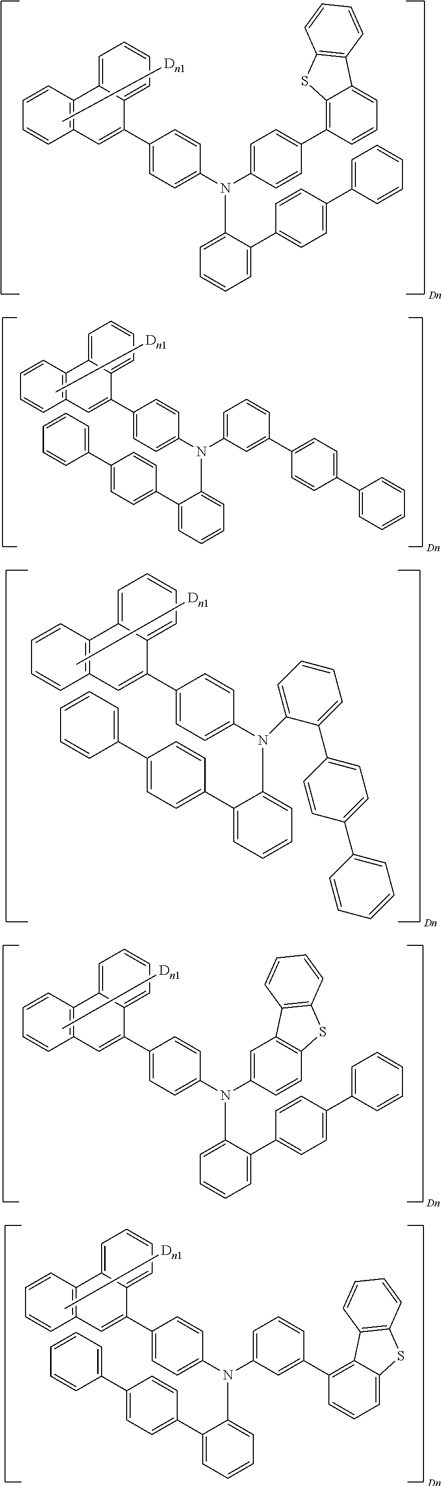

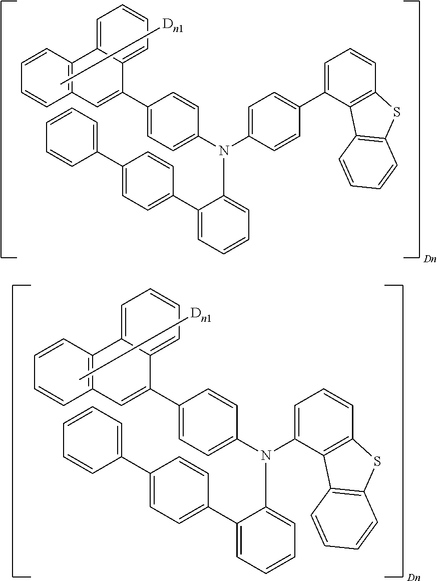

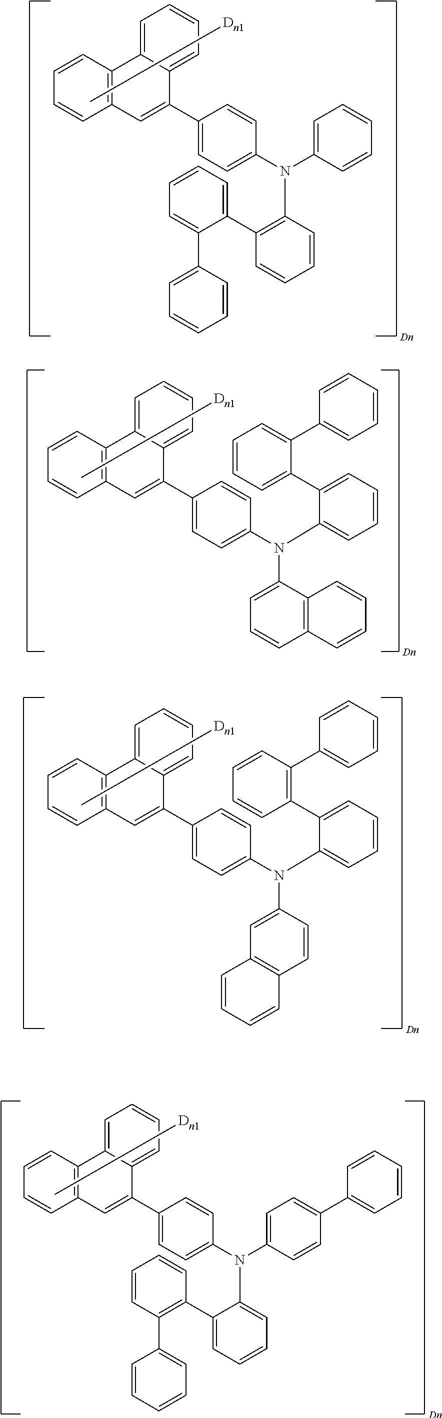

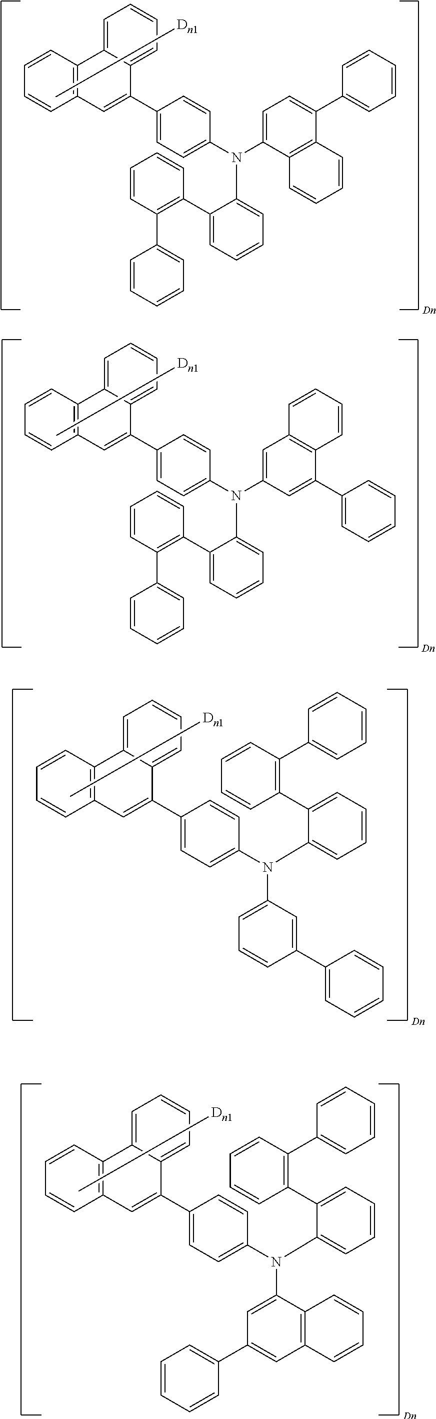

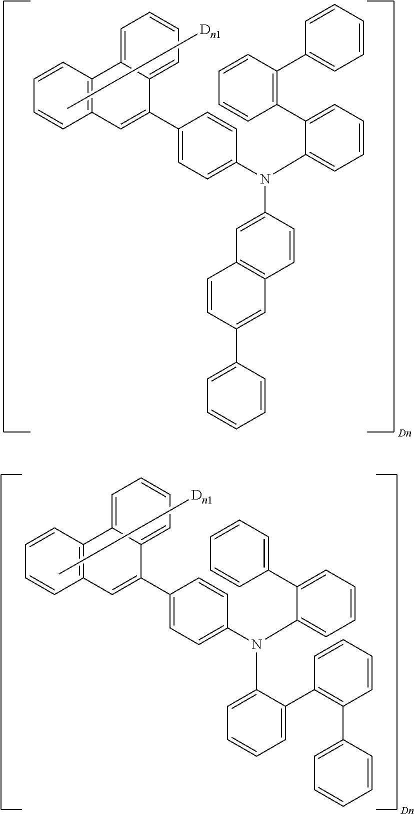

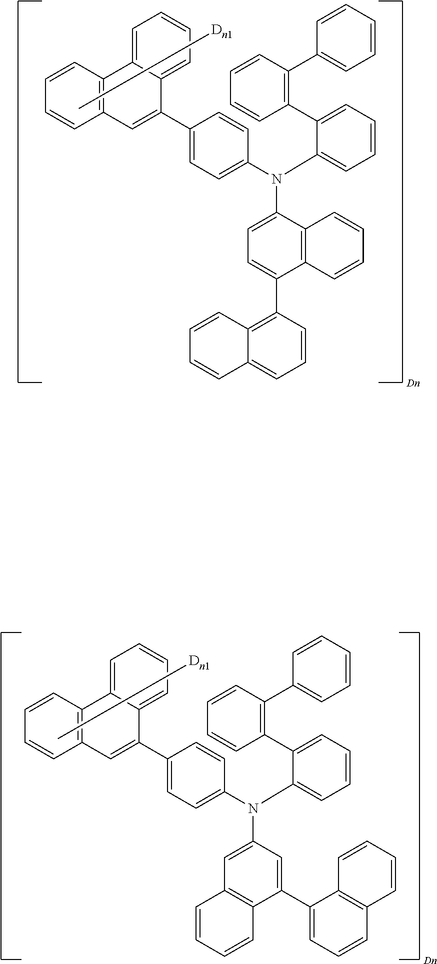

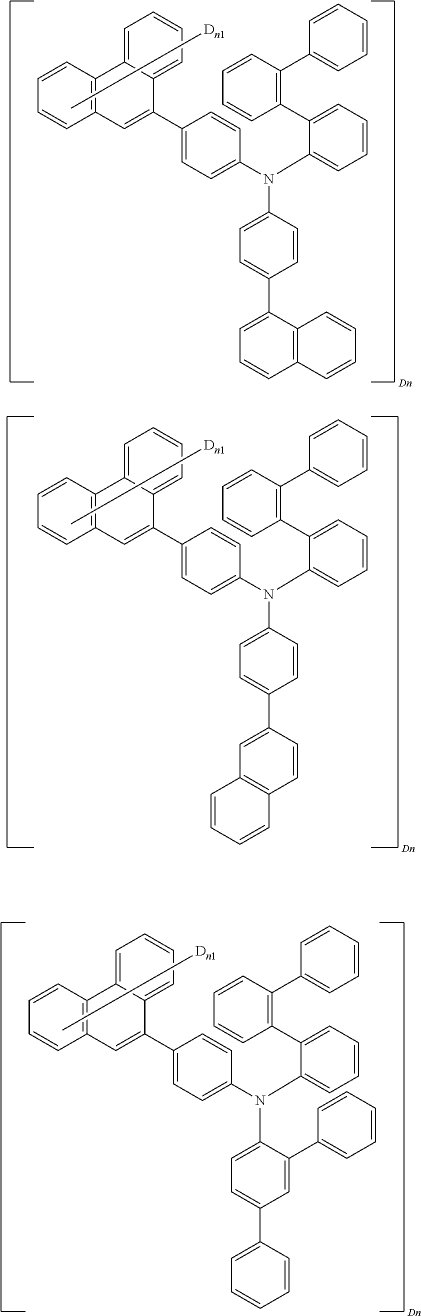

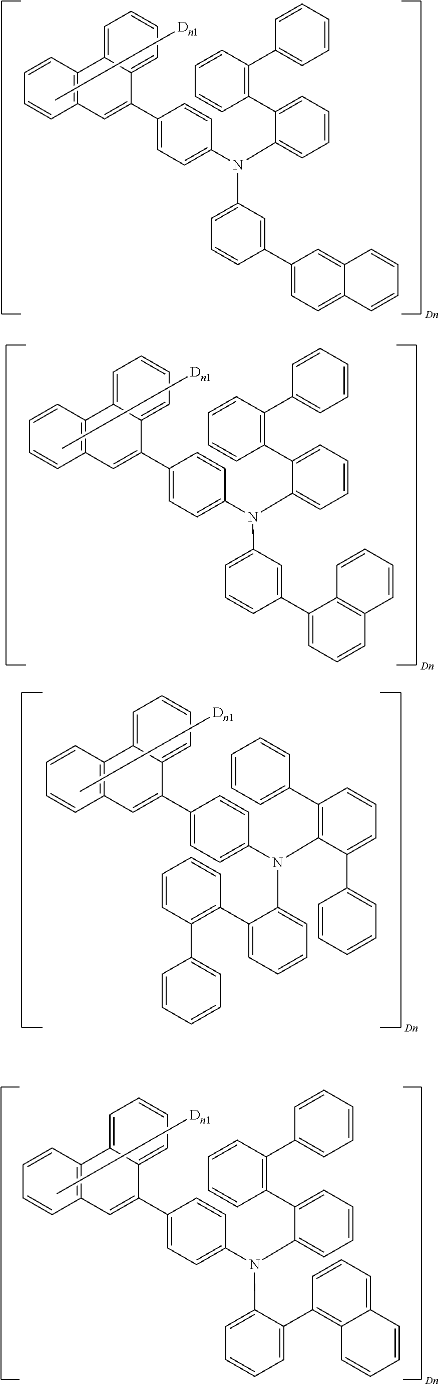

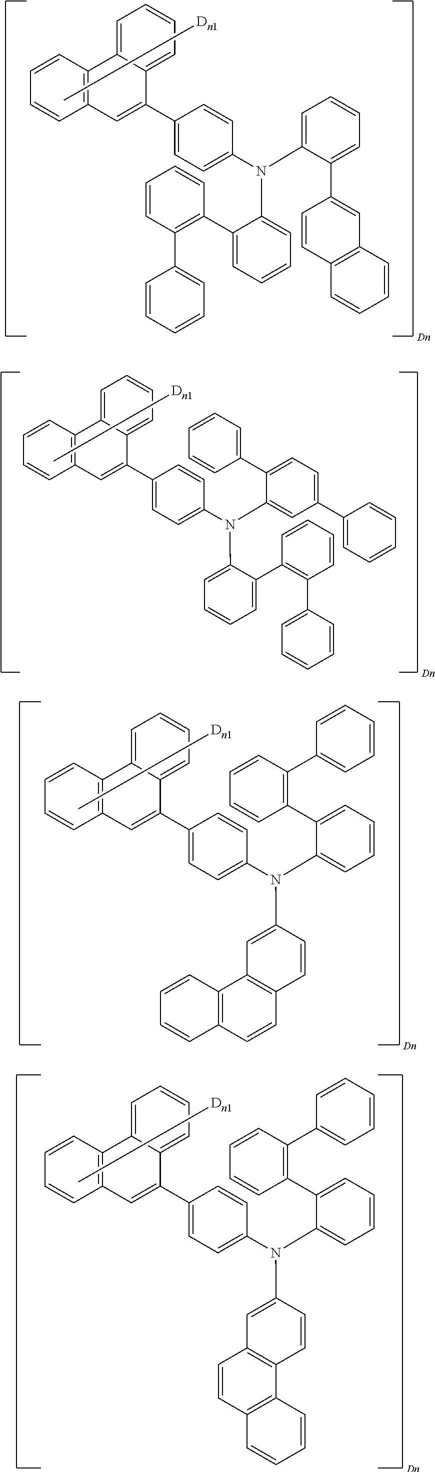

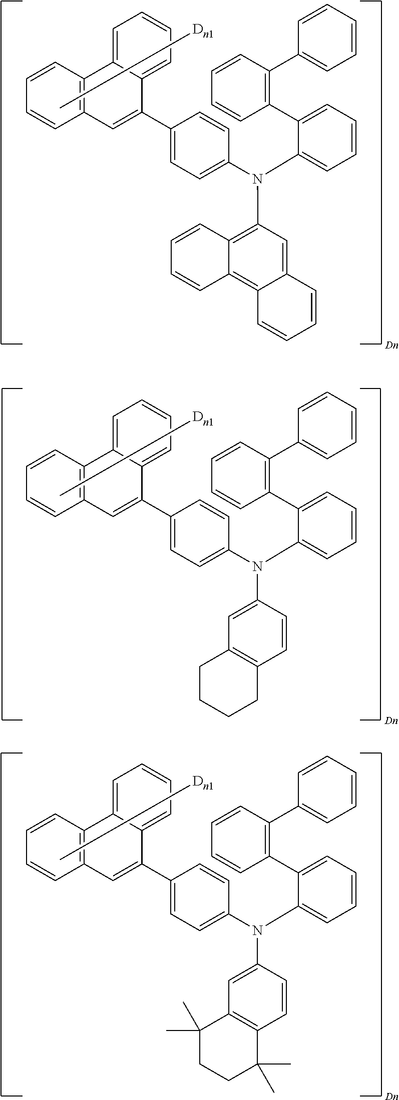

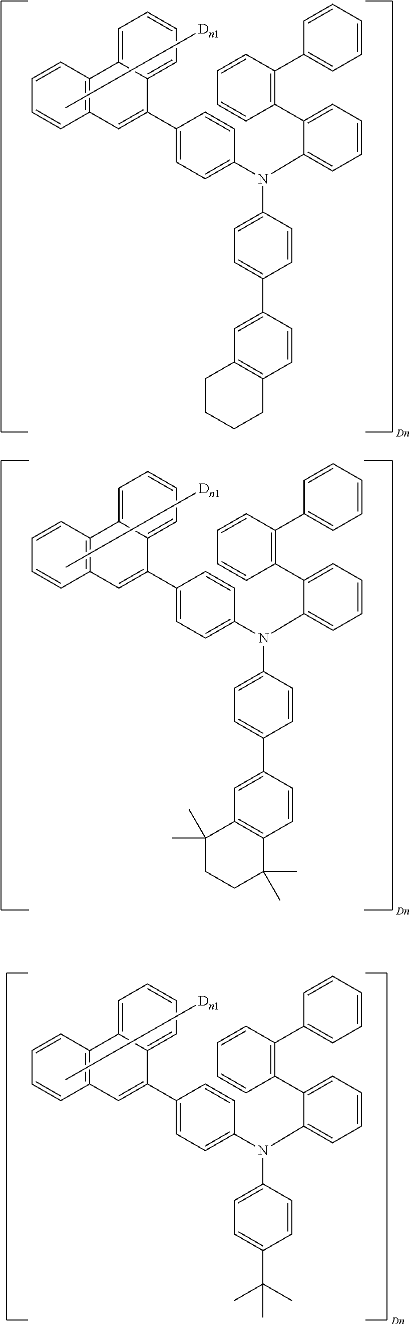

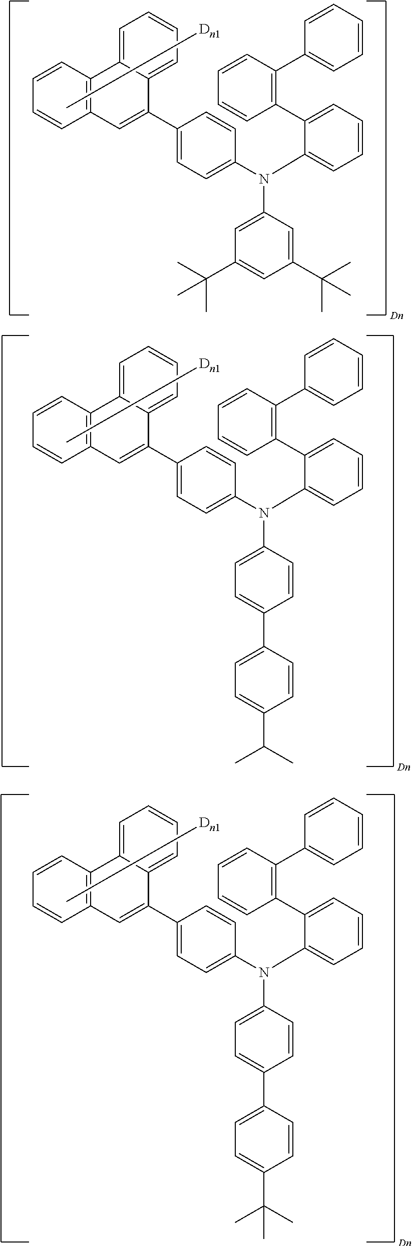

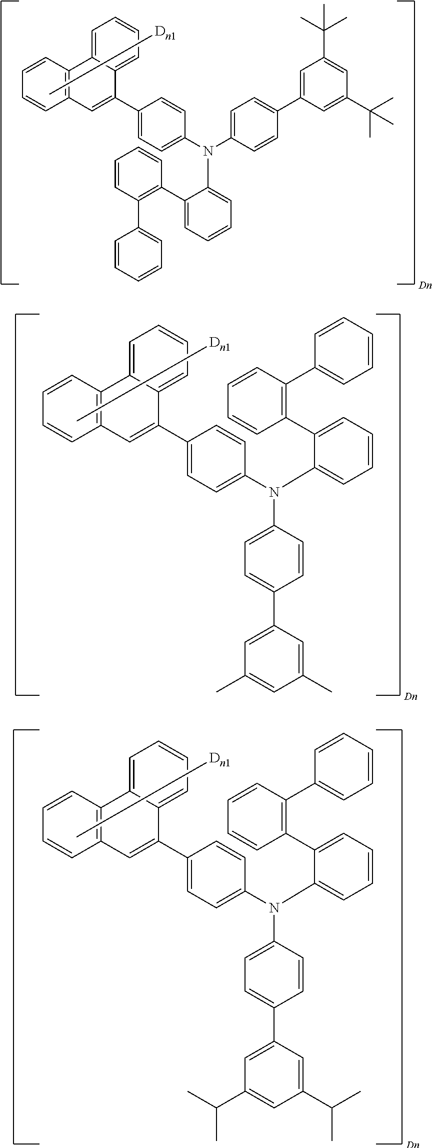

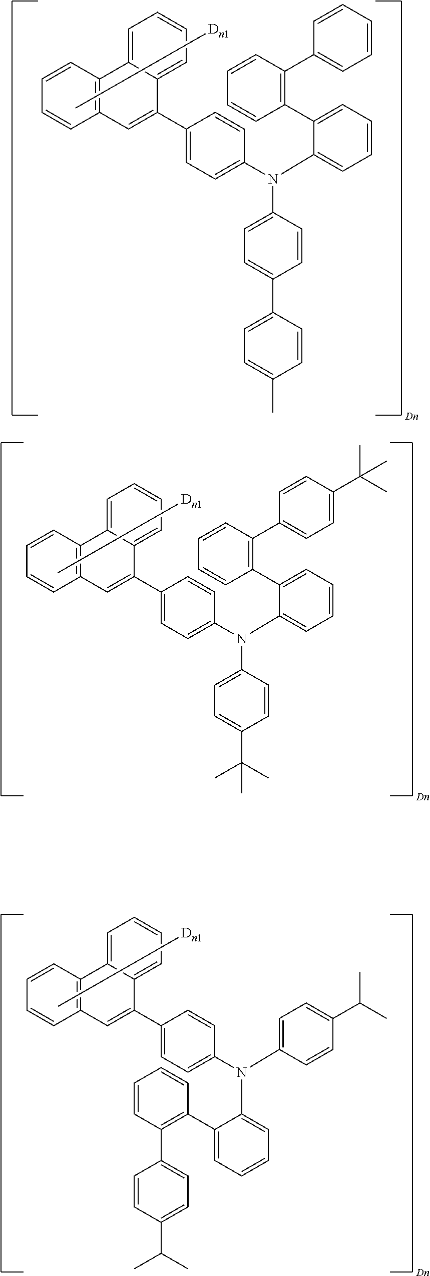

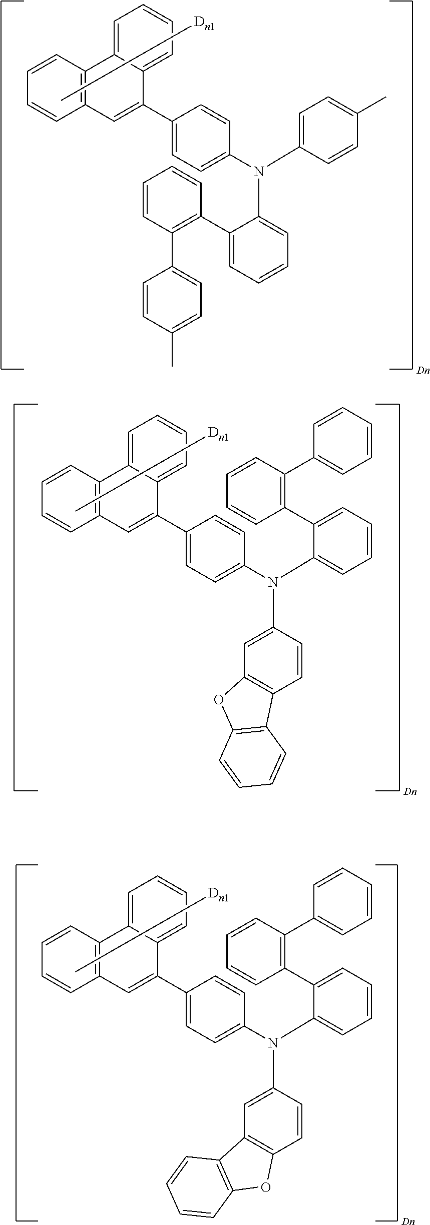

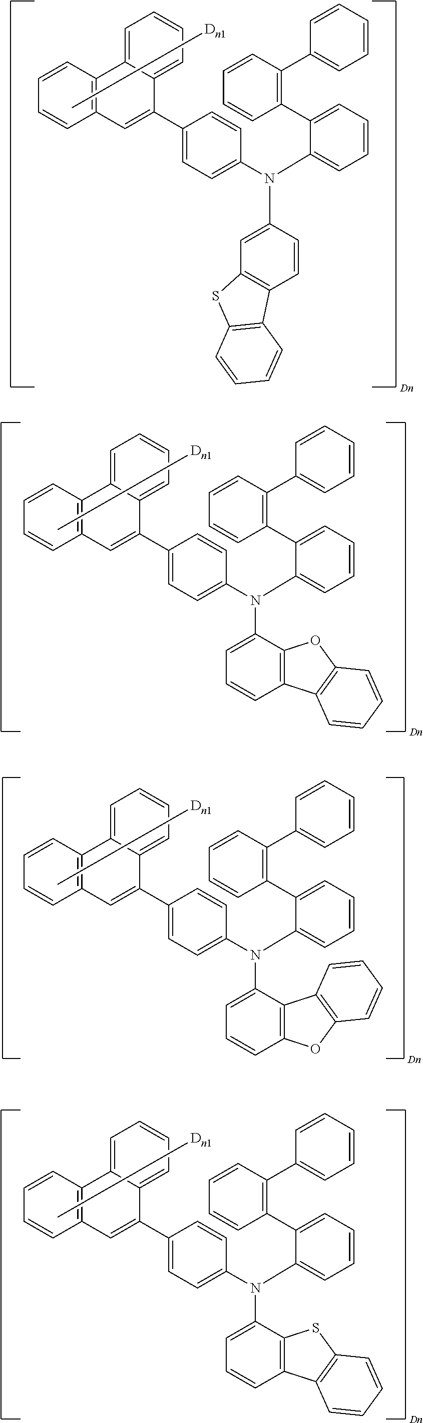

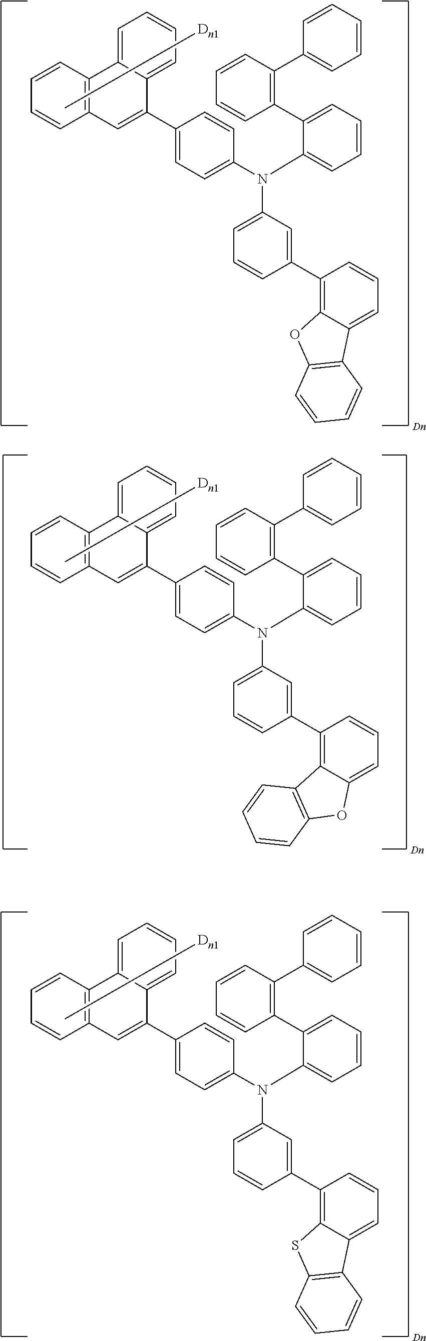

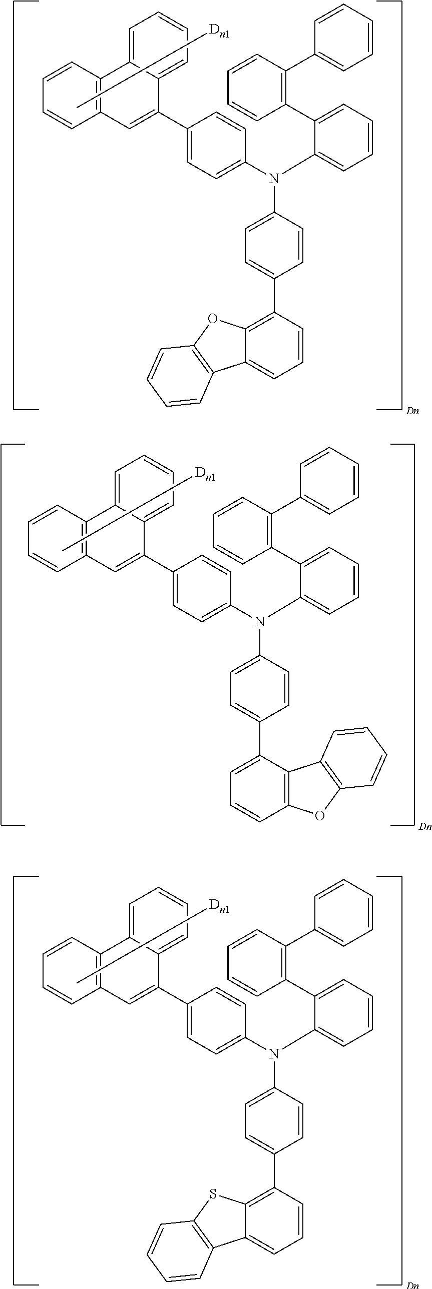

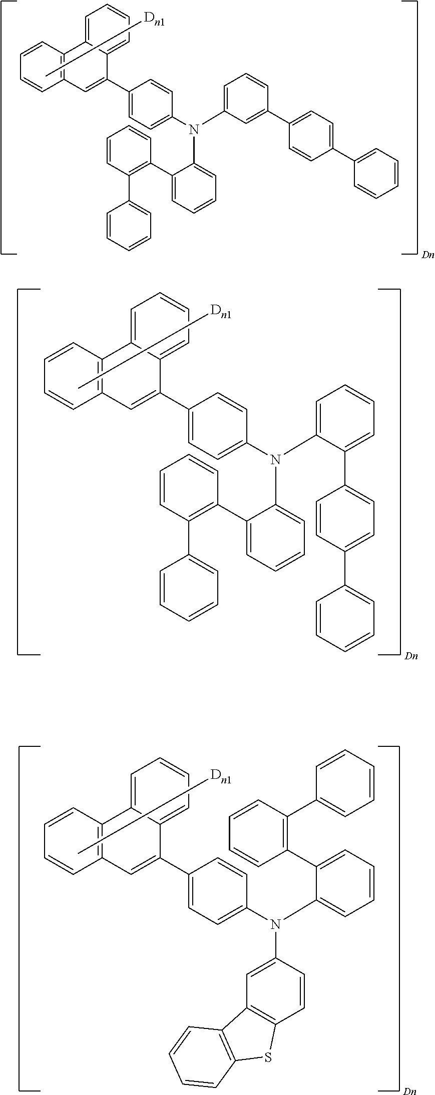

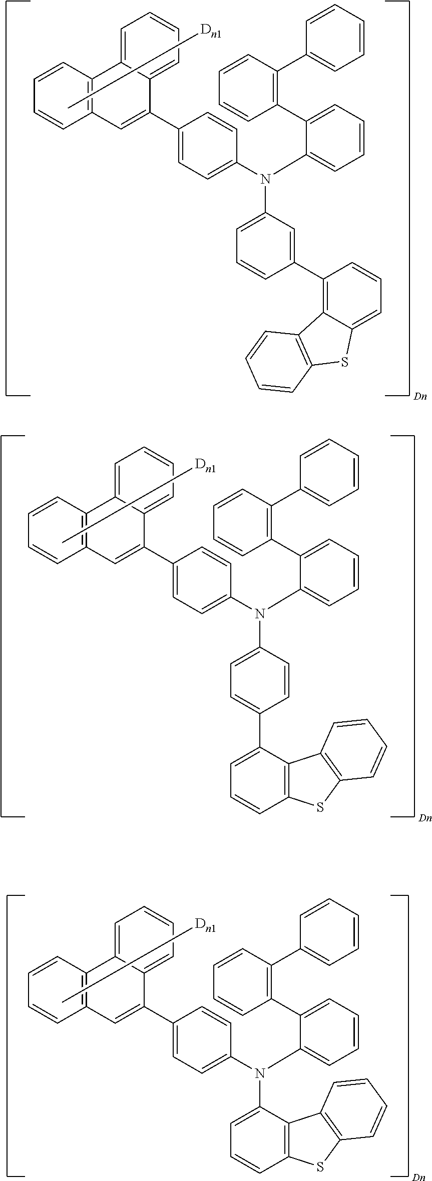

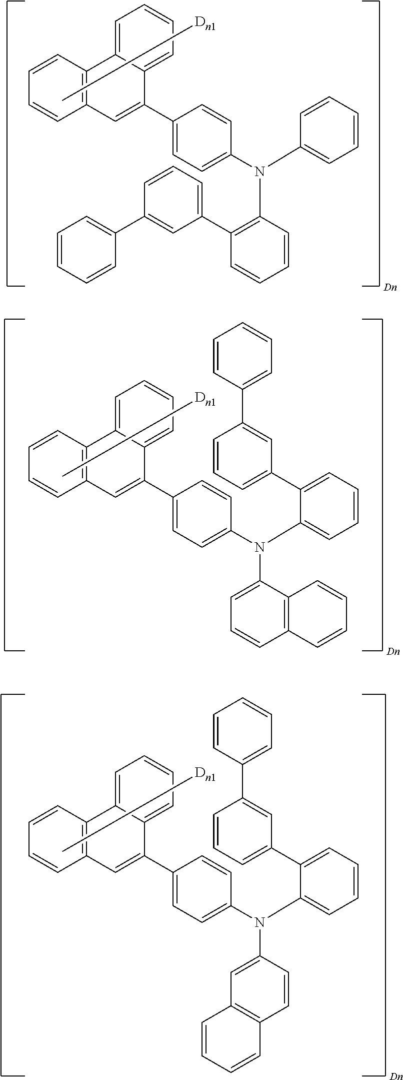

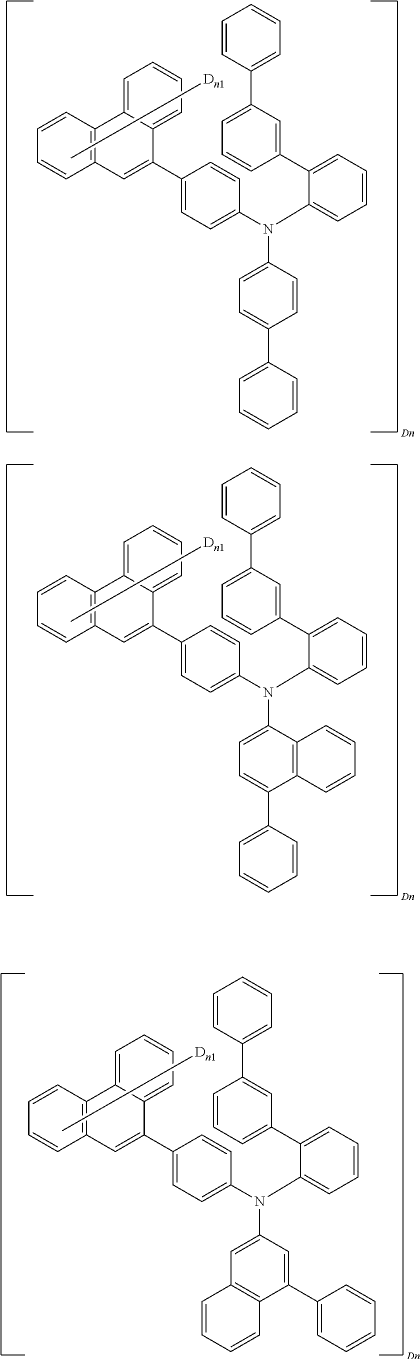

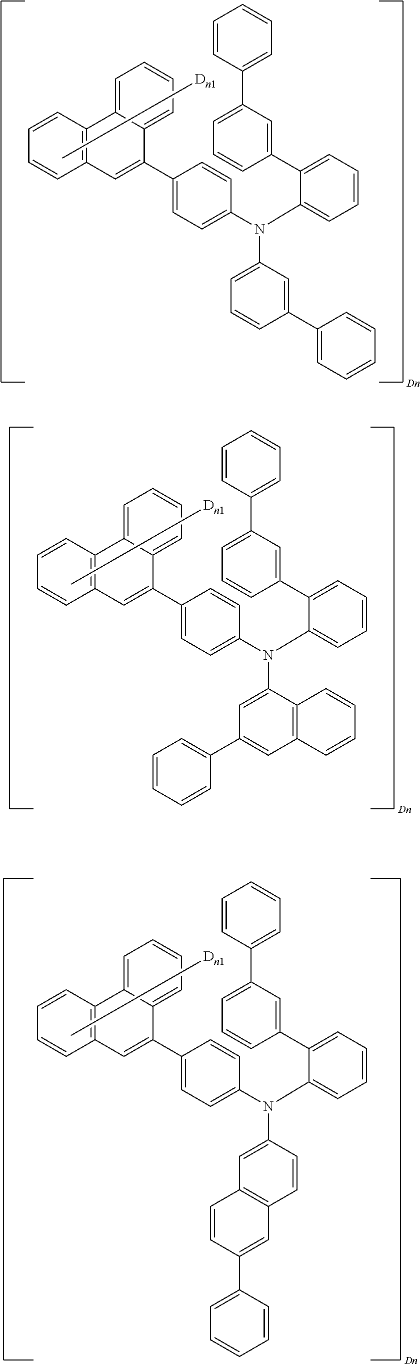

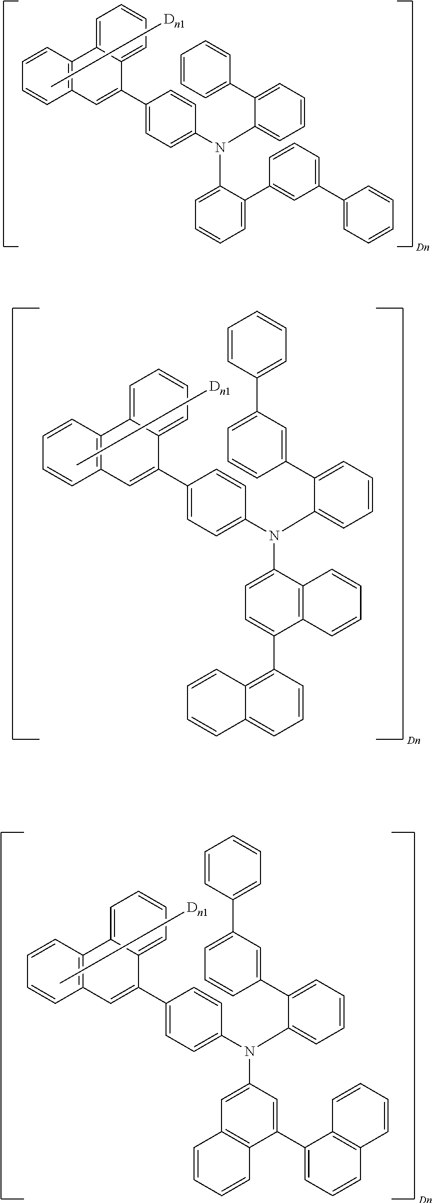

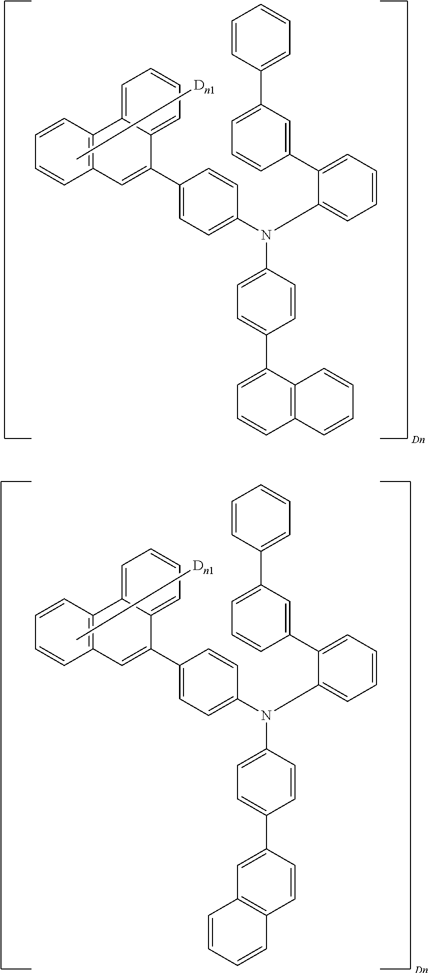

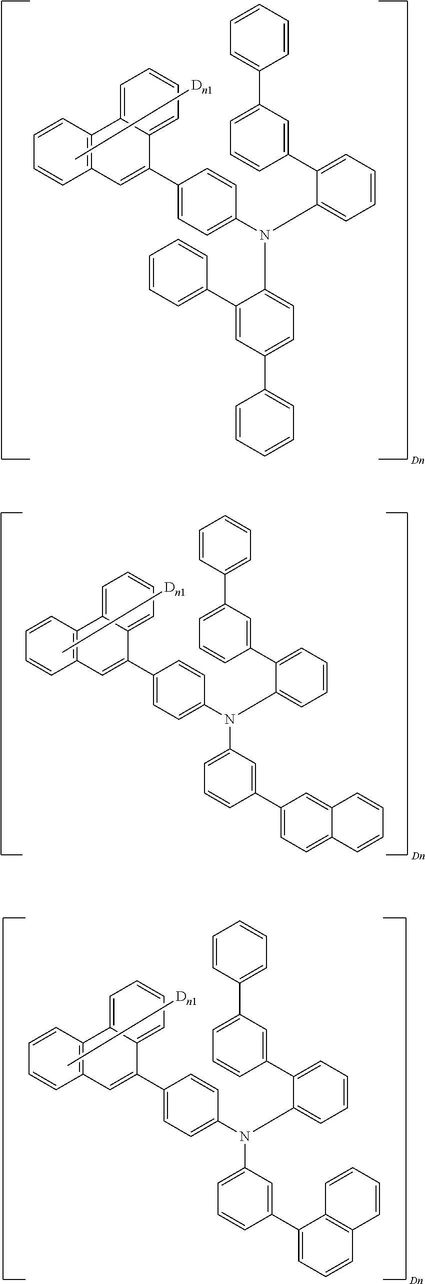

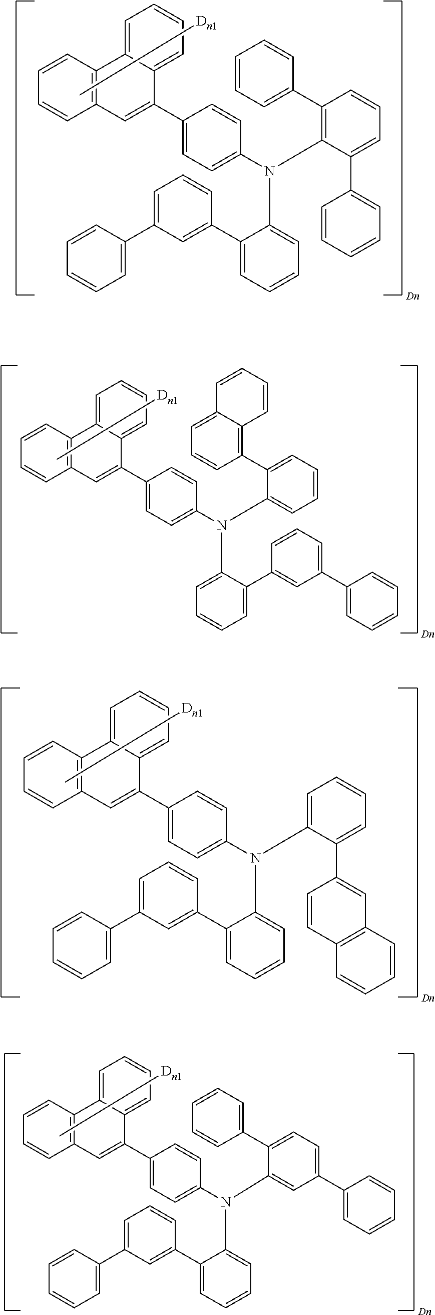

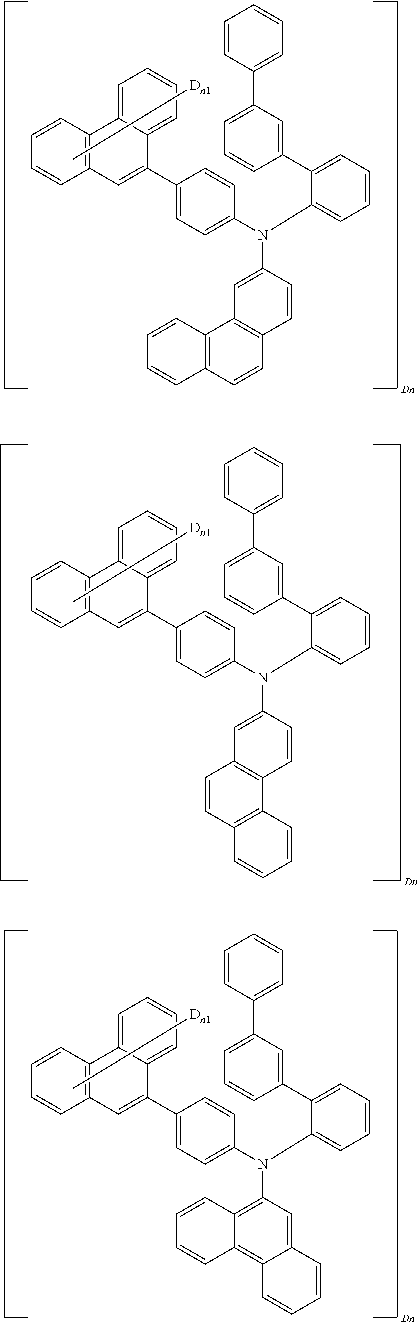

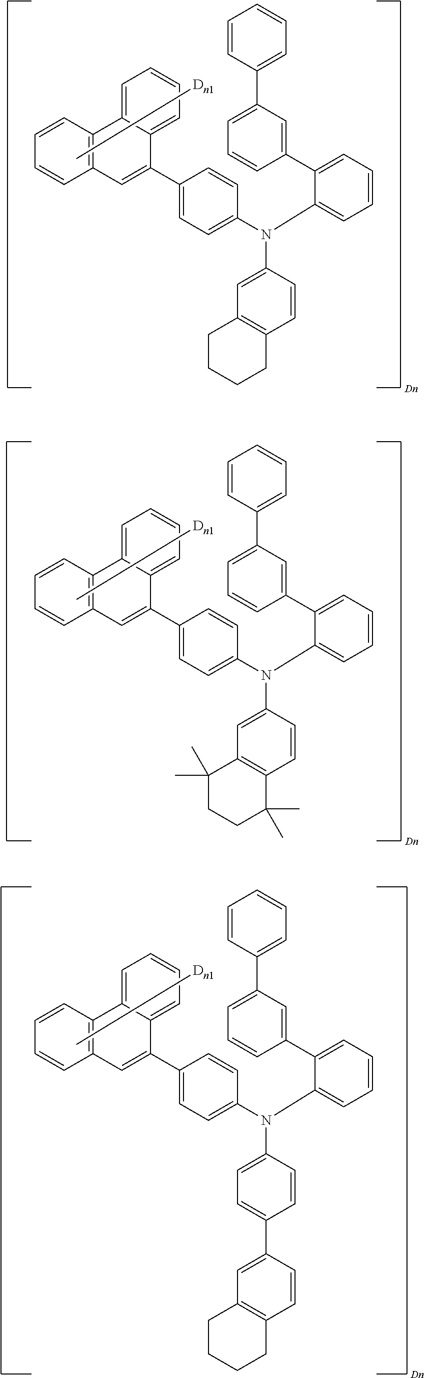

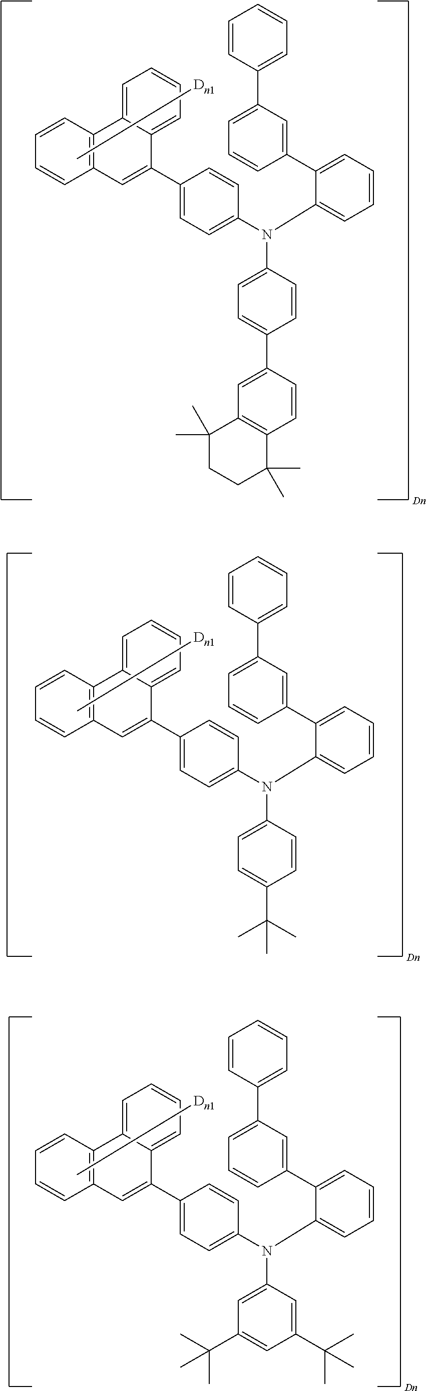

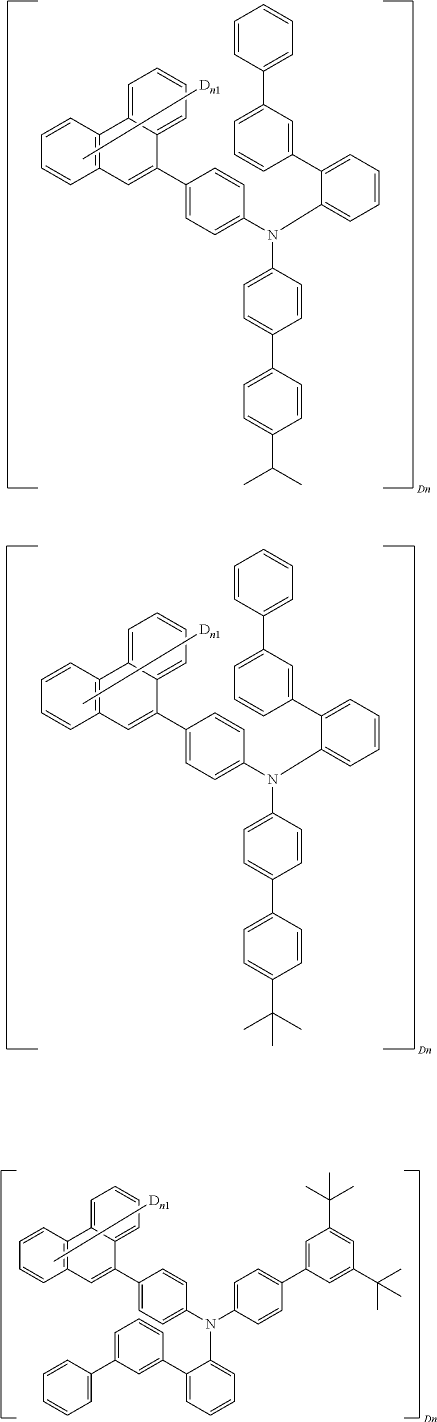

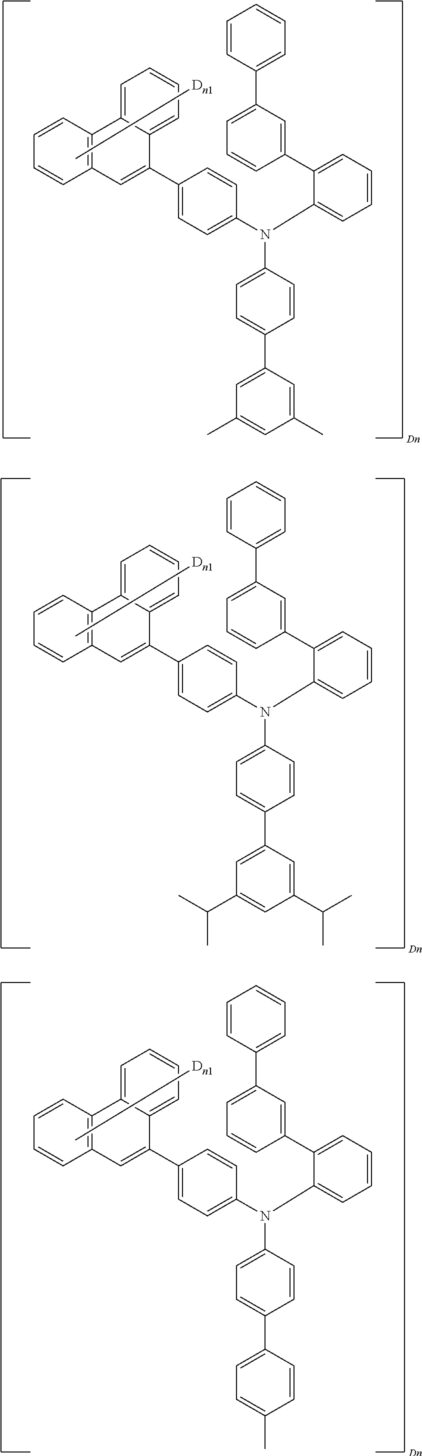

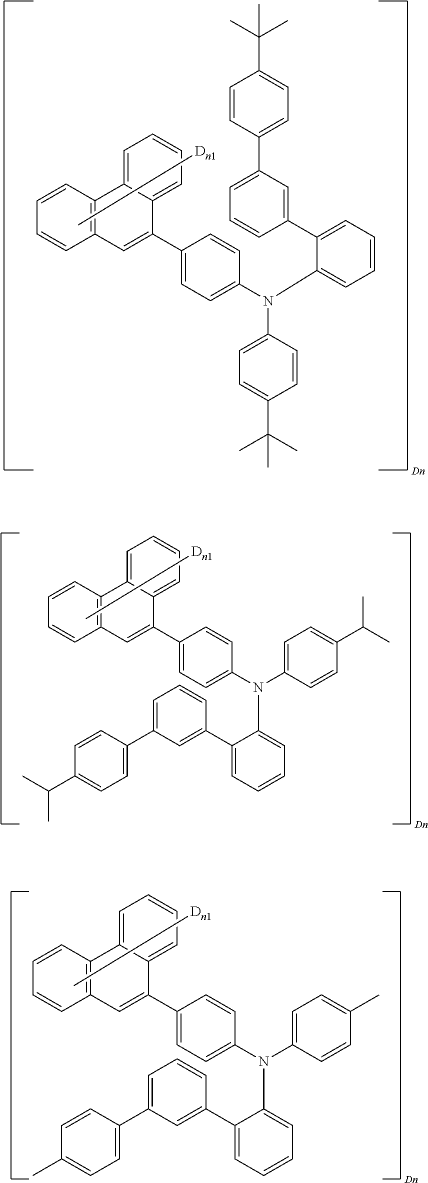

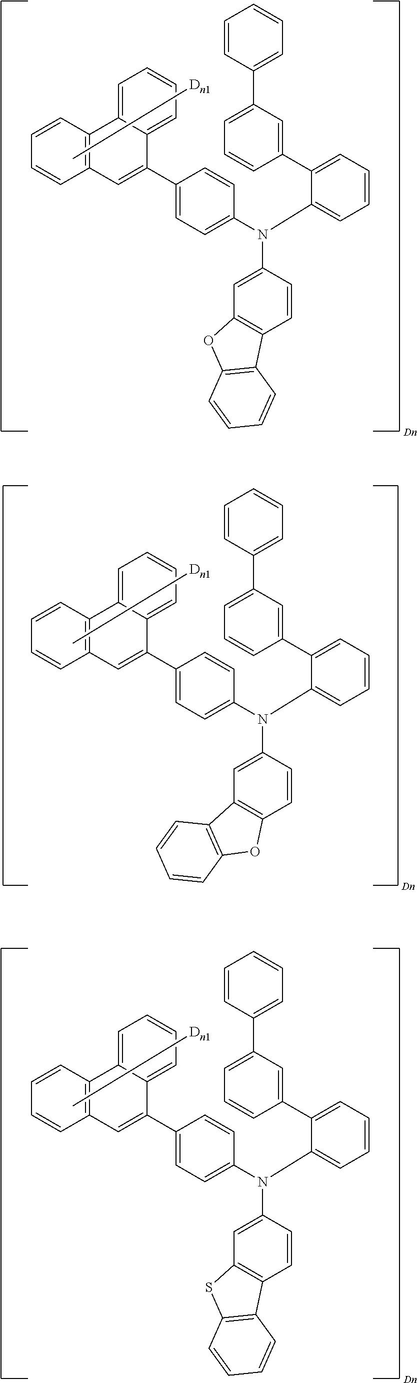

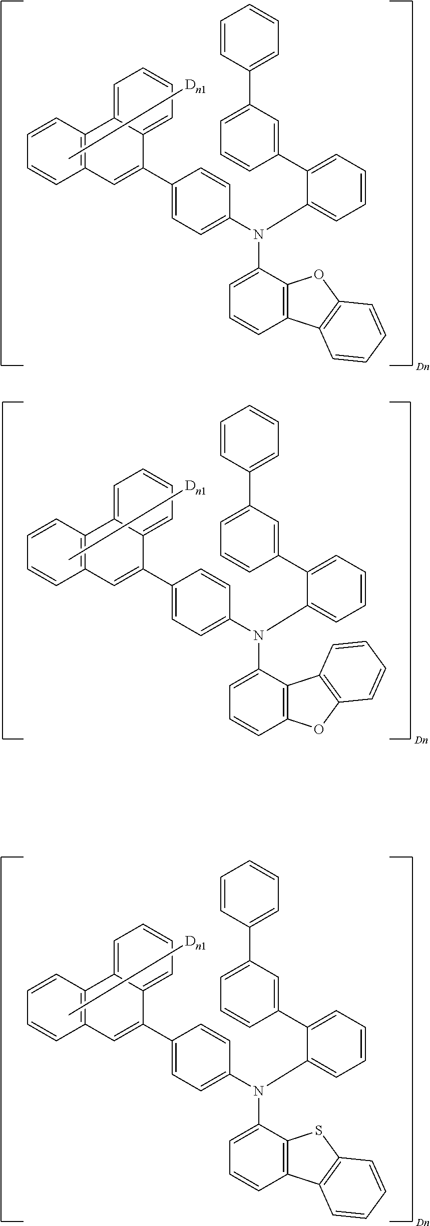

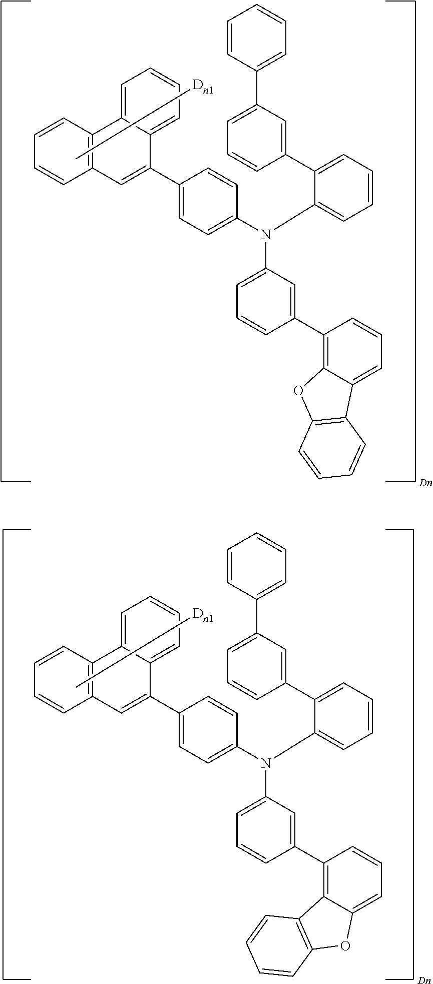

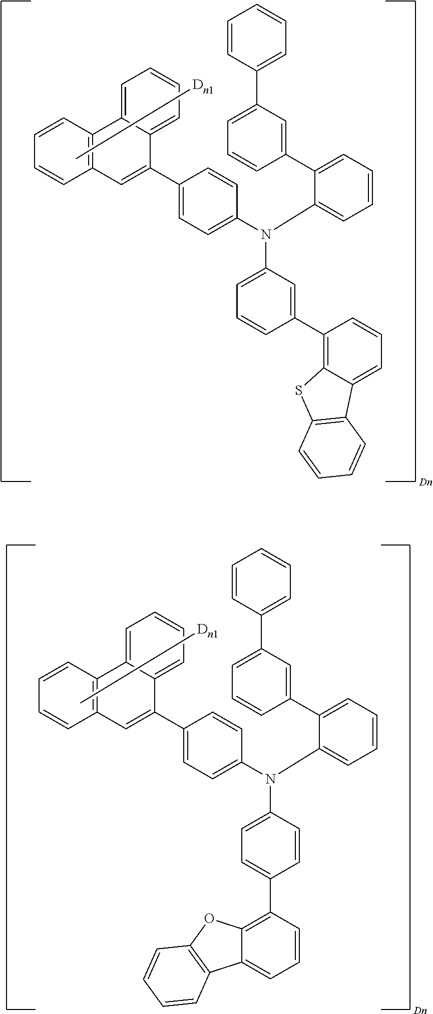

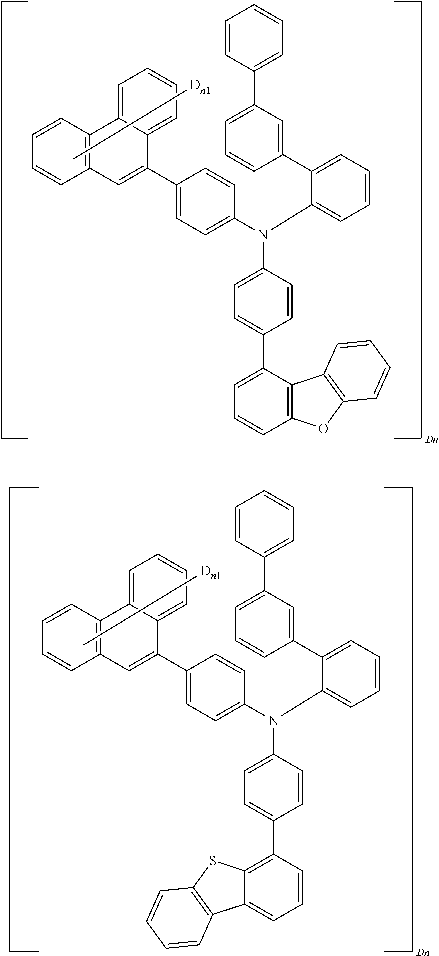

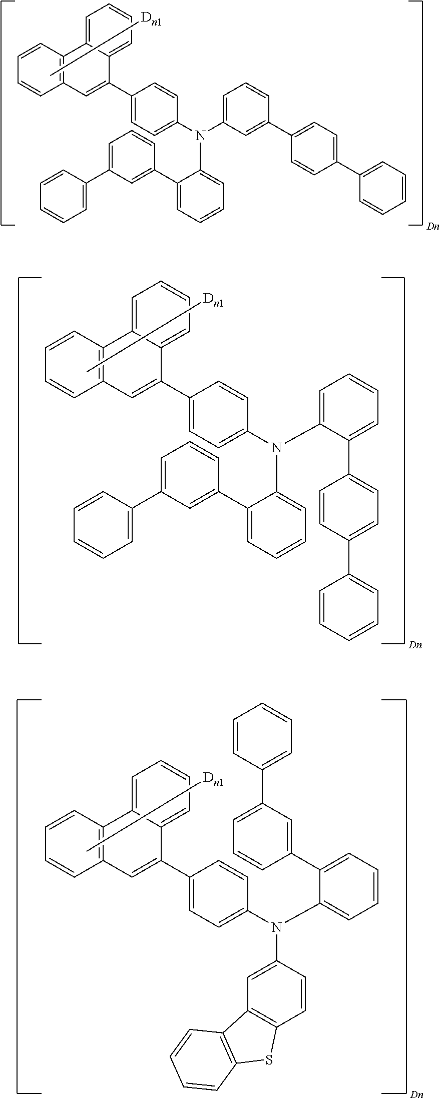

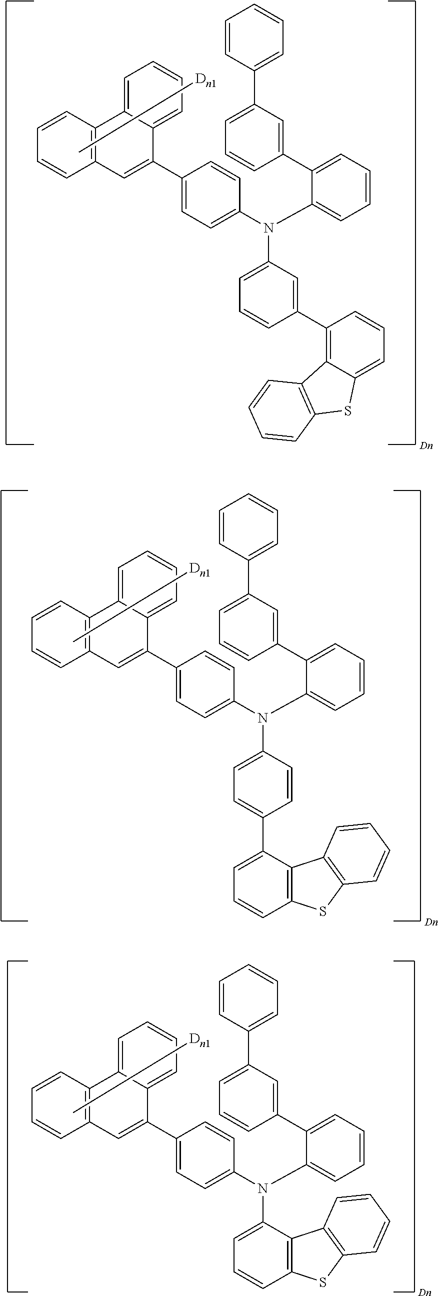

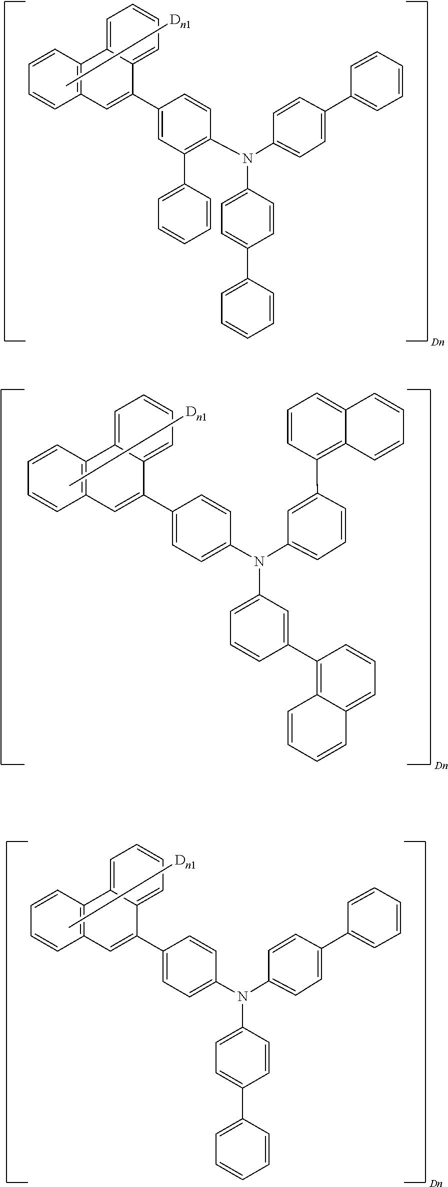

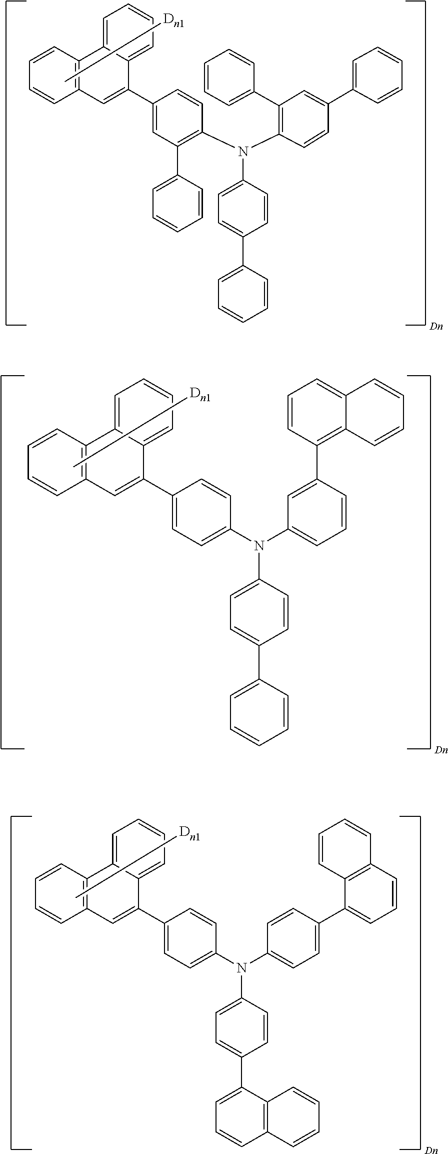

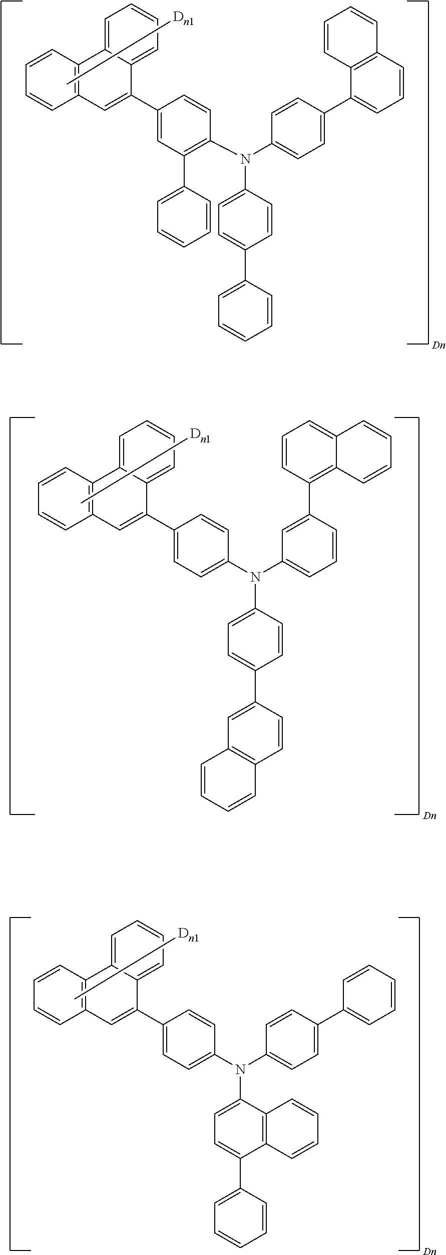

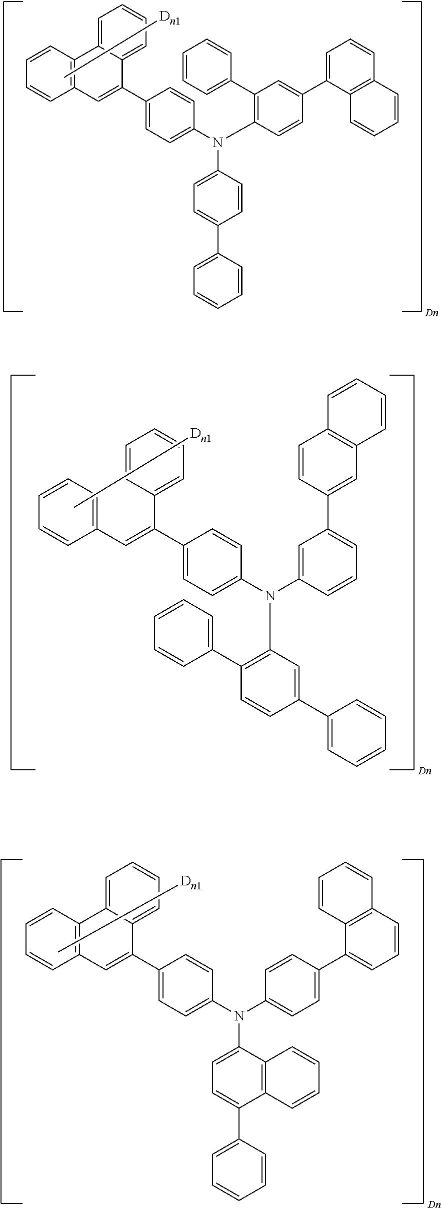

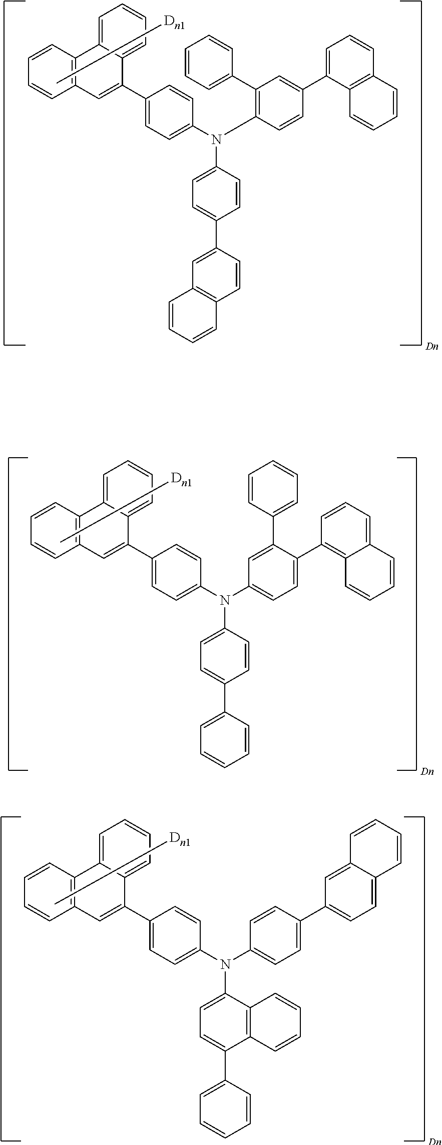

in the above group, D is deuterium,
n1 is an integer of 1 to 9, and
n is the total number of deuterium substituted in the compound,
wherein each of the above compounds has a deuterium substitution rate of 50% or more.

When the compound represented by Chemical Formula 2 is, for example, a compound represented by Chemical Formula 2-D, the compound can be prepared according to the preparation method as shown in in Reaction Scheme 2 below, and the remaining compounds can also be prepared in a similar manner.

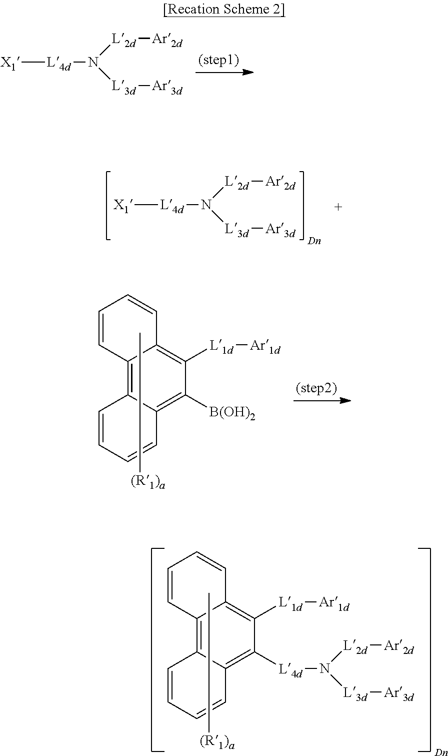

in Reaction Scheme 2, Dn, Ar′_{1d} to Ar′_{3d} and L′_{1d} to L′_{4d} are the same as defined in Chemical Formula 2-D, X₁′ is halogen, and preferably X₁ is chloro or bromo.

The compound represented by Chemical Formula 2 in Reaction Scheme 2 may be prepared by subjecting each deuterium-substituted reactant to a Suzuki coupling reaction, and Reaction Scheme 2 proceeds through a deuterium substitution reaction (step 1) followed by a Suzuki coupling reaction (step 2). The deuterium substitution reaction is preferably carried out in the presence of D₂O, and the reactive group, catalyst, solvent, and the like for the deuterium substitution reaction can be changed to suit the desired product as known in the art. The Suzuki coupling reaction is preferably carried out in the presence of a palladium catalyst and a base, and a reactive group for the Suzuki coupling reaction can be changed as known in the art. The preparation method can be more specifically described in Preparation Examples described hereinafter.

Preferably, the weight ratio of the compound represented by Chemical Formula 1 and the compound represented by Chemical Formula 2 in the light emitting layer is 10:90 to 90:10, more preferably 20:80 to 80:20, and 30:70 to 30:70. 70:30 or 40:60 to 60:40.

On the other hand, the light emitting layer may further include a dopant in addition to the host. The dopant material is not particularly limited as long as it is a material used for the organic light emitting device. As an example, an aromatic amine derivative, a styrylamine compound, a boron complex, a fluoranthene compound, a metal complex, and the like can be mentioned. Specific examples of the aromatic amine derivatives include substituted or unsubstituted fused aromatic ring derivatives having an arylamino group, examples thereof include pyrene, anthracene, chrysene, and periflanthene having an arylamino group, and the like. The styrylamine compound is a compound where at least one arylvinyl group is substituted in substituted or unsubstituted arylamine, in which one or two or more substituent groups selected from the group consisting of an aryl group, a silyl group, an alkyl group, a cycloalkyl group, and an arylamino group are substituted or unsubstituted. Specific examples thereof include styrylamine, styryldiamine, styryltriamine, styryltetramine, and the like, but are not limited thereto. Further, examples of the metal complex include an iridium complex, a platinum complex, and the like, but are not limited thereto.

In one example, the dopant material may be any one or more compounds selected from the group consisting of the following compounds, but is not limited thereto:

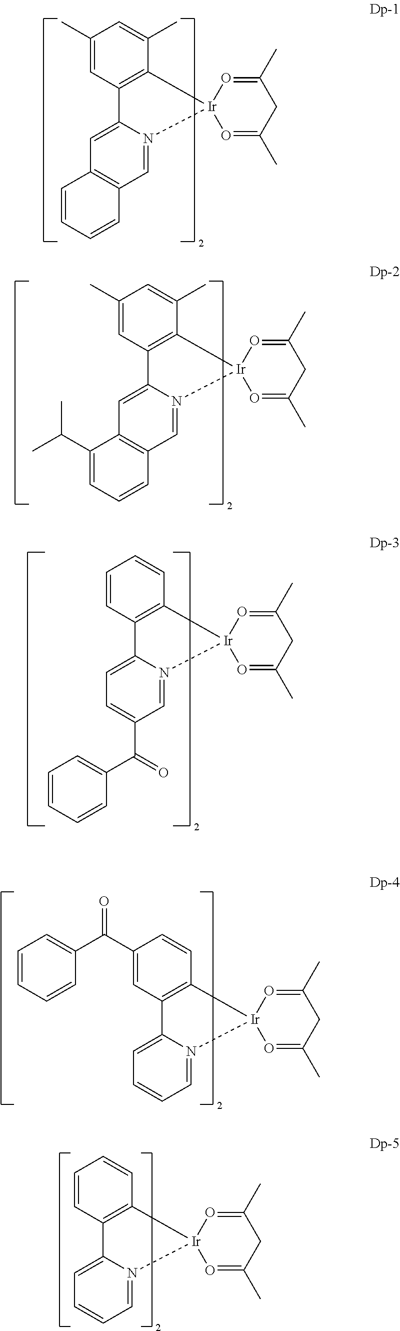

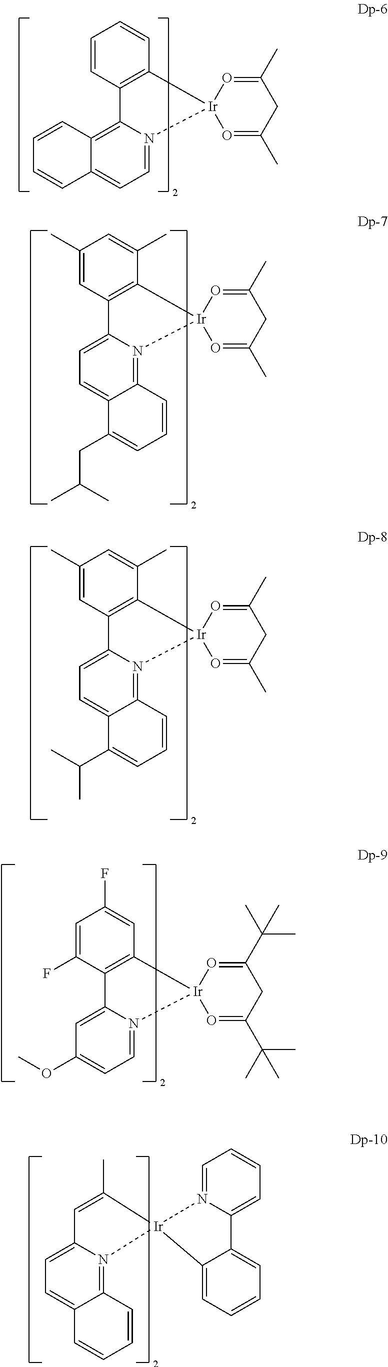

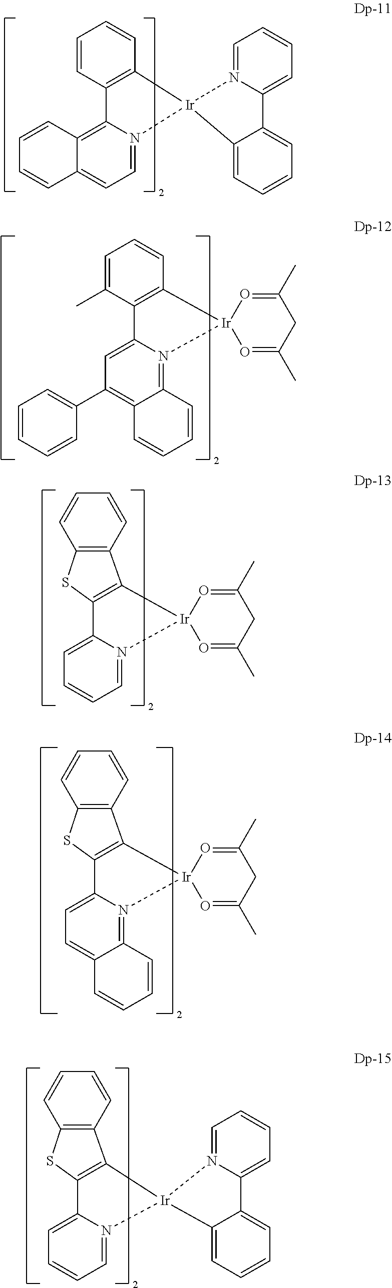

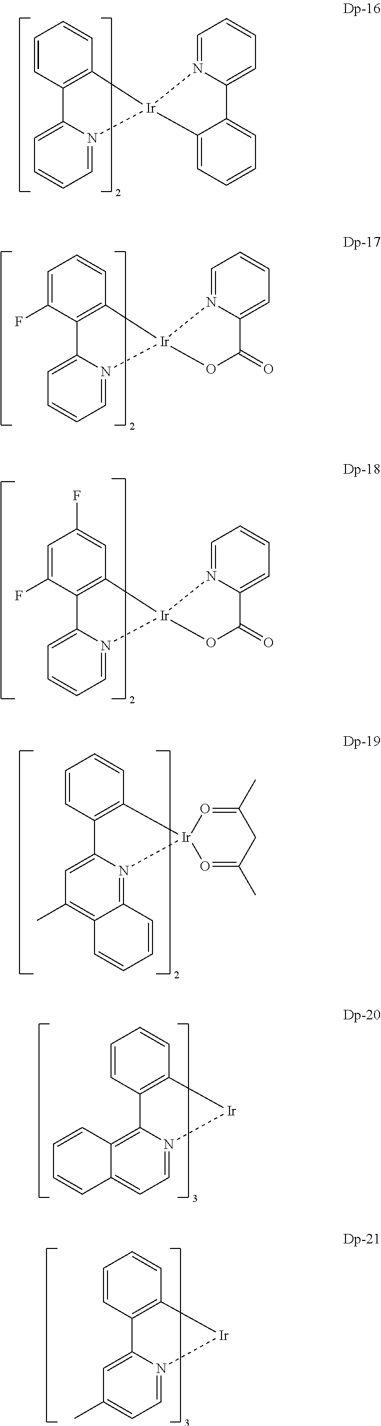

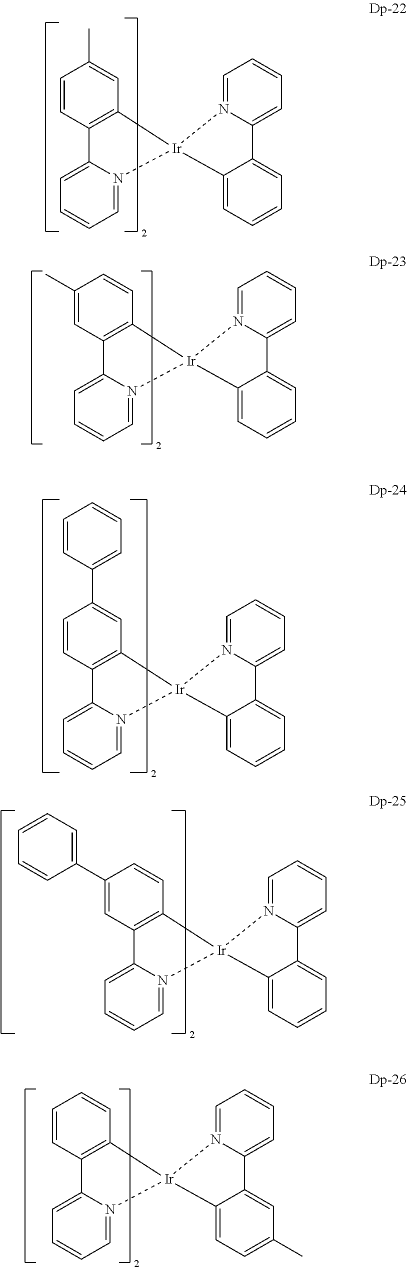

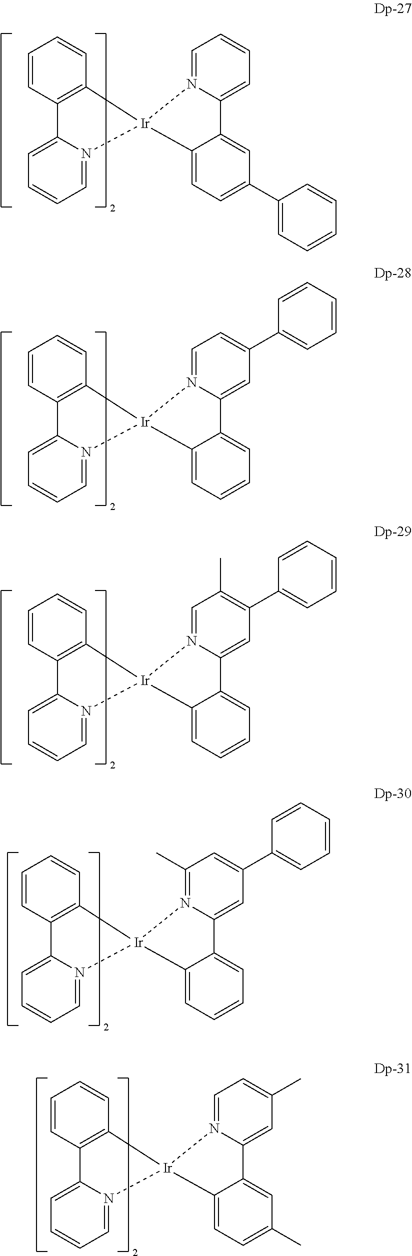

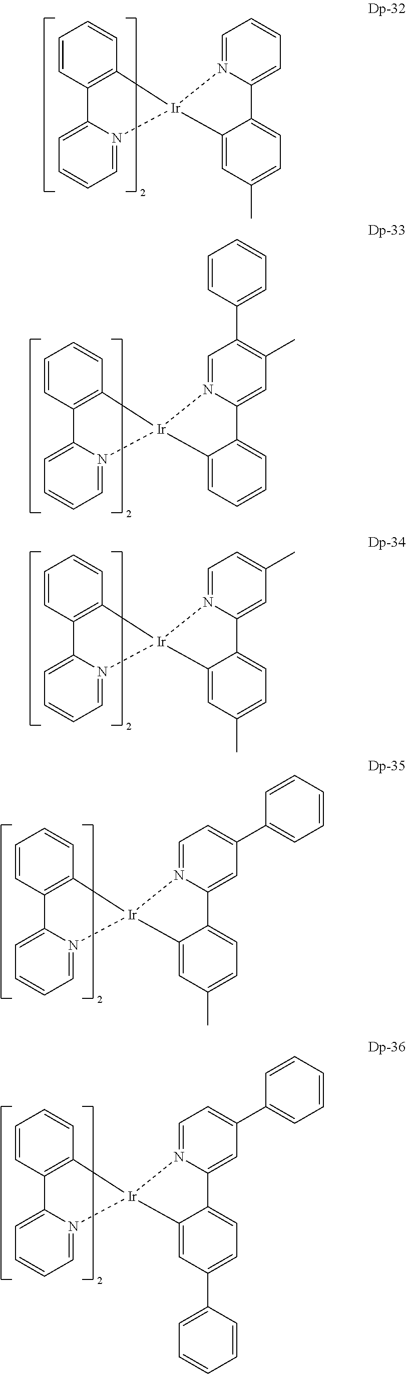

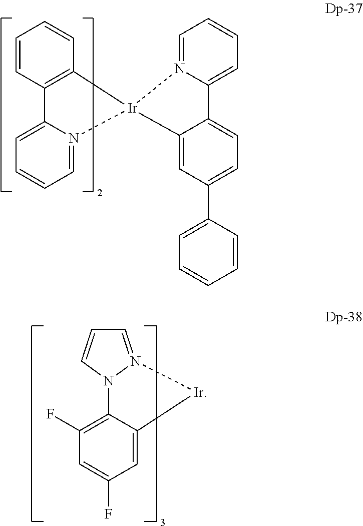

### Hole Blocking Layer

The hole blocking layer is a layer provided between the electron transport layer and the light emitting layer in order to prevent the holes injected in the anode from being transferred to the electron transport layer without being recombined in the light emitting layer, which may also be referred to as a hole inhibition layer or a hole stopping layer. The hole blocking layer is preferably a material having the large ionization energy.

### Electron Transport Layer

The organic light emitting device according to the present disclosure may include an electron transport layer on the light emitting layer, if necessary.

The electron transport layer is a layer that receives the electrons from the cathode or the electron injection layer formed on the cathode and transports the electrons to the light emitting layer, and that suppress transfer of holes from the light emitting layer, and an electron transport material is suitably a material which may receive well injection of electrons from a cathode and transfer the electrons to a light emitting layer, and has a large mobility for electrons.

Specific examples of the electron transport material include: an Al complex of 8-hydroxyquinoline; a complex including Alq₃; an organic radical compound; a hydroxyflavone-metal complex, and the like, but are not limited thereto. The electron transport layer may be used with any desired cathode material, as used according to a conventional technique. In particular, appropriate examples of the cathode material are a typical material which has a low work function, followed by an aluminum layer or a silver layer. Specific examples thereof include cesium, barium, calcium, ytterbium, and samarium, in each case followed by an aluminum layer or a silver layer.

### Electron Injection Layer

The organic light emitting device according to the present disclosure may further include an electron injection layer on the light emitting layer (or on an electron transport layer, if the electron transport layer exists), if necessary.

The electron injection layer is a layer which injects electrons from an electrode, and is preferably a compound which has a capability of transporting electrons, has an effect of injecting electrons from a cathode and an excellent effect of injecting electrons into a light emitting layer or a light emitting material, prevents excitons produced from the light emitting layer from moving to a hole injection layer, and is also excellent in the ability to form a thin film.

Specific examples of the electron injection layer include fluorenone, anthraquinodimethane, diphenoquinone, thiopyran dioxide, oxazole, oxadiazole, triazole, imidazole, perylenetetracarboxylic acid, fluorenylidene methane, anthrone, and the like, and derivatives thereof, a metal complex compound, a nitrogen-containing 5-membered ring derivative, and the like, but are not limited thereto.

Examples of the metal complex compound include 8-hydroxyquinolinato lithium, bis(8-hydroxyquinolinato)zinc, bis(8-hydroxyquinolinato)copper, bis(8-hydroxyquinolinato)manganese, tris(8-hydroxyquinolinato)aluminum, tris(2-methyl-8-hydroxyquinolinato)aluminum, tris(8-hydroxyquinolinato)gallium, bis(10-hydroxybenzo[h]quinolinato)beryllium, bis(10-hydroxybenzo[h]quinolinato)zinc, bis(2-methyl-8-quinolinato)chlorogallium, bis(2-methyl-8-quinolinato)(o-cresolato)gallium, bis(2-methyl-8-quinolinato)(1-naphtholato)aluminum, bis(2-methyl-8-quinolinato)(2-naphtholato)gallium, and the like, but are not limited thereto.

On the other hand, in the present disclosure, the “electron injection and transport layer” is a layer that performs both the roles of the electron injection layer and the electron transport layer, and the materials that perform the roles of each layer may be used alone or used in combination, without being limited thereto.

### Organic Light Emitting Device

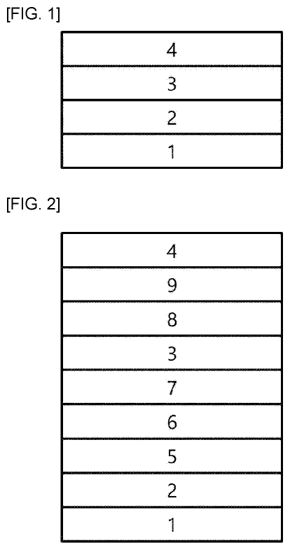

The structure of the organic light emitting device according to the present disclosure is illustrated in FIGS. 1 and 2. FIG. 1 shows an example of an organic light emitting device comprising a substrate 1, an anode 2, a light emitting layer 3, and a cathode 4. FIG. 2 shows an example of an organic light emitting device comprising a substrate 1, an anode 2, a hole injection layer 5, a hole transport layer 6, an electron blocking layer 7, a light emitting layer 3, a hole blocking layer 8, an electron injection and transport layer 9, and a cathode 4.

The organic light emitting device according to the present disclosure can be manufactured by sequentially stacking the above-described structures. In this case, the organic light emitting device may be manufactured by depositing a metal, metal oxides having conductivity, or an alloy thereof on the substrate by using a PVD(physical vapor deposition) method such as a sputtering method or an e-beam evaporation method to form the anode, forming the respective layers described above thereon, and then depositing a material that can be used as the cathode thereon. In addition to such a method, the organic light emitting device may be manufactured by sequentially depositing from the cathode material to the anode material on a substrate in the reverse order of the above-mentioned configuration (WO 2003/012890). Further, the light emitting layer may be formed by subjecting hosts and dopants to a vacuum deposition method and a solution coating method. Herein, the solution coating method means a spin coating, a dip coating, a doctor blading, an inkjet printing, a screen printing, a spray method, a roll coating, or the like, but is not limited thereto.

Meanwhile, the organic light emitting device according to the present disclosure may be a bottom emission device, a top emission device, or a double-sided light emitting device.

Below, preferable embodiments are presented to assist in the understanding of the present disclosure. The following examples are only provided for a better understanding of the present disclosure, and is not intended to limit the content of the present disclosure.

### Preparation Example 1-1

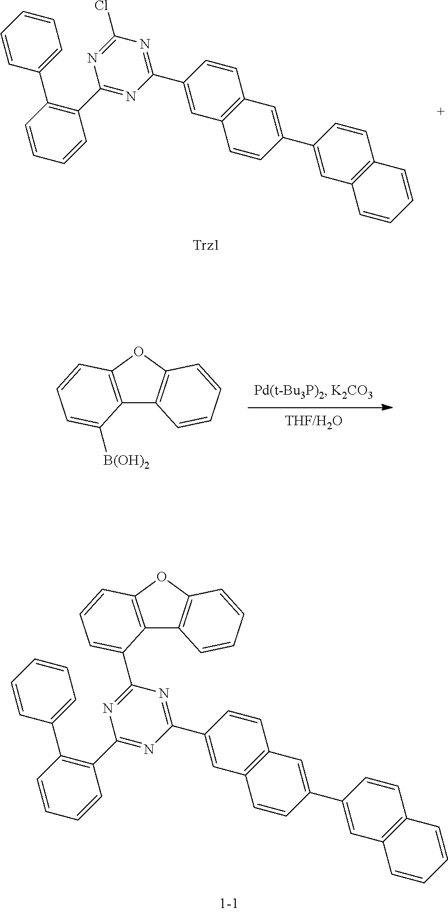 [SMILES: Clc1nc(-c2ccc3cc(-c4ccc5ccccc5c4)ccc3c2)nc(-c2ccccc2-c2ccccc2)n1 ; OB(O)c1cccc2oc3ccccc3c12 ; "THF/H2O" ; c1ccc(-c2ccccc2-c2nc(-c3ccc4cc(-c5ccc6ccccc6c5)ccc4c3)nc(-c3cccc4oc5ccccc5c34)n2)cc1]

Compound Trz1(15 g, 28.8 mmol) and dibenzo[b,d]furan-1-ylboronic acid(6.4 g, 30.3 mmol) were added to 300 ml of THF, and the mixture was stirred and refluxed. Then, potassium carbonate(12 g, 86.5 mmol) was dissolved in 36 ml of water and added thereto, and the mixture was sufficiently stirred and then bis(tri-tert-butylphosphine)palladium(0) (0.1 g, 0.3 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 12.2 g of Compound 1-1. (Yield: 65%, MS: [M+H]⁺=652).

### Preparation Example 1-2

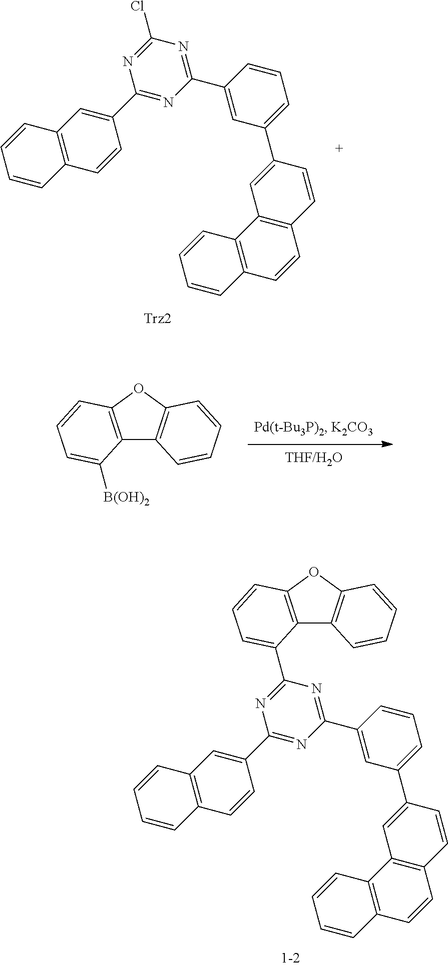 [SMILES: Clc1nc(-c2cccc(-c3ccc4ccc5ccccc5c4c3)c2)nc(-c2ccc3ccccc3c2)n1 ; OB(O)c1cccc2oc3ccccc3c12 ; "THF/H2O" ; c1cc(-c2ccc3ccc4ccccc4c3c2)cc(-c2nc(-c3ccc4ccccc4c3)nc(-c3cccc4oc5ccccc5c34)n2)c1]

Compound Trz2(15 g, 30.4 mmol) and dibenzo[b,d]furan-1-ylboronic acid(6.8 g, 31.9 mmol) were added to 300 ml of THF, and the mixture was stirred and refluxed. Then, potassium carbonate(12.6 g, 91.1 mmol) was dissolved in 38 ml of water and added thereto, and the mixture was sufficiently stirred and then bis(tri-tert-butylphosphine)palladium(0) (0.2 g, 0.3 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 14 g of Compound 1-2. (Yield: 74%, MS: [M+H]⁺=626).

### Preparation Example 1-3

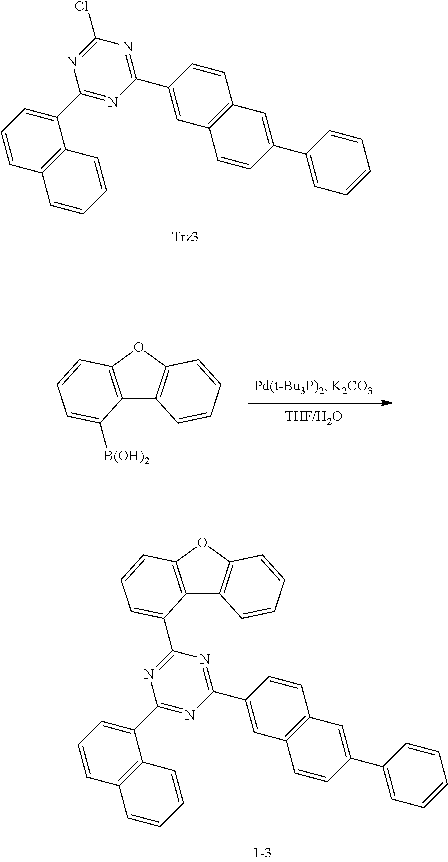 [SMILES: Clc1nc(-c2ccc3cc(-c4ccccc4)ccc3c2)nc(-c2cccc3ccccc23)n1 ; OB(O)c1cccc2oc3ccccc3c12 ; "THF/H2O" ; c1ccc(-c2ccc3cc(-c4nc(-c5cccc6ccccc56)nc(-c5cccc6oc7ccccc7c56)n4)ccc3c2)cc1]

Compound Trz3(15 g, 33.8 mmol) and dibenzo[b,d]furan-1-ylboronic acid(7.5 g, 35.5 mmol) were added to 300 ml of THF, and the mixture was stirred and refluxed. Then, potassium carbonate(14 g, 101.4 mmol) was dissolved in 42 ml of water and added thereto, and the mixture was sufficiently stirred and then bis(tri-tert-butylphosphine)palladium(0) (0.2 g, 0.3 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.4 g of Compound 1-3. (Yield: 69%, MS: [M+H]⁺=576).

### Preparation Example 1-4

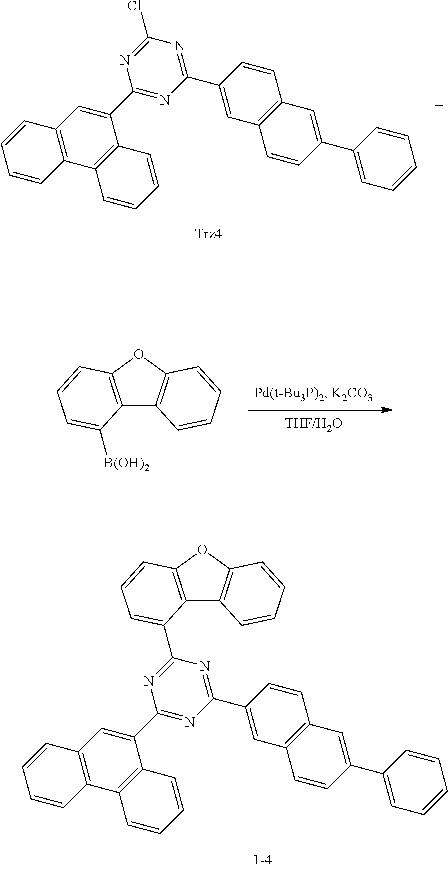 [SMILES: Clc1nc(-c2ccc3cc(-c4ccccc4)ccc3c2)nc(-c2cc3ccccc3c3ccccc23)n1 ; OB(O)c1cccc2oc3ccccc3c12 ; "THF/H2O" ; c1ccc(-c2ccc3cc(-c4nc(-c5cc6ccccc6c6ccccc56)nc(-c5cccc6oc7ccccc7c56)n4)ccc3c2)cc1]

Compound Trz4(15 g, 30.4 mmol) and dibenzo[b,d]furan-1-ylboronic acid(6.8 g, 31.9 mmol) were added to 300 ml of THF, and the mixture was stirred and refluxed. Then, potassium carbonate(12.6 g, 91.1 mmol) was dissolved in 38 ml of water and added thereto, and the mixture was sufficiently stirred and then bis(tri-tert-butylphosphine)palladium(0) (0.2 g, 0.3 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.3 g of Compound 1-4. (Yield: 70%, MS: [M+H]⁺=626).

### Preparation Example 1-5

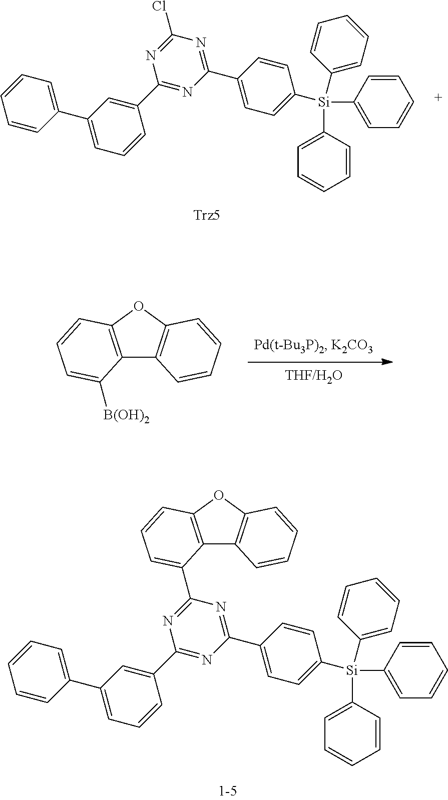 [SMILES: Clc1nc(-c2ccc([Si](c3ccccc3)(c3ccccc3)c3ccccc3)cc2)nc(-c2cccc(-c3ccccc3)c2)n1 ; OB(O)c1cccc2oc3ccccc3c12 ; "THF/H2O" ; c1ccc(-c2cccc(-c3nc(-c4ccc([Si](c5ccccc5)(c5ccccc5)c5ccccc5)cc4)nc(-c4cccc5oc6ccccc6c45)n3)c2)cc1]

Compound Trz5(15 g, 24.9 mmol) and dibenzo[b,d]furan-1-ylboronic acid(5.5 g, 26.2 mmol) were added to 300 ml of THF, and the mixture was stirred and refluxed. Then, potassium carbonate(10.3 g, 74.7 mmol) was dissolved in 31 ml of water and added thereto, and the mixture was sufficiently stirred and then bis(tri-tert-butylphosphine)palladium(0) (0.1 g, 0.2 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 12.6 g of Compound 1-5. (Yield: 69%, MS: [M+H]⁺=734).

### Preparation Example 1-6

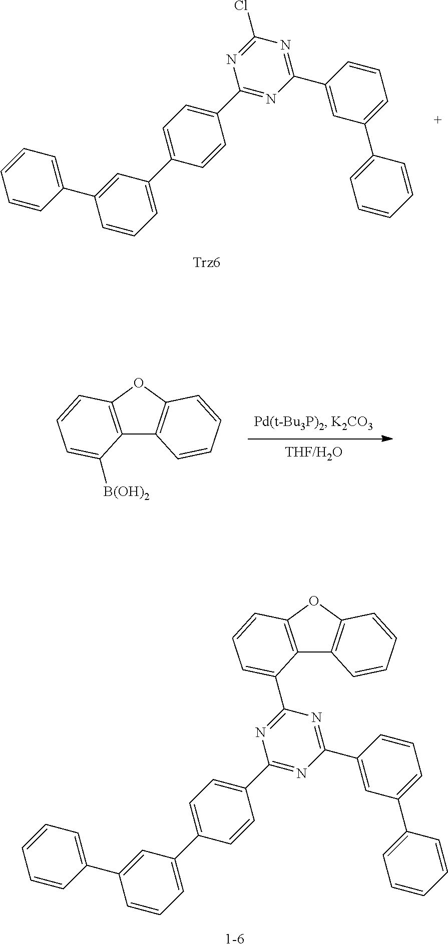 [SMILES: Clc1nc(-c2ccc(-c3cccc(-c4ccccc4)c3)cc2)nc(-c2cccc(-c3ccccc3)c2)n1 ; OB(O)c1cccc2oc3ccccc3c12 ; "THF/H2O" ; c1ccc(-c2cccc(-c3ccc(-c4nc(-c5cccc(-c6ccccc6)c5)nc(-c5cccc6oc7ccccc7c56)n4)cc3)c2)cc1]

Compound Trz6(15 g, 30.2 mmol) and dibenzo[b,d]furan-1-ylboronic acid(6.7 g, 31.8 mmol) were added to 300 ml of THF, and the mixture was stirred and refluxed. Then, potassium carbonate(12.5 g, 90.7 mmol) was dissolved in 38 ml of water and added thereto, and the mixture was sufficiently stirred and then bis(tri-tert-butylphosphine)palladium(0) (0.2 g, 0.3 mmol) was added. After the reaction for 4 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 12.5 g of Compound 1-6. (Yield: 66%, MS: [M+H]⁺=629).

### Preparation Example 1-7

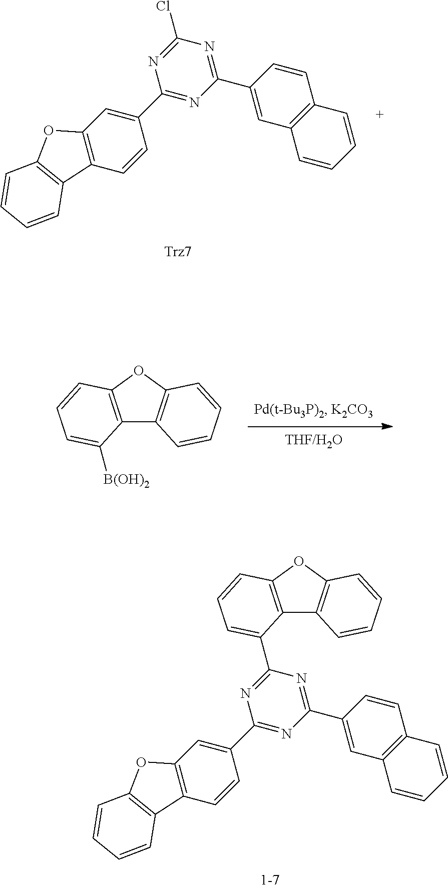 [SMILES: Clc1nc(-c2ccc3ccccc3c2)nc(-c2ccc3c(c2)oc2ccccc23)n1 ; OB(O)c1cccc2oc3ccccc3c12 ; "THF/H2O" ; c1ccc2cc(-c3nc(-c4ccc5c(c4)oc4ccccc45)nc(-c4cccc5oc6ccccc6c45)n3)ccc2c1]

Compound Trz7(15 g, 36.8 mmol) and dibenzo[b,d]furan-1-ylboronic acid(8.2 g, 38.6 mmol) were added to 300 ml of THF, and the mixture was stirred and refluxed. Then, potassium carbonate(15.2 g, 110.3 mmol) was dissolved in 46 ml of water and added thereto, and the mixture was sufficiently stirred and then bis(tri-tert-butylphosphine)palladium(0) (0.2 g, 0.4 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 14.9 g of Compound 1-7. (Yield: 75%, MS: [M+H]⁺=540).

### Preparation Example 1-8

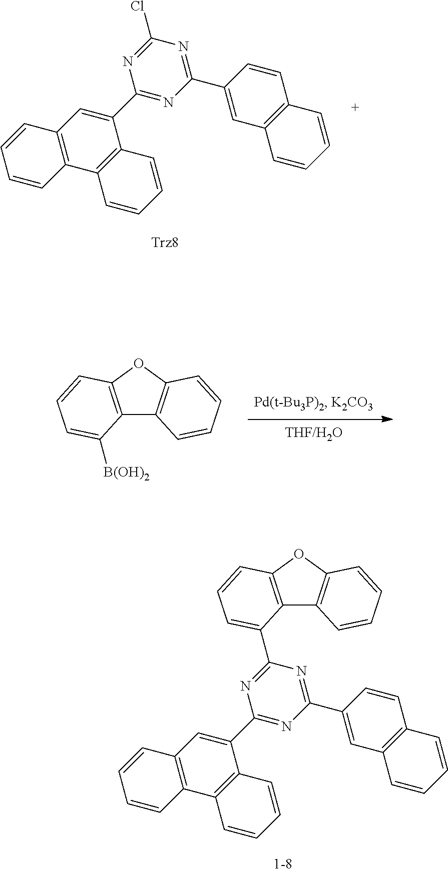 [SMILES: Clc1nc(-c2ccc3ccccc3c2)nc(-c2cc3ccccc3c3ccccc23)n1 ; OB(O)c1cccc2oc3ccccc3c12 ; "THF/H2O" ; c1ccc2cc(-c3nc(-c4cc5ccccc5c5ccccc45)nc(-c4cccc5oc6ccccc6c45)n3)ccc2c1]

Compound Trz8(15 g, 35.9 mmol) and dibenzo[b,d]furan-1-ylboronic acid(8 g, 37.7 mmol) were added to 300 ml of THF, and the mixture was stirred and refluxed. Then, potassium carbonate(14.9 g, 107.7 mmol) was dissolved in 45 ml of water and added thereto, and the mixture was sufficiently stirred and then bis(tri-tert-butylphosphine)palladium(0) (0.2 g, 0.4 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.8 g of Compound 1-8. (Yield: 70%, MS: [M+H]⁺=550).

### Preparation Example 1-9

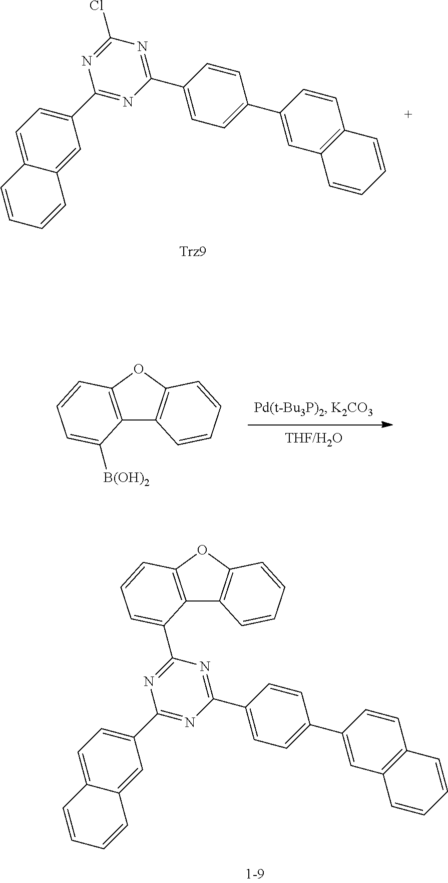 [SMILES: Clc1nc(-c2ccc(-c3ccc4ccccc4c3)cc2)nc(-c2ccc3ccccc3c2)n1 ; OB(O)c1cccc2oc3ccccc3c12 ; "THF/H2O" ; c1ccc2cc(-c3ccc(-c4nc(-c5ccc6ccccc6c5)nc(-c5cccc6oc7ccccc7c56)n4)cc3)ccc2c1]

Compound Trz9(15 g, 33.8 mmol) and dibenzo[b,d]furan-1-ylboronic acid(7.5 g, 35.5 mmol) were added to 300 ml of THF, and the mixture was stirred and refluxed. Then, potassium carbonate(14 g, 101.4 mmol) was dissolved in 42 ml of water and added thereto, and the mixture was sufficiently stirred and then bis(tri-tert-butylphosphine)palladium(0) (0.2 g, 0.3 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.6 g of Compound 1-9. (Yield: 70%, MS: [M+H]⁺=576).

### Preparation Example 1-10

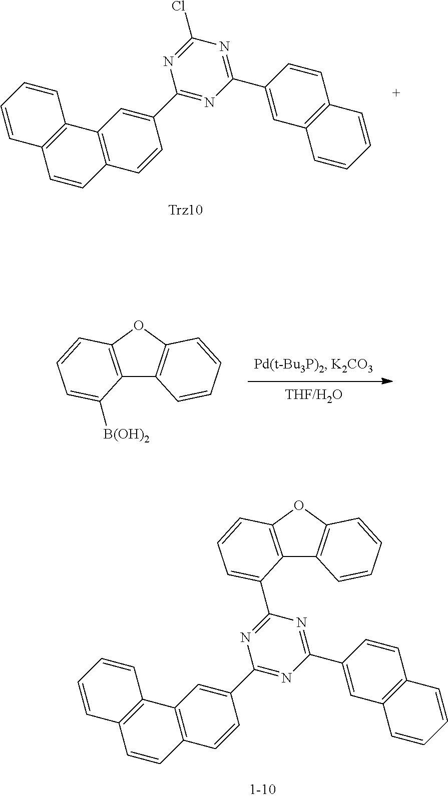 [SMILES: Clc1nc(-c2ccc3ccccc3c2)nc(-c2ccc3ccc4ccccc4c3c2)n1 ; OB(O)c1cccc2oc3ccccc3c12 ; "THF/H2O" ; c1ccc2cc(-c3nc(-c4ccc5ccc6ccccc6c5c4)nc(-c4cccc5oc6ccccc6c45)n3)ccc2c1]

Compound Trz10(15 g, 35.9 mmol) and dibenzo[b,d]furan-1-ylboronic acid(8 g, 37.7 mmol) were added to 300 ml of THF, and the mixture was stirred and refluxed. Then, potassium carbonate(14.9 g, 107.7 mmol) was dissolved in 45 ml of water and added thereto, and the mixture was sufficiently stirred and then bis(tri-tert-butylphosphine)palladium(0) (0.2 g, 0.4 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.8 g of Compound 1-10. (Yield: 70%, MS: [M+H]⁺=550).

### Preparation Example 1-11

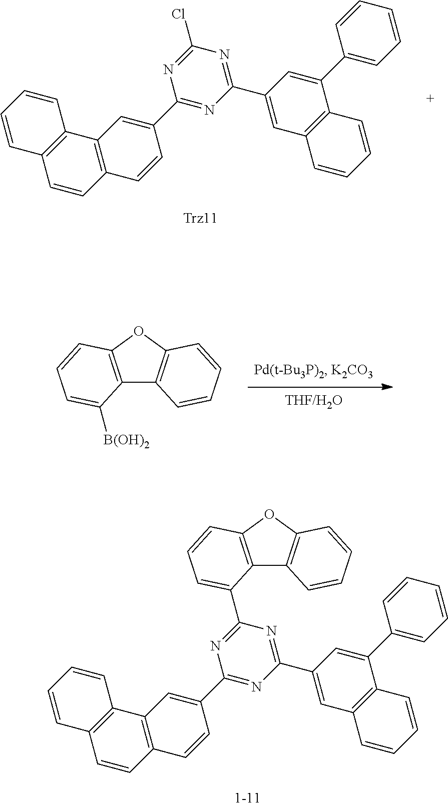 [SMILES: Clc1nc(-c2cc(-c3ccccc3)c3ccccc3c2)nc(-c2ccc3ccc4ccccc4c3c2)n1 ; OB(O)c1cccc2oc3ccccc3c12 ; "THF/H2O" ; c1ccc(-c2cc(-c3nc(-c4ccc5ccc6ccccc6c5c4)nc(-c4cccc5oc6ccccc6c45)n3)cc3ccccc23)cc1]

Compound Trz11(15 g, 30.4 mmol) and dibenzo[b,d]furan-1-ylboronic acid(6.8 g, 31.9 mmol) were added to 300 ml of THF, and the mixture was stirred and refluxed. Then, potassium carbonate(12.6 g, 91.1 mmol) was dissolved in 38 ml of water and added thereto, and the mixture was sufficiently stirred and then bis(tri-tert-butylphosphine)palladium(0) (0.2 g, 0.3 mmol) was added. After the reaction for 4 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.7 g of Compound 1-11. (Yield: 72%, MS: [M+H]⁺=626).

### Preparation Example 1-12

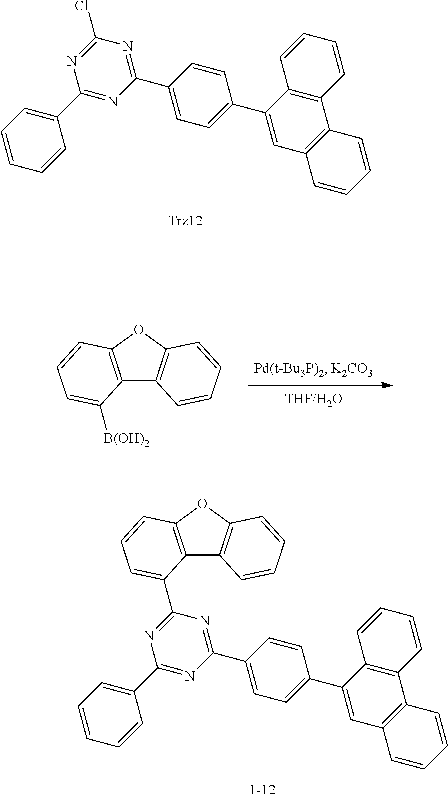 [SMILES: Clc1nc(-c2ccccc2)nc(-c2ccc(-c3cc4ccccc4c4ccccc34)cc2)n1 ; OB(O)c1cccc2oc3ccccc3c12 ; "THF/H2O" ; c1ccc(-c2nc(-c3ccc(-c4cc5ccccc5c5ccccc45)cc3)nc(-c3cccc4oc5ccccc5c34)n2)cc1]

Compound Trz12(15 g, 33.8 mmol) and 0 dibenzo[b,d]furan-1-ylboronic acid(7.5 g, 35.5 mmol) were added to 300 ml of THF, and the mixture was stirred and refluxed. Then, potassium carbonate(14 g, 101.4 mmol) was dissolved in 42 ml of water and added thereto, and the mixture was sufficiently stirred and then bis(tri-tert-butylphosphine)palladium(0) (0.2 g, 0.3 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 14.2 g of Compound 1-12. (Yield: 73%, MS: [M+H]⁺=576).

### Preparation Example 1-13

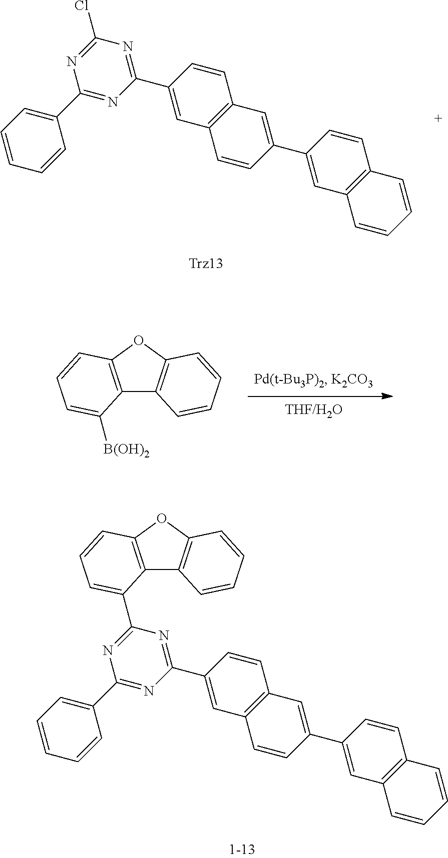 [SMILES: Clc1nc(-c2ccccc2)nc(-c2ccc3cc(-c4ccc5ccccc5c4)ccc3c2)n1 ; OB(O)c1cccc2oc3ccccc3c12 ; "THF/H2O" ; c1ccc(-c2nc(-c3ccc4cc(-c5ccc6ccccc6c5)ccc4c3)nc(-c3cccc4oc5ccccc5c34)n2)cc1]

Compound Trz13(15 g, 33.8 mmol) and dibenzo[b,d]furan-1-ylboronic acid(7.5 g, 35.5 mmol) were added to 300 ml of THF, and the mixture was stirred and refluxed. Then, potassium carbonate(14 g, 101.4 mmol) was dissolved in 42 ml of water and added thereto, and the mixture was sufficiently stirred and then bis(tri-tert-butylphosphine)palladium(0) (0.2 g, 0.3 mmol) was added. After the reaction for 4 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.4 g of Compound 1-13. (Yield: 69%, MS: [M+H]⁺=576).

### Preparation Example 1-14

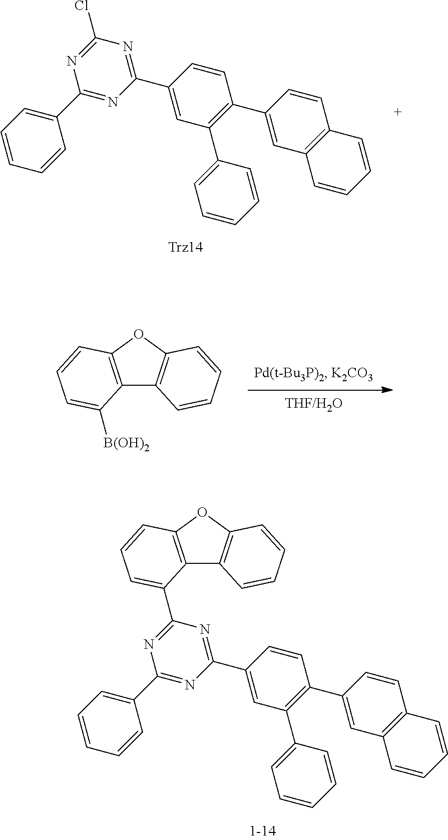 [SMILES: Clc1nc(-c2ccccc2)nc(-c2ccc(-c3ccc4ccccc4c3)c(-c3ccccc3)c2)n1 ; OB(O)c1cccc2oc3ccccc3c12 ; "THF/H2O" ; c1ccc(-c2nc(-c3ccc(-c4ccc5ccccc5c4)c(-c4ccccc4)c3)nc(-c3cccc4oc5ccccc5c34)n2)cc1]

Compound Trz14(15 g, 31.9 mmol) and dibenzo[b,d]furan-1-ylboronic acid(7.1 g, 33.5 mmol) were added to 300 ml of THF, and the mixture was stirred and refluxed. Then, potassium carbonate(13.2 g, 95.8 mmol) was dissolved in 40 ml of water and added thereto, and the mixture was sufficiently stirred and then bis(tri-tert-butylphosphine)palladium(0) (0.2 g, 0.3 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 14.2 g of Compound 1-14. (Yield: 74%, MS: [M+H]⁺=602).

### Preparation Example 1-15

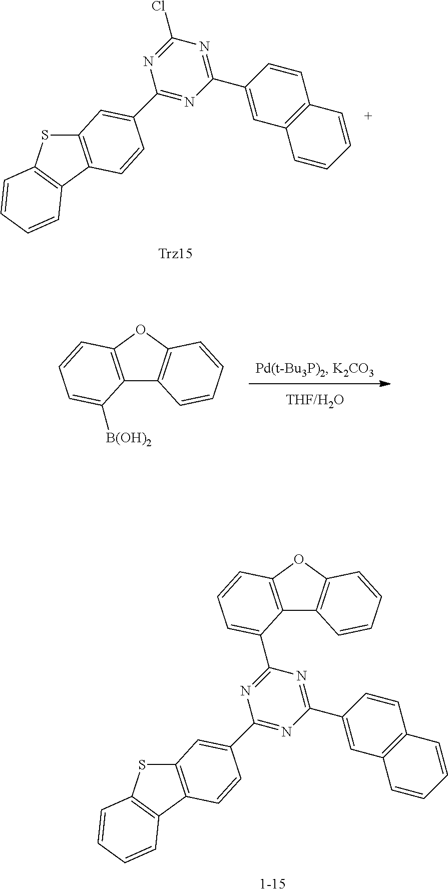 [SMILES: Clc1nc(-c2ccc3ccccc3c2)nc(-c2ccc3c(c2)sc2ccccc23)n1 ; OB(O)c1cccc2oc3ccccc3c12 ; c1ccc2cc(-c3nc(-c4ccc5c(c4)sc4ccccc45)nc(-c4cccc5oc6ccccc6c45)n3)ccc2c1]

Compound Trz15(15 g, 35.4 mmol) and dibenzo[b,d]furan-1-ylboronic acid(7.9 g, 37.2 mmol) were added to 300 ml of THF, and the mixture was stirred and refluxed. Then, potassium carbonate(14.7 g, 106.2 mmol) was dissolved in 44 ml of water and added thereto, and the mixture was sufficiently stirred and then bis(tri-tert-butylphosphine)palladium(0) (0.2 g, 0.4 mmol) was added. After the reaction for 4 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 14.3 g of Compound 1-15. (Yield: 73%, MS: [M+H]⁺=556).

### Preparation Example 1-16

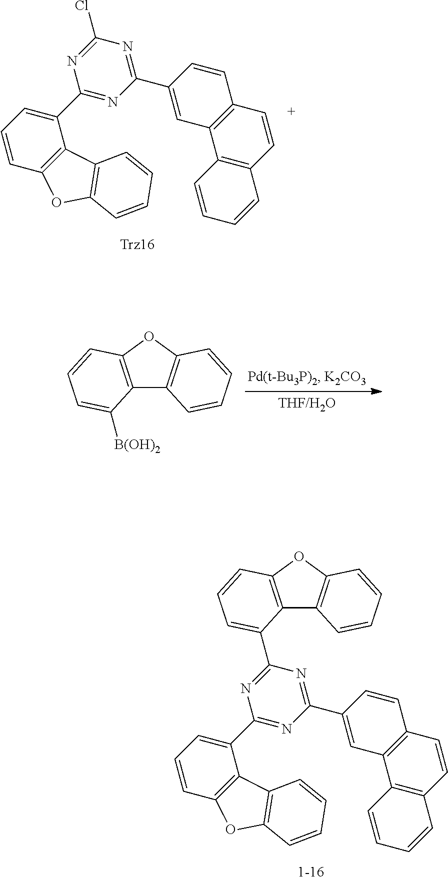 [SMILES: Clc1nc(-c2ccc3ccc4ccccc4c3c2)nc(-c2cccc3oc4ccccc4c23)n1 ; OB(O)c1cccc2oc3ccccc3c12 ; c1ccc2c(c1)ccc1ccc(-c3nc(-c4cccc5oc6ccccc6c45)nc(-c4cccc5oc6ccccc6c45)n3)cc12]

Compound Trz16(15 g, 32.8 mmol) and dibenzo[b,d]furan-1-ylboronic acid(7.3 g, 34.4 mmol) were added to 300 ml of THF, and the mixture was stirred and refluxed. Then, potassium carbonate(13.6 g, 98.3 mmol) was dissolved in 41 ml of water and added thereto, and the mixture was sufficiently stirred and then bis(tri-tert-butylphosphine)palladium(0) (0.2 g, 0.3 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 14.3 g of Compound 1-16. (Yield: 74%, MS: [M+H]⁺=590).

### Preparation Example 1-17

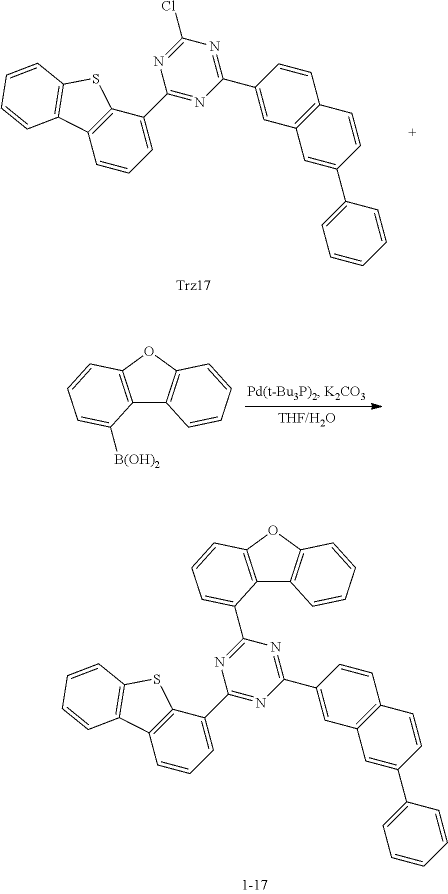 [SMILES: Clc1nc(-c2ccc3ccc(-c4ccccc4)cc3c2)nc(-c2cccc3c2sc2ccccc23)n1 ; OB(O)c1cccc2oc3ccccc3c12 ; c1ccc(-c2ccc3ccc(-c4nc(-c5cccc6c5sc5ccccc56)nc(-c5cccc6oc7ccccc7c56)n4)cc3c2)cc1]

Compound Trz17(15 g, 30 mmol) and dibenzo[b,d]furan-1-ylboronic acid(6.7 g, 31.5 mmol) were added to 300 ml of THF, and the mixture was stirred and refluxed. Then, potassium carbonate(12.4 g, 90 mmol) was dissolved in 37 ml of water and added thereto, and the mixture was sufficiently stirred and then bis(tri-tert-butylphosphine)palladium(0) (0.2 g, 0.3 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 14 g of Compound 1-17. (Yield: 74%, MS: [M+H]⁺=632).

### Preparation Example 1-18

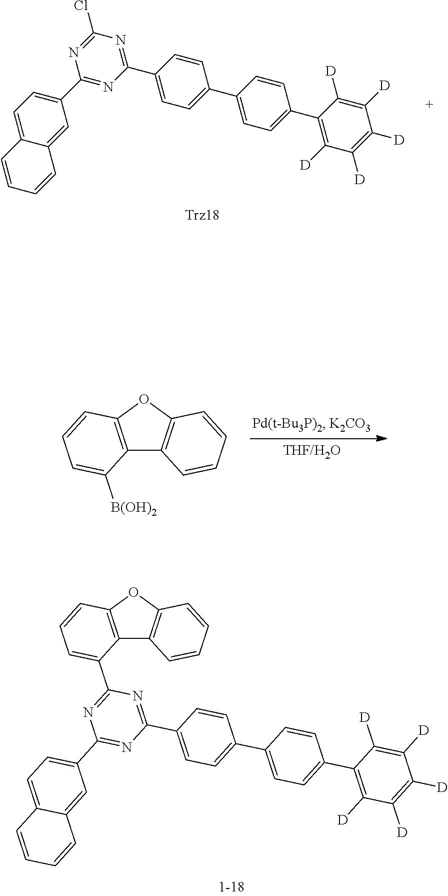 [SMILES: [2H]c1c([2H])c([2H])c(-c2ccc(-c3ccc(-c4nc(Cl)nc(-c5ccc6ccccc6c5)n4)cc3)cc2)c([2H])c1[2H] ; OB(O)c1cccc2oc3ccccc3c12 ; [2H]c1c([2H])c([2H])c(-c2ccc(-c3ccc(-c4nc(-c5ccc6ccccc6c5)nc(-c5cccc6oc7ccccc7c56)n4)cc3)cc2)c([2H])c1[2H]]

Compound Trz18(15 g, 31.6 mmol) and dibenzo[b,d]furan-1-ylboronic acid(7 g, 33.2 mmol) were added to 300 ml of THF, and the mixture was stirred and refluxed. Then, potassium carbonate(13.1 g, 94.7 mmol) was dissolved in 39 ml of water and added thereto, and the mixture was sufficiently stirred and then bis(tri-tert-butylphosphine)palladium(0) (0.2 g, 0.3 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 14.2 g of Compound 1-18. (Yield: 74%, MS: [M+H]⁺=607).

### Preparation Example 1-19

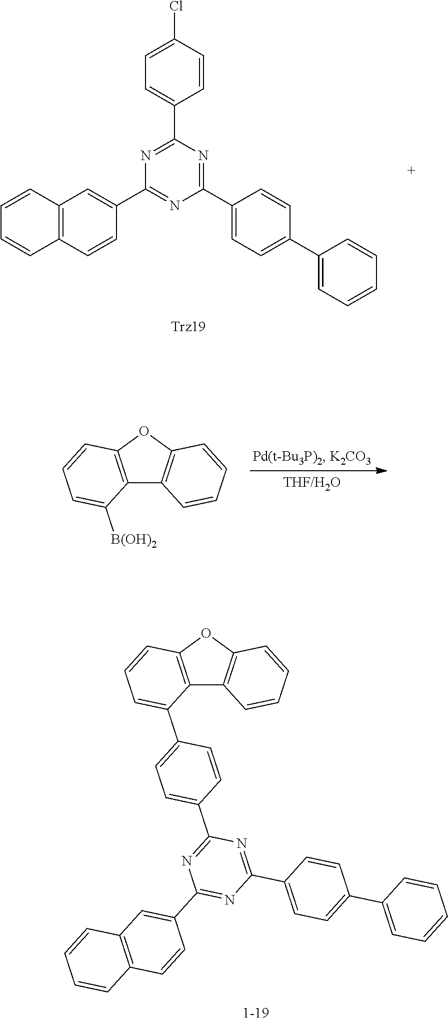 [SMILES: Clc1ccc(-c2nc(-c3ccc(-c4ccccc4)cc3)nc(-c3ccc4ccccc4c3)n2)cc1 ; OB(O)c1cccc2oc3ccccc3c12 ; c1ccc(-c2ccc(-c3nc(-c4ccc(-c5cccc6oc7ccccc7c56)cc4)nc(-c4ccc5ccccc5c4)n3)cc2)cc1]

Compound Trz19(15 g, 31.9 mmol) and dibenzo[b,d]furan-1-ylboronic acid(7.1 g, 33.5 mmol) were added to 300 ml of THF, and the mixture was stirred and refluxed. Then, potassium carbonate(13.2 g, 95.8 mmol) was dissolved in 40 ml of water and added thereto, and the mixture was sufficiently stirred and then bis(tri-tert-butylphosphine)palladium(0) (0.2 g, 0.3 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 12.7 g of Compound 1-19. (Yield: 66%, MS: [M+H]⁺=602).

### Preparation Example 1-20

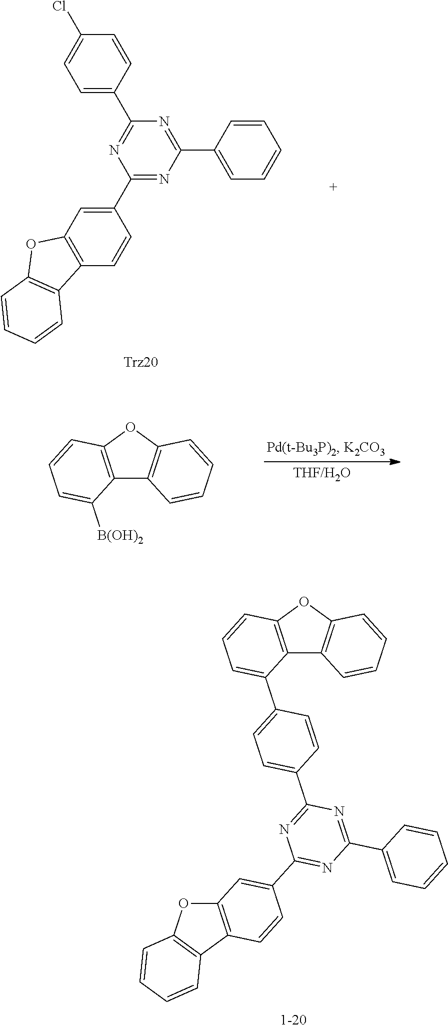 [SMILES: Clc1ccc(-c2nc(-c3ccccc3)nc(-c3ccc4c(c3)oc3ccccc34)n2)cc1 ; OB(O)c1cccc2oc3ccccc3c12 ; c1ccc(-c2nc(-c3ccc(-c4cccc5oc6ccccc6c45)cc3)nc(-c3ccc4c(c3)oc3ccccc34)n2)cc1]

Compound Trz20(15 g, 34.6 mmol) and dibenzo[b,d]furan-1-ylboronic acid(7.7 g, 36.3 mmol) were added to 300 ml of THF, and the mixture was stirred and refluxed. Then, potassium carbonate(14.3 g, 103.7 mmol) was dissolved in 43 ml of water and added thereto, and the mixture was sufficiently stirred and then bis(tri-tert-butylphosphine)palladium(0) (0.2 g, 0.3 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.9 g of Compound 1-20. (Yield: 71%, MS: [M+H]⁺=566).

### Preparation Example 1-21

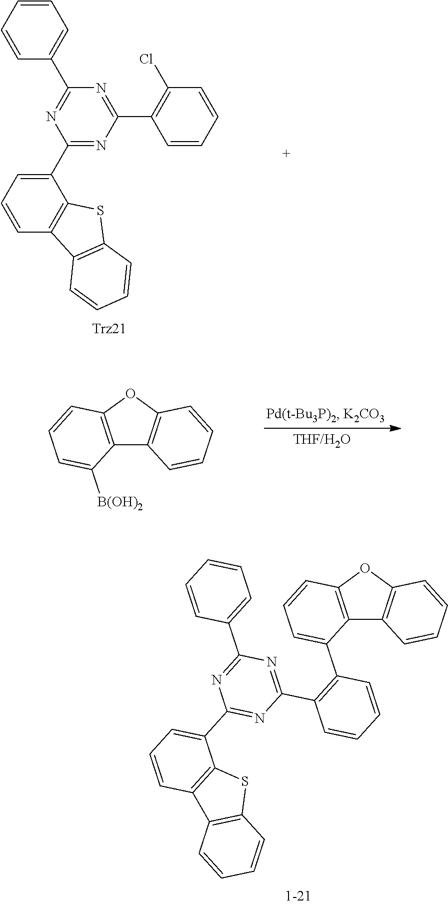 [SMILES: Clc1ccccc1-c1nc(-c2ccccc2)nc(-c2cccc3c2sc2ccccc23)n1 ; OB(O)c1cccc2oc3ccccc3c12 ; c1ccc(-c2nc(-c3ccccc3-c3cccc4oc5ccccc5c34)nc(-c3cccc4c3sc3ccccc34)n2)cc1]

Compound Trz21(15 g, 33.3 mmol) and dibenzo[b,d]furan-1-ylboronic acid(7.4 g, 35 mmol) were added to 300 ml of THF, and the mixture was stirred and refluxed. Then, potassium carbonate(13.8 g, 100 mmol) was dissolved in 41 ml of water and added thereto, and the mixture was sufficiently stirred and then bis(tri-tert-butylphosphine)palladium(0) (0.2 g, 0.3 mmol) was added. After the reaction for 4 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.9 g of Compound 1-21. (Yield: 72%, MS: [M+H]⁺=582).

### Preparation Example 1-22

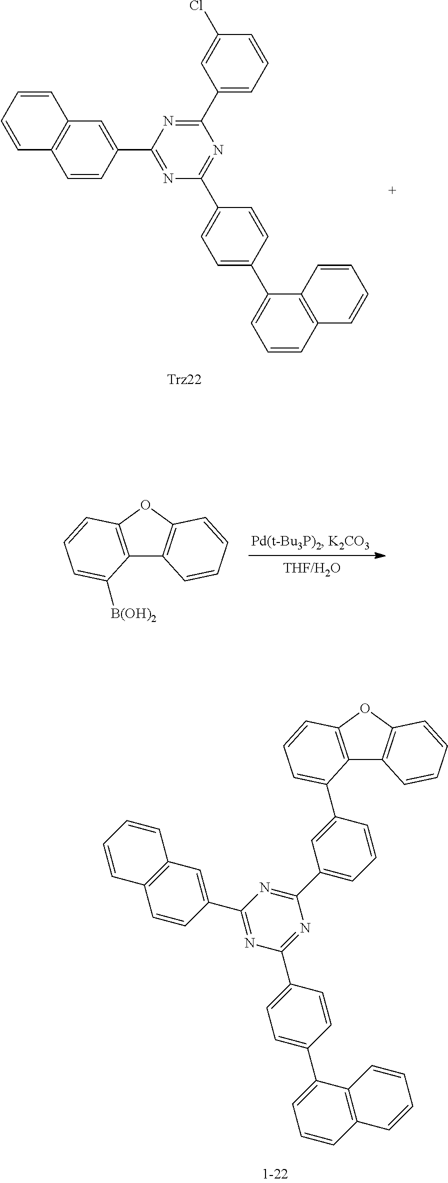 [SMILES: Clc1cccc(-c2nc(-c3ccc(-c4cccc5ccccc45)cc3)nc(-c3ccc4ccccc4c3)n2)c1 ; OB(O)c1cccc2oc3ccccc3c12 ; c1cc(-c2nc(-c3ccc(-c4cccc5ccccc45)cc3)nc(-c3ccc4ccccc4c3)n2)cc(-c2cccc3oc4ccccc4c23)c1]

Compound Trz22(15 g, 28.8 mmol) and dibenzo[b,d]furan-1-ylboronic acid(6.4 g, 30.3 mmol) were added to 300 ml of THF, and the mixture was stirred and refluxed. Then, potassium carbonate(12 g, 86.5 mmol) was dissolved in 36 ml of water and added thereto, and the mixture was sufficiently stirred and then bis(tri-tert-butylphosphine)palladium(0) (0.1 g, 0.3 mmol) was added. After the reaction for 4 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.3 g of Compound 1-22. (Yield: 71%, MS: [M+H]⁺=652).

### Preparation Example 1-23

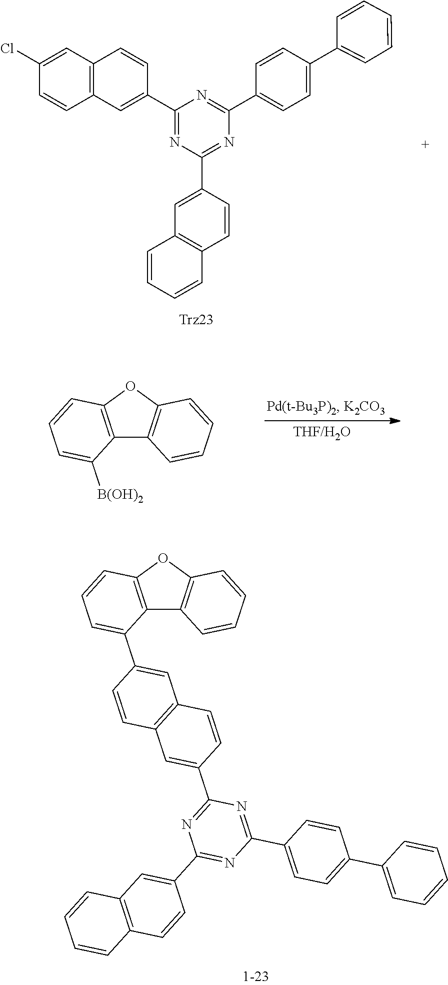 [SMILES: Clc1ccc2cc(-c3nc(-c4ccc(-c5ccccc5)cc4)nc(-c4ccc5ccccc5c4)n3)ccc2c1 ; OB(O)c1cccc2oc3ccccc3c12 ; c1ccc(-c2ccc(-c3nc(-c4ccc5ccccc5c4)nc(-c4ccc5cc(-c6cccc7oc8ccccc8c67)ccc5c4)n3)cc2)cc1]

Compound Trz23(15 g, 28.8 mmol) and dibenzo[b,d]furan-1-ylboronic acid(6.4 g, 30.3 mmol) were added to 300 ml of THF, and the mixture was stirred and refluxed. Then, potassium carbonate(12 g, 86.5 mmol) was dissolved in 36 ml of water and added thereto, and the mixture was sufficiently stirred and then bis(tri-tert-butylphosphine)palladium(0) (0.1 g, 0.3 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.7 g of Compound 1-23. (Yield: 73%, MS: [M+H]⁺=652).

### Preparation Example 1-24

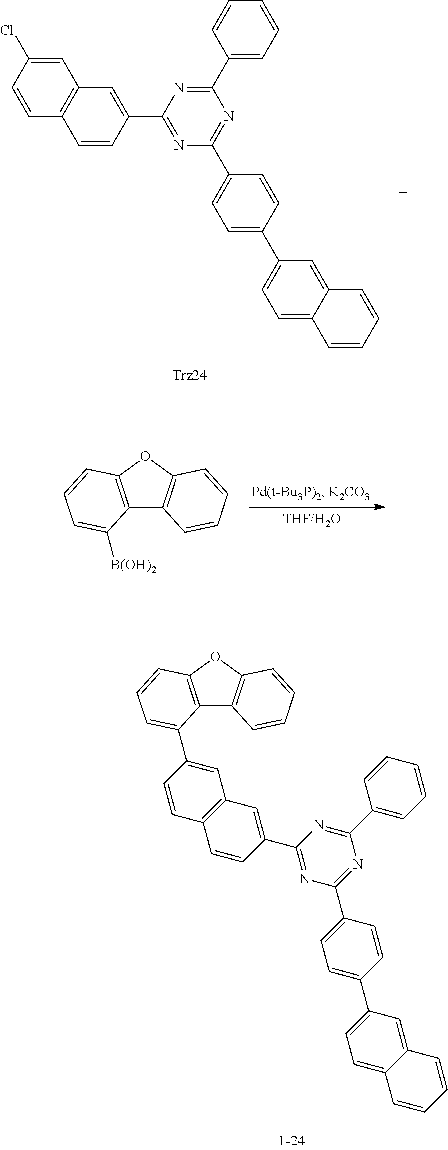 [SMILES: Clc1ccc2ccc(-c3nc(-c4ccccc4)nc(-c4ccc(-c5ccc6ccccc6c5)cc4)n3)cc2c1 ; OB(O)c1cccc2oc3ccccc3c12 ; c1ccc(-c2nc(-c3ccc(-c4ccc5ccccc5c4)cc3)nc(-c3ccc4ccc(-c5cccc6oc7ccccc7c56)cc4c3)n2)cc1]

Compound Trz24(15 g, 28.8 mmol) and dibenzo[b,d]furan-1-ylboronic acid(6.4 g, 30.3 mmol) were added to 300 ml of THF, and the mixture was stirred and refluxed. Then, potassium carbonate(12 g, 86.5 mmol) was dissolved in 36 ml of water and added thereto, and the mixture was sufficiently stirred and then bis(tri-tert-butylphosphine)palladium(0) (0.1 g, 0.3 mmol) was added. After the reaction for 4 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 12.6 g of Compound 1-24. (Yield: 67%, MS: [M+H]⁺=652).

### Preparation Example 1-25

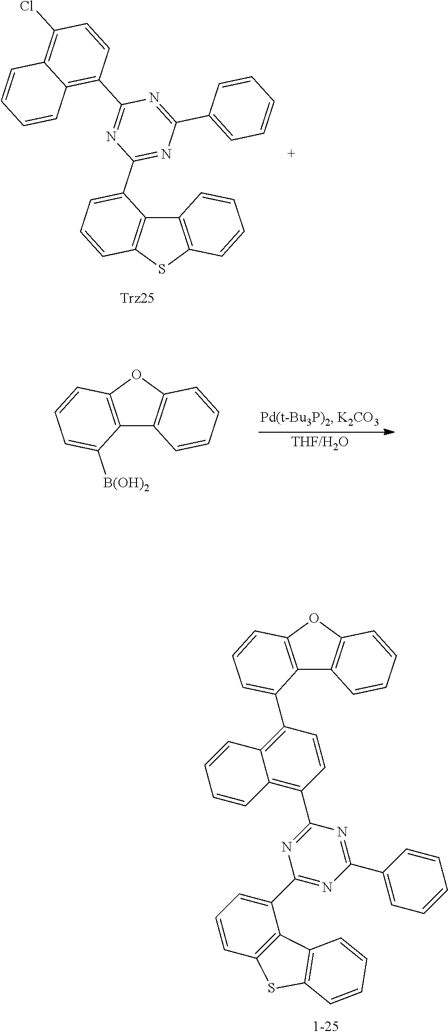 [SMILES: Clc1ccc(-c2nc(-c3ccccc3)nc(-c3cccc4sc5ccccc5c34)n2)c2ccccc12 ; OB(O)c1cccc2oc3ccccc3c12 ; "THF/H2O" ; c1ccc(-c2nc(-c3ccc(-c4cccc5oc6ccccc6c45)c4ccccc34)nc(-c3cccc4sc5ccccc5c34)n2)cc1]

Compound Trz25(15 g, 30 mmol) and dibenzo[b,d]furan-1-ylboronic acid(6.7 g, 31.5 mmol) were added to 300 ml of THF, and the mixture was stirred and refluxed. Then, potassium carbonate(12.4 g, 90 mmol) was dissolved in 37 ml of water and added thereto, and the mixture was sufficiently stirred and then bis(tri-tert-butylphosphine)palladium(0) (0.2 g, 0.3 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 14.2 g of Compound 1-25. (Yield: 75%, MS: [M+H]⁺=632).

### Preparation Example 1-26

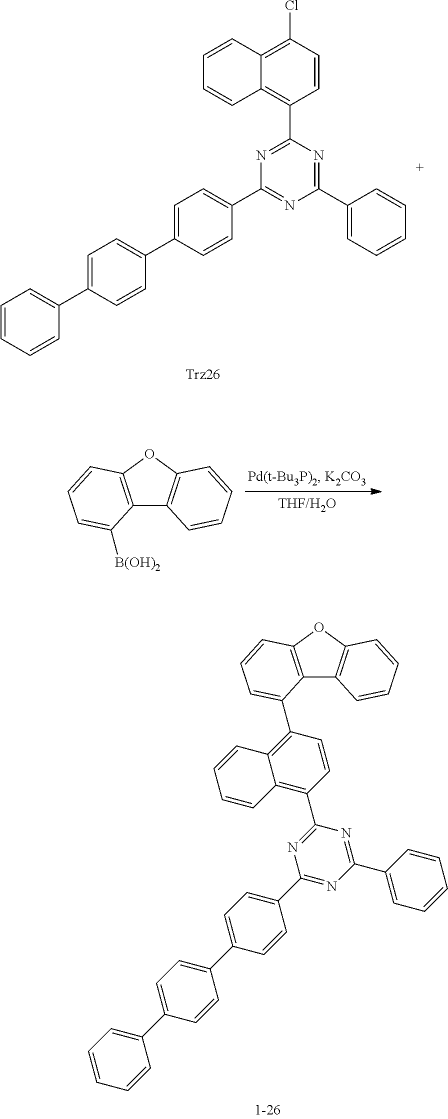 [SMILES: Clc1ccc(-c2nc(-c3ccccc3)nc(-c3ccc(-c4ccc(-c5ccccc5)cc4)cc3)n2)c2ccccc12 ; OB(O)c1cccc2oc3ccccc3c12 ; c1ccc(-c2ccc(-c3ccc(-c4nc(-c5ccccc5)nc(-c5ccc(-c6cccc7oc8ccccc8c67)c6ccccc56)n4)cc3)cc2)cc1]

Compound Trz26(15 g, 27.5 mmol) and dibenzo[b,d]furan-1-ylboronic acid(6.1 g, 28.8 mmol) were added to 300 ml of THF, and the mixture was stirred and refluxed. Then, potassium carbonate(11.4 g, 82.4 mmol) was dissolved in 34 ml of water and added thereto, and the mixture was sufficiently stirred and then bis(tri-tert-butylphosphine)palladium(0) (0.1 g, 0.3 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 14 g of Compound 1-26. (Yield: 75%, MS: [M+H]⁺=678).

### Preparation Example 1-27

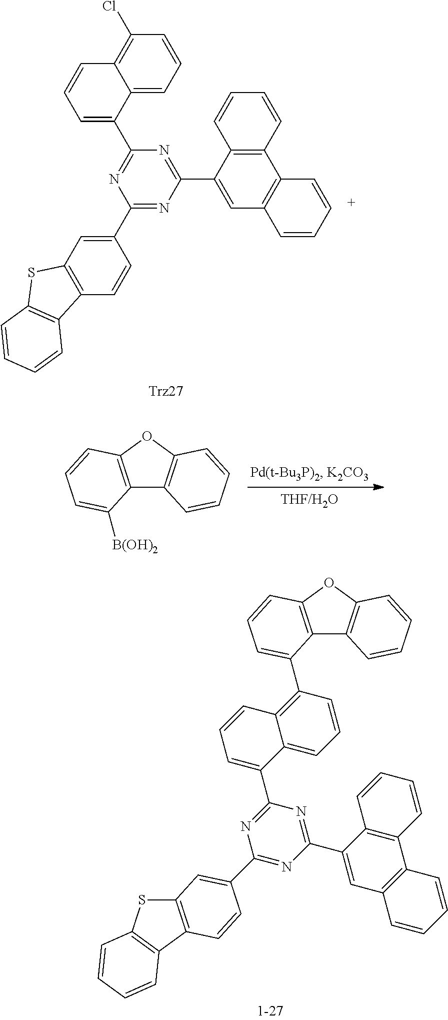 [SMILES: Clc1cccc2c(-c3nc(-c4ccc5c(c4)sc4ccccc45)nc(-c4cc5ccccc5c5ccccc45)n3)cccc12 ; OB(O)c1cccc2oc3ccccc3c12 ; c1ccc2c(c1)cc(-c1nc(-c3ccc4c(c3)sc3ccccc34)nc(-c3cccc4c(-c5cccc6oc7ccccc7c56)cccc34)n1)c1ccccc12]

Compound Trz27(15 g, 25 mmol) and dibenzo[b,d]furan-1-ylboronic acid(5.6 g, 26.2 mmol) were added to 300 ml of THF, and the mixture was stirred and refluxed. Then, potassium carbonate(10.4 g, 75 mmol) was dissolved in 31 ml of water and added thereto, and the mixture was sufficiently stirred and then bis(tri-tert-butylphosphine)palladium(0) (0.1 g, 0.2 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 12.6 g of Compound 1-27. (Yield: 69%, MS: [M+H]⁺=732).

### Preparation Example 1-28

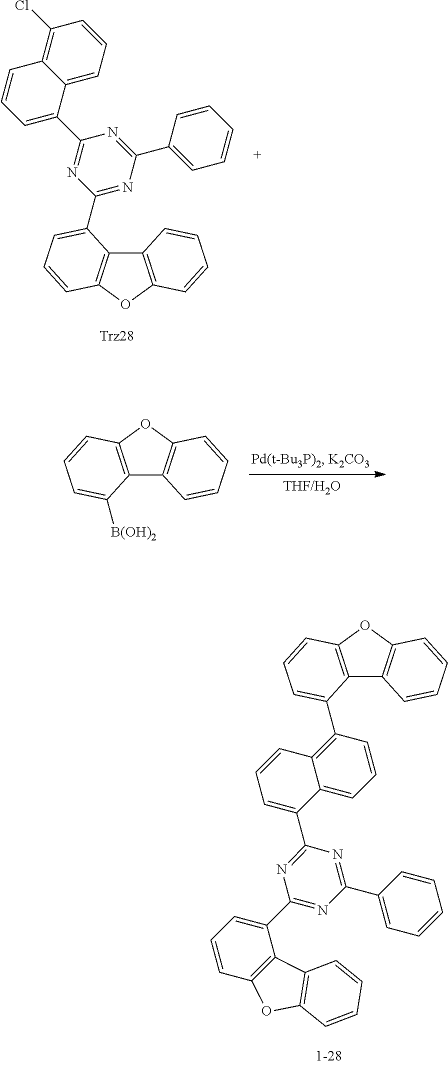

Compound Trz28(15 g, 31 mmol) and dibenzo[b,d]furan-1-ylboronic acid(6.9 g, 32.5 mmol) were added to 300 ml of THF, and the mixture was stirred and refluxed. Then, potassium carbonate(12.9 g, 93 mmol) was dissolved in 39 ml of water and added thereto, and the mixture was sufficiently stirred and then bis(tri-tert-butylphosphine)palladium(0) (0.2 g, 0.3 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13 g of Compound 1-28. (Yield: 68%, MS: [M+H]⁺=616).

### Preparation Example 1-29

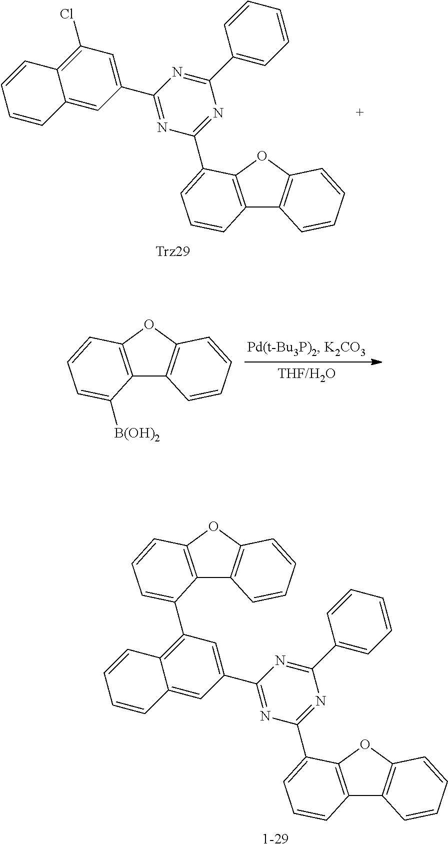 [SMILES: Clc1cc(-c2nc(-c3ccccc3)nc(-c3cccc4c3oc3ccccc34)n2)cc2ccccc12 ; OB(O)c1cccc2oc3ccccc3c12 ; c1ccc(-c2nc(-c3cc(-c4cccc5oc6ccccc6c45)c4ccccc4c3)nc(-c3cccc4c3oc3ccccc34)n2)cc1]

Compound Trz29(15 g, 31 mmol) and dibenzo[b,d]furan-1-ylboronic acid(6.9 g, 32.5 mmol) were added to 300 ml of THF, and the mixture was stirred and refluxed. Then, potassium carbonate(12.9 g, 93 mmol) was dissolved in 39 ml of water and added thereto, and the mixture was sufficiently stirred and then bis(tri-tert-butylphosphine)palladium(0) (0.2 g, 0.3 mmol) was added. After the reaction for 4 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.3 g of Compound 1-29. (Yield: 70%, MS: [M+H]⁺=616).

### Preparation Example 1-30

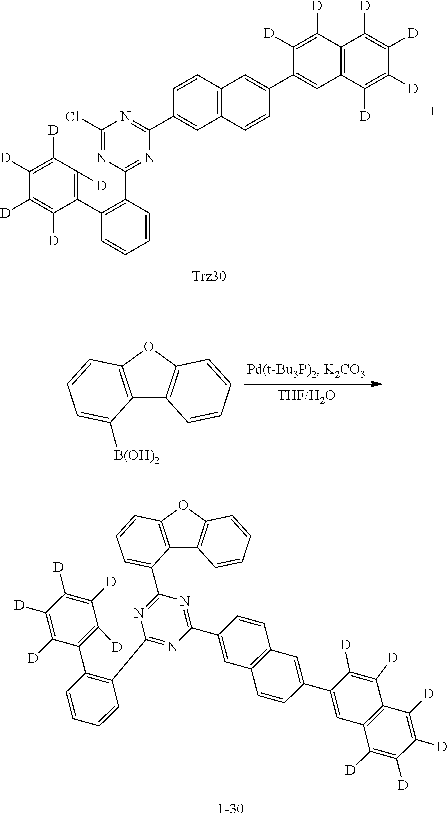 [SMILES: [2H]c1c([2H])c([2H])c(-c2ccccc2-c2nc(Cl)nc(-c3ccc4cc(-c5cc6c([2H])c([2H])c([2H])c([2H])c6c([2H])c5[2H])ccc4c3)n2)c([2H])c1[2H] ; OB(O)c1cccc2oc3ccccc3c12 ; [2H]c1c([2H])c([2H])c(-c2ccccc2-c2nc(-c3ccc4cc(-c5cc6c([2H])c([2H])c([2H])c([2H])c6c([2H])c5[2H])ccc4c3)nc(-c3cccc4oc5ccccc5c34)n2)c([2H])c1[2H]]

Compound Trz30(15 g, 28.2 mmol) and dibenzo[b,d]furan-1-ylboronic acid(6.3 g, 29.7 mmol) were added to 300 ml of THF, and the mixture was stirred and refluxed. Then, potassium carbonate(11.7 g, 84.7 mmol) was dissolved in 35 ml of water and added thereto, and the mixture was sufficiently stirred and then bis(tri-tert-butylphosphine)palladium(0) (0.1 g, 0.3 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 12.9 g of Compound 1-30. (Yield: 69%, MS: [M+H]⁺=663).

### Preparation Example 1-31

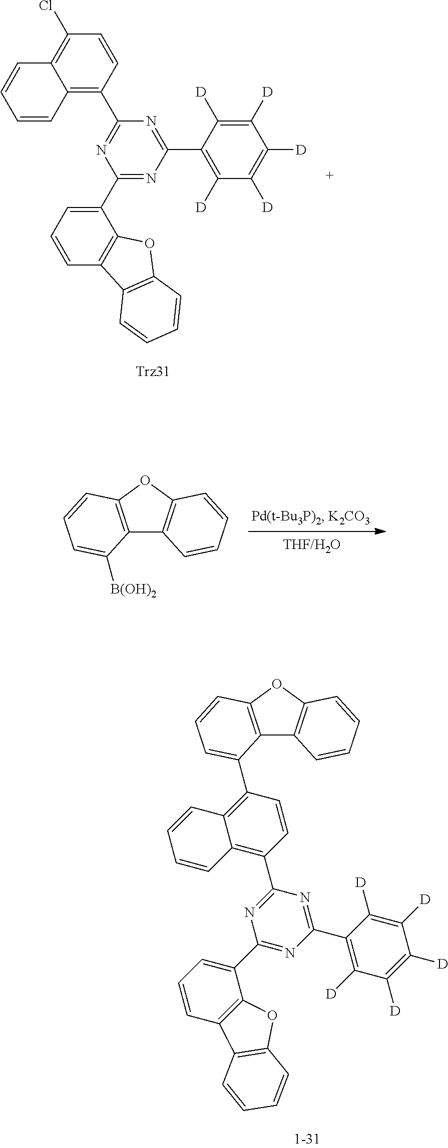 [SMILES: [2H]c1c([2H])c([2H])c(-c2nc(-c3ccc(Cl)c4ccccc34)nc(-c3cccc4c3oc3ccccc34)n2)c([2H])c1[2H] ; OB(O)c1cccc2oc3ccccc3c12 ; [2H]c1c([2H])c([2H])c(-c2nc(-c3ccc(-c4cccc5oc6ccccc6c45)c4ccccc34)nc(-c3cccc4c3oc3ccccc34)n2)c([2H])c1[2H]]

Compound Trz31(15 g, 30.7 mmol) and dibenzo[b,d]furan-1-ylboronic acid(6.8 g, 32.2 mmol) were added to 300 ml of THF, and the mixture was stirred and refluxed. Then, potassium carbonate(12.7 g, 92 mmol) was dissolved in 38 ml of water and added thereto, and the mixture was sufficiently stirred and then bis(tri-tert-butylphosphine)palladium(0) (0.2 g, 0.3 mmol) was added. After the reaction for 4 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 14.3 g of Compound 1-31. (Yield: 75%, MS: [M+H]⁺=621).

### Preparation Example 1-32

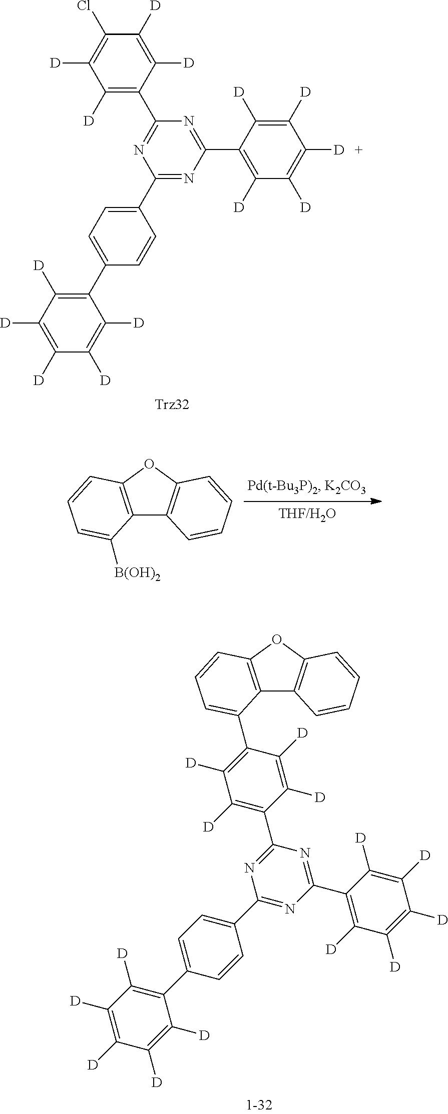 [SMILES: [2H]c1c([2H])c([2H])c(-c2ccc(-c3nc(-c4c([2H])c([2H])c([2H])c([2H])c4[2H])nc(-c4c([2H])c([2H])c(Cl)c([2H])c4[2H])n3)cc2)c([2H])c1[2H] ; OB(O)c1cccc2oc3ccccc3c12 ; [2H]c1c([2H])c([2H])c(-c2ccc(-c3nc(-c4c([2H])c([2H])c([2H])c([2H])c4[2H])nc(-c4c([2H])c([2H])c(-c5cccc6oc7ccccc7c56)c([2H])c4[2H])n3)cc2)c([2H])c1[2H]]

Compound Trz32(15 g, 34.6 mmol) and dibenzo[b,d]furan-1-ylboronic acid(7.7 g, 36.3 mmol) were added to 300 ml of THF, and the mixture was stirred and refluxed. Then, potassium carbonate(14.3 g, 103.7 mmol) was dissolved in 43 ml of water and added thereto, and the mixture was sufficiently stirred and then bis(tri-tert-butylphosphine)palladium(0) (0.2 g, 0.3 mmol) was added. After the reaction for 4 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.9 g of Compound 1-32. (Yield: 71%, MS: [M+H]⁺=566).

### Preparation Example 1-33

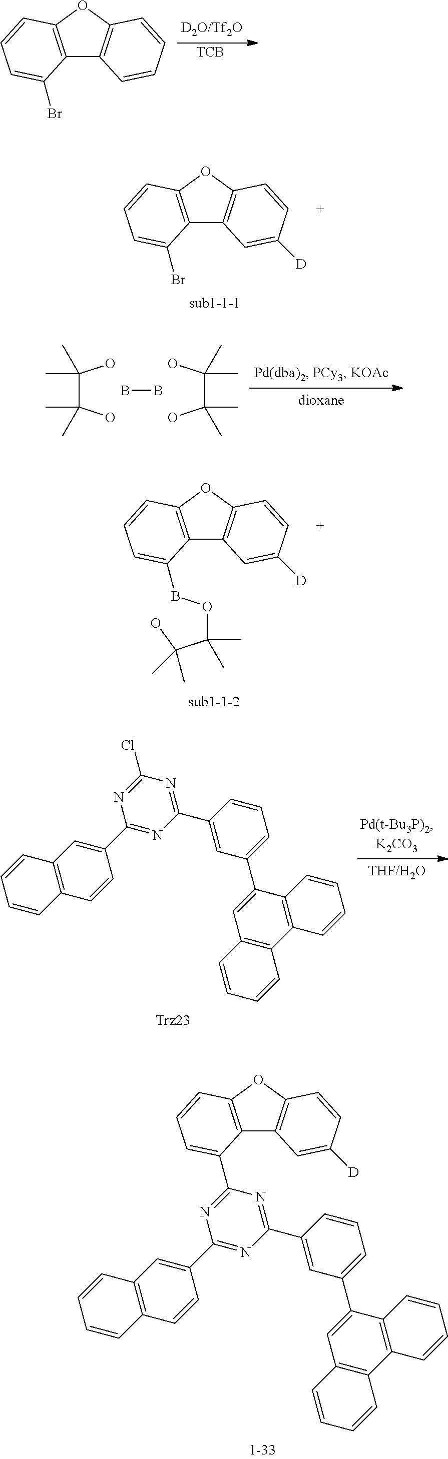

Trifluoromethanesulfonic anhydride(24 g, 85 mmol) and deuterium oxide(8.5 g, 424.9 mmol) were added at 0° C., and the mixture was stirred for 5 hours to prepare a solution. 1-Bromodibenzo[b,d]furan(15 g, 60.7 mmol) was added to 120 mL of 1,2,4-trichlorobenzene, and the mixture was stirred. Then, the prepared mixed solution of trifluoromethanesulfonic anhydride and deuterium oxide was slowly added dropwise to a mixed solution of 1-bromodibenzo[b,d]furan and 1,2,4-trichlorobenzene, and the mixture was stirred while heating to 140° C. and then keeping that temperature. After the reaction for 5 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.7 g of Compound sub1-1-1. (Yield: 38%, MS: [M+H]⁺=248)

Compound sub1-1-1(15 g, 60.5 mmol) and bis(pinacolato)diboron(16.9 g, 66.5 mmol) were added to 300 ml of 1,4-dioxane, and the mixture was stirred under reflux. Then, potassium acetate(8.9 g, 90.7 mmol) was added thereto, the mixture was sufficiently stirred and then bis(dibenzylideneacetone)palladium(0) (1 g, 1.8 mmol) and tricyclohexylphosphine(1 g, 3.6 mmol) were added. After the reaction for 6 hours, the reaction mixture was cooled to room temperature, the organic layer was separated using chloroform and water, and then the organic layer was distilled. This was again dissolved in chloroform, washed twice with water, and the organic layer was then separated. Anhydrous magnesium sulfate was added thereto, stirred, then filtered, and the filtrate was distilled under reduced pressure. The concentrated compound was purified by a silica gel column chromatography to prepare 13.4 g of Compound sub1-1-2. (Yield: 75%, MS: [M+H]⁺=296)

Compound sub1-1-2(15 g, 50.8 mmol) and Compound Trz33(26.4 g, 53.4 mmol) were added to 300 ml of THF, and the mixture was stirred and refluxed. Then, potassium carbonate(21.1 g, 152.5 mmol) was dissolved in 63 ml of water and added thereto, the mixture was sufficiently stirred and then bis(tri-tert-butylphosphine)palladium(0) (0.3 g, 0.5 mmol) was added. After the reaction for 3 hours, the reaction mixture was cooled to room temperature, and then the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 21 g of Compound 1-33. (Yield: 66%, MS: [M+H]⁺=627)

### Preparation Example 1-34

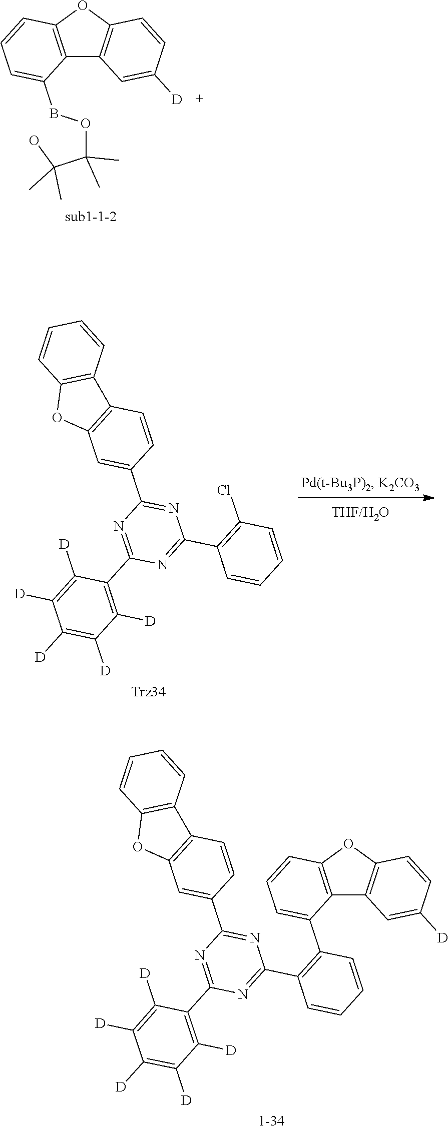

Compound sub1-1-2(15 g, 50.8 mmol) and Compound Trz34(23.4 g, 53.4 mmol) were added to 300 ml of THF, and the mixture was stirred and refluxed. Then, potassium carbonate(21.1 g, 152.5 mmol) was dissolved in 63 ml of water and added thereto, and the mixture was sufficiently stirred and then bis(tri-tert-butylphosphine)palladium(0) (0.3 g, 0.5 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 19.4 g of Compound 1-34. (Yield: 67%, MS: [M+H]⁺=572).

### Preparation Example 1-35

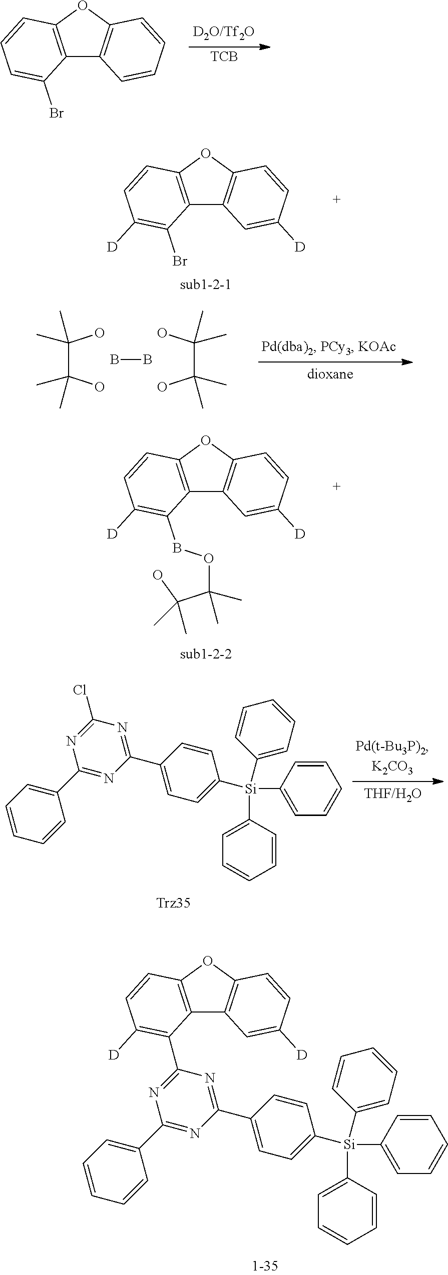

Trifluoromethanesulfonic anhydride(48 g, 170 mmol) and deuterium oxide(17 g, 849.9 mmol) were added at 0° C., and the mixture was stirred for 5 hours to prepare a solution. 1-Bromodibenzo[b,d]furan(15 g, 60.7 mmol) was added to 120 mL of 1,2,4-trichlorobenzene, and the mixture was stirred. Then, the prepared mixed solution of trifluoromethanesulfonic anhydride and deuterium oxide was slowly added dropwise to a mixed solution of 1-bromodibenzo[b,d]furan and 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 6 g of Compound sub1-2-1. (Yield: 40%, MS: [M+H]⁺=249)

Compound sub1-2-1(15 g, 60.2 mmol) and bis(pinacolato)diboron(16.8 g, 66.2 mmol) were added to 300 ml of 1,4-dioxane, and the mixture was stirred under reflux. Then, potassium acetate(8.9 g, 90.3 mmol) was added thereto, the mixture was sufficiently stirred and then bis(dibenzylideneacetone)palladium(0) (1 g, 1.8 mmol) and tricyclohexylphosphine(1 g, 3.6 mmol) were added. After the reaction for 4 hours, the reaction mixture was cooled to room temperature, the organic layer was separated using chloroform and water, and then the organic layer was distilled. This was again dissolved in chloroform, washed twice with water, and the organic layer was then separated. Anhydrous magnesium sulfate was added thereto, stirred, then filtered, and the filtrate was distilled under reduced pressure. The concentrated compound was purified by a silica gel column chromatography to prepare 12.5 g of Compound sub1-2-2. (Yield: 70%, MS: [M+H]⁺=297)

Compound sub1-2-2(15 g, 50.6 mmol) and Compound Trz35(28 g, 53.2 mmol) were added to 300 ml of THF, and the mixture was stirred and refluxed. Then, potassium carbonate(21 g, 151.9 mmol) was dissolved in 63 ml of water and added thereto, the mixture was sufficiently stirred and then bis(tri-tert-butylphosphine)palladium(0) (0.3 g, 0.5 mmol) was added. After the reaction for 4 hours, the reaction mixture was cooled to room temperature, and then the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 23.4 g of Compound 1-35. (Yield: 70%, MS: [M+H]⁺=660)

### Preparation Example 1-36

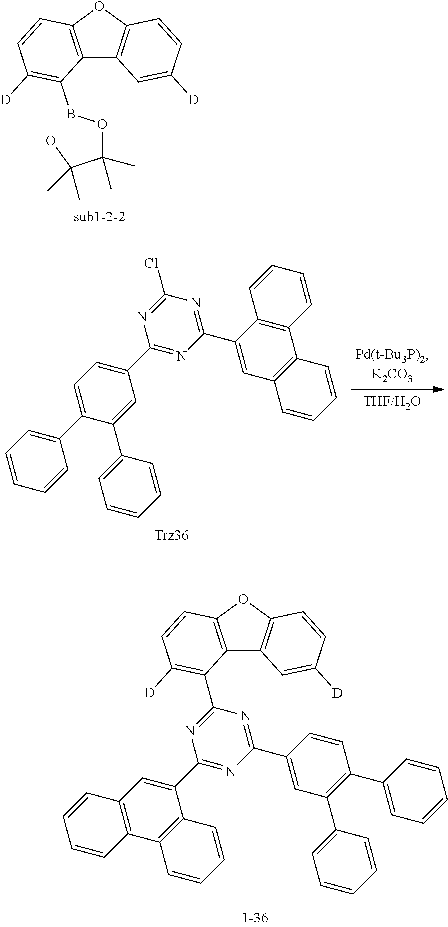

Compound sub1-2-2(15 g, 50.6 mmol) and Compound Trz36(27.6 g, 53.2 mmol) were added to 300 ml of THF, and the mixture was stirred and refluxed. Then, potassium carbonate(21 g, 151.9 mmol) was dissolved in 63 ml of water and added thereto, and the mixture was sufficiently stirred and then bis(tri-tert-butylphosphine)palladium(0) (0.3 g, 0.5 mmol) was added. After the reaction for 4 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 22.5 g of Compound 1-36. (Yield: 68%, MS: [M+H]⁺=654).

### Preparation Example 1-37

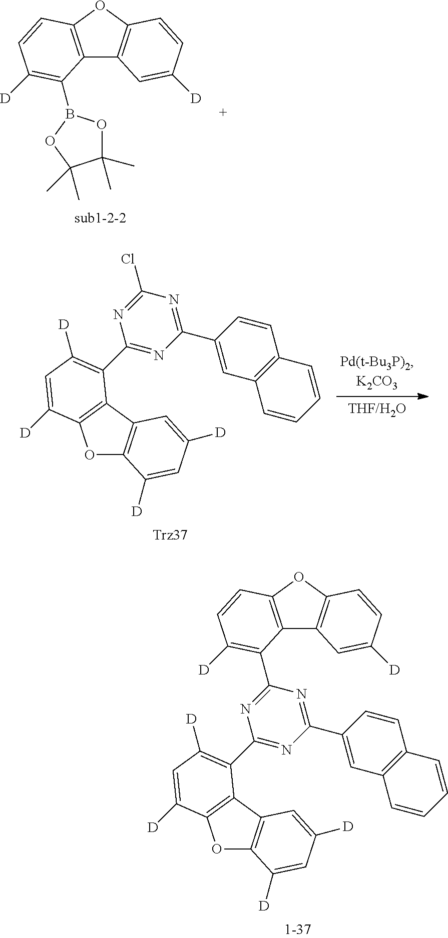 [SMILES: [2H]c1ccc2oc3ccc([2H])c(B4OC(C)(C)C(C)(C)O4)c3c2c1 ; [2H]c1cc([2H])c2oc3c([2H])cc([2H])c(-c4nc(Cl)nc(-c5ccc6ccccc6c5)n4)c3c2c1 ; [2H]c1ccc2oc3ccc([2H])c(-c4nc(-c5ccc6ccccc6c5)nc(-c5c([2H])cc([2H])c6oc7c([2H])cc([2H])cc7c56)n4)c3c2c1]

Compound sub1-2-2(15 g, 50.6 mmol) and Compound Trz37(21.9 g, 53.2 mmol) were added to 300 ml of THF, and the mixture was stirred and refluxed. Then, potassium carbonate(21 g, 151.9 mmol) was dissolved in 63 ml of water and added thereto, and the mixture was sufficiently stirred and then bis(tri-tert-butylphosphine)palladium(0) (0.3 g, 0.5 mmol) was added. After the reaction for 4 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 17.9 g of Compound 1-37. (Yield: 65%, MS: [M+H]⁺=546).

### Preparation Example 1-38

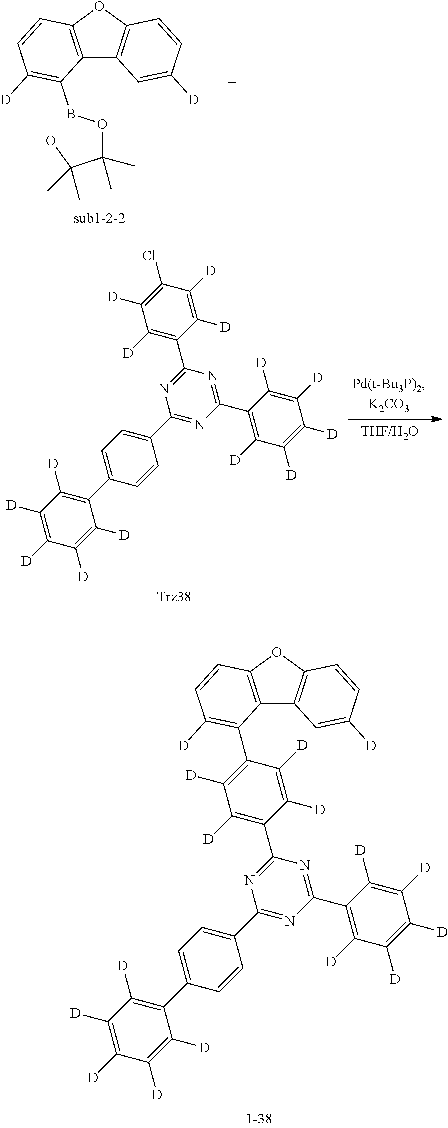

Compound sub1-2-2(15 g, 50.6 mmol) and Compound Trz38(23.1 g, 53.2 mmol) were added to 300 ml of THF, and the mixture was stirred and refluxed. Then, potassium carbonate(21 g, 151.9 mmol) was dissolved in 63 ml of water and added thereto, and the mixture was sufficiently stirred and then bis(tri-tert-butylphosphine)palladium(0) (0.3 g, 0.5 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 19 g of Compound 1-38. (Yield: 66%, MS: [M+H]⁺=568).

### Preparation Example 1-39

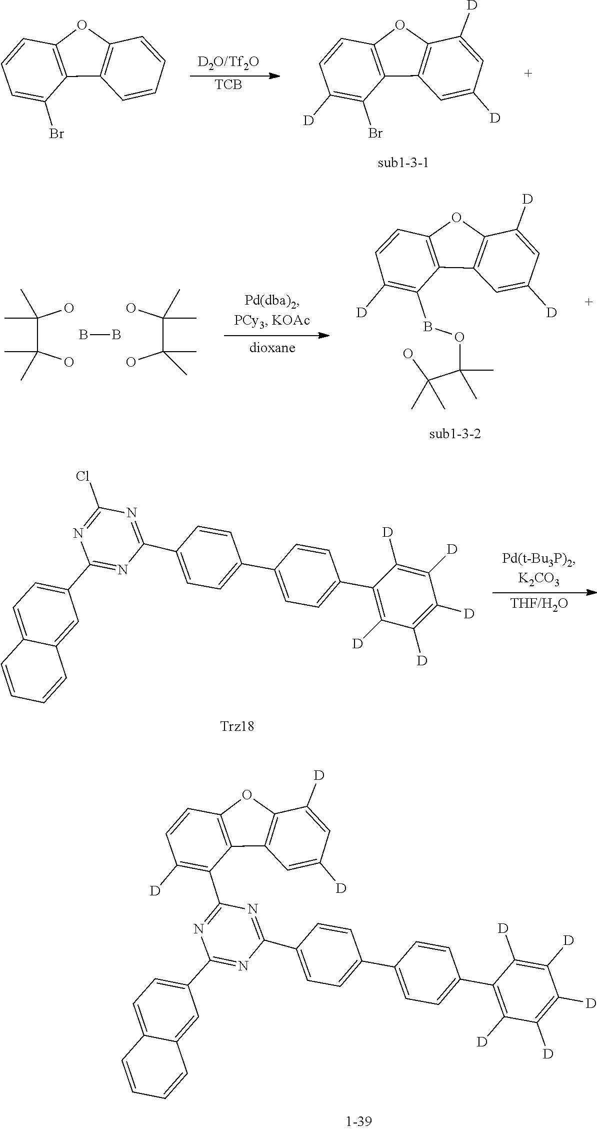

Trifluoromethanesulfonic anhydride(71.9 g, 255 mmol) and deuterium oxide(25.5 g, 1274.8 mmol) were added at 0° C., and the mixture was stirred for 5 hours to prepare a solution. 1-Bromodibenzo[b,d]furan(15 g, 60.7 mmol) was added to 120 mL of 1,2,4-trichlorobenzene, and the mixture was stirred. Then, the prepared mixed solution of trifluoromethanesulfonic anhydride and deuterium oxide was slowly added dropwise to a mixed solution of 1-bromodibenzo[b,d]furan and 1,2,4-trichlorobenzene, and the mixture was stirred while heating to 140° C. and then keeping that temperature. After the reaction for 14 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 6.3 g of Compound sub1-3-1. (Yield: 42%, MS: [M+H]⁺=250)

Compound sub1-3-1(15 g, 60 mmol) and bis(pinacolato)diboron(16.8 g, 66 mmol) were added to 300 ml of 1,4-dioxane, and the mixture was stirred under reflux. Then, potassium acetate(8.8 g, 90 mmol) was added thereto, the mixture was sufficiently stirred and then bis(dibenzylideneacetone)palladium(0) (1 g, 1.8 mmol) and tricyclohexylphosphine(1 g, 3.6 mmol) were added. After the reaction for 6 hours, the reaction mixture was cooled to room temperature, the organic layer was separated using chloroform and water, and then the organic layer was distilled. This was again dissolved in chloroform, washed twice with water, and the organic layer was then separated. Anhydrous magnesium sulfate was added thereto, stirred, then filtered, and the filtrate was distilled under reduced pressure. The concentrated compound was purified by a silica gel column chromatography to prepare 11.4 g of Compound sub1-3-2. (Yield: 64%, MS: [M+H]⁺=298)

Compound sub1-3-2(15 g, 50.5 mmol) and Compound Trz18(25.2 g, 53 mmol) were added to 300 ml of THF, and the mixture was stirred and refluxed. Then, potassium carbonate(20.9 g, 151.4 mmol) was dissolved in 63 ml of water and added thereto, the mixture was sufficiently stirred and then bis(tri-tert-butylphosphine)palladium(0) (0.3 g, 0.5 mmol) was added. After the reaction for 3 hours, the reaction mixture was cooled to room temperature, and then the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 23.1 g of Compound 1-39. (Yield: 75%, MS: [M+H]⁺=610)

### Preparation Example 1-40

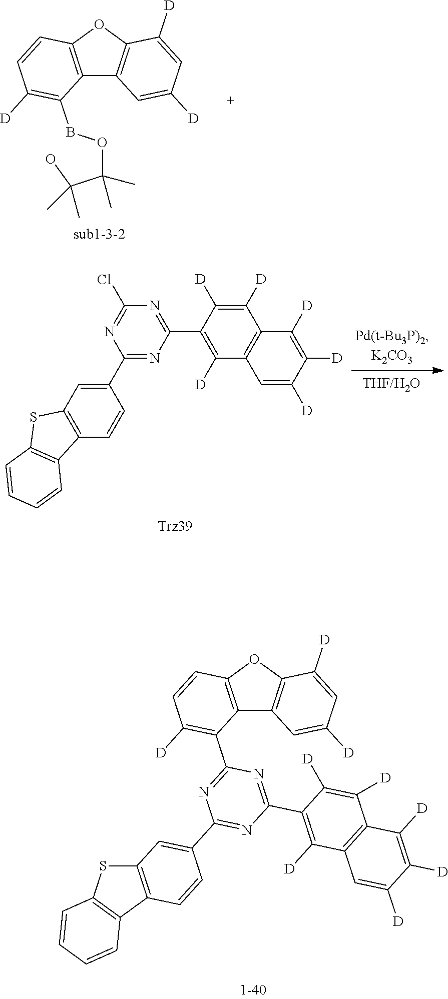

Compound sub1-3-2(15 g, 50.5 mmol) and Compound Trz39(22.8 g, 53 mmol) were added to 300 ml of THF, and the mixture was stirred and refluxed. Then, potassium carbonate(20.9 g, 151.4 mmol) was dissolved in 63 ml of water and added thereto, and the mixture was sufficiently stirred and then bis(tri-tert-butylphosphine)palladium(0) (0.3 g, 0.5 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 18.5 g of Compound 1-40. (Yield: 65%, MS: [M+H]⁺=565).

### Preparation Example 1-41

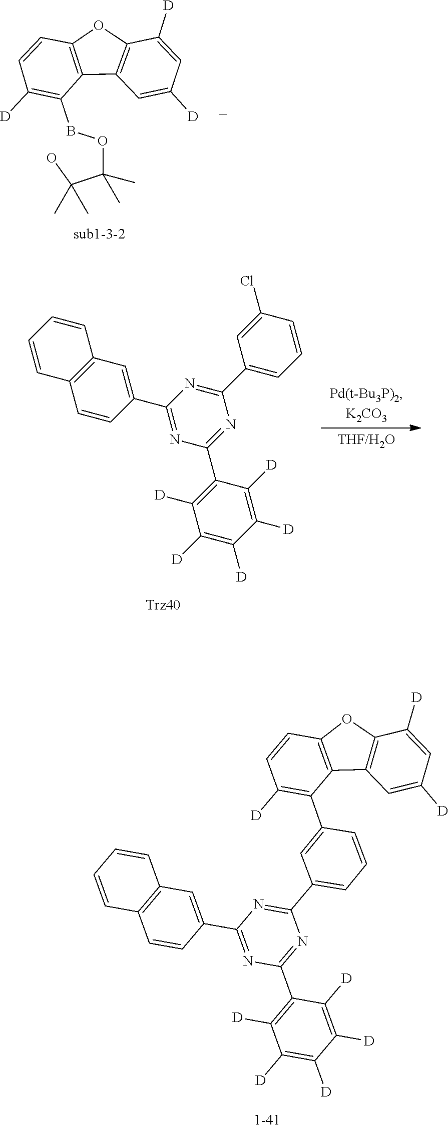

Compound sub1-3-2(15 g, 50.5 mmol) and Compound Trz40(21.1 g, 53 mmol) were added to 300 ml of THF, and the mixture was stirred and refluxed. Then, potassium carbonate(20.9 g, 151.4 mmol) was dissolved in 63 ml of water and added thereto, and the mixture was sufficiently stirred and then bis(tri-tert-butylphosphine)palladium(0) (0.3 g, 0.5 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 17.8 g of Compound 1-41. (Yield: 66%, MS: [M+H]⁺=534).

### Preparation Example 1-42

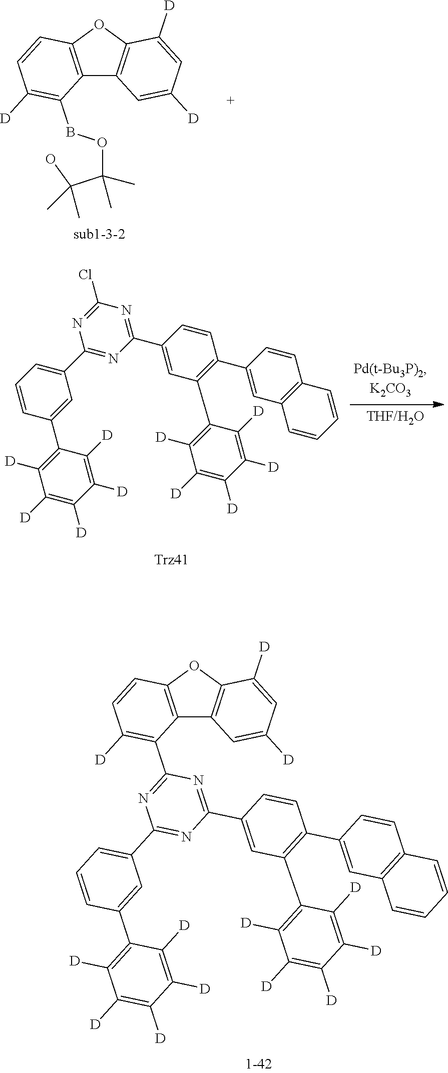

Compound sub1-3-2(15 g, 50.5 mmol) and Compound Trz41(29.5 g, 53 mmol) were added to 300 ml of THF, and the mixture was stirred and refluxed. Then, potassium carbonate(20.9 g, 151.4 mmol) was dissolved in 63 ml of water and added thereto, and the mixture was sufficiently stirred and then bis(tri-tert-butylphosphine)palladium(0) (0.3 g, 0.5 mmol) was added. After the reaction for 4 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 24.4 g of Compound 1-42. (Yield: 70%, MS: [M+H]⁺=691).

### Preparation Example 1-43

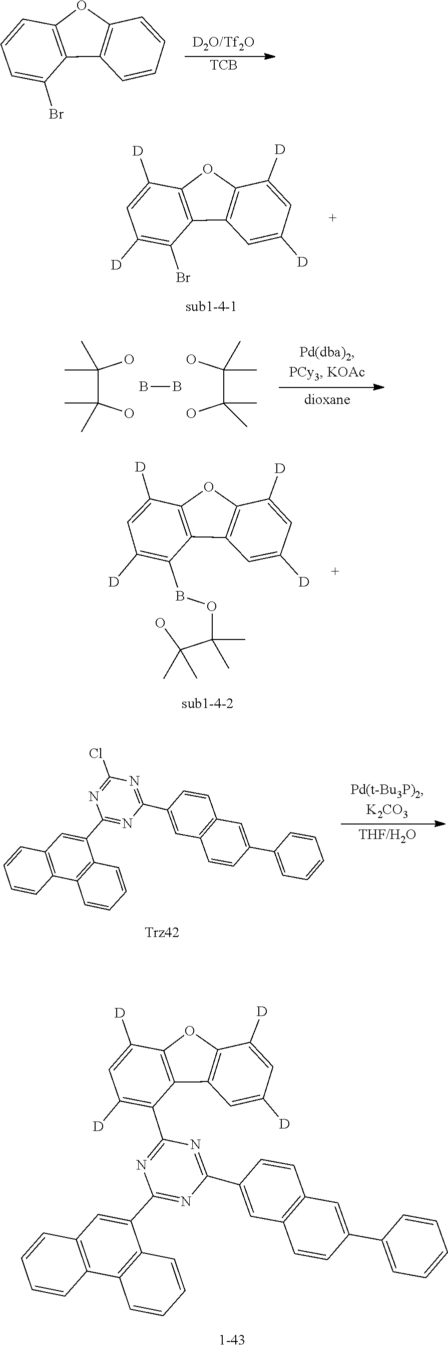

Trifluoromethanesulfonic anhydride(95.9 g, 340 mmol) and deuterium oxide(34 g, 1699.8 mmol) were added at 0° C., and the mixture was stirred for 5 hours to prepare a solution. 1-Bromodibenzo[b,d]furan(15 g, 60.7 mmol) was added to 120 mL of 1,2,4-trichlorobenzene, and the mixture was stirred. Then, the prepared mixed solution of trifluoromethanesulfonic anhydride and deuterium oxide was slowly added dropwise to a mixed solution of 1-bromodibenzo[b,d]furan and 1,2,4-trichlorobenzene, and the mixture was stirred while heating to 140° C. and then keeping that temperature. After the reaction for 20 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.6 g of Compound sub1-4-1. (Yield: 37%, MS: [M+H]⁺=251)

Compound sub1-4-1(15 g, 59.7 mmol) and bis(pinacolato)diboron(16.7 g, 65.7 mmol) were added to 300 ml of 1,4-dioxane, and the mixture was stirred under reflux. Then, potassium acetate(8.8 g, 89.6 mmol) was added thereto, the mixture was sufficiently stirred and then bis(dibenzylideneacetone)palladium(0) (1 g, 1.8 mmol) and tricyclohexylphosphine(1 g, 3.6 mmol) were added. After the reaction for 5 hours, the reaction mixture was cooled to room temperature, the organic layer was separated using chloroform and water, and then the organic layer was distilled. This was again dissolved in chloroform, washed twice with water, and the organic layer was then separated. Anhydrous magnesium sulfate was added thereto, stirred, then filtered, and the filtrate was distilled under reduced pressure. The concentrated compound was purified by a silica gel column chromatography to prepare 12.5 g of Compound sub1-4-2. (Yield: 70%, MS: [M+H]⁺=299)

Compound sub1-4-2(15 g, 50.3 mmol) and Compound Trz42(26.1 g, 52.8 mmol) were added to 300 ml of THF, and the mixture was stirred and refluxed. Then, potassium carbonate(20.9 g, 150.9 mmol) was dissolved in 63 ml of water and added thereto, the mixture was sufficiently stirred and then bis(tri-tert-butylphosphine)palladium(0) (0.3 g, 0.5 mmol) was added. After the reaction for 4 hours, the reaction mixture was cooled to room temperature, and then the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 21.5 g of Compound 1-43. (Yield: 68%, MS: [M+H]⁺=631)

### Preparation Example 1-44

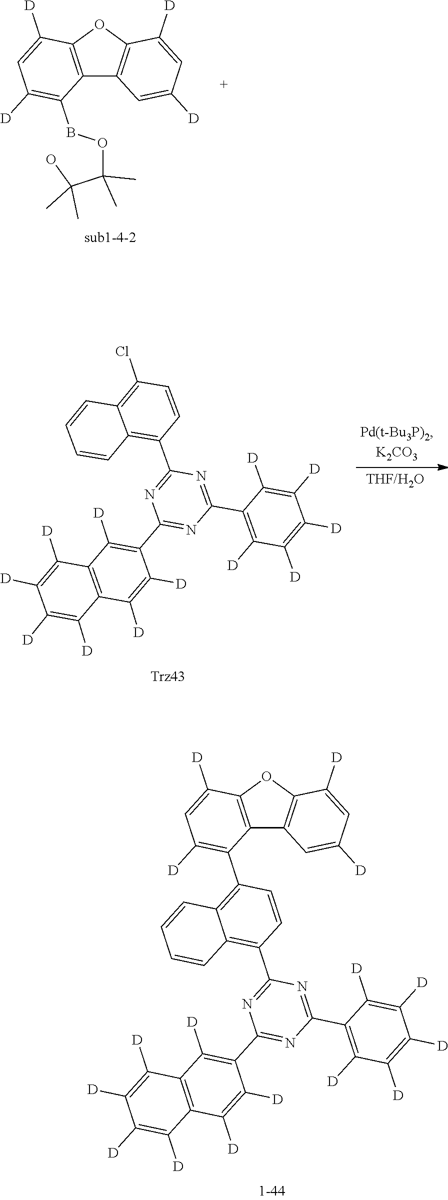

Compound sub1-4-2(15 g, 50.3 mmol) and Compound Trz43(24.1 g, 52.8 mmol) were added to 300 ml of THF, and the mixture was stirred and refluxed. Then, potassium carbonate(20.9 g, 150.9 mmol) was dissolved in 63 ml of water and added thereto, and the mixture was sufficiently stirred and then bis(tri-tert-butylphosphine)palladium(0) (0.3 g, 0.5 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 20.2 g of Compound 1-44. (Yield: 68%, MS: [M+H]⁺=592).

### Preparation Example 1-45

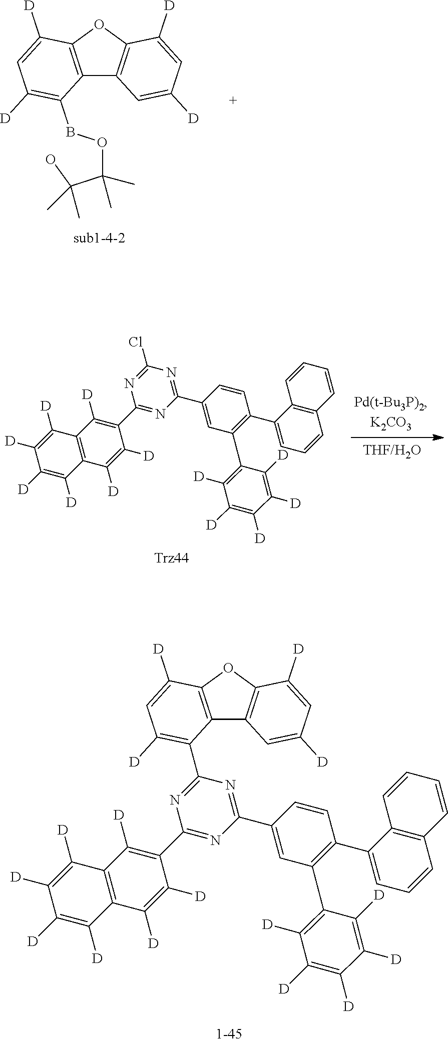

Compound sub1-4-2(15 g, 50.3 mmol) and Compound Trz44(28.1 g, 52.8 mmol) were added to 300 ml of THF, and the mixture was stirred and refluxed. Then, potassium carbonate(20.9 g, 150.9 mmol) was dissolved in 63 ml of water and added thereto, and the mixture was sufficiently stirred and then bis(tri-tert-butylphosphine)palladium(0) (0.3 g, 0.5 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 24.2 g of Compound 1-45. (Yield: 72%, MS: [M+H]⁺=668).

### Preparation Example 1-46

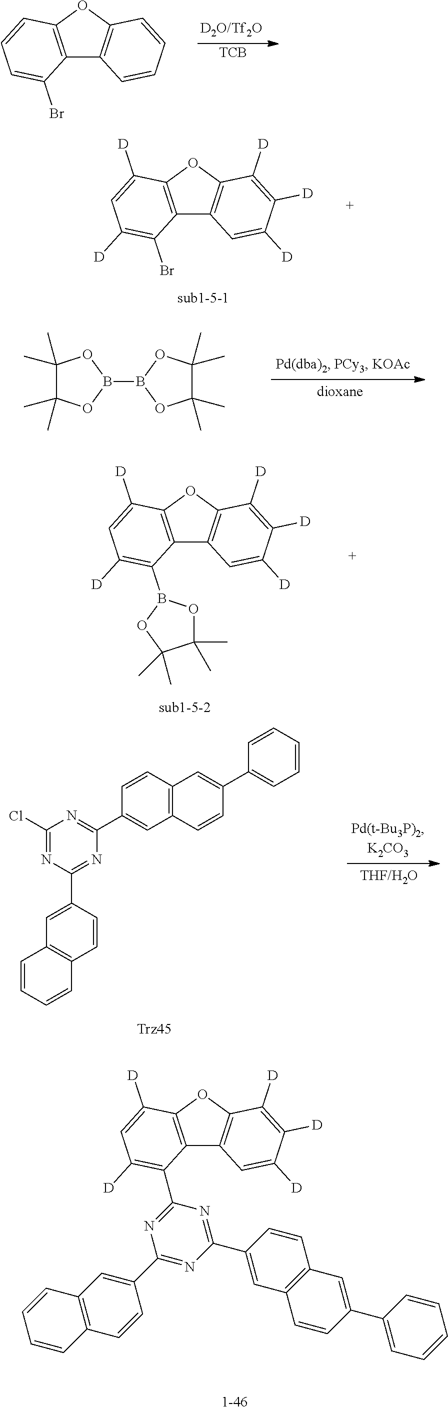

Trifluoromethanesulfonic anhydride(119.9 g, 424.9 mmol) and deuterium oxide(42.6 g, 2124.7 mmol) were added at 0° C., and the mixture was stirred for 5 hours to prepare a solution. 1-Bromodibenzo[b,d]furan(15 g, 60.7 mmol) was added to 120 mL of 1,2,4-trichlorobenzene, and the mixture was stirred. Then, the prepared mixed solution of trifluoromethanesulfonic anhydride and deuterium oxide was slowly added dropwise to a mixed solution of 1-bromodibenzo[b,d]furan and 1,2,4-trichlorobenzene, and the mixture was stirred while heating to 140° C. and then keeping that temperature. After the reaction for 24 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.9 g of Compound sub1-5-1. (Yield: 39%, MS: [M+H]⁺=252)

Compound sub1-5-1(15 g, 59.5 mmol) and bis(pinacolato)diboron(16.6 g, 65.4 mmol) were added to 300 ml of 1,4-dioxane, and the mixture was stirred under reflux. Then, potassium acetate(8.8 g, 89.2 mmol) was added thereto, the mixture was sufficiently stirred and then bis(dibenzylideneacetone)palladium(0) (1 g, 1.8 mmol) and tricyclohexylphosphine(1 g, 3.6 mmol) were added. After the reaction for 4 hours, the reaction mixture was cooled to room temperature, the organic layer was separated using chloroform and water, and then the organic layer was distilled. This was again dissolved in chloroform, washed twice with water, and the organic layer was then separated. Anhydrous magnesium sulfate was added thereto, stirred, then filtered, and the filtrate was distilled under reduced pressure. The concentrated compound was purified by a silica gel column chromatography to prepare 11.2 g of Compound sub1-5-2. (Yield: 63%, MS: [M+H]⁺=300)

Compound sub1-5-2(15 g, 50.1 mmol) and Compound Trz45(23.4 g, 52.6 mmol) were added to 300 ml of THF, and the mixture was stirred and refluxed. Then, potassium carbonate(20.8 g, 150.4 mmol) was dissolved in 62 ml of water and added thereto, the mixture was sufficiently stirred and then bis(tri-tert-butylphosphine)palladium(0) (0.3 g, 0.5 mmol) was added. After the reaction for 4 hours, the reaction mixture was cooled to room temperature, and then the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 20.1 g of Compound 1-46. (Yield: 69%, MS: [M+H]⁺=581)

### Preparation Example 1-47

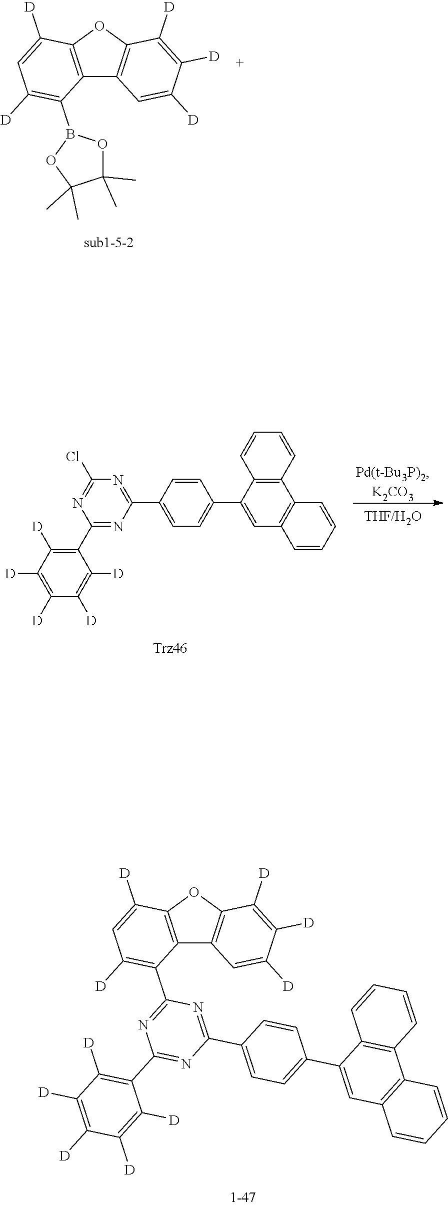

Compound sub1-5-2(15 g, 50.1 mmol) and Compound Trz46(23.6 g, 52.6 mmol) were added to 300 ml of THF, and the mixture was stirred and refluxed. Then, potassium carbonate(20.8 g, 150.4 mmol) was dissolved in 62 ml of water and added thereto, and the mixture was sufficiently stirred and then bis(tri-tert-butylphosphine)palladium(0) (0.3 g, 0.5 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 20.2 g of Compound 1-47. (Yield: 69%, MS: [M+H]⁺=586).

### Preparation Example 1-48

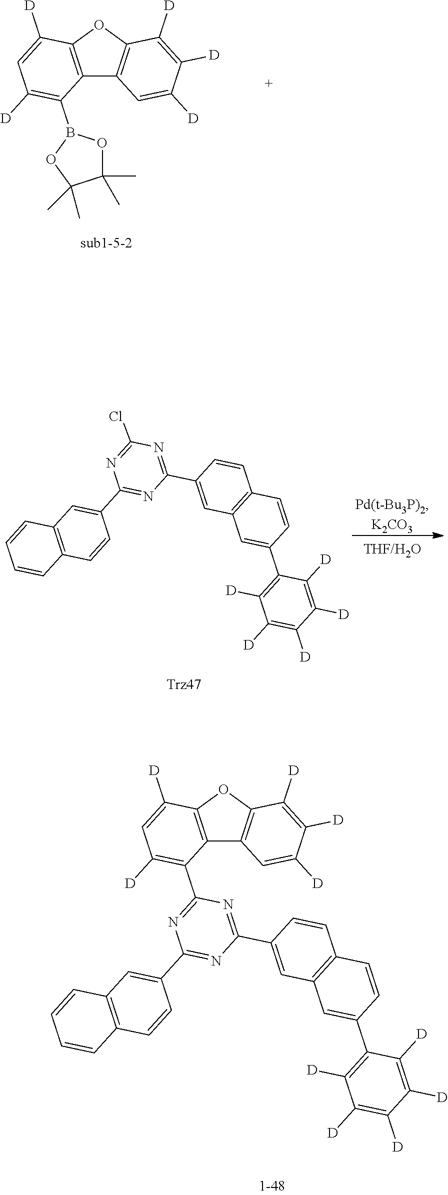 [SMILES: [2H]c1cc2c(oc3c([2H])cc([2H])c(B4OC(C)(C)C(C)(C)O4)c32)c([2H])c1[2H] ; [2H]c1c([2H])c([2H])c(-c2ccc3ccc(-c4nc(Cl)nc(-c5ccc6ccccc6c5)n4)cc3c2)c([2H])c1[2H] ; [2H]c1cc2c(oc3c([2H])cc([2H])c(-c4nc(-c5ccc6ccccc6c5)nc(-c5ccc6ccc(-c7c([2H])c([2H])c([2H])c([2H])c7[2H])cc6c5)n4)c32)c([2H])c1[2H]]

Compound sub1-5-2(15 g, 50.1 mmol) and Compound Trz47(23.6 g, 52.6 mmol) were added to 300 ml of THF, and the mixture was stirred and refluxed. Then, potassium carbonate(20.8 g, 150.4 mmol) was dissolved in 62 ml of water and added thereto, and the mixture was sufficiently stirred and then bis(tri-tert-butylphosphine)palladium(0) (0.3 g, 0.5 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 21.7 g of Compound 1-48. (Yield: 74%, MS: [M+H]⁺=586).

### Preparation Example 1-49

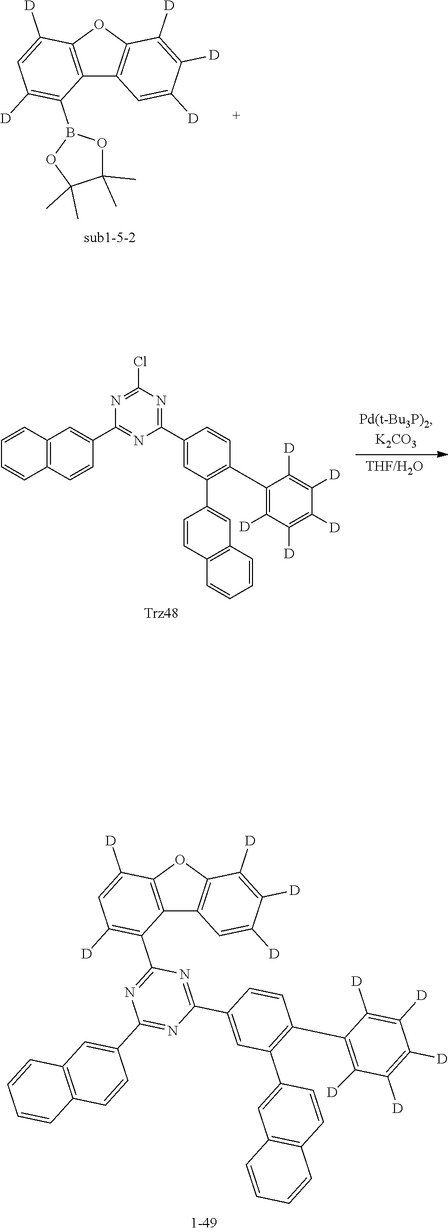 [SMILES: [2H]c1cc2c(oc3c([2H])cc([2H])c(B4OC(C)(C)C(C)(C)O4)c32)c([2H])c1[2H] ; [2H]c1c([2H])c([2H])c(-c2ccc(-c3nc(Cl)nc(-c4ccc5ccccc5c4)n3)cc2-c2ccc3ccccc3c2)c([2H])c1[2H] ; [2H]c1cc2c(oc3c([2H])cc([2H])c(-c4nc(-c5ccc(-c6c([2H])c([2H])c([2H])c([2H])c6[2H])c(-c6ccc7ccccc7c6)c5)nc(-c5ccc6ccccc6c5)n4)c32)c([2H])c1[2H]]

Compound sub1-5-2(15 g, 50.1 mmol) and Compound Trz48(27.6 g, 52.6 mmol) were added to 300 ml of THF, and the mixture was stirred and refluxed. Then, potassium carbonate(20.8 g, 150.4 mmol) was dissolved in 62 ml of water and added thereto, and the mixture was sufficiently stirred and then bis(tri-tert-butylphosphine)palladium(0) (0.3 g, 0.5 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 22.5 g of Compound 1-49. (Yield: 68%, MS: [M+H]⁺=662).

### Preparation Example 1-50

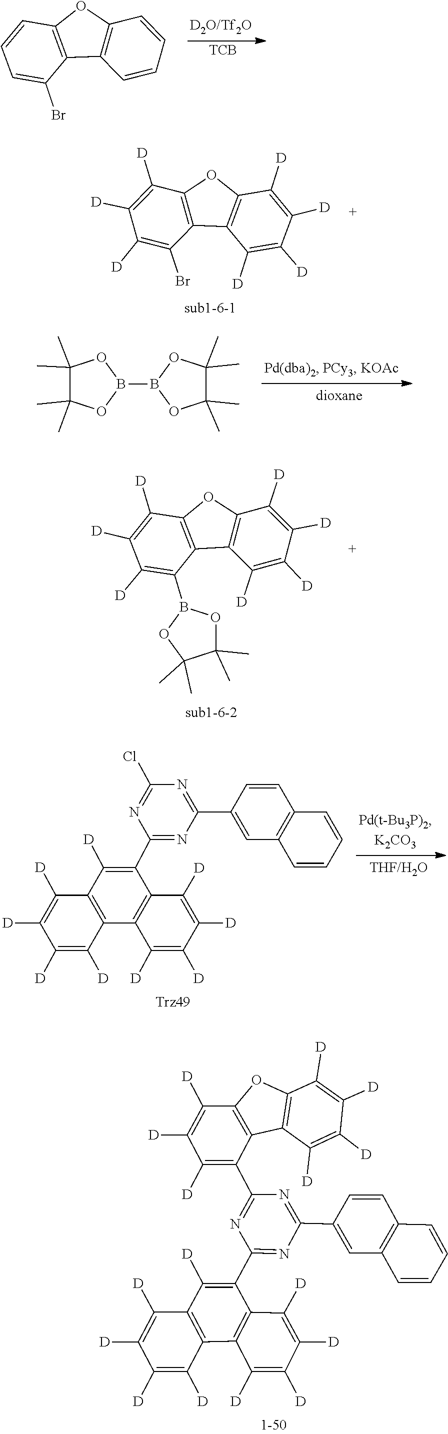

Trifluoromethanesulfonic anhydride(167.8 g, 594.9 mmol) and deuterium oxide(59.6 g, 2974.6 mmol) were added at 0° C., and the mixture was stirred for 5 hours to prepare a solution. 1-Bromodibenzo[b,d]furan(15 g, 60.7 mmol) was added to 120 mL of 1,2,4-trichlorobenzene, and the mixture was stirred. Then, the prepared mixed solution of trifluoromethanesulfonic anhydride and deuterium oxide was slowly added dropwise to a mixed solution of 1-bromodibenzo[b,d]furan and 1,2,4-trichlorobenzene, and the mixture was stirred while heating to 140° C. and then keeping that temperature. After the reaction for 36 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 6.1 g of Compound sub1-6-1. (Yield: 40%, MS: [M+H]⁺=254)

Compound sub1-6-1(15 g, 59 mmol) and bis(pinacolato)diboron(16.5 g, 64.9 mmol) were added to 300 ml of 1,4-dioxane, and the mixture was stirred under reflux. Then, potassium acetate(8.7 g, 88.5 mmol) was added thereto, the mixture was sufficiently stirred and then bis(dibenzylideneacetone)palladium(0) (1 g, 1.8 mmol) and tricyclohexylphosphine(1 g, 3.5 mmol) were added. After the reaction for 4 hours, the reaction mixture was cooled to room temperature, the organic layer was separated using chloroform and water, and then the organic layer was distilled. This was again dissolved in chloroform, washed twice with water, and the organic layer was then separated. Anhydrous magnesium sulfate was added thereto, stirred, then filtered, and the filtrate was distilled under reduced pressure. The concentrated compound was purified by a silica gel column chromatography to prepare 11.6 g of Compound sub1-6-2. (Yield: 65%, MS: [M+H]⁺=302)

Compound sub1-6-2(15 g, 49.8 mmol) and Compound Trz49(22.3 g, 52.3 mmol) were added to 300 ml of THF, and the mixture was stirred and refluxed. Then, potassium carbonate(20.6 g, 149.4 mmol) was dissolved in 62 ml of water and added thereto, the mixture was sufficiently stirred and then bis(tri-tert-butylphosphine)palladium(0) (0.3 g, 0.5 mmol) was added. After the reaction for 5 hours, the reaction mixture was cooled to room temperature, and then the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 20.3 g of Compound 1-50. (Yield: 72%, MS: [M+H]⁺=566)

### Preparation Example 1-51

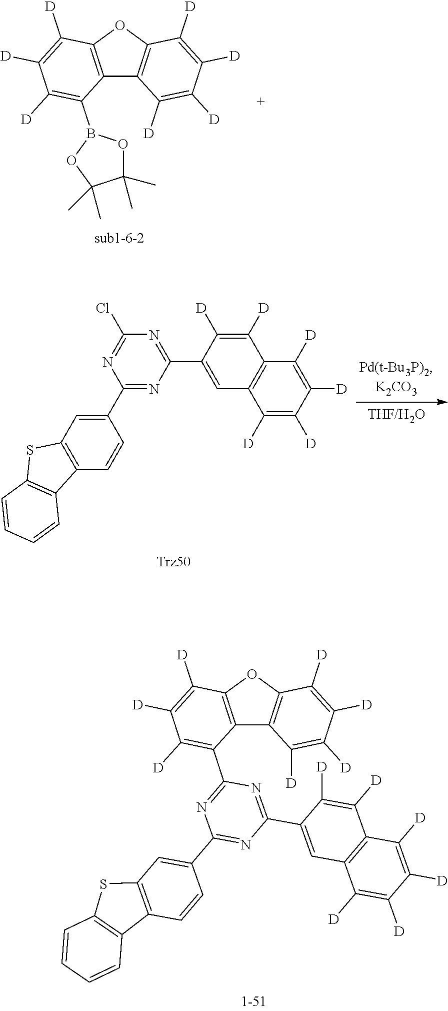

Compound sub1-6-2(15 g, 49.8 mmol) and Compound Trz50(22.5 g, 52.3 mmol) were added to 300 ml of THF, and the mixture was stirred and refluxed. Then, potassium carbonate(20.6 g, 149.4 mmol) was dissolved in 62 ml of water and added thereto, and the mixture was sufficiently stirred and then bis(tri-tert-butylphosphine)palladium(0) (0.3 g, 0.5 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 20.4 g of Compound 1-51. (Yield: 72%, MS: [M+H]⁺=569).

### Preparation Example 1-52

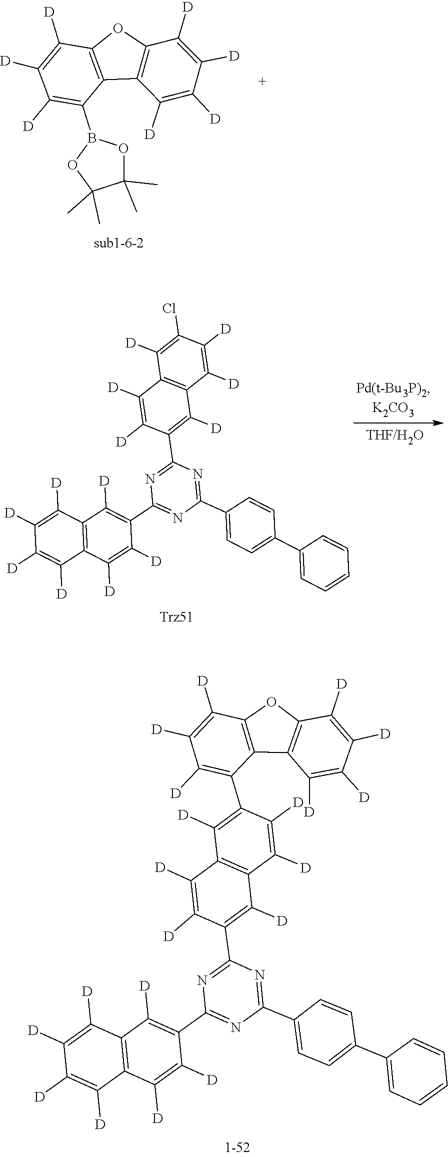

Compound sub1-6-2(15 g, 49.8 mmol) and Compound Trz51 (27.9 g, 52.3 mmol) were added to 300 ml of THF, and the mixture was stirred and refluxed. Then, potassium carbonate(20.6 g, 149.4 mmol) was dissolved in 62 ml of water and added thereto, and the mixture was sufficiently stirred and then bis(tri-tert-butylphosphine)palladium(0) (0.3 g, 0.5 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 24.7 g of Compound 1-52. (Yield: 74%, MS: [M+H]⁺=672).

### Preparation Example 1-53

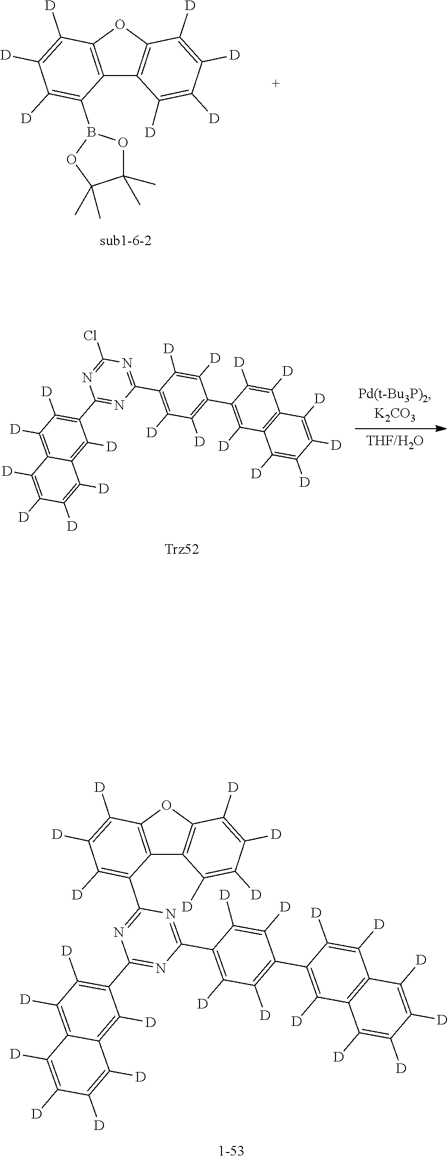 [SMILES: [2H]c1c([2H])c([2H])c2c(oc3c([2H])c([2H])c([2H])c(B4OC(C)(C)C(C)(C)O4)c32)c1[2H] ; [2H]c1c([2H])c(-c2c([2H])c([2H])c3c([2H])c([2H])c([2H])c([2H])c3c2[2H])c([2H])c([2H])c1-c1nc(Cl)nc(-c2c([2H])c([2H])c3c([2H])c([2H])c([2H])c([2H])c3c2[2H])n1 ; [2H]c1c([2H])c(-c2c([2H])c([2H])c3c([2H])c([2H])c([2H])c([2H])c3c2[2H])c([2H])c([2H])c1-c1nc(-c2c([2H])c([2H])c3c([2H])c([2H])c([2H])c([2H])c3c2[2H])nc(-c2c([2H])c([2H])c([2H])c3oc4c([2H])c([2H])c([2H])c([2H])c4c23)n1]

Compound sub1-6-2 (15 g, 49.8 mmol) and Compound Trz52 (24.2 g, 52.3 mmol) were added to 300 ml of THF, and the mixture was stirred and refluxed. Then, potassium carbonate(20.6 g, 149.4 mmol) was dissolved in 62 ml of water and added thereto, and the mixture was sufficiently stirred and then bis(tri-tert-butylphosphine)palladium(0) (0.3 g, 0.5 mmol) was added. After the reaction for 5 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 22.4 g of Compound 1-53. (Yield: 75%, MS: [M+H]⁺=601).

### Preparation Example 1-54

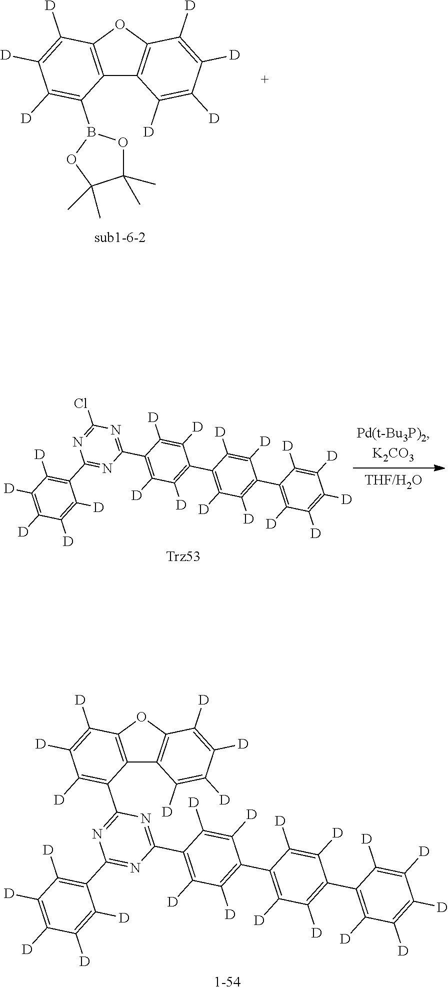 [SMILES: [2H]c1c([2H])c([2H])c2c(oc3c([2H])c([2H])c([2H])c(B4OC(C)(C)C(C)(C)O4)c32)c1[2H] ; [2H]c1c([2H])c([2H])c(-c2nc(Cl)nc(-c3c([2H])c([2H])c(-c4c([2H])c([2H])c(-c5c([2H])c([2H])c([2H])c([2H])c5[2H])c([2H])c4[2H])c([2H])c3[2H])n2)c([2H])c1[2H] ; [2H]c1c([2H])c([2H])c(-c2nc(-c3c([2H])c([2H])c(-c4c([2H])c([2H])c(-c5c([2H])c([2H])c([2H])c([2H])c5[2H])c([2H])c4[2H])c([2H])c3[2H])nc(-c3c([2H])c([2H])c([2H])c4oc5c([2H])c([2H])c([2H])c([2H])c5c34)n2)c([2H])c1[2H]]

Compound sub1-6-2(15 g, 49.8 mmol) and Compound Trz53(22.9 g, 52.3 mmol) were added to 300 ml of THF, and the mixture was stirred and refluxed. Then, potassium carbonate(20.6 g, 149.4 mmol) was dissolved in 62 ml of water and added thereto, and the mixture was sufficiently stirred and then bis(tri-tert-butylphosphine)palladium(0) (0.3 g, 0.5 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 18.7 g of Compound 1-54. (Yield: 65%, MS: [M+H]⁺=577).

### Preparation Example 1-55

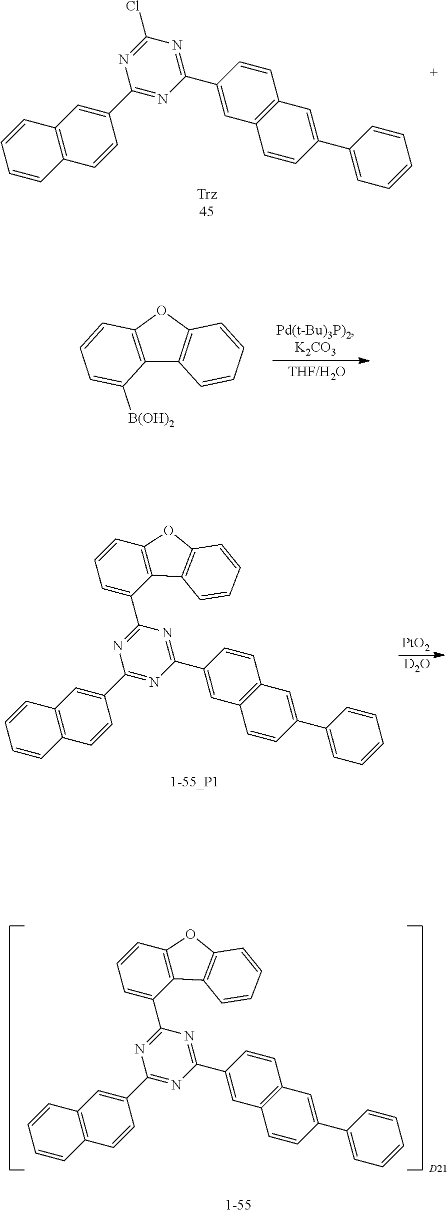

Compound Trz45(15 g, 33.8 mmol) and dibenzo[b,d]furan-1-ylboronic acid(7.5 g, 35.5 mmol) were added to 300 ml of THF, and the mixture was stirred and refluxed. Then, potassium carbonate(14 g, 101.4 mmol) was dissolved in 42 ml of water and added thereto, and the mixture was sufficiently stirred and then bis(tri-tert-butylphosphine)palladium(0) (0.2 g, 0.3 mmol) was added. After the reaction for 4 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 12.8 g of Compound 1-55_P1. (Yield: 66%, MS: [M+H]⁺=576).

Compound 1-55_P1(10 g, 17.4 mmol), PtO₂(1.2 g, 5.2 mmol) and D₂O(87 ml) were added to a shaker tube, and then the tube was sealed and heated at 250° C. and 600 psi for 12 hours. When the reaction was terminated, chloroform was added thereto, and the reaction solution was transferred to a separatory funnel, and extracted. The extract was dried over MgSO₄ and concentrated, and then the sample was purified by silica gel column chromatography to prepare 4.1 g of Compound 1-55. (Yield: 40%, MS: [M+H]⁺=598).

### Preparation Example 1-56

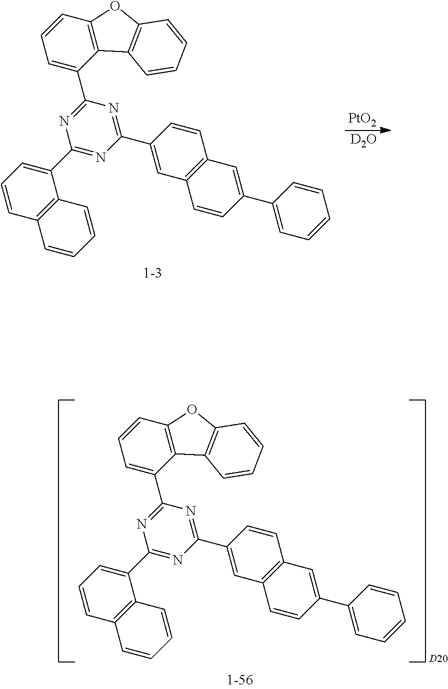

Compound 1-3(10 g, 17.4 mmol), PtO₂(1.2 g, 5.2 mmol) and D₂O (87 ml) were added to a shaker tube, and then the tube was sealed and heated at 250° C. and 600 psi for 12 hours. When the reaction was terminated, chloroform was added thereto, and the reaction solution was transferred to a separatory funnel, and extracted. The extract was dried over MgSO₄ and concentrated, and then the sample was purified by silica gel column chromatography to prepare 4.4 g of Compound 1-56. (Yield: 43%, MS: [M+H]⁺=597).

### Preparation Example 1-57

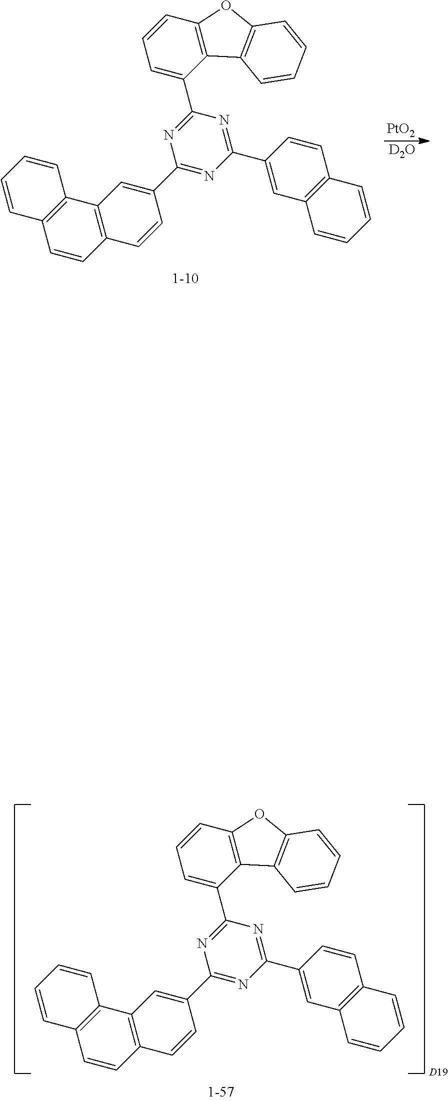

Compound 1-10(10 g, 18.2 mmol), PtO₂(1.2 g, 5.5 mmol) and D₂O (91 ml) were added to a shaker tube, and then the tube was sealed and heated at 250° C. and 600 psi for 12 hours. When the reaction was terminated, chloroform was added thereto, and the reaction solution was transferred to a separatory funnel, and extracted. The extract was dried over MgSO₄ and concentrated, and then the sample was purified by silica gel column chromatography to prepare 4.1 g of Compound 1-57. (Yield: 40%, MS: [M+H]⁺=570).

### Preparation Example 1-58

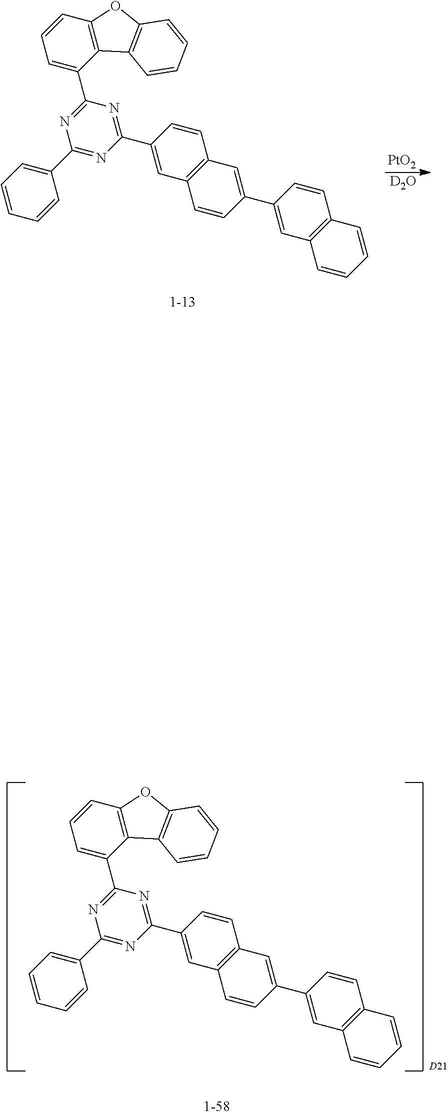

Compound 1-13(10 g, 17.4 mmol), PtO₂(1.2 g, 5.2 mmol) and D₂O (870 ml) were added to a shaker tube, and then the tube was sealed and heated at 250° C. and 600 psi for 12 hours. When the reaction was terminated, chloroform was added thereto, and the reaction solution was transferred to a separatory funnel, and extracted. The extract was dried over MgSO₄ and concentrated, and then the sample was purified by silica gel column chromatography to prepare 4.5 g of Compound 1-58. (Yield: 43%, MS: [M+H]⁺=598).

### Preparation Example 1-59

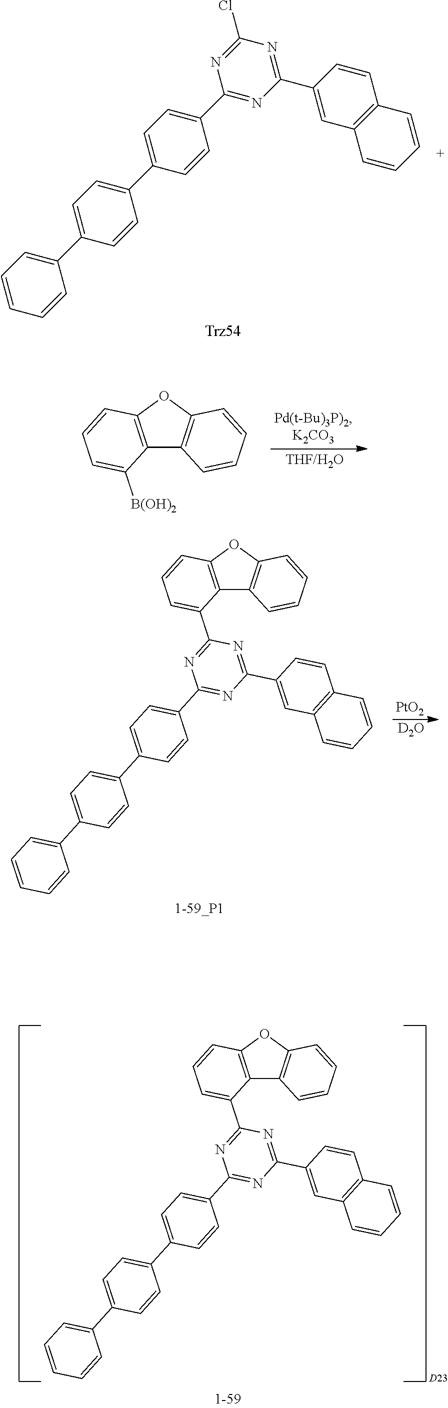

Compound Trz54(15 g, 31.9 mmol) and dibenzo[b,d]furan-1-ylboronic acid(7.1 g, 33.5 mmol) were added to 300 ml of THF, and the mixture was stirred and refluxed. Then, potassium carbonate(13.2 g, 95.8 mmol) was dissolved in 40 ml of water and added thereto, and the mixture was sufficiently stirred and then bis(tri-tert-butylphosphine)palladium(0) (0.2 g, 0.3 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 14.2 g of Compound 1-59_P1. (Yield: 74%, MS: [M+H]⁺=602).

Compound 1-59_P1(10 g, 16.6 mmol), PtO₂(1.1 g, 5 mmol) and D₂O(83 ml) were added to a shaker tube, and then the tube was sealed and heated at 250° C. and 600 psi for 12 hours. When the reaction was terminated, chloroform was added thereto, and the reaction solution was transferred to a separatory funnel, and extracted. The extract was dried over MgSO₄ and concentrated, and then the sample was purified by silica gel column chromatography to prepare 4.5 g of Compound 1-59. (Yield: 43%, MS: [M+H]⁺=626).

### Preparation Example 1-60

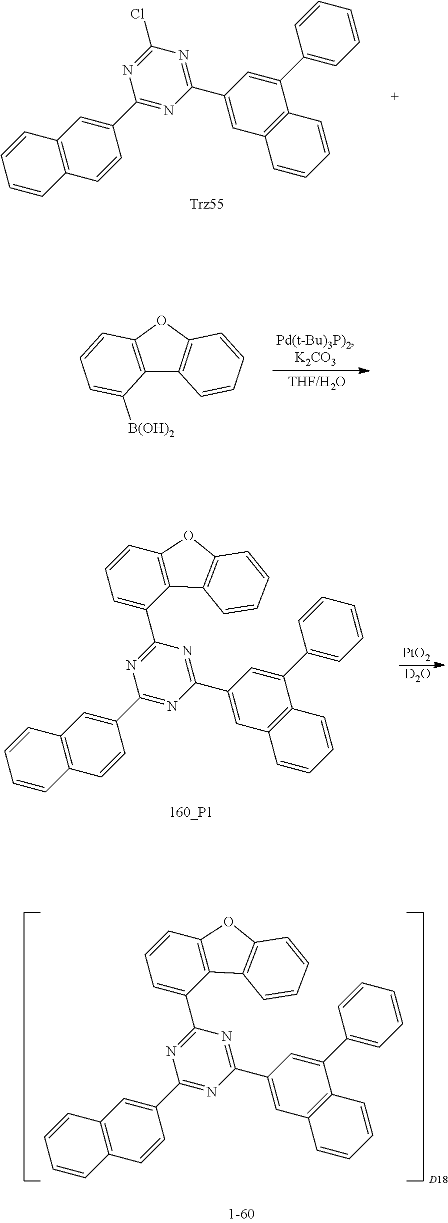

Compound Trz55(15 g, 33.8 mmol) and dibenzo[b,d]furan-1-ylboronic acid(7.5 g, 35.5 mmol) were added to 300 ml of THF, and the mixture was stirred and refluxed. Then, potassium carbonate(14 g, 101.4 mmol) was dissolved in 42 ml of water and added thereto, and the mixture was sufficiently stirred and then bis(tri-tert-butylphosphine)palladium(0) (0.2 g, 0.3 mmol) was added. After the reaction for 3 hours, the reaction mixture was cooled to room temperature, the organic layer and the aqueous layer were separated, and the organic layer was distilled. This was again dissolved in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.2 g of Compound 1-600_P1. (Yield: 68%, MS: [M+H]⁺=576).

Compound 1-60_P1(10 g, 17.4 mmol), PtO₂(1.2 g, 5.2 mmol) and D₂O(87 ml) were added to a shaker tube, and then the tube was sealed and heated at 250° C. and 600 psi for 12 hours. When the reaction was terminated, chloroform was added thereto, and the reaction solution was transferred to a separatory funnel, and extracted. The extract was dried over MgSO₄ and concentrated, and then the sample was purified by silica gel column chromatography to prepare 5.2 g of Compound 1-60. (Yield: 50%, MS: [M+H]⁺=595).

### Preparation Example 1-61

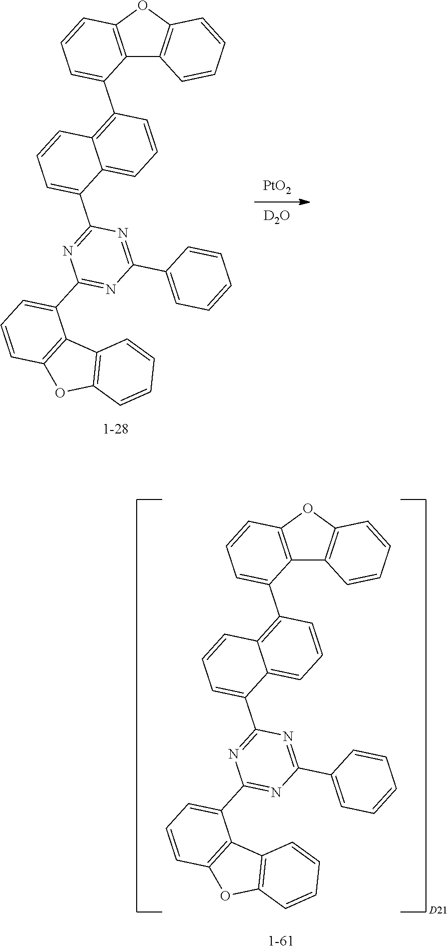

Compound 1-28(10 g, 16.2 mmol), PtO₂(1.1 g, 4.9 mmol) and D₂O(81 ml) were added to a shaker tube, and then the tube was sealed and heated at 250° C. and 600 psi for 12 hours. When the reaction was terminated, chloroform was added thereto, and the reaction solution was transferred to a separatory funnel, and extracted. The extract was dried over MgSO₄ and concentrated, and then the sample was purified by silica gel column chromatography to prepare 5 g of Compound 1-61. (Yield: 48%, MS: [M+H]⁺=638).

### Preparation Example 2-1

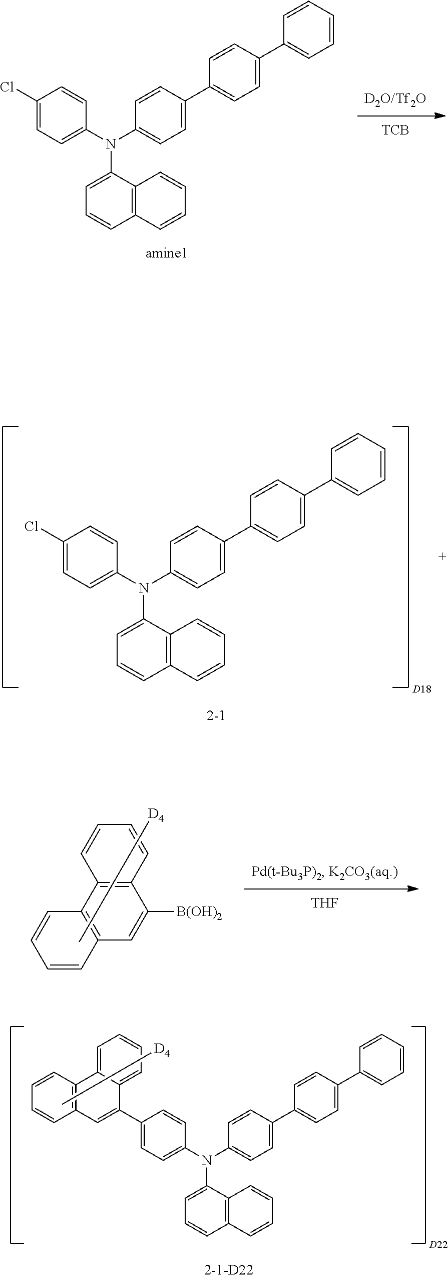

Compound amine1(10 g, 20.7 mmol) was added to 200 ml of 1,2,4-trichlorobenzene, and the mixture was stirred at room temperature. In another vessel, deuterium oxide(15 g, 746.9 mmol) was added to trifluoromethanesulfonic anhydride(52.7 g, 186.7 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5 g of Compound 2-1. (Yield: 48%, MS: [M+H]⁺=501).

Compound 2-1 (15 g, 30 mmol) and phenanthren-9-ylboronic acid_D4 (7.1 g, 31.5 mmol) were added to 300 ml of THF, and the mixture was stirred and refluxed. Then, potassium carbonate(12.4 g, 90 mmol) was dissolved in 100 ml of water and added thereto, and the mixture was sufficiently stirred and then bis(tri-tert-butylphosphine)palladium(0) (0.2 g, 0.3 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.7 g of Compound 2-1-D22. (Yield: 76%, MS: [M+H]⁺=647)

### Preparation Example 2-2

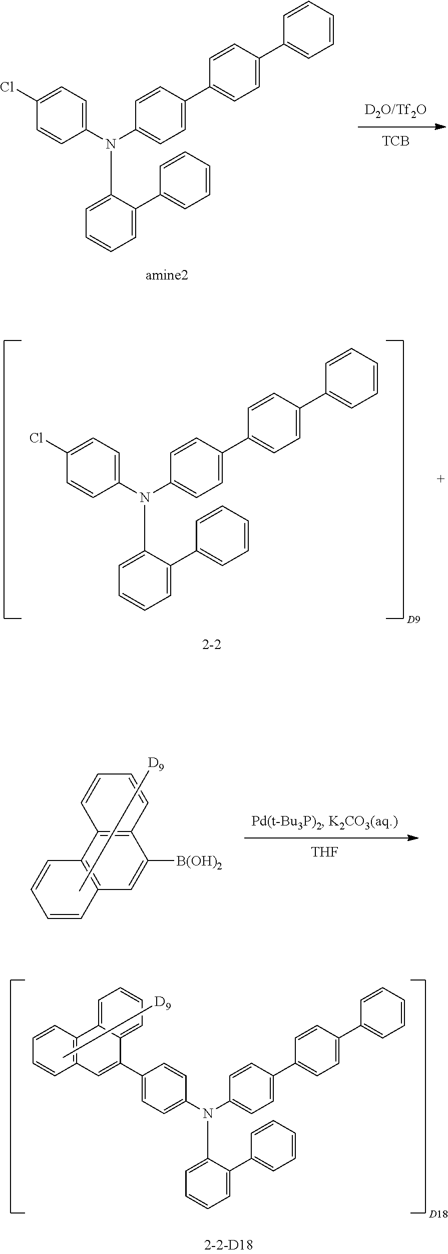

Compound amine2(10 g, 19.7 mmol) was added to 200 ml of 1,2,4-trichlorobenzene, and the mixture was stirred at room temperature. In another vessel, deuterium oxide(14.2 g, 708.6 mmol) was added to trifluoromethanesulfonic anhydride(33.3 g, 118.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.1 g of Compound 2-2. (Yield: 50%, MS: [M+H]⁺=518).

Compound 2-2(15 g, 29 mmol) and phenanthren-9-ylboronic acid_D9(7 g, 30.5 mmol) were added to 300 ml of THF, and the mixture was stirred and refluxed. Then, potassium carbonate(12 g, 87 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.5 g of Compound 2-2-D18. (Yield: 75%, MS: [M+H]⁺=669)

### Preparation Example 2-3

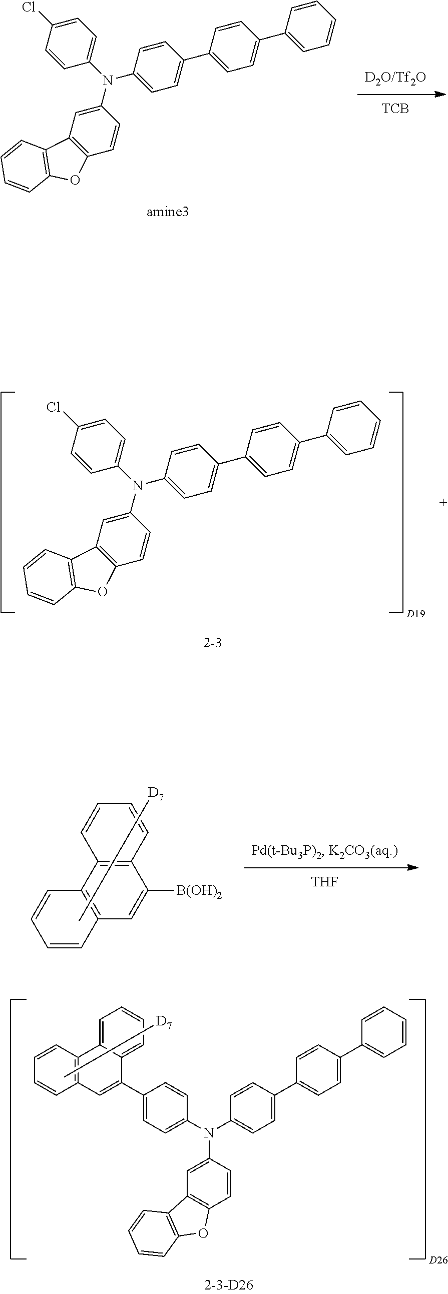

Compound amine3(10 g, 19.2 mmol) was added to 200 ml of 1,2,4-trichlorobenzene, and the mixture was stirred at room temperature. In another vessel, deuterium oxide(13.8 g, 689.6 mmol) was added to trifluoromethanesulfonic anhydride(48.6 g, 172.4 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5 g of Compound 2-3. (Yield: 48%, MS: [M+H]⁺=542).

Compound 2-3(15 g, 27.7 mmol) and phenanthren-9-ylboronic acid_D7(6.7 g, 29.1 mmol) were added to 300 ml of THF, and the mixture was stirred and refluxed. Then, potassium carbonate(11.5 g, 83.2 mmol) was dissolved in 100 ml of water and added thereto, and the mixture was sufficiently stirred and then bis(tri-tert-butylphosphine)palladium(0) (0.1 g, 0.3 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 11.5 g of Compound 2-3-D26. (Yield: 60%, MS: [M+H]⁺=691)

### Preparation Example 2-4

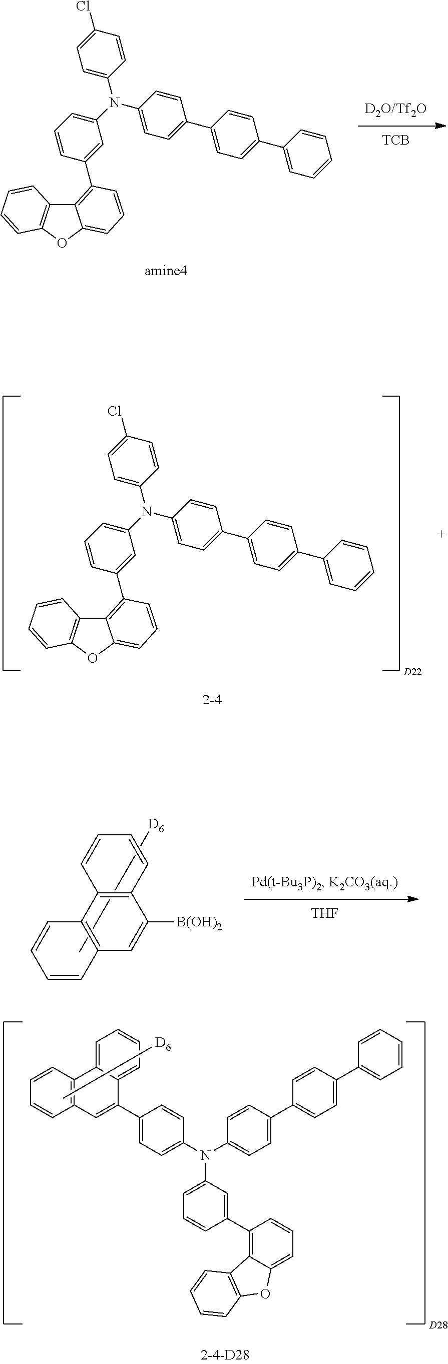

Compound amine4(10 g, 16.7 mmol) was added to 200 ml of 1,2,4-trichlorobenzene, and the mixture was stirred at room temperature. In another vessel, deuterium oxide(12.1 g, 601.9 mmol) was added to trifluoromethanesulfonic anhydride(42.5 g, 150.5 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.3 g of Compound 2-4. (Yield: 41%, MS: [M+H]⁺=621).

Compound 2-4(15 g, 24.2 mmol) and phenanthren-9-ylboronic acid_D6(5.8 g, 25.4 mol) were added to 300 ml of THF, and the mixture was stirred and refluxed. Then, potassium carbonate(10 g, 72.6 mmol) was dissolved in 100 ml of water and added thereto, and the mixture was sufficiently stirred and then bis(tri-tert-butylphosphine)palladium(0) (0.1 g, 0.2 mmol) was added. After the reaction for 4 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.9 g of Compound 2-4-D28. (Yield: 75%, MS: [M+H]⁺=769)

### Preparation Example 2-5

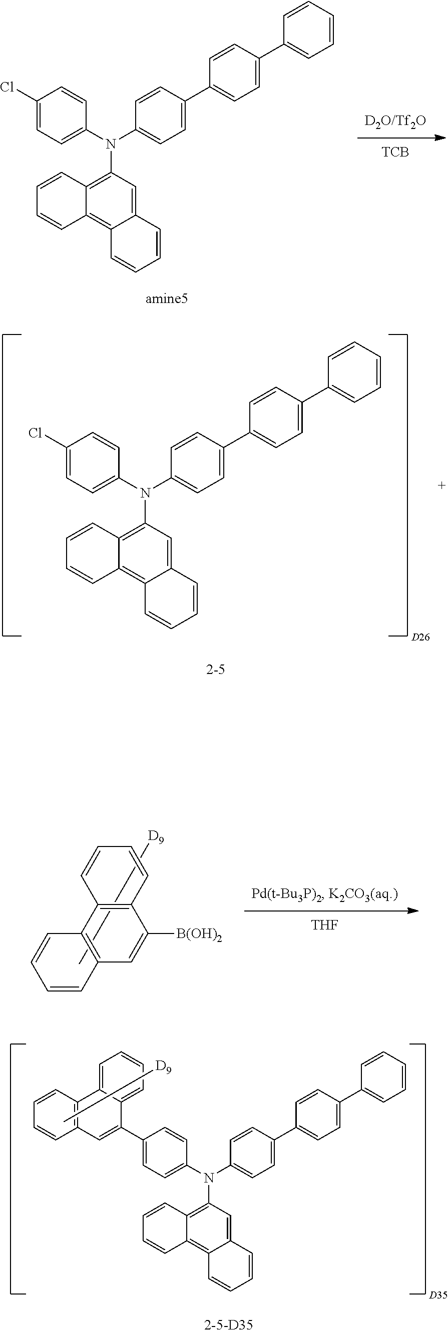

Compound amine5(10 g, 18.8 mmol) was added to 200 ml of 1,2,4-trichlorobenzene, and the mixture was stirred at room temperature. In another vessel, deuterium oxide(13.6 g, 676.6 mmol) was added to trifluoromethanesulfonic anhydride(63.6 g, 225.5 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 15 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.2 g of Compound 2-5. (Yield: 50%, MS: [M+H]⁺=559).

Compound 2-5(15 g, 26.9 mmol) and phenanthren-9-ylboronic acid_D9(6.5 g, 28.2 mmol) were added to 300 ml of THF, and the mixture was stirred and refluxed. Then, potassium carbonate(11.1 g, 80.6 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.1 g of Compound 2-5-D35. (Yield: 74%, MS: [M+H]⁺=710)

### Preparation Example 2-6

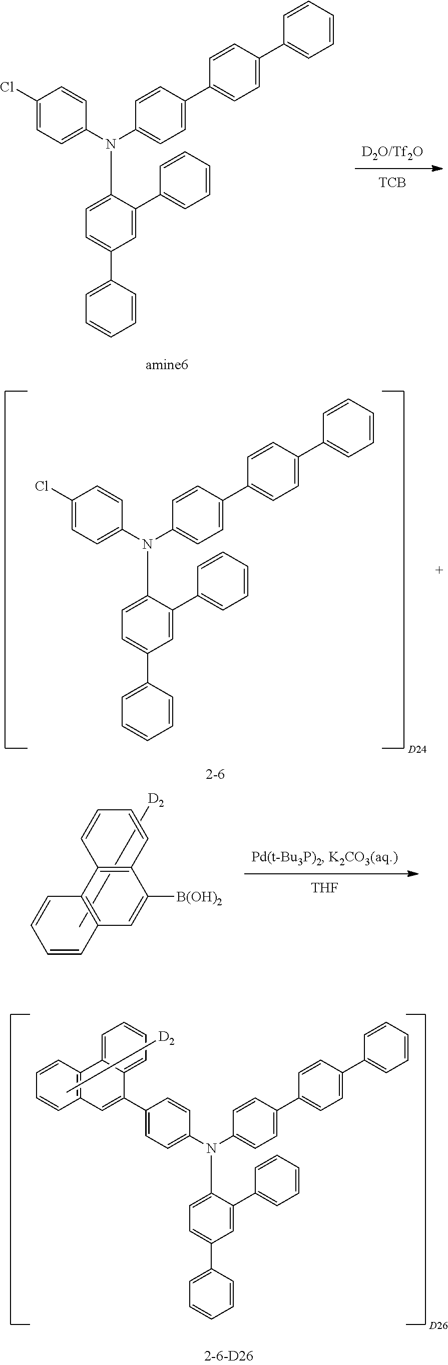

Compound amine6(10 g, 17.1 mmol) was added to 200 ml of 1,2,4-trichlorobenzene, and the mixture was stirred at room temperature. In another vessel, deuterium oxide(12.3 g, 616.3 mmol) was added to trifluoromethanesulfonic anhydride(43.5 g, 154.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.7 g of Compound 2-6. (Yield: 45%, MS: [M+H]⁺=609).

Compound 2-6(15 g, 24.7 mmol) and phenanthren-9-ylboronic acid_D2(5.8 g, 25.9 mmol) were added to 300 ml of THF, and the mixture was stirred and refluxed. Then, potassium carbonate(10.2 g, 74 mmol) was dissolved in 100 ml of water and added thereto, and the mixture was sufficiently stirred and then bis(tri-tert-butylphosphine)palladium(0) (0.1 g, 0.2 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.9 g of Compound 2-6-D26. (Yield: 75%, MS: [M+H]⁺=753)

### Preparation Example 2-7

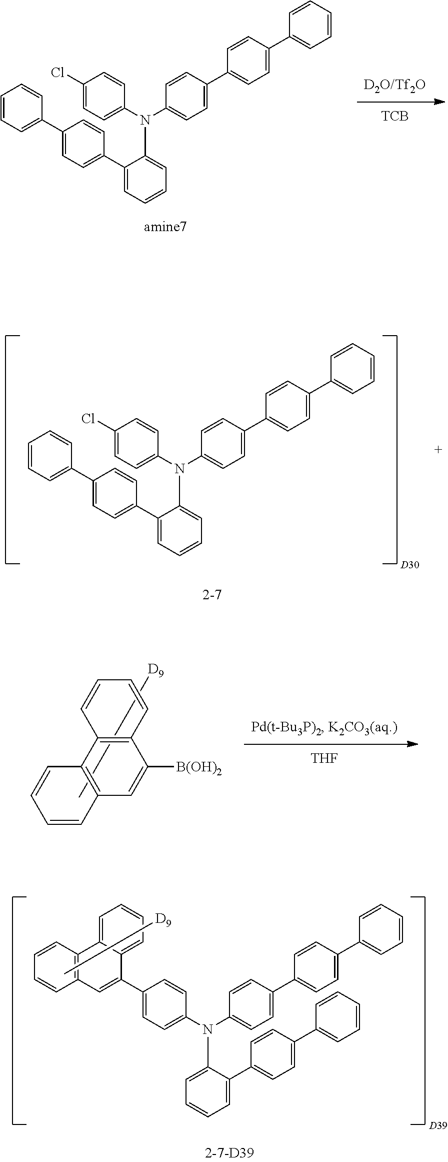

Compound amine7(10 g, 17.1 mmol) was added to 200 ml of 1,2,4-trichlorobenzene, and the mixture was stirred at room temperature. In another vessel, deuterium oxide(12.3 g, 616.3 mmol) was added to trifluoromethanesulfonic anhydride(58 g, 205.4 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 15 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.8 g of Compound 2-7. (Yield: 46%, MS: [M+H]⁺=615).

Compound 2-7(15 g, 24.4 mmol) and phenanthren-9-ylboronic acid_D9(5.9 g, 25.6 mmol) were added to 300 ml of THF, and the mixture was stirred and refluxed. Then, potassium carbonate(10.1 g, 73.3 mmol) was dissolved in 100 ml of water and added thereto, and the mixture was sufficiently stirred and then bis(tri-tert-butylphosphine)palladium(0) (0.1 g, 0.2 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 11.4 g of Compound 2-7-D39. (Yield: 61%, MS: [M+H]⁺=766)

### Preparation Example 2-8

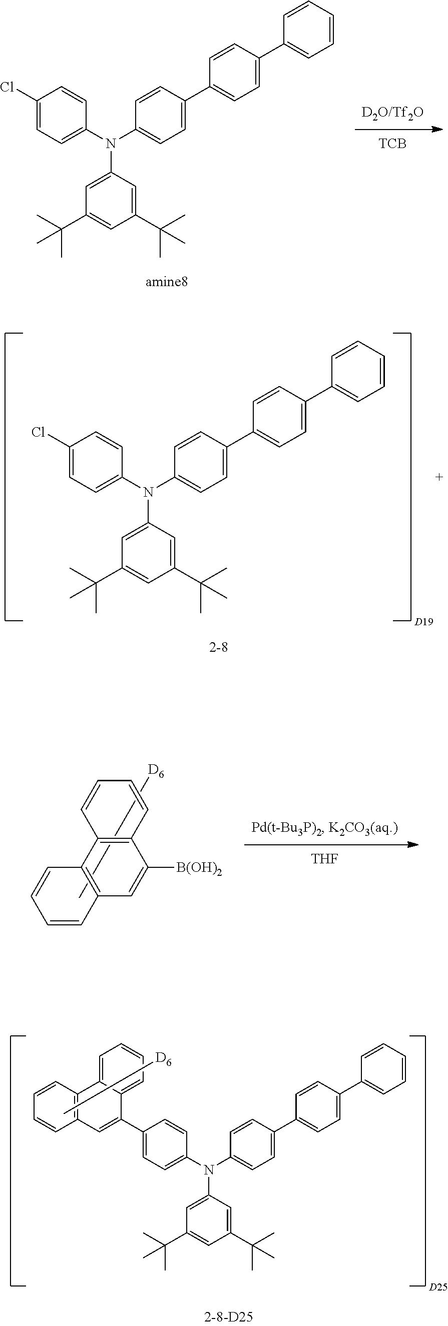

Compound amine8(10 g, 18.4 mmol) was added to 200 ml of 1,2,4-trichlorobenzene, and the mixture was stirred at room temperature. In another vessel, deuterium oxide(13.3 g, 661.5 mmol) was added to trifluoromethanesulfonic anhydride(31.1 g, 110.3 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.8 g of Compound 2-8. (Yield: 47%, MS: [M+H]⁺=563).

Compound 2-8(15 g, 26.8 mmol) and phenanthren-9-ylboronic acid_D6(6.4 g, 28.1 mmol) were added to 300 ml of THF, and the mixture was stirred and refluxed. Then, potassium carbonate(11.1 g, 80.3 mmol) was dissolved in 100 ml of water and added thereto, and the mixture was sufficiently stirred and then bis(tri-tert-butylphosphine)palladium(0) (0.1 g, 0.3 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.1 g of Compound 2-8-D25. (Yield: 69%, MS: [M+H]⁺=711)

### Preparation Example 2-9

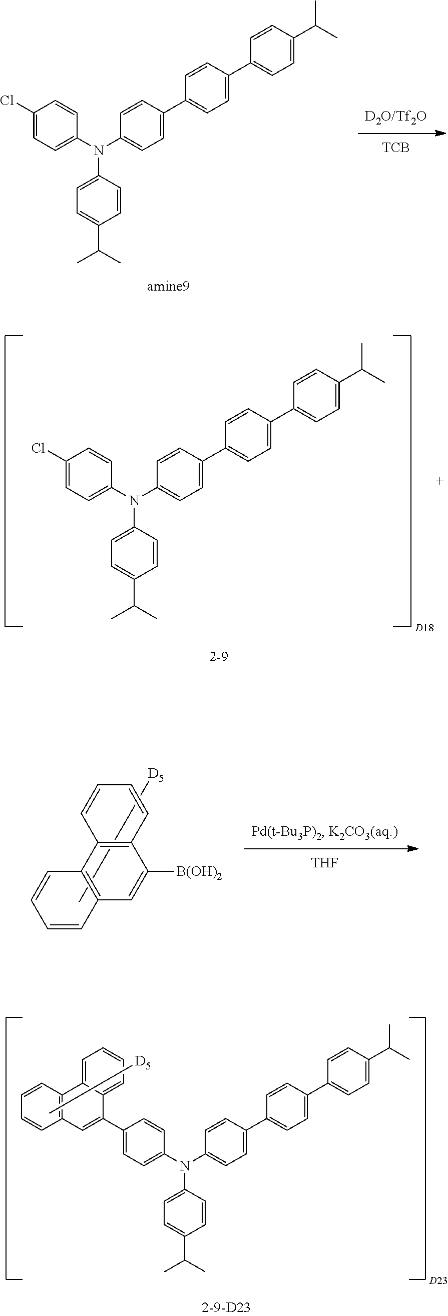

Compound amine9(10 g, 19.4 mmol) was added to 200 ml of 1,2,4-trichlorobenzene, and the mixture was stirred at room temperature. In another vessel, deuterium oxide(14 g, 697.5 mmol) was added to trifluoromethanesulfonic anhydride(32.8 g, 116.2 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.4 g of Compound 2-9. (Yield: 43%, MS: [M+H]⁺=534).

Compound 2-9(15 g, 28.3 mmol) and phenanthren-9-ylboronic acid_D5(6.7 g, 29.7 mmol) were added to 300 ml of THF, and the mixture was stirred and refluxed. Then, potassium carbonate(11.7 g, 84.9 mmol) was dissolved in 100 ml of water and added thereto, and the mixture was sufficiently stirred and then bis(tri-tert-butylphosphine)palladium(0) (0.1 g, 0.3 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 15.3 g of Compound 2-9-D23. (Yield: 80%, MS: [M+H]⁺=681)

### Preparation Example 2-10

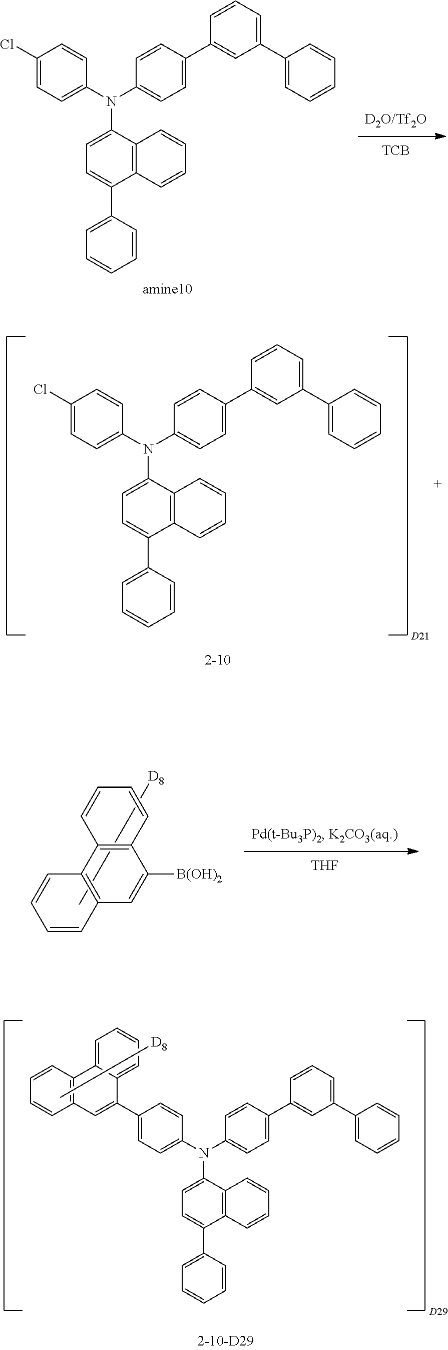

Compound amine10(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(45.5 g, 161.3 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.4 g of Compound 2-10. (Yield: 42%, MS: [M+H]⁺=580).

Compound 2-10(15 g, 25.9 mmol) and phenanthren-9-ylboronic acid_D8(6.3 g, 27.2 mmol) were added to 300 ml of THF, and the mixture was stirred and refluxed. Then, potassium carbonate(10.7 g, 77.7 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12.6 g of Compound 2-10-D29. (Yield: 67%, MS: [M+H]⁺=730)

### Preparation Example 2-11

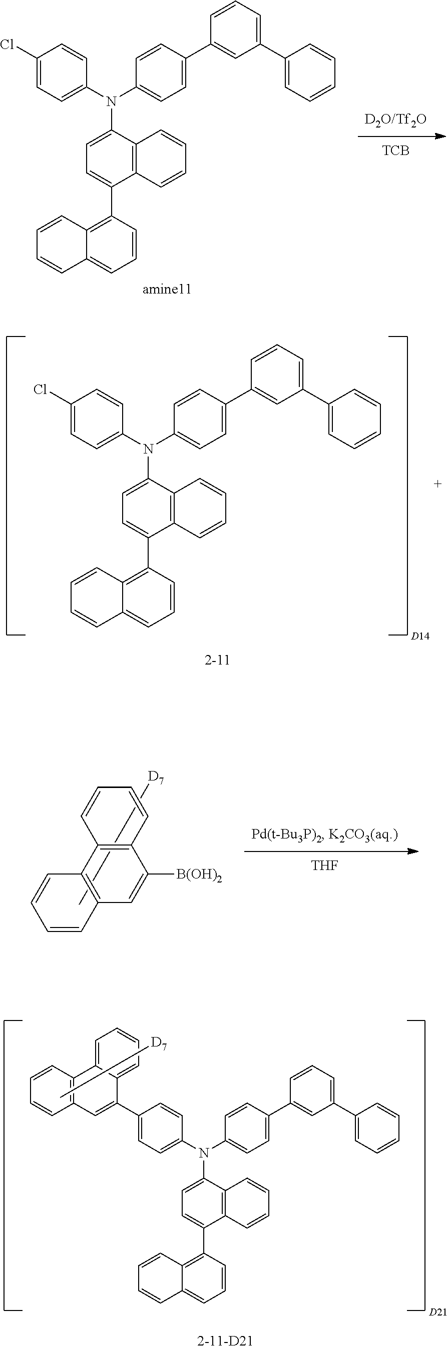

Compound amine11(10 g, 16.4 mmol) was added to 200 ml of 1,2,4-trichlorobenzene, and the mixture was stirred at room temperature. In another vessel, deuterium oxide(11.9 g, 591.9 mmol) was added to trifluoromethanesulfonic anhydride(27.8 g, 98.7 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.9 g of Compound 2-11. (Yield: 48%, MS: [M+H]⁺=623).

Compound 2-11(15 g, 24.1 mmol) and phenanthren-9-ylboronic acid_D7(5.8 g, 25.3 mmol) were added to 300 ml of THF, and the mixture was stirred and refluxed. Then, potassium carbonate(10 g, 72.3 mmol) was dissolved in 100 ml of water and added thereto, and the mixture was sufficiently stirred and then bis(tri-tert-butylphosphine)palladium(0) (0.1 g, 0.2 mmol) was added. After the reaction for 4 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 11.5 g of Compound 2-11-D21. (Yield: 62%, MS: [M+H]⁺=772)

### Preparation Example 2-12

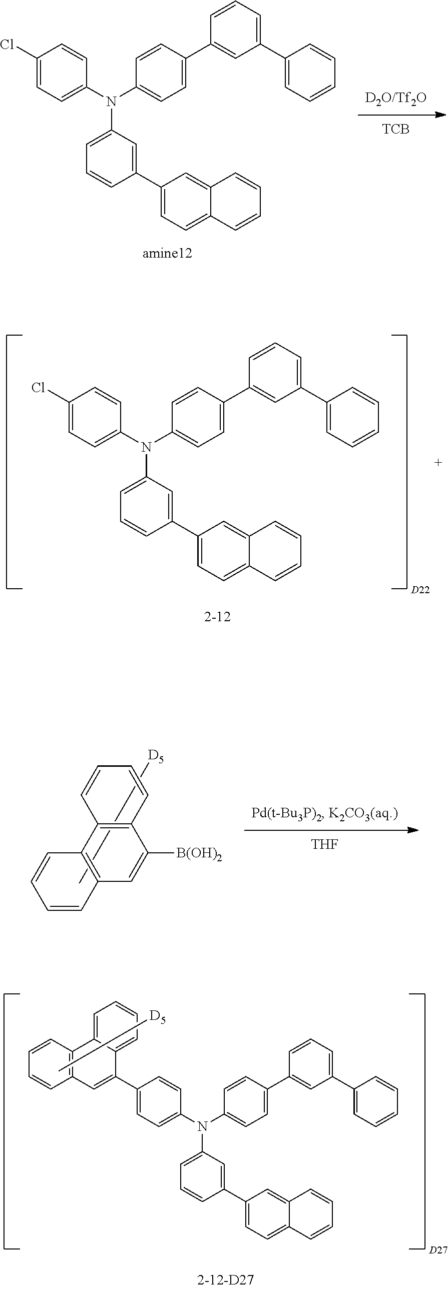

Compound amine12(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(45.5 g, 161.3 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.1 g of Compound 2-12. (Yield: 49%, MS: [M+H]⁺=581).

Compound 2-12(15 g, 25.9 mmol) and phenanthren-9-ylboronic acid_D5(6.2 g, 27.1 mmol) were added to 300 ml of THF, and the mixture was stirred and refluxed. Then, potassium carbonate(10.7 g, 77.6 mmol) was dissolved in 100 ml of water and added thereto, and the mixture was sufficiently stirred and then bis(tri-tert-butylphosphine)palladium(0) (0.1 g, 0.3 mmol) was added. After the reaction for 4 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 11.5 g of Compound 2-12-D27. (Yield: 61%, MS: [M+H]⁺=728)

### Preparation Example 2-13

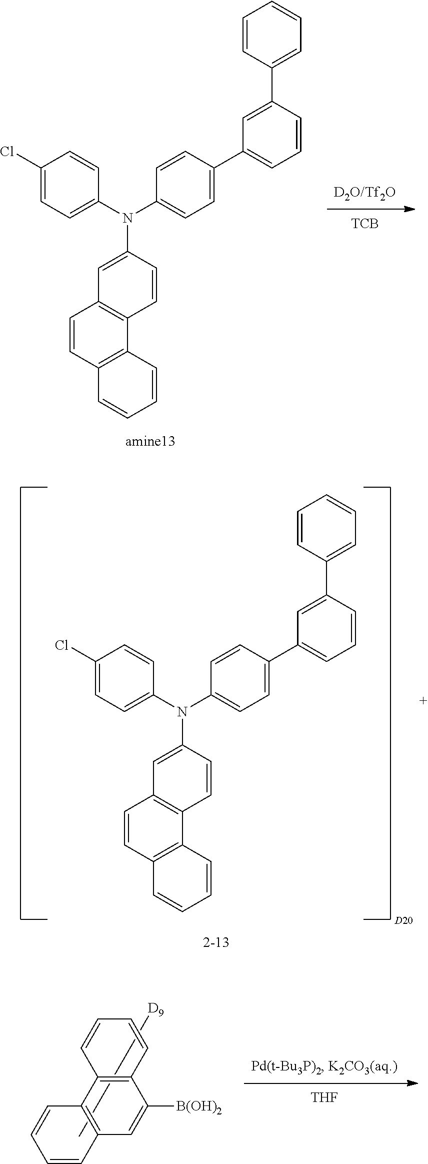

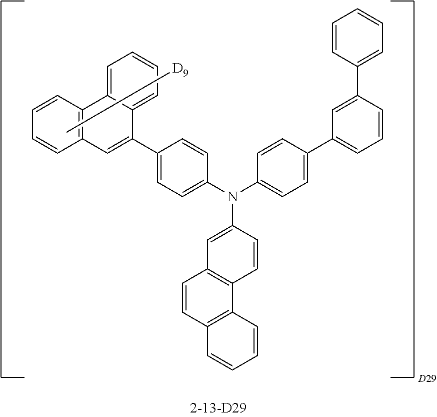

Compound amine13(10 g, 18.8 mmol) was added to 200 ml of 1,2,4-trichlorobenzene, and the mixture was stirred at room temperature. In another vessel, deuterium oxide(13.6 g, 676.6 mmol) was added to trifluoromethanesulfonic anhydride(47.7 g, 169.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.1 g of Compound 2-13. (Yield: 49%, MS: [M+H]⁺=553).

Compound 2-13(15 g, 27.2 mmol) and phenanthren-9-ylboronic acid_D9(6.6 g, 28.5 mmol) were added to 300 ml of THF, and the mixture was stirred and refluxed. Then, potassium carbonate(11.3 g, 81.5 mmol) was dissolved in 100 ml of water and added thereto, and the mixture was sufficiently stirred and then bis(tri-tert-butylphosphine)palladium(0) (0.1 g, 0.3 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 15.1 g of Compound 2-13-D29. (Yield: 79%, MS: [M+H]⁺=704)

### Preparation Example 2-14

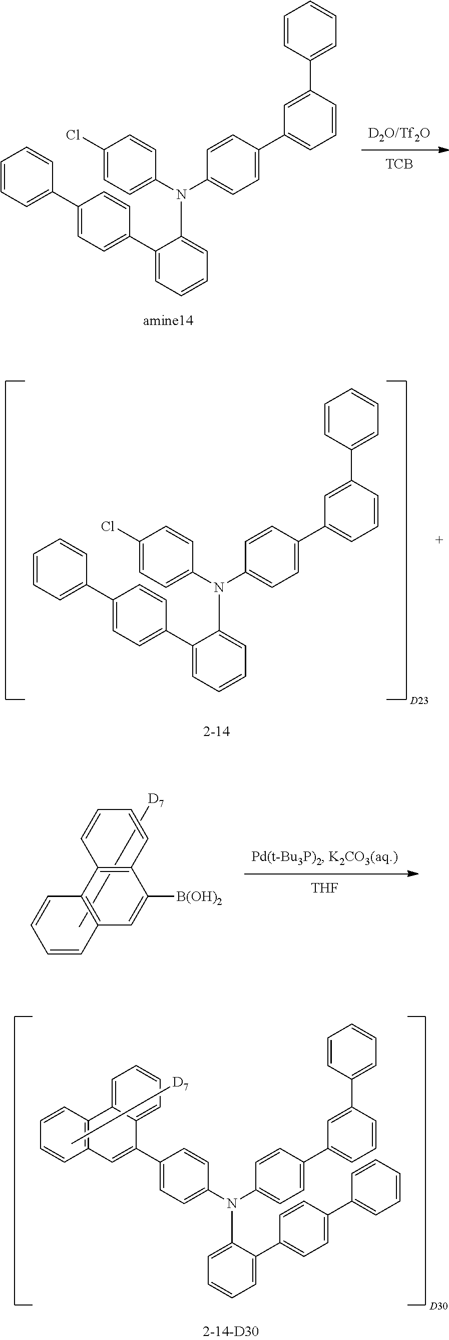

Compound amine14(10 g, 17.1 mmol) was added to 200 ml of 1,2,4-trichlorobenzene, and the mixture was stirred at room temperature. In another vessel, deuterium oxide(12.3 g, 616.3 mmol) was added to trifluoromethanesulfonic anhydride(43.5 g, 154.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.5 g of Compound 2-14. (Yield: 43%, MS: [M+H]⁺=608).

Compound 2-14(15 g, 24.7 mmol) and phenanthren-9-ylboronic acid_D7(5.9 g, 25.9 mmol) were added to 300 ml of THF, and the mixture was stirred and refluxed. Then, potassium carbonate(10.2 g, 74.1 mmol) was dissolved in 100 ml of water and added thereto, and the mixture was sufficiently stirred and then bis(tri-tert-butylphosphine)palladium(0) (0.1 g, 0.2 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12 g of Compound 2-14-D30. (Yield: 64%, MS: [M+H]⁺=757)

### Preparation Example 2-15

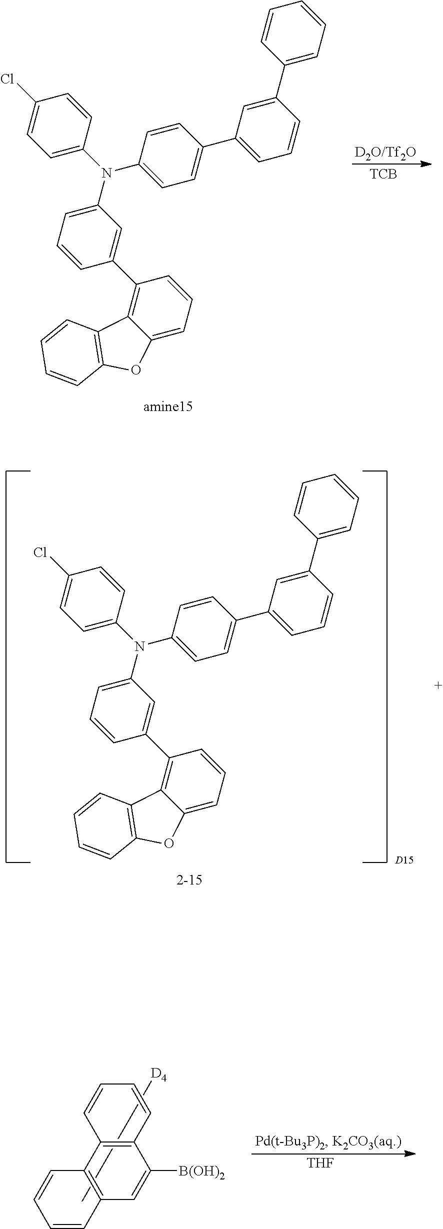

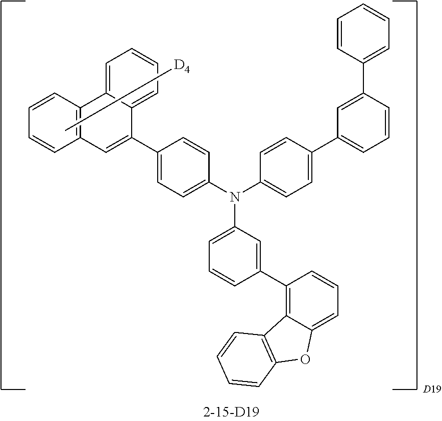

Compound amine15(10 g, 16.7 mmol) was added to 200 ml of 1,2,4-trichlorobenzene, and the mixture was stirred at room temperature. In another vessel, deuterium oxide(12.1 g, 601.9 mmol) was added to trifluoromethanesulfonic anhydride(28.3 g, 100.3 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.4 g of Compound 2-15. (Yield: 43%, MS: [M+H]⁺=614).

Compound 2-15(15 g, 24.5 mmol) and phenanthren-9-ylboronic acid_D4(5.8 g, 25.7 mmol) were added to 300 ml of THF, and the mixture was stirred and refluxed. Then, potassium carbonate(10.1 g, 73.4 mmol) was dissolved in 100 ml of water and added thereto, and the mixture was sufficiently stirred and then bis(tri-tert-butylphosphine)palladium(0) (0.1 g, 0.2 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.7 g of Compound 2-15-D19. (Yield: 74%, MS: [M+H]⁺=760)

### Preparation Example 2-16

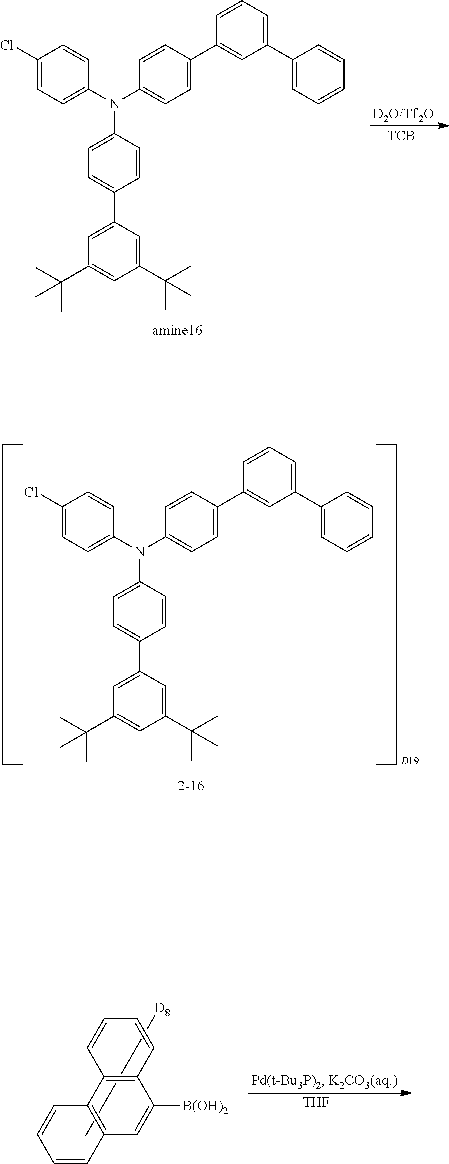

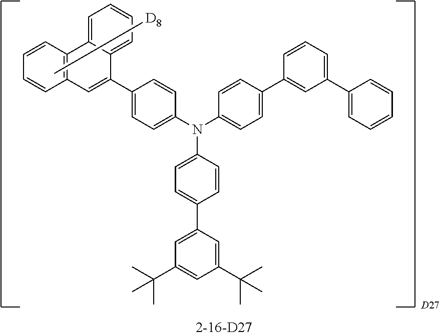

Compound amine16(10 g, 16.1 mmol) was added to 200 ml of 1,2,4-trichlorobenzene, and the mixture was stirred at room temperature. In another vessel, deuterium oxide(11.6 g, 580.4 mmol) was added to trifluoromethanesulfonic anhydride(27.3 g, 96.7 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5 g of Compound 2-16. (Yield: 49%, MS: [M+H]⁺=639).

Compound 2-16(15 g, 23.5 mmol) and phenanthren-9-ylboronic acid_D8(5.7 g, 24.7 mmol) were added to 300 ml of THF, and the mixture was stirred and refluxed. Then, potassium carbonate(9.8 g, 70.6 mmol) was dissolved in 100 ml of water and added thereto, and the mixture was sufficiently stirred and then bis(tri-tert-butylphosphine)palladium(0) (0.1 g, 0.2 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 11.5 g of Compound 2-16-D27. (Yield: 62%, MS: [M+H]⁺=789)

### Preparation Example 2-17

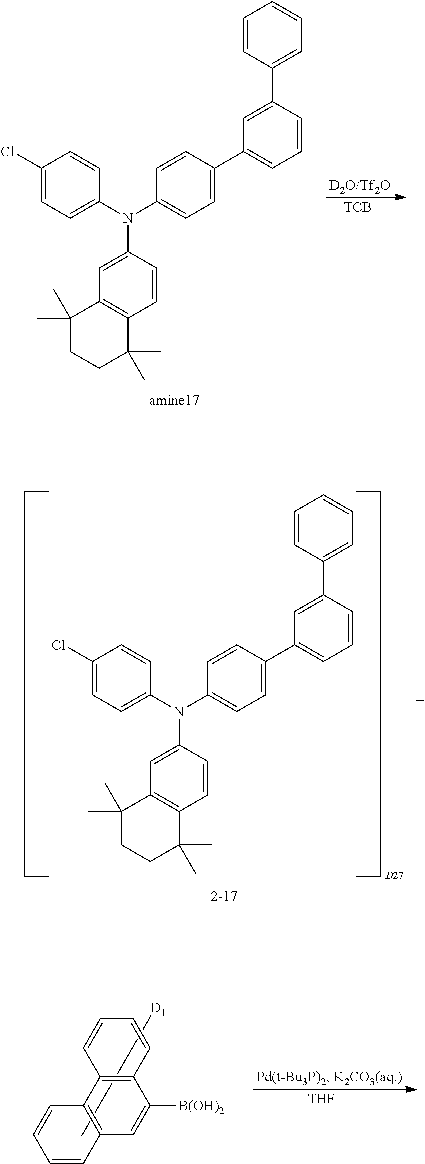

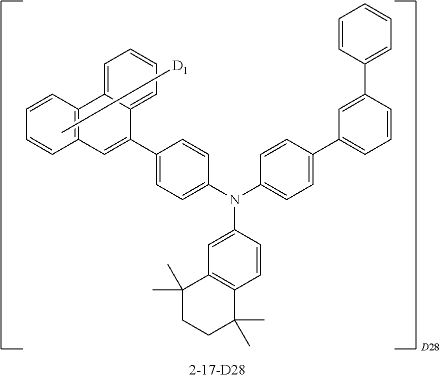

Compound amine17(10 g, 18.4 mmol) was added to 200 ml of 1,2,4-trichlorobenzene, and the mixture was stirred at room temperature. In another vessel, deuterium oxide(13.3 g, 664 mmol) was added to trifluoromethanesulfonic anhydride(46.8 g, 166 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.1 g of Compound 2-17. (Yield: 49%, MS: [M+H]⁺=570).

Compound 2-17(15 g, 26.4 mmol) and phenanthren-9-ylboronic acid_D1(6.2 g, 27.7 mmol) were added to 300 ml of THF, and the mixture was stirred and refluxed. Then, potassium carbonate(10.9 g, 79.1 mmol) was dissolved in 100 ml of water and added thereto, and the mixture was sufficiently stirred and then bis(tri-tert-butylphosphine)palladium(0) (0.1 g, 0.3 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.1 g of Compound 2-17-D28. (Yield: 75%, MS: [M+H]⁺=713)

### Preparation Example 2-18

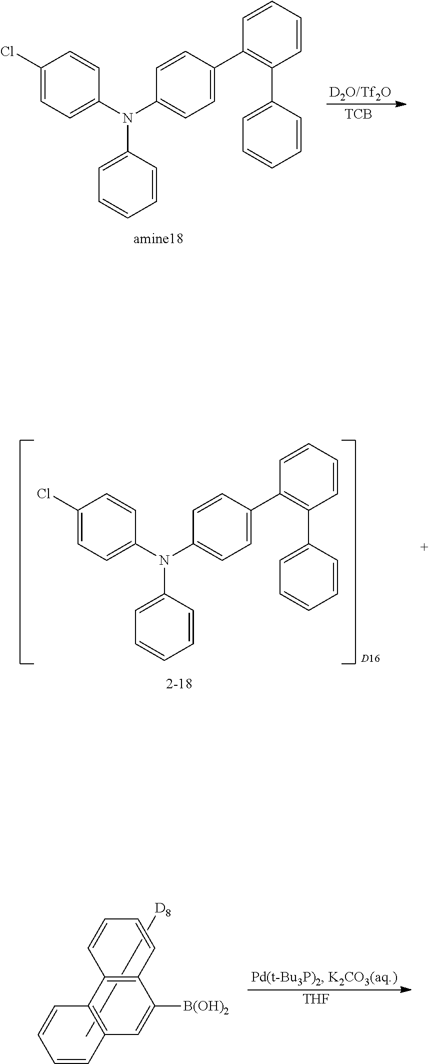

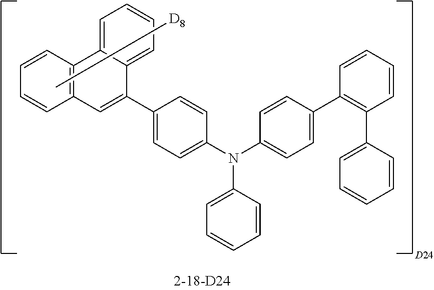

Compound amine18(10 g, 23.2 mmol) was added to 200 ml of 1,2,4-trichlorobenzene, and the mixture was stirred at room temperature. In another vessel, deuterium oxide(16.7 g, 833.4 mmol) was added to trifluoromethanesulfonic anhydride(58.8 g, 208.4 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.3 g of Compound 2-18. (Yield: 41%, MS: [M+H]⁺=449).

Compound 2-18(15 g, 33.5 mmol) and phenanthren-9-ylboronic acid_D8(8.1 g, 35.2 mmol) were added to 300 ml of THF, and the mixture was stirred and refluxed. Then, potassium carbonate(13.9 g, 100.5 mmol) was dissolved in 100 ml of water and added thereto, and the mixture was sufficiently stirred and then bis(tri-tert-butylphosphine)palladium(0) (0.2 g, 0.3 mmol) was added. After the reaction for 4 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 15.8 g of Compound 2-18-D24. (Yield: 79%, MS: [M+H]⁺=599)

### Preparation Example 2-19

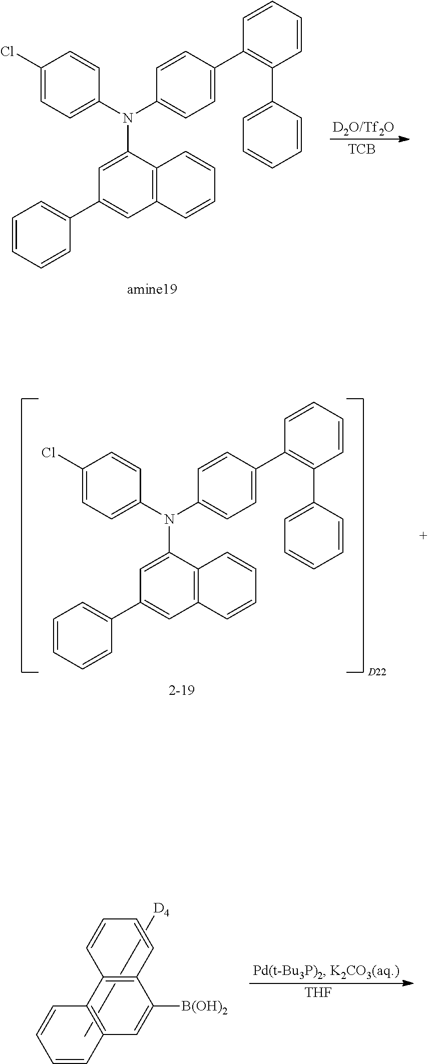

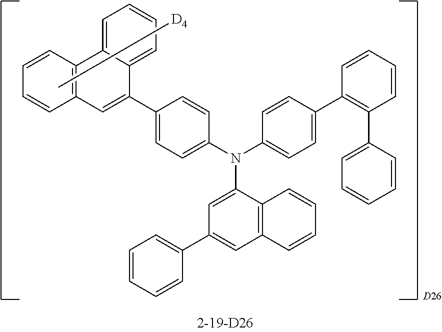

Compound amine19(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(45.5 g, 161.3 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.3 g of Compound 2-19. (Yield: 41%, MS: [M+H]⁺=584).

Compound 2-19(15 g, 25.9 mmol) and phenanthren-9-ylboronic acid_D4(6.1 g, 27.1 mmol) were added to 300 ml of THF, and the mixture was stirred and refluxed. Then, potassium carbonate(10.7 g, 77.6 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12.2 g of Compound 2-19-D26. (Yield: 65%, MS: [M+H]⁺=727)

### Preparation Example 2-20

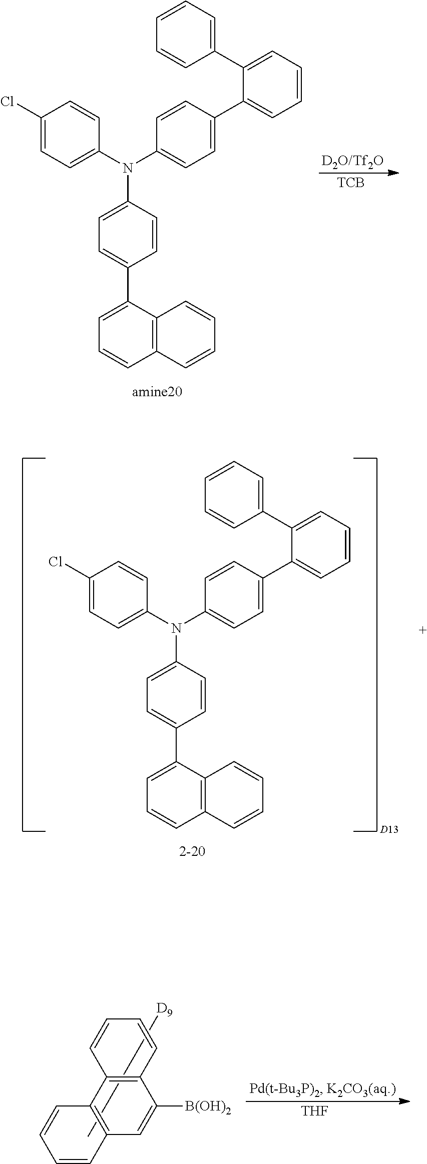

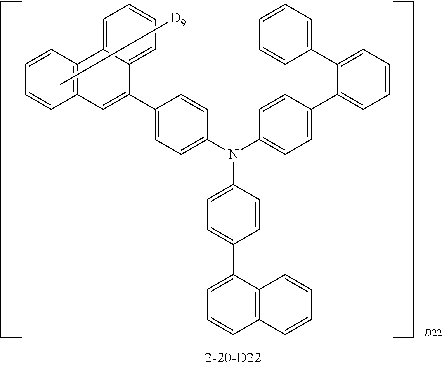

Compound amine20(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(30.3 g, 107.5 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.9 g of Compound 2-20. (Yield: 48%, MS: [M+H]⁺=572).

Compound 2-20(15 g, 26.3 mmol) and phenanthren-9-ylboronic acid_D9(6.4 g, 27.6 mmol) were added to 300 ml of THF, and the mixture was stirred and refluxed. Then, potassium carbonate(10.9 g, 78.8 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.7 g of Compound 2-20-D22. (Yield: 72%, MS: [M+H]⁺=723)

### Preparation Example 2-21

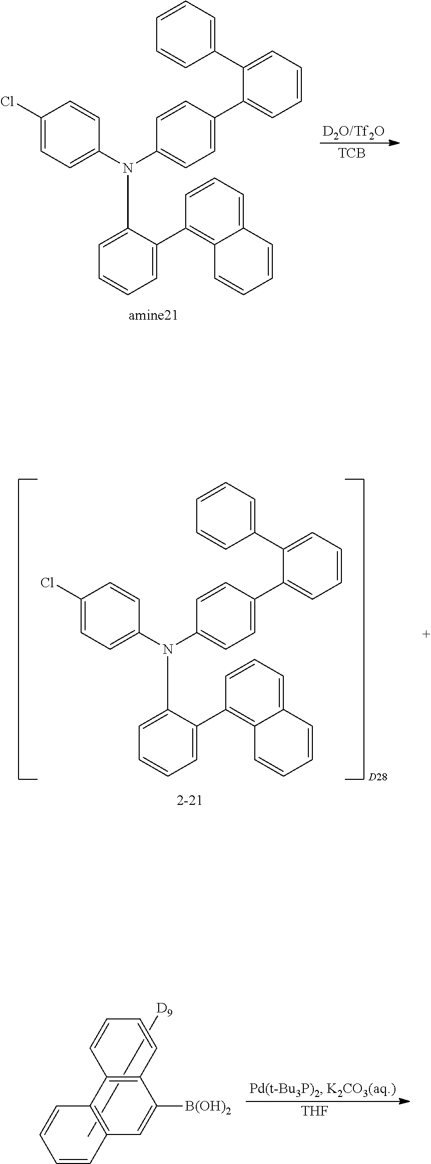

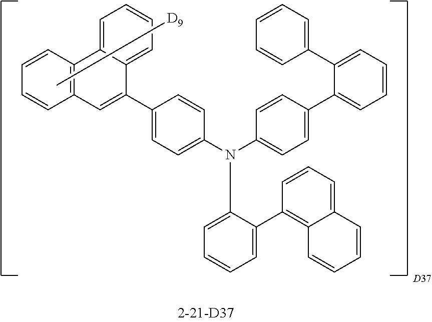

Compound amine21(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(60.7 g, 215 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 15 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.3 g of Compound 2-21. (Yield: 50%, MS: [M+H]⁺=587).

Compound 2-21(15 g, 25.6 mmol) and phenanthren-9-ylboronic acid_D9(6.2 g, 26.9 mmol) were added to 300 ml of THF, and the mixture was stirred and refluxed. Then, potassium carbonate(10.6 g, 76.8 mmol) was dissolved in 100 ml of water and added thereto, and the mixture was sufficiently stirred and then bis(tri-tert-butylphosphine)palladium(0) (0.1 g, 0.3 mmol) was added. After the reaction for 4 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.2 g of Compound 2-21-D37. (Yield: 70%, MS: [M+H]⁺=738)

### Preparation Example 2-22

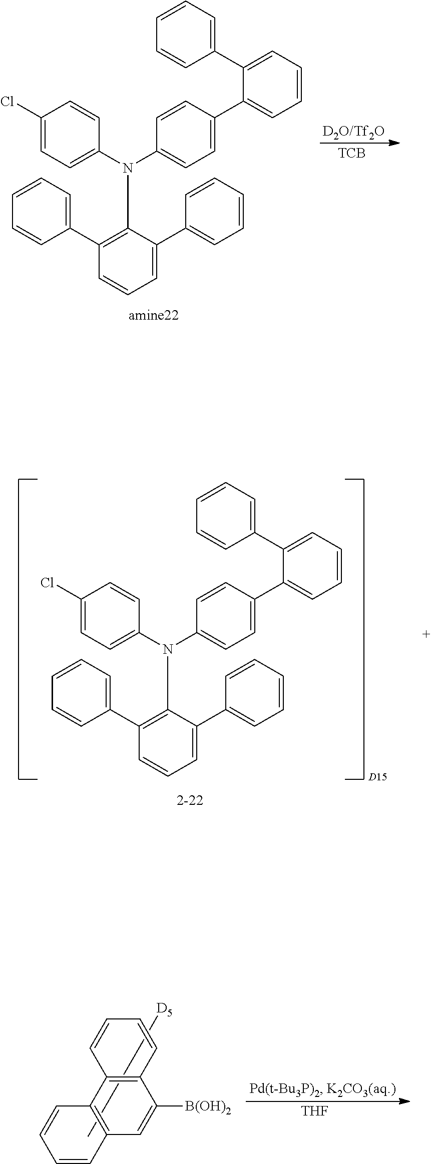

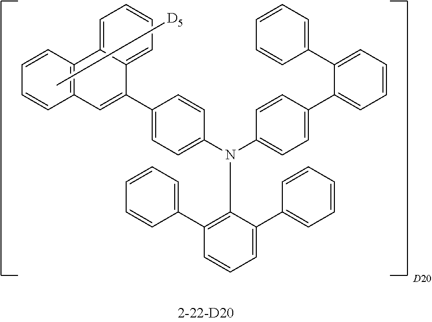

Compound amine22(10 g, 17.1 mmol) was added to 200 ml of 1,2,4-trichlorobenzene, and the mixture was stirred at room temperature. In another vessel, deuterium oxide(12.3 g, 616.3 mmol) was added to trifluoromethanesulfonic anhydride(29 g, 102.7 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.2 g of Compound 2-22. (Yield: 41%, MS: [M+H]⁺=600).

Compound 2-22(15 g, 25 mmol) and phenanthren-9-ylboronic acid_D5(6 g, 26.3 mmol) were added to 300 ml of THF, and the mixture was stirred and refluxed. Then, potassium carbonate(10.4 g, 75.1 mmol) was dissolved in 100 ml of water and added thereto, and the mixture was sufficiently stirred and then bis(tri-tert-butylphosphine)palladium(0) (0.1 g, 0.3 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.3 g of Compound 2-22-D20. (Yield: 71%, MS: [M+H]⁺=747)

### Preparation Example 2-23

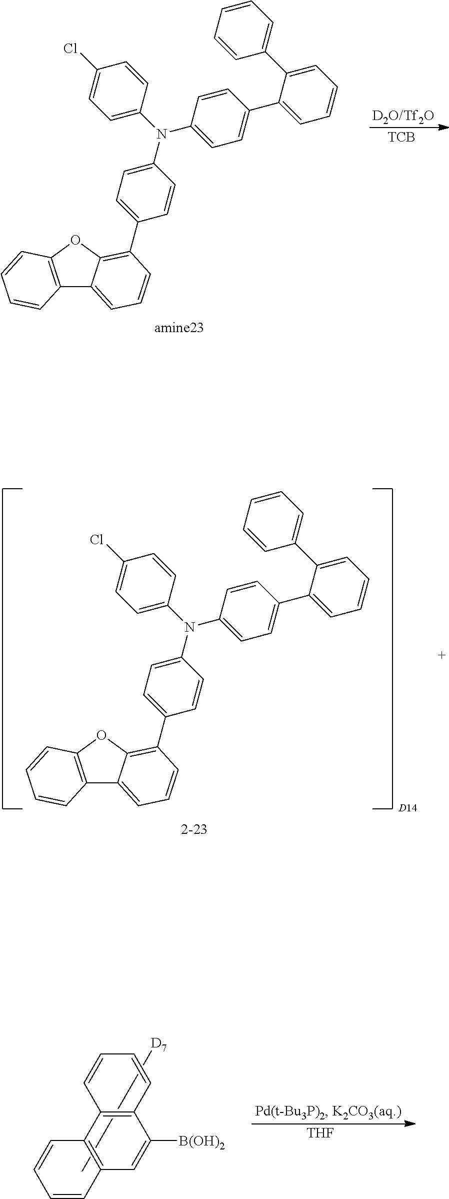

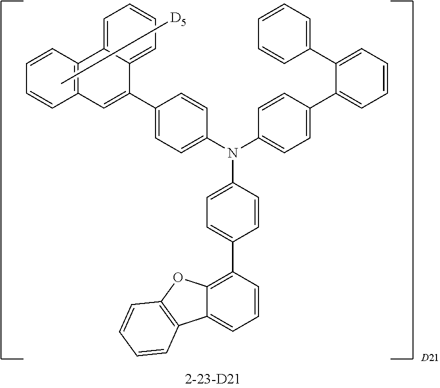

Compound amine23(10 g, 16.7 mmol) was added to 200 ml of 1,2,4-trichlorobenzene, and the mixture was stirred at room temperature. In another vessel, deuterium oxide(12.1 g, 601.9 mmol) was added to trifluoromethanesulfonic anhydride(28.3 g, 100.3 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.1 g of Compound 2-23. (Yield: 50%, MS: [M+H]⁺=613).

Compound 2-23(15 g, 24.5 mmol) and phenanthren-9-ylboronic acid_D7(5.9 g, 25.7 mmol) were added to 300 ml of THF, and the mixture was stirred and refluxed. Then, potassium carbonate(10.2 g, 73.5 mmol) was dissolved in 100 ml of water and added thereto, and the mixture was sufficiently stirred and then bis(tri-tert-butylphosphine)palladium(0) (0.1 g, 0.2 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12.5 g of Compound 2-23-D21. (Yield: 67%, MS: [M+H]⁺=762)

### Preparation Example 2-24

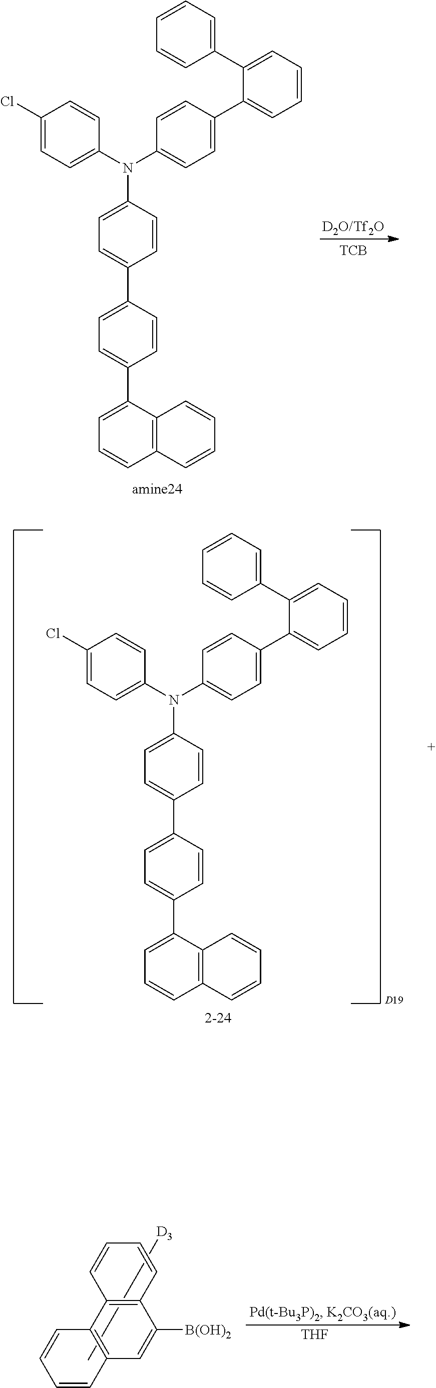

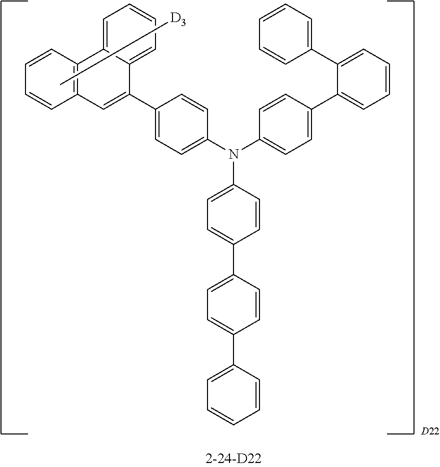

Compound amine24(10 g, 17.1 mmol) was added to 200 ml of 1,2,4-trichlorobenzene, and the mixture was stirred at room temperature. In another vessel, deuterium oxide(12.3 g, 616.3 mmol) was added to trifluoromethanesulfonic anhydride(43.5 g, 154.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5 g of Compound 2-24. (Yield: 48%, MS: [M+H]⁺=604).

Compound 2-24(15 g, 24.9 mmol) and phenanthren-9-ylboronic acid_D3(5.9 g, 26.1 mmol) were added to 300 ml of THF, and the mixture was stirred and refluxed. Then, potassium carbonate(10.3 g, 74.6 mmol) was dissolved in 100 ml of water and added thereto, and the mixture was sufficiently stirred and then bis(tri-tert-butylphosphine)palladium(0) (0.1 g, 0.2 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12.3 g of Compound 2-24-D22. (Yield: 66%, MS: [M+H]⁺=749)

### Preparation Example 2-25

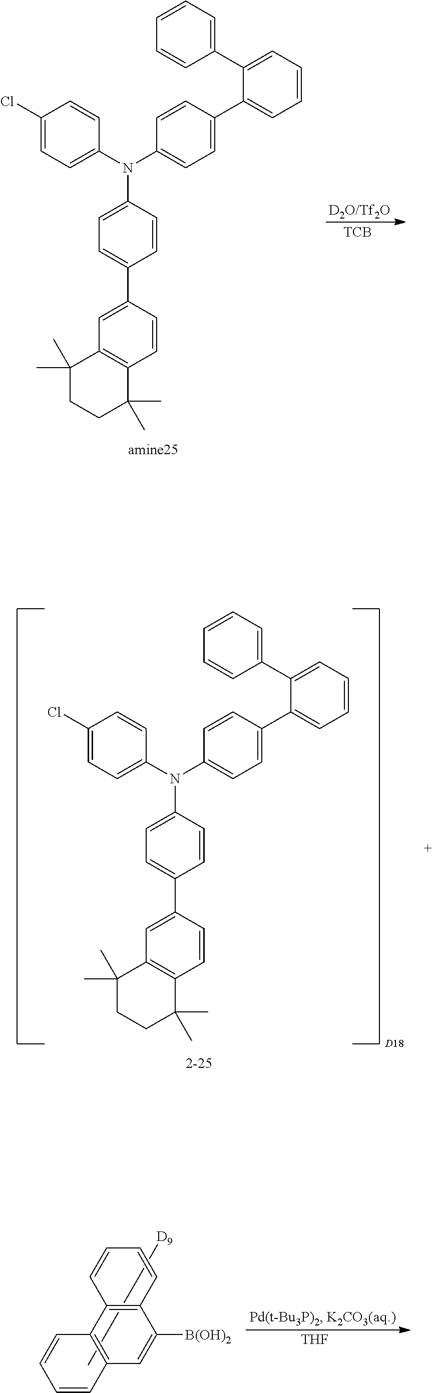

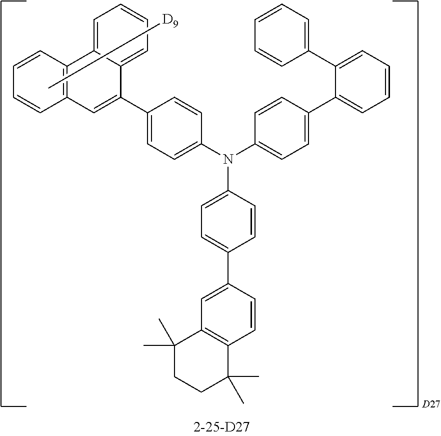

Compound amine25(10 g, 16.2 mmol) was added to 200 ml of 1,2,4-trichlorobenzene, and the mixture was stirred at room temperature. In another vessel, deuterium oxide(11.7 g, 582.3 mmol) was added to trifluoromethanesulfonic anhydride(27.4 g, 97 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5 g of Compound 2-25. (Yield: 49%, MS: [M+H]⁺=637).

Compound 2-25(15 g, 23.6 mmol) and phenanthren-9-ylboronic acid_D9(5.7 g, 24.8 mmol) were added to 300 ml of THF, and the mixture was stirred and refluxed. Then, potassium carbonate(9.8 g, 70.7 mmol) was dissolved in 100 ml of water and added thereto, and the mixture was sufficiently stirred and then bis(tri-tert-butylphosphine)palladium(0) (0.1 g, 0.2 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12.1 g of Compound 2-25-D27. (Yield: 65%, MS: [M+H]⁺=788)

### Preparation Example 2-26

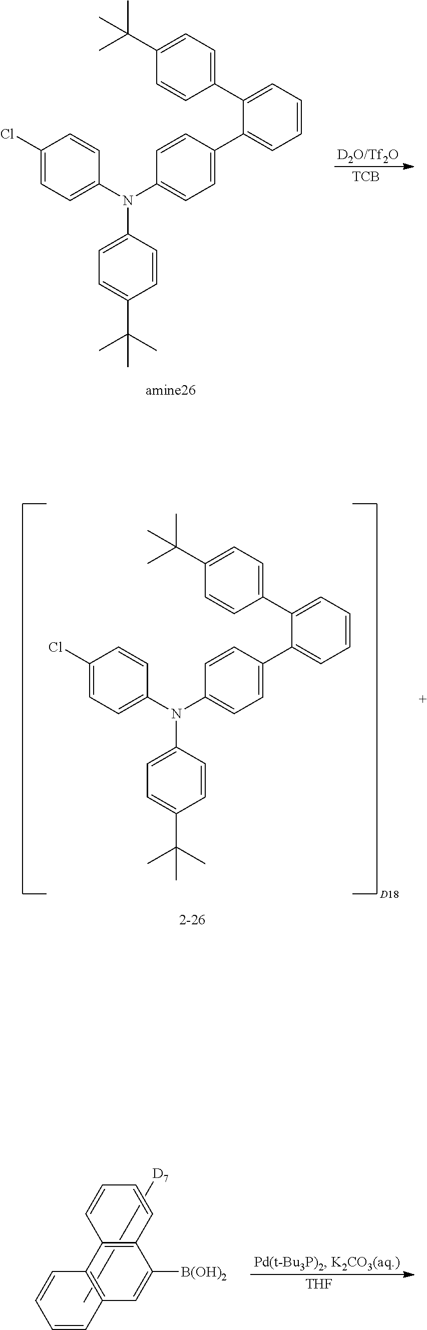

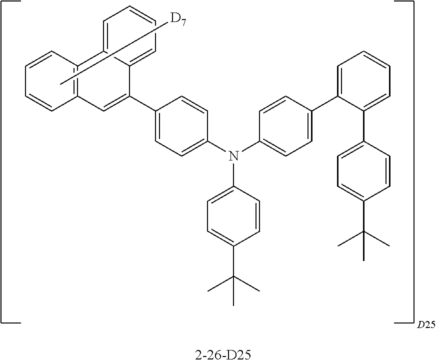

Compound amine26(10 g, 18.4 mmol) was added to 200 ml of 1,2,4-trichlorobenzene, and the mixture was stirred at room temperature. In another vessel, deuterium oxide(13.3 g, 661.5 mmol) was added to trifluoromethanesulfonic anhydride(31.1 g, 110.3 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.4 g of Compound 2-26. (Yield: 43%, MS: [M+H]⁺=563).

Compound 2-26(15 g, 26.7 mmol) and phenanthren-9-ylboronic acid_D7(6.4 g, 28 mmol) were added to 300 ml of THF, and the mixture was stirred and refluxed. Then, potassium carbonate(11.1 g, 80 mmol) was dissolved in 100 ml of water and added thereto, and the mixture was sufficiently stirred and then bis(tri-tert-butylphosphine)palladium(0) (0.1 g, 0.3 mmol) was added. After the reaction for 4 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12 g of Compound 2-26-D25. (Yield: 63%, MS: [M+H]⁺=712)

### Preparation Example 2-27

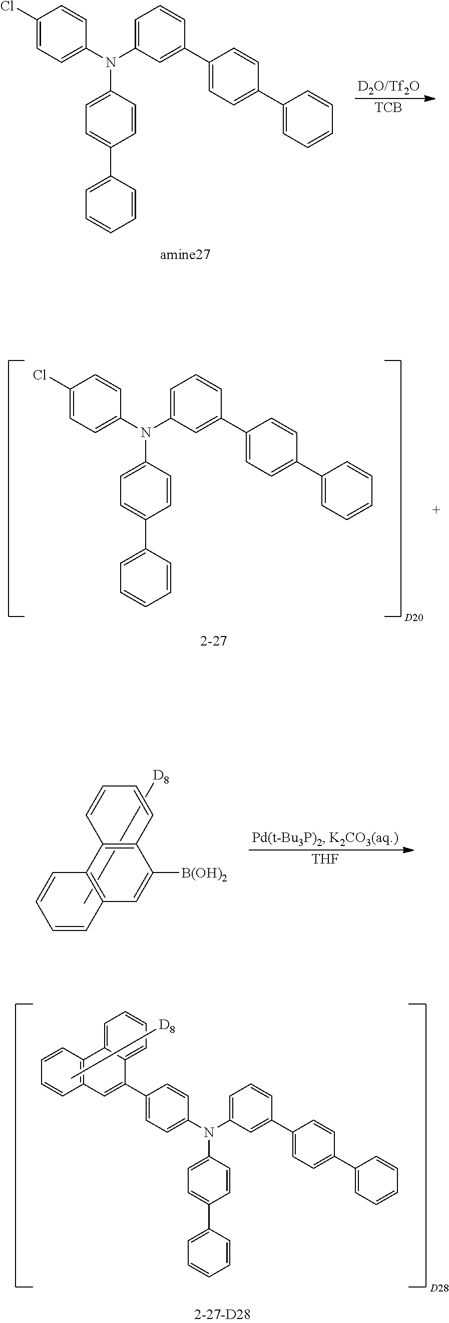

Compound amine27(10 g, 19.7 mmol) was added to 200 ml of 1,2,4-trichlorobenzene, and the mixture was stirred at room temperature. In another vessel, deuterium oxide(14.2 g, 708.6 mmol) was added to trifluoromethanesulfonic anhydride(50 g, 177.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5 g of Compound 2-27. (Yield: 48%, MS: [M+H]⁺=529).

Compound 2-27(15 g, 28.4 mmol) and phenanthren-9-ylboronic acid_D8(6.9 g, 29.8 mmol) were added to 300 ml of THF, and the mixture was stirred and refluxed. Then, potassium carbonate(11.8 g, 85.2 mmol) was dissolved in 100 ml of water and added thereto, and the mixture was sufficiently stirred and then bis(tri-tert-butylphosphine)palladium(0) (0.1 g, 0.3 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12.1 g of Compound 2-27-D28. (Yield: 63%, MS: [M+H]⁺=679)

### Preparation Example 2-28

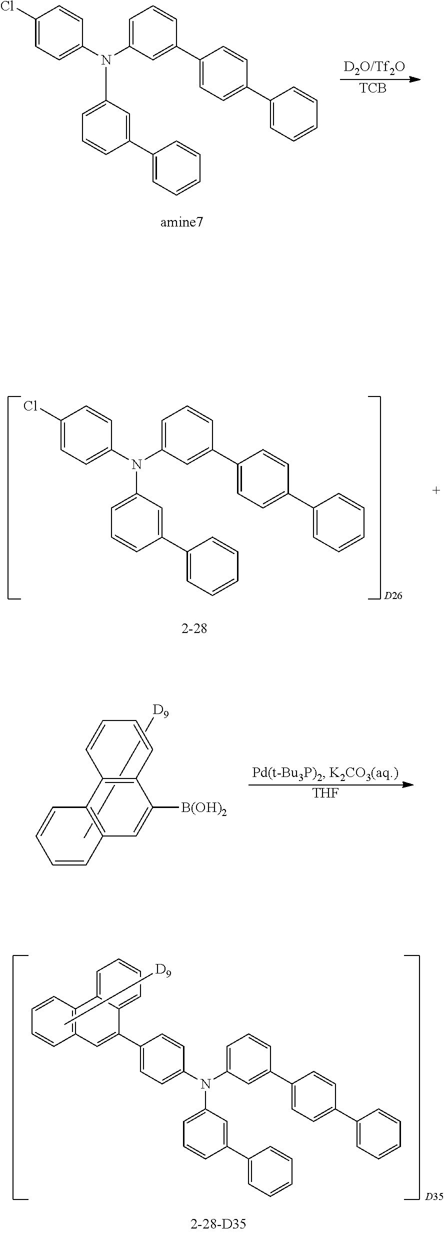

Compound amine28(10 g, 19.7 mmol) was added to 200 ml of 1,2,4-trichlorobenzene, and the mixture was stirred at room temperature. In another vessel, deuterium oxide(14.2 g, 708.6 mmol) was added to trifluoromethanesulfonic anhydride(66.6 g, 236.2 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 15 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.2 g of Compound 2-28. (Yield: 49%, MS: [M+H]⁺=535).

Compound 2-28(15 g, 28.1 mmol) and phenanthren-9-ylboronic acid_D9(6.8 g, 29.5 mmol) were added to 300 ml of THF, and the mixture was stirred and refluxed. Then, potassium carbonate(11.6 g, 84.3 mmol) was dissolved in 100 ml of water and added thereto, and the mixture was sufficiently stirred and then bis(tri-tert-butylphosphine)palladium(0) (0.1 g, 0.3 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12.5 g of Compound 2-28-D35. (Yield: 65%, MS: [M+H]⁺=686)

### Preparation Example 2-29

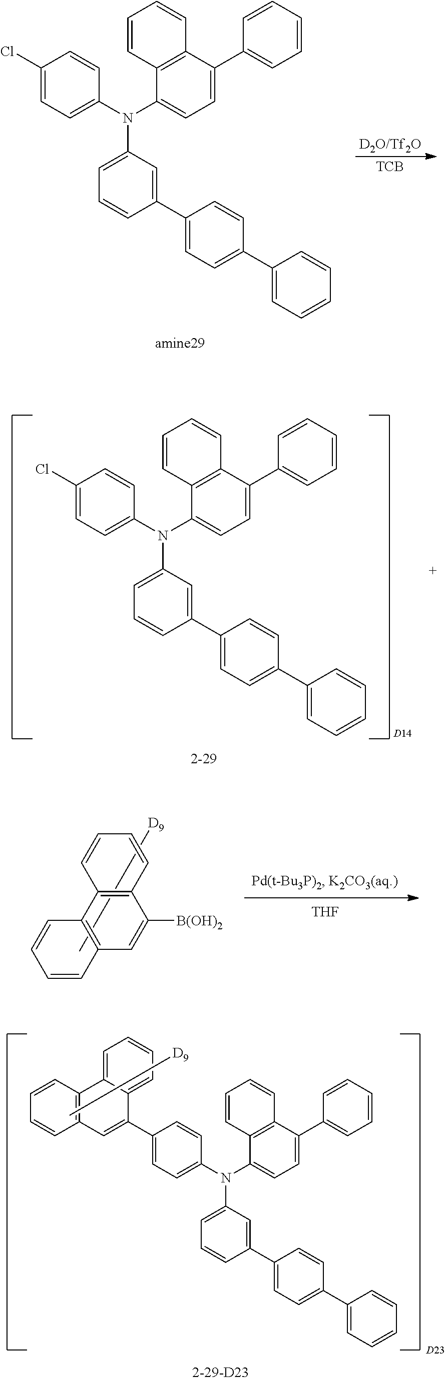

Compound amine29(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(30.3 g, 107.5 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.2 g of Compound 2-29. (Yield: 41%, MS: [M+H]⁺=573).

Compound 2-29(15 g, 26.2 mmol) and phenanthren-9-ylboronic acid_D9(6.4 g, 27.5 mmol) were added to 300 ml of THF, and the mixture was stirred and refluxed. Then, potassium carbonate(10.9 g, 78.7 mmol) was dissolved in 100 ml of water and added thereto, and the mixture was sufficiently stirred and then bis(tri-tert-butylphosphine)palladium(0) (0.1 g, 0.3 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 11.4 g of Compound 2-29-D23. (Yield: 60%, MS: [M+H]⁺=724)

### Preparation Example 2-30

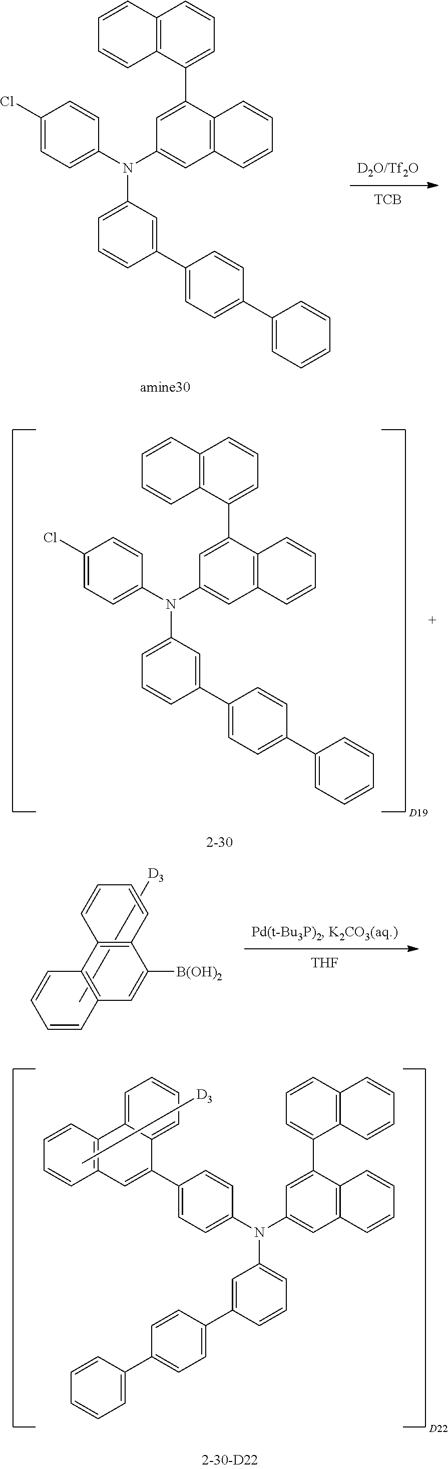

Compound amine30(10 g, 16.4 mmol) was added to 200 ml of 1,2,4-trichlorobenzene, and the mixture was stirred at room temperature. In another vessel, deuterium oxide(11.9 g, 591.9 mmol) was added to trifluoromethanesulfonic anhydride(41.8 g, 148 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.2 g of Compound 2-30. (Yield: 50%, MS: [M+H]⁺=628).

Compound 2-30(15 g, 23.9 mmol) and phenanthren-9-ylboronic acid_D3(5.7 g, 25.1 mmol) were added to 300 ml of THF, and the mixture was stirred and refluxed. Then, potassium carbonate(9.9 g, 71.7 mmol) was dissolved in 100 ml of water and added thereto, and the mixture was sufficiently stirred and then bis(tri-tert-butylphosphine)palladium(0) (0.1 g, 0.2 mmol) was added. After the reaction for 4 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 11.3 g of Compound 2-30-D22. (Yield: 61%, MS: [M+H]⁺=773)

### Preparation Example 2-31

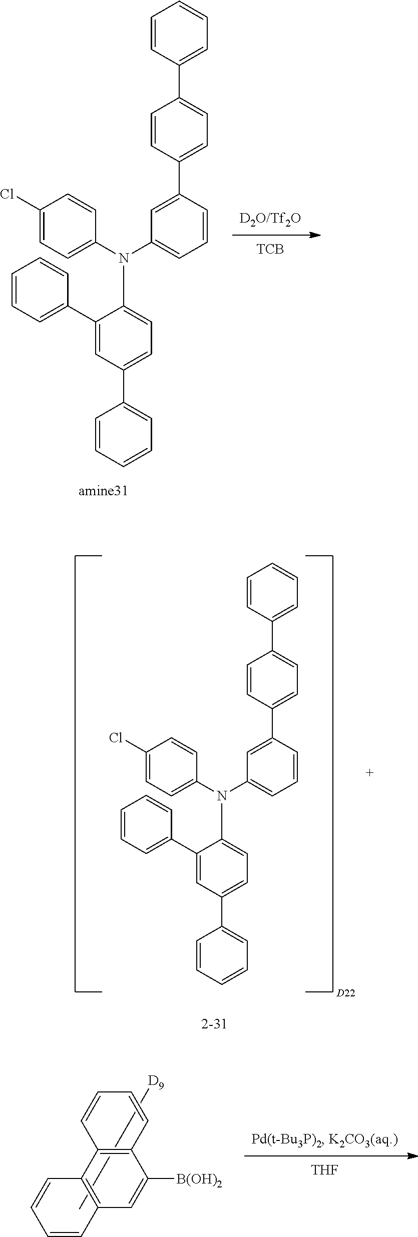

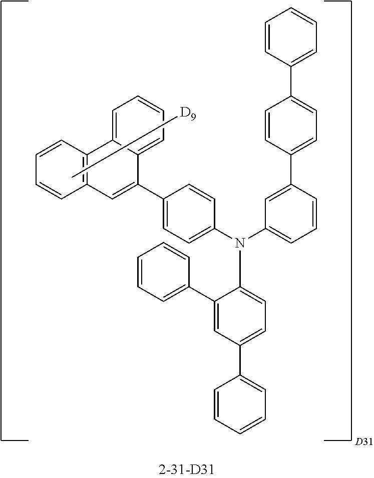

Compound amine31(10 g, 17.1 mmol) was added to 200 ml of 1,2,4-trichlorobenzene, and the mixture was stirred at room temperature. In another vessel, deuterium oxide(12.3 g, 616.3 mmol) was added to trifluoromethanesulfonic anhydride(43.5 g, 154.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.8 g of Compound 2-31. (Yield: 46%, MS: [M+H]⁺=607).

Compound 2-31(15 g, 24.7 mmol) and phenanthren-9-ylboronic acid_D9(6 g, 26 mmol) were added to 300 ml of THF, and the mixture was stirred and refluxed. Then, potassium carbonate(10.3 g, 74.2 mmol) was dissolved in 100 ml of water and added thereto, and the mixture was sufficiently stirred and then bis(tri-tert-butylphosphine)palladium(0) (0.1 g, 0.2 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.6 g of Compound 2-31-D31. (Yield: 78%, MS: [M+H]⁺=758)

### Preparation Example 2-32

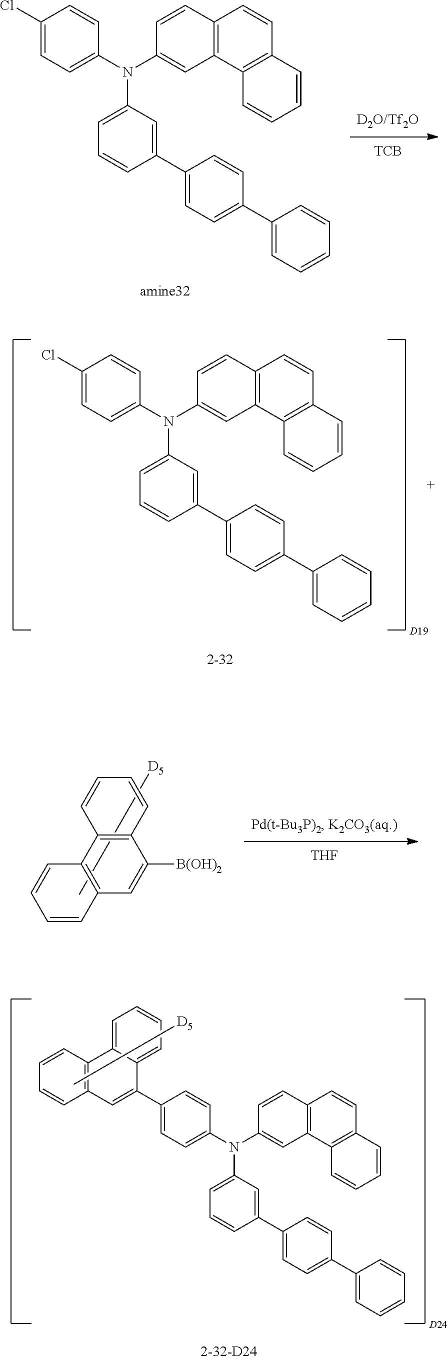

Compound amine32(10 g, 18.8 mmol) was added to 200 ml of 1,2,4-trichlorobenzene, and the mixture was stirred at room temperature. In another vessel, deuterium oxide(13.6 g, 676.6 mmol) was added to trifluoromethanesulfonic anhydride(47.7 g, 169.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.3 g of Compound 2-32. (Yield: 42%, MS: [M+H]⁺=552).

Compound 2-32(15 g, 27.2 mmol) and phenanthren-9-ylboronic acid_D5(6.5 g, 28.6 mmol) were added to 300 ml of THF, and the mixture was stirred and refluxed. Then, potassium carbonate(11.3 g, 81.7 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.5 g of Compound 2-32-D24. (Yield: 71%, MS: [M+H]⁺=699)

### Preparation Example 2-33

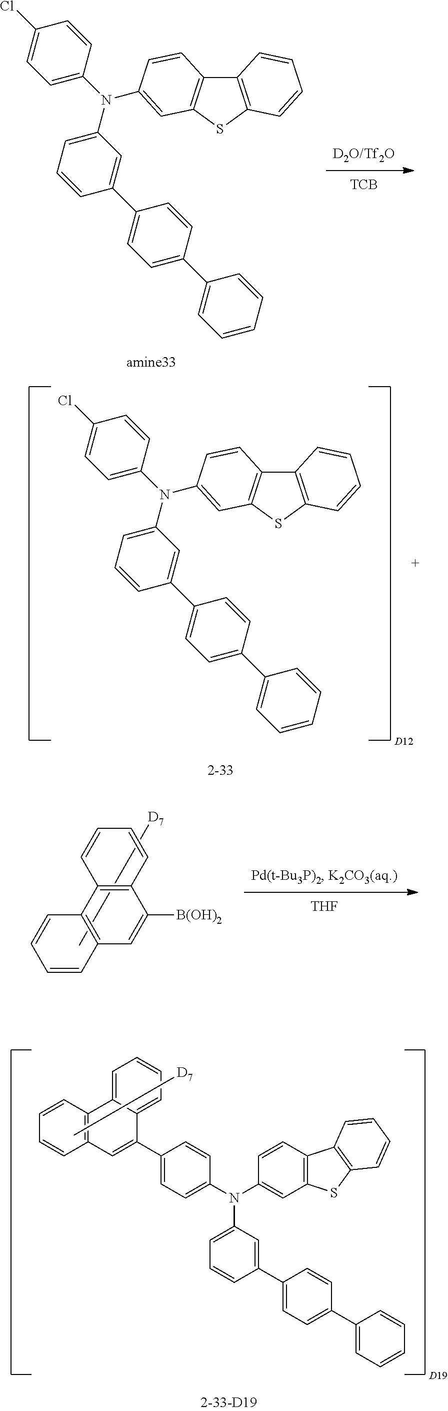

Compound amine33(10 g, 18.6 mmol) was added to 200 ml of 1,2,4-trichlorobenzene, and the mixture was stirred at room temperature. In another vessel, deuterium oxide(13.4 g, 669 mmol) was added to trifluoromethanesulfonic anhydride(31.5 g, 111.5 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.5 g of Compound 2-33. (Yield: 44%, MS: [M+H]⁺=551).

Compound 2-33(15 g, 27.3 mmol) and phenanthren-9-ylboronic acid_D7(6.6 g, 28.6 mmol) were added to 300 ml of THF, and the mixture was stirred and refluxed. Then, potassium carbonate(11.3 g, 81.8 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.3 g of Compound 2-33-D19. (Yield: 75%, MS: [M+H]⁺=700)

### Preparation Example 2-34

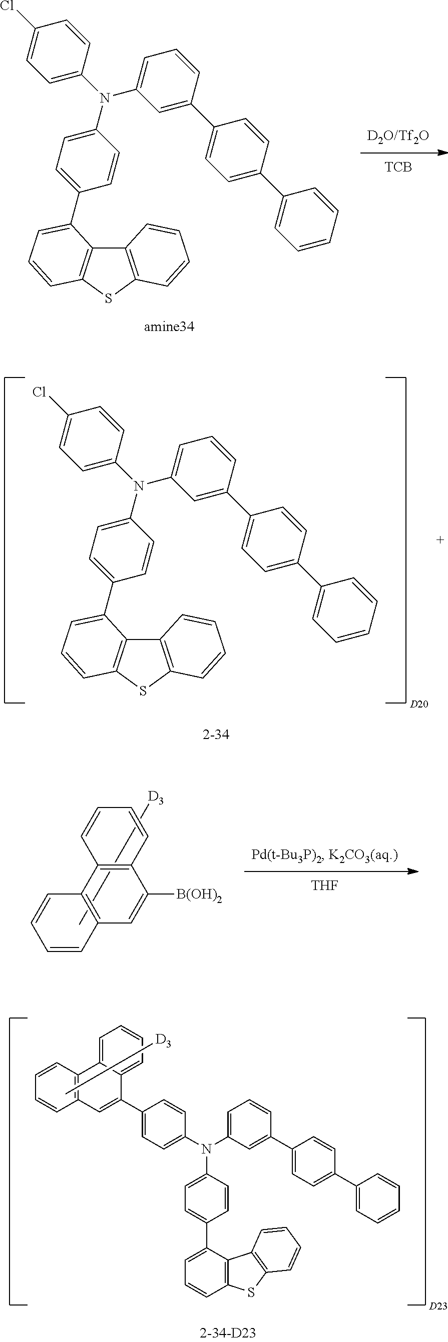

Compound amine34(10 g, 16.3 mmol) was added to 200 ml of 1,2,4-trichlorobenzene, and the mixture was stirred at room temperature. In another vessel, deuterium oxide(11.7 g, 586.1 mmol) was added to trifluoromethanesulfonic anhydride(41.3 g, 146.5 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.5 g of Compound 2-34. (Yield: 44%, MS: [M+H]⁺=635).

Compound 2-34(15 g, 23.7 mmol) and phenanthren-9-ylboronic acid_D3(5.6 g, 24.8 mmol) were added to 300 ml of THF, and the mixture was stirred and refluxed. Then, potassium carbonate(9.8 g, 71 mmol) was dissolved in 100 ml of water and added thereto, and the mixture was sufficiently stirred and then bis(tri-tert-butylphosphine)palladium(0) (0.1 g, 0.2 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12.7 g of Compound 2-34-D23. (Yield: 69%, MS: [M+H]⁺=780)

### Preparation Example 2-35

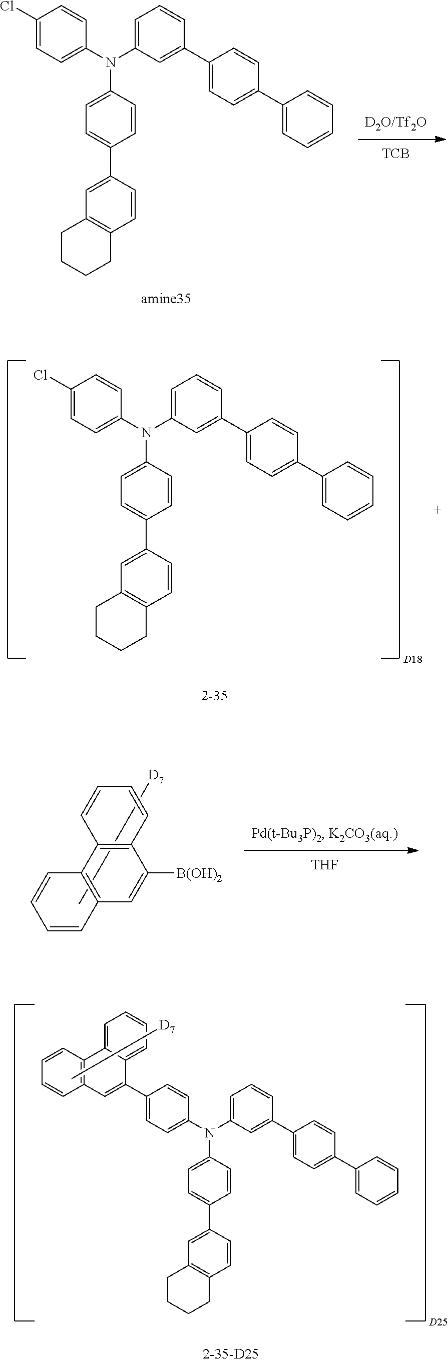

Compound amine35(10 g, 17.8 mmol) was added to 200 ml of 1,2,4-trichlorobenzene, and the mixture was stirred at room temperature. In another vessel, deuterium oxide(12.8 g, 640.4 mmol) was added to trifluoromethanesulfonic anhydride(45.2 g, 160.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.7 g of Compound 2-35. (Yield: 46%, MS: [M+H]⁺=581).

Compound 2-35(15 g, 25.9 mmol) and phenanthren-9-ylboronic acid_D7(6.2 g, 27.1 mmol) were added to 300 ml of THF, and the mixture was stirred and refluxed. Then, potassium carbonate(10.7 g, 77.6 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 11.3 g of Compound 2-35-D25. (Yield: 60%, MS: [M+H]⁺=730)

### Preparation Example 2-36

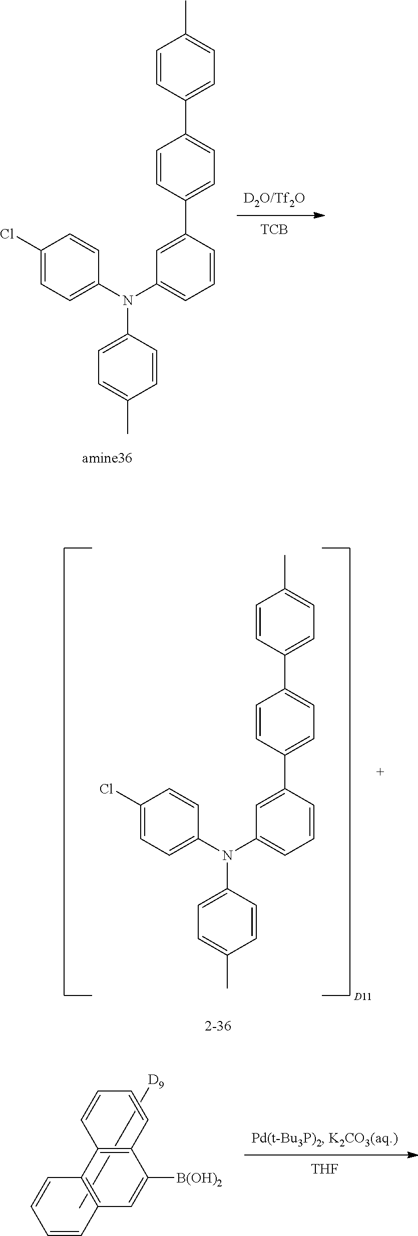

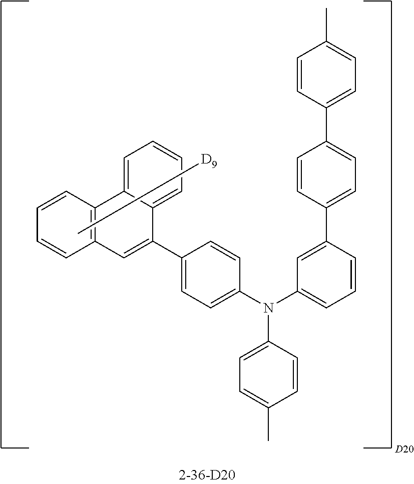

Compound amine36(10 g, 21.7 mmol) was added to 200 ml of 1,2,4-trichlorobenzene, and the mixture was stirred at room temperature. In another vessel, deuterium oxide(15.7 g, 782.6 mmol) was added to trifluoromethanesulfonic anhydride(36.8 g, 130.4 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.1 g of Compound 2-36. (Yield: 40%, MS: [M+H]⁺=472).

Compound 2-36(15 g, 31.8 mmol) and phenanthren-9-ylboronic acid_D9(7.7 g, 33.4 mmol) were added to 300 ml of THF, and the mixture was stirred and refluxed. Then, potassium carbonate(13.2 g, 95.5 mmol) was dissolved in 100 ml of water and added thereto, and the mixture was sufficiently stirred and then bis(tri-tert-butylphosphine)palladium(0) (0.2 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12.5 g of Compound 2-36-D20. (Yield: 63%, MS: [M+H]⁺=623)

### Preparation Example 2-37

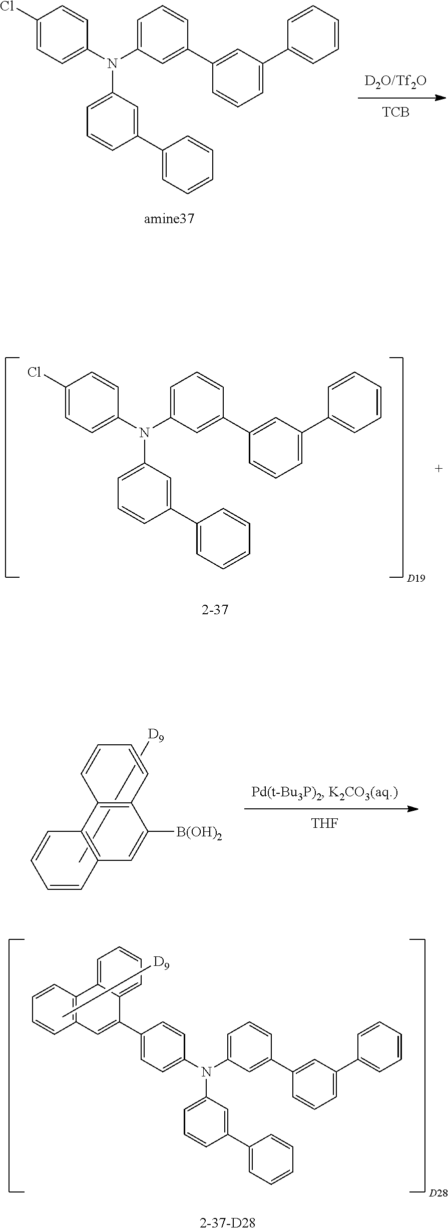

Compound amine37(10 g, 19.7 mmol) was added to 200 ml of 1,2,4-trichlorobenzene, and the mixture was stirred at room temperature. In another vessel, deuterium oxide(14.2 g, 708.6 mmol) was added to trifluoromethanesulfonic anhydride(50 g, 177.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5 g of Compound 2-37. (Yield: 48%, MS: [M+H]⁺=527).

Compound 2-37(15 g, 28.5 mmol) and phenanthren-9-ylboronic acid_D9(6.9 g, 29.9 mmol) were added to 300 ml of THF, and the mixture was stirred and refluxed. Then, potassium carbonate(11.8 g, 85.4 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.2 g of Compound 2-37-D28. (Yield: 74%, MS: [M+H]⁺=678)

### Preparation Example 2-38

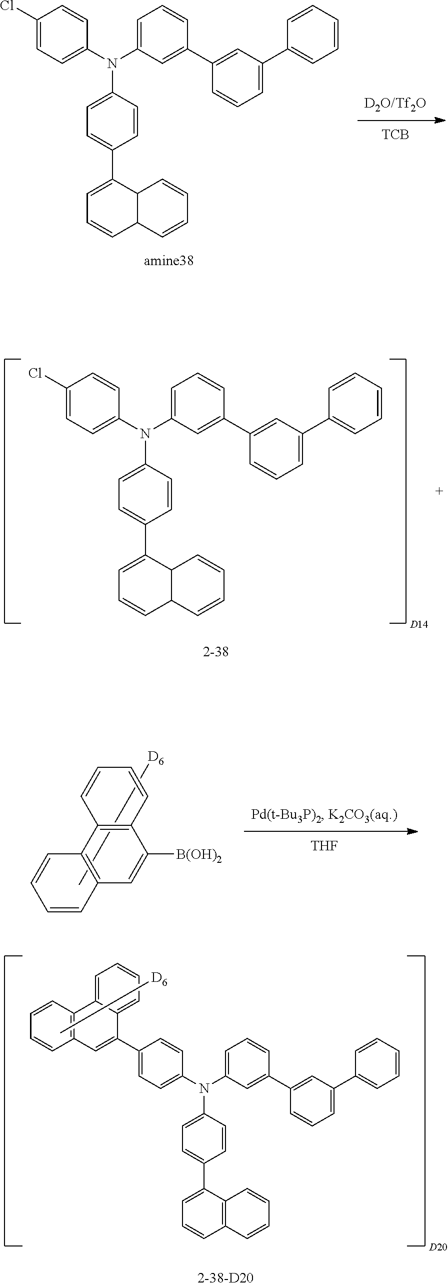

Compound amine38(10 g, 17.9 mmol) was added to 200 ml of 1,2,4-trichlorobenzene, and the mixture was stirred at room temperature. In another vessel, deuterium oxide(12.9 g, 642.7 mmol) was added to trifluoromethanesulfonic anhydride(30.2 g, 107.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5 g of Compound 2-38. (Yield: 49%, MS: [M+H]⁺=575).

Compound 2-38(15 g, 26.1 mmol) and phenanthren-9-ylboronic acid_D6(6.3 g, 27.4 mmol) were added to 300 ml of THF, and the mixture was stirred and refluxed. Then, potassium carbonate(10.8 g, 78.4 mmol) was dissolved in 100 ml of water and added thereto, and the mixture was sufficiently stirred and then bis(tri-tert-butylphosphine)palladium(0) (0.1 g, 0.3 mmol) was added. After the reaction for 4 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12.4 g of Compound 2-38-D20. (Yield: 66%, MS: [M+H]⁺=721)

### Preparation Example 2-39

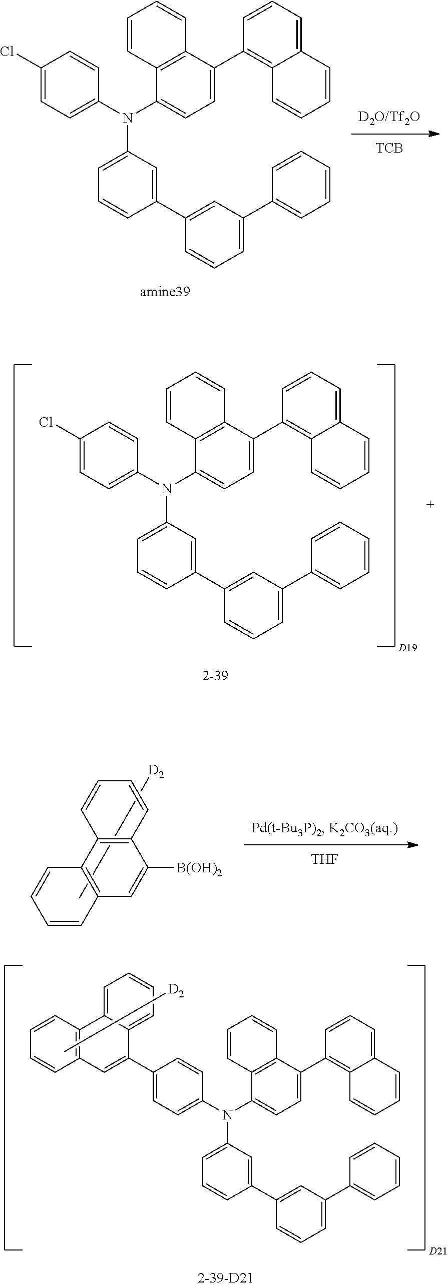

Compound amine39(10 g, 16.4 mmol) was added to 200 ml of 1,2,4-trichlorobenzene, and the mixture was stirred at room temperature. In another vessel, deuterium oxide(11.9 g, 591.9 mmol) was added to trifluoromethanesulfonic anhydride(41.8 g, 148 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.9 g of Compound 2-39. (Yield: 48%, MS: [M+H]⁺=628).

Compound 2-39(15 g, 23.9 mmol) and phenanthren-9-ylboronic acid_D2(5.6 g, 25.1 mmol) were added to 300 ml of THF, and the mixture was stirred and refluxed. Then, potassium carbonate(9.9 g, 71.7 mmol) was dissolved in 100 ml of water and added thereto, and the mixture was sufficiently stirred and then bis(tri-tert-butylphosphine)palladium(0) (0.1 g, 0.2 mmol) was added. After the reaction for 4 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12.2 g of Compound 39-D21. (Yield: 66%, MS: [M+H]⁺=772)

### Preparation Example 2-40

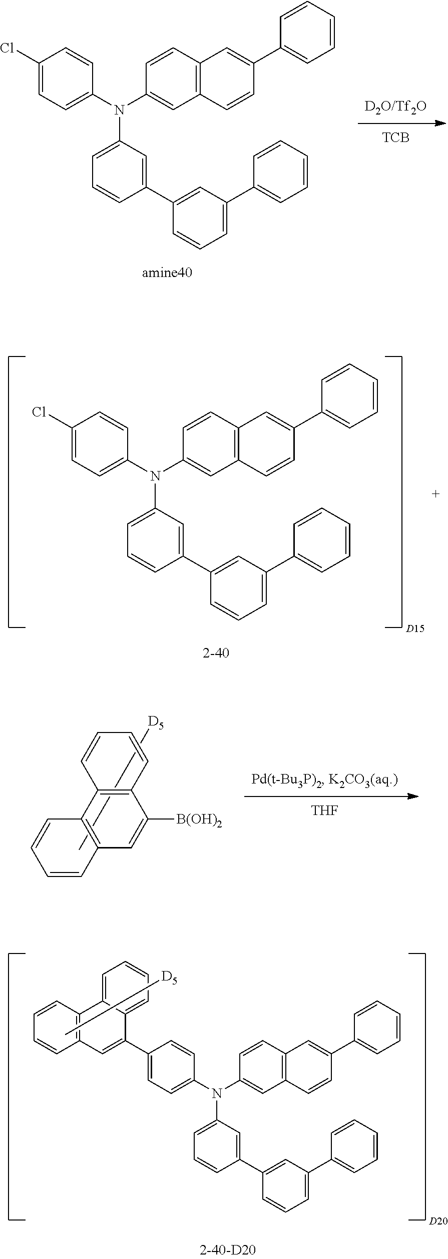

Compound amine40(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(30.3 g, 107.5 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5 g of Compound 2-40. (Yield: 49%, MS: [M+H]⁺=574).

Compound 2-40(15 g, 26.2 mmol) and phenanthren-9-ylboronic acid_D5(6.2 g, 27.5 mmol) were added to 300 ml of THF, and the mixture was stirred and refluxed. Then, potassium carbonate(10.9 g, 78.5 mmol) was dissolved in 100 ml of water and added thereto, and the mixture was sufficiently stirred and then bis(tri-tert-butylphosphine)palladium(0) (0.1 g, 0.3 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12.4 g of Compound 2-40-D20. (Yield: 66%, MS: [M+H]⁺=721)

### Preparation Example 2-41

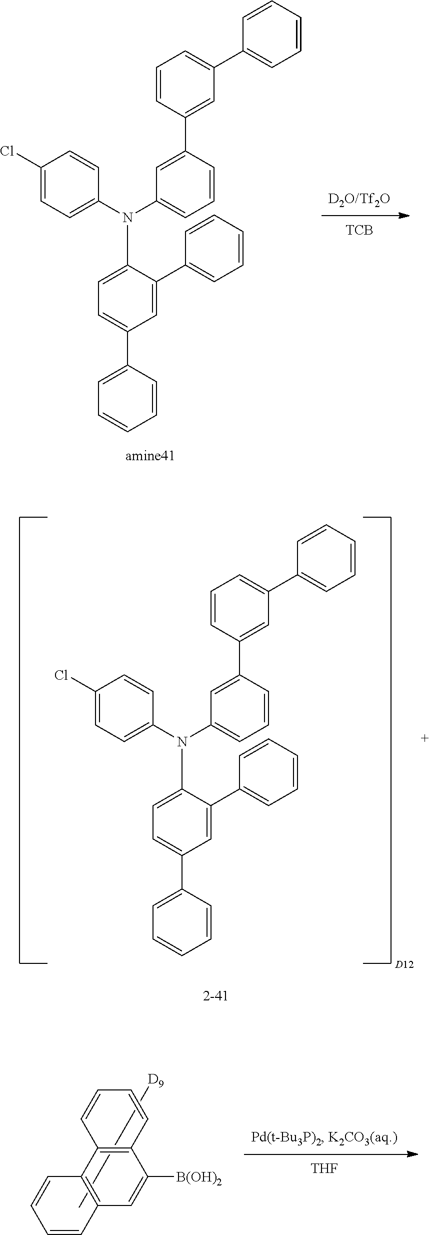

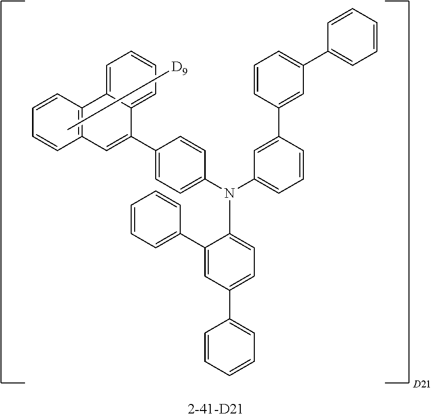

Compound amine41(10 g, 17.1 mmol) was added to 200 ml of 1,2,4-trichlorobenzene, and the mixture was stirred at room temperature. In another vessel, deuterium oxide(12.3 g, 616.3 mmol) was added to trifluoromethanesulfonic anhydride(29 g, 102.7 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.1 g of Compound 2-41. (Yield: 40%, MS: [M+H]⁺=597).

Compound 2-41(15 g, 25.2 mmol) and phenanthren-9-ylboronic acid_D9(6.1 g, 26.4 mmol) were added to 300 ml of THF, and the mixture was stirred and refluxed. Then, potassium carbonate(10.4 g, 75.5 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.9 g of Compound 2-41-D21. (Yield: 74%, MS: [M+H]⁺=748)

### Preparation Example 2-42

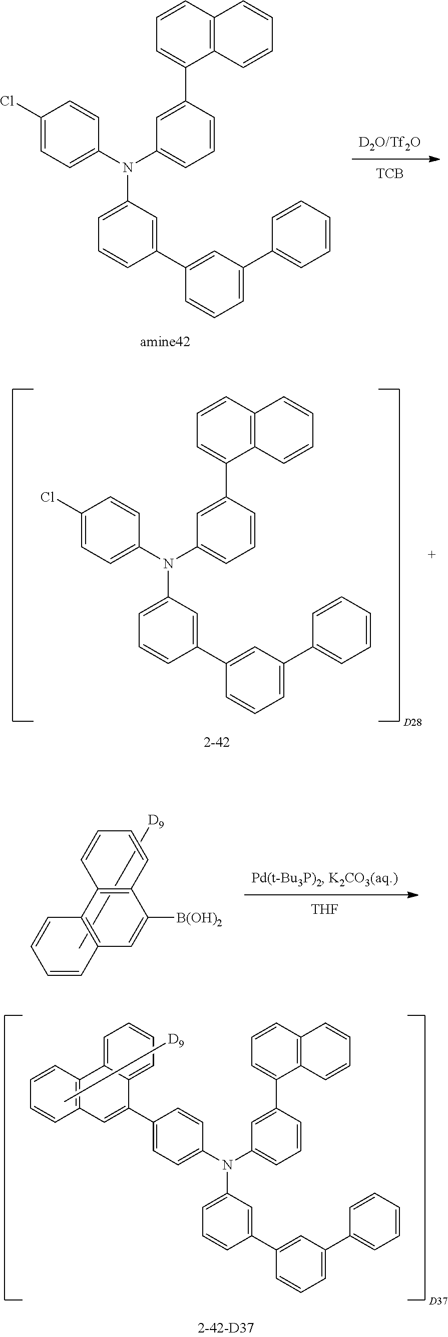

Compound amine42(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(60.7 g, 215 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 15 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.6 g of Compound 2-42. (Yield: 44%, MS: [M+H]⁺=587).

Compound 2-42(15 g, 25.6 mmol) and phenanthren-9-ylboronic acid_D9(6.2 g, 26.9 mmol) were added to 300 ml of THF, and the mixture was stirred and refluxed. Then, potassium carbonate(10.6 g, 76.8 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.6 g of Compound 2-42-D37. (Yield: 72%, MS: [M+H]⁺=738)

### Preparation Example 2-43

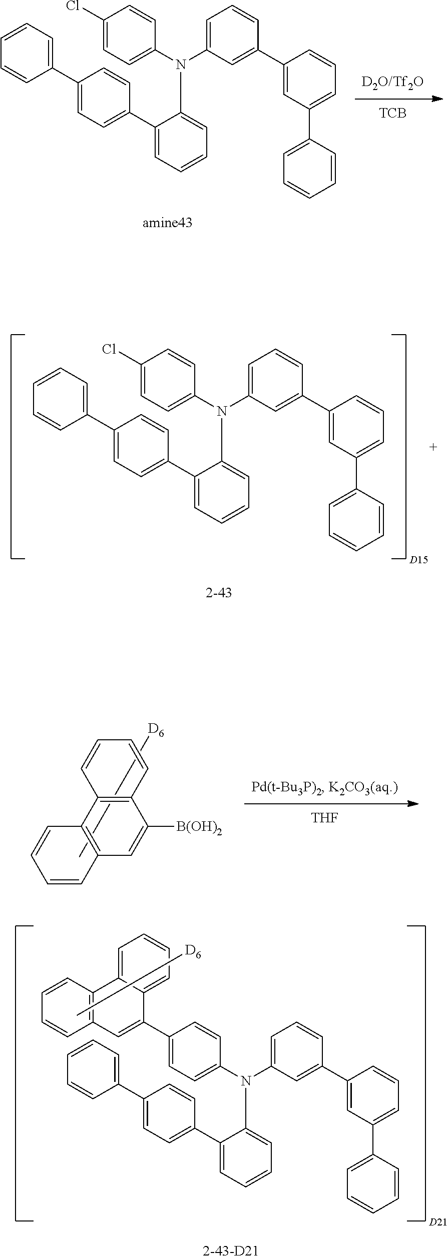

Compound amine43(10 g, 17.1 mmol) was added to 200 ml of 1,2,4-trichlorobenzene, and the mixture was stirred at room temperature. In another vessel, deuterium oxide(12.3 g, 616.3 mmol) was added to trifluoromethanesulfonic anhydride(29 g, 102.7 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.2 g of Compound 2-43. (Yield: 41%, MS: [M+H]⁺=600).

Compound 2-43(15 g, 25 mmol) and phenanthren-9-ylboronic acid_D6(6 g, 26.3 mmol) were added to 300 ml of THF, and the mixture was stirred and refluxed. Then, potassium carbonate(10.4 g, 75.1 mmol) was dissolved in 100 ml of water and added thereto, and the mixture was sufficiently stirred and then bis(tri-tert-butylphosphine)palladium(0) (0.1 g, 0.3 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.5 g of Compound 2-43-D21. (Yield: 72%, MS: [M+H]⁺=748)

### Preparation Example 2-44

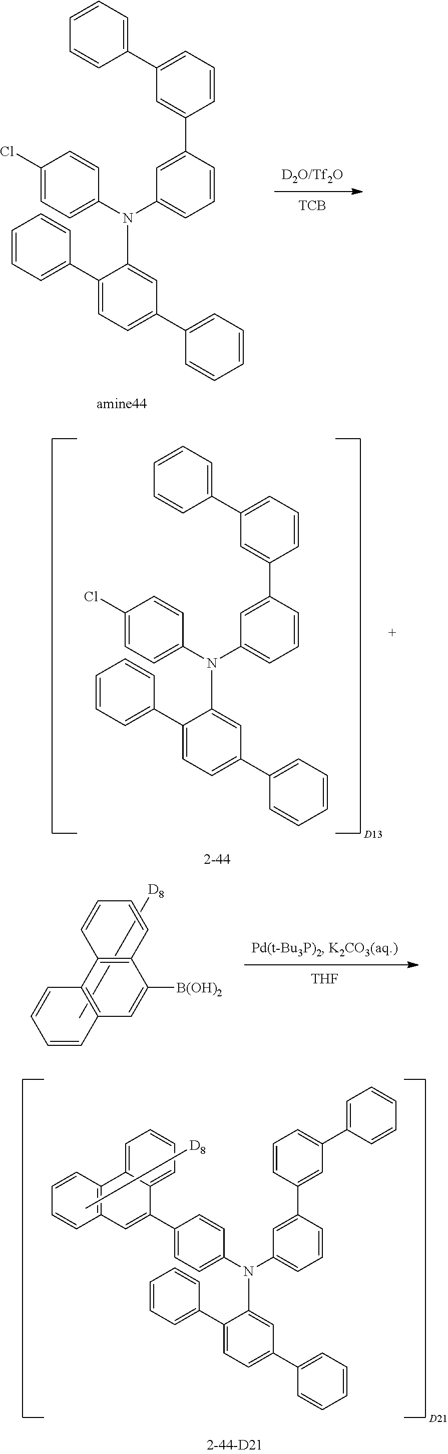

Compound amine44(10 g, 17.1 mmol) was added to 200 ml of 1,2,4-trichlorobenzene, and the mixture was stirred at room temperature. In another vessel, deuterium oxide(12.3 g, 616.3 mmol) was added to trifluoromethanesulfonic anhydride(29 g, 102.7 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.6 g of Compound 2-44. (Yield: 45%, MS: [M+H]⁺=598).

Compound 2-44(15 g, 25.1 mmol) and phenanthren-9-ylboronic acid_D8(6.1 g, 26.4 mmol) were added to 300 ml of THF, and the mixture was stirred and refluxed. Then, potassium carbonate(10.4 g, 75.4 mmol) was dissolved in 100 ml of water and added thereto, and the mixture was sufficiently stirred and then bis(tri-tert-butylphosphine)palladium(0) (0.1 g, 0.3 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.3 g of Compound 2-44-D21. (Yield: 76%, MS: [M+H]⁺=748)

### Preparation Example 2-45

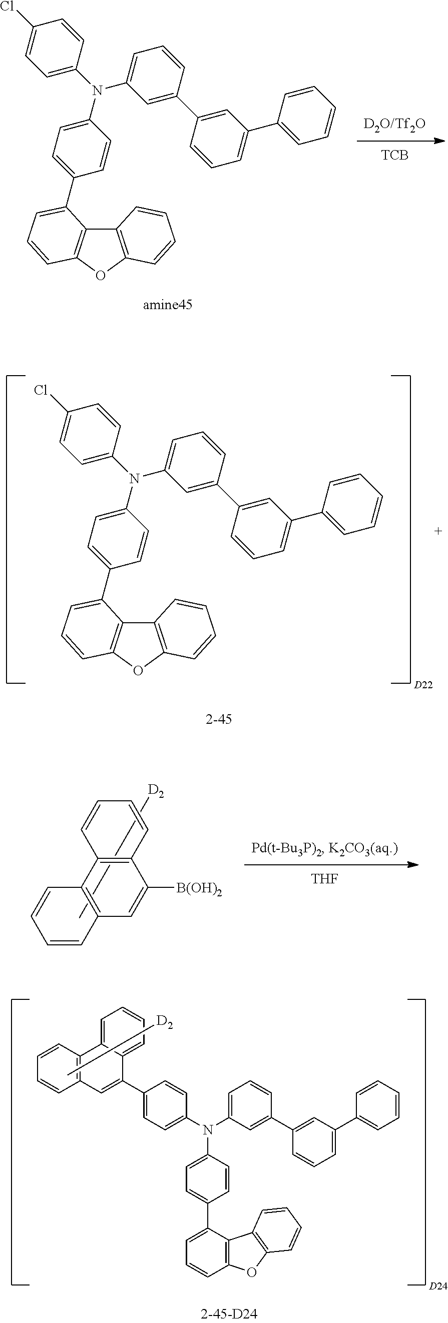

Compound amine45(10 g, 16.7 mmol) was added to 200 ml of 1,2,4-trichlorobenzene, and the mixture was stirred at room temperature. In another vessel, deuterium oxide(12.1 g, 601.9 mmol) was added to trifluoromethanesulfonic anhydride(42.5 g, 150.5 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.1 g of Compound 2-45. (Yield: 49%, MS: [M+H]⁺=621).

Compound 2-45(15 g, 24.2 mmol) and phenanthren-9-ylboronic acid_D2(5.7 g, 25.4 mmol) were added to 300 ml of THF, and the mixture was stirred and refluxed. Then, potassium carbonate(10 g, 72.6 mmol) was dissolved in 100 ml of water and added thereto, and the mixture was sufficiently stirred and then bis(tri-tert-butylphosphine)palladium(0) (0.1 g, 0.2 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12.2 g of Compound 2-45-D24. (Yield: 66%, MS: [M+H]⁺=765)

### Preparation Example 2-46

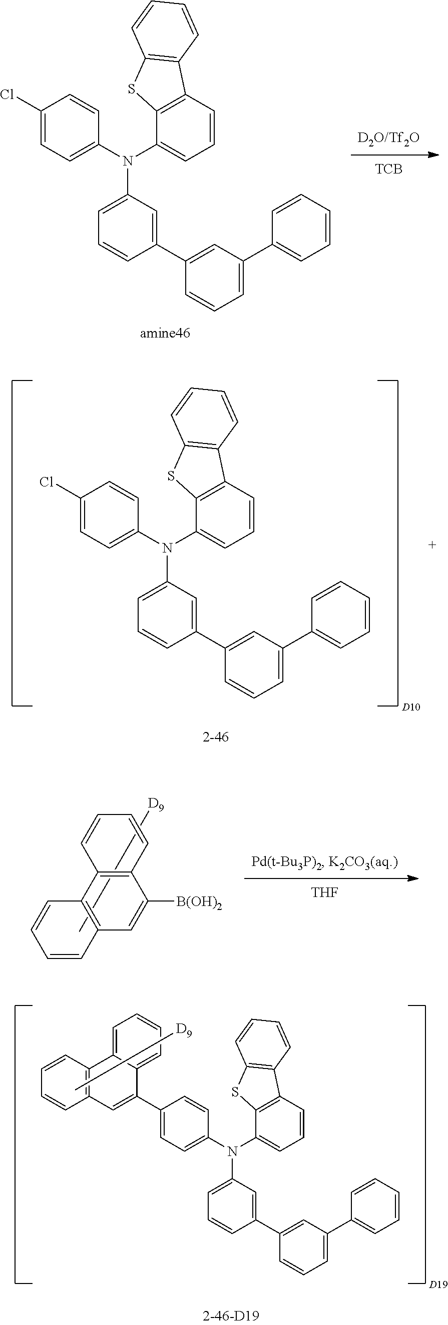

Compound amine46(10 g, 18.6 mmol) was added to 200 ml of 1,2,4-trichlorobenzene, and the mixture was stirred at room temperature. In another vessel, deuterium oxide(13.4 g, 669 mmol) was added to trifluoromethanesulfonic anhydride(31.5 g, 111.5 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5 g of Compound 2-46. (Yield: 49%, MS: [M+H]⁺=549).

Compound 2-46(15 g, 27.4 mmol) and phenanthren-9-ylboronic acid_D9(6.6 g, 28.7 mmol) were added to 300 ml of THF, and the mixture was stirred and refluxed. Then, potassium carbonate(11.3 g, 82.1 mmol) was dissolved in 100 ml of water and added thereto, and the mixture was sufficiently stirred and then bis(tri-tert-butylphosphine)palladium(0) (0.1 g, 0.3 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14 g of Compound 2-46-D19. (Yield: 73%, MS: [M+H]⁺=700)

### Preparation Example 2-47

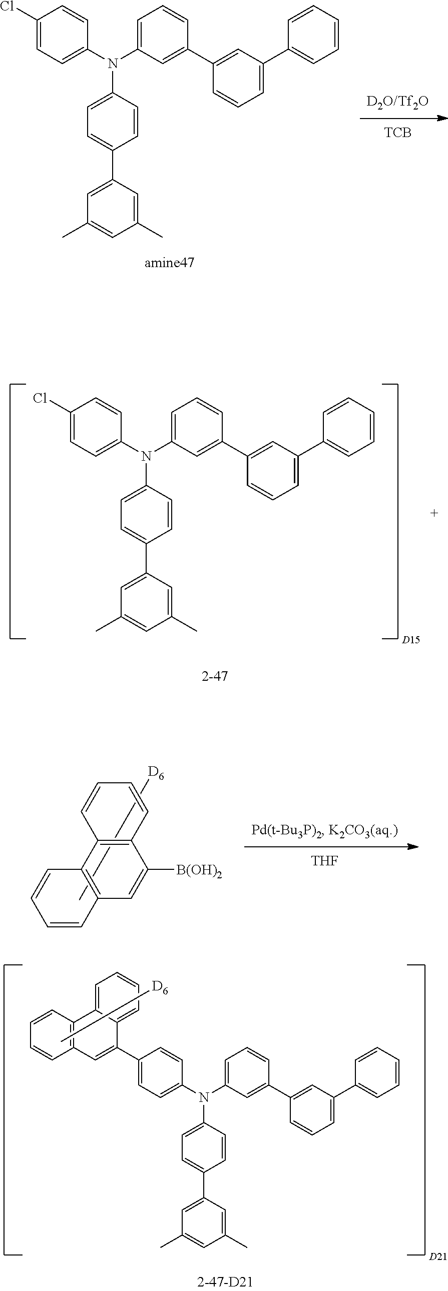

Compound amine47(10 g, 18.7 mmol) was added to 200 ml of 1,2,4-trichlorobenzene, and the mixture was stirred at room temperature. In another vessel, deuterium oxide(13.4 g, 671.5 mmol) was added to trifluoromethanesulfonic anhydride(31.6 g, 111.9 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.3 g of Compound 2-47. (Yield: 42%, MS: [M+H]⁺=552).

Compound 2-47(15 g, 27.2 mmol) and phenanthren-9-ylboronic acid_D6(6.5 g, 28.6 mmol) were added to 300 ml of THF, and the mixture was stirred and refluxed. Then, potassium carbonate(11.3 g, 81.7 mmol) was dissolved in 100 ml of water and added thereto, and the mixture was sufficiently stirred and then bis(tri-tert-butylphosphine)palladium(0) (0.1 g, 0.3 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.3 g of Compound 2-47-D21. (Yield: 75%, MS: [M+H]⁺=700)

### Preparation Example 2-48

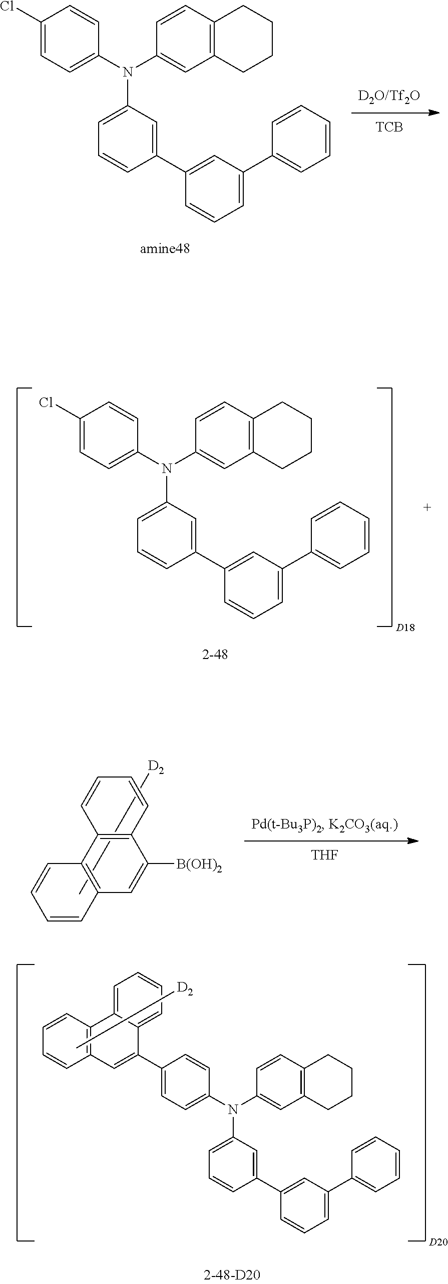

Compound amine48(10 g, 20.6 mmol) was added to 200 ml of 1,2,4-trichlorobenzene, and the mixture was stirred at room temperature. In another vessel, deuterium oxide(14.8 g, 740.6 mmol) was added to trifluoromethanesulfonic anhydride(52.2 g, 185.2 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.4 g of Compound 2-48. (Yield: 42%, MS: [M+H]⁺=505).

Compound 2-48(15 g, 29.8 mmol) and phenanthren-9-ylboronic acid_D2(7 g, 31.2 mmol) were added to 300 ml of THF, and the mixture was stirred and refluxed. Then, potassium carbonate(12.3 g, 89.3 mmol) was dissolved in 100 ml of water and added thereto, and the mixture was sufficiently stirred and then bis(tri-tert-butylphosphine)palladium(0) (0.2 g, 0.3 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 11.6 g of Compound 2-48-D20. (Yield: 60%, MS: [M+H]⁺=649)

### Preparation Example 2-49

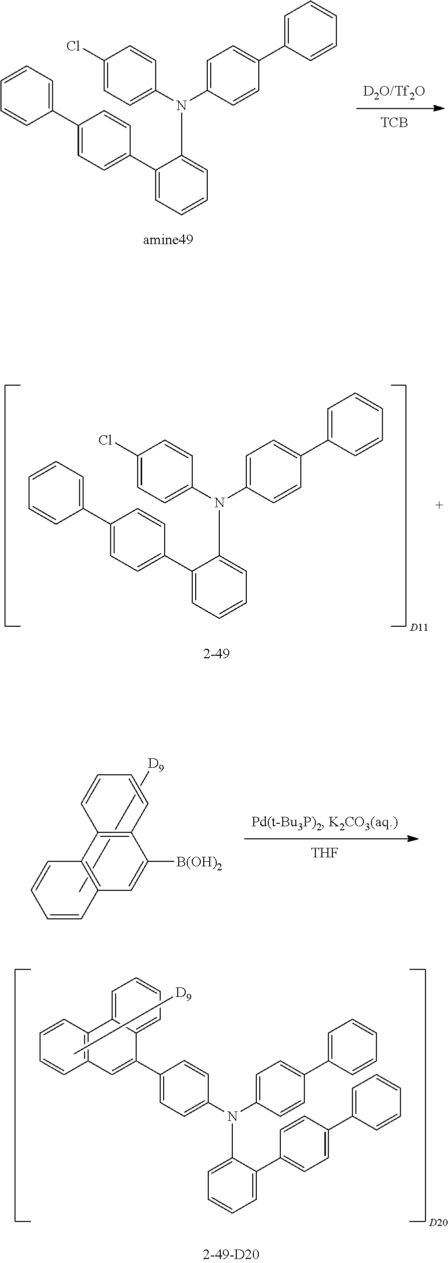

Compound amine49(10 g, 19.7 mmol) was added to 200 ml of 1,2,4-trichlorobenzene, and the mixture was stirred at room temperature. In another vessel, deuterium oxide(14.2 g, 708.6 mmol) was added to trifluoromethanesulfonic anhydride(33.3 g, 118.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.2 g of Compound 2-49. (Yield: 41%, MS: [M+H]⁺=520).

Compound 2-49(15 g, 28.9 mmol) and phenanthren-9-ylboronic acid_D9(7 g, 30.3 mmol) were added to 300 ml of THF, and the mixture was stirred and refluxed. Then, potassium carbonate(12 g, 86.7 mmol) was dissolved in 100 ml of water and added thereto, and the mixture was sufficiently stirred and then bis(tri-tert-butylphosphine)palladium(0) (0.1 g, 0.3 mmol) was added. After the reaction for 4 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.2 g of Compound 2-49-D20. (Yield: 68%, MS: [M+H]⁺=671)

### Preparation Example 2-50

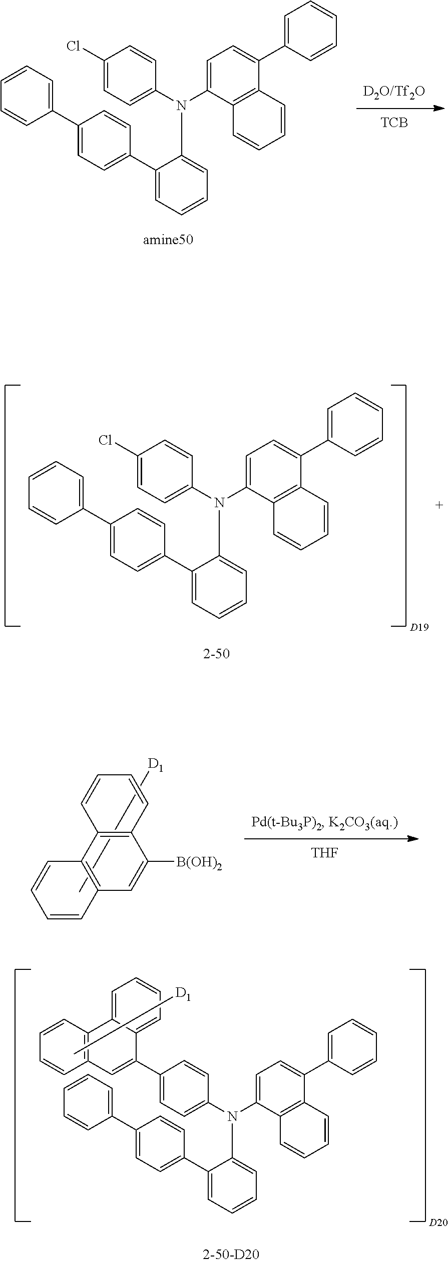

Compound amine50(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(45.5 g, 161.3 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.2 g of Compound 2-50. (Yield: 50%, MS: [M+H]⁺=578).

Compound 2-50(15 g, 26 mmol) and phenanthren-9-ylboronic acid_D1(6.1 g, 27.3 mmol) were added to 300 ml of THF, and the mixture was stirred and refluxed. Then, potassium carbonate(10.8 g, 78 mmol) was dissolved in 100 ml of water and added thereto, and the mixture was sufficiently stirred and then bis(tri-tert-butylphosphine)palladium(0) (0.1 g, 0.3 mmol) was added. After the reaction for 4 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 15 g of Compound 2-50-D20. (Yield: 80%, MS: [M+H]⁺=721)

### Preparation Example 2-51

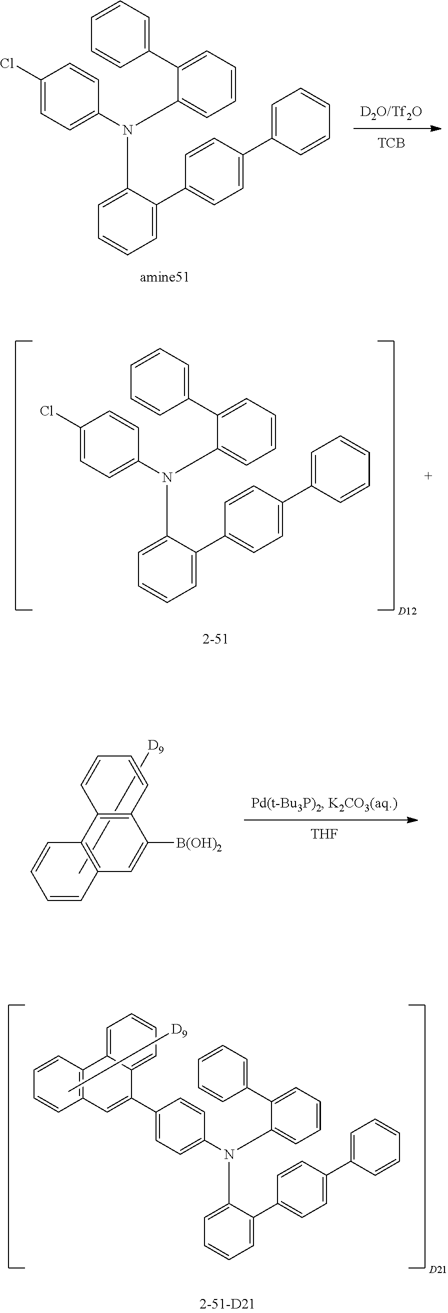

Compound amine51(10 g, 19.7 mmol) was added to 200 ml of 1,2,4-trichlorobenzene, and the mixture was stirred at room temperature. In another vessel, deuterium oxide(14.2 g, 708.6 mmol) was added to trifluoromethanesulfonic anhydride(33.3 g, 118.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.5 g of Compound 2-51. (Yield: 44%, MS: [M+H]⁺=521).

Compound 2-51(15 g, 28.8 mmol) and phenanthren-9-ylboronic acid_D9(7 g, 30.3 mmol) were added to 300 ml of THF, and the mixture was stirred and refluxed. Then, potassium carbonate(12 g, 86.5 mmol) was dissolved in 100 ml of water and added thereto, and the mixture was sufficiently stirred and then bis(tri-tert-butylphosphine)palladium(0) (0.1 g, 0.3 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 15.5 g of Compound 2-51-D21. (Yield: 80%, MS: [M+H]⁺=672)

### Preparation Example 2-52

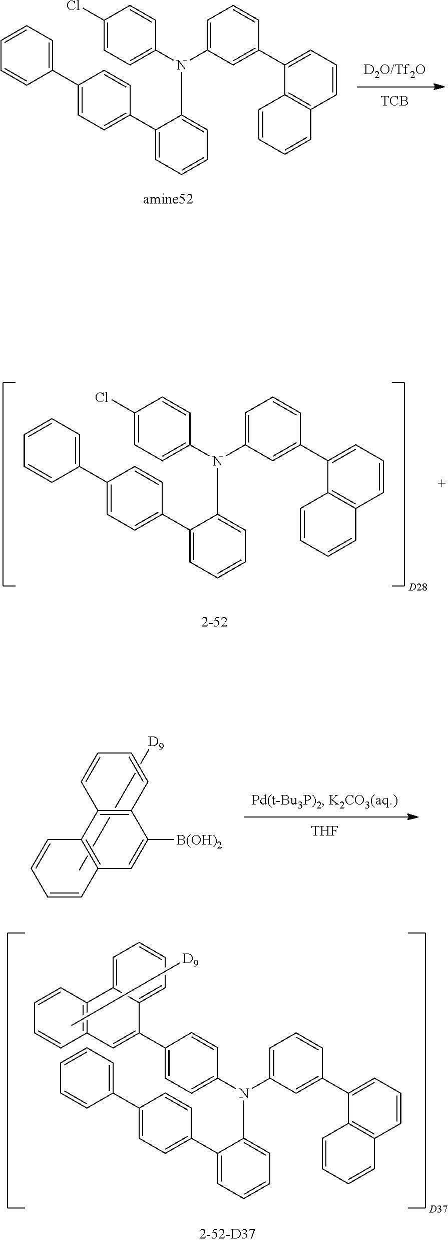

Compound amine52(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(60.7 g, 215 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 15 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 5.3 g of Compound 2-52. (Yield: 50%, MS: [M+H]⁺=587).

Compound 2-52(15 g, 25.6 mmol) and phenanthren-9-ylboronic acid_D9(6.2 g, 26.9 mmol) were added to 300 ml of THF, and the mixture was stirred and refluxed. Then, potassium carbonate(10.6 g, 76.8 mmol) was dissolved in 100 ml of water and added thereto, and the mixture was sufficiently stirred and then bis(tri-tert-butylphosphine)palladium(0) (0.1 g, 0.3 mmol) was added. After the reaction for 4 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.9 g of Compound 2-52-D37. (Yield: 79%, MS: [M+H]⁺=738)

### Preparation Example 2-53

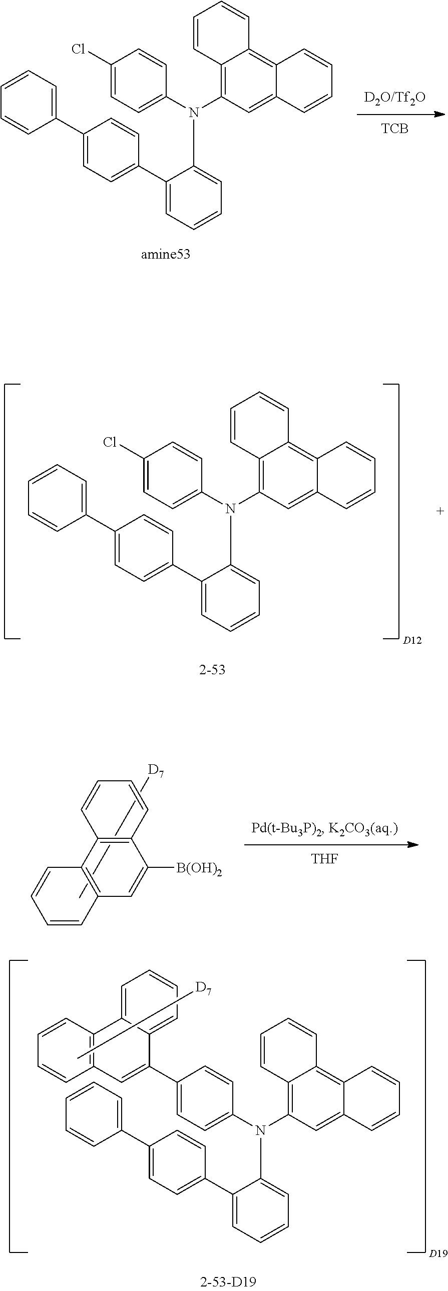

Compound amine53(10 g, 18.8 mmol) was added to 200 ml of 1,2,4-trichlorobenzene, and the mixture was stirred at room temperature. In another vessel, deuterium oxide(13.6 g, 676.6 mmol) was added to trifluoromethanesulfonic anhydride(31.8 g, 112.8 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.8 g of Compound 2-53. (Yield: 47%, MS: [M+H]⁺=545).

Compound 2-53(15 g, 27.6 mmol) and phenanthren-9-ylboronic acid_D7(6.6 g, 28.9 mmol) were added to 300 ml of THF, and the mixture was stirred and refluxed. Then, potassium carbonate(11.4 g, 82.7 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.1 g of Compound 2-53-D19. (Yield: 74%, MS: [M+H]⁺=694)

### Preparation Example 2-54

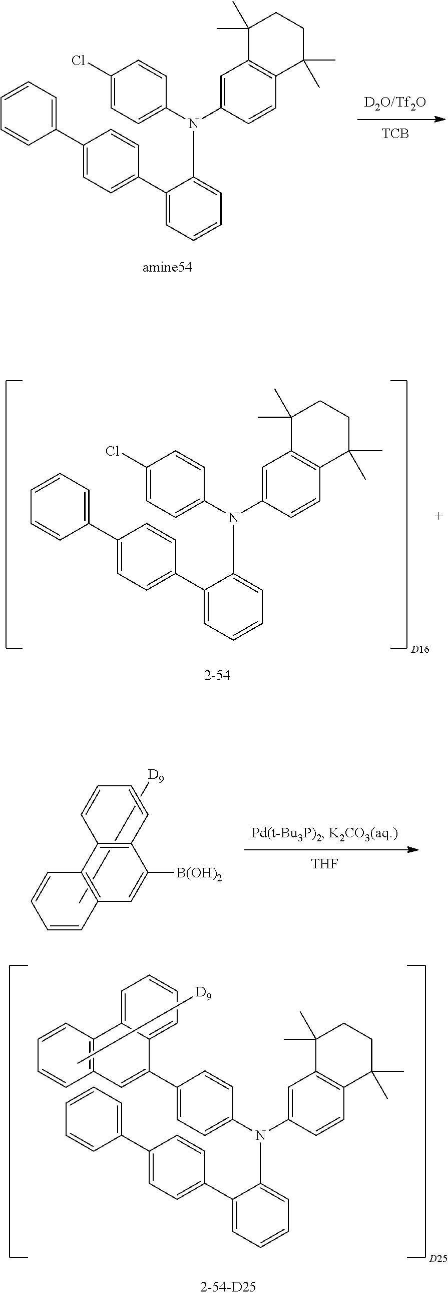

Compound amine54(10 g, 18.4 mmol) was added to 200 ml of 1,2,4-trichlorobenzene, and the mixture was stirred at room temperature. In another vessel, deuterium oxide(13.3 g, 664 mmol) was added to trifluoromethanesulfonic anhydride(31.2 g, 110.7 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.9 g of Compound 2-54. (Yield: 48%, MS: [M+H]⁺=559).

Compound 2-54(15 g, 26.9 mmol) and phenanthren-9-ylboronic acid_D9(6.5 g, 28.2 mmol) were added to 300 ml of THF, and the mixture was stirred and refluxed. Then, potassium carbonate(11.1 g, 80.6 mmol) was dissolved in 100 ml of water and added thereto, and the mixture was sufficiently stirred and then bis(tri-tert-butylphosphine)palladium(0) (0.1 g, 0.3 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.1 g of Compound 2-54-D25. (Yield: 74%, MS: [M+H]⁺=710)

### Preparation Example 2-55

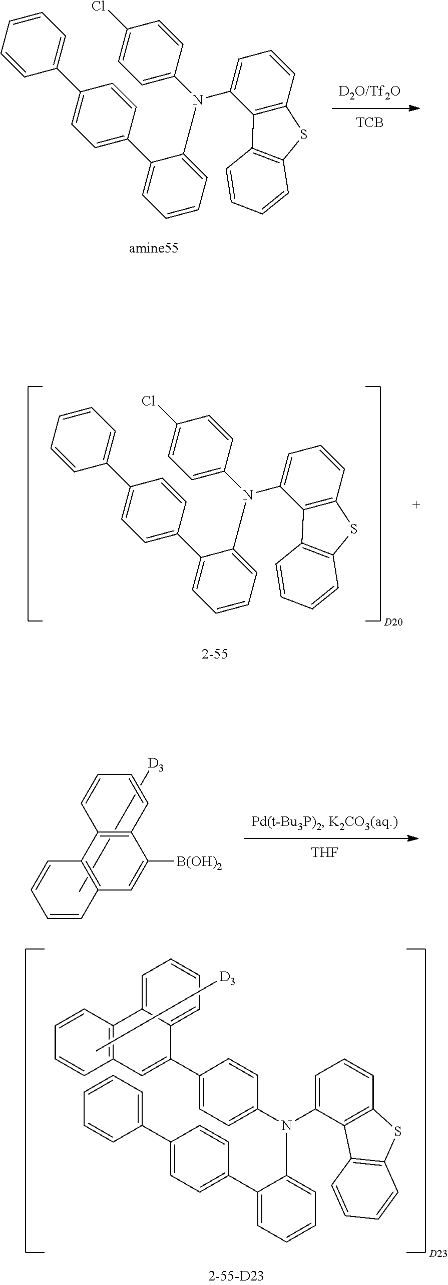

Compound amine55(10 g, 18.6 mmol) was added to 200 ml of 1,2,4-trichlorobenzene, and the mixture was stirred at room temperature. In another vessel, deuterium oxide(13.4 g, 669 mmol) was added to trifluoromethanesulfonic anhydride(47.2 g, 167.3 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.9 g of Compound 2-55. (Yield: 47%, MS: [M+H]⁺=559).

Compound 2-55(15 g, 26.9 mmol) and phenanthren-9-ylboronic acid_D3(6.4 g, 28.2 mmol) were added to 300 ml of THF, and the mixture was stirred and refluxed. Then, potassium carbonate(11.1 g, 80.6 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 11.3 g of Compound 2-55-D23. (Yield: 60%, MS: [M+H]⁺=704)

### Preparation Example 2-56

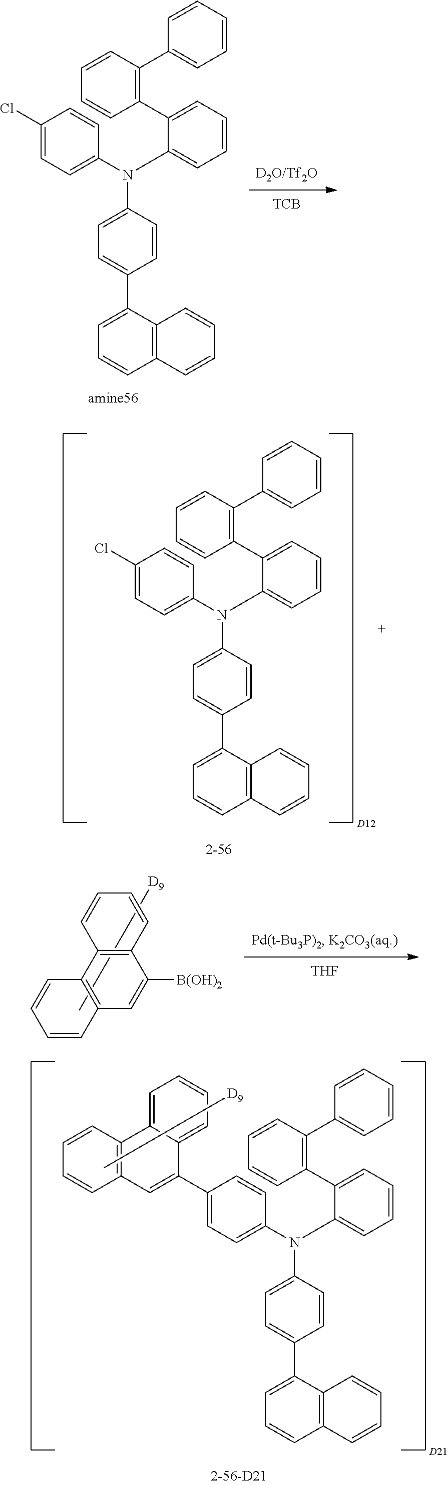

Compound amine56(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(30.3 g, 107.5 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.1 g of Compound 2-56. (Yield: 40%, MS: [M+H]⁺=571).

Compound 2-56(15 g, 26.3 mmol) and phenanthren-9-ylboronic acid_D9(6.4 g, 27.6 mmol) were added to 300 ml of THF, and the mixture was stirred and refluxed. Then, potassium carbonate(10.9 g, 78.9 mmol) was dissolved in 100 ml of water and added thereto, and the mixture was sufficiently stirred and then bis(tri-tert-butylphosphine)palladium(0) (0.1 g, 0.3 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 11.4 g of Compound 2-56-D21. (Yield: 60%, MS: [M+H]⁺=722)

### Preparation Example 2-57

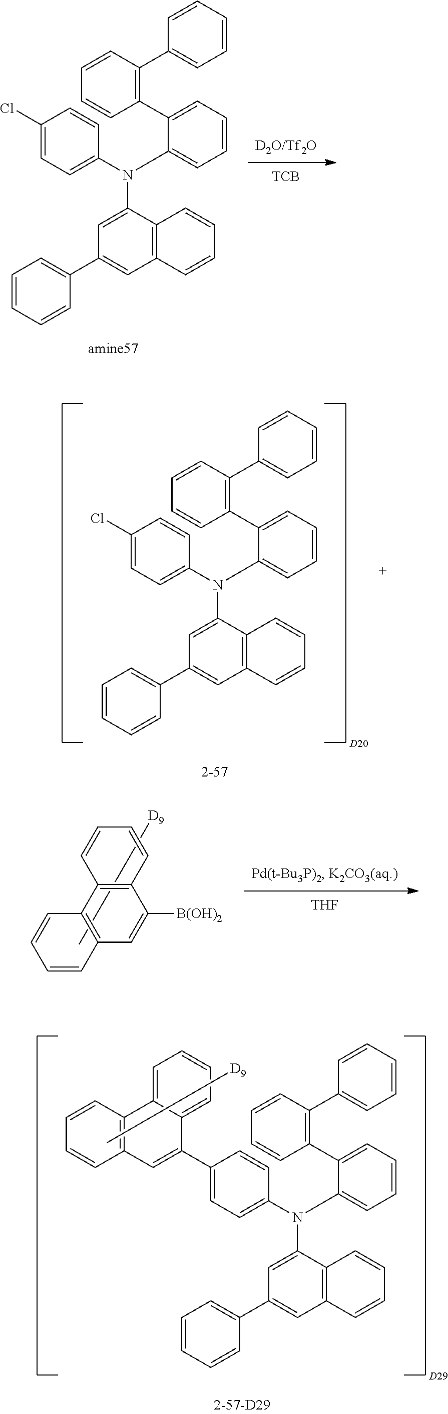

Compound amine57(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(45.5 g, 161.3 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.6 g of Compound 2-57. (Yield: 44%, MS: [M+H]⁺=579).

Compound 2-57(15 g, 25.9 mmol) and phenanthren-9-ylboronic acid_D9(6.3 g, 27.2 mmol) were added to 300 ml of THF, and the mixture was stirred and refluxed. Then, potassium carbonate(10.8 g, 77.8 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 11.7 g of Compound 2-57-D29. (Yield: 62%, MS: [M+H]⁺=730)

### Preparation Example 2-58

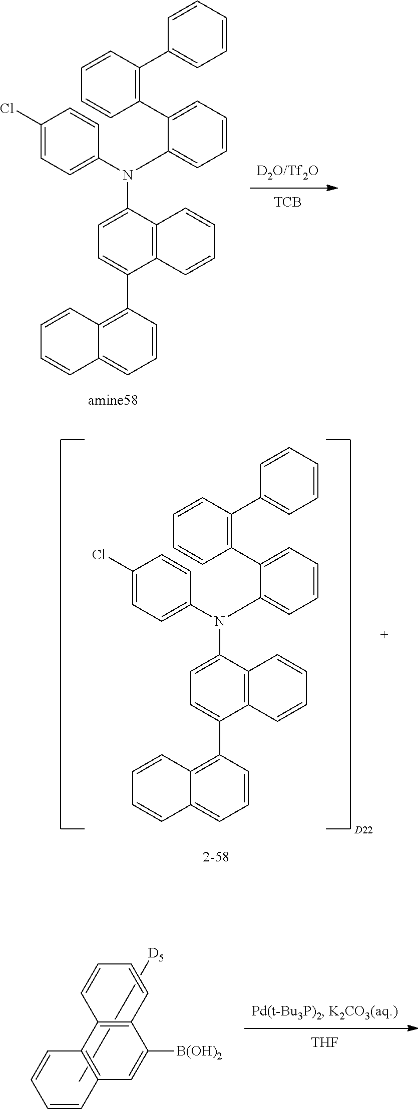

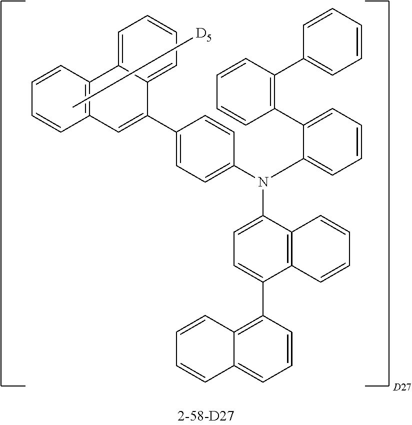

Compound amine58(10 g, 16.4 mmol) was added to 200 ml of 1,2,4-trichlorobenzene, and the mixture was stirred at room temperature. In another vessel, deuterium oxide(11.9 g, 591.9 mmol) was added to trifluoromethanesulfonic anhydride(41.8 g, 148 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.1 g of Compound 2-58. (Yield: 40%, MS: [M+H]⁺=631).

Compound 2-58(15 g, 23.8 mmol) and phenanthren-9-ylboronic acid_D5(5.7 g, 25 mmol) were added to 300 ml of THF, and the mixture was stirred and refluxed. Then, potassium carbonate(9.9 g, 71.4 mmol) was dissolved in 100 ml of water and added thereto, and the mixture was sufficiently stirred and then bis(tri-tert-butylphosphine)palladium(0) (0.1 g, 0.2 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.2 g of Compound 2-58-D27. (Yield: 77%, MS: [M+H]⁺=778)

### Preparation Example 2-59

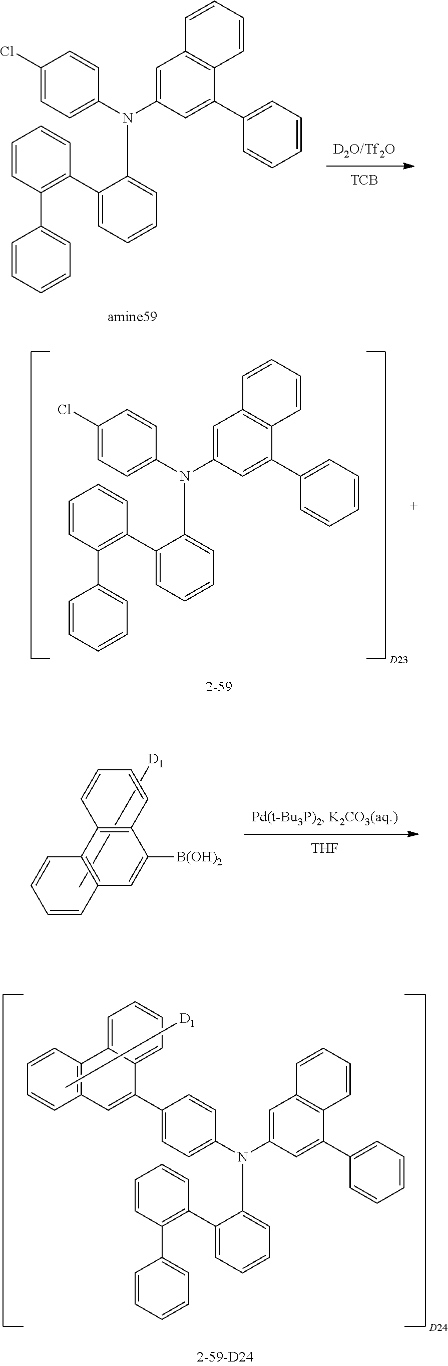

Compound amine59(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(45.5 g, 161.3 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.3 g of Compound 2-59. (Yield: 41%, MS: [M+H]⁺=582).

Compound 2-59(15 g, 25.8 mmol) and phenanthren-9-ylboronic acid_D1(6 g, 27.1 mmol) were added to 300 ml of THF, and the mixture was stirred and refluxed. Then, potassium carbonate(10.7 g, 77.4 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 11.2 g of Compound 2-59-D24. (Yield: 60%, MS: [M+H]⁺=725)

### Preparation Example 2-60

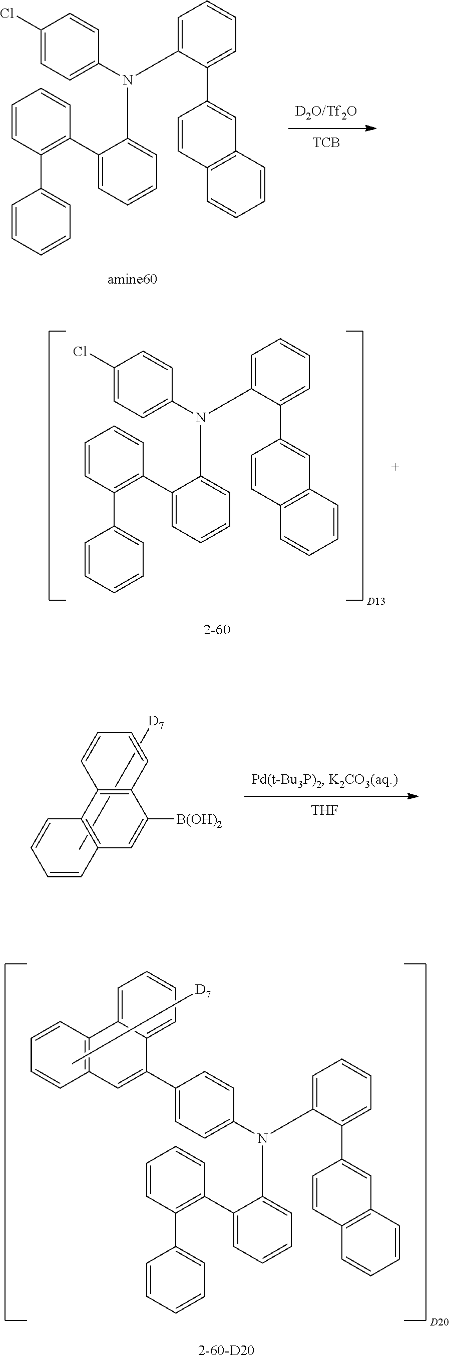

Compound amine60(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(30.3 g, 107.5 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.7 g of Compound 2-60. (Yield: 46%, MS: [M+H]⁺=572).

Compound 2-60(15 g, 26.3 mmol) and phenanthren-9-ylboronic acid_D7(6.3 g, 27.6 mmol) were added to 300 ml of THF, and the mixture was stirred and refluxed. Then, potassium carbonate(10.9 g, 78.8 mmol) was dissolved in 100 ml of water and added thereto, and the mixture was sufficiently stirred and then bis(tri-tert-butylphosphine)palladium(0) (0.1 g, 0.3 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.2 g of Compound 2-60-D20. (Yield: 75%, MS: [M+H]⁺=721)

### Preparation Example 2-61

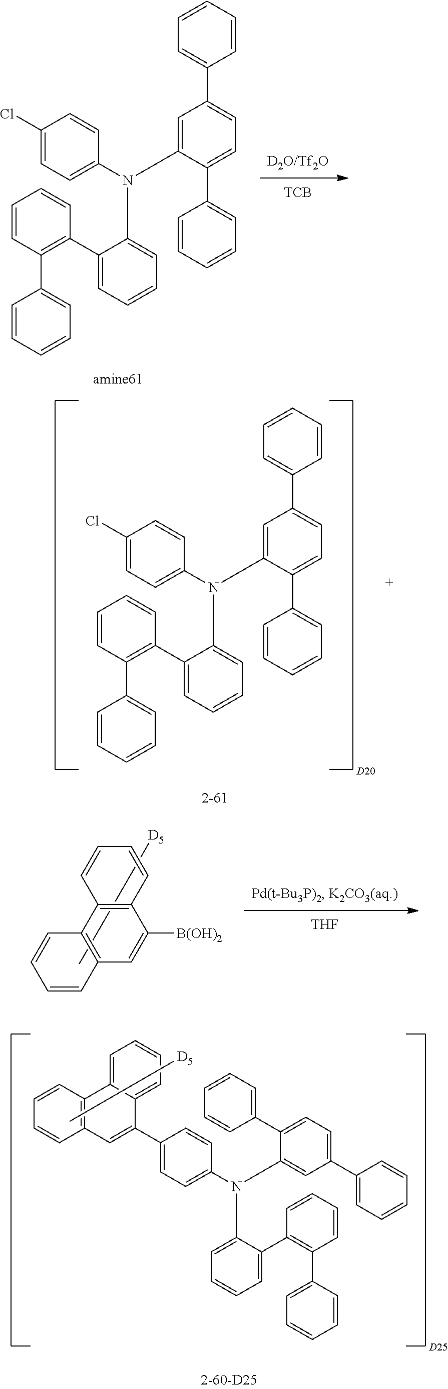

Compound amine61(10 g, 17.1 mmol) was added to 200 ml of 1,2,4-trichlorobenzene, and the mixture was stirred at room temperature. In another vessel, deuterium oxide(12.3 g, 616.3 mmol) was added to trifluoromethanesulfonic anhydride(43.5 g, 154.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.2 g of Compound 2-61. (Yield: 41%, MS: [M+H]⁺=605).

Compound 2-61(15 g, 24.8 mmol) and phenanthren-9-ylboronic acid_D5(5.9 g, 26.1 mmol) were added to 300 ml of THF, and the mixture was stirred and refluxed. Then, potassium carbonate(10.3 g, 74.5 mmol) was dissolved in 100 ml of water and added thereto, and the mixture was sufficiently stirred and then bis(tri-tert-butylphosphine)palladium(0) (0.1 g, 0.2 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 11.6 g of Compound 2-61-D25. (Yield: 62%, MS: [M+H]⁺=752)

### Preparation Example 2-62

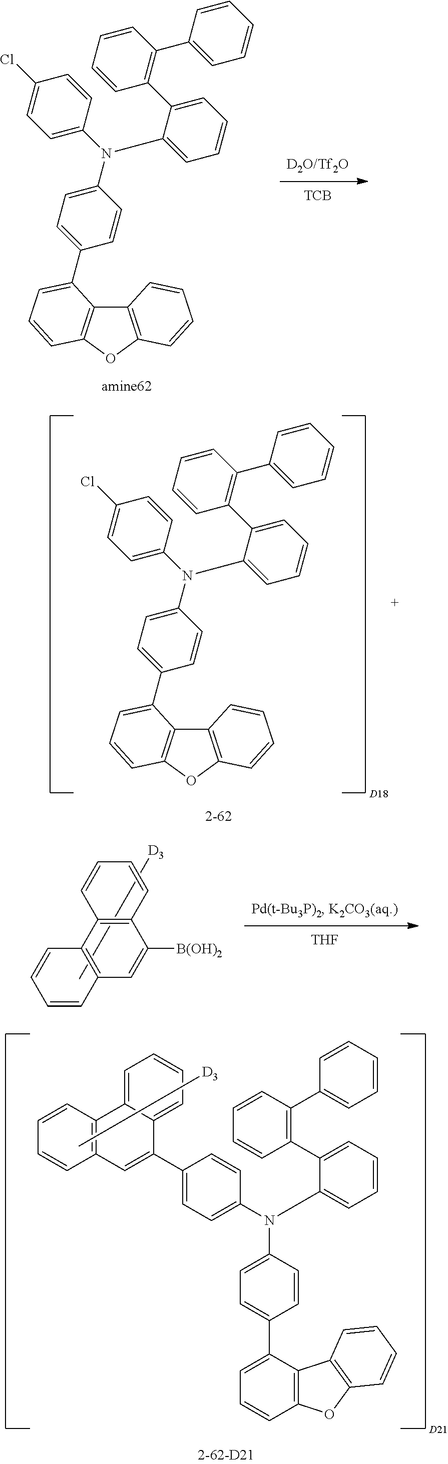

Compound amine62(10 g, 16.7 mmol) was added to 200 ml of 1,2,4-trichlorobenzene, and the mixture was stirred at room temperature. In another vessel, deuterium oxide(12.1 g, 601.9 mmol) was added to trifluoromethanesulfonic anhydride(42.5 g, 150.5 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.6 g of Compound 2-62. (Yield: 45%, MS: [M+H]⁺=617).

Compound 2-62(15 g, 24.3 mmol) and phenanthren-9-ylboronic acid_D3(5.8 g, 25.6 mmol) were added to 300 ml of THF, and the mixture was stirred and refluxed. Then, potassium carbonate(10.1 g, 73 mmol) was dissolved in 100 ml of water and added thereto, and the mixture was sufficiently stirred and then bis(tri-tert-butylphosphine)palladium(0) (0.1 g, 0.2 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.2 g of Compound 2-62-D21. (Yield: 71%, MS: [M+H]⁺=762)

### Preparation Example 2-63

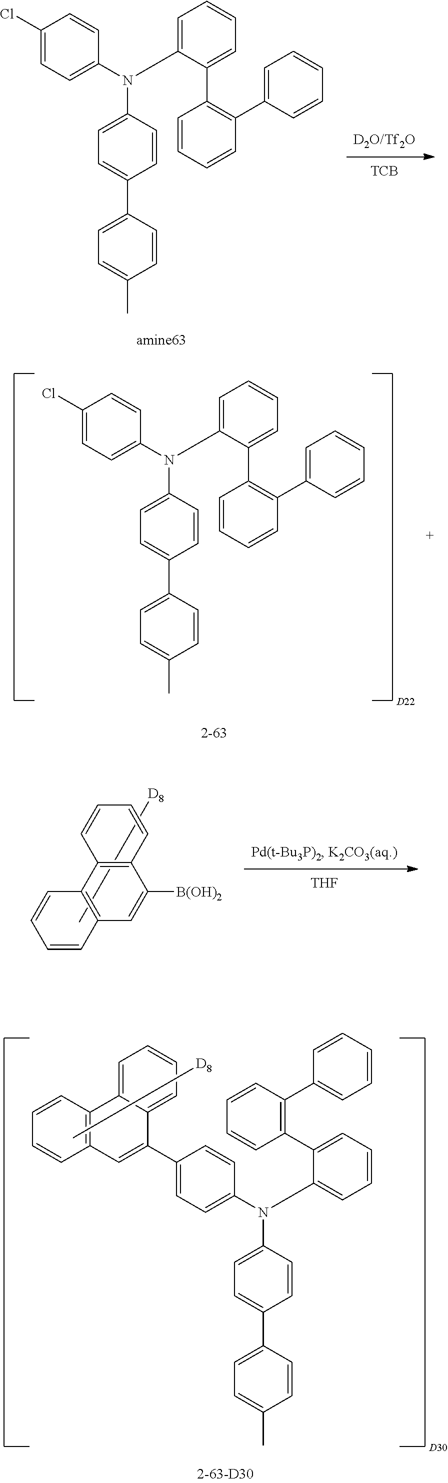

Compound amine63(10 g, 19.2 mmol) was added to 200 ml of 1,2,4-trichlorobenzene, and the mixture was stirred at room temperature. In another vessel, deuterium oxide(13.8 g, 689.5 mmol) was added to trifluoromethanesulfonic anhydride(48.6 g, 172.4 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.8 g of Compound 2-63. (Yield: 46%, MS: [M+H]⁺=545).

Compound 2-63(15 g, 27.6 mmol) and phenanthren-9-ylboronic acid_D8(6.7 g, 28.9 mmol) were added to 300 ml of THF, and the mixture was stirred and refluxed. Then, potassium carbonate(11.4 g, 82.7 mmol) was dissolved in 100 ml of water and added thereto, and the mixture was sufficiently stirred and then bis(tri-tert-butylphosphine)palladium(0) (0.1 g, 0.3 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.2 g of Compound 2-63-D30. (Yield: 69%, MS: [M+H]⁺=695)

### Preparation Example 2-64

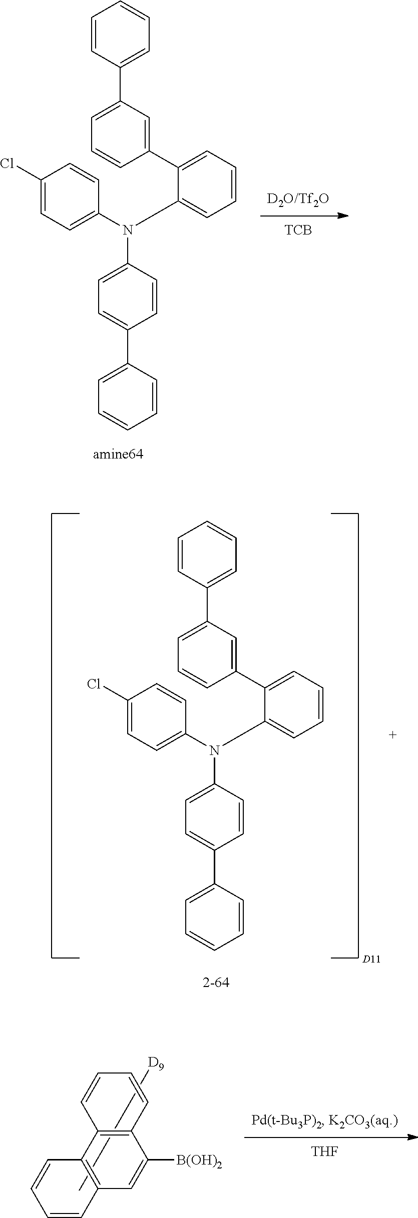

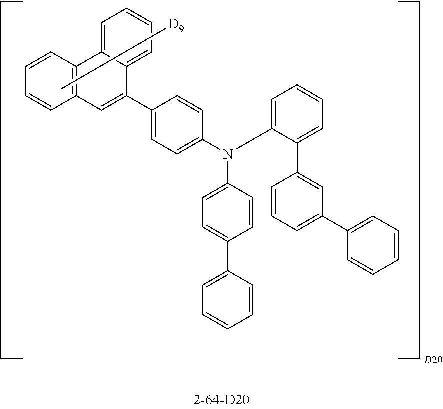

Compound amine64(10 g, 19.7 mmol) was added to 200 ml of 1,2,4-trichlorobenzene, and the mixture was stirred at room temperature. In another vessel, deuterium oxide(14.2 g, 708.6 mmol) was added to trifluoromethanesulfonic anhydride(33.3 g, 118.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.8 g of Compound 2-64. (Yield: 47%, MS: [M+H]⁺=520).

Compound 2-64(15 g, 28.9 mmol) and phenanthren-9-ylboronic acid_D9(7 g, 30.3 mmol) were added to 300 ml of THF, and the mixture was stirred and refluxed. Then, potassium carbonate(12 g, 86.7 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.1 g of Compound 2-64-D20. (Yield: 73%, MS: [M+H]⁺=671)

### Preparation Example 2-65

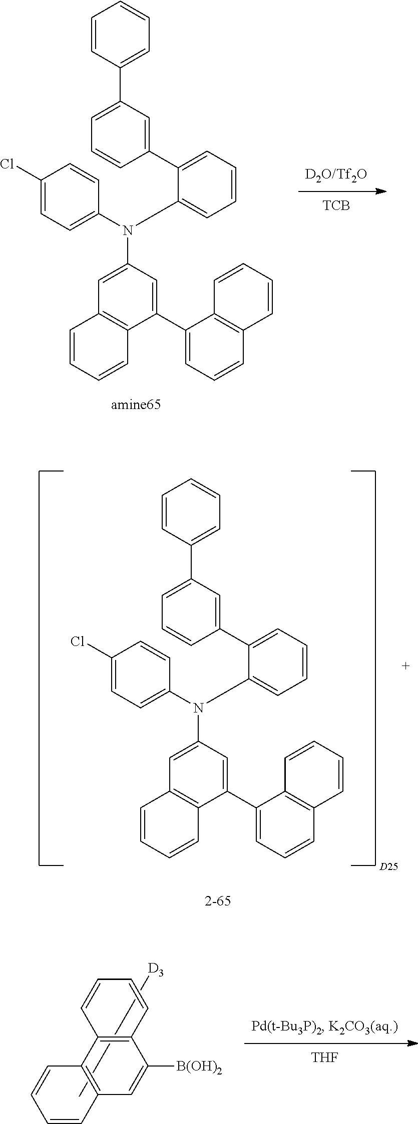

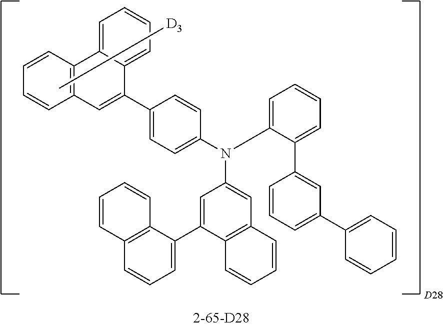

Compound amine65(10 g, 16.4 mmol) was added to 200 ml of 1,2,4-trichlorobenzene, and the mixture was stirred at room temperature. In another vessel, deuterium oxide(11.9 g, 591.9 mmol) was added to trifluoromethanesulfonic anhydride(41.8 g, 148 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.4 g of Compound 2-65. (Yield: 42%, MS: [M+H]⁺=634).

Compound 2-65(15 g, 23.7 mmol) and phenanthren-9-ylboronic acid_D3(5.6 g, 24.9 mmol) were added to 300 ml of THF, and the mixture was stirred and refluxed. Then, potassium carbonate(9.8 g, 71.1 mmol) was dissolved in 100 ml of water and added thereto, and the mixture was sufficiently stirred and then bis(tri-tert-butylphosphine)palladium(0) (0.1 g, 0.2 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.6 g of Compound 2-65-D28. (Yield: 79%, MS: [M+H]⁺=779)

### Preparation Example 2-66

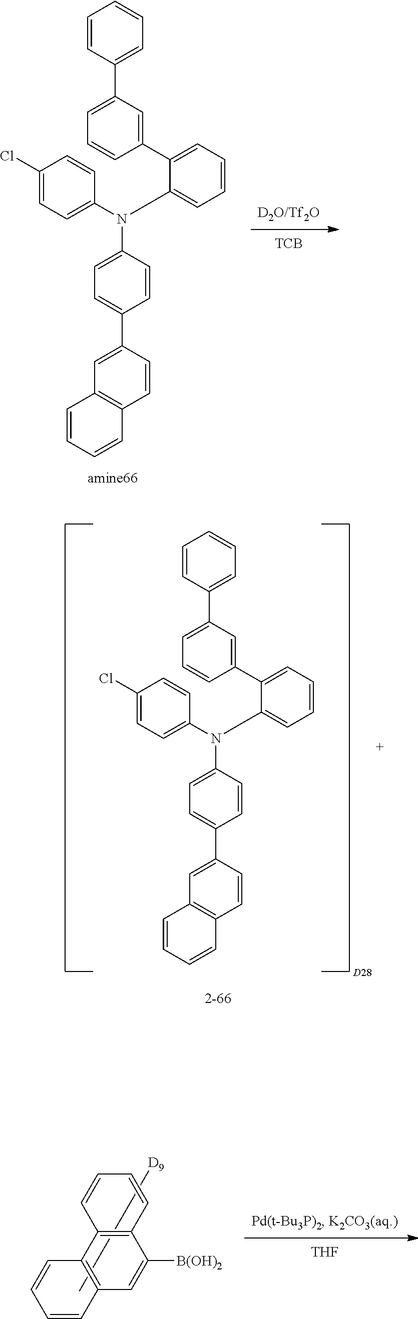

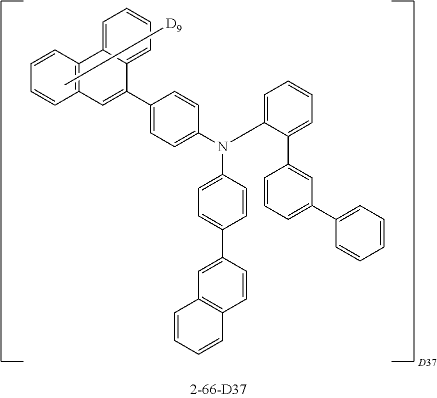

Compound amine66(10 g, 17.9 mmol) was added to 200 ml of 1,2,4-trichlorobenzene, and the mixture was stirred at room temperature. In another vessel, deuterium oxide(12.9 g, 645 mmol) was added to trifluoromethanesulfonic anhydride(60.7 g, 215 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 15 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.5 g of Compound 2-66. (Yield: 43%, MS: [M+H]⁺=587).

Compound 2-66(15 g, 25.6 mmol) and phenanthren-9-ylboronic acid_D9(6.2 g, 26.9 mmol) were added to 300 ml of THF, and the mixture was stirred and refluxed. Then, potassium carbonate(10.6 g, 76.8 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.2 g of Compound 2-66-D37. (Yield: 70%, MS: [M+H]⁺=738)

### Preparation Example 2-67

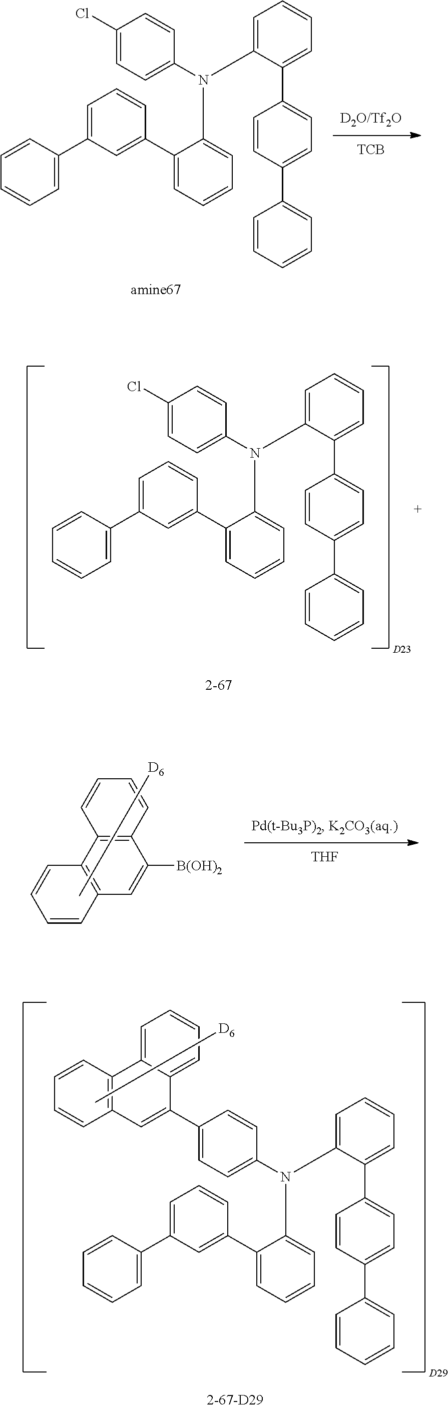

Compound amine67(10 g, 17.1 mmol) was added to 200 ml of 1,2,4-trichlorobenzene, and the mixture was stirred at room temperature. In another vessel, deuterium oxide(12.3 g, 616.3 mmol) was added to trifluoromethanesulfonic anhydride(43.5 g, 154.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.7 g of Compound 2-67. (Yield: 45%, MS: [M+H]⁺=608).

Compound 2-67(15 g, 24.7 mmol) and phenanthren-9-ylboronic acid_D6(5.9 g, 25.9 mmol) were added to 300 ml of THF, and the mixture was stirred and refluxed. Then, potassium carbonate(10.2 g, 74.1 mmol) was dissolved in 100 ml of water and added thereto, and the mixture was sufficiently stirred and then bis(tri-tert-butylphosphine)palladium(0) (0.1 g, 0.2 mmol) was added. After the reaction for 4 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12.9 g of Compound 2-67-D29. (Yield: 69%, MS: [M+H]⁺=756)

### Preparation Example 2-68

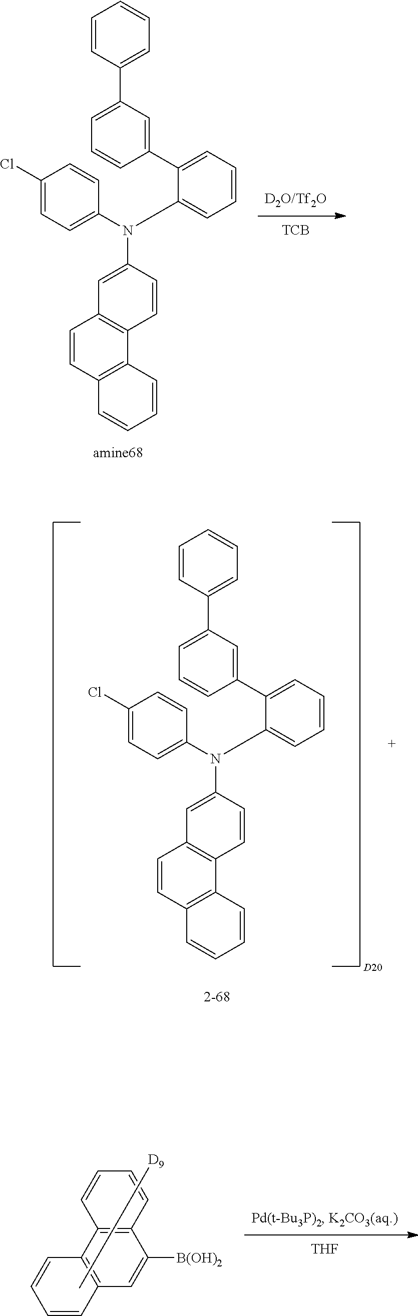

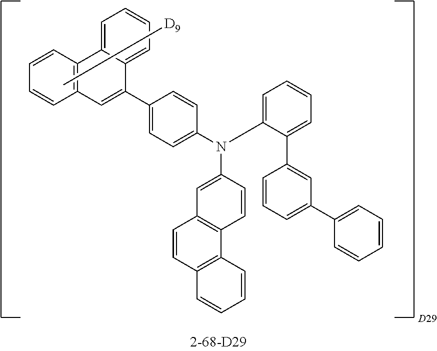

Compound amine68(10 g, 18.8 mmol) was added to 200 ml of 1,2,4-trichlorobenzene, and the mixture was stirred at room temperature. In another vessel, deuterium oxide(13.6 g, 676.6 mmol) was added to trifluoromethanesulfonic anhydride(47.7 g, 169.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.5 g of Compound 2-68. (Yield: 43%, MS: [M+H]⁺=553).

Compound 2-68(15 g, 27.2 mmol) and phenanthren-9-ylboronic acid_D9(6.6 g, 28.5 mmol) were added to 300 ml of THF, and the mixture was stirred and refluxed. Then, potassium carbonate(11.3 g, 81.5 mmol) was dissolved in 100 ml of water and added thereto, and the mixture was sufficiently stirred and then bis(tri-tert-butylphosphine)palladium(0) (0.1 g, 0.3 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 13.2 g of Compound 2-68-D29. (Yield: 69%, MS: [M+H]⁺=704)

### Preparation Example 2-69

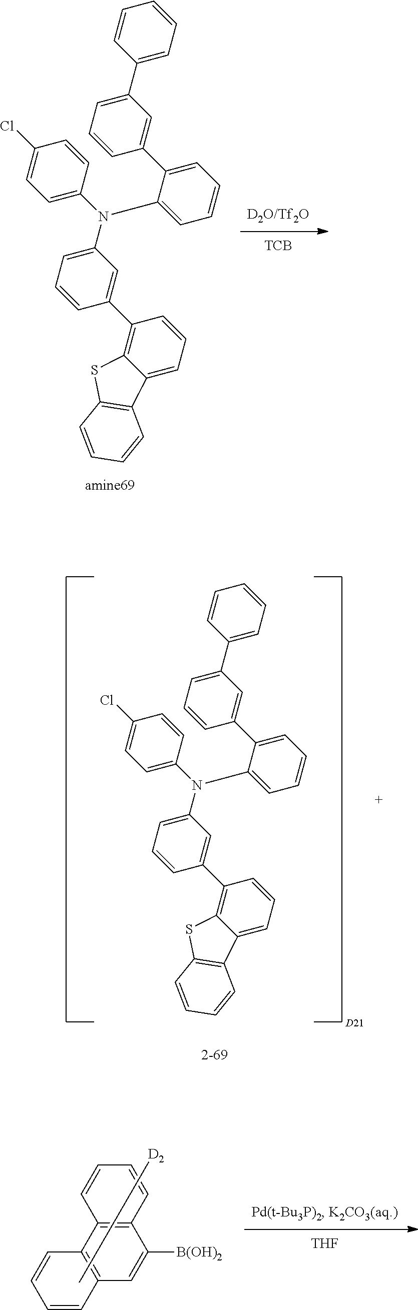

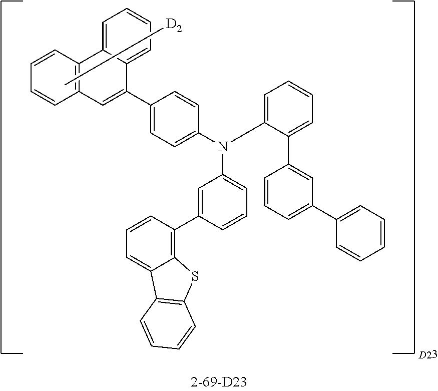

Compound amine69(10 g, 16.3 mmol) was added to 200 ml of 1,2,4-trichlorobenzene, and the mixture was stirred at room temperature. In another vessel, deuterium oxide(11.7 g, 586.1 mmol) was added to trifluoromethanesulfonic anhydride(41.3 g, 146.5 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.3 g of Compound 2-69. (Yield: 42%, MS: [M+H]⁺=636).

Compound 2-69(15 g, 23.6 mmol) and phenanthren-9-ylboronic acid_D2(5.6 g, 24.8 mmol) were added to 300 ml of THF, and the mixture was stirred and refluxed. Then, potassium carbonate(9.8 g, 70.8 mmol) was dissolved in 100 ml of water and added thereto, and the mixture was sufficiently stirred and then bis(tri-tert-butylphosphine)palladium(0) (0.1 g, 0.2 mmol) was added. After the reaction for 5 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 12 g of Compound 2-69-D23. (Yield: 65%, MS: [M+H]⁺=780)

### Preparation Example 2-70

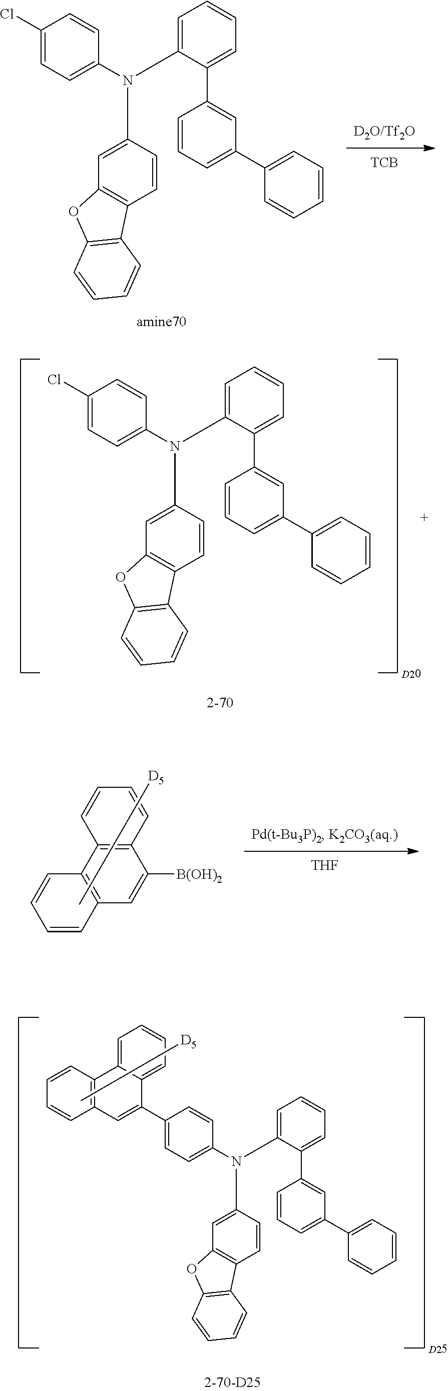

Compound amine70(10 g, 19.2 mmol) was added to 200 ml of 1,2,4-trichlorobenzene, and the mixture was stirred at room temperature. In another vessel, deuterium oxide(13.8 g, 689.6 mmol) was added to trifluoromethanesulfonic anhydride(48.6 g, 172.4 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 8 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.1 g of Compound 2-70. (Yield: 40%, MS: [M+H]⁺=541).

Compound 2-70(15 g, 27.7 mmol) and phenanthren-9-ylboronic acid_D5(6.6 g, 29.1 mmol) were added to 300 ml of THF, and the mixture was stirred and refluxed. Then, potassium carbonate(11.5 g, 83 mmol) was dissolved in 100 ml of water and added thereto, and the mixture was sufficiently stirred and then bis(tri-tert-butylphosphine)palladium(0) (0.1 g, 0.3 mmol) was added. After the reaction for 4 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.1 g of Compound 2-70-D25. (Yield: 74%, MS: [M+H]⁺=690)

### Preparation Example 2-71

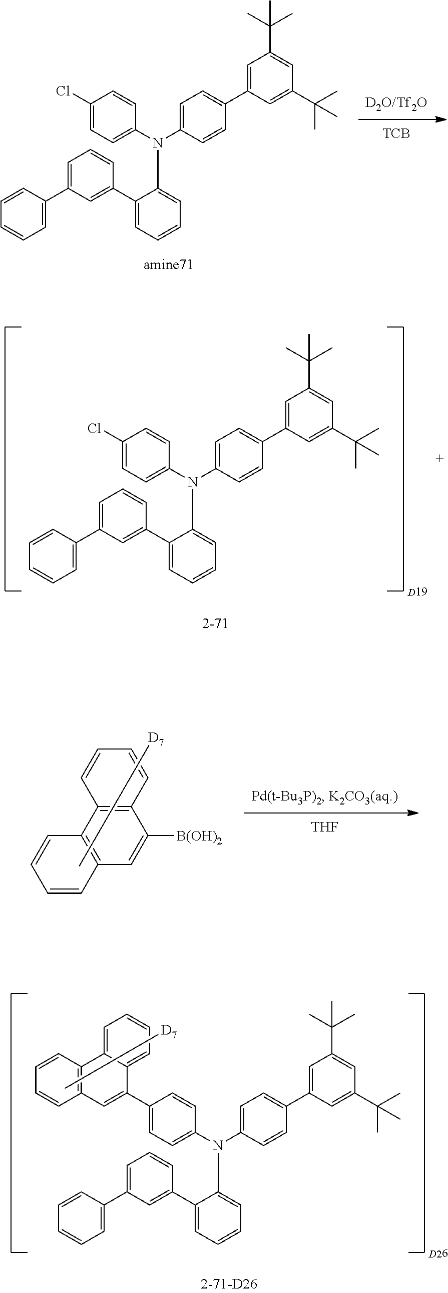

Compound amine71(10 g, 16.1 mmol) was added to 200 ml of 1,2,4-trichlorobenzene, and the mixture was stirred at room temperature. In another vessel, deuterium oxide(11.6 g, 580.4 mmol) was added to trifluoromethanesulfonic anhydride(27.3 g, 96.7 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.8 g of Compound 2-71. (Yield: 47%, MS: [M+H]⁺=640).

Compound 2-71(15 g, 23.5 mmol) and phenanthren-9-ylboronic acid_D7(5.6 g, 24.6 mmol) were added to 300 ml of THF, and the mixture was stirred and refluxed. Then, potassium carbonate(9.7 g, 70.4 mmol) was dissolved in 100 ml of water and added thereto, and the mixture was sufficiently stirred and then bis(tri-tert-butylphosphine)palladium(0) (0.1 g, 0.2 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.2 g of Compound 2-71-D26. (Yield: 77%, MS: [M+H]⁺=789)

### Preparation Example 2-72

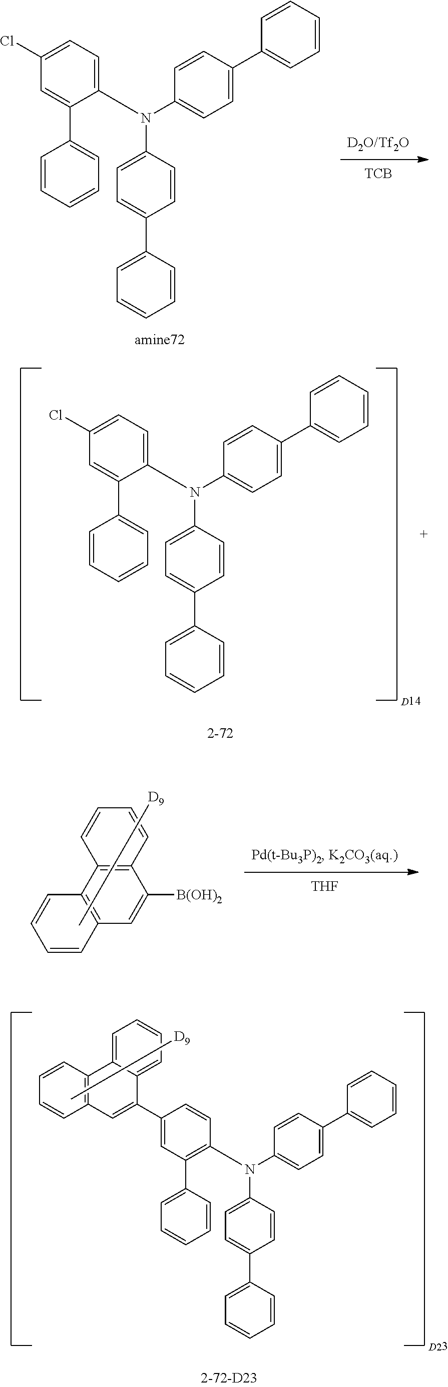

Compound amine72(10 g, 19.7 mmol) was added to 200 ml of 1,2,4-trichlorobenzene, and the mixture was stirred at room temperature. In another vessel, deuterium oxide(14.2 g, 708.6 mmol) was added to trifluoromethanesulfonic anhydride(33.3 g, 118.1 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 4.2 g of Compound 2-72. (Yield: 41%, MS: [M+H]⁺=523).

Compound 2-72(15 g, 28.7 mmol) and phenanthren-9-ylboronic acid_D9(7 g, 30.2 mmol) were added to 300 ml of THF, and the mixture was stirred and refluxed. Then, potassium carbonate(11.9 g, 86.2 mmol) was dissolved in 100 ml of water and added thereto, and the mixture was sufficiently stirred and then bis(tri-tert-butylphosphine)palladium(0) (0.1 g, 0.3 mmol) was added. After the reaction for 2 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 14.9 g of Compound 2-72-D23. (Yield: 77%, MS: [M+H]⁺=674)

### Preparation Example 2-73

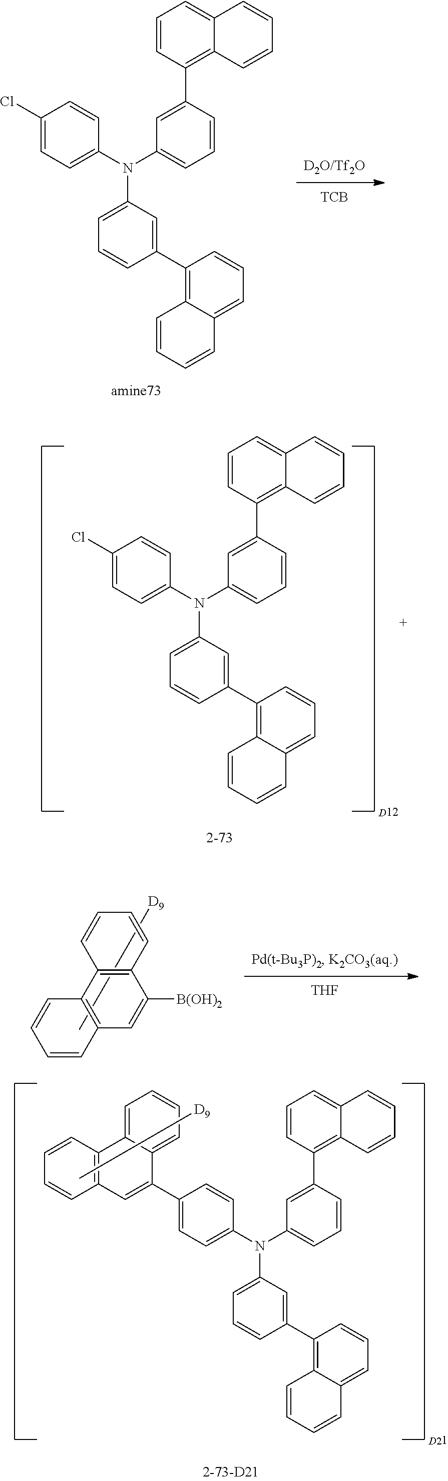

Compound amine73(20 g, 37.6 mmol) was added to 200 ml of 1,2,4-trichlorobenzene, and the mixture was stirred at room temperature. In another vessel, deuterium oxide(14.2 g, 708.6 mmol) was added to trifluoromethanesulfonic anhydride(66.6 g, 236.2 mmol) at 0° C., and the mixture was stirred for 10 hours to prepare a solution. Then, a mixed solution of trifluoromethanesulfonic anhydride and deuterium oxide was added dropwise to the prepared mixed solution of 1,2,4-trichlorobenzene, and the mixture was stirred while heating to 140° C. and then keeping that temperature. After the reaction for 4 hours, the reaction mixture was cooled to room temperature, and the organic layer and the aqueous layer were separated. Then, the organic layer was neutralized with an aqueous potassium carbonate solution. After washing twice with water, the organic layer was separated, anhydrous magnesium sulfate was added thereto, stirred, then filtered, and the filtrate was distilled under reduced pressure. The concentrated compound was purified by a silica gel column chromatography to prepare 10.8 g of Compound 2-73. (Yield: 53%, MS: [M+H]⁺=544).

Compound 2-73(15 g, 27.6 mmol) and phenanthren-9-ylboronic acid_D9(7 g, 29.0 mmol) were added to 300 ml of THF, and the mixture was stirred and refluxed. Then, potassium carbonate(12 g, 86.5 mmol) was dissolved in 100 ml of water and added thereto, and the mixture was sufficiently stirred and then bis(tri-tert-butylphosphine)palladium(0) (0.1 g, 0.3 mmol) was added. After the reaction for 3 hours, the reaction mixture was cooled to room temperature, the organic layer and the aqueous layer were separated, and the organic layer was distilled. This was again dissolved in chloroform, washed twice with water, and then the organic layer was separated, anhydrous magnesium sulfate was added thereto, stirred, then filtered, and the filtrate was distilled under reduced pressure. The concentrated compound was purified by a silica gel column chromatography to prepare 9.6 g of Compound 2-73-D21. (Yield: 75%, MS: [M+H]⁺=674)

### Example 1

A glass substrate on which ITO (indium tin oxide) was coated as a thin film to a thickness of 1000 Å was put into distilled water in which a detergent was dissolved, and ultrasonically cleaned. A product manufactured by Fischer Co. was used as the detergent, and as the distilled water, distilled water filtered twice using a filter manufactured by Millipore Co. was used. After the ITO was cleaned for 30 minutes, ultrasonic cleaning was repeated twice using distilled water for 10 minutes. After the cleaning with distilled water was completed, the substrate was ultrasonically cleaned with solvents of isopropyl alcohol, acetone, and methanol, dried, and then transferred to a plasma cleaner. In addition, the substrate was cleaned for 5 minutes using oxygen plasma and then transferred to a vacuum depositor.

On the ITO transparent electrode thus prepared, the following compound HI-1 was formed to a thickness of 1150 Å as a hole injection layer, but the following compound A-1 was p-doped at a concentration of 1.5 wt. %. The following compound HT-1 was vacuum deposited on the hole injection layer to form a hole transport layer with a layer thickness of 800 Å. Then, the following compound EB-1 was vacuum deposited on the hole transport layer to a layer thickness of 150 Å to form an electron blocking layer. Then, the following compound 1-1 as a first host, the following compound 2-1-D22 a second host and the following Compound Dp-7 as a dopant were vacuum deposited in a weight ratio of 49:49:2 on the EB-1 deposited layer to form a red light emitting layer with a layer thickness of 400 Å. The following compound HB-1 was vacuum deposited on the light emitting layer to a layer thickness of 30 Å to form a hole blocking layer. Then, the following compound ET-1 and the following compound LiQ were vacuum deposited in a weight ratio of 2:1 on the hole blocking layer to form an electron injection and transport layer with a layer thickness of 300 Å. Lithium fluoride (LiF) and aluminum were sequentially deposited to have a thickness of 12 Å and 1000 Å, respectively, on the electron injection and transport layer, thereby forming a cathode.

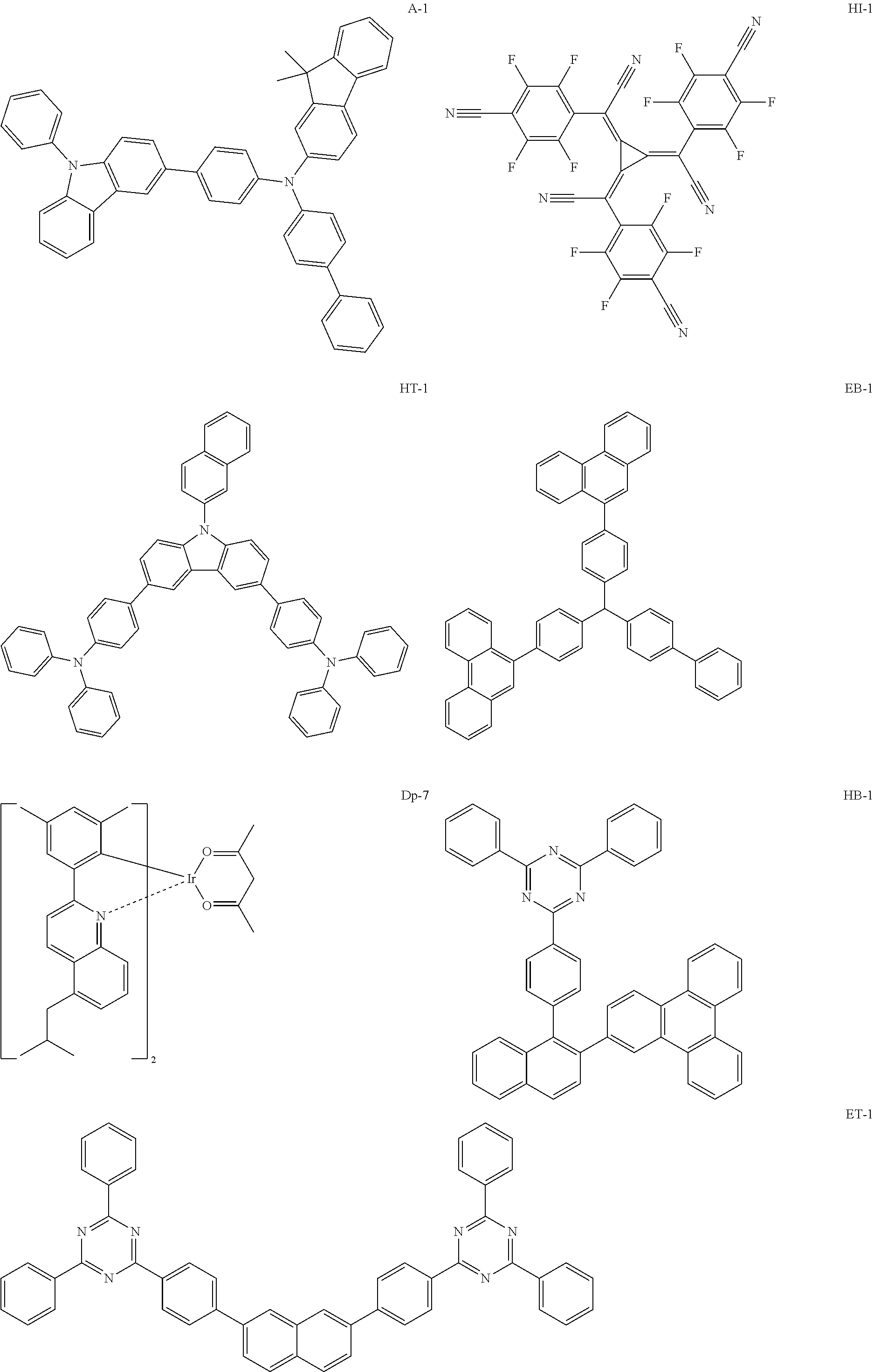

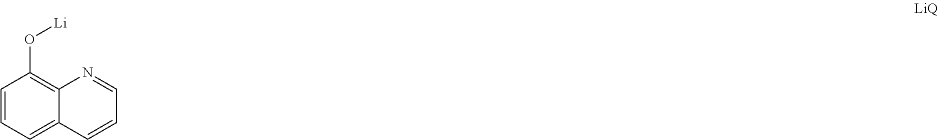

In the above-mentioned processes, the vapor deposition rate of the organic material was maintained at 0.4~0.7 Å/sec, the deposition rates of lithium fluoride and aluminum of the cathode were maintained at 0.3 Å/sec and 2 Å/sec, respectively, and the degree of vacuum during the deposition was maintained at 2*10⁻⁷~5*10⁻⁶ torr, thereby manufacturing an organic light emitting device.

### Example 2 to Example 245

The organic light emitting device was manufactured in the same manner as in Example 1, except that the compound represented by Chemical Formula 1 as the first host and the compound represented by Chemical Formula 2 as the second host were co-deposited and used in a ratio of 1:1 as shown in Tables 1 to 6 below instead of Compound 1 in the organic light emitting device of Example 1.

### Comparative Example 1 to Comparative Example 60

The organic light emitting device was manufactured in the same manner as in Example 1, except that Comparative Compounds A-1 to A-12 as the first host and the compound represented by Chemical Formula 2 as the second host were co-deposited and used in a ratio of 1:1 as shown in Tables 7 and 8 below instead of Compound 1 in the organic light emitting device of Example 1. Compounds A-1 to A-12 shown in Tables 7 and 8 below are as follows.

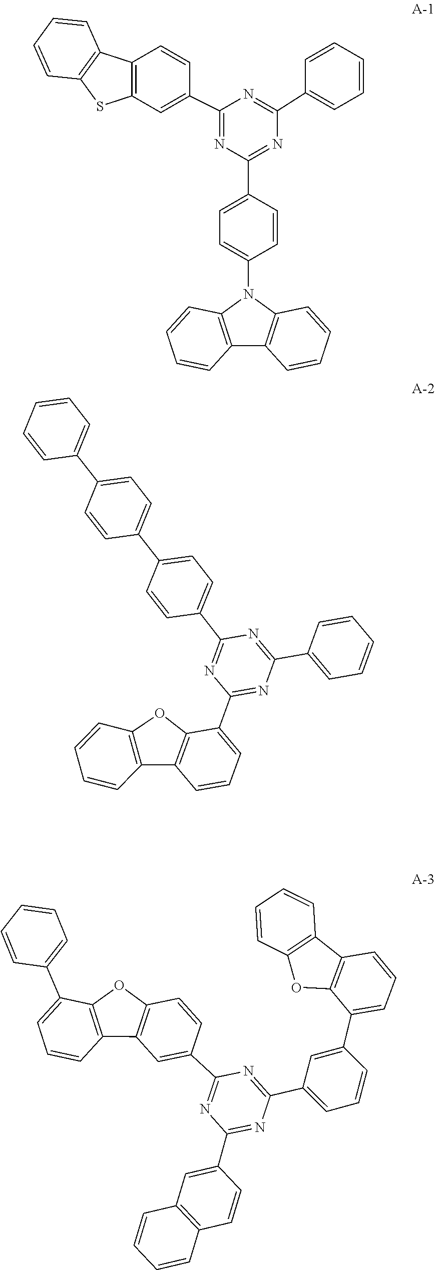 [SMILES: c1ccc(-c2nc(-c3ccc(-n4c5ccccc5c5ccccc54)cc3)nc(-c3ccc4c(c3)sc3ccccc34)n2)cc1 ; c1ccc(-c2ccc(-c3ccc(-c4nc(-c5ccccc5)nc(-c5cccc6c5oc5ccccc56)n4)cc3)cc2)cc1 ; c1ccc(-c2cccc3c2oc2ccc(-c4nc(-c5cccc(-c6cccc7c6oc6ccccc67)c5)nc(-c5ccc6ccccc6c5)n4)cc23)cc1]

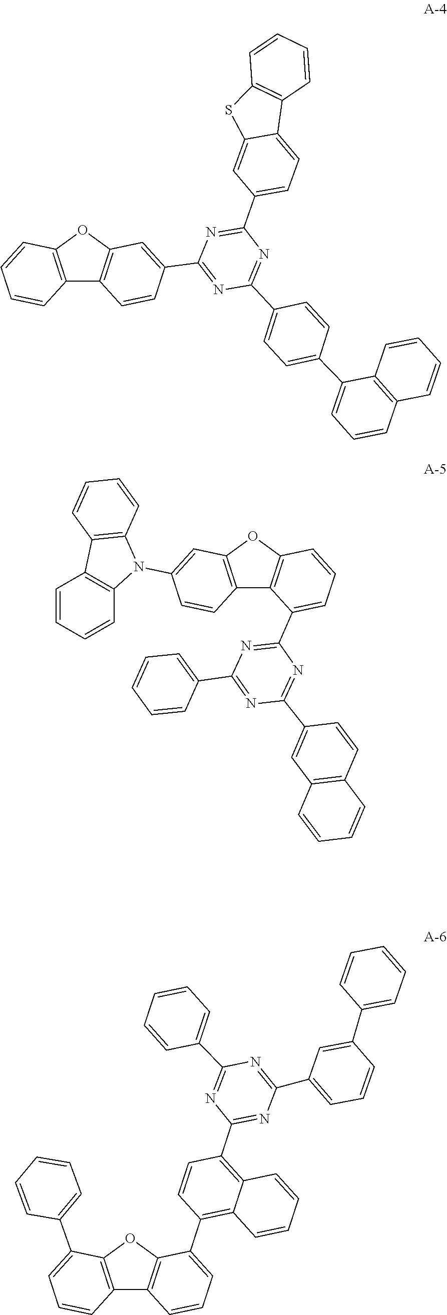 [SMILES: c1ccc2c(-c3ccc(-c4nc(-c5ccc6c(c5)oc5ccccc56)nc(-c5ccc6c(c5)sc5ccccc56)n4)cc3)cccc2c1 ; c1ccc(-c2nc(-c3ccc4ccccc4c3)nc(-c3cccc4oc5cc(-n6c7ccccc7c7ccccc76)ccc5c34)n2)cc1 ; c1ccc(-c2cccc(-c3nc(-c4ccccc4)nc(-c4ccc(-c5cccc6c5oc5c(-c7ccccc7)cccc56)c5ccccc45)n3)c2)cc1]

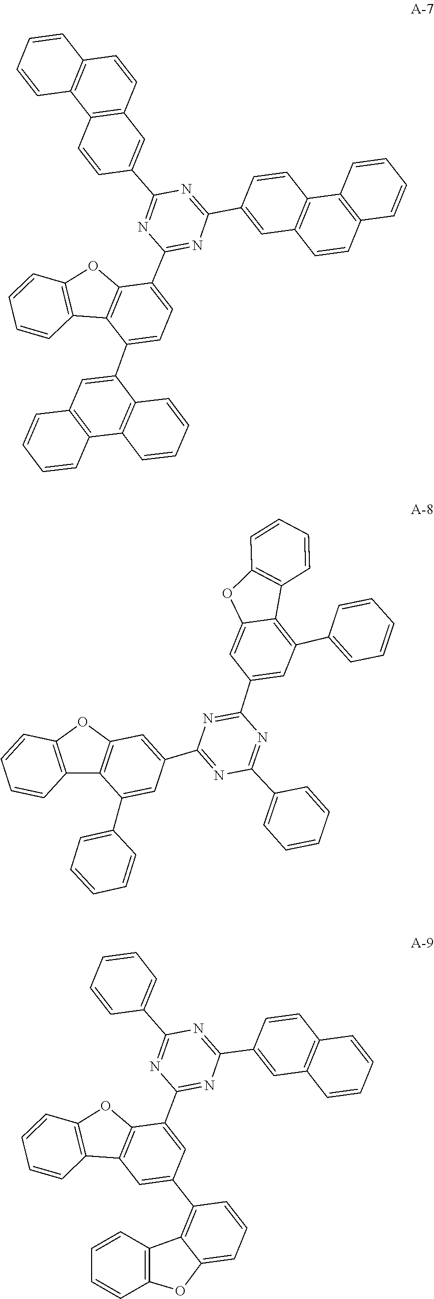 [SMILES: c1ccc2c(c1)ccc1cc(-c3nc(-c4ccc5c(ccc6ccccc65)c4)nc(-c4ccc(-c5cc6ccccc6c6ccccc56)c5c4oc4ccccc45)n3)ccc12 ; c1ccc(-c2nc(-c3cc(-c4ccccc4)c4c(c3)oc3ccccc34)nc(-c3cc(-c4ccccc4)c4c(c3)oc3ccccc34)n2)cc1 ; c1ccc(-c2nc(-c3ccc4ccccc4c3)nc(-c3cc(-c4cccc5oc6ccccc6c45)cc4c3oc3ccccc34)n2)cc1]

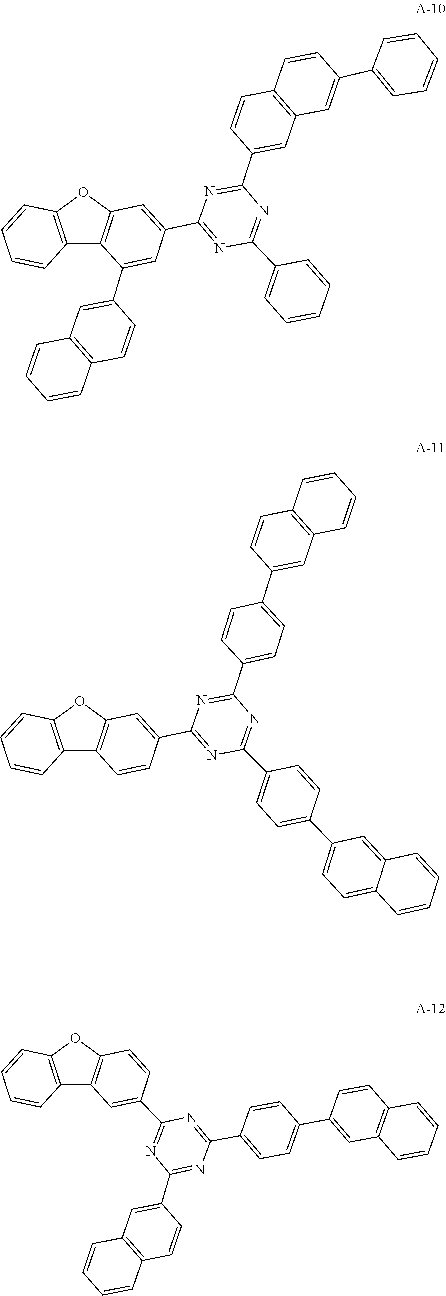 [SMILES: c1ccc(-c2ccc3ccc(-c4nc(-c5ccccc5)nc(-c5cc(-c6ccc7ccccc7c6)c6c(c5)oc5ccccc56)n4)cc3c2)cc1 ; c1ccc2cc(-c3ccc(-c4nc(-c5ccc(-c6ccc7ccccc7c6)cc5)nc(-c5ccc6c(c5)oc5ccccc56)n4)cc3)ccc2c1 ; c1ccc2cc(-c3ccc(-c4nc(-c5ccc6ccccc6c5)nc(-c5ccc6oc7ccccc7c6c5)n4)cc3)ccc2c1]

### Comparative Example 61 to Comparative Example 268

The organic light emitting device was manufactured in the same manner as in Example 1, except that the compound represented by Chemical Formula 1 as the first host and Comparative Compounds shown in Tables 9 to 13 below were co-deposited and used in a ratio of 1:1 as shown in Tables 9 to 14 below instead of Compound 1 in the organic light emitting device of Example 1. The second host compounds shown in Tables 9 to 14 below are as follows.

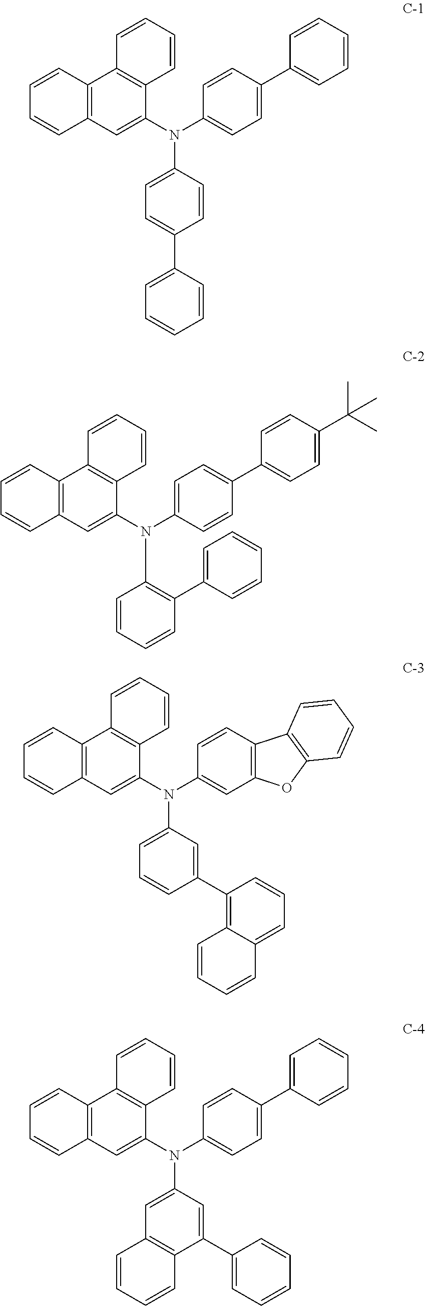

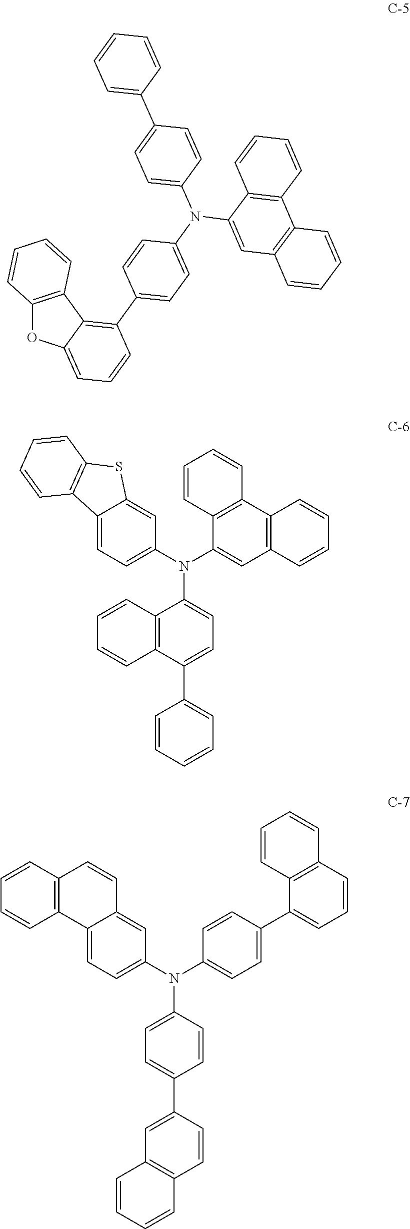 [SMILES: c1ccc(-c2ccc(N(c3ccc(-c4cccc5oc6ccccc6c45)cc3)c3cc4ccccc4c4ccccc34)cc2)cc1 ; c1ccc(-c2ccc(N(c3ccc4c(c3)sc3ccccc34)c3cc4ccccc4c4ccccc34)c3ccccc23)cc1 ; c1ccc2cc(-c3ccc(N(c4ccc(-c5cccc6ccccc56)cc4)c4ccc5c(ccc6ccccc65)c4)cc3)ccc2c1]

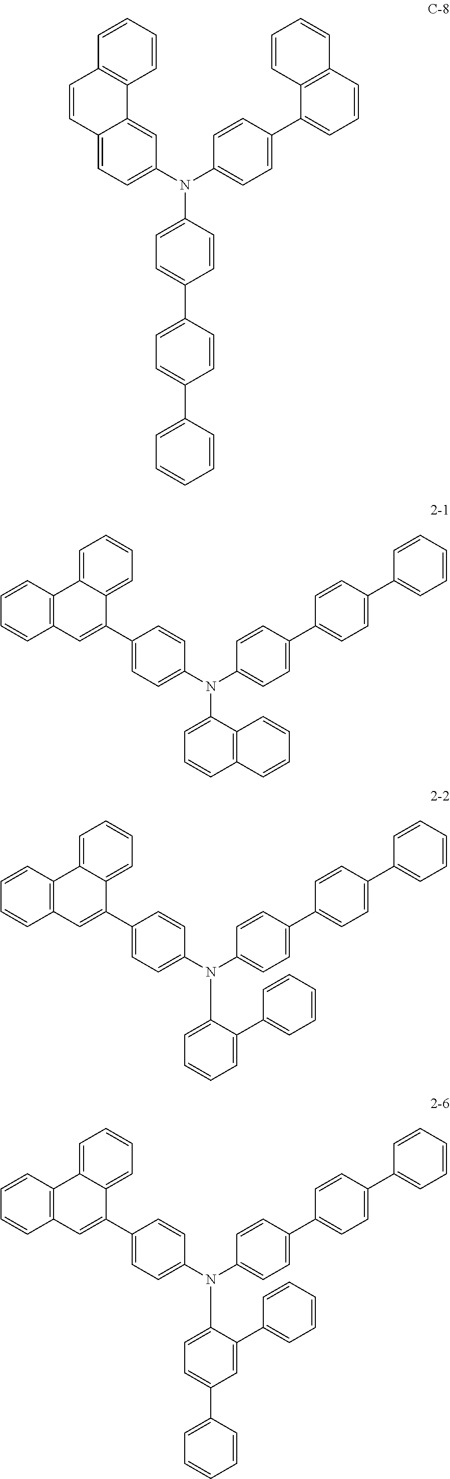 [SMILES: c1ccc(-c2ccc(-c3ccc(N(c4ccc(-c5cccc6ccccc56)cc4)c4ccc5ccc6ccccc6c5c4)cc3)cc2)cc1 ; c1ccc(-c2ccc(-c3ccc(N(c4ccc(-c5cc6ccccc6c6ccccc56)cc4)c4cccc5ccccc45)cc3)cc2)cc1 ; c1ccc(-c2ccc(-c3ccc(N(c4ccc(-c5cc6ccccc6c6ccccc56)cc4)c4ccccc4-c4ccccc4)cc3)cc2)cc1 ; c1ccc(-c2ccc(-c3ccc(N(c4ccc(-c5cc6ccccc6c6ccccc56)cc4)c4ccc(-c5ccccc5)cc4-c4ccccc4)cc3)cc2)cc1]

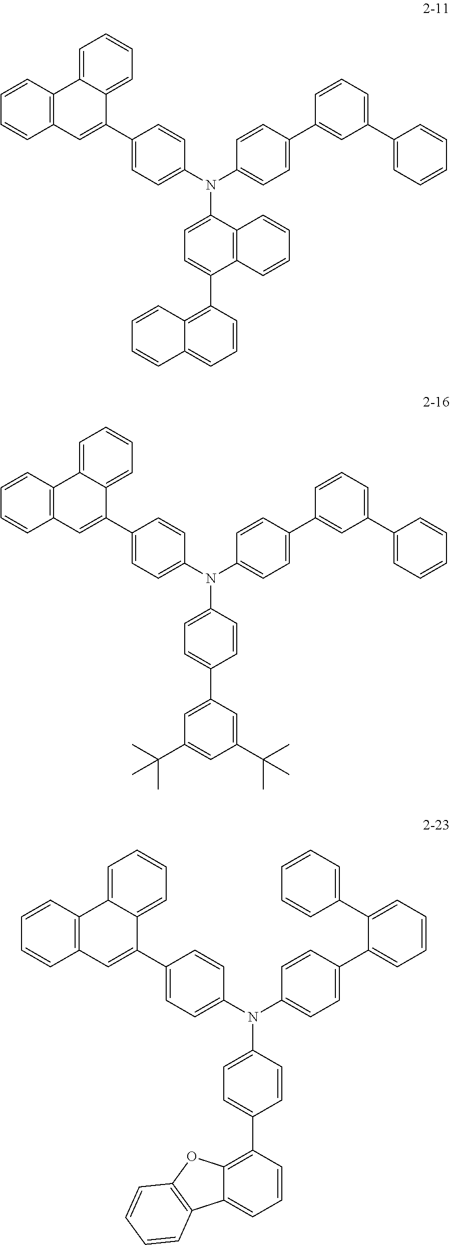 [SMILES: c1ccc(-c2cccc(-c3ccc(N(c4ccc(-c5cc6ccccc6c6ccccc56)cc4)c4ccc(-c5cccc6ccccc56)c5ccccc45)cc3)c2)cc1 ; CC(C)(C)c1cc(-c2ccc(N(c3ccc(-c4cccc(-c5ccccc5)c4)cc3)c3ccc(-c4cc5ccccc5c5ccccc45)cc3)cc2)cc(C(C)(C)C)c1 ; c1ccc(-c2ccccc2-c2ccc(N(c3ccc(-c4cc5ccccc5c5ccccc45)cc3)c3ccc(-c4cccc5c4oc4ccccc45)cc3)cc2)cc1]

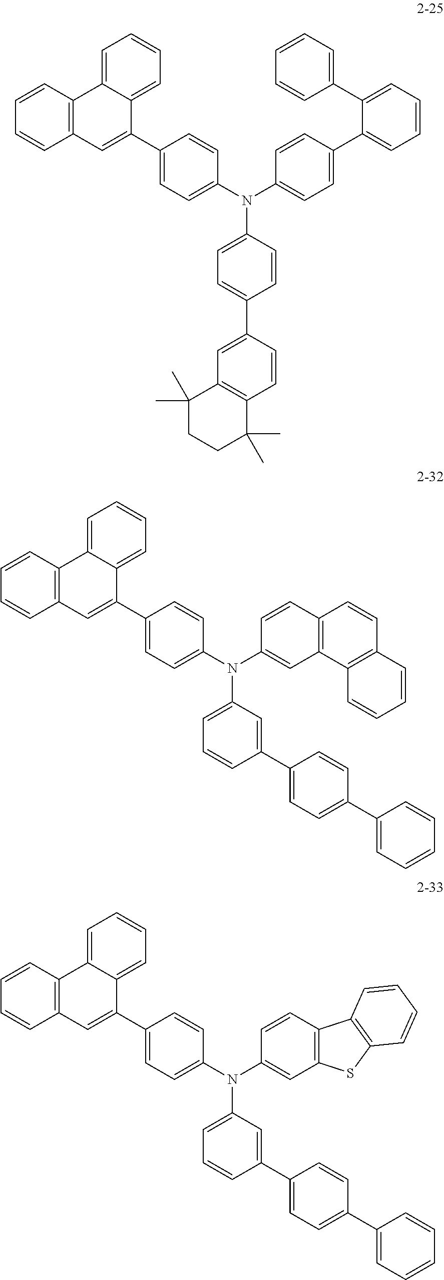 [SMILES: CC1(C)CCC(C)(C)c2cc(-c3ccc(N(c4ccc(-c5ccccc5-c5ccccc5)cc4)c4ccc(-c5cc6ccccc6c6ccccc56)cc4)cc3)ccc21 ; c1ccc(-c2ccc(-c3cccc(N(c4ccc(-c5cc6ccccc6c6ccccc56)cc4)c4ccc5ccc6ccccc6c5c4)c3)cc2)cc1 ; c1ccc(-c2ccc(-c3cccc(N(c4ccc(-c5cc6ccccc6c6ccccc56)cc4)c4ccc5c(c4)sc4ccccc45)c3)cc2)cc1]

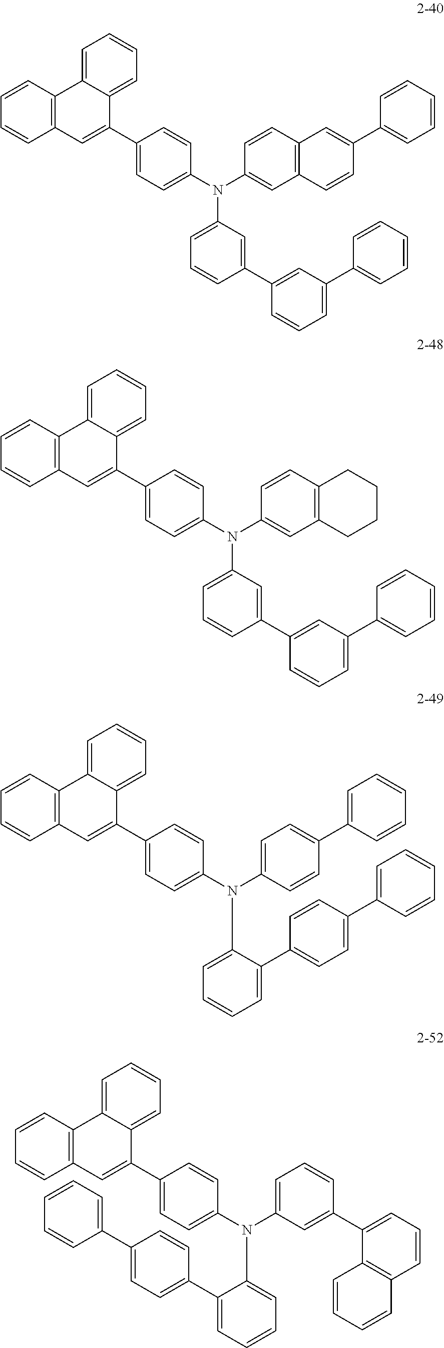 [SMILES: c1ccc(-c2cccc(-c3cccc(N(c4ccc(-c5cc6ccccc6c6ccccc56)cc4)c4ccc5cc(-c6ccccc6)ccc5c4)c3)c2)cc1 ; c1ccc(-c2cccc(-c3cccc(N(c4ccc(-c5cc6ccccc6c6ccccc56)cc4)c4ccc5c(c4)CCCC5)c3)c2)cc1 ; c1ccc(-c2ccc(-c3ccccc3N(c3ccc(-c4ccccc4)cc3)c3ccc(-c4cc5ccccc5c5ccccc45)cc3)cc2)cc1 ; c1ccc(-c2ccc(-c3ccccc3N(c3ccc(-c4cc5ccccc5c5ccccc45)cc3)c3cccc(-c4cccc5ccccc45)c3)cc2)cc1]

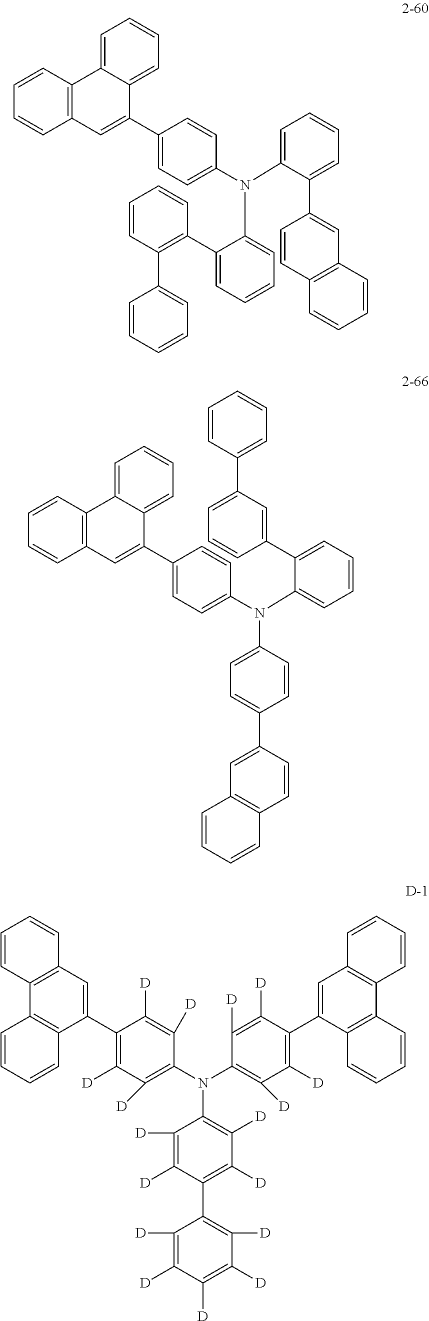 [SMILES: c1ccc(-c2ccccc2-c2ccccc2N(c2ccc(-c3cc4ccccc4c4ccccc34)cc2)c2ccccc2-c2ccc3ccccc3c2)cc1 ; c1ccc(-c2cccc(-c3ccccc3N(c3ccc(-c4ccc5ccccc5c4)cc3)c3ccc(-c4cc5ccccc5c5ccccc45)cc3)c2)cc1 ; [2H]c1c([2H])c([2H])c(-c2c([2H])c([2H])c(N(c3c([2H])c([2H])c(-c4cc5ccccc5c5ccccc45)c([2H])c3[2H])c3c([2H])c([2H])c(-c4cc5ccccc5c5ccccc45)c([2H])c3[2H])c([2H])c2[2H])c([2H])c1[2H]]

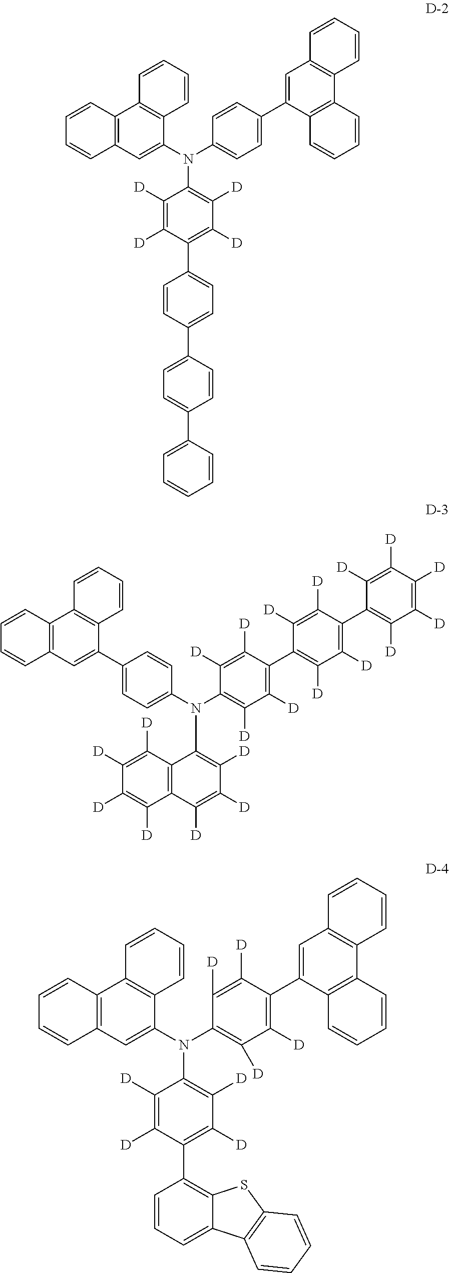 [SMILES: [2H]c1c([2H])c(N(c2ccc(-c3cc4ccccc4c4ccccc34)cc2)c2cc3ccccc3c3ccccc23)c([2H])c([2H])c1-c1ccc(-c2ccc(-c3ccccc3)cc2)cc1 ; [2H]c1c([2H])c([2H])c(-c2c([2H])c([2H])c(-c3c([2H])c([2H])c(N(c4ccc(-c5cc6ccccc6c6ccccc56)cc4)c4c([2H])c([2H])c([2H])c5c([2H])c([2H])c([2H])c([2H])c45)c([2H])c3[2H])c([2H])c2[2H])c([2H])c1[2H] ; [2H]c1c([2H])c(N(c2c([2H])c([2H])c(-c3cccc4c3sc3ccccc34)c([2H])c2[2H])c2cc3ccccc3c3ccccc23)c([2H])c([2H])c1-c1cc2ccccc2c2ccccc12]

### Experimental Example

The voltage and efficiency were measured (based on 15 mA/cm²) by applying a current to the organic light emitting devices manufactured in the Examples 1 to 245 and Comparative Examples 1 to 268, and the results are shown in Tables 1 to 14 below. The lifetime T95 was measured based on 6000 nit, and L95 means the time required for the lifetime to be reduced to 95% of the initial lifetime.

TABLE 1

| | | | Driving | Efficiency | Lifetime | Luminous |
|---|---|---|---|---|---|---|
| Category | First host | Second host | voltage (V) | (cd/A) | T95(hr) | color |
| Example 1 | Compound 1- | Compound 2-1-D22 | 3.50 | 24.66 | 207 | Red |
| Example 2 | 1 | Compound 2-17- | 3.45 | 23.29 | 212 | Red |
| | | D28 | | | | |
| Example 3 | | Compound 2-35- | 3.48 | 23.71 | 195 | Red |
| | | D25 | | | | |
| Example 4 | | Compound 2-52- | 3.45 | 23.51 | 202 | Red |
| | | D37 | | | | |
| Example 5 | | Compound 2-71- | 3.44 | 24.16 | 196 | Red |
| | | D26 | | | | |
| Example 6 | Compound 1- | Compound 2-2-D18 | 3.49 | 23.96 | 192 | Red |
| Example 7 | 2 | Compound 2-19- | 3.44 | 24.26 | 206 | Red |
| | | 026 | | | | |
| Example 8 | | Compound 2-38- | 3.44 | 23.72 | 195 | Red |
| | | D20 | | | | |
| Example 9 | | Compound 2-49- | 3.49 | 24.43 | 190 | Red |
| | | D20 | | | | |
| Example 10 | | Compound 2-67- | 3.44 | 23.66 | 193 | Red |
| | | D29 | | | | |
| Example 11 | Compound 1- | Compound 2-3-D26 | 3.59 | 21.30 | 199 | Red |
| Example 12 | 3 | Compound 2-15- | 3.53 | 21.44 | 204 | Red |
| | | D19 | | | | |
| Example 13 | | Compound 2-27- | 3.60 | 21.32 | 196 | Red |
| | | D28 | | | | |
| Example 14 | | Compound 2-43- | 3.52 | 21.90 | 192 | Red |
| | | D21 | | | | |
| Example 15 | | Compound 2-69- | 3.51 | 21.69 | 194 | Red |
| | | D23 | | | | |
| Example 16 | Compound 1- | Compound 2-4-D28 | 3.55 | 21.89 | 212 | Red |
| Example 17 | 4 | Compound 2-29- | 3.58 | 21.33 | 204 | Red |
| | | D23 | | | | |
| Example 18 | | Compound 2-36- | 3.50 | 21.33 | 195 | Red |
| | | D20 | | | | |
| Example 19 | | Compound 2-54- | 3.63 | 22.00 | 190 | Red |
| | | D25 | | | | |
| Example 20 | | Compound 2-66- | 3.63 | 21.58 | 197 | Red |
| | | D37 | | | | |
| Example 21 | Compound 1- | Compound 2-5-D35 | 3.63 | 22.34 | 209 | Red |
| Example 22 | 5 | Compound 2-30- | 3.67 | 22.90 | 197 | Red |
| | | D22 | | | | |
| Example 23 | | Compound 2-41- | 3.59 | 23.03 | 205 | Red |
| | | D21 | | | | |
| Example 24 | | Compound 2-57- | 3.60 | 22.47 | 212 | Red |
| | | D29 | | | | |
| Example 25 | | Compound 2-62- | 3.62 | 22.44 | 196 | Red |
| | | D21 | | | | |
| Example 26 | Compound 1- | Compound 2-6-D26 | 3.61 | 22.35 | 214 | Red |
| Example 27 | 6 | Compound 2-23- | 3.67 | 22.95 | 202 | Red |
| | | D21 | | | | |
| Example 28 | | Compound 2-48- | 3.58 | 22.18 | 195 | Red |
| | | D20 | | | | |
| Example 29 | | Compound 2-60- | 3.68 | 22.97 | 198 | Red |
| | | D20 | | | | |
| Example 30 | | Compound 2-73- | 3.60 | 22.96 | 213 | Red |
| | | D21 | | | | |
| Example 31 | Compound 1- | Compound 2-7-D39 | 3.51 | 22.24 | 225 | Red |
| Example 32 | 8 | Compound 2-22- | 3.44 | 23.09 | 206 | Red |
| | | D20 | | | | |
| Example 33 | | Compound 2-37- | 3.44 | 23.03 | 214 | Red |
| | | D28 | | | | |
| Example 34 | | Compound 2-50- | 3.46 | 22.86 | 225 | Red |
| | | D20 | | | | |
| Example 35 | | Compound 2-70- | 3.45 | 22.96 | 215 | Red |
| | | D25 | | | | |
| Example 36 | Compound 1- | Compound 2-8-D25 | 3.40 | 22.37 | 220 | Red |
| Example 37 | 9 | Compound 2-25- | 3.44 | 22.41 | 215 | Red |
| | | D27 | | | | |
| Example 38 | | Compound 2-39- | 3.52 | 22.65 | 216 | Red |
| | | D21 | | | | |
| Example 39 | | Compound 2-51- | 3.51 | 23.02 | 222 | Red |
| | | D21 | | | | |
| Example 40 | | Compound 2-64- | 3.51 | 22.85 | 216 | Red |
| | | D20 | | | | |
| Example 41 | Compound 1- | Compound 2-9-D23 | 3.61 | 21.51 | 197 | Red |
| Example 42 | 10 | Compound 2-16- | 3.53 | 21.67 | 209 | Red |
| | | D27 | | | | |
| Example 43 | | Compound 2-34- | 3.57 | 21.73 | 195 | Red |
| | | D23 | | | | |
| Example 44 | | Compound 2-45- | 3.51 | 21.70 | 203 | Red |
| | | D24 | | | | |
| Example 45 | | Compound 2-56- | 3.56 | 21.31 | 214 | Red |
| | | D21 | | | | |

TABLE 2

| | | | Driving | Efficiency | Lifetime | Luminous |
|---|---|---|---|---|---|---|
| Category | First host | Second host | voltage (V) | (cd/A) | T95(hr) | color |
| Example 46 | Compound 1- | Compound 2-10- | 3.61 | 22.56 | 197 | Red |
| | 11 | D29 | | | | |
| Example 47 | | Compound 2-24- | 3.64 | 22.30 | 199 | Red |
| | | D22 | | | | |
| Example 48 | | Compound 2-40- | 3.69 | 23.02 | 195 | Red |
| | | D20 | | | | |
| Example 49 | | Compound 2-53- | 3.66 | 22.74 | 205 | Red |
| | | D19 | | | | |
| Example 50 | | Compound 2-72- | 3.61 | 23.07 | 219 | Red |
| | | D23 | | | | |
| Example 51 | Compound 1- | Compound 2-11- | 3.60 | 22.91 | 205 | Red |
| | 13 | D21 | | | | |
| Example 52 | | Compound 2-20- | 3.63 | 22.55 | 195 | Red |
| | | D22 | | | | |
| Example 53 | | Compound 2-33- | 3.59 | 22.79 | 193 | Red |
| | | D19 | | | | |
| Example 54 | | Compound 2-55- | 3.69 | 22.35 | 206 | Red |
| | | D23 | | | | |
| Example 55 | | Compound 2-65- | 3.68 | 22.60 | 199 | Red |
| | | D28 | | | | |
| Example 56 | Compound 1- | Compound 2-12- | 3.41 | 23.77 | 200 | Red |
| | 15 | D27 | | | | |
| Example 57 | | Compound 2-21- | 3.49 | 24.24 | 196 | Red |
| | | D37 | | | | |
| Example 58 | | Compound 2-32- | 3.44 | 23.75 | 199 | Red |
| | | D24 | | | | |
| Example 59 | | Compound 2-44- | 3.40 | 23.22 | 204 | Red |
| | | 021 | | | | |
| Example 60 | | Compound 2-63- | 3.41 | 23.96 | 190 | Red |
| | | D30 | | | | |
| Example 61 | Compound 1- | Compound 2-13- | 3.51 | 24.07 | 198 | Red |
| | 16 | D29 | | | | |
| Example 62 | | Compound 2-26- | 3.41 | 24.23 | 194 | Red |
| | | D25 | | | | |
| Example 63 | | Compound 2-42- | 3.51 | 23.20 | 201 | Red |
| | | D37 | | | | |
| Example 64 | | Compound 2-59- | 3.42 | 24.28 | 203 | Red |
| | | D24 | | | | |
| Example 65 | | Compound 2-61- | 3.47 | 24.24 | 196 | Red |
| | | D25 | | | | |
| Example 66 | Compound 1- | Compound 2-14- | 3.41 | 22.51 | 208 | Red |
| | 17 | D30 | | | | |
| Example 67 | | Compound 2-28- | 3.49 | 22.28 | 216 | Red |
| | | D35 | | | | |
| Example 68 | | Compound 2-46- | 3.44 | 22.45 | 209 | Red |
| | | D19 | | | | |
| Example 69 | | Compound 2-58- | 3.40 | 22.66 | 210 | Red |
| | | D27 | | | | |
| Example 70 | | Compound 2-68- | 3.41 | 22.85 | 208 | Red |
| | | D29 | | | | |
| Example 71 | Compound 1- | Compound 2-3-D26 | 3.51 | 22.74 | 220 | Red |
| Example 72 | 19 | Compound 2-18- | 3.41 | 22.20 | 223 | Red |
| | | D24 | | | | |
| Example 73 | | Compound 2-31- | 3.51 | 22.41 | 215 | Red |
| | | D31 | | | | |
| Example 74 | | Compound 2-47- | 3.42 | 22.54 | 213 | Red |
| | | D21 | | | | |
| Example 75 | | Compound 2-72- | 3.47 | 22.79 | 215 | Red |
| | | D23 | | | | |
| Example 76 | Compound 1- | Compound 2-1-D22 | 3.56 | 21.92 | 212 | Red |
| Example 77 | 20 | Compound 2-17- | 3.61 | 21.75 | 203 | Red |
| | | D28 | | | | |
| Example 78 | | Compound 2-35- | 3.59 | 21.41 | 21 | Red |
| | | D25 | | | | |
| Example 79 | | Compound 2-52- | 3.59 | 21.52 | 206 | Red |
| | | D37 | | | | |
| Example 80 | | Compound 2-71- | 3.61 | 21.58 | 203 | Red |
| | | D26 | | | | |
| Example 81 | Compound 1- | Compound 2-2-D18 | 3.50 | 22.27 | 209 | Red |
| Example 82 | 21 | Compound 2-19- | 3.52 | 22.54 | 213 | Red |
| | | D26 | | | | |
| Example 83 | | Compound 2-38- | 3.42 | 22.46 | 21 | Red |
| | | D20 | | | | |
| Example 84 | | Compound 2-49- | 3.52 | 22,76 | 214 | Red |
| | | D20 | | | | |
| Example 85 | | Compound 2-67- | 3.40 | 22.14 | 22 | Red |
| | | D29 | | | | |
| Example 86 | Compound 1- | Compound 2-3-D26 | 3.48 | 22.53 | 223 | Red |
| Example 87 | 22 | Compound 2-15- | 3.47 | 22.64 | 214 | Red |
| | | D19 | | | | |
| Example 88 | | Compound- 2-27- | 3.48 | 22.69 | 218 | Red |
| | | D28 | | | | |
| Example 89 | | Compound 2-43- | 3.48 | 22.65 | 223 | Red |
| | | D21 | | | | |
| Example 90 | | Compound 2-69- | 3.49 | 23.09 | 214 | Red |
| | | D23 | | | | |

TABLE 3

| | | | Driving | Efficiency | Lifetime | Luminous |
|---|---|---|---|---|---|---|
| Category | First host | Second host | voltage (V) | (cd/A) | T95(hr) | color |
| Example 91 | Compound 1- | Compound 2-4-D28 | 3.46 | 24.46 | 195 | Red |
| Example 92 | 24 | Compound 2-29- | 3.43 | 24.61 | 213 | Red |
| | | D23 | | | | |
| Example 93 | | Compound 2-36- | 3.46 | 23.69 | 201 | Red |
| | | D20 | | | | |
| Example 94 | | Compound 2-54- | 3.42 | 24.53 | 194 | Red |
| | | D25 | | | | |
| Example 95 | | Compound 2-66- | 3.43 | 23.21 | 206 | Red |
| | | D37 | | | | |
| Example 96 | Compound 1- | Compound 2-5-D35 | 3.46 | 24.20 | 214 | Red |
| Example 97 | 25 | Compound 2-30- | 3.44 | 24.34 | 197 | Red |
| | | D22 | | | | |
| Example 98 | | Compound 2-41- | 3.46 | 24.21 | 203 | Red |
| | | D2″ | | | | |
| Example 99 | | Compound 2-57- | 3.42 | 23.73 | 198 | Red |
| | | D29 | | | | |
| Example 100 | | Compound 2-62- | 3.52 | 24.22 | 197 | Red |
| | | D21 | | | | |
| Example 101 | Compound 1- | Compound 2-6-D26 | 3.66 | 22.67 | 216 | Red |
| Example 102 | 27 | Compound 2-23- | 3.68 | 22.74 | 204 | Red |
| | | D21 | | | | |
| Example 103 | | Compound 2-48- | 3.62 | 22.52 | 195 | Red |
| | | D20 | | | | |
| Example 104 | | Compound 2-60- | 3.63 | 22.32 | 202 | Red |
| | | D20 | | | | |
| Example 105 | | Compound- 2-73- | 3.61 | 23.06 | 199 | Red |
| | | D21 | | | | |
| Example 106 | Compound 1- | Compound 2-7-D39 | 3.62 | 23.07 | 208 | Red |
| Example 107 | 28 | Compound 2-22- | 3.64 | 22.55 | 202 | Red |
| | | D20 | | | | |
| Example 108 | | Compound 2-37- | 3.58 | 23.00 | 191 | Red |
| | | D28 | | | | |
| Example 109 | | Compound 2-50- | 3.69 | 22.97 | 214 | Red |
| | | D20 | | | | |
| Example 110 | | Compound 2-70- | 3.59 | 22.88 | 196 | Red |
| | | D25 | | | | |
| Example 111 | Compound 1- | Compound 2-8-D25 | 3.45 | 22.13 | 223 | Red |
| Example 112 | 29 | Compound 2-25- | 3.42 | 22.13 | 227 | Red |
| | | D27 | | | | |
| Example 113 | | Compound 2-39- | 3.41 | 22.53 | 209 | Red |
| | | D21 | | | | |
| Example 114 | | Compound 2-51- | 3.43 | 22.47 | 215 | Red |
| | | D21 | | | | |
| Example 115 | | Compound 2-64- | 3.40 | 22.17 | 204 | Red |
| | | D20 | | | | |
| Example 116 | Compound 1- | Compound 2-9-D23 | 3.49 | 25.24 | 236 | Red |
| Example 117 | 30 | Compound 2-16- | 3.45 | 25.64 | 222 | Red |
| | | D27 | | | | |
| Example 118 | | Compound 2-34- | 3.47 | 25.68 | 236 | Red |
| | | D23 | | | | |
| Example 119 | | Compound 2-45- | 3.50 | 25.74 | 247 | Red |
| | | D24 | | | | |
| Example 120 | | Compound 2-56- | 3.51 | 25.35 | 228 | Red |
| | | D21 | | | | |
| Example 121 | Compound 1- | Compound 2-10- | 3.44 | 25.59 | 221 | Red |
| | 31 | D29 | | | | |
| Example 122 | | Compound 2-24- | 3.41 | 25.82 | 247 | Red |
| | | D22 | | | | |
| Example 123 | | Compound 2-40- | 3.50 | 25.35 | 246 | Red |
| | | D20 | | | | |
| Example 124 | | Compound 2-53- | 3.41 | 24.93 | 227 | Red |
| | | D19 | | | | |
| Example 125 | | Compound 2-72- | 3.42 | 25.28 | 242 | Red |
| | | D23 | | | | |
| Example 126 | Compound 1- | Compound 2-11- | 3.43 | 23.95 | 234 | Red |
| | 32 | D21 | | | | |
| Example 127 | | Compound 2-20- | 3.58 | 24.61 | 240 | Red |
| | | D22 | | | | |
| Example 128 | | Compound 2-33- | 3.59 | 24.57 | 235 | Red |
| | | D19 | | | | |
| Example 129 | | Compound 2-55- | 3.61 | 23.56 | 248 | Red |
| | | D23 | | | | |
| Example 130 | | Compound 2-65- | 3.52 | 23.79 | 242 | Red |
| | | D28 | | | | |
| Example 131 | Compound 1- | Compound 2-12- | 3.60 | 24.58 | 228 | Red |
| | 33 | D27 | | | | |
| Example 132 | | Compound 2-21- | 3.60 | 23.57 | 250 | Red |
| | | D37 | | | | |
| Example 133 | | Compound 2-32- | 3.62 | 24.02 | 237 | Red |
| | | D24 | | | | |
| Example 134 | | Compound 2-44- | 3.55 | 23.97 | 228 | Red |
| | | D21 | | | | |
| Example 135 | | Compound 2-63- | 3.52 | 23.82 | 242 | Red |
| | | D30 | | | | |

TABLE 4

| | | | Driving | Efficiency | Lifetime | Luminous |
|---|---|---|---|---|---|---|
| Category | First host | Second host | voltage (V) | (cd/A) | T95(hr) | color |
| Example 136 | Compound 1- | Compound 2-13- | 3.55 | 23.95 | 234 | Red |
| | 34 | D29 | | | | |
| Example 137 | | Compound 2-26- | 3.58 | 24.61 | 246 | Red |
| | | D25 | | | | |
| Example 138 | | Compound 2-42- | 3.59 | 24.57 | 235 | Red |
| | | D37 | | | | |
| Example 139 | | Compound 2-59- | 3.61 | 23.56 | 248 | Red |
| | | D24 | | | | |
| Example 140 | | Compound 2-61- | 3.52 | 23.79 | 240 | Red |
| | | D25 | | | | |
| Example 141 | Compound 1- | Compound 2-14- | 3.60 | 24.58 | 228 | Red |
| | 35 | D30 | | | | |
| Example 142 | | Compound 2-28- | 3.60 | 23.57 | 250 | Red |
| | | D35 | | | | |
| Example 113 | | Compound 2-46- | 3.62 | 24.02 | 242 | Red |
| | | D19 | | | | |
| Example 144 | | Compound 2-58- | 3.55 | 23.97 | 232 | Red |
| | | D27 | | | | |
| Example 145 | | Compound 2-68- | 3.52 | 23.82 | 247 | Red |
| | | D29 | | | | |
| Example 146 | Compound 1- | Compound 2-3-D26 | 3.41 | 25.83 | 231 | Red |
| Example 147 | 36 | Compound 2-18- | 3.40 | 25.48 | 227 | Red |
| | | D24 | | | | |
| Example 148 | | Compound 2-31- | 3.50 | 24.84 | 243 | Red |
| | | D31 | | | | |
| Example 149 | | Compound 2-47- | 3.49 | 25.75 | 232 | Red |
| | | D21 | | | | |
| Example 150 | | Compound 2-72- | 3.46 | 25.60 | 214 | Red |
| | | D23 | | | | |
| Example 151 | Compound 1- | Compound 2-1-D22 | 3.63 | 24.48 | 226 | Red |
| Example 152 | 37 | Compound 2-17- | 3.56 | 23.86 | 210 | Red |
| | | D28 | | | | |
| Example 153 | | Compound 2-35- | 3.54 | 23.78 | 241 | Red |
| | | D25 | | | | |
| Example 154 | | Compound 2-52- | 3.55 | 24.26 | 224 | Red |
| | | D37 | | | | |
| Example 155 | | Compound 2-71- | 3.53 | 23.72 | 232 | Red |
| | | D26 | | | | |
| Example 156 | Compound 1- | Compound 2-2-D18 | 3.59 | 23.66 | 231 | Red |
| Example 157 | 38 | Compound 2-19- | 3.55 | 24.61 | 237 | Red |
| | | D26 | | | | |
| Example 158 | | Compound 2-38- | 3.54 | 23.28 | 246 | Red |
| | | D20 | | | | |
| Example 159 | | Compound 2-49- | 3.60 | 24.09 | 240 | Red |
| | | D20 | | | | |
| Example 160 | | Compound 2-67- | 3.62 | 23.23 | 248 | Red |
| | | D29 | | | | |
| Example 161 | Compound 1- | Compound 2-3-D26 | 3.48 | 23.51 | 250 | Red |
| Example 162 | 10 | Compound 2-15- | 3.43 | 24.14 | 227 | Red |
| | | D19 | | | | |
| Example 163 | | Compound 2-27- | 3.41 | 23.21 | 242 | Red |
| | | D28 | | | | |
| Example 164 | | Compound 2-43- | 3.51 | 23.67 | 231 | Red |
| | | D21 | | | | |
| Example 165 | | Compound 2-69- | 3.41 | 23.40 | 235 | Red |
| | | D23 | | | | |
| Example 166 | Compound 1- | Compound- 2-4-D28 | 3.46 | 23.81 | 240 | Red |
| Example 167 | 41 | Compound 2-29- | 3.45 | 23.87 | 233 | Red |
| | | D23 | | | | |
| Example 168 | | Compound 2-36- | 3.46 | 24.14 | 217 | Red |
| | | D20 | | | | |
| Example 169 | | Compound 2-54- | 3.46 | 23.27 | 239 | Red |
| | | D25 | | | | |
| Example 170 | | Compound 2-66- | 3.44 | 24.18 | 247 | Red |
| | | D37 | | | | |
| Example 171 | Compound 1- | Compound 2-5-D35 | 3.57 | 24.44 | 223 | Red |
| Example 172 | 42 | Compound 2-30- | 3.62 | 23.51 | 244 | Red |
| | | D22 | | | | |
| Example 173 | | Compound 2-41- | 3.59 | 24.44 | 239 | Red |
| | | D21 | | | | |
| Example 174 | | Compound 2-57- | 3.63 | 24,19 | 219 | Red |
| | | D29 | | | | |
| Example 175 | | Compound 2-62- | 3.55 | 23.95 | 240 | Red |
| | | D21 | | | | |
| Example 176 | Compound 1- | Compound 2-6-D26 | 3.53 | 24.68 | 228 | Red |
| Example 177 | 43 | Compound 2-23- | 3.59 | 23.86 | 244 | Red |
| | | D21 | | | | |
| Example 178 | | Compound 2-48- | 3.52 | 24.40 | 226 | Red |
| | | D20 | | | | |
| Example 179 | | Compound 2-60- | 3.54 | 23.87 | 242 | Red |
| | | D20 | | | | |
| Example 180 | | Compound 2-73- | 3.61 | 24.10 | 235 | Red |
| | | D21 | | | | |

TABLE 5

| | | | Driving | Efficiency | Lifetime | Luminous |
|---|---|---|---|---|---|---|
| Category | First host | Second host | voltage (V) | (cd/A) | T95(hr) | color |
| Example 181 | Compound 1- | Compound 2-7-D39 | 3.41 | 25.59 | 251 | Red |
| Example 182 | 44 | Compound 2-22- | 3.40 | 25.52 | 245 | Red |
| | | D20 | | | | |
| Example 183 | | Compound 2-37- | 3.49 | 25.69 | 225 | Red |
| | | D28 | | | | |
| Example 184 | | Compound 2-50- | 3.51 | 25.14 | 237 | Red |
| | | D20 | | | | |
| Example 185 | | Compound 2-70- | 3.42 | 25.44 | 216 | Red |
| | | D25 | | | | |
| Example 186 | Compound 1- | Compound 2-8-D25 | 3.46 | 24.85 | 239 | Red |
| Example 187 | 45 | Compound 2-25- | 3.51 | 25.25 | 223 | Red |
| | | D27 | | | | |
| Example 188 | | Compound 2-39- | 3.48 | 25.28 | 228 | Red |
| | | D21 | | | | |
| Example 189 | | Compound 2-51- | 3.41 | 25.10 | 242 | Red |
| | | D21 | | | | |
| Example 190 | | Compound 2-64- | 3.45 | 25.40 | 246 | Red |
| | | D20 | | | | |
| Example 191 | Compound 1- | Compound 2-9-D23 | 3.49 | 25.34 | 232 | Red |
| Example 192 | 46 | Compound 2-16- | 3.42 | 25.65 | 227 | Red |
| | | D27 | | | | |
| Example 193 | | Compound 2-34- | 3.50 | 25.28 | 245 | Red |
| | | D23 | | | | |
| Example 194 | | Compound 2-45- | 3.44 | 24.94 | 250 | Red |
| | | D24 | | | | |
| Example 195 | | Compound- 2-56- | 3.47 | 25.84 | 244 | Red |
| | | D21 | | | | |
| Example 196 | Compound 1- | Compound 2-10- | 3.44 | 25.86 | 229 | Red |
| | 48 | D29 | | | | |
| Example 197 | | Compound 2-24- | 3.46 | 24.83 | 243 | Red |
| | | D22 | | | | |
| Example 198 | | Compound- 2-40- | 3.48 | 25.55 | 230 | Red |
| | | D20 | | | | |
| Example 199 | | Compound 2-53- | 3.41 | 25.21 | 242 | Red |
| | | D19 | | | | |
| Example 200 | | Compound 2-72- | 3.43 | 25.57 | 237 | Red |
| | | D23 | | | | |
| Example 201 | Compound 1- | Compound 2-11- | 3.62 | 23.47 | 216 | Red |
| | 49 | D21 | | | | |
| Example 202 | | Compound 2-20- | 3.55 | 24.58 | 225 | Red |
| | | D22 | | | | |
| Example 203 | | Compound 2-33- | 3.63 | 24.43 | 248 | Red |
| | | D19 | | | | |
| Example 204 | | Compound 2-55- | 3.57 | 24.24 | 239 | Red |
| | | D23 | | | | |
| Example 205 | | Compound 2-65- | 3.50 | 24.06 | 218 | Red |
| | | D28 | | | | |
| Example 206 | Compound 1- | Compound 2-12- | 3.61 | 24.20 | 245 | Red |
| | 50 | D27 | | | | |
| Example 207 | | Compound 2-21- | 3.50 | 24.57 | 224 | Red |
| | | D37 | | | | |
| Example 208 | | Compound 2-32- | 3.61 | 24.10 | 249 | Red |
| | | D24 | | | | |
| Example 209 | | Compound 2-44- | 3.63 | 24.58 | 227 | Red |
| | | D21 | | | | |
| Example 210 | | Compound 2-63- | 3.54 | 24.22 | 240 | Red |
| | | D30 | | | | |
| Example 211 | Compound 1- | Compound 2-13- | 3.44 | 23.47 | 236 | Red |
| | 51 | D29 | | | | |
| Example 212 | | Compound 2-26- | 3.45 | 24.58 | 225 | Red |
| | | D25 | | | | |
| Example 213 | | Compound 2-42- | 3.50 | 24.43 | 248 | Red |
| | | D37 | | | | |
| Example 214 | | Compound 2-59- | 3.52 | 24.24 | 239 | Red |
| | | D24 | | | | |
| Example 215 | | Compound 2-61- | 3.45 | 24.06 | 228 | Red |
| | | D25 | | | | |
| Example 216 | Compound 1- | Compound 2-14- | 3.48 | 22.77 | 254 | Red |
| | 54 | D30 | | | | |
| Example 217 | | Compound 2-28- | 3.52 | 22.40 | 246 | Red |
| | | D35 | | | | |
| Example 218 | | Compound 2-46- | 3.41 | 23.09 | 259 | Red |
| | | D19 | | | | |
| Example 219 | | Compound 2-58- | 3.52 | 22.86 | 265 | Red |
| | | D27 | | | | |
| Example 220 | | Compound 2-68- | 3.40 | 22.79 | 257 | Red |
| | | D29 | | | | |
| Example 221 | Compound 1- | Compound 2-3-D26 | 3.40 | 22.74 | 260 | Red |
| Example 222 | 55 | Compound 2-18- | 3.47 | 22.46 | 271 | Red |
| | | D24 | | | | |
| Example 223 | | Compound 2-31- | 3.49 | 22.16 | 269 | Red |
| | | D31 | | | | |
| Example 224 | | Compound 2-47- | 3.52 | 22.89 | 275 | Red |
| | | D21 | | | | |
| Example 225 | | Compound 2-72- | 3.52 | 23.10 | 267 | Red |
| | | D23 | | | | |

TABLE 6

| | | | Driving | Efficiency | Lifetime | Luminous |
|---|---|---|---|---|---|---|
| Category | First host | Second host | voltage (V) | (cd/A) | T95(hr) | color |
| Example 226 | Compound 1- | Compound 2-12- | 3.54 | 25.88 | 256 | Red |
| | 57 | D27 | | | | |
| Example 227 | | Compound 2-21- | 3.50 | 25.61 | 264 | Red |
| | | D37 | | | | |
| Example 228 | | Compound 2-32- | 3.56 | 25.64 | 270 | Red |
| | | D24 | | | | |
| Example 229 | | Compound 2-44- | 3.62 | 25.39 | 273 | Red |
| | | D21 | | | | |
| Example 230 | | Compound 2-63- | 3.62 | 25.17 | 256 | Red |
| | | D30 | | | | |
| Example 231 | Compound 1- | Compound 2-13- | 3.55 | 25.52 | 275 | Red |
| | 59 | D29 | | | | |
| Example 232 | | Compound 2-26- | 3.51 | 25.88 | 267 | Red |
| | | D25 | | | | |
| Example 233 | | Compound 2-42- | 3.50 | 24.86 | 270 | Red |
| | | D37 | | | | |
| Example 234 | | Compound 2-59- | 3.62 | 25.45 | 252 | Red |
| | | D24 | | | | |
| Example 235 | | Compound 2-61- | 3.56 | 25.68 | 258 | Red |
| | | D25 | | | | |
| Example 236 | Compound 1- | Compound 2-14- | 3.42 | 25.72 | 266 | Red |
| | 60 | D30 | | | | |
| Example 237 | | Compound 2-28- | 3.47 | 25.66 | 248 | Red |
| | | D35 | | | | |
| Example 238 | | Compound 2-46- | 3.49 | 25.23 | 272 | Red |
| | | D19 | | | | |
| Example 239 | | Compound 2-58- | 3.45 | 24.84 | 260 | Red |
| | | D27 | | | | |
| Example 240 | | Compound 2-68- | 3.52 | 25.36 | 259 | Red |
| | | D29 | | | | |
| Example 241 | Compound 1- | Compound 2-3-D26 | 3.41 | 25.12 | 247 | Red |
| Example 242 | 61 | Compound 2-18- | 3.44 | 25.67 | 266 | Red |
| | | D24 | | | | |
| Example 243 | | Compound 2-31- | 3.41 | 24.80 | 272 | Red |
| | | D3 | | | | |
| Example 244 | | Compound 2-47- | 3.51 | 25.50 | 262 | Red |
| | | D21 | | | | |
| Example 245 | | Compound 2-72- | 3.43 | 25.15 | 268 | Red |
| | | D23 | | | | |

TABLE 7

| | | | Driving | Efficiency | Lifetime | Luminous |
|---|---|---|---|---|---|---|
| Category | First host | Second host | voltage (V) | (cd/A) | T95(hr) | color |
| Comparative | Compound A-1 | Compound 2-1- | 3.94 | 17.79 | 139 | Red |
| Example 1 | | D22 | | | | |
| Comparative | | Compound 2-17- | 3.80 | 18.28 | 148 | Red |
| Example 2 | | D28 | | | | |
| Comparative | | Compound 2-35- | 3.84 | 18.18 | 142 | Red |
| Example 3 | | D25 | | | | |
| Comparative | | Compound 2-52- | 3.83 | 17.92 | 141 | Red |
| Example 4 | | D37 | | | | |
| Comparative | | Compound 2-71- | 3.83 | 18.20 | 141 | Red |
| Example 5 | | D26 | | | | |
| Comparative | Compound A-2 | Compound 2-2- | 3.86 | 18.73 | 148 | Red |
| Example 6 | | D18 | | | | |
| Comparative | | Compound 2-19- | 3.85 | 18.67 | 138 | Red |
| Example 7 | | D26 | | | | |
| Comparative | | Compound 2-38- | 3.80 | 18.36 | 145 | Red |
| Example 8 | | D20 | | | | |
| Comparative | | Compound 2-49- | 3.76 | 18.14 | 148 | Red |
| Example 9 | | D20 | | | | |
| Comparative | | Compound 2-67- | 3.78 | 18.62 | 151 | Red |
| Example 10 | | D29 | | | | |
| Comparative | Compound A-3 | Compound 2-3- | 3.99 | 18.10 | 158 | Red |
| Example 11 | | D26 | | | | |
| Comparative | | Compound 2-15- | 3.78 | 18.13 | 159 | Red |
| Example 12 | | D19 | | | | |
| Comparative | | Compound 2-27- | 3.75 | 18.47 | 162 | Red |
| Example 13 | | D28 | | | | |
| Comparative | | Compound 2-43- | 3.80 | 18.58 | 160 | Red |
| Example 14 | | D21 | | | | |
| Comparative | | Compound 2-69- | 3.87 | 18.38 | 164 | Red |
| Example 15 | | D23 | | | | |
| Comparative | Compound A-4 | Compound 2-4- | 3.80 | 18.79 | 161 | Red |
| Example 16 | | D28 | | | | |
| Comparative | | Compound 2-29- | 3.80 | 18.56 | 161 | Red |
| Example 17 | | D23 | | | | |
| Comparative | | Compound 2-36- | 3.83 | 18.14 | 165 | Red |
| Example 18 | | D20 | | | | |
| Comparative | | Compound 2-54- | 3.78 | 18.03 | 160 | Red |
| Example 19 | | D25 | | | | |
| Comparative | | Compound 2-66- | 3.80 | 18.23 | 161 | Red |
| Example 20 | | D37 | | | | |
| Comparative | Compound A-5 | Compound 2-5- | 3.98 | 17.92 | 150 | Red |
| Example 21 | | D35 | | | | |
| Comparative | | Compound 2-30- | 3.87 | 18.03 | 152 | Red |
| Example 22 | | D22 | | | | |
| Comparative | | Compound 2-41- | 3.88 | 18.76 | 152 | Red |
| Example 23 | | D21 | | | | |
| Comparative | | Compound 2-57- | 3.84 | 18.19 | 144 | Red |
| Example 24 | | D29 | | | | |
| Comparative | | Compound 2-62- | 3.81 | 18.03 | 144 | Red |
| Example 25 | | D21 | | | | |
| Comparative | Compound A-6 | Compound 2-6- | 3.88 | 18.32 | 142 | Red |
| Example 26 | | D26 | | | | |
| Comparative | | Compound 2-23- | 3.78 | 18.32 | 152 | Red |
| Example 27 | | D21 | | | | |
| Comparative | | Compound 2-48- | 3.84 | 18.69 | 152 | Red |
| Example 28 | | D20 | | | | |
| Comparative | | Compound 2-60- | 3.80 | 18.52 | 141 | Red |
| Example 29 | | D20 | | | | |
| Comparative | | Compound 2-73- | 3.88 | 18.21 | 146 | Red |
| Example 30 | | D21 | | | | |

TABLE 8

| | | | Driving | Efficiency | Lifetime | Luminous |
|---|---|---|---|---|---|---|
| Category | First host | Second host | voltage (V) | (cd/A) | T95(hr) | color |
| Comparative | Compound A-7 | Compound 2-7- | 3.96 | 17.67 | 139 | Red |
| Example 31 | | D39 | | | | |
| Comparative | | Compound 2-22- | 3.85 | 18.11 | 150 | Red |
| Example 32 | | D20 | | | | |
| Comparative | | Compound 2-37- | 3.84 | 18.51 | 140 | Red |
| Example 33 | | D28 | | | | |
| Comparative | | Compound 2-50- | 3.82 | 18.02 | 148 | Red |
| Example 34 | | D20 | | | | |
| Comparative | | Compound 2-70- | 3.84 | 18.12 | 140 | Red |
| Example 35 | | D25 | | | | |
| Comparative | Compound A-8 | Compound 2-8- | 3.82 | 18.36 | 145 | Red |
| Example 36 | | D25 | | | | |
| Comparative | | Compound 2-25- | 3.75 | 17.95 | 151 | Red |
| Example 37 | | D27 | | | | |
| Comparative | | Compound 2-39- | 3.78 | 18.04 | 143 | Red |
| Example 38 | | D21 | | | | |
| Comparative | | Compound 2-51- | 3.84 | 17.93 | 139 | Red |
| Example 39 | | D21 | | | | |
| Comparative | | Compound 2-64- | 3.83 | 18.74 | 138 | Red |
| Example 40 | | D20 | | | | |
| Comparative | Compound A-9 | Compound 2-9- | 3.83 | 19.66 | 161 | Red |
| Example 41 | | D23 | | | | |
| Comparative | | Compound 2-16- | 3.79 | 20.14 | 158 | Red |
| Example 42 | | D27 | | | | |
| Comparative | | Compound 2-34- | 3.86 | 19.83 | 161 | Red |
| Example 43 | | D23 | | | | |
| Comparative | | Compound 2-45- | 3.87 | 19.73 | 161 | Red |
| Example 44 | | D24 | | | | |
| Comparative | | Compound 2-56- | 3.85 | 19.76 | 161 | Red |
| Example 45 | | D21 | | | | |
| Comparative | Compound A-10 | Compound 2-10- | 3.86 | 19.49 | 165 | Red |
| Example 46 | | D29 | | | | |
| Comparative | | Compound 2-24- | 3.80 | 20.20 | 165 | Red |
| Example 47 | | D22 | | | | |
| Comparative | | Compound 2-40- | 3.84 | 19.64 | 163 | Red |
| Example 48 | | D20 | | | | |
| Comparative | | Compound 2-53- | 3.86 | 20.14 | 165 | Red |
| Example 49 | | D19 | | | | |
| Comparative | | Compound 2-72- | 3.88 | 20.24 | 160 | Red |
| Example 50 | | D23 | | | | |
| Comparative | Compound A-11 | Compound 2-11- | 3.92 | 18.59 | 153 | Red |
| Example 51 | | D21 | | | | |
| Comparative | | Compound 2-20- | 3.79 | 18.14 | 146 | Red |
| Example 52 | | D22 | | | | |
| Comparative | | Compound 2-33- | 3.80 | 18.60 | 147 | Red |
| Example 53 | | D19 | | | | |
| Comparative | | Compound 2-55- | 3.87 | 18.24 | 148 | Red |
| Example 54 | | D23 | | | | |
| Comparative | | Compound 2-65- | 3.88 | 17.95 | 148 | Red |
| Example 55 | | D28 | | | | |
| Comparative | Compound A-12 | Compound 2-12- | 3.81 | 18.10 | 145 | Red |
| Example 56 | | D27 | | | | |
| Comparative | | Compound 2-21- | 3.77 | 18.54 | 150 | Red |
| Example 57 | | D37 | | | | |
| Comparative | | Compound 2-32- | 3.78 | 18.70 | 148 | Red |
| Example 58 | | D24 | | | | |
| Comparative | | Compound 2-44- | 3.88 | 18.31 | 150 | Red |
| Example 59 | | D21 | | | | |
| Comparative | | Compound 2-63- | 3.77 | 18.26 | 145 | Red |
| Example 60 | | D30 | | | | |

TABLE 9

| | | | Driving | Efficiency | Lifetime | Luminous |
|---|---|---|---|---|---|---|
| Category | First host | Second host | voltage (V) | (cd/A) | T95(hr) | color |
| Comparative | Compound 1-1 | Compound C-1 | 3.93 | 18.52 | 163 | Red |
| Example 61 | | | | | | |
| Comparative | Compound 1-6 | | 3.83 | 18.01 | 156 | Red |
| Example 62 | | | | | | |
| Comparative | Compound 1- | | 3.82 | 18.21 | 162 | Red |
| Example 63 | 11 | | | | | |
| Comparative | Compound 1- | | 3.81 | 18.79 | 158 | Red |
| Example 64 | 17 | | | | | |
| Comparative | Compound 1- | | 3.85 | 18.14 | 164 | Red |
| Example 65 | 24 | | | | | |
| Comparative | Compound 1- | | 3.81 | 18.37 | 165 | Red |
| Example 66 | 30 | | | | | |
| Comparative | Compound 1- | | 3.76 | 18.70 | 157 | Red |
| Example 67 | 35 | | | | | |
| Comparative | Compound 1- | | 3.75 | 18.10 | 158 | Red |
| Example 68 | 41 | | | | | |
| Comparative | Compound 1-2 | Compound C-2 | 3.97 | 17.21 | 149 | Red |
| Example 69 | | | | | | |
| Comparative | Compound 1-8 | | 3.75 | 18.17 | 144 | Red |
| Example 70 | | | | | | |
| Comparative | Compound 1- | | 3.78 | 18.42 | 141 | Red |
| Example 71 | 19 | | | | | |
| Comparative | Compound 1- | | 3.84 | 18.24 | 145 | Red |
| Example 72 | 25 | | | | | |
| Comparative | Compound 1- | | 3.75 | 17.95 | 134 | Red |
| Example 73 | 31 | | | | | |
| Comparative | Compound 1- | | 3.88 | 18.26 | 132 | Red |
| Example 74 | 36 | | | | | |
| Comparative | Compound 1- | | 3.75 | 18.46 | 138 | Red |
| Example 75 | 42 | | | | | |
| Comparative | Compound 1- | | 3.86 | 18.40 | 144 | Red |
| Example 76 | 46 | | | | | |
| Comparative | Compound 1-3 | Compound C-3 | 3.86 | 19.86 | 156 | Red |
| Example 77 | | | | | | |
| Comparative | Compound 1-8 | | 3.75 | 19.48 | 163 | Red |
| Example 78 | | | | | | |
| Comparative | Compound 1- | | 3.85 | 19.74 | 155 | Red |
| Example 79 | 14 | | | | | |
| Comparative | Compound 1- | | 3.75 | 20.18 | 163 | Red |
| Example 80 | 20 | | | | | |
| Comparative | Compound 1- | | 3.75 | 19.79 | 152 | Red |
| Example 81 | 28 | | | | | |
| Comparative | Compound 1- | | 3.82 | 19.70 | 161 | Red |
| Example 82 | 34 | | | | | |
| Comparative | Compound 1- | | 3.88 | 19.86 | 165 | Red |
| Example 83 | 43 | | | | | |
| Comparative | Compound 1- | | 3.75 | 19.24 | 157 | Red |
| Example 84 | 50 | | | | | |
| Comparative | Compound 1-4 | Compound C-4 | 3.93 | 17.96 | 146 | Red |
| Example 85 | | | | | | |
| Comparative | Compound 1-9 | | 3.75 | 18.26 | 133 | Red |
| Example 86 | | | | | | |
| Comparative | Compound 1- | | 3.80 | 18.44 | 147 | Red |
| Example 87 | 15 | | | | | |
| Comparative | Compound 1- | | 3.80 | 18.21 | 135 | Red |
| Example 88 | 29 | | | | | |
| Comparative | Compound 1- | | 3.81 | 18.45 | 139 | Red |
| Example 89 | 38 | | | | | |
| Comparative | Compound 1- | | 3.82 | 18.08 | 144 | Red |
| Example 90 | 40 | | | | | |
| Comparative | Compound 1- | | 3.83 | 18.22 | 150 | Red |
| Example 91 | 44 | | | | | |
| Comparative | Compound 1- | | 3.86 | 18.45 | 137 | Red |
| Example 92 | 59 | | | | | |

TABLE 10

| | | | Driving | Efficiency | Lifetime | Luminous |
|---|---|---|---|---|---|---|
| Category | First host | Second host | voltage (V) | (cd/A) | T95(hr) | color |
| Comparative | Compound 1-5 | Compound C-5 | 3.99 | 18.19 | 145 | Red |
| Example 93 | | | | | | |
| Comparative | Compound 1- | | 3.76 | 18.54 | 128 | Red |
| Example 94 | 10 | | | | | |
| Comparative | Compound 1- | | 3.79 | 18.30 | 139 | Red |
| Example 95 | 16 | | | | | |
| Comparative | Compound 1- | | 3.79 | 18.61 | 120 | Red |
| Example 96 | 27 | | | | | |
| Comparative | Compound 1- | | 3.83 | 18.07 | 142 | Red |
| Example 97 | 37 | | | | | |
| Comparative | Compound 1- | | 3.79 | 18.71 | 134 | Red |
| Example 98 | 45 | | | | | |
| Comparative | Compound 1- | | 3.87 | 18.28 | 142 | Red |
| Example 99 | 51 | | | | | |
| Comparative | Compound 1- | | 3.83 | 18.72 | 151 | Red |
| Example 100 | 57 | | | | | |
| Comparative | Compound 1-6 | Compound C-6 | 3.99 | 17.06 | 141 | Red |
| Example 101 | | | | | | |
| Comparative | Compound 1- | | 3.84 | 18.32 | 135 | Red |
| Example 102 | 13 | | | | | |
| Comparative | Compound 1- | | 3.76 | 18.19 | 143 | Red |
| Example 103 | 21 | | | | | |
| Comparative | Compound' 1- | | 3.82 | 18.78 | 151 | Red |
| Example 104 | 32 | | | | | |
| Comparative | Compound 1- | | 3.82 | 18.02 | 137 | Red |
| Example 105 | 35 | | | | | |
| Comparative | Compound 1- | | 3.79 | 18.22 | 148 | Red |
| Example 106 | 49 | | | | | |
| Comparative | Compound 1- | | 3.80 | 18.32 | 142 | Red |
| Example 107 | 55 | | | | | |
| Comparative | Compound 1- | | 3.80 | 18.70 | 138 | Red |
| Example 108 | 61 | | | | | |
| Comparative | Compound 1-8 | Compound C-7 | 3.91 | 18.36 | 148 | Red |
| Example 109 | | | | | | |
| Comparative | Compound 1- | | 3.81 | 17.94 | 157 | Red |
| Example 110 | 13 | | | | | |
| Comparative | Compound 1- | | 3.85 | 18.51 | 160 | Red |
| Example 111 | 22 | | | | | |
| Comparative | Compound 1- | | 3.87 | 18.65 | 151 | Red |
| Example 112 | 33 | | | | | |
| Comparative | Compound 1- | | 3.82 | 18.03 | 163 | Red |
| Example 113 | 41 | | | | | |
| Comparative | Compound 1- | | 3.81 | 18.15 | 156 | Red |
| Example 114 | 48 | | | | | |
| Comparative | Compound 1- | | 3.82 | 18.38 | 143 | Red |
| Example 115 | 54 | | | | | |
| Comparative | Compound- 1- | | 3.83 | 18.66 | 150 | Red |
| Example 116 | 60 | | | | | |
| Comparative | Compound 1-1 | Compound C-8 | 3.76 | 19.86 | 137 | Red |
| Example 117 | | | | | | |
| Comparative | Compound 1-6 | | 3.88 | 19.34 | 149 | Red |
| Example 118 | | | | | | |
| Comparative | Compound 1- | | 3.78 | 19.78 | 142 | Red |
| Example 119 | 11 | | | | | |
| Comparative | Compound 1- | | 3.87 | 19.24 | 136 | Red |
| Example 120 | 17 | | | | | |
| Comparative | Compound 1- | | 3.85 | 19.68 | 142 | Red |
| Example 121 | 24 | | | | | |
| Comparative | Compound 1- | | 3.80 | 19.25 | 138 | Red |
| Example 122 | 30 | | | | | |
| Comparative | Compound 1- | | 3.77 | 19.17 | 146 | Red |
| Example 123 | 35 | | | | | |
| Comparative | Compound 1- | | 3.79 | 20.08 | 130 | Red |
| Example 124 | 41 | | | | | |

TABLE 11

| | | | Driving | Efficiency | Lifetime | Luminous |
|---|---|---|---|---|---|---|
| Category | First host | Second host | voltage (V) | (cd/A) | T95(hr) | color |
| Comparative | Compound 1-1 | Compound 2-1 | 3.49 | 24.68 | 151 | Red |
| Example 125 | | | | | | |
| Comparative | Compound 1-6 | | 3.43 | 24.39 | 136 | Red |
| Example 126 | | | | | | |
| Comparative | Compound 1- | | 3.39 | 24.93 | 142 | Red |
| Example 127 | 11 | | | | | |
| Comparative | Compound 1- | | 3.50 | 24.58 | 145 | Red |
| Example 128 | 17 | | | | | |
| Comparative | Compound 1- | | 3.47 | 25.13 | 147 | Red |
| Example 129 | 24 | | | | | |
| Comparative | Compound 1- | | 3.41 | 24.78 | 155 | Red |
| Example 130 | 30 | | | | | |
| Comparative | Compound 1- | | 3.48 | 24.37 | 150 | Red |
| Example 131 | 35 | | | | | |
| Comparative | Compound 1- | | 3.39 | 25.16 | 146 | Red |
| Example 132 | 41 | | | | | |
| Comparative | Compound 1-2 | Compound 2-2 | 3.47 | 23.98 | 163 | Red |
| Example 133 | | | | | | |
| Comparative | Compound 1-8 | | 3.46 | 24.96 | 147 | Red |
| Example 134 | | | | | | |
| Comparative | Compound 1- | | 3.49 | 24.49 | 155 | Red |
| Example 135 | 19 | | | | | |
| Comparative | Compound 1- | | 3.51 | 24.39 | 158 | Red |
| Example 136 | 25 | | | | | |
| Comparative | Compound 1- | | 3.45 | 24.62 | 162 | Red |
| Example 137 | 31 | | | | | |
| Comparative | Compound- 1- | | 3.49 | 24.40 | 145 | Red |
| Example 138 | 36 | | | | | |
| Comparative | Compound 1- | | 3.42 | 24.82 | 157 | Red |
| Example 139 | 42 | | | | | |
| Comparative | Compound 1- | | 3.47 | 25.37 | 155 | Red |
| Example 140 | 46 | | | | | |
| Comparative | Compound 1-3 | Compound 2-6 | 3.63 | 24.45 | 143 | Red |
| Example 141 | | | | | | |
| Comparative | Compound 1-8 | | 3.62 | 25.28 | 140 | Red |
| Example 142 | | | | | | |
| Comparative | Compound 1- | | 3.55 | 24.82 | 152 | Red |
| Example 143 | 14 | | | | | |
| Comparative | Compound 1- | | 3.59 | 24.46 | 137 | Red |
| Example 144 | 20 | | | | | |
| Comparative | Compound 1- | | 3.55 | 25.45 | 149 | Red |
| Example 145 | 28 | | | | | |
| Comparative | Compound 1- | | 3.55 | 24.86 | 146 | Red |
| Example 146 | 34 | | | | | |
| Comparative | Compound 1- | | 3.51 | 24.65 | 167 | Red |
| Example 147 | 43 | | | | | |
| Comparative | Compound 1- | | 3.60 | 24.49 | 150 | Red |
| Example 148 | 50 | | | | | |
| Comparative | Compound 1-4 | Compound 2- | 3.54 | 22.38 | 159 | Red |
| Example 149 | | 11 | | | | |
| Comparative | Compound 1-9 | | 3.55 | 22.71 | 160 | Red |
| Example 150 | | | | | | |
| Comparative | Compound 1- | | 3.63 | 22.57 | 151 | Red |
| Example 151 | 15 | | | | | |
| Comparative | Compound 1- | | 3.51 | 22.11 | 164 | Red |
| Example 152 | 29 | | | | | |
| Comparative | Compound 1- | | 3.48 | 21.93 | 157 | Red |
| Example 153 | 38 | | | | | |
| Comparative | Compound 1- | | 3.50 | 22.51 | 156 | Red |
| Example 154 | 40 | | | | | |
| Comparative | Compound | | 3.56 | 21.98 | 161 | Red |
| Example 155 | 1-44 | | | | | |
| Comparative | Compound 1- | | 3.48 | 22.82 | 156 | Red |
| Example 156 | 59 | | | | | |
| Comparative | Compound 1-5 | Compound 2- | 3.62 | 23.71 | 134 | Red |
| Example 157 | | 16 | | | | |
| Comparative | Compound 1- | | 3.56 | 21.69 | 158 | Red |
| Example1 158 | 10 | | | | | |
| Comparative | Compound 1- | | 3.72 | 23.87 | 163 | Red |
| Example 159 | 16 | | | | | |
| Comparative | Compound 1- | | 3.79 | 23.30 | 150 | Red |
| Example 160 | 27 | | | | | |
| Comparative | Compound 1- | | 3.80 | 23.64 | 142 | Red |
| Example 161 | 37 | | | | | |
| Comparative | Compound 1- | | 3.73 | 23.18 | 149 | Red |
| Example 162 | 45 | | | | | |
| Comparative | Compound 1- | | 3.70 | 23.50 | 137 | Red |
| Example 163 | 51 | | | | | |
| Comparative | Compound 1- | | 3.69 | 23.59 | 148 | Red |
| Example 164 | 57 | | | | | |

TABLE 12

| | | | Driving | Efficiency | Lifetime | Luminous |
|---|---|---|---|---|---|---|
| Category | First host | Second host | voltage (V) | (cd/A) | T95(hr) | color |
| Comparative | Compound 1-6 | Compound 2- | 3.65 | 22.99 | 164 | Red |
| Example 165 | | 23 | | | | |
| Comparative | Compound 1- | | 3.60 | 25.18 | 149 | Red |
| Example 166 | 13 | | | | | |
| Comparative | Compound 1- | | 3.55 | 24.83 | 134 | Red |
| Example 167 | 21 | | | | | |
| Comparative | Compound 1- | | 3.49 | 25.04 | 141 | Red |
| Example 168 | 32 | | | | | |
| Comparative | Compound 1- | | 3.80 | 23.43 | 132 | Red |
| Example 169 | 35 | | | | | |
| Comparative | Compound 1- | | 3.66 | 23.91 | 148 | Red |
| Example 170 | 49 | | | | | |
| Comparative | Compound 1- | | 3.67 | 23.23 | 140 | Red |
| Example 171 | 55 | | | | | |
| Comparative | Compound 1- | | 3.74 | 23.92 | 144 | Red |
| Example 172 | 61 | | | | | |
| Comparative | Compound 1-8 | Compound 2- | 3.40 | 25.45 | 157 | Red |
| Example 173 | | 25 | | | | |
| Comparative | Compound 1- | | 3.39 | 24.77 | 160 | Red |
| Example 174 | 13 | | | | | |
| Comparative | Compound 1- | | 3.49 | 24.84 | 162 | Red |
| Example 175 | 22 | | | | | |
| Comparative | Compound 1- | | 3.46 | 25.33 | 157 | Red |
| Example 176 | 33 | | | | | |
| Comparative | Compound 1- | | 3.47 | 24.40 | 143 | Red |
| Example 177 | 41 | | | | | |
| Comparative | Compound 1- | | 3.40 | 24.63 | 165 | Red |
| Example 178 | 48 | | | | | |
| Comparative | Compound 1- | | 3.49 | 24.82 | 158 | Red |
| Example 179 | 54 | | | | | |
| Comparative | Compound 1- | | 3.49 | 24.95 | 166 | Red |
| Example 180 | 60 | | | | | |
| Comparative | Compound 1-1 | Compound 2- | 3.64 | 23.38 | 141 | Red |
| Example 181 | | 32 | | | | |
| Comparative | Compound 1-6 | | 3.63 | 23.77 | 149 | Red |
| Example 182 | | | | | | |
| Comparative | Compound 1- | | 3.80 | 23.63 | 137 | Red |
| Example 183 | 11 | | | | | |
| Comparative | Compound 1- | | 3.83 | 23.18 | 145 | Red |
| Example 184 | 17 | | | | | |
| Comparative | Compound 1- | | 3.62 | 23.16 | 151 | Red |
| Example 185 | 24 | | | | | |
| Comparative | Compound 1- | | 3.63 | 23.42 | 139 | Red |
| Example 186 | 30 | | | | | |
| Comparative | Compound 1- | | 3.75 | 24.03 | 140 | Red |
| Example 187 | 35 | | | | | |
| Comparative | Compound 1- | | 3.66 | 23.32 | 132 | Red |
| Example 188 | 41 | | | | | |
| Comparative | Compound 1-2 | Compound 2- | 3.63 | 24.49 | 147 | Red |
| Example 189 | | 33 | | | | |
| Comparative | Compound 1-8 | | 3.55 | 24.33 | 142 | Red |
| Example 190 | | | | | | |
| Comparative | Compound 1- | | 3.59 | 24.46 | 137 | Red |
| Example 191 | 19 | | | | | |
| Comparative | Compound 1- | | 3.48 | 25.20 | 145 | Red |
| Example 192 | 25 | | | | | |
| Comparative | Compound 1- | | 3.58 | 24.37 | 151 | Red |
| Example 193 | 31 | | | | | |
| Comparative | Compound 1- | | 3.50 | 24.62 | 139 | Red |
| Example 194 | 36 | | | | | |
| Comparative | Compound 1- | | 3.61 | 25.20 | 140 | Red |
| Example 195 | 42 | | | | | |
| Comparative | Compound 1- | | 3.50 | 25.31 | 142 | Red |
| Example 196 | 46 | | | | | |
| Comparative | Compound 1-3 | Compound 2- | 3.63 | 21.32 | 131 | Red |
| Example 197 | | 40 | | | | |
| Comparative | Compound 1-8 | | 3.55 | 21.33 | 149 | Red |
| Example1 198 | | | | | | |
| Comparative | Compound 1- | | 3.43 | 24.86 | 155 | Red |
| Example 199 | 14 | | | | | |
| Comparative | Compound 1- | | 3.43 | 24.86 | 164 | Red |
| Example 200 | 20 | | | | | |
| Comparative | Compound 1- | | 3.43 | 24.70 | 158 | Red |
| Example 201 | 28 | | | | | |
| Comparative | Compound 1- | | 3.42 | 25.11 | 152 | Red |
| Example 202 | 34 | | | | | |
| Comparative | Compound 1- | | 3.61 | 21.37 | 140 | Red |
| Example 203 | 43 | | | | | |
| Comparative | Compound 1- | | 3.50 | 21.31 | 162 | Red |
| Example 204 | 50 | | | | | |

TABLE 13

| | | | Driving | Efficiency | Lifetime | Luminous |
|---|---|---|---|---|---|---|
| Category | First host | Second host | voltage (V) | (cd/A) | T95(hr) | color |
| Comparative | Compound 1-4 | Compound 2- | 3.60 | 22.44 | 159 | Red |
| Example 205 | | 48 | | | | |
| Comparative | Compound 1-9 | | 3.52 | 21.89 | 147 | Red |
| Example 206 | | | | | | |
| Comparative | Compound 1- | | 3.56 | 22.86 | 155 | Red |
| Example 207 | 15 | | | | | |
| Comparative | Compound 1- | | 3.60 | 22.61 | 166 | Red |
| Example 208 | 29 | | | | | |
| Comparative | Compound 1- | | 3.62 | 22.69 | 162 | Red |
| Example 209 | 38 | | | | | |
| Comparative | Compound 1- | | 3.48 | 22.55 | 157 | Red |
| Example 210 | 40 | | | | | |
| Comparative | Compound 1- | | 3.50 | 22.54 | 166 | Red |
| Example 211 | 44 | | | | | |
| Comparative | Compound 1- | | 3.49 | 21.82 | 164 | Red |
| Example 212 | 59 | | | | | |
| Comparative | Compound 1-5 | Compound 2- | 3.67 | 23.13 | 148 | Red |
| Example 213 | | 52 | | | | |
| Comparative | Compound 1- | | 3.67 | 23.18 | 134 | Red |
| Example 214 | 10 | | | | | |
| Comparative | Compound 1- | | 3.45 | 25.44 | 163 | Red |
| Example 215 | 16 | | | | | |
| Comparative | Compound 1- | | 3.49 | 24.46 | 162 | Red |
| Example 216 | 27 | | | | | |
| Comparative | Compound 1- | | 3.52 | 24.30 | 167 | Red |
| Example 217 | 37 | | | | | |
| Comparative | Compound 1- | | 3.40 | 24.70 | 165 | Red |
| Example 218 | 45 | | | | | |
| Comparative | Compound 1- | | 3.65 | 23.67 | 131 | Red |
| Example 219 | 51 | | | | | |
| Comparative | Compound 1- | | 3.73 | 23.67 | 137 | Red |
| Example 220 | 57 | | | | | |
| Comparative | Compound 1-6 | Compound 2- | 3.64 | 22.95 | 158 | Red |
| Example 221 | | 60 | | | | |
| Comparative | Compound 1- | | 3.52 | 24.37 | 134 | Red |
| Example 222 | 13 | | | | | |
| Comparative | Compound 1- | | 3.56 | 24.58 | 141 | Red |
| Example 223 | 21 | | | | | |
| Comparative | Compound 1- | | 3.60 | 24.96 | 149 | Red |
| Example 224 | 32 | | | | | |
| Comparative | Compound 1- | | 3.62 | 25.42 | 147 | Red |
| Example 225 | 35 | | | | | |
| Comparative | Compound 1- | | 3.48 | 24.36 | 144 | Red |
| Example 226 | 49 | | | | | |
| Comparative | Compound 1- | | 3.50 | 24.34 | 136 | Red |
| Example 227 | 55 | | | | | |
| Comparative | Compound 1- | | 3.49 | 24.88 | 137 | Red |
| Example 228 | 61 | | | | | |
| Comparative | Compound 1-8 | Compound 2- | 3.63 | 21.15 | 137 | Red |
| Example 229 | | 66 | | | | |
| Comparative | Compound 1- | | 3.62 | 21.05 | 144 | Red |
| Example 230 | 13 | | | | | |
| Comparative | Compound 1- | | 3.57 | 21.19 | 143 | Red |
| Example 231 | 22 | | | | | |
| Comparative | Compound 1- | | 3.40 | 25.34 | 164 | Red |
| Example 232 | 33 | | | | | |
| Comparative | Compound 1- | | 3.40 | 24.24 | 166 | Red |
| Example 233 | 41 | | | | | |
| Comparative | Compound 1- | | 3.48 | 24.31 | 159 | Red |
| Example 234 | 48 | | | | | |
| Comparative | Compound 1- | | 3.48 | 21.11 | 138 | Red |
| Example 235 | 54 | | | | | |
| Comparative | Compound 1- | | 3.60 | 21.32 | 145 | Red |
| Example 236 | 60 | | | | | |

TABLE 14

| | | | Driving | Efficiency | Lifetime | Luminous |
|---|---|---|---|---|---|---|
| Category | First host | Second host | voltage (V) | (cd/A) | T95(hr) | color |
| Comparative | Compound 1-1 | Compound D-1 | 3.47 | 25.25 | 163 | Red |
| Example 237 | | | | | | |
| Comparative | Compound 1-6 | | 3.46 | 25.48 | 160 | Red |
| Example 238 | | | | | | |
| Comparative | Compound 1- | | 3.45 | 25.31 | 159 | Red |
| Example 239 | 11 | | | | | |
| Comparative | Compound 1- | | 3.48 | 25.46 | 166 | Red |
| Example 240 | 17 | | | | | |
| Comparative | Compound 1- | | 3.46 | 24.46 | 162 | Red |
| Example 241 | 24 | | | | | |
| Comparative | Compound 1- | | 3.43 | 25.00 | 161 | Red |
| Example 242 | 30 | | | | | |
| Comparative | Compound 1- | | 3.49 | 24.40 | 163 | Red |
| Example 243 | 35 | | | | | |
| Comparative | Compound 1- | | 3.43 | 25.20 | 157 | Red |
| Example 244 | 41 | | | | | |
| Comparative | Compound 1-2 | Compound D-2 | 3.51 | 22.12 | 160 | Red |
| Example 245 | | | | | | |
| Comparative | Compound 1-8 | | 3.60 | 22.64 | 164 | Red |
| Example 246 | | | | | | |
| Comparative | Compound 1- | | 3.63 | 22.56 | 166 | Red |
| Example 247 | 19 | | | | | |
| Comparative | Compound 1- | | 3.63 | 22.17 | 157 | Red |
| Example 248 | 25 | | | | | |
| Comparative | Compound 1- | | 3.53 | 22.30 | 160 | Red |
| Example 249 | 31 | | | | | |
| Comparative | Compound 1- | | 3.50 | 22.36 | 165 | Red |
| Example 250 | 36 | | | | | |
| Comparative | Compound 1- | | 3.53 | 22.87 | 155 | Red |
| Example 251 | 42 | | | | | |
| Comparative | Compound 1- | | 3.54 | 22.89 | 163 | Red |
| Example 252 | 46 | | | | | |
| Comparative | Compound 1-3 | Compound D-3 | 3.4() | 24.74 | 165 | Red |
| Example 253 | | | | | | |
| Comparative | Compound 1-8 | | 3.39 | 24.89 | 165 | Red |
| Example 254 | | | | | | |
| Comparative | Compound 1- | | 3.51 | 24.63 | 157 | Red |
| Example 255 | 14 | | | | | |
| Comparative | Compound 1- | | 3.56 | 21.92 | 167 | Red |
| Example 256 | 20 | | | | | |
| Comparative | Compound 1- | | 3.39 | 24.76 | 155 | Red |
| Example 257 | 28 | | | | | |
| Comparative | Compound 1- | | 3.49 | 24.54 | 160 | Red |
| Example 258 | 34 | | | | | |
| Comparative | Compound 1- | | 3.40 | 25.09 | 156 | Red |
| Example 259 | 43 | | | | | |
| Comparative | Compound 1- | | 3.51 | 25.47 | 165 | Red |
| Example 260 | 50 | | | | | |
| Comparative | Compound 1-4 | Compound D-4 | 3.40 | 23.72 | 158 | Red |
| Example 261 | | | | | | |
| Comparative | Compound 1-9 | | 3.42 | 23.75 | 165 | Red |
| Example 262 | | | | | | |
| Comparative | Compound 1- | | 3.46 | 23.89 | 157 | Red |
| Example 263 | 15 | | | | | |
| Comparative | Compound 1- | | 3.43 | 23.36 | 162 | Red |
| Example 264 | 29 | | | | | |
| Comparative | Compound 1- | | 3.42 | 23.20 | 160 | Red |
| Example 265 | 38 | | | | | |
| Comparative | Compound 1- | | 3.39 | 23.84 | 161 | Red |
| Example 266 | 40 | | | | | |
| Comparative | Compound 1- | | 3.46 | 23.41 | 163 | Red |
| Example 267 | 44 | | | | | |
| Comparative | Compound 1- | | 3.40 | 23.24 | 159 | Red |
| Example 268 | 59 | | | | | |

When a current was applied to the organic light emitting devices manufactured in Examples 1 to 245 and Comparative Examples 1 to 268, the results shown in Tables 1 to 14 were obtained. The red organic light emitting device of Example 1 used materials that were widely used in the past, and had a structure which used Compound EB-1 as an electron blocking layer and Dp-7 as a dopant in the red light emitting layer. As shown in Table 7 to Table 8, when Comparative Example Compounds A-1 to A-12 and the compound of Chemical Formula 2 of the present disclosure were co-deposited and used as a red light emitting layer, the result showed a whole increase in driving voltage and a decrease in efficiency and lifetime as compared to the combination of the present disclosure. Further, as shown in Tables 9 to 14, even when the comparative compound and the compound of Chemical Formula 1 of the present disclosure were co-deposited and used as a red light emitting layer, the results also showed an increase in driving voltage and a decrease in efficiency and lifetime.

From the above results, it could be confirmed that when the compound represented by Chemical Formula 1 as the first host of the present disclosure and the compound represented by Chemical Formula 2 as the second host of the present disclosure were used in combination, energy transfer to the red dopant in the red light emitting layer was excellently achieved, thereby making a more stable balance in the light emitting layer than the combination in Comparative Examples, and combining the electrons and holes to effectively form excitons and remarkably increase efficiency and lifetime. In addition, it was inferred that deuterium substitution for the compound of the present disclosure contributed to molecular stability and further improved lifetime characteristics. In conclusion, when the compound represented by Chemical Formula 1 and the compound represented by Chemical Formula 2 of the present disclosure are combined, co-deposited, and used as a host of a red light emitting layer, it is possible to improve the driving voltage, luminous efficiency, and lifetime characteristics of the organic light emitting device.

[Description of Symbols]

| | |
|---|---|
| 1: | substrate |
| 2: | anode |
| 3: | light emitting layer |
| 4: | cathode |
| 5: | hole injection layer |
| 6: | hole transport layer |
| 7: | electron blocking layer |
| 8: | hole blocking layer |
| 9: | electron injection and transport layer |

1. An organic light emitting device comprising:
an anode;
a cathode; and
a light emitting layer interposed between the anode and the cathode,
wherein the light emitting layer includes a compound represented by the following Chemical Formula 1, and a compound represented by the following Chemical Formula 2: 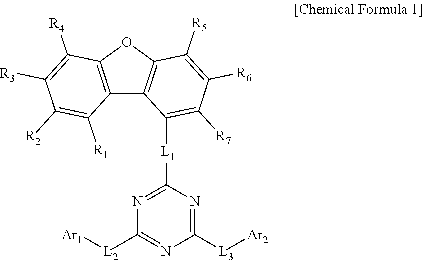
in Chemical Formula 1,
Ar₁ and Ar₂ are each independently a substituted or unsubstituted C₆₋₆₀ aryl; or a substituted or unsubstituted C₂₋₆₀ heteroaryl containing at least one selected from the group consisting of N, O and S,
L₁ is a single bond; or a substituted or unsubstituted C₆₋₆₀ arylene,
L₂ and L₃ are each independently a single bond; a substituted or unsubstituted C₆₋₆₀ arylene; or a substituted or unsubstituted C₂₋₆₀ heteroarylene containing at least one selected from the group consisting of N, O and S, and
R₁ to R₇ are each independently hydrogen or deuterium, 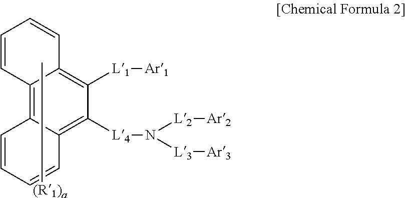
in Chemical Formula 2,
Ar′₁ is hydrogen; deuterium; a substituted or unsubstituted C₆₋₆₀ aryl; or a substituted or unsubstituted C₂₋₆₀ heteroaryl containing at least one selected from the group consisting of N, O and S,
Ar′₂ and Ar′₃ are each independently a substituted or unsubstituted C₆₋₆₀ aryl; or a substituted or unsubstituted C₂₋₆₀ heteroaryl containing at least one selected from the group consisting of N, O and S,
L′₁ to L′₃ are each independently a single bond; a substituted or unsubstituted C₆₋₆₀ arylene; or a substituted or unsubstituted C₂₋₆₀ heteroarylene containing at least one selected from the group consisting of N, O and S,
L′₄ is a single bond or a substituted or unsubstituted C₆₋₆₀ arylene, R′₁ is hydrogen or deuterium,
a is an integer of 1 to 8, and
at least one of -L′₁-Ar′₁ and R′₁ is deuterium,
wherein the compound represented by Chemical Formula 2 has a deuterium substitution rate of 50% or more.

2. The organic light emitting device of claim 1, wherein:
Ar₁ and Ar₂ are each independently phenyl, biphenylyl, terphenylyl, triphenylsilyl phenyl, naphthyl, phenanthrenyl, dibenzofuranyl, or dibenzothiophenyl,
wherein the phenyl, biphenylyl, terphenylyl, triphenylsilyl phenyl, naphthyl, phenanthrenyl, dibenzofuranyl, and dibenzothiophenyl are each independently unsubstituted or substituted with at least one deuterium.

3. The organic light emitting device of claim 1, wherein:
L₁ is a single bond, a substituted or unsubstituted phenylene, or a substituted or unsubstituted naphthalenediyl,

4. The organic light emitting device of claim 1, wherein:
L₂ and L₃ are each independently a single bond, a substituted or unsubstituted phenylene, a substituted or unsubstituted biphenyldiyl, or a substituted or unsubstituted naphthalenediyl.

5. The organic light emitting device of claim 1, wherein:
the compound represented by Chemical Formula 1 is any one selected from the group consisting of the following compounds:

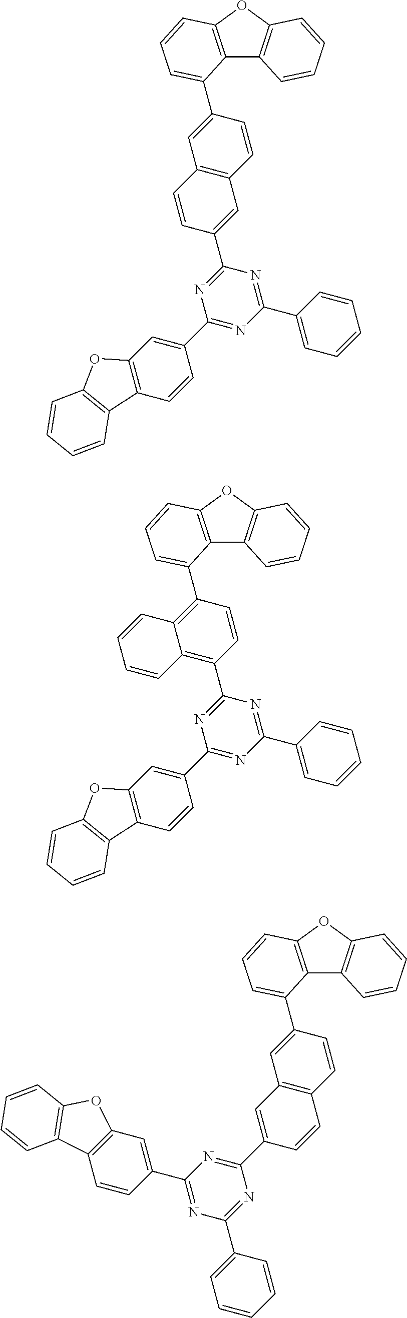 [SMILES: c1ccc(-c2nc(-c3ccc4cc(-c5cccc6oc7ccccc7c56)ccc4c3)nc(-c3ccc4c(c3)oc3ccccc34)n2)cc1 ; c1ccc(-c2nc(-c3ccc4c(c3)oc3ccccc34)nc(-c3ccc(-c4cccc5oc6ccccc6c45)c4ccccc34)n2)cc1 ; c1ccc(-c2nc(-c3ccc4ccc(-c5cccc6oc7ccccc7c56)cc4c3)nc(-c3ccc4c(c3)oc3ccccc34)n2)cc1]

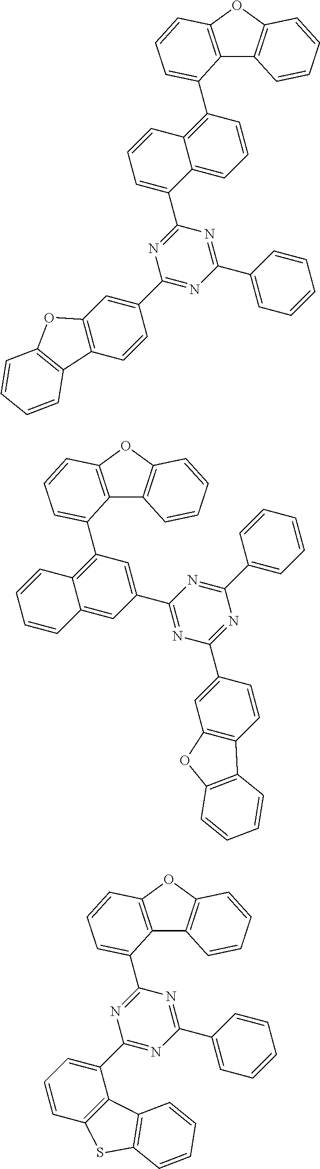 [SMILES: c1ccc(-c2nc(-c3ccc4c(c3)oc3ccccc34)nc(-c3cccc4c(-c5cccc6oc7ccccc7c56)cccc34)n2)cc1 ; c1ccc(-c2nc(-c3cc(-c4cccc5oc6ccccc6c45)c4ccccc4c3)nc(-c3ccc4c(c3)oc3ccccc34)n2)cc1 ; c1ccc(-c2nc(-c3cccc4oc5ccccc5c34)nc(-c3cccc4sc5ccccc5c34)n2)cc1]

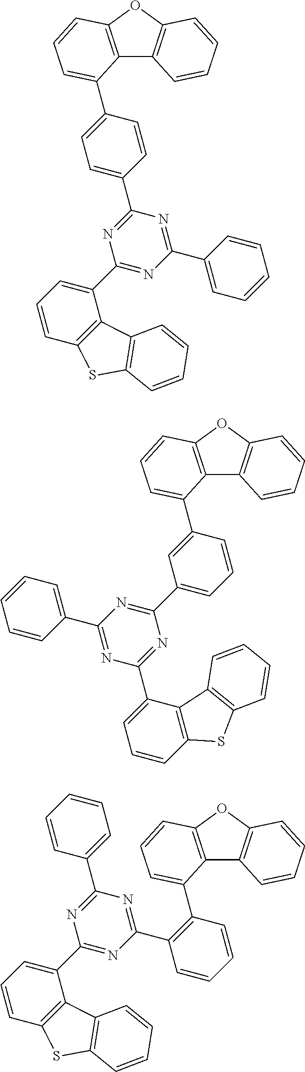

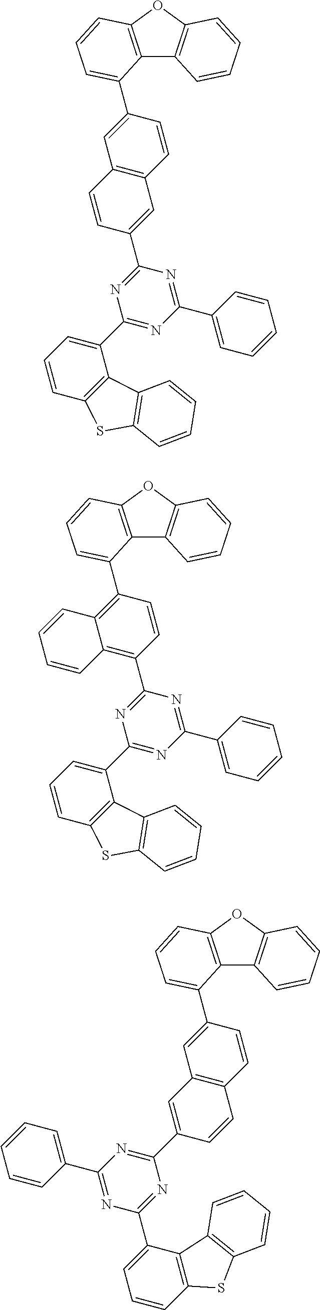

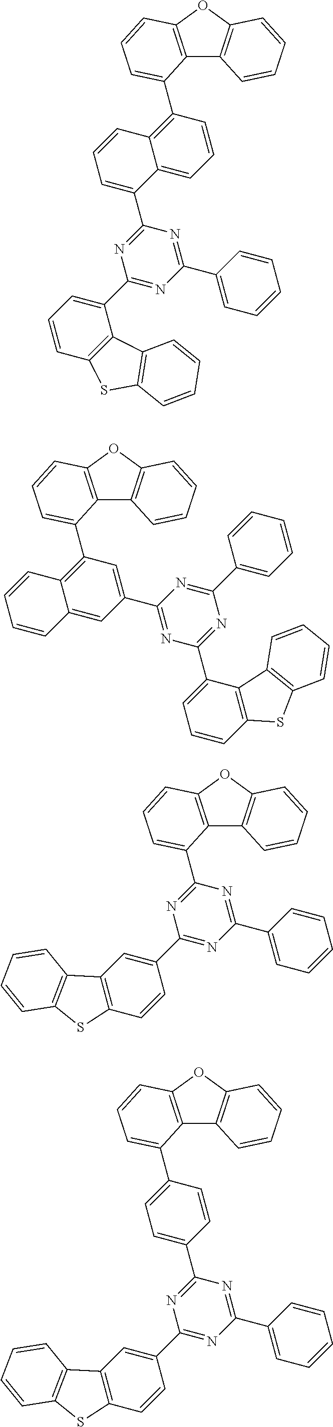

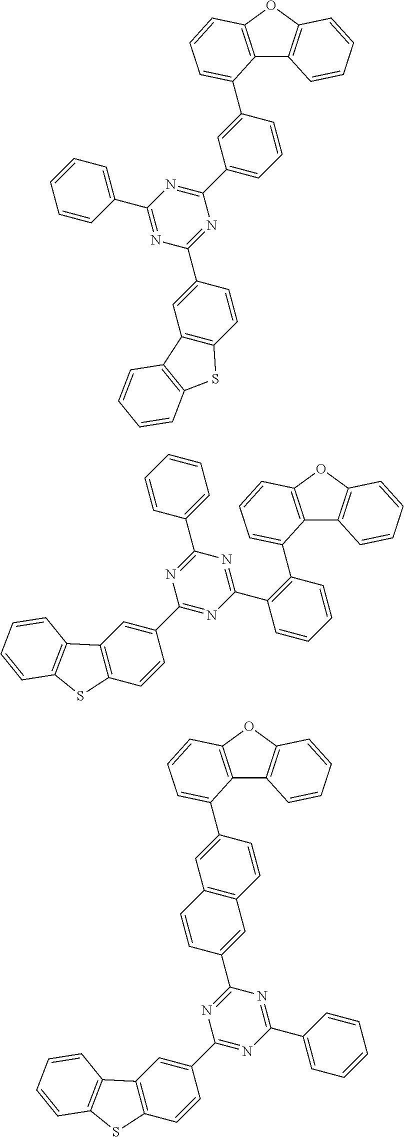

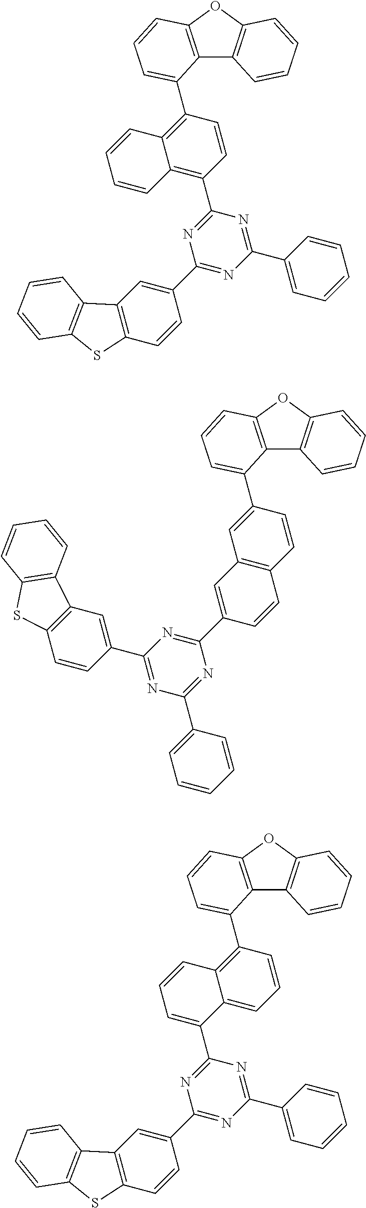 [SMILES: c1ccc(-c2nc(-c3ccc4sc5ccccc5c4c3)nc(-c3ccc(-c4cccc5oc6ccccc6c45)c4ccccc34)n2)cc1 ; c1ccc(-c2nc(-c3ccc4ccc(-c5cccc6oc7ccccc7c56)cc4c3)nc(-c3ccc4sc5ccccc5c4c3)n2)cc1 ; c1ccc(-c2nc(-c3ccc4sc5ccccc5c4c3)nc(-c3cccc4c(-c5cccc6oc7ccccc7c56)cccc34)n2)cc1]

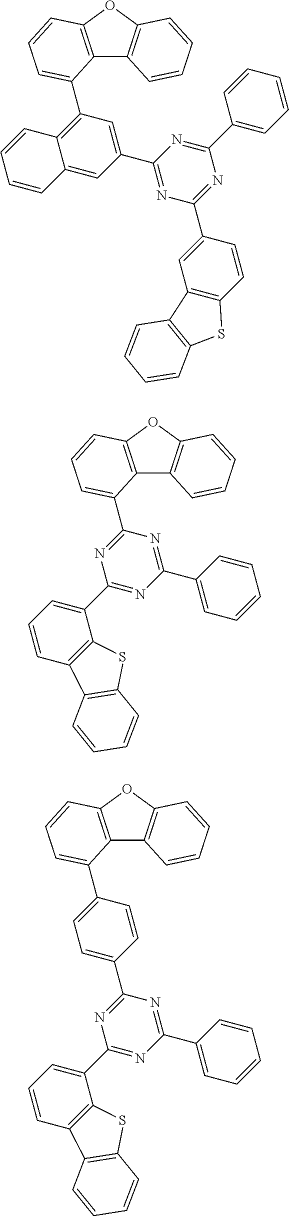

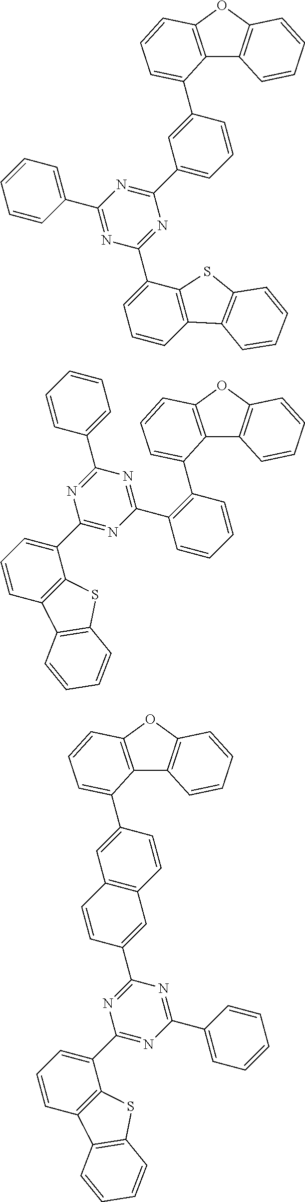

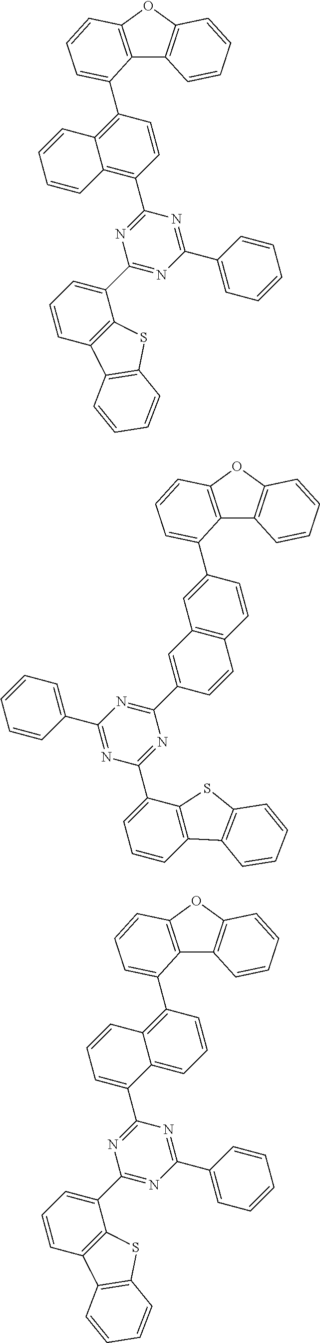 [SMILES: c1ccc(-c2nc(-c3ccc(-c4cccc5oc6ccccc6c45)c4ccccc34)nc(-c3cccc4c3sc3ccccc34)n2)cc1 ; c1ccc(-c2nc(-c3ccc4ccc(-c5cccc6oc7ccccc7c56)cc4c3)nc(-c3cccc4c3sc3ccccc34)n2)cc1 ; c1ccc(-c2nc(-c3cccc4c(-c5cccc6oc7ccccc7c56)cccc34)nc(-c3cccc4c3sc3ccccc34)n2)cc1]

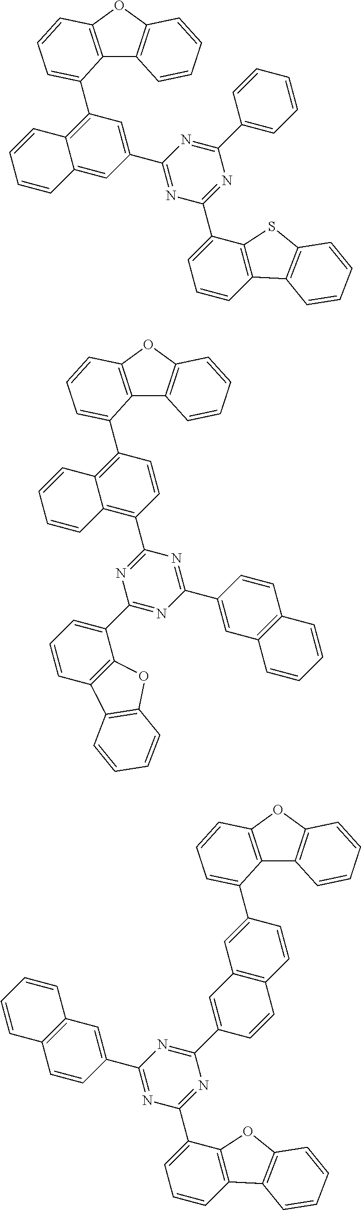 [SMILES: c1ccc(-c2nc(-c3cc(-c4cccc5oc6ccccc6c45)c4ccccc4c3)nc(-c3cccc4c3sc3ccccc34)n2)cc1 ; c1ccc2cc(-c3nc(-c4ccc(-c5cccc6oc7ccccc7c56)c5ccccc45)nc(-c4cccc5c4oc4ccccc45)n3)ccc2c1 ; c1ccc2cc(-c3nc(-c4ccc5ccc(-c6cccc7oc8ccccc8c67)cc5c4)nc(-c4cccc5c4oc4ccccc45)n3)ccc2c1]

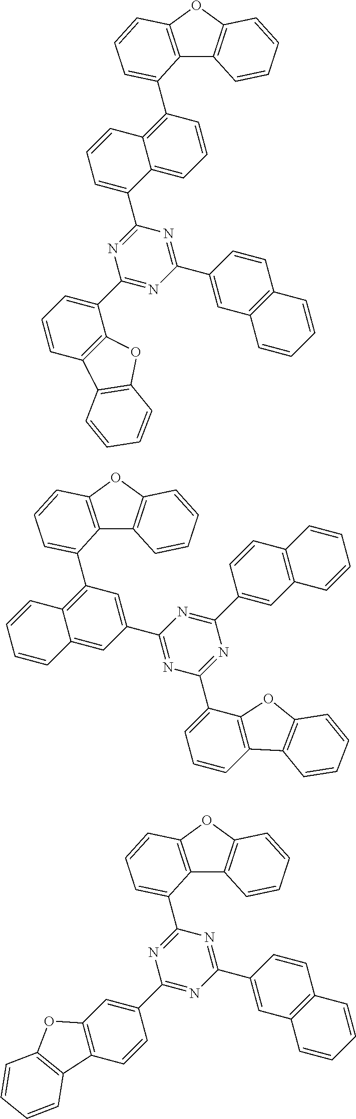

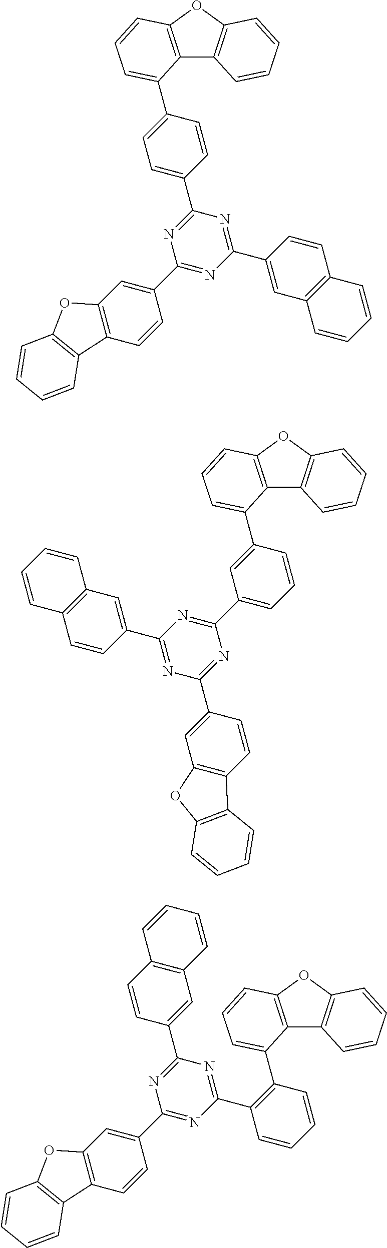

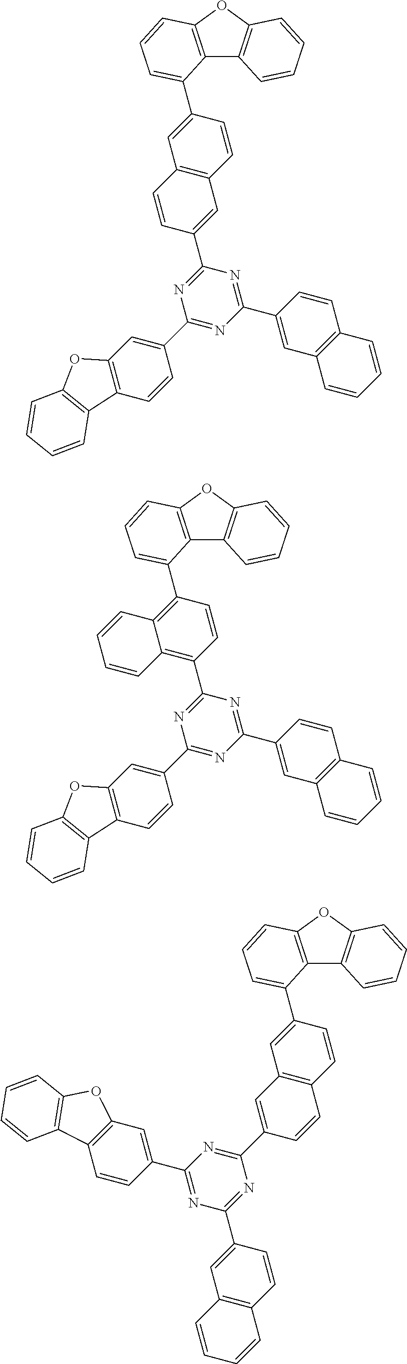 [SMILES: c1ccc2cc(-c3nc(-c4ccc5cc(-c6cccc7oc8ccccc8c67)ccc5c4)nc(-c4ccc5c(c4)oc4ccccc45)n3)ccc2c1 ; c1ccc2cc(-c3nc(-c4ccc5c(c4)oc4ccccc45)nc(-c4ccc(-c5cccc6oc7ccccc7c56)c5ccccc45)n3)ccc2c1 ; c1ccc2cc(-c3nc(-c4ccc5ccc(-c6cccc7oc8ccccc8c67)cc5c4)nc(-c4ccc5c(c4)oc4ccccc45)n3)ccc2c1]

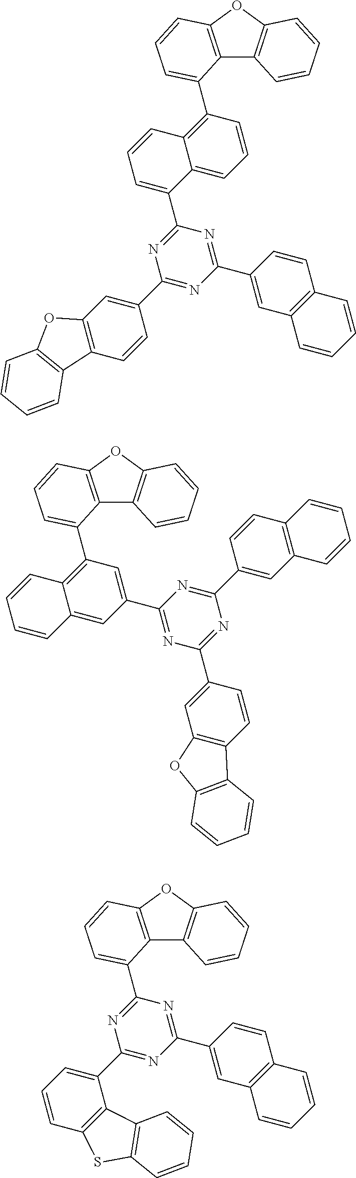 [SMILES: c1ccc2cc(-c3nc(-c4ccc5c(c4)oc4ccccc45)nc(-c4cccc5c(-c6cccc7oc8ccccc8c67)cccc45)n3)ccc2c1 ; c1ccc2cc(-c3nc(-c4cc(-c5cccc6oc7ccccc7c56)c5ccccc5c4)nc(-c4ccc5c(c4)oc4ccccc45)n3)ccc2c1 ; c1ccc2cc(-c3nc(-c4cccc5oc6ccccc6c45)nc(-c4cccc5sc6ccccc6c45)n3)ccc2c1]

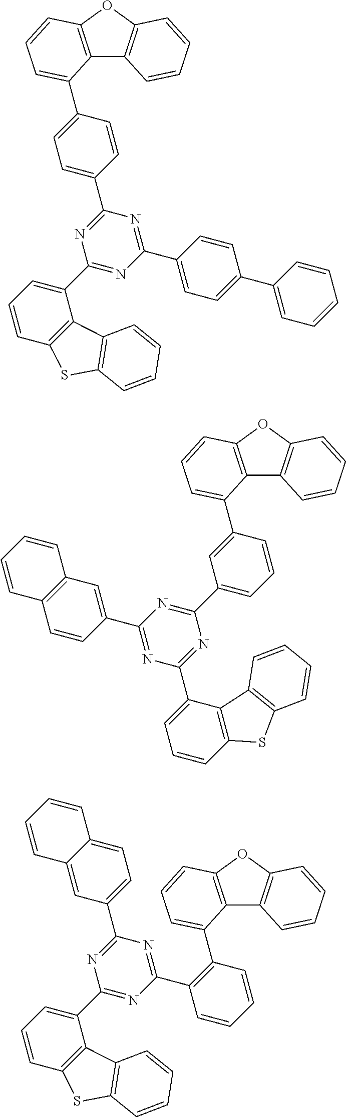 [SMILES: c1ccc(-c2ccc(-c3nc(-c4ccc(-c5cccc6oc7ccccc7c56)cc4)nc(-c4cccc5sc6ccccc6c45)n3)cc2)cc1 ; c1cc(-c2nc(-c3ccc4ccccc4c3)nc(-c3cccc4sc5ccccc5c34)n2)cc(-c2cccc3oc4ccccc4c23)c1 ; c1ccc(-c2cccc3oc4ccccc4c23)c(-c2nc(-c3ccc4ccccc4c3)nc(-c3cccc4sc5ccccc5c34)n2)c1]

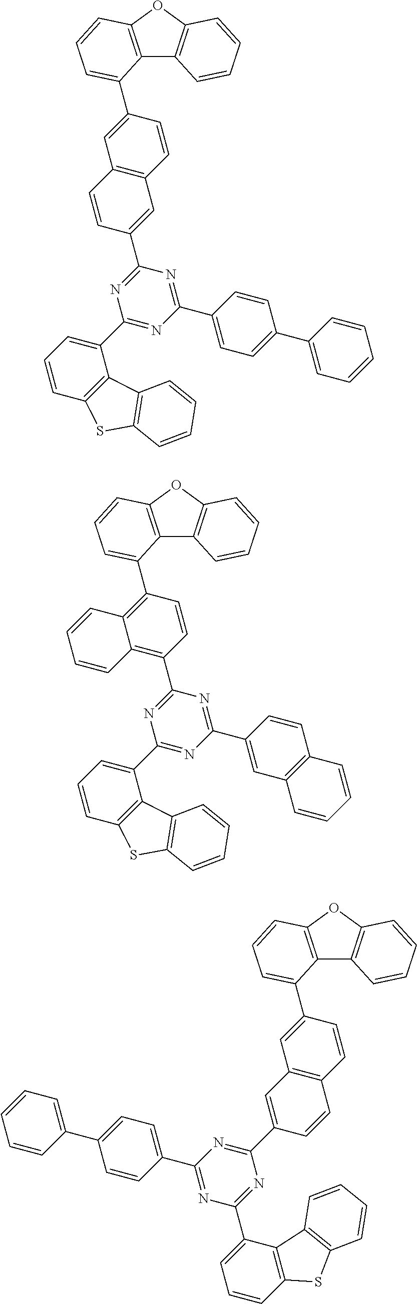

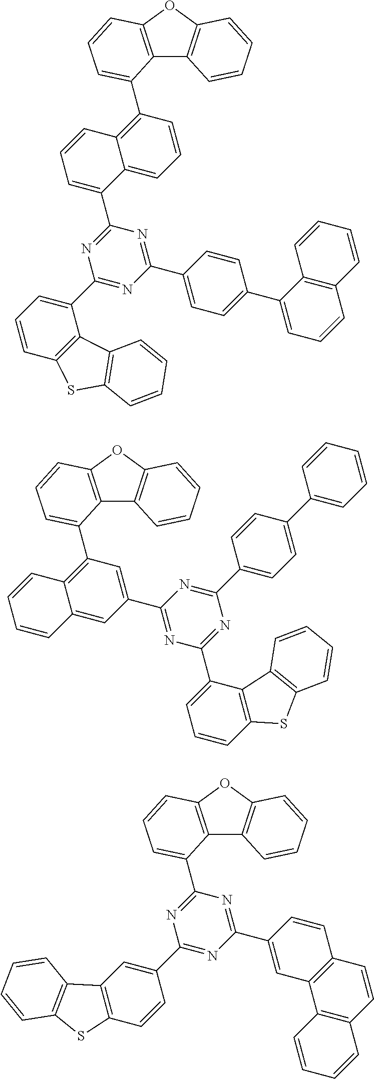

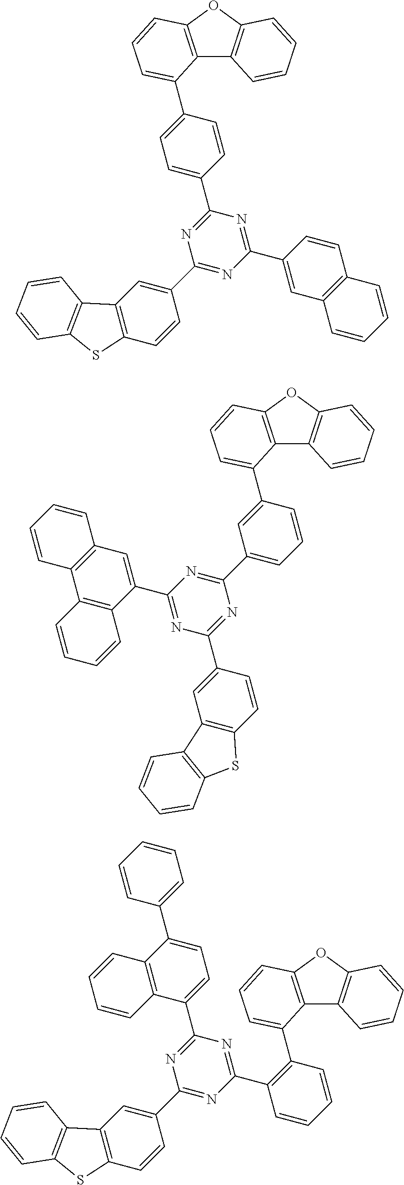

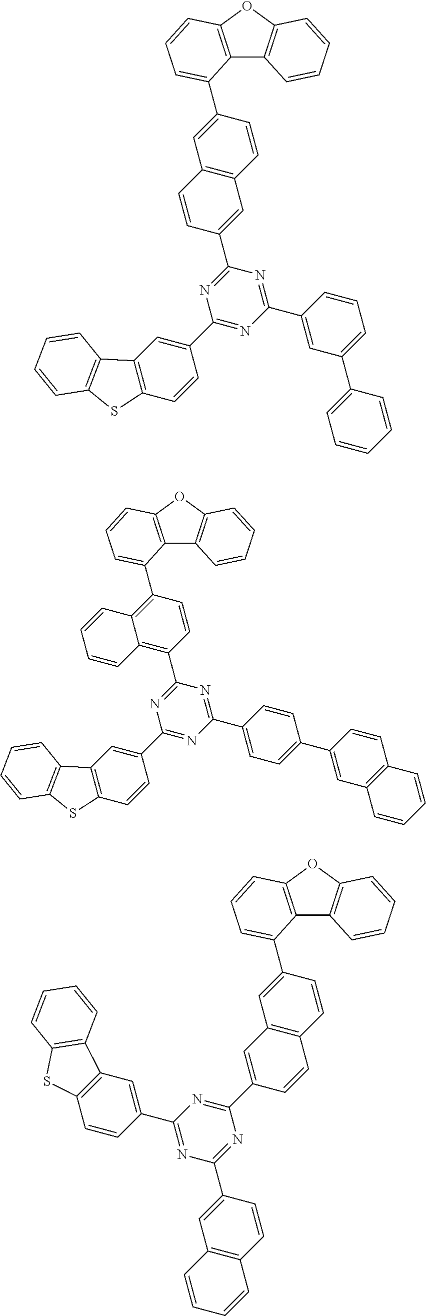 [SMILES: c1ccc(-c2cccc(-c3nc(-c4ccc5cc(-c6cccc7oc8ccccc8c67)ccc5c4)nc(-c4ccc5sc6ccccc6c5c4)n3)c2)cc1 ; c1ccc2cc(-c3ccc(-c4nc(-c5ccc6sc7ccccc7c6c5)nc(-c5ccc(-c6cccc7oc8ccccc8c67)c6ccccc56)n4)cc3)ccc2c1 ; c1ccc2cc(-c3nc(-c4ccc5ccc(-c6cccc7oc8ccccc8c67)cc5c4)nc(-c4ccc5sc6ccccc6c5c4)n3)ccc2c1]

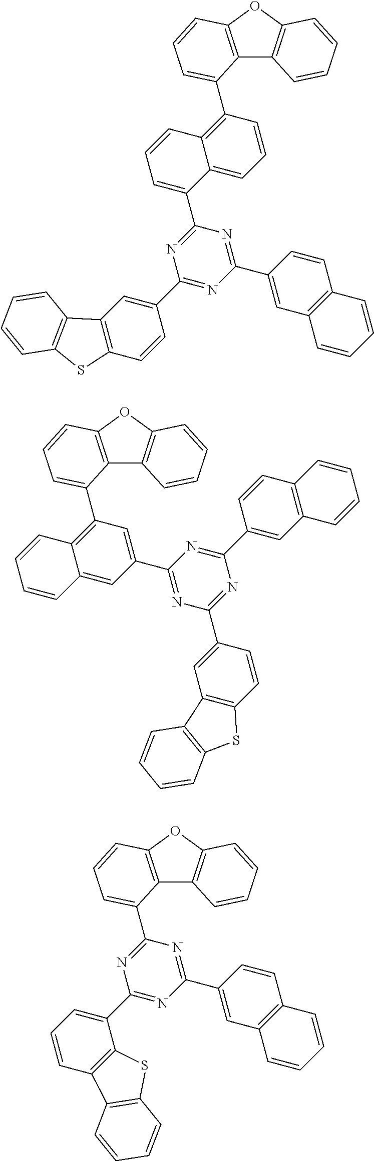

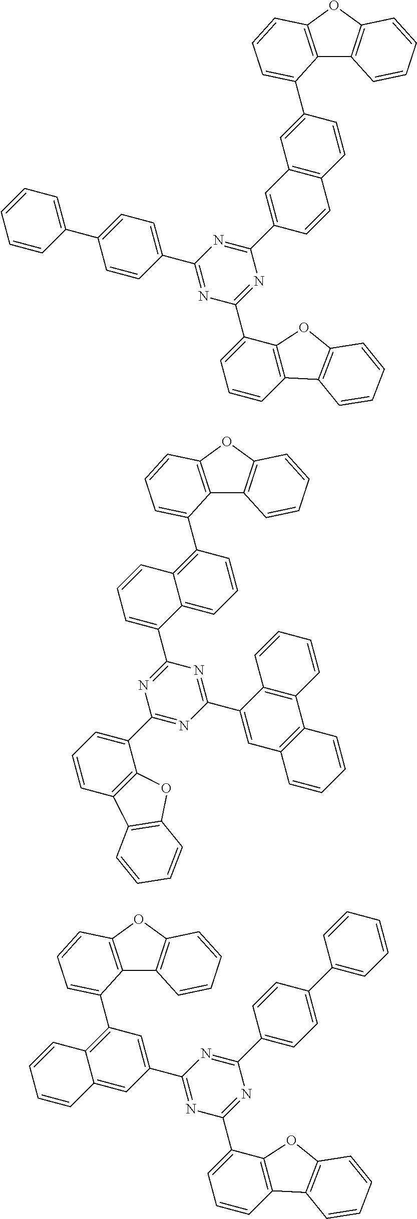

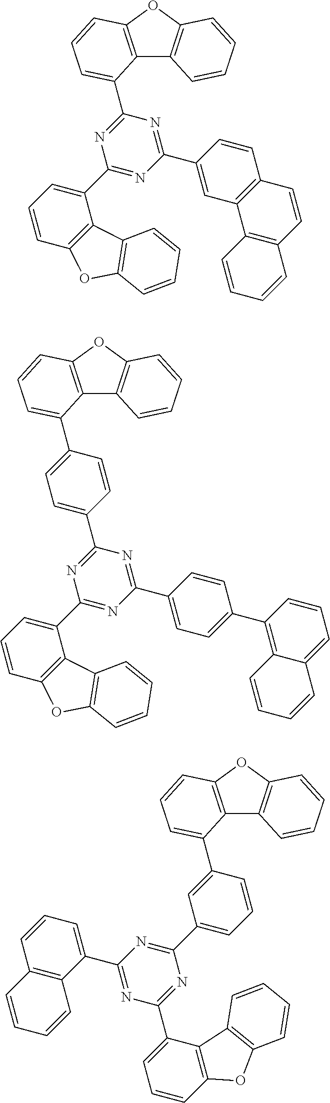 [SMILES: c1ccc2c(c1)ccc1ccc(-c3nc(-c4cccc5oc6ccccc6c45)nc(-c4cccc5oc6ccccc6c45)n3)cc12 ; c1ccc2c(-c3ccc(-c4nc(-c5ccc(-c6cccc7oc8ccccc8c67)cc5)nc(-c5cccc6oc7ccccc7c56)n4)cc3)cccc2c1 ; c1cc(-c2nc(-c3cccc4ccccc34)nc(-c3cccc4oc5ccccc5c34)n2)cc(-c2cccc3oc4ccccc4c23)c1]

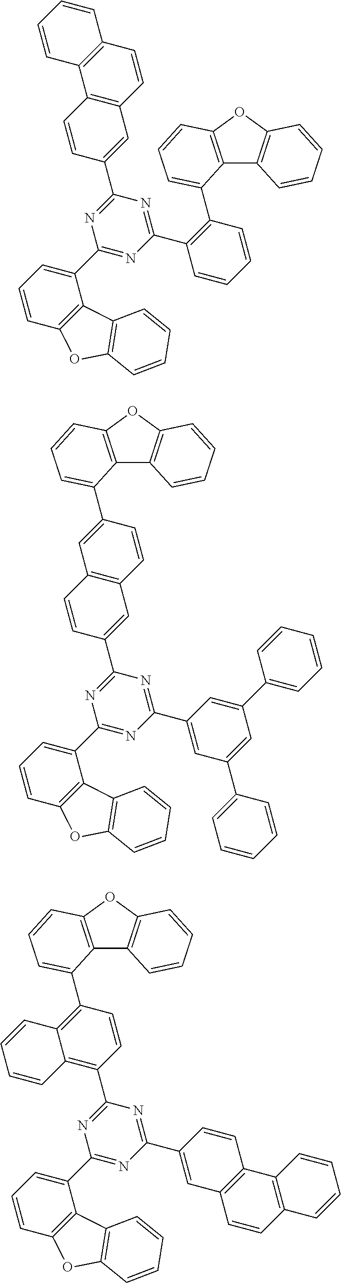

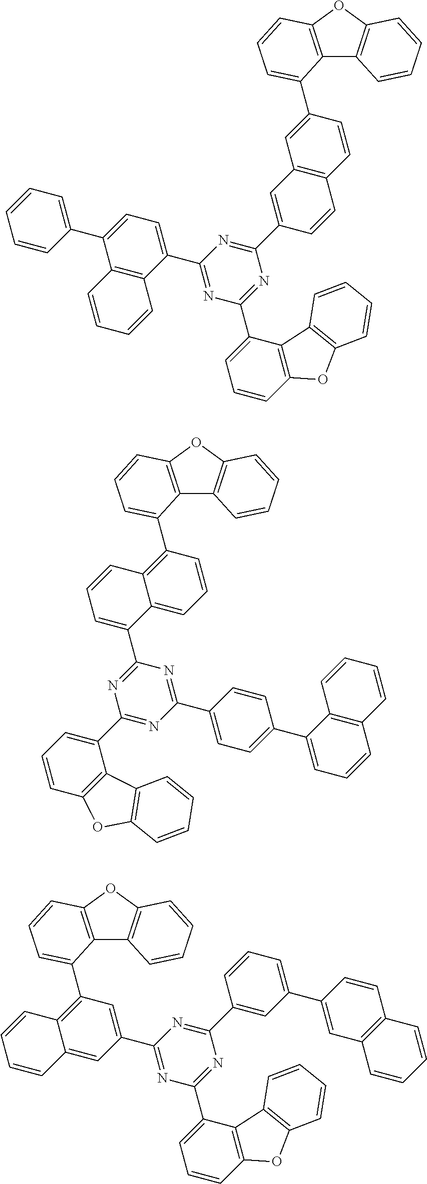 [SMILES: c1ccc(-c2ccc(-c3nc(-c4ccc5ccc(-c6cccc7oc8ccccc8c67)cc5c4)nc(-c4cccc5oc6ccccc6c45)n3)c3ccccc23)cc1 ; c1ccc2c(-c3ccc(-c4nc(-c5cccc6c(-c7cccc8oc9ccccc9c78)cccc56)nc(-c5cccc6oc7ccccc7c56)n4)cc3)cccc2c1 ; c1cc(-c2ccc3ccccc3c2)cc(-c2nc(-c3cc(-c4cccc5oc6ccccc6c45)c4ccccc4c3)nc(-c3cccc4oc5ccccc5c34)n2)c1]

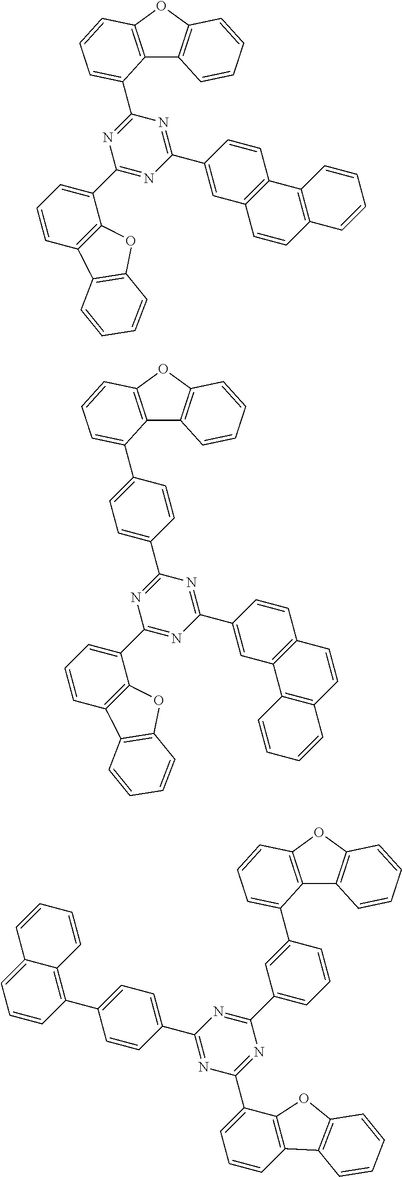

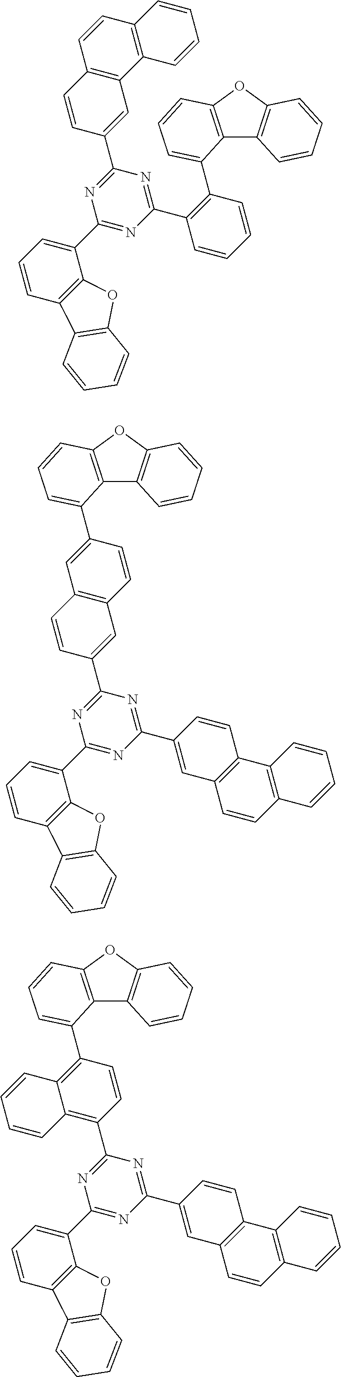

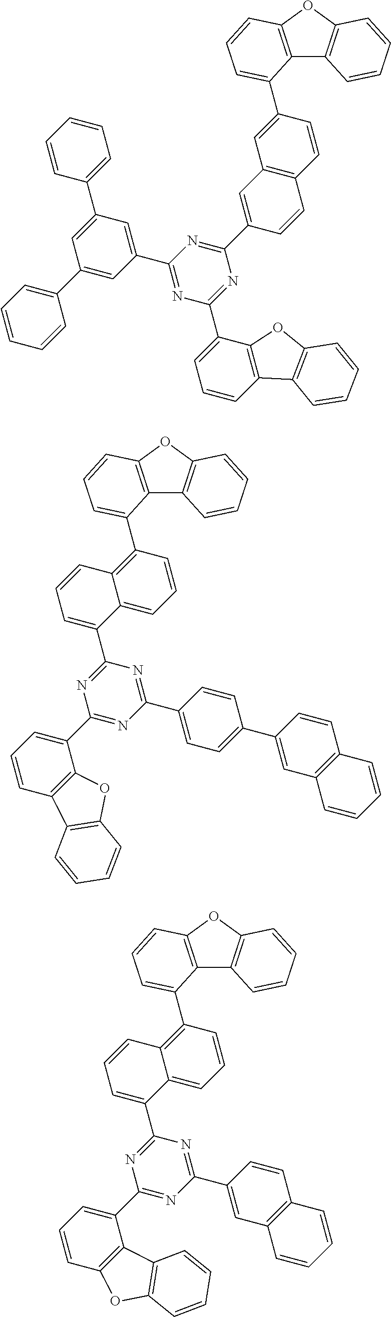 [SMILES: c1ccc(-c2cc(-c3ccccc3)cc(-c3nc(-c4ccc5ccc(-c6cccc7oc8ccccc8c67)cc5c4)nc(-c4cccc5c4oc4ccccc45)n3)c2)cc1 ; c1ccc2cc(-c3ccc(-c4nc(-c5cccc6c(-c7cccc8oc9ccccc9c78)cccc56)nc(-c5cccc6c5oc5ccccc56)n4)cc3)ccc2c1 ; c1ccc2cc(-c3nc(-c4cccc5c(-c6cccc7oc8ccccc8c67)cccc45)nc(-c4cccc5oc6ccccc6c45)n3)ccc2c1]

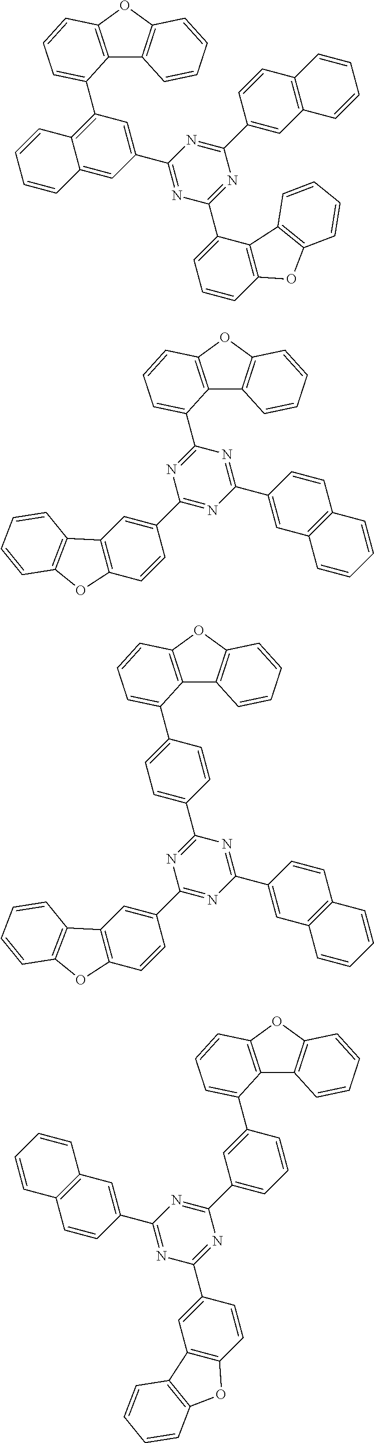

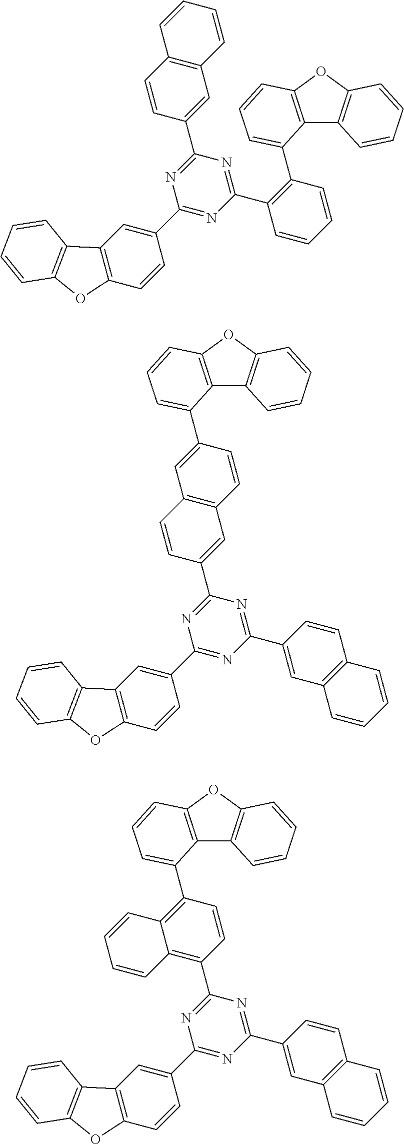 [SMILES: c1ccc(-c2cccc3oc4ccccc4c23)c(-c2nc(-c3ccc4ccccc4c3)nc(-c3ccc4oc5ccccc5c4c3)n2)c1 ; c1ccc2cc(-c3nc(-c4ccc5cc(-c6cccc7oc8ccccc8c67)ccc5c4)nc(-c4ccc5oc6ccccc6c5c4)n3)ccc2c1 ; c1ccc2cc(-c3nc(-c4ccc5oc6ccccc6c5c4)nc(-c4ccc(-c5cccc6oc7ccccc7c56)c5ccccc45)n3)ccc2c1]

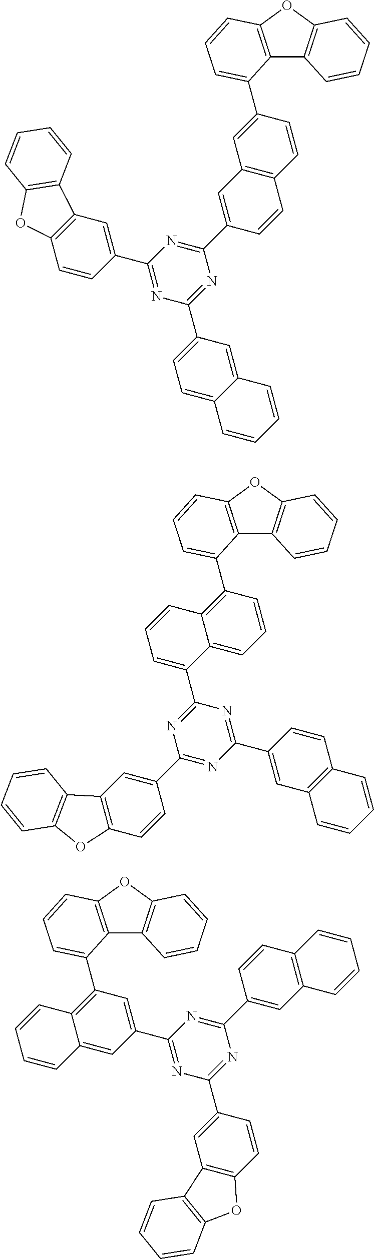

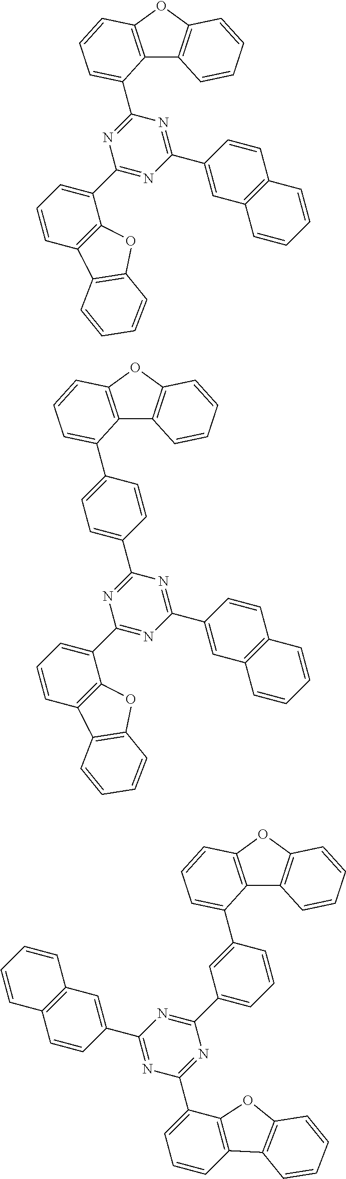

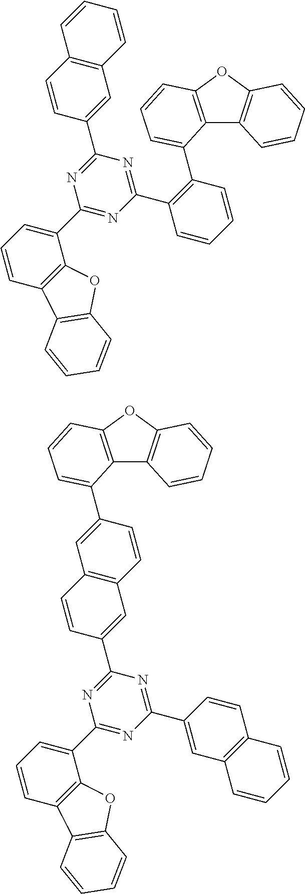 [SMILES: c1ccc(-c2cccc3oc4ccccc4c23)c(-c2nc(-c3ccc4ccccc4c3)nc(-c3cccc4c3oc3ccccc34)n2)c1 ; c1ccc2cc(-c3nc(-c4ccc5cc(-c6cccc7oc8ccccc8c67)ccc5c4)nc(-c4cccc5c4oc4ccccc45)n3)ccc2c1]

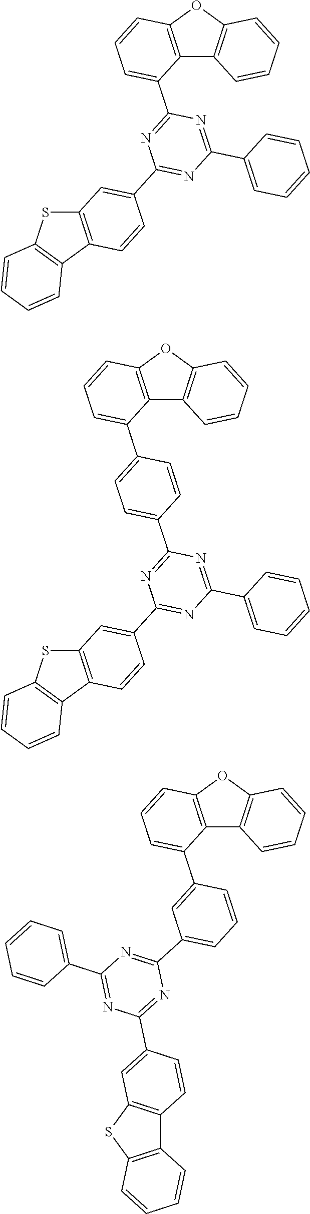 [SMILES: c1ccc(-c2nc(-c3ccc4c(c3)sc3ccccc34)nc(-c3cccc4oc5ccccc5c34)n2)cc1 ; c1ccc(-c2nc(-c3ccc(-c4cccc5oc6ccccc6c45)cc3)nc(-c3ccc4c(c3)sc3ccccc34)n2)cc1 ; c1ccc(-c2nc(-c3cccc(-c4cccc5oc6ccccc6c45)c3)nc(-c3ccc4c(c3)sc3ccccc34)n2)cc1]

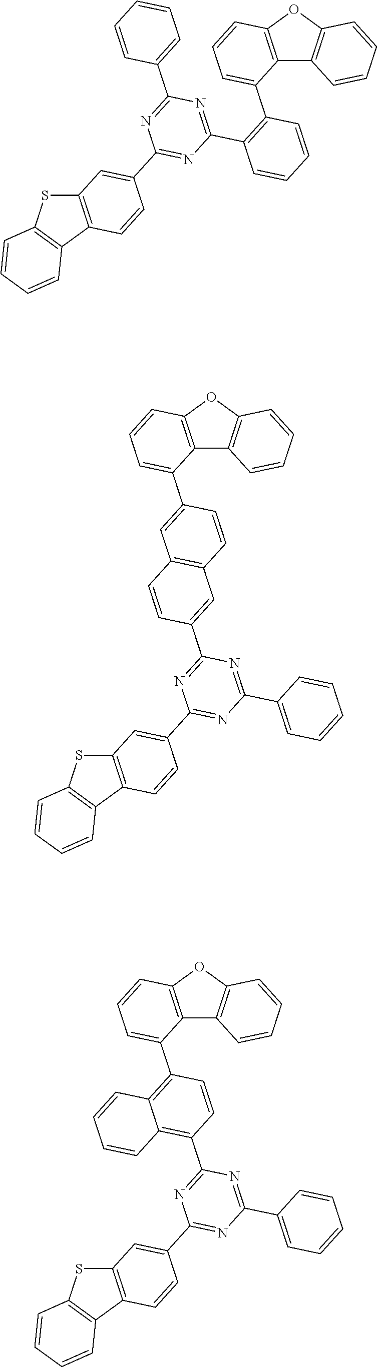 [SMILES: c1ccc(-c2nc(-c3ccc4c(c3)sc3ccccc34)nc(-c3ccccc3-c3cccc4oc5ccccc5c34)n2)cc1 ; c1ccc(-c2nc(-c3ccc4cc(-c5cccc6oc7ccccc7c56)ccc4c3)nc(-c3ccc4c(c3)sc3ccccc34)n2)cc1 ; c1ccc(-c2nc(-c3ccc4c(c3)sc3ccccc34)nc(-c3ccc(-c4cccc5oc6ccccc6c45)c4ccccc34)n2)cc1]

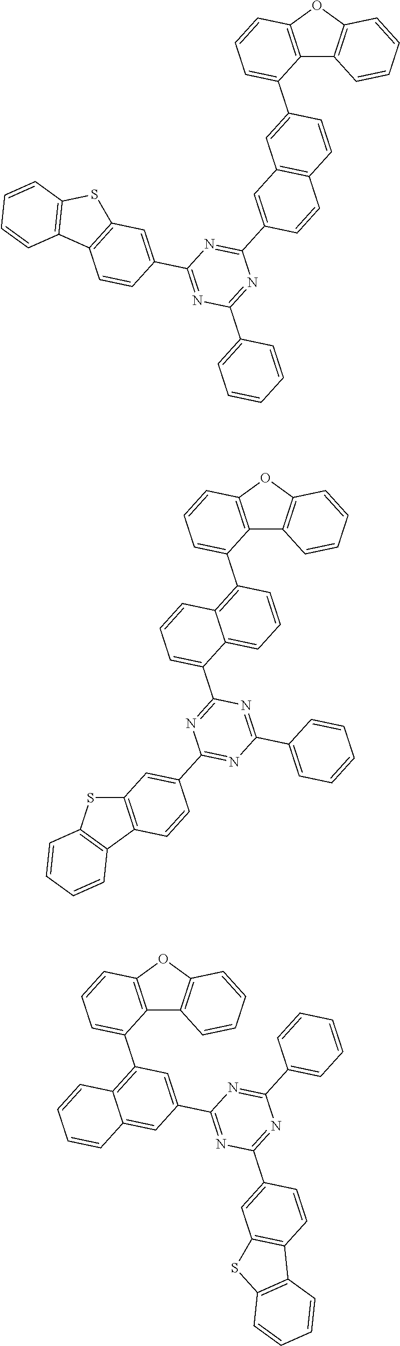 [SMILES: c1ccc(-c2nc(-c3ccc4ccc(-c5cccc6oc7ccccc7c56)cc4c3)nc(-c3ccc4c(c3)sc3ccccc34)n2)cc1 ; c1ccc(-c2nc(-c3ccc4c(c3)sc3ccccc34)nc(-c3cccc4c(-c5cccc6oc7ccccc7c56)cccc34)n2)cc1 ; c1ccc(-c2nc(-c3cc(-c4cccc5oc6ccccc6c45)c4ccccc4c3)nc(-c3ccc4c(c3)sc3ccccc34)n2)cc1]

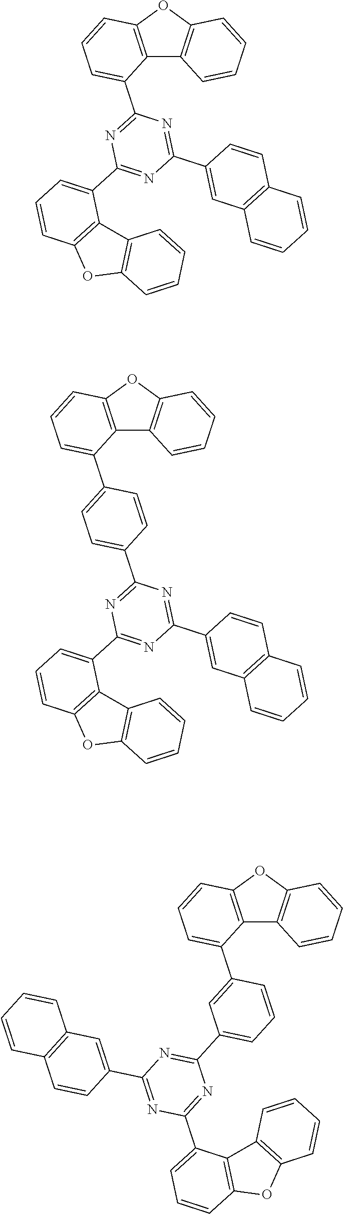 [SMILES: c1ccc2cc(-c3nc(-c4cccc5oc6ccccc6c45)nc(-c4cccc5oc6ccccc6c45)n3)ccc2c1 ; c1ccc2cc(-c3nc(-c4ccc(-c5cccc6oc7ccccc7c56)cc4)nc(-c4cccc5oc6ccccc6c45)n3)ccc2c1 ; c1cc(-c2nc(-c3ccc4ccccc4c3)nc(-c3cccc4oc5ccccc5c34)n2)cc(-c2cccc3oc4ccccc4c23)c1]

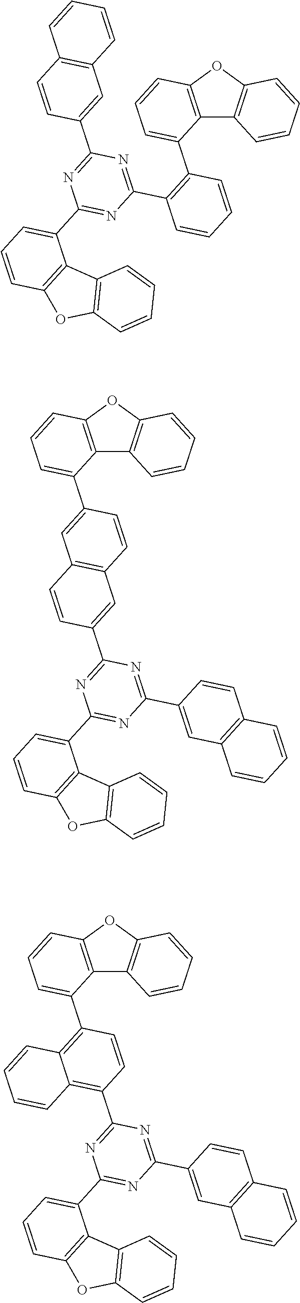 [SMILES: c1ccc(-c2cccc3oc4ccccc4c23)c(-c2nc(-c3ccc4ccccc4c3)nc(-c3cccc4oc5ccccc5c34)n2)c1 ; c1ccc2cc(-c3nc(-c4ccc5cc(-c6cccc7oc8ccccc8c67)ccc5c4)nc(-c4cccc5oc6ccccc6c45)n3)ccc2c1 ; c1ccc2cc(-c3nc(-c4ccc(-c5cccc6oc7ccccc7c56)c5ccccc45)nc(-c4cccc5oc6ccccc6c45)n3)ccc2c1]

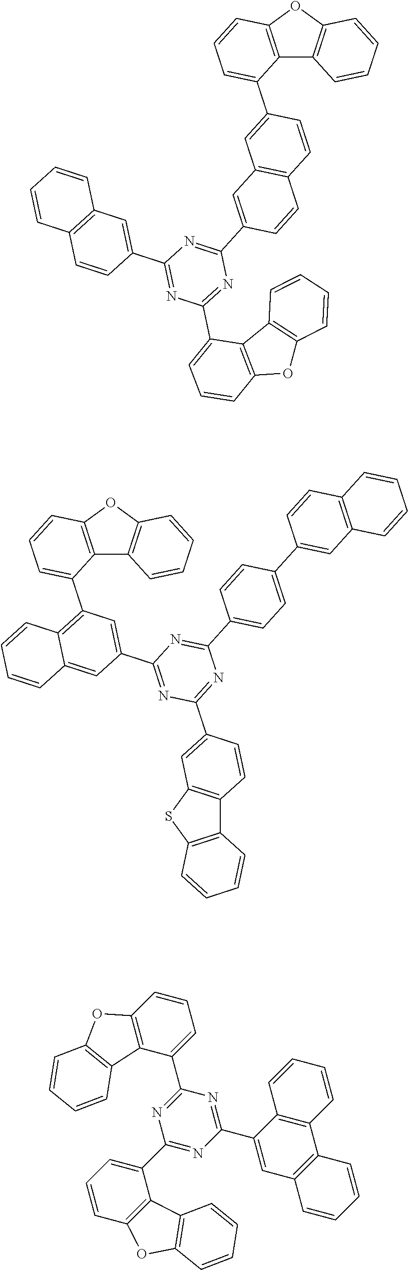 [SMILES: c1ccc2cc(-c3nc(-c4ccc5ccc(-c6cccc7oc8ccccc8c67)cc5c4)nc(-c4cccc5oc6ccccc6c45)n3)ccc2c1 ; c1ccc2cc(-c3ccc(-c4nc(-c5cc(-c6cccc7oc8ccccc8c67)c6ccccc6c5)nc(-c5ccc6c(c5)sc5ccccc56)n4)cc3)ccc2c1 ; c1ccc2c(c1)cc(-c1nc(-c3cccc4oc5ccccc5c34)nc(-c3cccc4oc5ccccc5c34)n1)c1ccccc12]

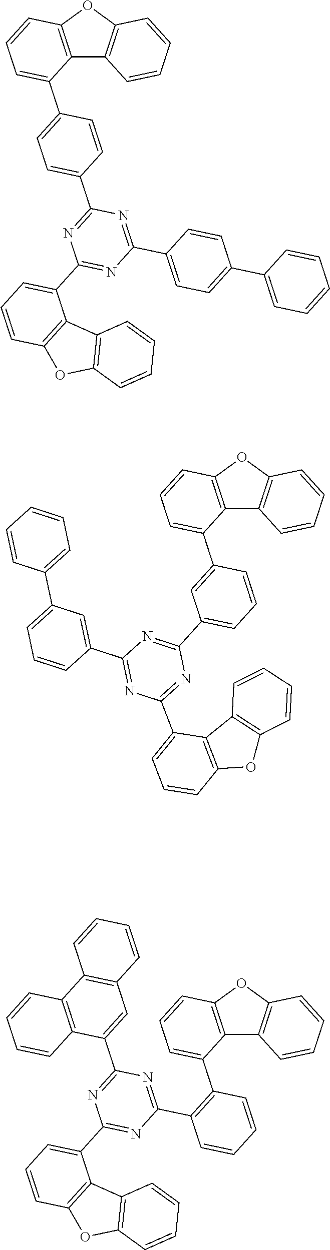 [SMILES: c1ccc(-c2ccc(-c3nc(-c4ccc(-c5cccc6oc7ccccc7c56)cc4)nc(-c4cccc5oc6ccccc6c45)n3)cc2)cc1 ; c1ccc(-c2cccc(-c3nc(-c4cccc(-c5cccc6oc7ccccc7c56)c4)nc(-c4cccc5oc6ccccc6c45)n3)c2)cc1 ; c1ccc(-c2cccc3oc4ccccc4c23)c(-c2nc(-c3cc4ccccc4c4ccccc34)nc(-c3cccc4oc5ccccc5c34)n2)c1]

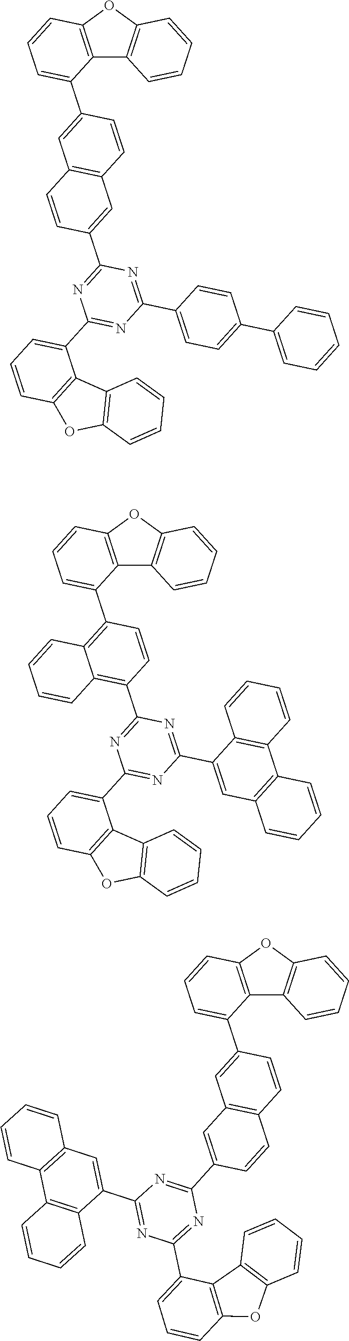 [SMILES: c1ccc(-c2ccc(-c3nc(-c4ccc5cc(-c6cccc7oc8ccccc8c67)ccc5c4)nc(-c4cccc5oc6ccccc6c45)n3)cc2)cc1 ; c1ccc2c(c1)cc(-c1nc(-c3ccc(-c4cccc5oc6ccccc6c45)c4ccccc34)nc(-c3cccc4oc5ccccc5c34)n1)c1ccccc12 ; c1ccc2c(c1)cc(-c1nc(-c3ccc4ccc(-c5cccc6oc7ccccc7c56)cc4c3)nc(-c3cccc4oc5ccccc5c34)n1)c1ccccc12]

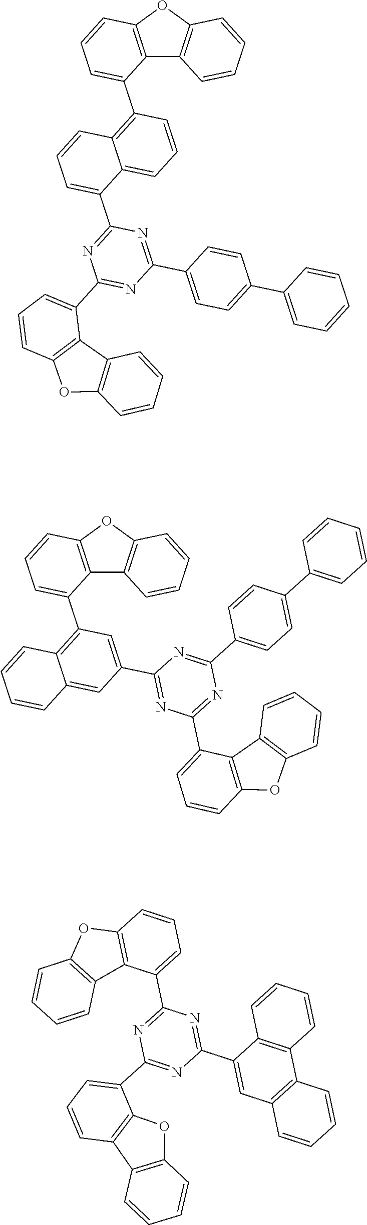 [SMILES: c1ccc(-c2ccc(-c3nc(-c4cccc5c(-c6cccc7oc8ccccc8c67)cccc45)nc(-c4cccc5oc6ccccc6c45)n3)cc2)cc1 ; c1ccc(-c2ccc(-c3nc(-c4cc(-c5cccc6oc7ccccc7c56)c5ccccc5c4)nc(-c4cccc5oc6ccccc6c45)n3)cc2)cc1 ; c1ccc2c(c1)cc(-c1nc(-c3cccc4c3oc3ccccc34)nc(-c3cccc4oc5ccccc5c34)n1)c1ccccc12]

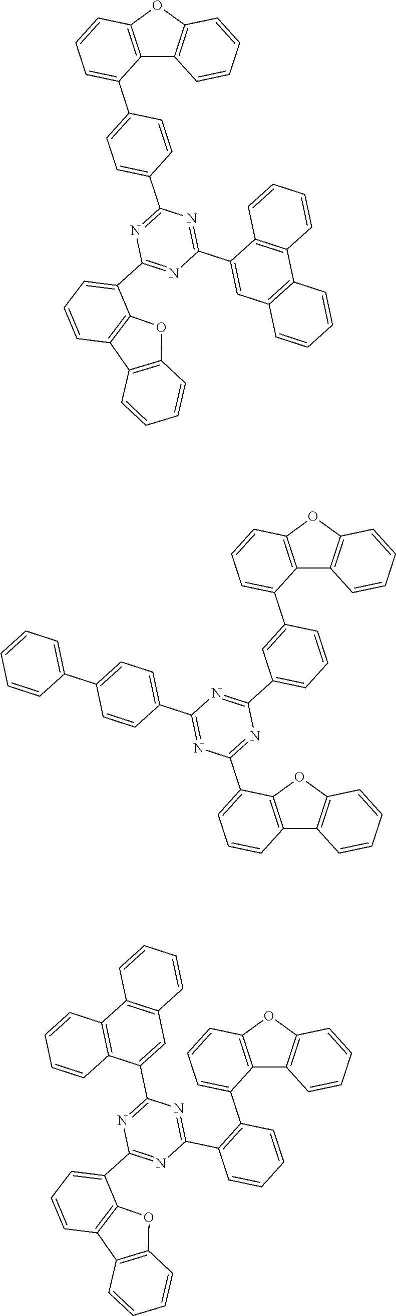 [SMILES: c1ccc2c(c1)cc(-c1nc(-c3ccc(-c4cccc5oc6ccccc6c45)cc3)nc(-c3cccc4c3oc3ccccc34)n1)c1ccccc12 ; c1ccc(-c2ccc(-c3nc(-c4cccc(-c5cccc6oc7ccccc7c56)c4)nc(-c4cccc5c4oc4ccccc45)n3)cc2)cc1 ; c1ccc(-c2cccc3oc4ccccc4c23)c(-c2nc(-c3cc4ccccc4c4ccccc34)nc(-c3cccc4c3oc3ccccc34)n2)c1]

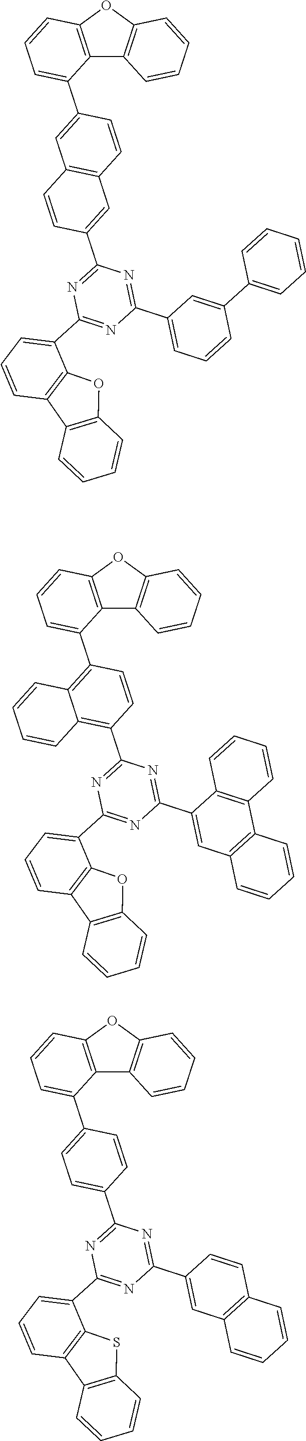

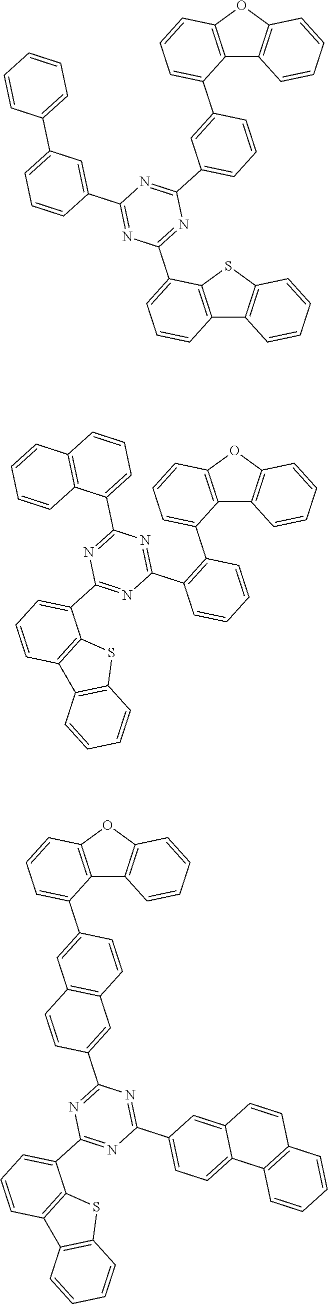 [SMILES: c1ccc(-c2cccc(-c3nc(-c4cccc(-c5cccc6oc7ccccc7c56)c4)nc(-c4cccc5c4sc4ccccc45)n3)c2)cc1 ; c1ccc(-c2cccc3oc4ccccc4c23)c(-c2nc(-c3cccc4ccccc34)nc(-c3cccc4c3sc3ccccc34)n2)c1 ; c1ccc2c(c1)ccc1cc(-c3nc(-c4ccc5cc(-c6cccc7oc8ccccc8c67)ccc5c4)nc(-c4cccc5c4sc4ccccc45)n3)ccc12]

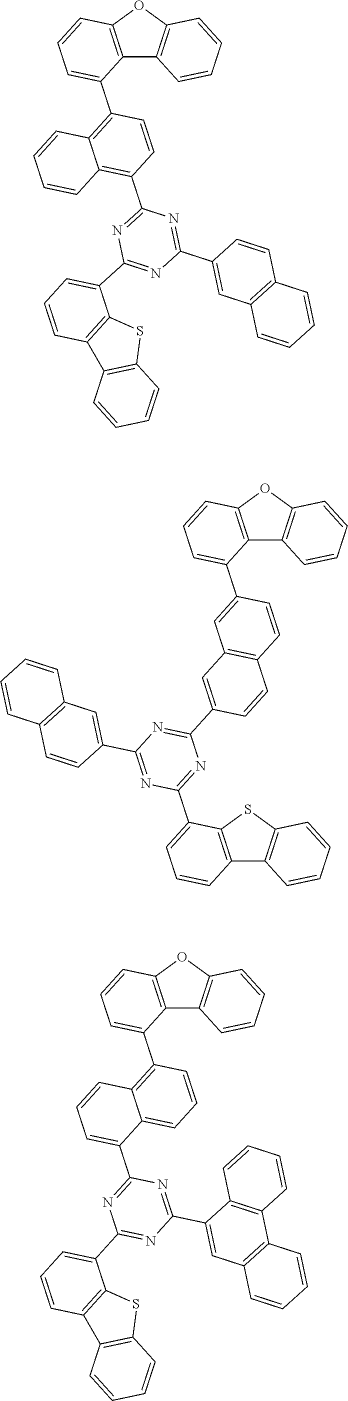 [SMILES: c1ccc2cc(-c3nc(-c4ccc(-c5cccc6oc7ccccc7c56)c5ccccc45)nc(-c4cccc5c4sc4ccccc45)n3)ccc2c1 ; c1ccc2cc(-c3nc(-c4ccc5ccc(-c6cccc7oc8ccccc8c67)cc5c4)nc(-c4cccc5c4sc4ccccc45)n3)ccc2c1 ; c1ccc2c(c1)cc(-c1nc(-c3cccc4c(-c5cccc6oc7ccccc7c56)cccc34)nc(-c3cccc4c3sc3ccccc34)n1)c1ccccc12]

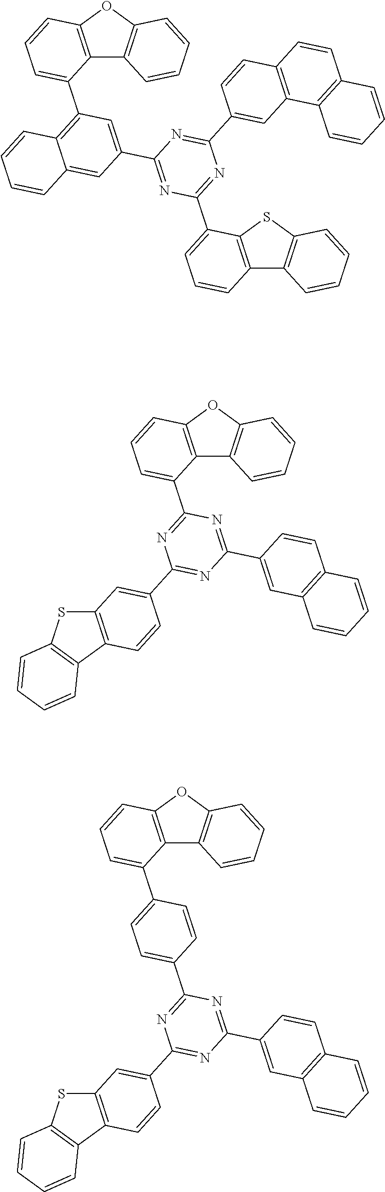 [SMILES: c1ccc2c(-c3cccc4oc5ccccc5c34)cc(-c3nc(-c4ccc5ccc6ccccc6c5c4)nc(-c4cccc5c4sc4ccccc45)n3)cc2c1 ; c1ccc2cc(-c3nc(-c4ccc5c(c4)sc4ccccc45)nc(-c4cccc5oc6ccccc6c45)n3)ccc2c1 ; c1ccc2cc(-c3nc(-c4ccc(-c5cccc6oc7ccccc7c56)cc4)nc(-c4ccc5c(c4)sc4ccccc45)n3)ccc2c1]

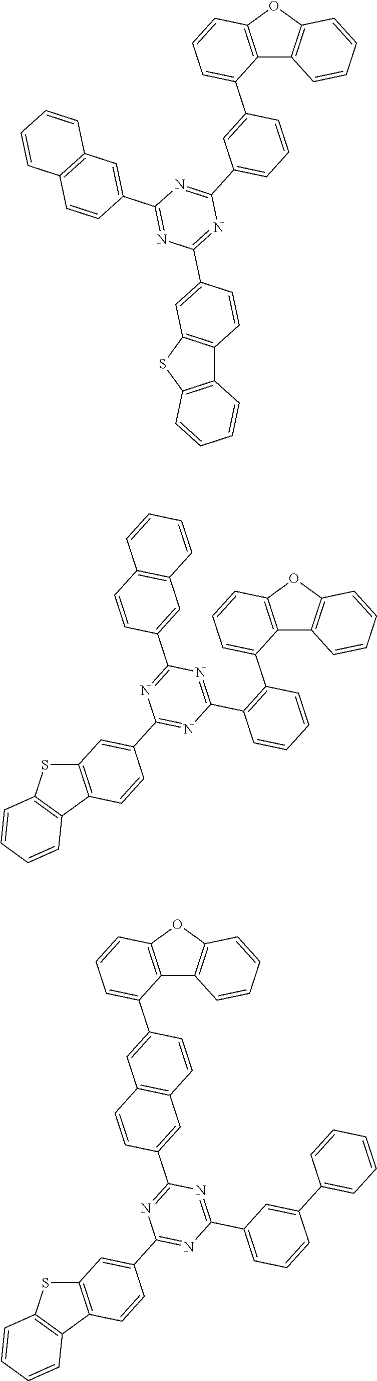 [SMILES: c1cc(-c2nc(-c3ccc4ccccc4c3)nc(-c3ccc4c(c3)sc3ccccc34)n2)cc(-c2cccc3oc4ccccc4c23)c1 ; c1ccc(-c2cccc3oc4ccccc4c23)c(-c2nc(-c3ccc4ccccc4c3)nc(-c3ccc4c(c3)sc3ccccc34)n2)c1 ; c1ccc(-c2cccc(-c3nc(-c4ccc5cc(-c6cccc7oc8ccccc8c67)ccc5c4)nc(-c4ccc5c(c4)sc4ccccc45)n3)c2)cc1]

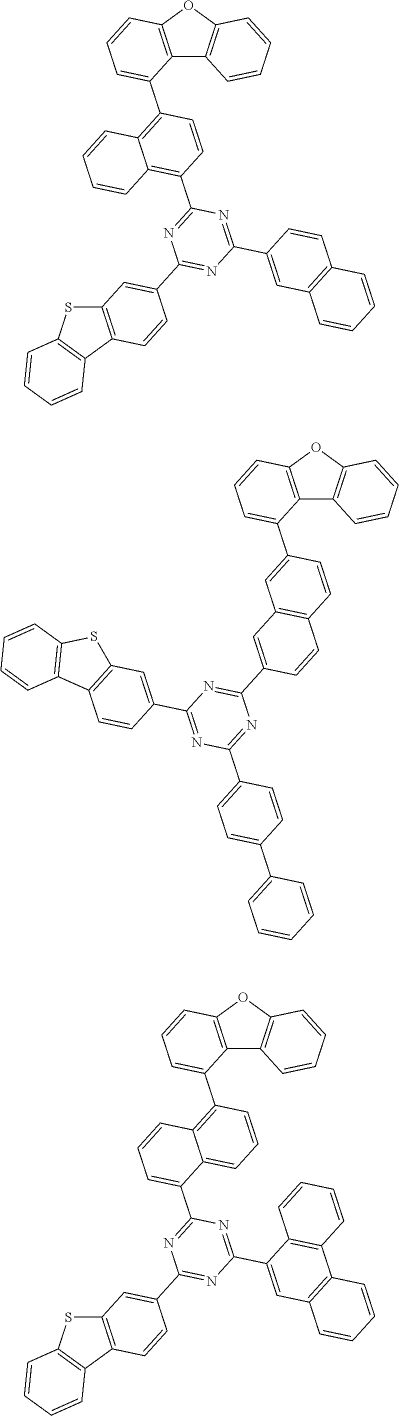 [SMILES: c1ccc2cc(-c3nc(-c4ccc5c(c4)sc4ccccc45)nc(-c4ccc(-c5cccc6oc7ccccc7c56)c5ccccc45)n3)ccc2c1 ; c1ccc(-c2ccc(-c3nc(-c4ccc5ccc(-c6cccc7oc8ccccc8c67)cc5c4)nc(-c4ccc5c(c4)sc4ccccc45)n3)cc2)cc1 ; c1ccc2c(c1)cc(-c1nc(-c3ccc4c(c3)sc3ccccc34)nc(-c3cccc4c(-c5cccc6oc7ccccc7c56)cccc34)n1)c1ccccc12]

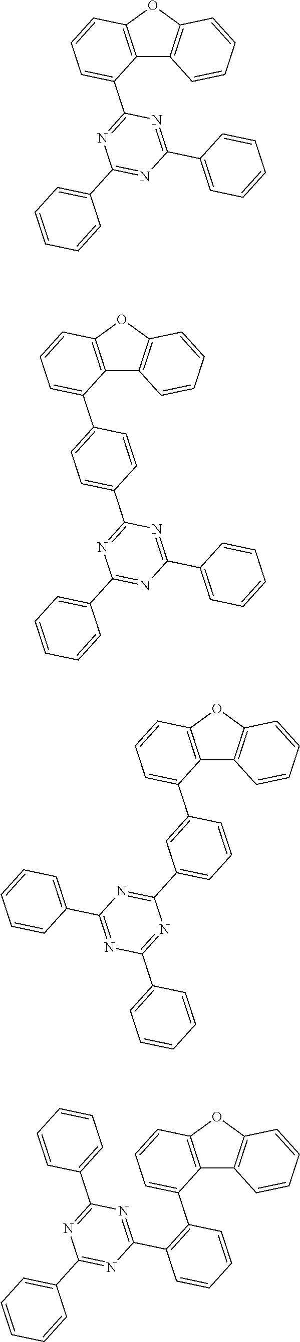 [SMILES: c1ccc(-c2nc(-c3ccccc3)nc(-c3cccc4oc5ccccc5c34)n2)cc1 ; c1ccc(-c2nc(-c3ccccc3)nc(-c3ccc(-c4cccc5oc6ccccc6c45)cc3)n2)cc1 ; c1ccc(-c2nc(-c3ccccc3)nc(-c3cccc(-c4cccc5oc6ccccc6c45)c3)n2)cc1 ; c1ccc(-c2nc(-c3ccccc3)nc(-c3ccccc3-c3cccc4oc5ccccc5c34)n2)cc1]

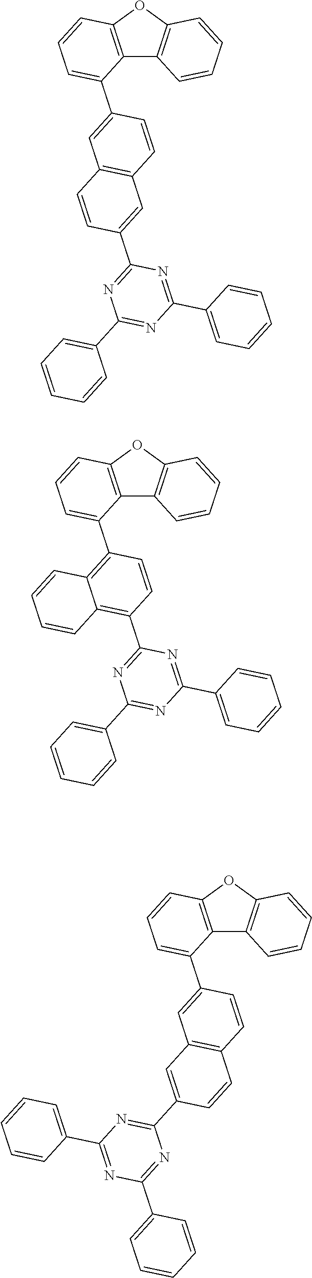 [SMILES: c1ccc(-c2nc(-c3ccccc3)nc(-c3ccc4cc(-c5cccc6oc7ccccc7c56)ccc4c3)n2)cc1 ; c1ccc(-c2nc(-c3ccccc3)nc(-c3ccc(-c4cccc5oc6ccccc6c45)c4ccccc34)n2)cc1 ; c1ccc(-c2nc(-c3ccccc3)nc(-c3ccc4ccc(-c5cccc6oc7ccccc7c56)cc4c3)n2)cc1]

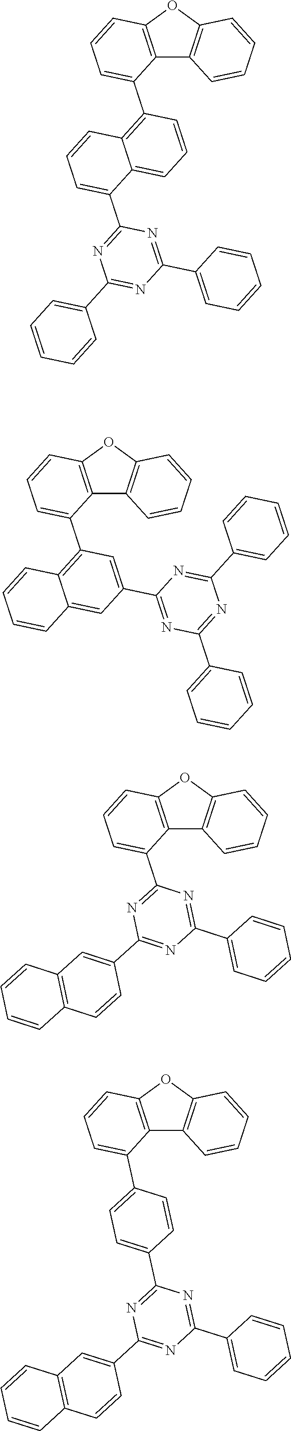 [SMILES: c1ccc(-c2nc(-c3ccccc3)nc(-c3cccc4c(-c5cccc6oc7ccccc7c56)cccc34)n2)cc1 ; c1ccc(-c2nc(-c3ccccc3)nc(-c3cc(-c4cccc5oc6ccccc6c45)c4ccccc4c3)n2)cc1 ; c1ccc(-c2nc(-c3ccc4ccccc4c3)nc(-c3cccc4oc5ccccc5c34)n2)cc1 ; c1ccc(-c2nc(-c3ccc(-c4cccc5oc6ccccc6c45)cc3)nc(-c3ccc4ccccc4c3)n2)cc1]

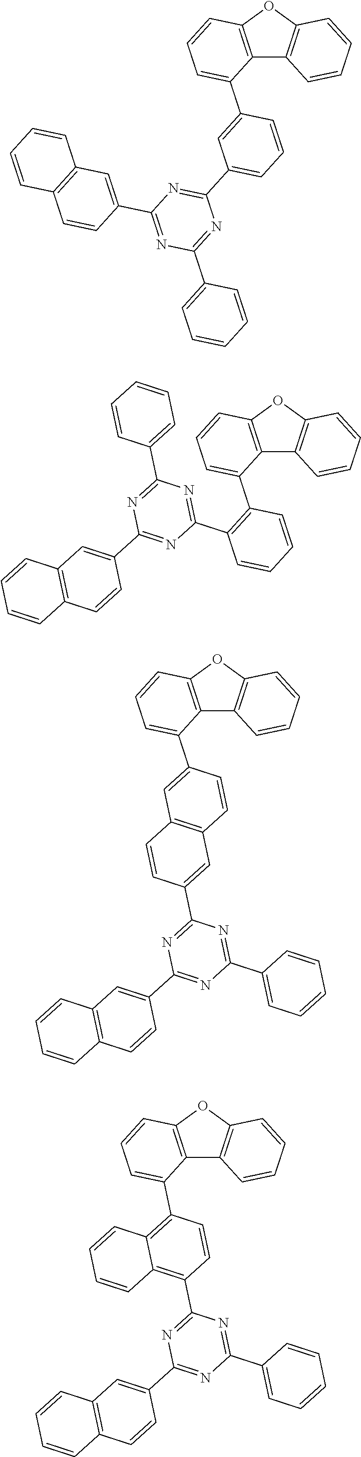 [SMILES: c1ccc(-c2nc(-c3cccc(-c4cccc5oc6ccccc6c45)c3)nc(-c3ccc4ccccc4c3)n2)cc1 ; c1ccc(-c2nc(-c3ccc4ccccc4c3)nc(-c3ccccc3-c3cccc4oc5ccccc5c34)n2)cc1 ; c1ccc(-c2nc(-c3ccc4ccccc4c3)nc(-c3ccc4cc(-c5cccc6oc7ccccc7c56)ccc4c3)n2)cc1 ; c1ccc(-c2nc(-c3ccc4ccccc4c3)nc(-c3ccc(-c4cccc5oc6ccccc6c45)c4ccccc34)n2)cc1]

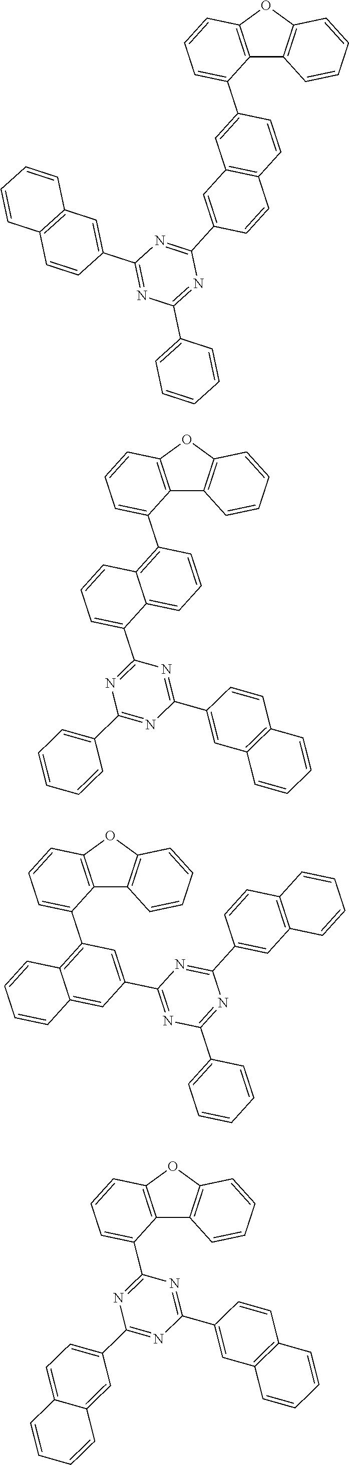

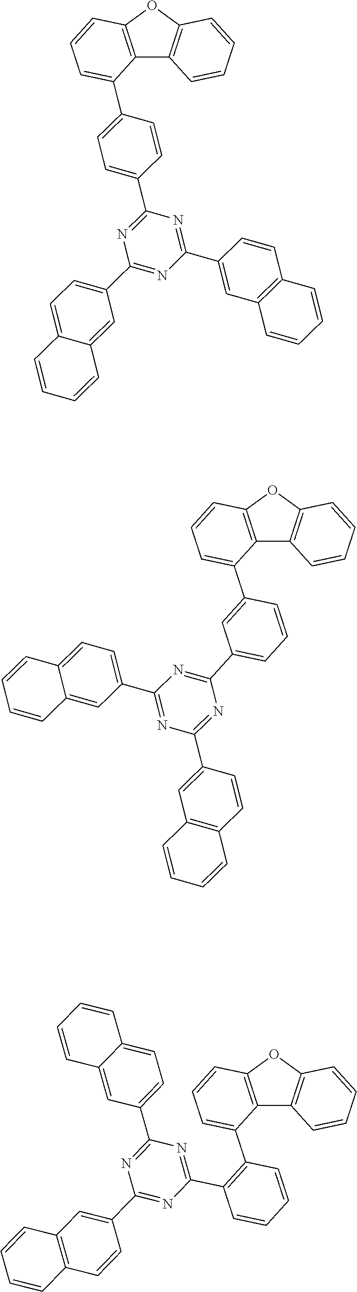 [SMILES: c1ccc2cc(-c3nc(-c4ccc(-c5cccc6oc7ccccc7c56)cc4)nc(-c4ccc5ccccc5c4)n3)ccc2c1 ; c1cc(-c2nc(-c3ccc4ccccc4c3)nc(-c3ccc4ccccc4c3)n2)cc(-c2cccc3oc4ccccc4c23)c1 ; c1ccc(-c2cccc3oc4ccccc4c23)c(-c2nc(-c3ccc4ccccc4c3)nc(-c3ccc4ccccc4c3)n2)c1]

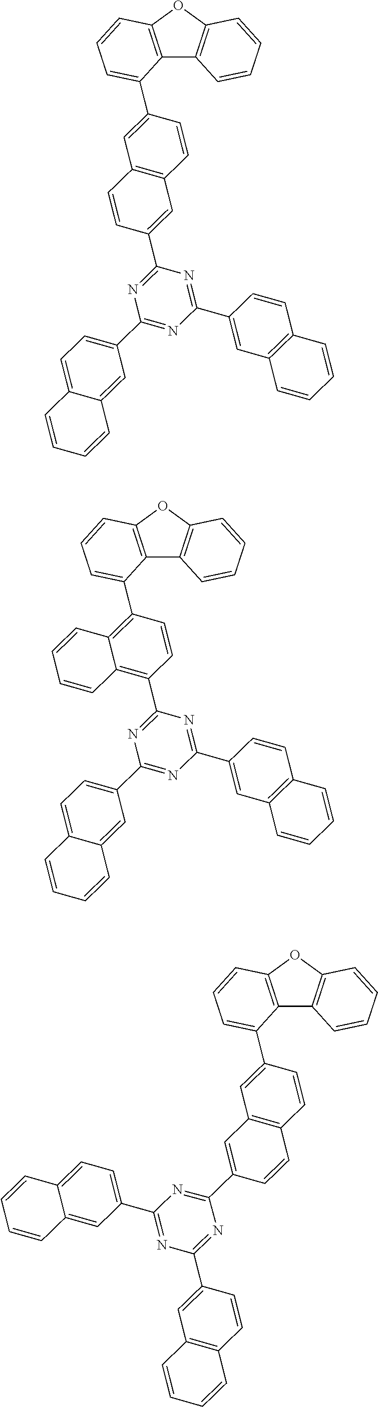 [SMILES: c1ccc2cc(-c3nc(-c4ccc5ccccc5c4)nc(-c4ccc5cc(-c6cccc7oc8ccccc8c67)ccc5c4)n3)ccc2c1 ; c1ccc2cc(-c3nc(-c4ccc5ccccc5c4)nc(-c4ccc(-c5cccc6oc7ccccc7c56)c5ccccc45)n3)ccc2c1 ; c1ccc2cc(-c3nc(-c4ccc5ccccc5c4)nc(-c4ccc5ccc(-c6cccc7oc8ccccc8c67)cc5c4)n3)ccc2c1]

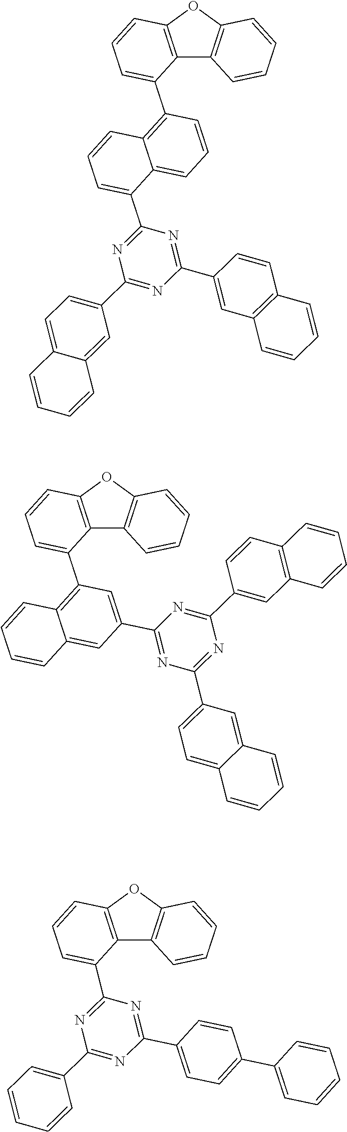 [SMILES: c1ccc2cc(-c3nc(-c4ccc5ccccc5c4)nc(-c4cccc5c(-c6cccc7oc8ccccc8c67)cccc45)n3)ccc2c1 ; c1ccc2cc(-c3nc(-c4ccc5ccccc5c4)nc(-c4cc(-c5cccc6oc7ccccc7c56)c5ccccc5c4)n3)ccc2c1 ; c1ccc(-c2ccc(-c3nc(-c4ccccc4)nc(-c4cccc5oc6ccccc6c45)n3)cc2)cc1]

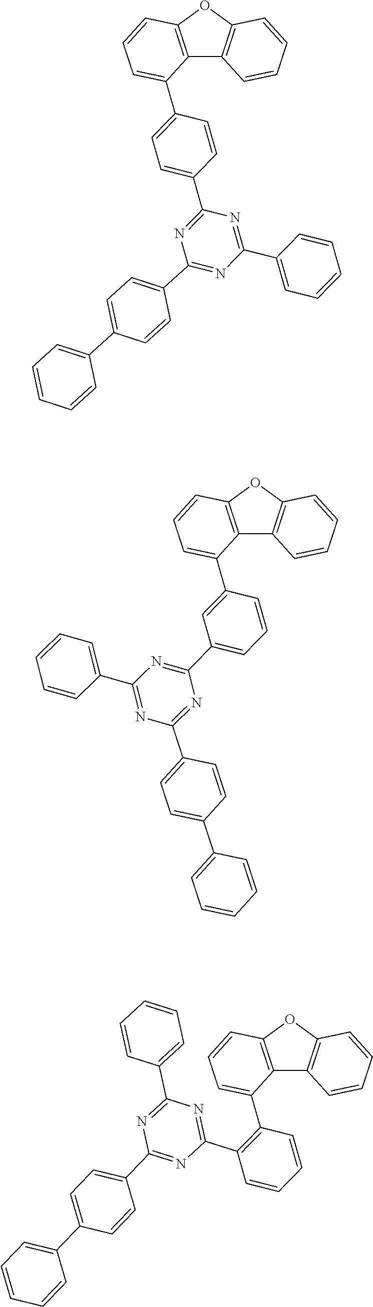 [SMILES: c1ccc(-c2ccc(-c3nc(-c4ccccc4)nc(-c4ccc(-c5cccc6oc7ccccc7c56)cc4)n3)cc2)cc1 ; c1ccc(-c2ccc(-c3nc(-c4ccccc4)nc(-c4cccc(-c5cccc6oc7ccccc7c56)c4)n3)cc2)cc1 ; c1ccc(-c2ccc(-c3nc(-c4ccccc4)nc(-c4ccccc4-c4cccc5oc6ccccc6c45)n3)cc2)cc1]

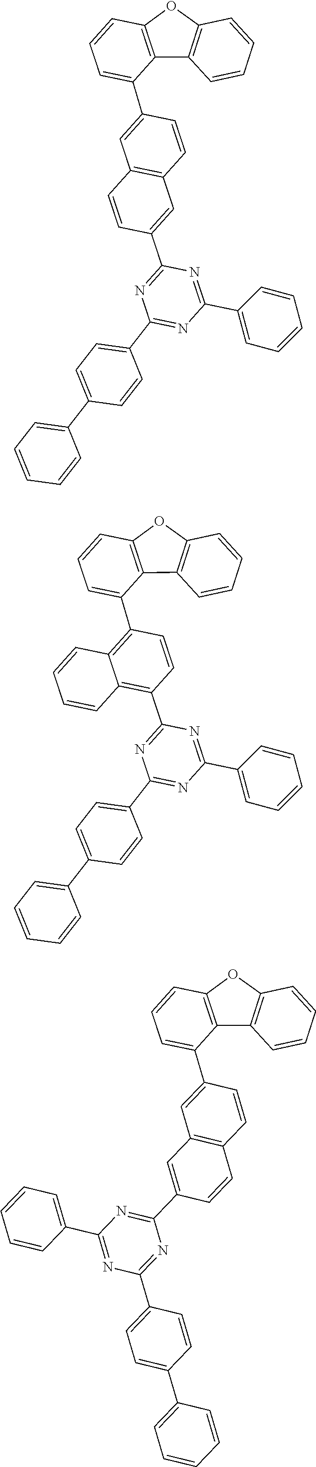 [SMILES: c1ccc(-c2ccc(-c3nc(-c4ccccc4)nc(-c4ccc5cc(-c6cccc7oc8ccccc8c67)ccc5c4)n3)cc2)cc1 ; c1ccc(-c2ccc(-c3nc(-c4ccccc4)nc(-c4ccc(-c5cccc6oc7ccccc7c56)c5ccccc45)n3)cc2)cc1 ; c1ccc(-c2ccc(-c3nc(-c4ccccc4)nc(-c4ccc5ccc(-c6cccc7oc8ccccc8c67)cc5c4)n3)cc2)cc1]

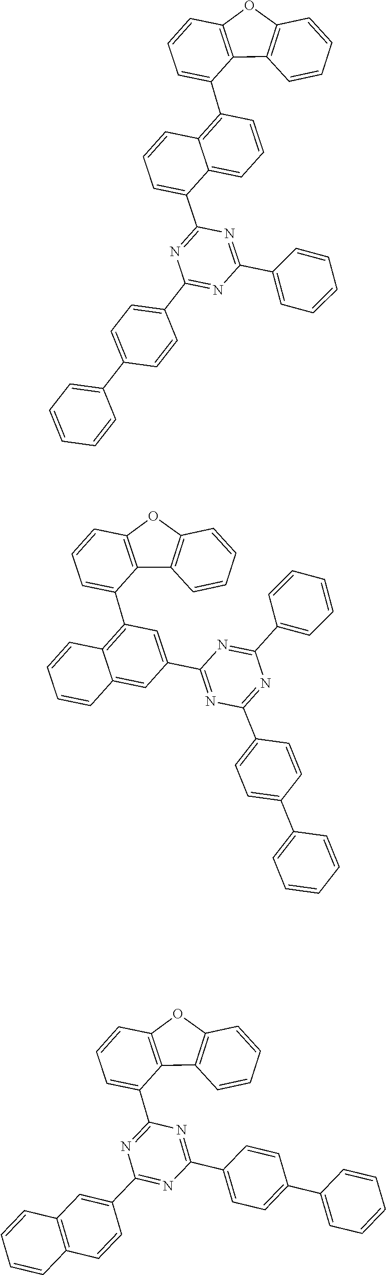 [SMILES: c1ccc(-c2ccc(-c3nc(-c4ccccc4)nc(-c4cccc5c(-c6cccc7oc8ccccc8c67)cccc45)n3)cc2)cc1 ; c1ccc(-c2ccc(-c3nc(-c4ccccc4)nc(-c4cc(-c5cccc6oc7ccccc7c56)c5ccccc5c4)n3)cc2)cc1 ; c1ccc(-c2ccc(-c3nc(-c4ccc5ccccc5c4)nc(-c4cccc5oc6ccccc6c45)n3)cc2)cc1]

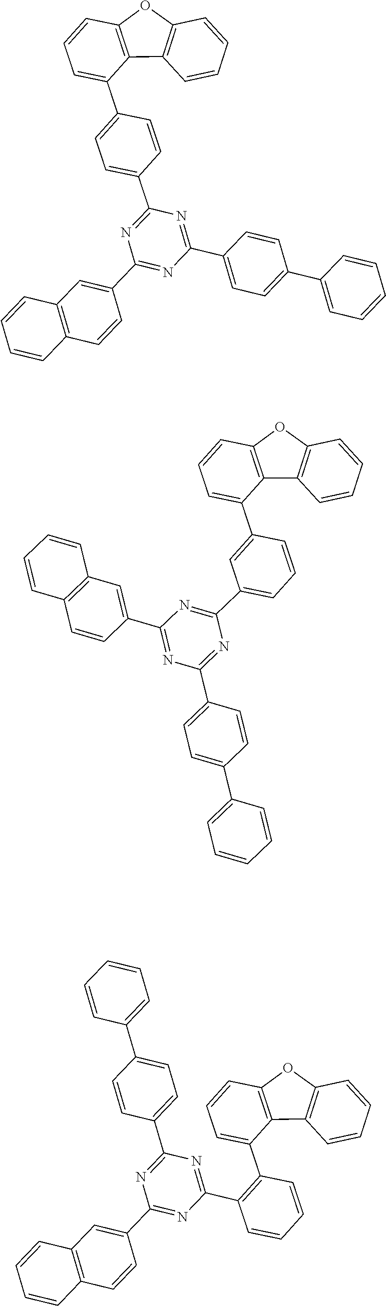 [SMILES: c1ccc(-c2ccc(-c3nc(-c4ccc(-c5cccc6oc7ccccc7c56)cc4)nc(-c4ccc5ccccc5c4)n3)cc2)cc1 ; c1ccc(-c2ccc(-c3nc(-c4cccc(-c5cccc6oc7ccccc7c56)c4)nc(-c4ccc5ccccc5c4)n3)cc2)cc1 ; c1ccc(-c2ccc(-c3nc(-c4ccc5ccccc5c4)nc(-c4ccccc4-c4cccc5oc6ccccc6c45)n3)cc2)cc1]

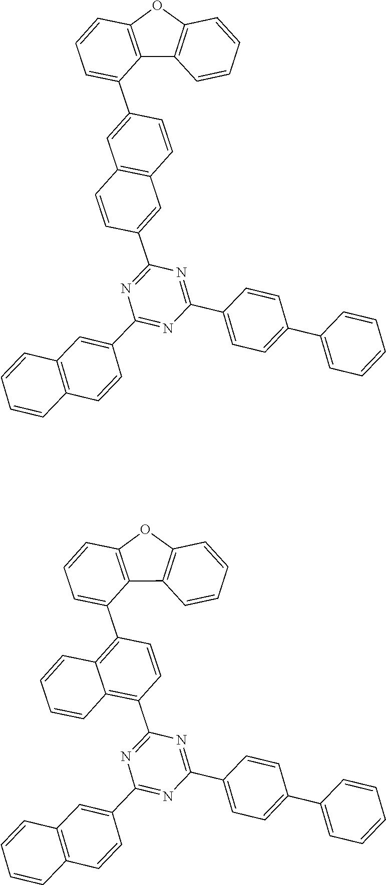 [SMILES: c1ccc(-c2ccc(-c3nc(-c4ccc5ccccc5c4)nc(-c4ccc5cc(-c6cccc7oc8ccccc8c67)ccc5c4)n3)cc2)cc1 ; c1ccc(-c2ccc(-c3nc(-c4ccc5ccccc5c4)nc(-c4ccc(-c5cccc6oc7ccccc7c56)c5ccccc45)n3)cc2)cc1]

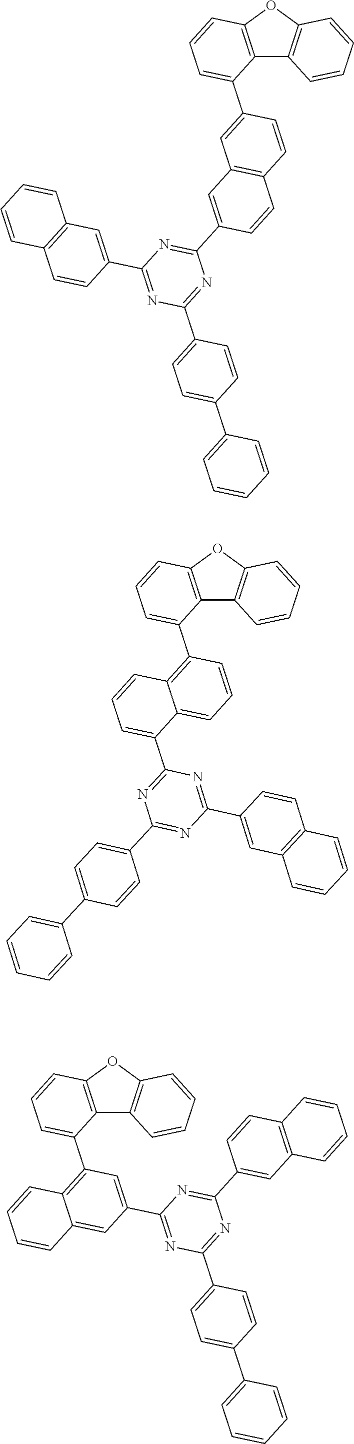 [SMILES: c1ccc(-c2ccc(-c3nc(-c4ccc5ccccc5c4)nc(-c4ccc5ccc(-c6cccc7oc8ccccc8c67)cc5c4)n3)cc2)cc1 ; c1ccc(-c2ccc(-c3nc(-c4ccc5ccccc5c4)nc(-c4cccc5c(-c6cccc7oc8ccccc8c67)cccc45)n3)cc2)cc1 ; c1ccc(-c2ccc(-c3nc(-c4ccc5ccccc5c4)nc(-c4cc(-c5cccc6oc7ccccc7c56)c5ccccc5c4)n3)cc2)cc1]

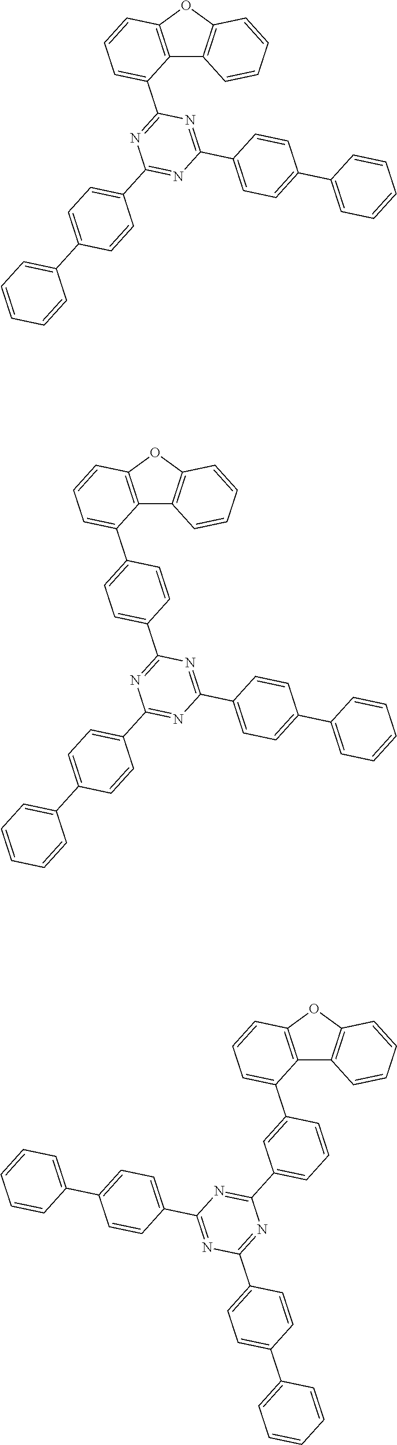 [SMILES: c1ccc(-c2ccc(-c3nc(-c4ccc(-c5ccccc5)cc4)nc(-c4cccc5oc6ccccc6c45)n3)cc2)cc1 ; c1ccc(-c2ccc(-c3nc(-c4ccc(-c5ccccc5)cc4)nc(-c4ccc(-c5cccc6oc7ccccc7c56)cc4)n3)cc2)cc1 ; c1ccc(-c2ccc(-c3nc(-c4ccc(-c5ccccc5)cc4)nc(-c4cccc(-c5cccc6oc7ccccc7c56)c4)n3)cc2)cc1]

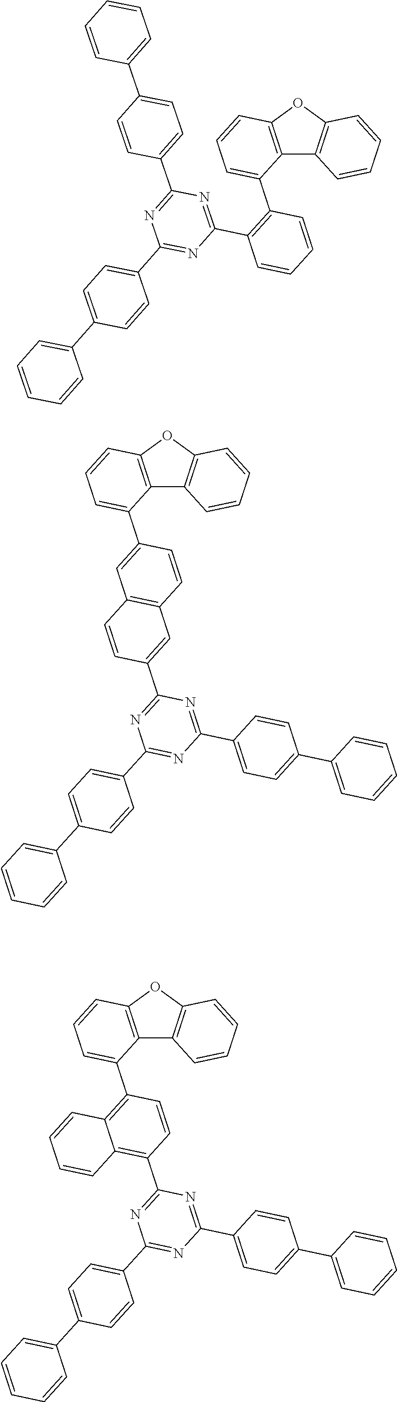 [SMILES: c1ccc(-c2ccc(-c3nc(-c4ccc(-c5ccccc5)cc4)nc(-c4ccccc4-c4cccc5oc6ccccc6c45)n3)cc2)cc1 ; c1ccc(-c2ccc(-c3nc(-c4ccc(-c5ccccc5)cc4)nc(-c4ccc5cc(-c6cccc7oc8ccccc8c67)ccc5c4)n3)cc2)cc1 ; c1ccc(-c2ccc(-c3nc(-c4ccc(-c5ccccc5)cc4)nc(-c4ccc(-c5cccc6oc7ccccc7c56)c5ccccc45)n3)cc2)cc1]

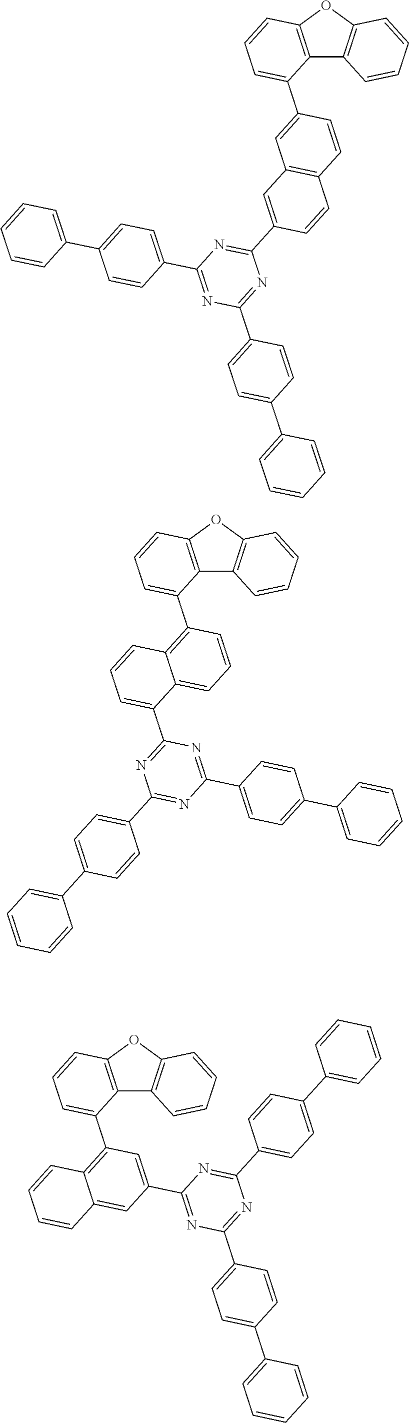

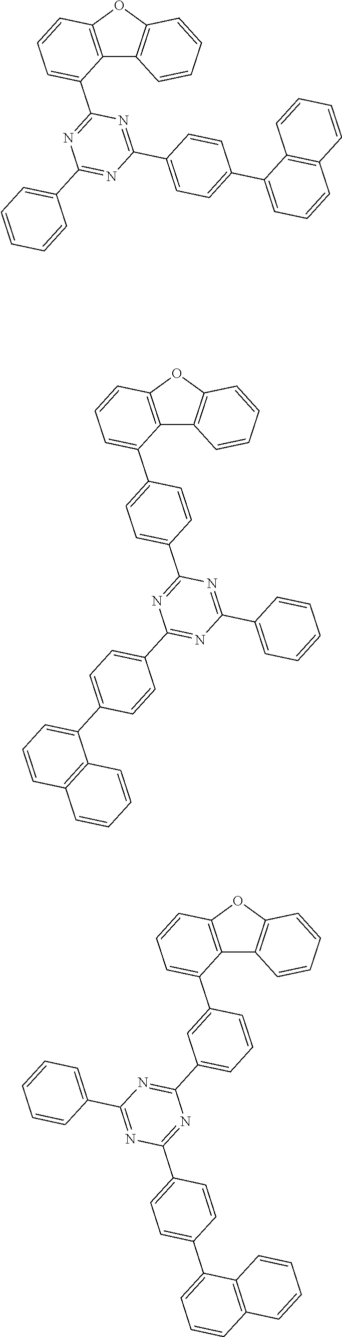 [SMILES: c1ccc(-c2nc(-c3ccc(-c4cccc5ccccc45)cc3)nc(-c3cccc4oc5ccccc5c34)n2)cc1 ; c1ccc(-c2nc(-c3ccc(-c4cccc5ccccc45)cc3)nc(-c3ccc(-c4cccc5oc6ccccc6c45)cc3)n2)cc1 ; c1ccc(-c2nc(-c3ccc(-c4cccc5ccccc45)cc3)nc(-c3cccc(-c4cccc5oc6ccccc6c45)c3)n2)cc1]

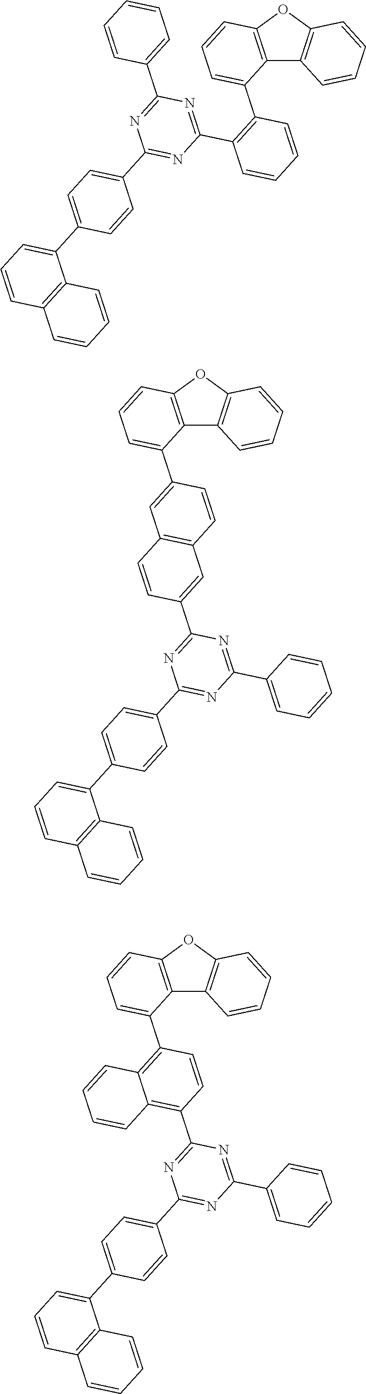 [SMILES: c1ccc(-c2nc(-c3ccc(-c4cccc5ccccc45)cc3)nc(-c3ccccc3-c3cccc4oc5ccccc5c34)n2)cc1 ; c1ccc(-c2nc(-c3ccc(-c4cccc5ccccc45)cc3)nc(-c3ccc4cc(-c5cccc6oc7ccccc7c56)ccc4c3)n2)cc1 ; c1ccc(-c2nc(-c3ccc(-c4cccc5ccccc45)cc3)nc(-c3ccc(-c4cccc5oc6ccccc6c45)c4ccccc34)n2)cc1]

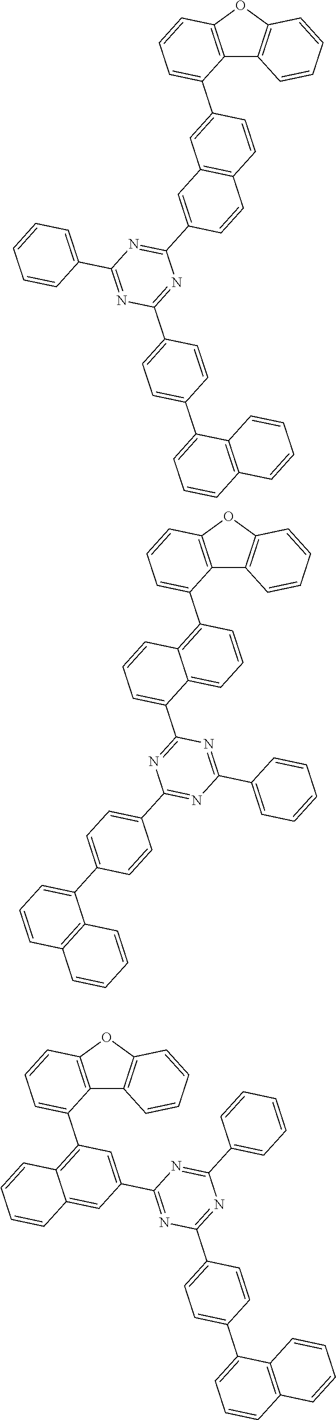

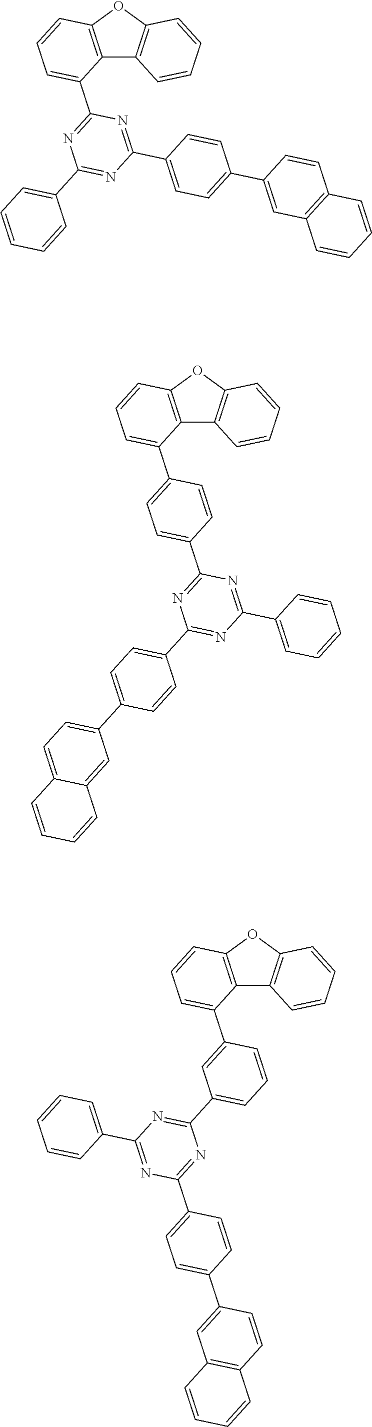 [SMILES: c1ccc(-c2nc(-c3ccc(-c4ccc5ccccc5c4)cc3)nc(-c3cccc4oc5ccccc5c34)n2)cc1 ; c1ccc(-c2nc(-c3ccc(-c4ccc5ccccc5c4)cc3)nc(-c3ccc(-c4cccc5oc6ccccc6c45)cc3)n2)cc1 ; c1ccc(-c2nc(-c3ccc(-c4ccc5ccccc5c4)cc3)nc(-c3cccc(-c4cccc5oc6ccccc6c45)c3)n2)cc1]

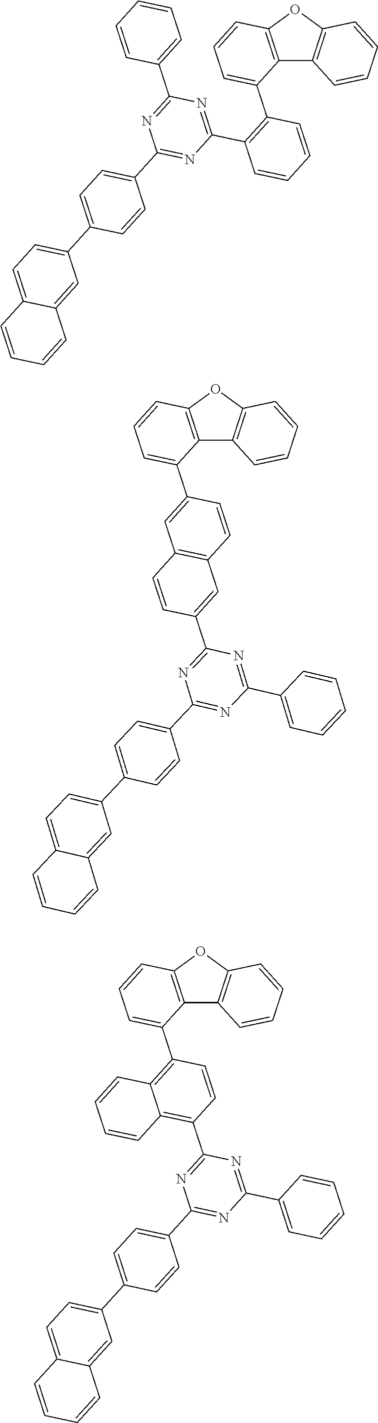 [SMILES: c1ccc(-c2nc(-c3ccc(-c4ccc5ccccc5c4)cc3)nc(-c3ccccc3-c3cccc4oc5ccccc5c34)n2)cc1 ; c1ccc(-c2nc(-c3ccc(-c4ccc5ccccc5c4)cc3)nc(-c3ccc4cc(-c5cccc6oc7ccccc7c56)ccc4c3)n2)cc1 ; c1ccc(-c2nc(-c3ccc(-c4ccc5ccccc5c4)cc3)nc(-c3ccc(-c4cccc5oc6ccccc6c45)c4ccccc34)n2)cc1]

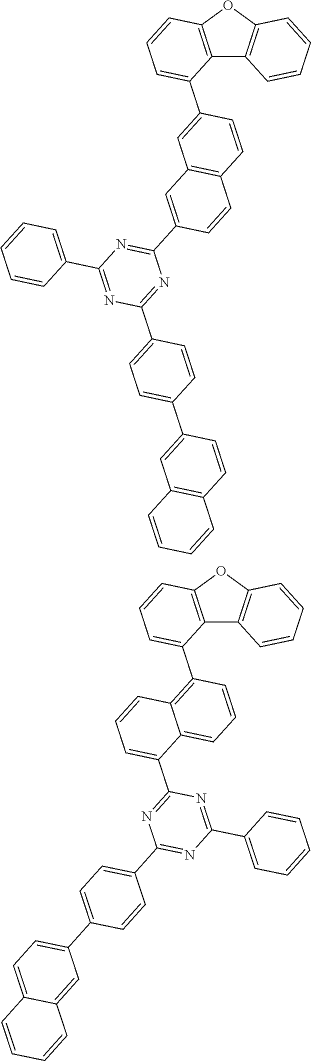

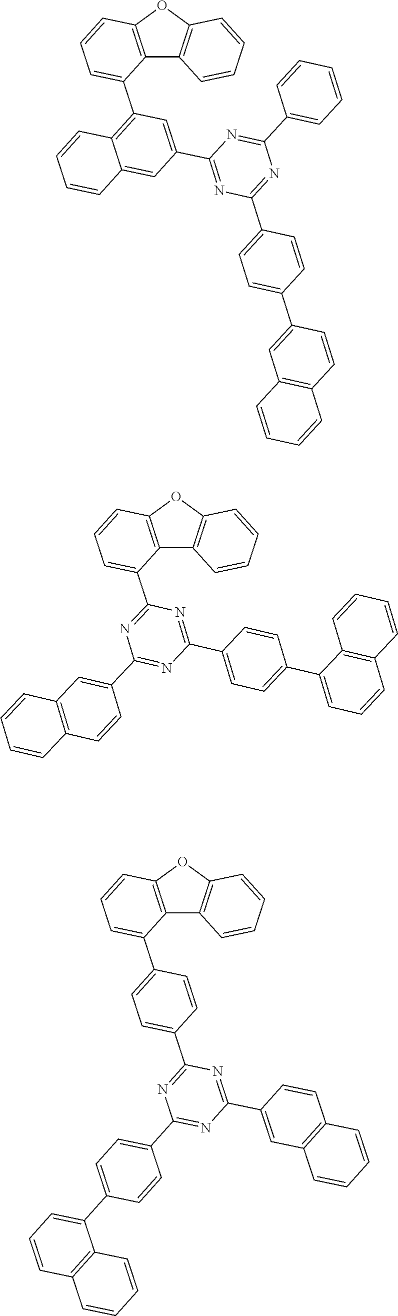 [SMILES: c1ccc(-c2nc(-c3ccc(-c4ccc5ccccc5c4)cc3)nc(-c3cc(-c4cccc5oc6ccccc6c45)c4ccccc4c3)n2)cc1 ; c1ccc2cc(-c3nc(-c4ccc(-c5cccc6ccccc56)cc4)nc(-c4cccc5oc6ccccc6c45)n3)ccc2c1 ; c1ccc2cc(-c3nc(-c4ccc(-c5cccc6ccccc56)cc4)nc(-c4ccc(-c5cccc6oc7ccccc7c56)cc4)n3)ccc2c1]

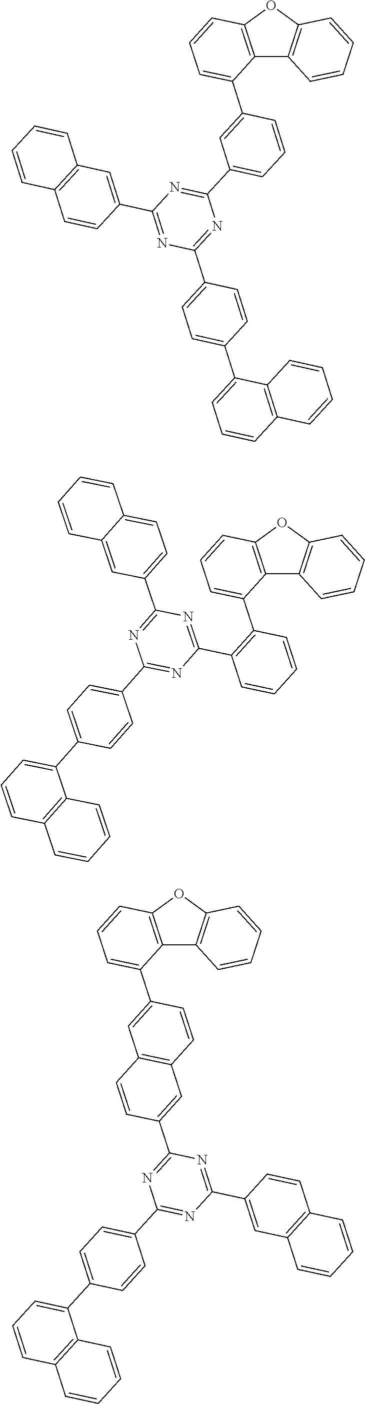 [SMILES: c1cc(-c2nc(-c3ccc(-c4cccc5ccccc45)cc3)nc(-c3ccc4ccccc4c3)n2)cc(-c2cccc3oc4ccccc4c23)c1 ; c1ccc(-c2cccc3oc4ccccc4c23)c(-c2nc(-c3ccc(-c4cccc5ccccc45)cc3)nc(-c3ccc4ccccc4c3)n2)c1 ; c1ccc2cc(-c3nc(-c4ccc(-c5cccc6ccccc56)cc4)nc(-c4ccc5cc(-c6cccc7oc8ccccc8c67)ccc5c4)n3)ccc2c1]

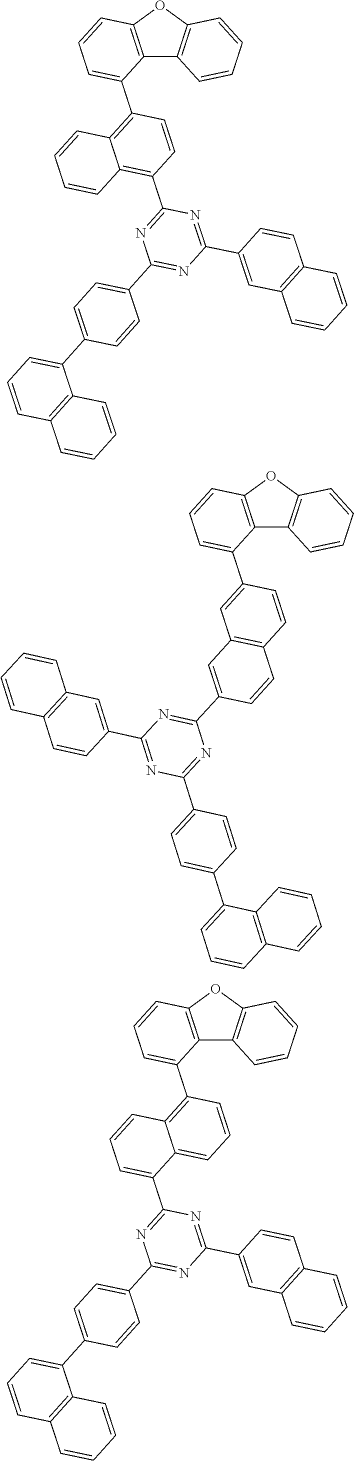

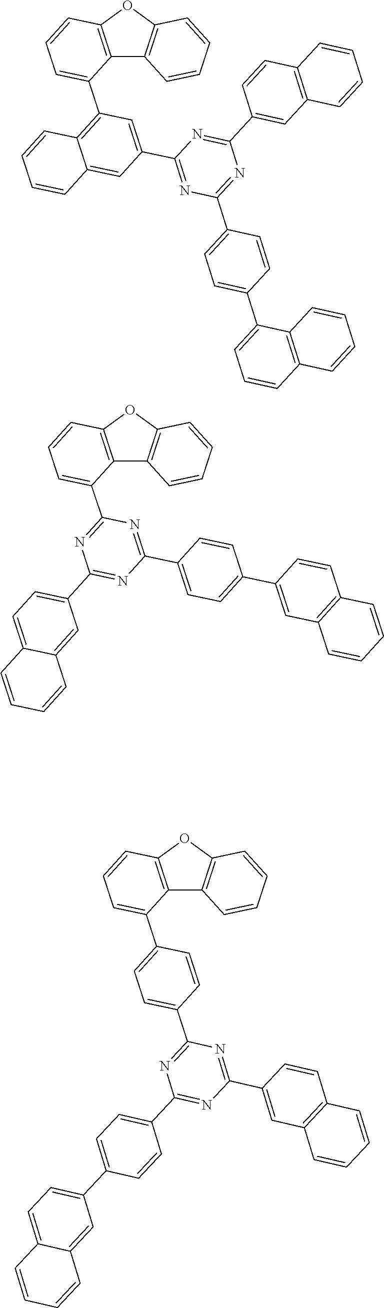 [SMILES: c1ccc2cc(-c3nc(-c4ccc(-c5cccc6ccccc56)cc4)nc(-c4cc(-c5cccc6oc7ccccc7c56)c5ccccc5c4)n3)ccc2c1 ; c1ccc2cc(-c3ccc(-c4nc(-c5ccc6ccccc6c5)nc(-c5cccc6oc7ccccc7c56)n4)cc3)ccc2c1 ; c1ccc2cc(-c3ccc(-c4nc(-c5ccc(-c6cccc7oc8ccccc8c67)cc5)nc(-c5ccc6ccccc6c5)n4)cc3)ccc2c1]

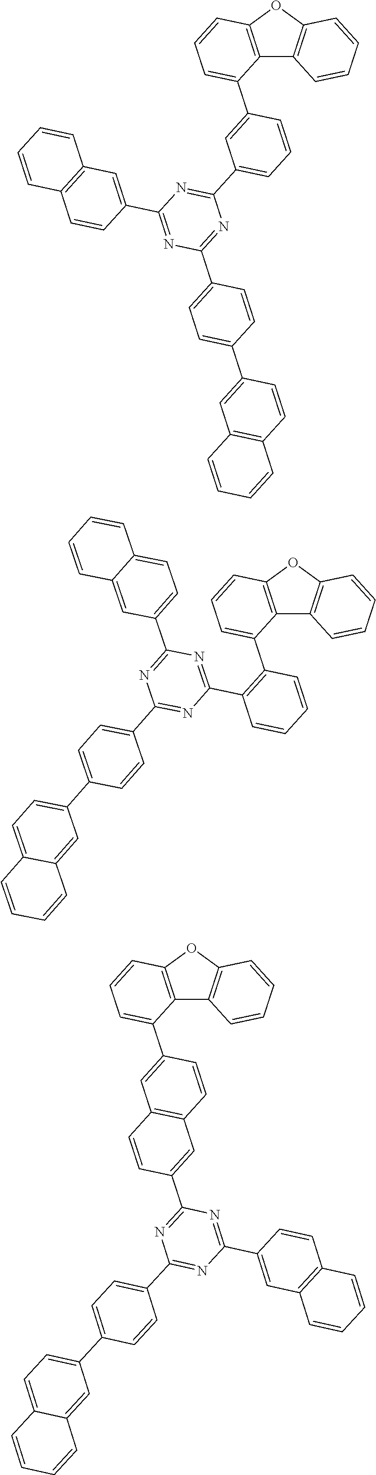 [SMILES: c1cc(-c2nc(-c3ccc(-c4ccc5ccccc5c4)cc3)nc(-c3ccc4ccccc4c3)n2)cc(-c2cccc3oc4ccccc4c23)c1 ; c1ccc(-c2cccc3oc4ccccc4c23)c(-c2nc(-c3ccc(-c4ccc5ccccc5c4)cc3)nc(-c3ccc4ccccc4c3)n2)c1 ; c1ccc2cc(-c3ccc(-c4nc(-c5ccc6ccccc6c5)nc(-c5ccc6cc(-c7cccc8oc9ccccc9c78)ccc6c5)n4)cc3)ccc2c1]

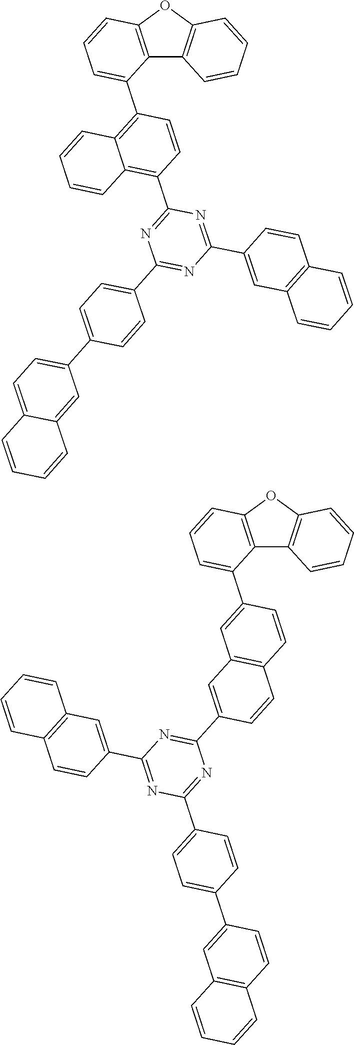 [SMILES: c1ccc2cc(-c3ccc(-c4nc(-c5ccc6ccccc6c5)nc(-c5ccc(-c6cccc7oc8ccccc8c67)c6ccccc56)n4)cc3)ccc2c1 ; c1ccc2cc(-c3ccc(-c4nc(-c5ccc6ccccc6c5)nc(-c5ccc6ccc(-c7cccc8oc9ccccc9c78)cc6c5)n4)cc3)ccc2c1]

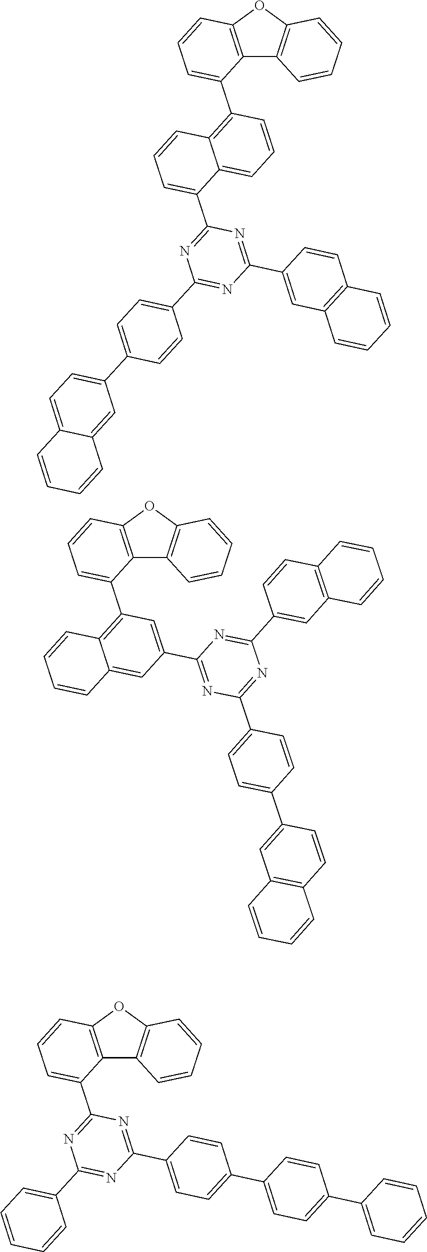

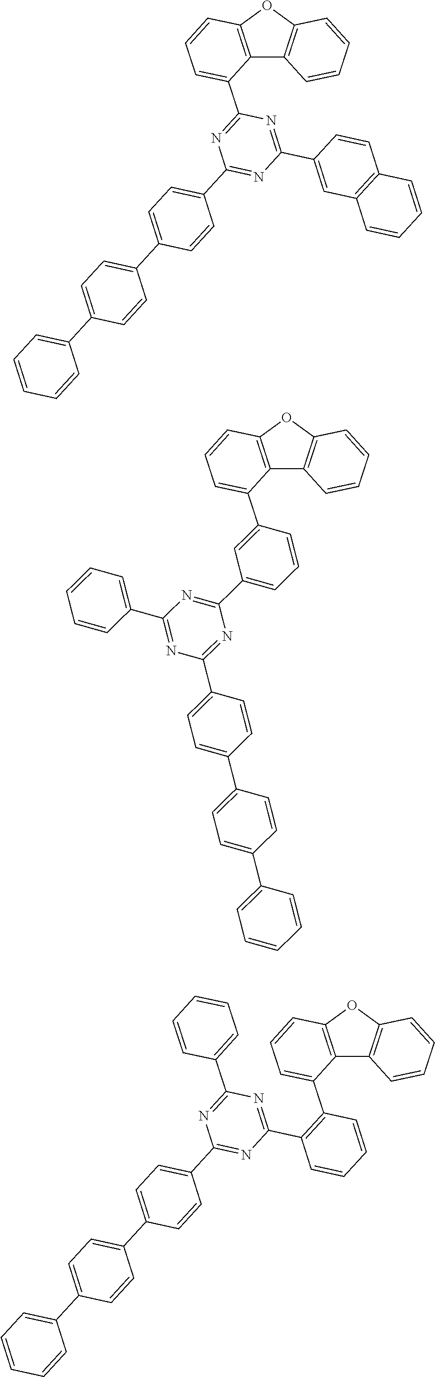 [SMILES: c1ccc(-c2ccc(-c3ccc(-c4nc(-c5ccc6ccccc6c5)nc(-c5cccc6oc7ccccc7c56)n4)cc3)cc2)cc1 ; c1ccc(-c2ccc(-c3ccc(-c4nc(-c5ccccc5)nc(-c5cccc(-c6cccc7oc8ccccc8c67)c5)n4)cc3)cc2)cc1 ; c1ccc(-c2ccc(-c3ccc(-c4nc(-c5ccccc5)nc(-c5ccccc5-c5cccc6oc7ccccc7c56)n4)cc3)cc2)cc1]

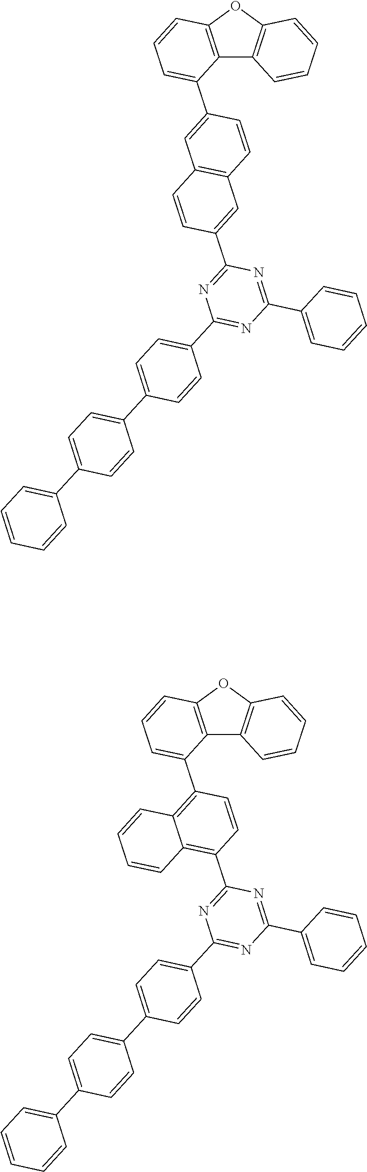 [SMILES: c1ccc(-c2ccc(-c3ccc(-c4nc(-c5ccccc5)nc(-c5ccc6cc(-c7cccc8oc9ccccc9c78)ccc6c5)n4)cc3)cc2)cc1 ; c1ccc(-c2ccc(-c3ccc(-c4nc(-c5ccccc5)nc(-c5ccc(-c6cccc7oc8ccccc8c67)c6ccccc56)n4)cc3)cc2)cc1]

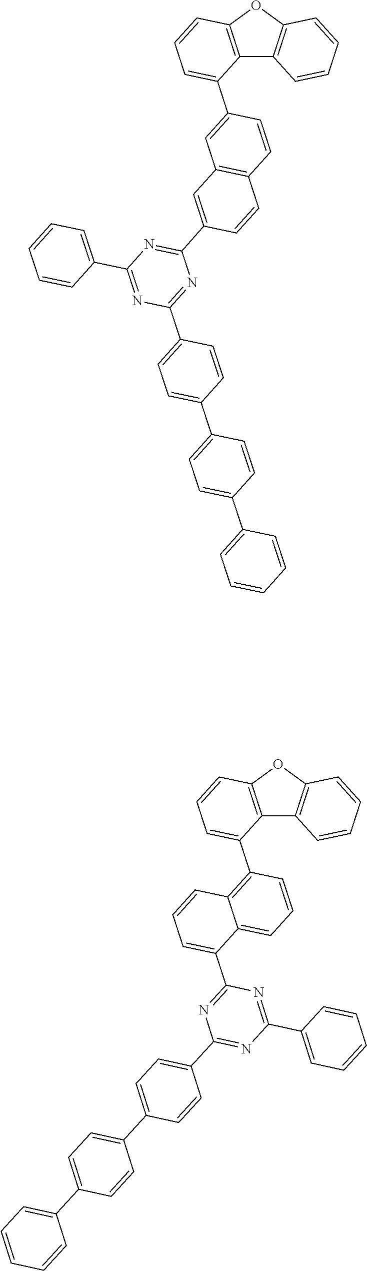 [SMILES: c1ccc(-c2ccc(-c3ccc(-c4nc(-c5ccccc5)nc(-c5ccc6ccc(-c7cccc8oc9ccccc9c78)cc6c5)n4)cc3)cc2)cc1 ; c1ccc(-c2ccc(-c3ccc(-c4nc(-c5ccccc5)nc(-c5cccc6c(-c7cccc8oc9ccccc9c78)cccc56)n4)cc3)cc2)cc1]

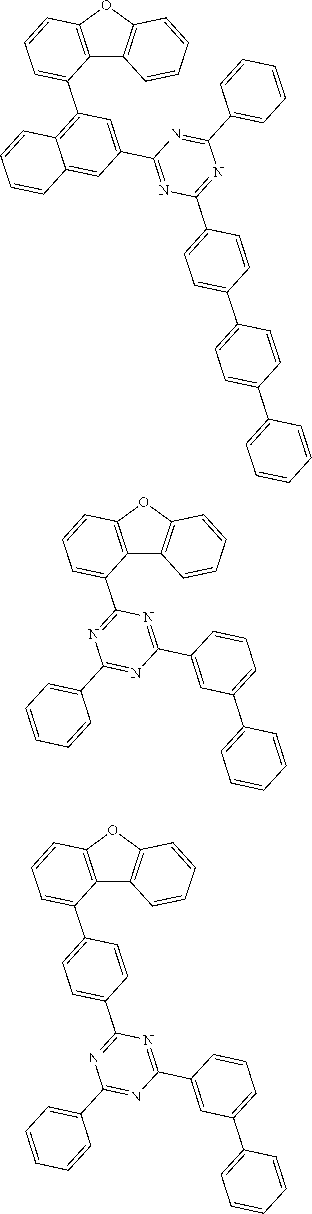 [SMILES: c1ccc(-c2ccc(-c3ccc(-c4nc(-c5ccccc5)nc(-c5cc(-c6cccc7oc8ccccc8c67)c6ccccc6c5)n4)cc3)cc2)cc1 ; c1ccc(-c2cccc(-c3nc(-c4ccccc4)nc(-c4cccc5oc6ccccc6c45)n3)c2)cc1 ; c1ccc(-c2cccc(-c3nc(-c4ccccc4)nc(-c4ccc(-c5cccc6oc7ccccc7c56)cc4)n3)c2)cc1]

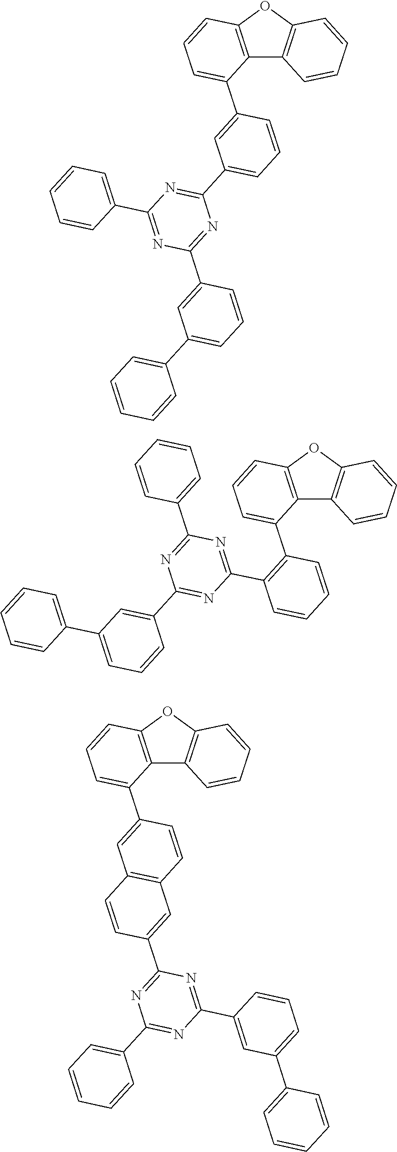

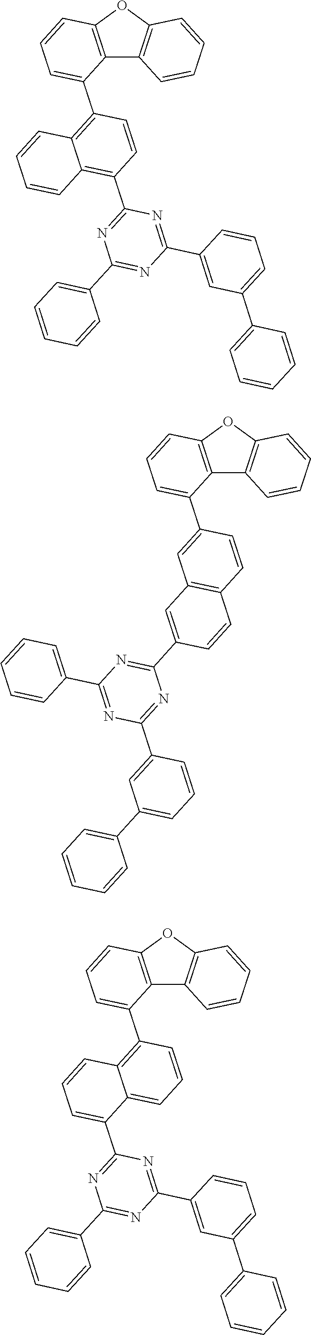

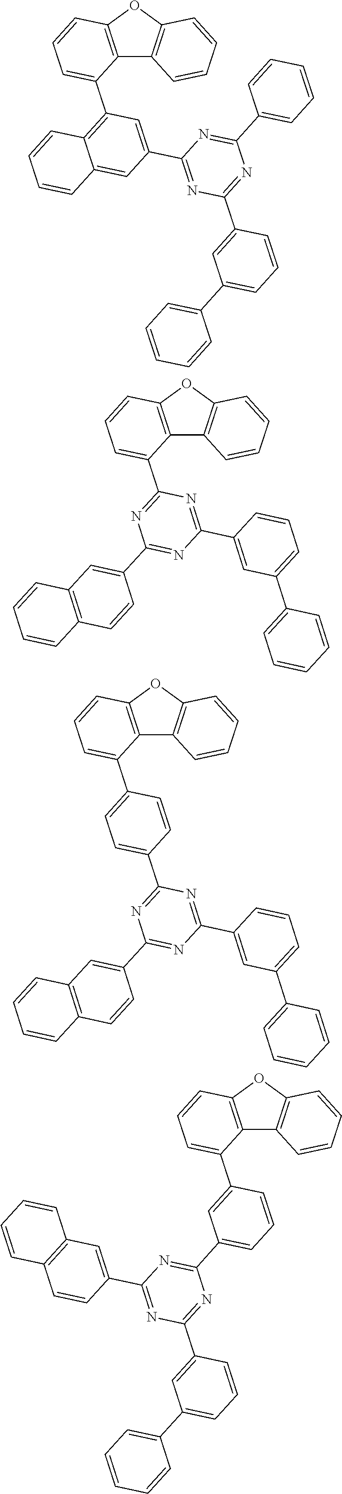

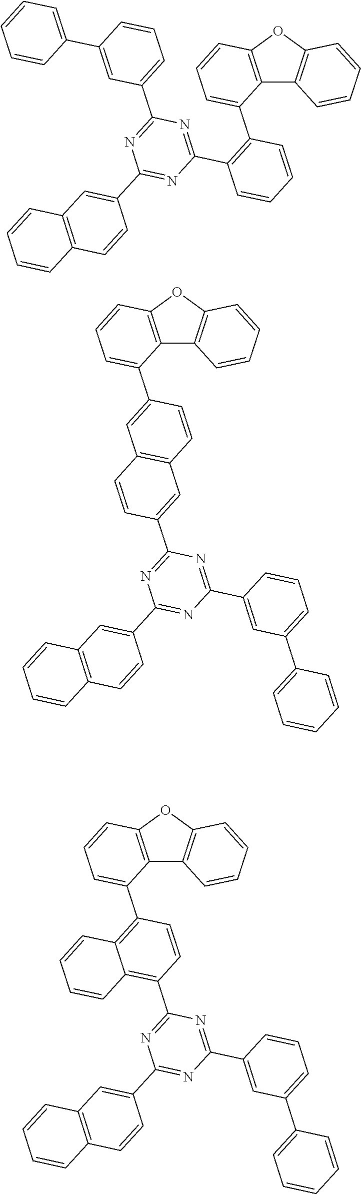 [SMILES: c1ccc(-c2cccc(-c3nc(-c4ccc5ccccc5c4)nc(-c4ccccc4-c4cccc5oc6ccccc6c45)n3)c2)cc1 ; c1ccc(-c2cccc(-c3nc(-c4ccc5ccccc5c4)nc(-c4ccc5cc(-c6cccc7oc8ccccc8c67)ccc5c4)n3)c2)cc1 ; c1ccc(-c2cccc(-c3nc(-c4ccc5ccccc5c4)nc(-c4ccc(-c5cccc6oc7ccccc7c56)c5ccccc45)n3)c2)cc1]

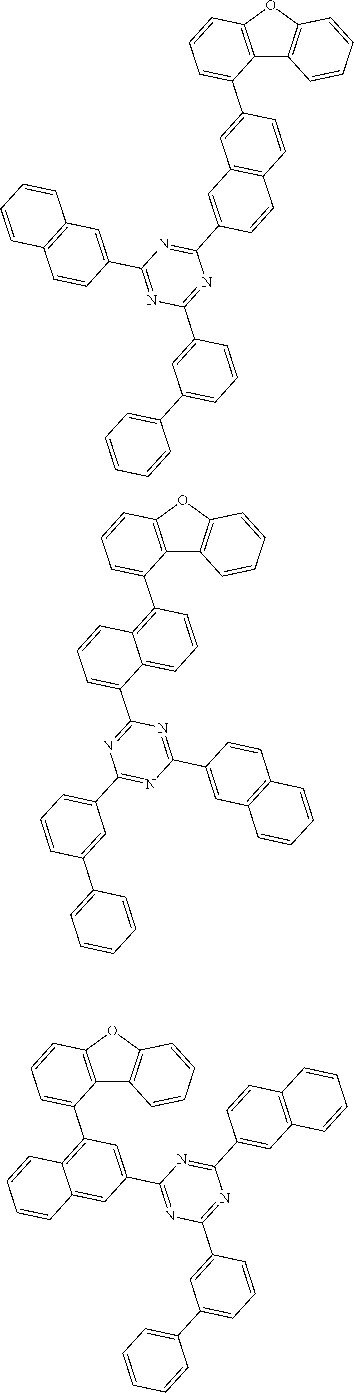

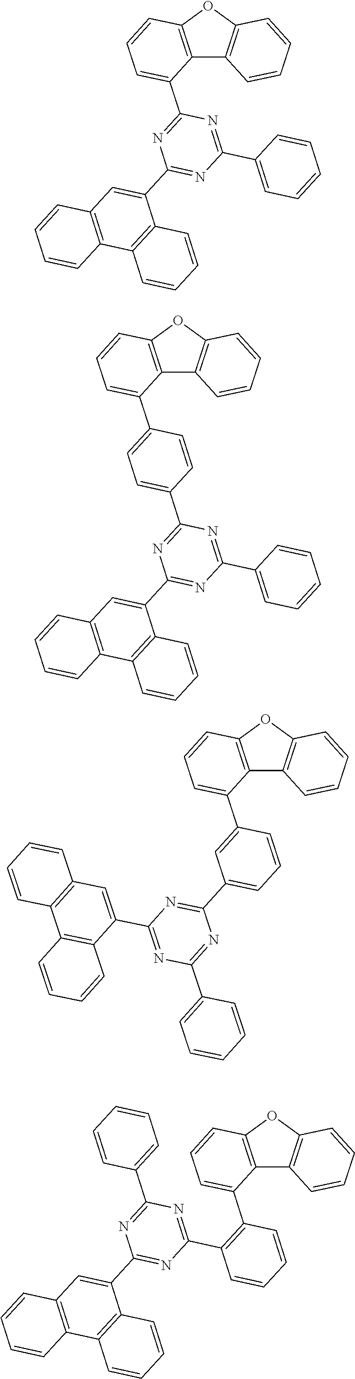

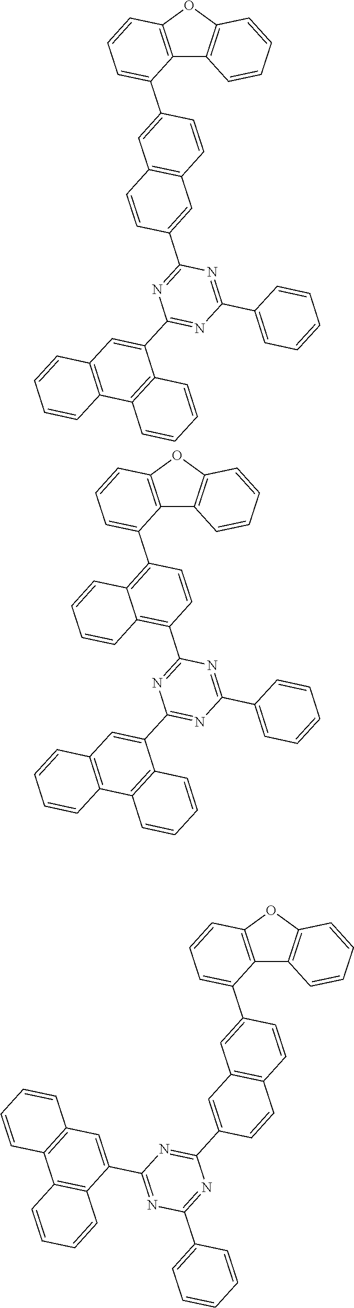

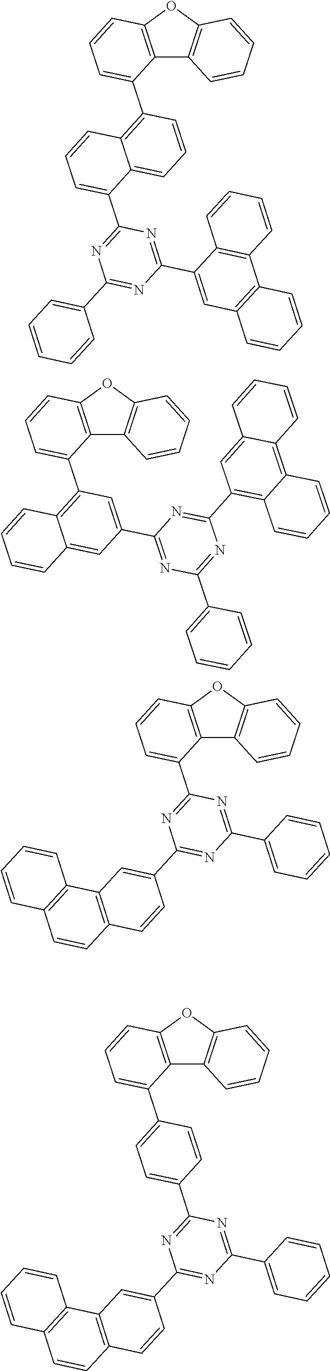

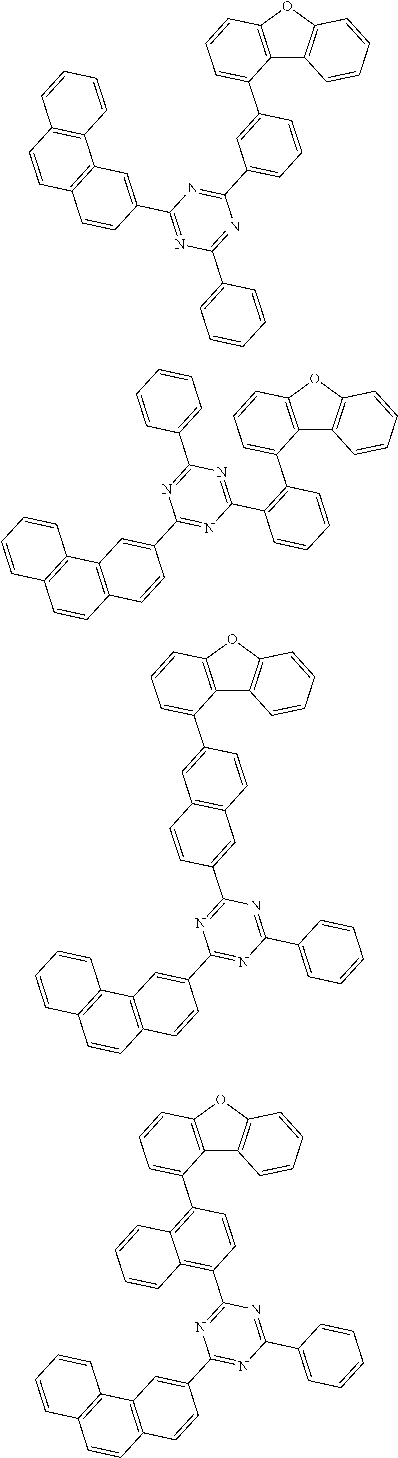

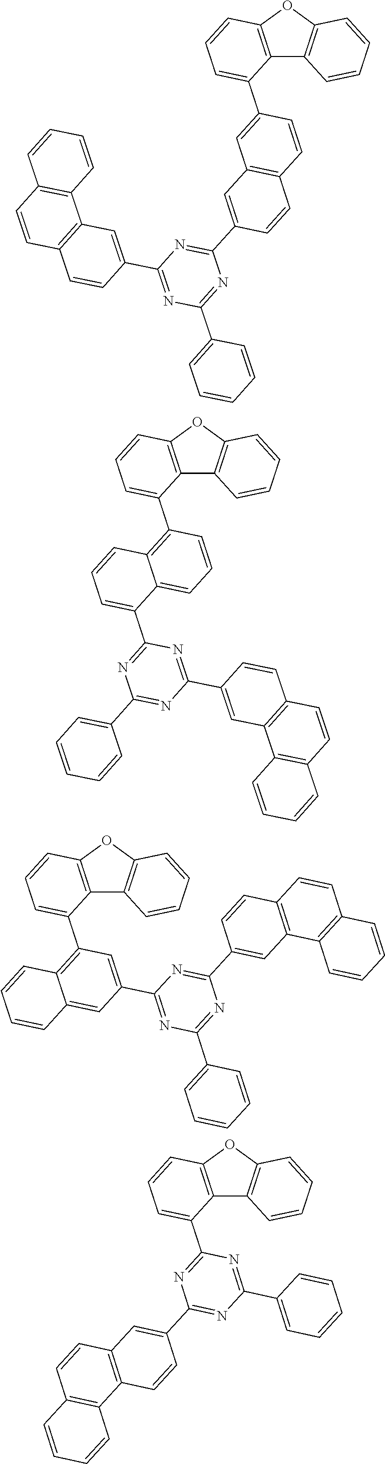

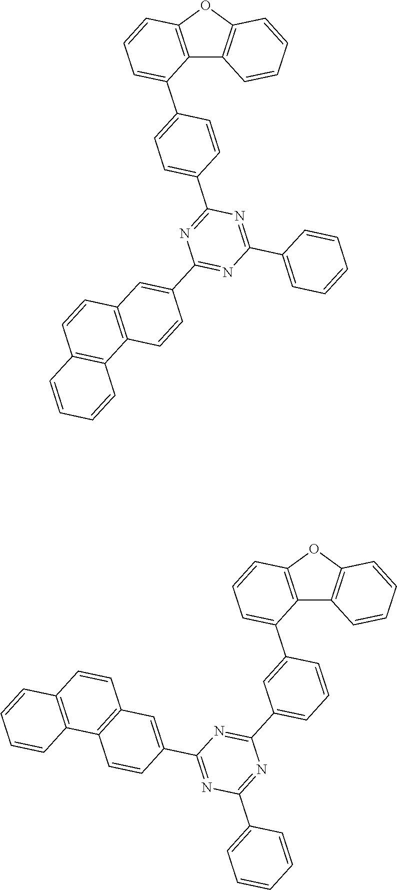 [SMILES: c1ccc(-c2nc(-c3ccc(-c4cccc5oc6ccccc6c45)cc3)nc(-c3ccc4c(ccc5ccccc54)c3)n2)cc1 ; c1ccc(-c2nc(-c3cccc(-c4cccc5oc6ccccc6c45)c3)nc(-c3ccc4c(ccc5ccccc54)c3)n2)cc1]

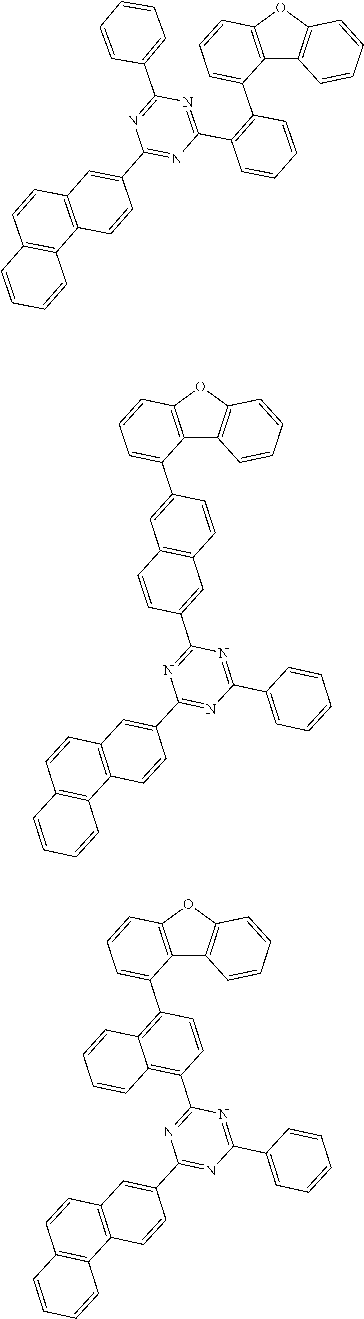 [SMILES: c1ccc(-c2nc(-c3ccc4c(ccc5ccccc54)c3)nc(-c3ccccc3-c3cccc4oc5ccccc5c34)n2)cc1 ; c1ccc(-c2nc(-c3ccc4cc(-c5cccc6oc7ccccc7c56)ccc4c3)nc(-c3ccc4c(ccc5ccccc54)c3)n2)cc1 ; c1ccc(-c2nc(-c3ccc4c(ccc5ccccc54)c3)nc(-c3ccc(-c4cccc5oc6ccccc6c45)c4ccccc34)n2)cc1]

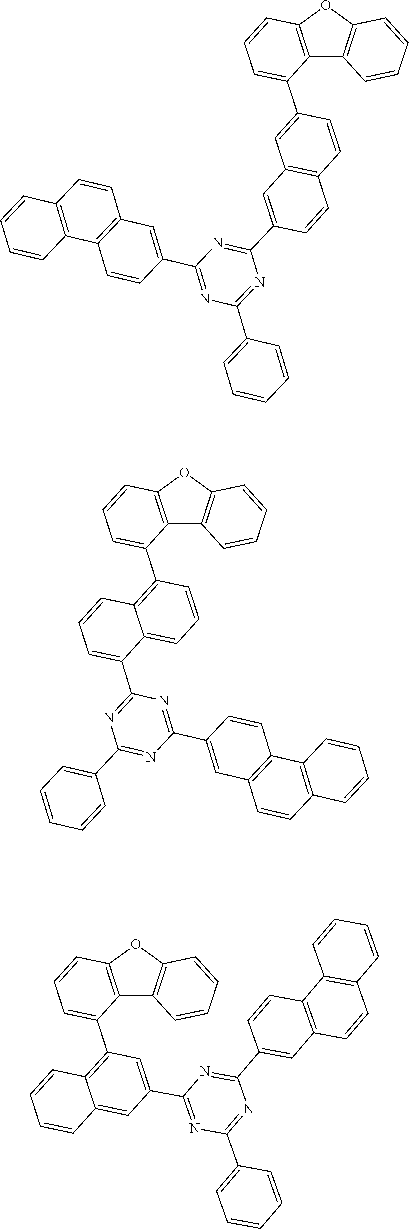 [SMILES: c1ccc(-c2nc(-c3ccc4ccc(-c5cccc6oc7ccccc7c56)cc4c3)nc(-c3ccc4c(ccc5ccccc54)c3)n2)cc1 ; c1ccc(-c2nc(-c3ccc4c(ccc5ccccc54)c3)nc(-c3cccc4c(-c5cccc6oc7ccccc7c56)cccc34)n2)cc1 ; c1ccc(-c2nc(-c3cc(-c4cccc5oc6ccccc6c45)c4ccccc4c3)nc(-c3ccc4c(ccc5ccccc54)c3)n2)cc1]

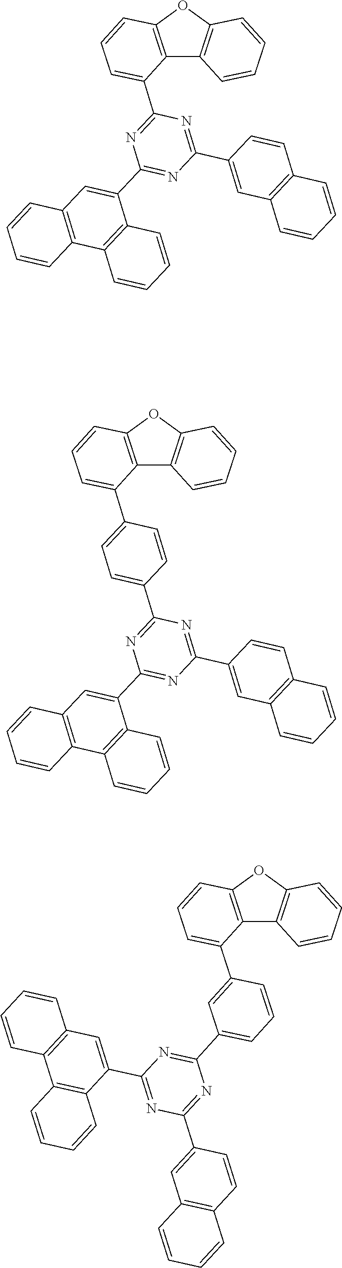 [SMILES: c1ccc2cc(-c3nc(-c4cc5ccccc5c5ccccc45)nc(-c4cccc5oc6ccccc6c45)n3)ccc2c1 ; c1ccc2cc(-c3nc(-c4ccc(-c5cccc6oc7ccccc7c56)cc4)nc(-c4cc5ccccc5c5ccccc45)n3)ccc2c1 ; c1cc(-c2nc(-c3ccc4ccccc4c3)nc(-c3cc4ccccc4c4ccccc34)n2)cc(-c2cccc3oc4ccccc4c23)c1]

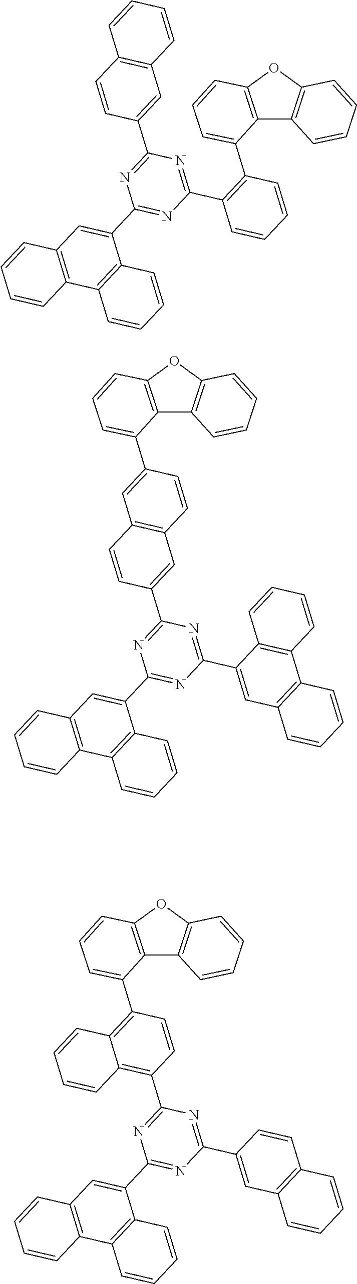

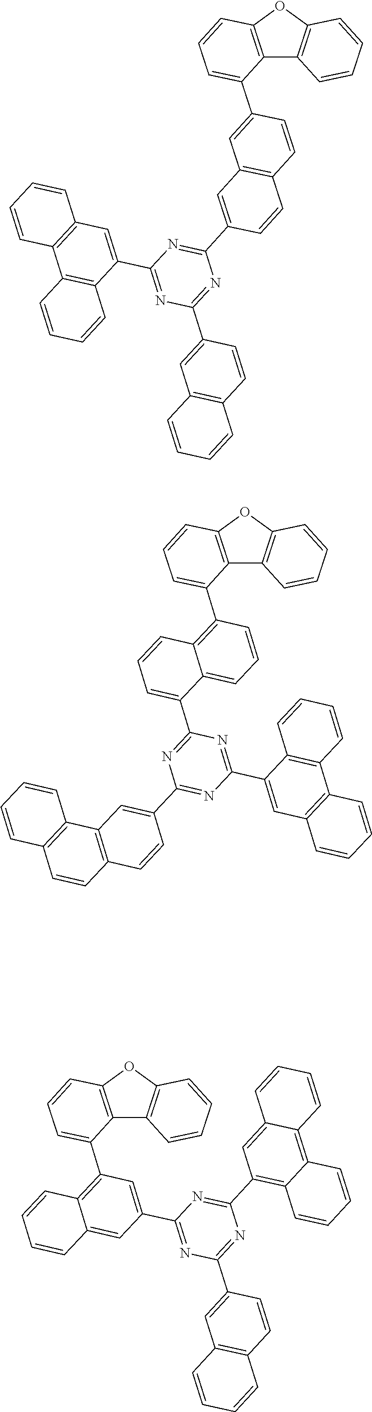 [SMILES: c1ccc2cc(-c3nc(-c4ccc5ccc(-c6cccc7oc8ccccc8c67)cc5c4)nc(-c4cc5ccccc5c5ccccc45)n3)ccc2c1 ; c1ccc2c(c1)ccc1ccc(-c3nc(-c4cccc5c(-c6cccc7oc8ccccc8c67)cccc45)nc(-c4cc5ccccc5c5ccccc45)n3)cc12 ; c1ccc2cc(-c3nc(-c4cc(-c5cccc6oc7ccccc7c56)c5ccccc5c4)nc(-c4cc5ccccc5c5ccccc45)n3)ccc2c1]

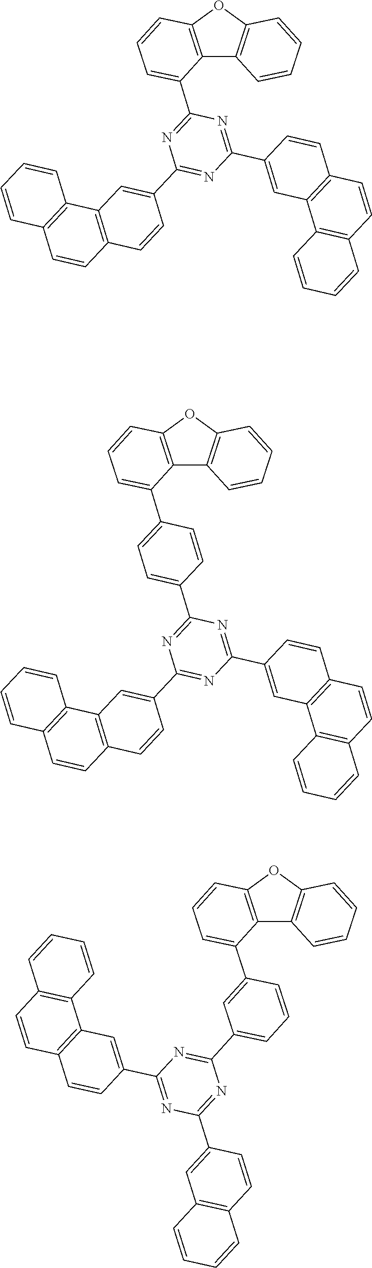 [SMILES: c1ccc2c(c1)ccc1ccc(-c3nc(-c4ccc5ccc6ccccc6c5c4)nc(-c4cccc5oc6ccccc6c45)n3)cc12 ; c1ccc2c(c1)ccc1ccc(-c3nc(-c4ccc(-c5cccc6oc7ccccc7c56)cc4)nc(-c4ccc5ccc6ccccc6c5c4)n3)cc12 ; c1cc(-c2nc(-c3ccc4ccccc4c3)nc(-c3ccc4ccc5ccccc5c4c3)n2)cc(-c2cccc3oc4ccccc4c23)c1]

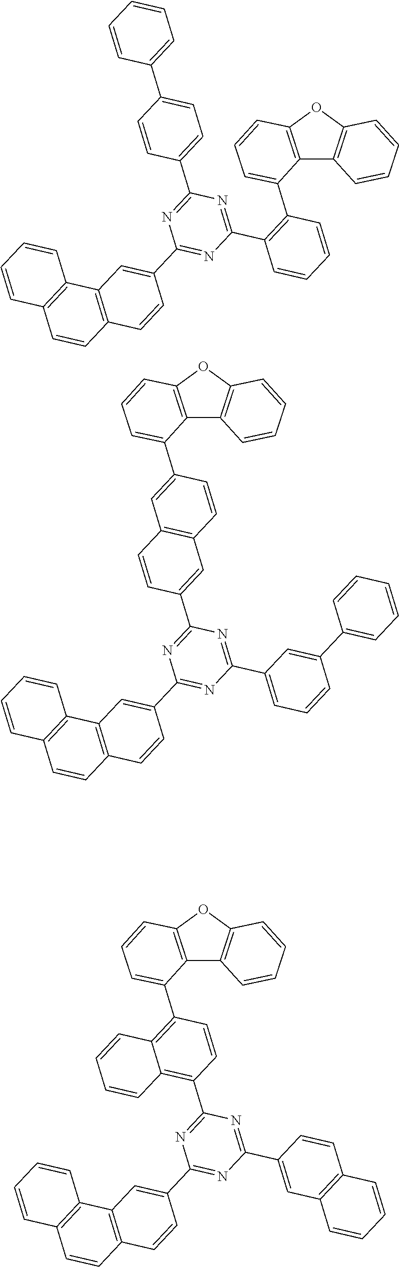 [SMILES: c1ccc(-c2ccc(-c3nc(-c4ccc5ccc6ccccc6c5c4)nc(-c4ccccc4-c4cccc5oc6ccccc6c45)n3)cc2)cc1 ; c1ccc(-c2cccc(-c3nc(-c4ccc5cc(-c6cccc7oc8ccccc8c67)ccc5c4)nc(-c4ccc5ccc6ccccc6c5c4)n3)c2)cc1 ; c1ccc2cc(-c3nc(-c4ccc5ccc6ccccc6c5c4)nc(-c4ccc(-c5cccc6oc7ccccc7c56)c5ccccc45)n3)ccc2c1]

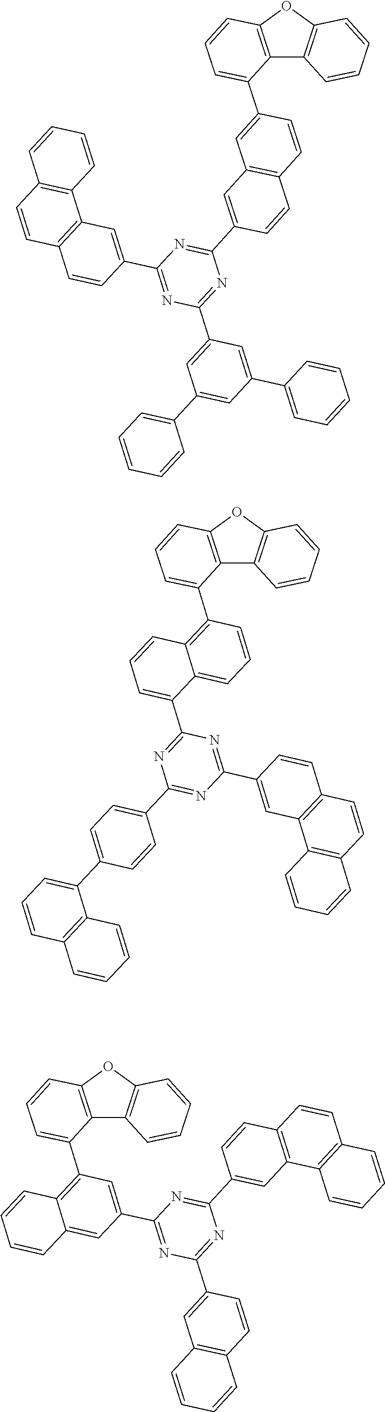 [SMILES: c1ccc(-c2cc(-c3ccccc3)cc(-c3nc(-c4ccc5ccc(-c6cccc7oc8ccccc8c67)cc5c4)nc(-c4ccc5ccc6ccccc6c5c4)n3)c2)cc1 ; c1ccc2c(-c3ccc(-c4nc(-c5ccc6ccc7ccccc7c6c5)nc(-c5cccc6c(-c7cccc8oc9ccccc9c78)cccc56)n4)cc3)cccc2c1 ; c1ccc2cc(-c3nc(-c4cc(-c5cccc6oc7ccccc7c56)c5ccccc5c4)nc(-c4ccc5ccc6ccccc6c5c4)n3)ccc2c1]

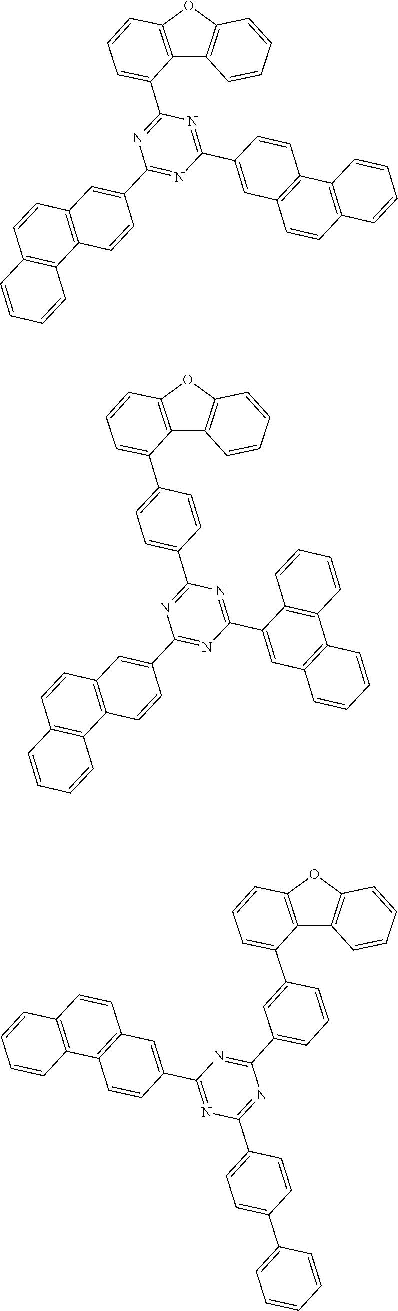 [SMILES: c1ccc2c(c1)ccc1cc(-c3nc(-c4ccc5c(ccc6ccccc65)c4)nc(-c4cccc5oc6ccccc6c45)n3)ccc12 ; c1ccc2c(c1)ccc1cc(-c3nc(-c4ccc(-c5cccc6oc7ccccc7c56)cc4)nc(-c4cc5ccccc5c5ccccc45)n3)ccc12 ; c1ccc(-c2ccc(-c3nc(-c4cccc(-c5cccc6oc7ccccc7c56)c4)nc(-c4ccc5c(ccc6ccccc65)c4)n3)cc2)cc1]

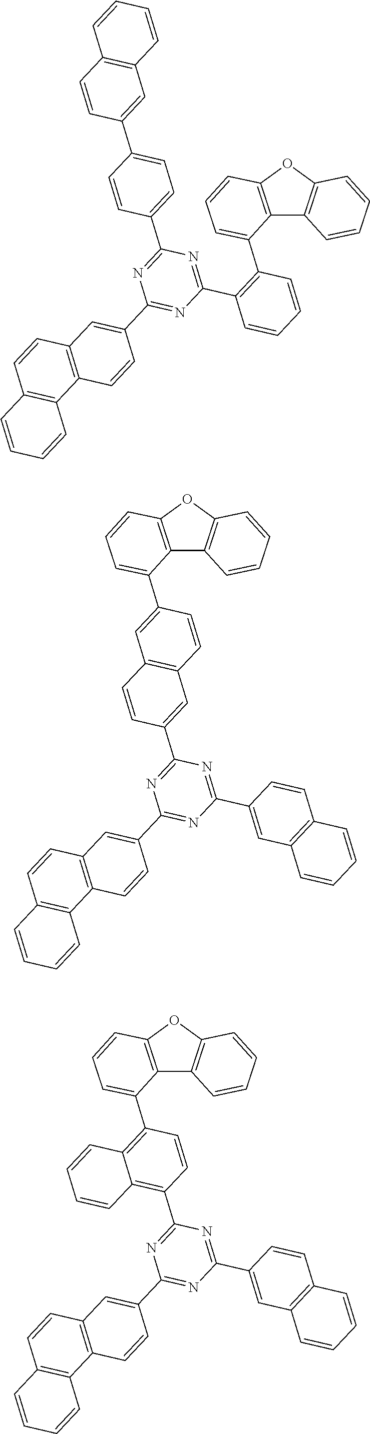 [SMILES: c1ccc(-c2cccc3oc4ccccc4c23)c(-c2nc(-c3ccc(-c4ccc5ccccc5c4)cc3)nc(-c3ccc4c(ccc5ccccc54)c3)n2)c1 ; c1ccc2cc(-c3nc(-c4ccc5cc(-c6cccc7oc8ccccc8c67)ccc5c4)nc(-c4ccc5c(ccc6ccccc65)c4)n3)ccc2c1 ; c1ccc2cc(-c3nc(-c4ccc5c(ccc6ccccc65)c4)nc(-c4ccc(-c5cccc6oc7ccccc7c56)c5ccccc45)n3)ccc2c1]

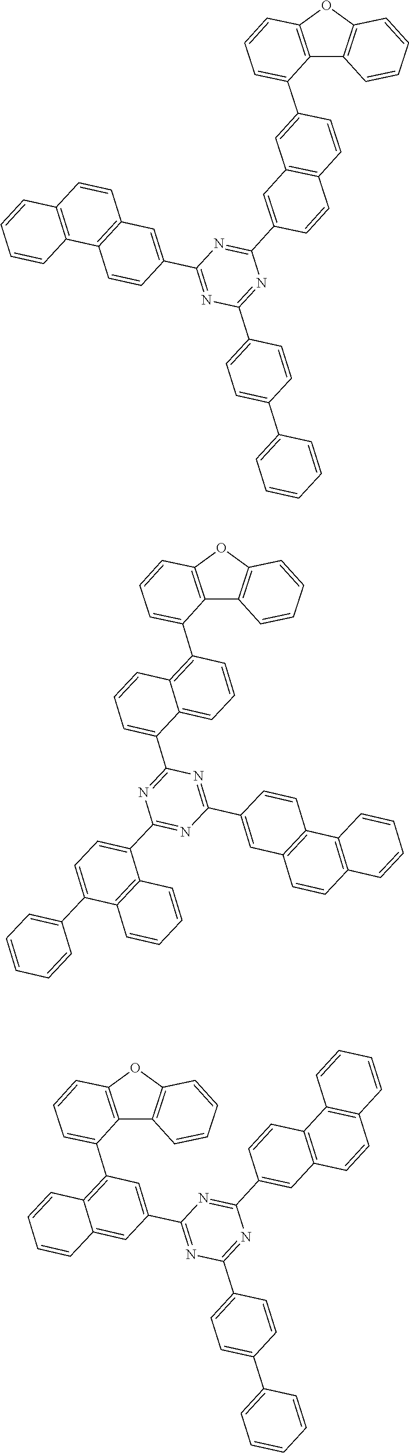 [SMILES: c1ccc(-c2ccc(-c3nc(-c4ccc5ccc(-c6cccc7oc8ccccc8c67)cc5c4)nc(-c4ccc5c(ccc6ccccc65)c4)n3)cc2)cc1 ; c1ccc(-c2ccc(-c3nc(-c4ccc5c(ccc6ccccc65)c4)nc(-c4cccc5c(-c6cccc7oc8ccccc8c67)cccc45)n3)c3ccccc23)cc1 ; c1ccc(-c2ccc(-c3nc(-c4cc(-c5cccc6oc7ccccc7c56)c5ccccc5c4)nc(-c4ccc5c(ccc6ccccc65)c4)n3)cc2)cc1]

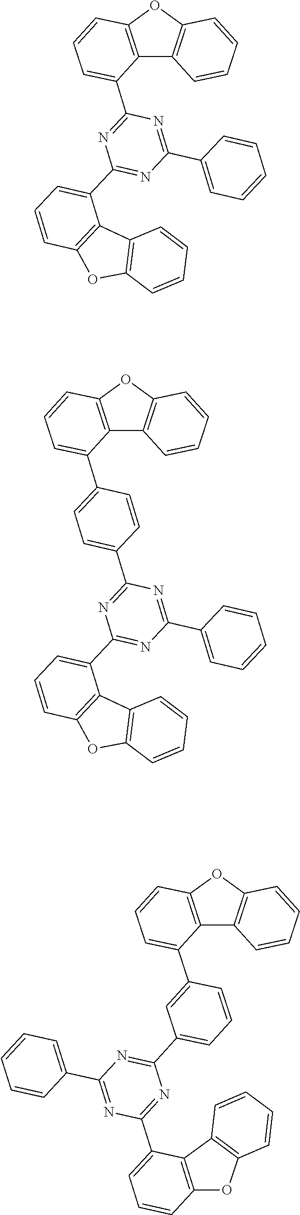 [SMILES: c1ccc(-c2nc(-c3cccc4oc5ccccc5c34)nc(-c3cccc4oc5ccccc5c34)n2)cc1 ; c1ccc(-c2nc(-c3ccc(-c4cccc5oc6ccccc6c45)cc3)nc(-c3cccc4oc5ccccc5c34)n2)cc1 ; c1ccc(-c2nc(-c3cccc(-c4cccc5oc6ccccc6c45)c3)nc(-c3cccc4oc5ccccc5c34)n2)cc1]

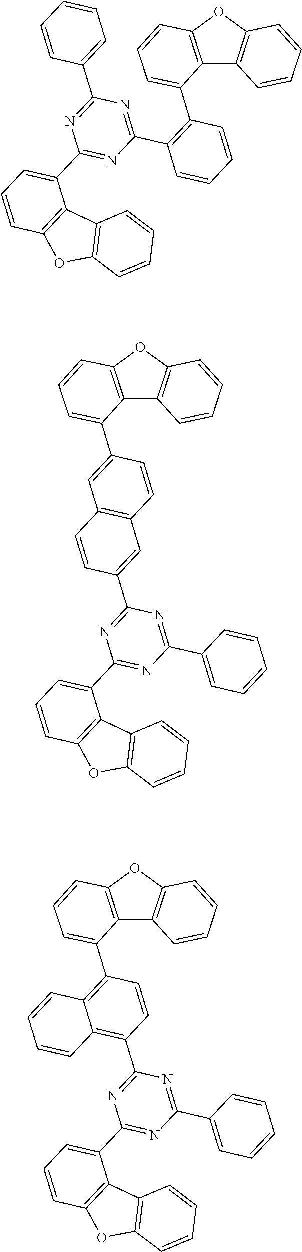 [SMILES: c1ccc(-c2nc(-c3ccccc3-c3cccc4oc5ccccc5c34)nc(-c3cccc4oc5ccccc5c34)n2)cc1 ; c1ccc(-c2nc(-c3ccc4cc(-c5cccc6oc7ccccc7c56)ccc4c3)nc(-c3cccc4oc5ccccc5c34)n2)cc1 ; c1ccc(-c2nc(-c3ccc(-c4cccc5oc6ccccc6c45)c4ccccc34)nc(-c3cccc4oc5ccccc5c34)n2)cc1]

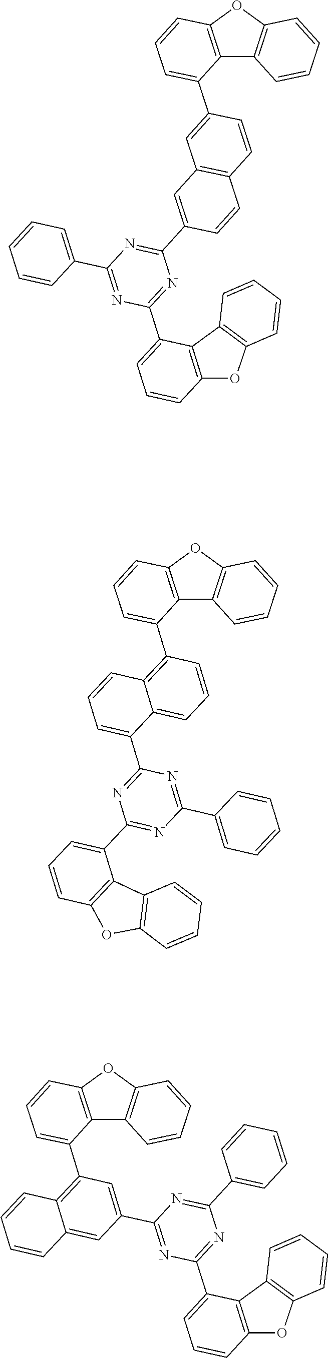 [SMILES: c1ccc(-c2nc(-c3ccc4ccc(-c5cccc6oc7ccccc7c56)cc4c3)nc(-c3cccc4oc5ccccc5c34)n2)cc1 ; c1ccc(-c2nc(-c3cccc4c(-c5cccc6oc7ccccc7c56)cccc34)nc(-c3cccc4oc5ccccc5c34)n2)cc1 ; c1ccc(-c2nc(-c3cc(-c4cccc5oc6ccccc6c45)c4ccccc4c3)nc(-c3cccc4oc5ccccc5c34)n2)cc1]

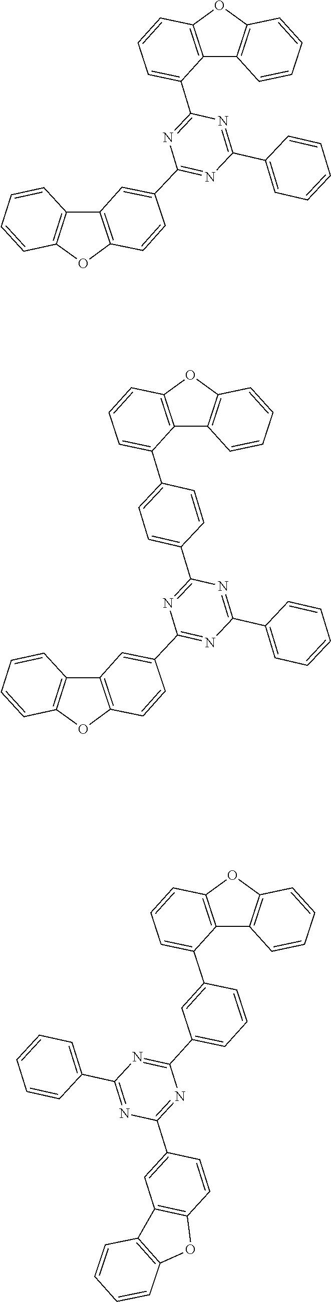 [SMILES: c1ccc(-c2nc(-c3ccc4oc5ccccc5c4c3)nc(-c3cccc4oc5ccccc5c34)n2)cc1 ; c1ccc(-c2nc(-c3ccc(-c4cccc5oc6ccccc6c45)cc3)nc(-c3ccc4oc5ccccc5c4c3)n2)cc1 ; c1ccc(-c2nc(-c3cccc(-c4cccc5oc6ccccc6c45)c3)nc(-c3ccc4oc5ccccc5c4c3)n2)cc1]

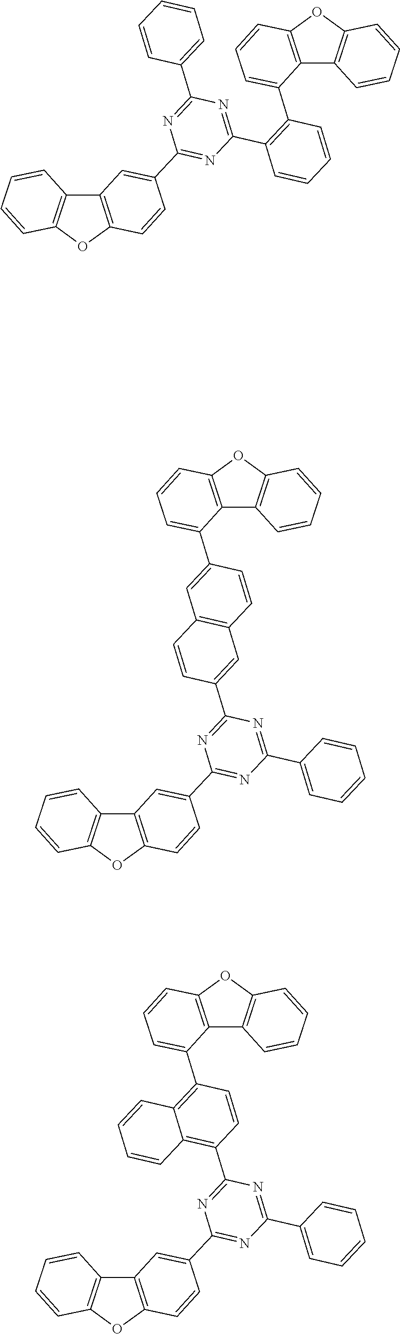 [SMILES: c1ccc(-c2nc(-c3ccc4oc5ccccc5c4c3)nc(-c3ccccc3-c3cccc4oc5ccccc5c34)n2)cc1 ; c1ccc(-c2nc(-c3ccc4cc(-c5cccc6oc7ccccc7c56)ccc4c3)nc(-c3ccc4oc5ccccc5c4c3)n2)cc1 ; c1ccc(-c2nc(-c3ccc4oc5ccccc5c4c3)nc(-c3ccc(-c4cccc5oc6ccccc6c45)c4ccccc34)n2)cc1]

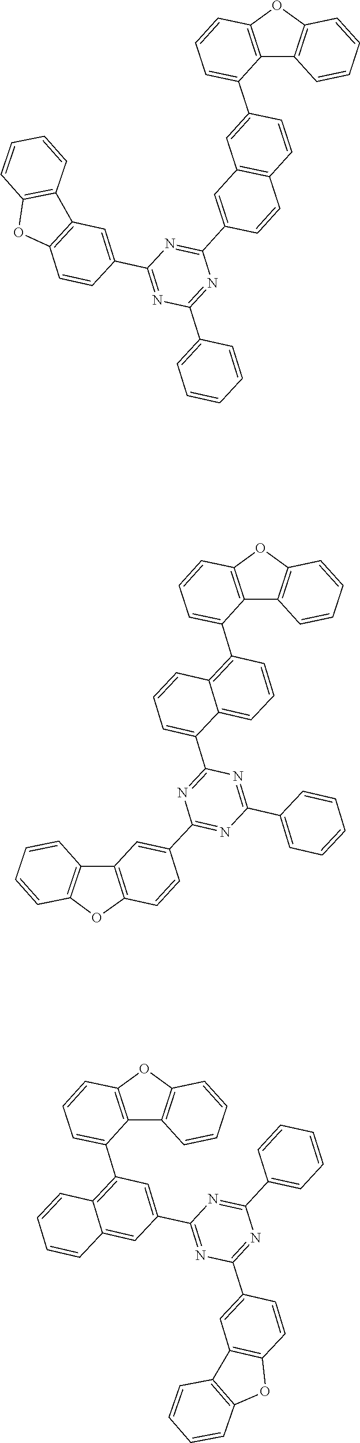 [SMILES: c1ccc(-c2nc(-c3ccc4ccc(-c5cccc6oc7ccccc7c56)cc4c3)nc(-c3ccc4oc5ccccc5c4c3)n2)cc1 ; c1ccc(-c2nc(-c3ccc4oc5ccccc5c4c3)nc(-c3cccc4c(-c5cccc6oc7ccccc7c56)cccc34)n2)cc1 ; c1ccc(-c2nc(-c3cc(-c4cccc5oc6ccccc6c45)c4ccccc4c3)nc(-c3ccc4oc5ccccc5c4c3)n2)cc1]

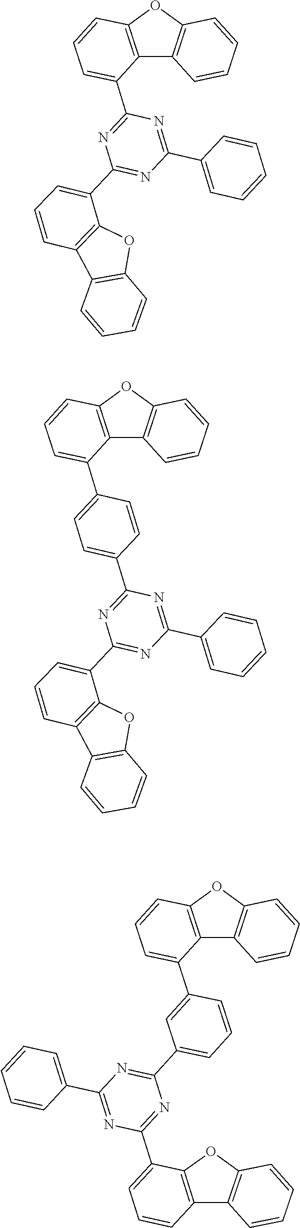 [SMILES: c1ccc(-c2nc(-c3cccc4c3oc3ccccc34)nc(-c3cccc4oc5ccccc5c34)n2)cc1 ; c1ccc(-c2nc(-c3ccc(-c4cccc5oc6ccccc6c45)cc3)nc(-c3cccc4c3oc3ccccc34)n2)cc1 ; c1ccc(-c2nc(-c3cccc(-c4cccc5oc6ccccc6c45)c3)nc(-c3cccc4c3oc3ccccc34)n2)cc1]

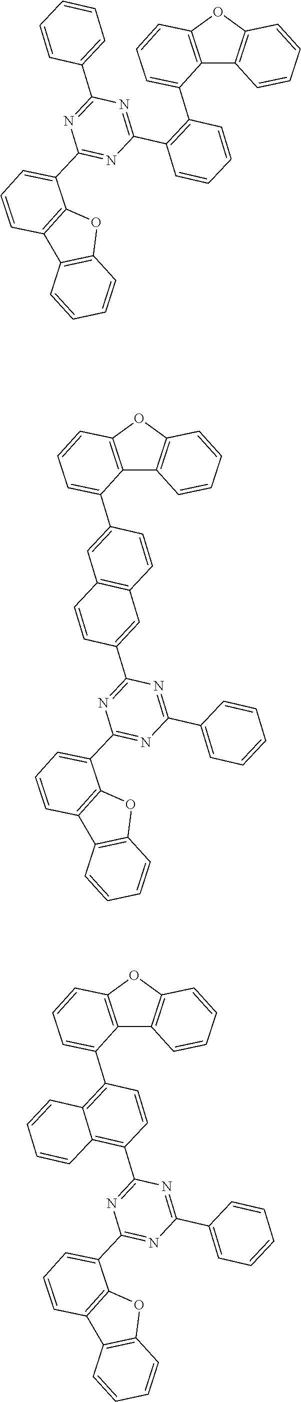 [SMILES: c1ccc(-c2nc(-c3ccccc3-c3cccc4oc5ccccc5c34)nc(-c3cccc4c3oc3ccccc34)n2)cc1 ; c1ccc(-c2nc(-c3ccc4cc(-c5cccc6oc7ccccc7c56)ccc4c3)nc(-c3cccc4c3oc3ccccc34)n2)cc1 ; c1ccc(-c2nc(-c3ccc(-c4cccc5oc6ccccc6c45)c4ccccc34)nc(-c3cccc4c3oc3ccccc34)n2)cc1]

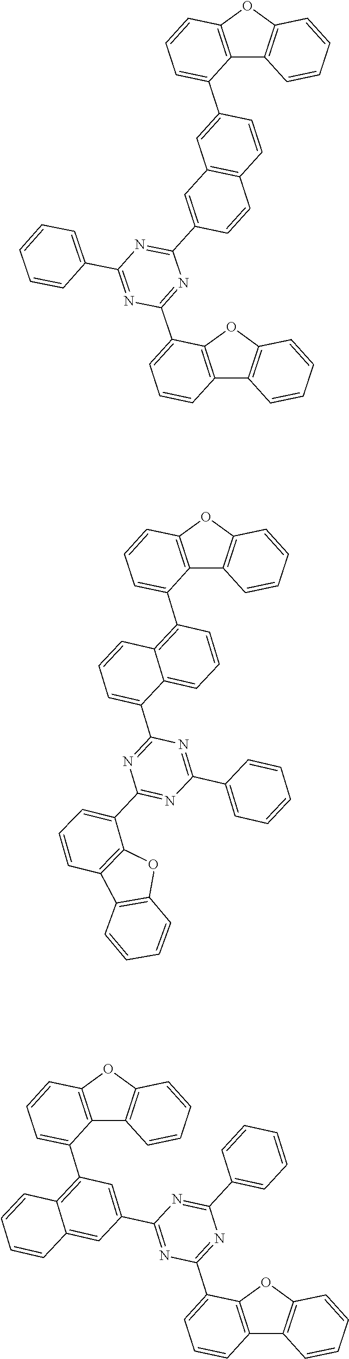 [SMILES: c1ccc(-c2nc(-c3ccc4ccc(-c5cccc6oc7ccccc7c56)cc4c3)nc(-c3cccc4c3oc3ccccc34)n2)cc1 ; c1ccc(-c2nc(-c3cccc4c(-c5cccc6oc7ccccc7c56)cccc34)nc(-c3cccc4c3oc3ccccc34)n2)cc1 ; c1ccc(-c2nc(-c3cc(-c4cccc5oc6ccccc6c45)c4ccccc4c3)nc(-c3cccc4c3oc3ccccc34)n2)cc1]

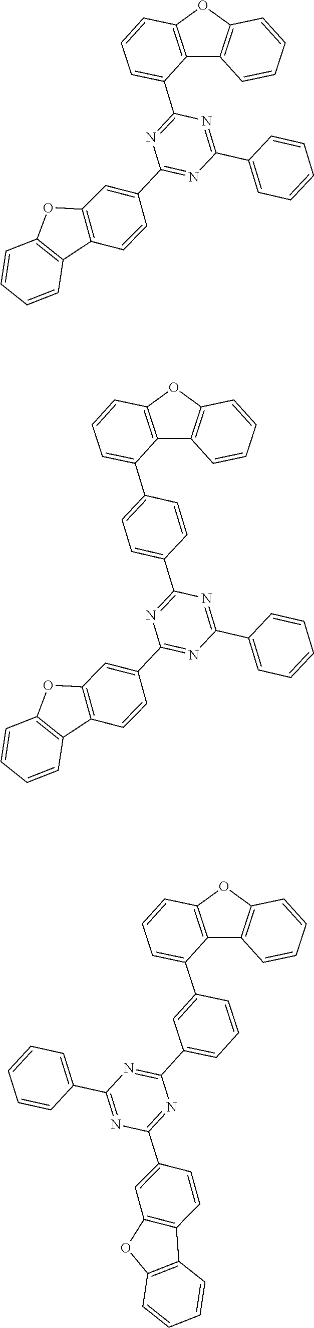 [SMILES: c1ccc(-c2nc(-c3ccc4c(c3)oc3ccccc34)nc(-c3cccc4oc5ccccc5c34)n2)cc1 ; c1ccc(-c2nc(-c3ccc(-c4cccc5oc6ccccc6c45)cc3)nc(-c3ccc4c(c3)oc3ccccc34)n2)cc1 ; c1ccc(-c2nc(-c3cccc(-c4cccc5oc6ccccc6c45)c3)nc(-c3ccc4c(c3)oc3ccccc34)n2)cc1]

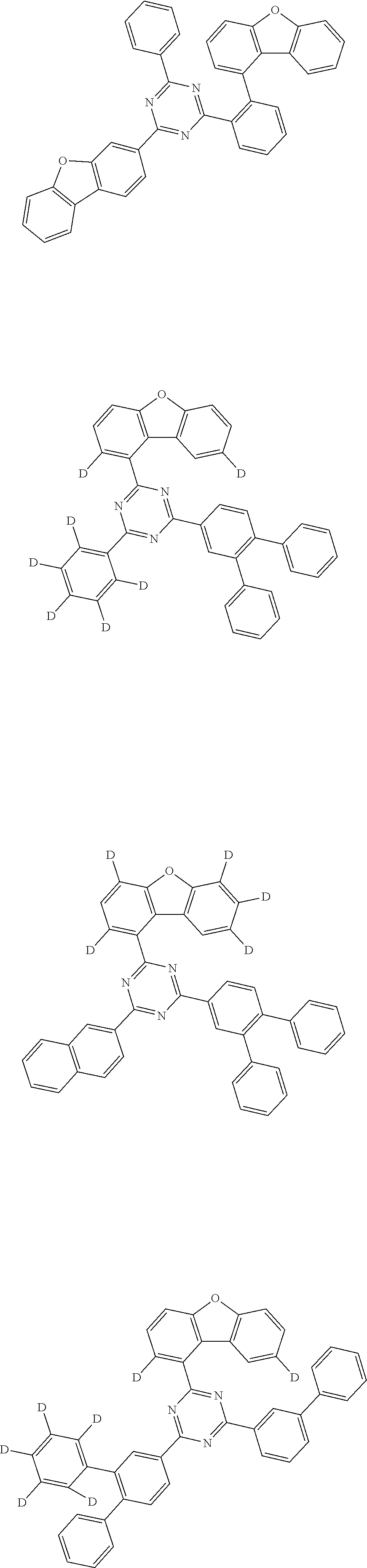 [SMILES: c1ccc(-c2nc(-c3ccc4c(c3)oc3ccccc34)nc(-c3ccccc3-c3cccc4oc5ccccc5c34)n2)cc1 ; [2H]c1ccc2oc3ccc([2H])c(-c4nc(-c5ccc(-c6ccccc6)c(-c6ccccc6)c5)nc(-c5c([2H])c([2H])c([2H])c([2H])c5[2H])n4)c3c2c1 ; [2H]c1cc2c(oc3c([2H])cc([2H])c(-c4nc(-c5ccc(-c6ccccc6)c(-c6ccccc6)c5)nc(-c5ccc6ccccc6c5)n4)c32)c([2H])c1[2H] ; [2H]c1ccc2oc3ccc([2H])c(-c4nc(-c5cccc(-c6ccccc6)c5)nc(-c5ccc(-c6ccccc6)c(-c6c([2H])c([2H])c([2H])c([2H])c6[2H])c5)n4)c3c2c1]

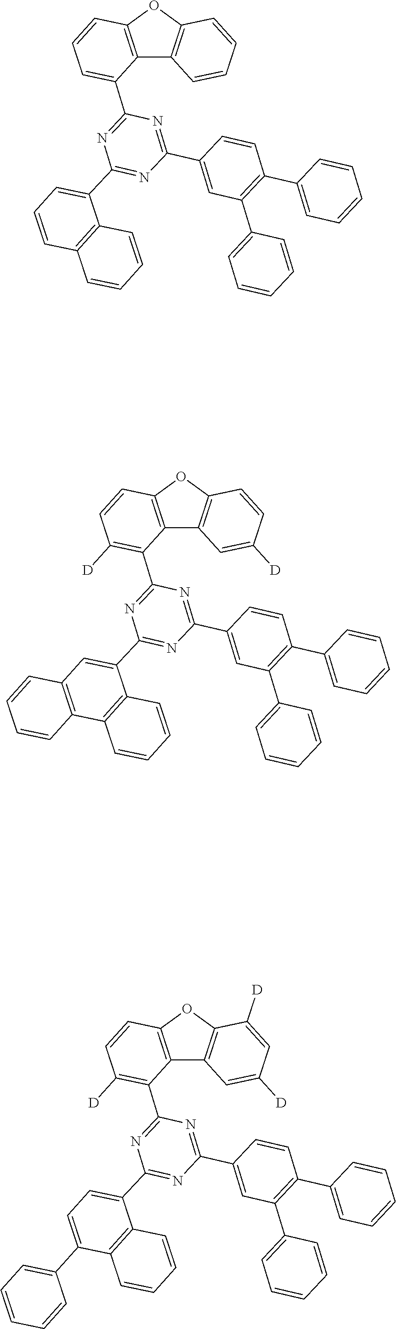 [SMILES: c1ccc(-c2ccc(-c3nc(-c4cccc5ccccc45)nc(-c4cccc5oc6ccccc6c45)n3)cc2-c2ccccc2)cc1 ; [2H]c1ccc2oc3ccc([2H])c(-c4nc(-c5ccc(-c6ccccc6)c(-c6ccccc6)c5)nc(-c5cc6ccccc6c6ccccc56)n4)c3c2c1 ; [2H]c1cc([2H])c2oc3ccc([2H])c(-c4nc(-c5ccc(-c6ccccc6)c(-c6ccccc6)c5)nc(-c5ccc(-c6ccccc6)c6ccccc56)n4)c3c2c1]

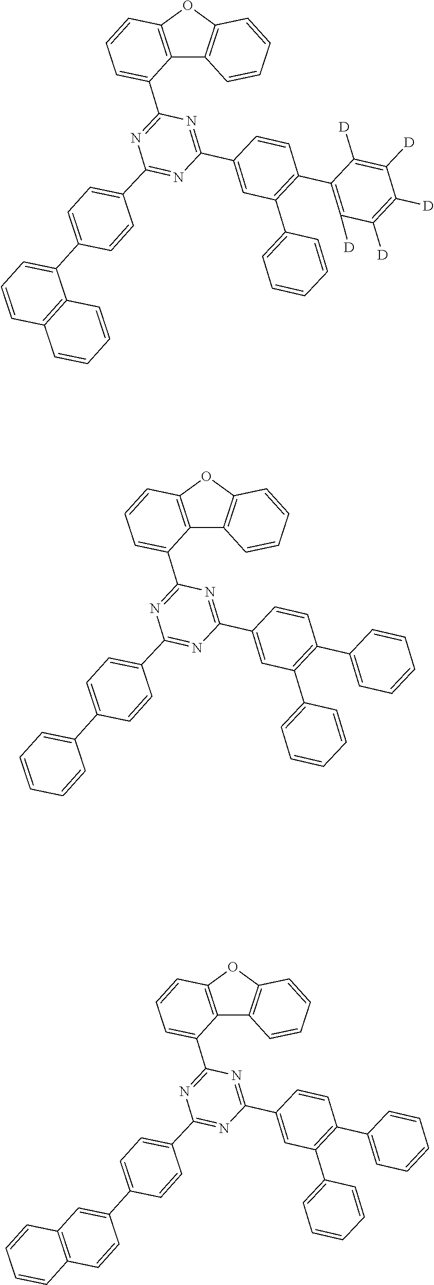 [SMILES: [2H]c1c([2H])c([2H])c(-c2ccc(-c3nc(-c4ccc(-c5cccc6ccccc56)cc4)nc(-c4cccc5oc6ccccc6c45)n3)cc2-c2ccccc2)c([2H])c1[2H] ; c1ccc(-c2ccc(-c3nc(-c4ccc(-c5ccccc5)c(-c5ccccc5)c4)nc(-c4cccc5oc6ccccc6c45)n3)cc2)cc1 ; c1ccc(-c2ccc(-c3nc(-c4ccc(-c5ccc6ccccc6c5)cc4)nc(-c4cccc5oc6ccccc6c45)n3)cc2-c2ccccc2)cc1]

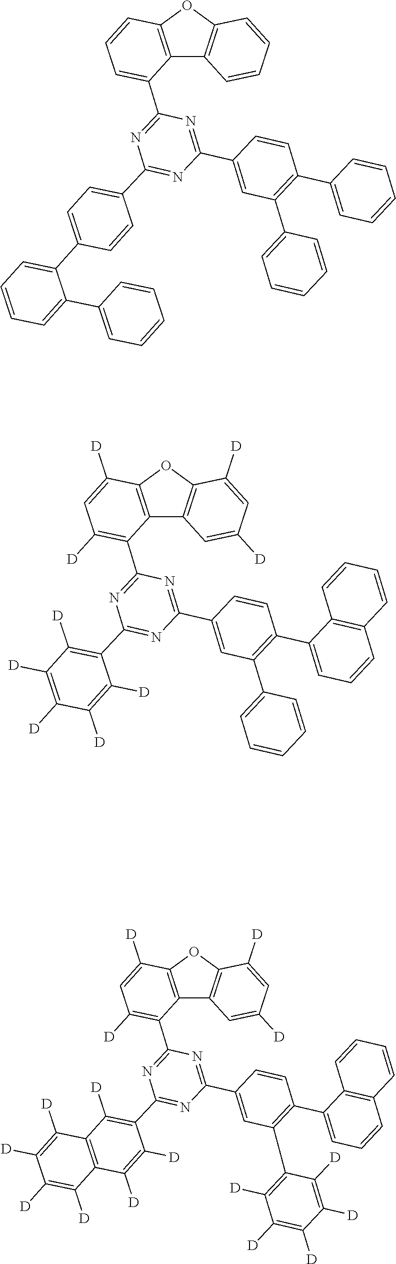 [SMILES: c1ccc(-c2ccccc2-c2ccc(-c3nc(-c4ccc(-c5ccccc5)c(-c5ccccc5)c4)nc(-c4cccc5oc6ccccc6c45)n3)cc2)cc1 ; [2H]c1cc([2H])c2oc3c([2H])cc([2H])c(-c4nc(-c5ccc(-c6cccc7ccccc67)c(-c6ccccc6)c5)nc(-c5c([2H])c([2H])c([2H])c([2H])c5[2H])n4)c3c2c1 ; [2H]c1cc([2H])c2oc3c([2H])cc([2H])c(-c4nc(-c5ccc(-c6cccc7ccccc67)c(-c6c([2H])c([2H])c([2H])c([2H])c6[2H])c5)nc(-c5c([2H])c([2H])c6c([2H])c([2H])c([2H])c([2H])c6c5[2H])n4)c3c2c1]

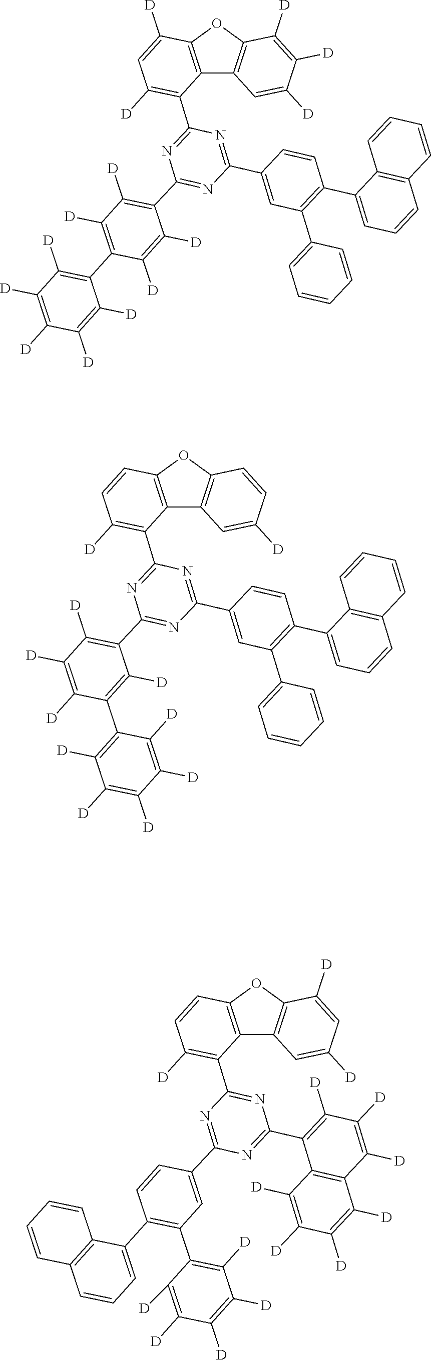 [SMILES: [2H]c1cc2c(oc3c([2H])cc([2H])c(-c4nc(-c5ccc(-c6cccc7ccccc67)c(-c6ccccc6)c5)nc(-c5c([2H])c([2H])c(-c6c([2H])c([2H])c([2H])c([2H])c6[2H])c([2H])c5[2H])n4)c32)c([2H])c1[2H] ; [2H]c1ccc2oc3ccc([2H])c(-c4nc(-c5ccc(-c6cccc7ccccc67)c(-c6ccccc6)c5)nc(-c5c([2H])c([2H])c([2H])c(-c6c([2H])c([2H])c([2H])c([2H])c6[2H])c5[2H])n4)c3c2c1 ; [2H]c1cc([2H])c2oc3ccc([2H])c(-c4nc(-c5ccc(-c6cccc7ccccc67)c(-c6c([2H])c([2H])c([2H])c([2H])c6[2H])c5)nc(-c5c([2H])c([2H])c([2H])c6c([2H])c([2H])c([2H])c([2H])c56)n4)c3c2c1]

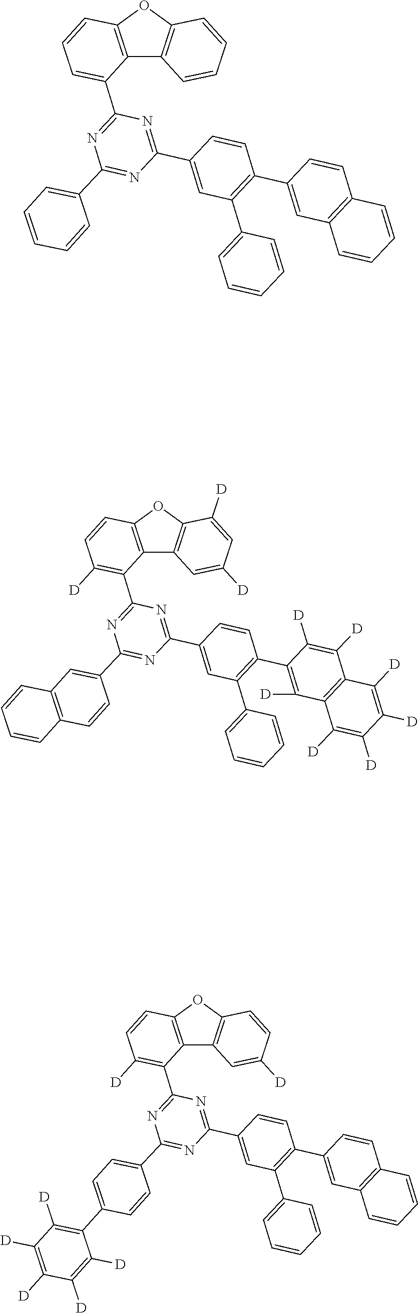 [SMILES: c1ccc(-c2nc(-c3ccc(-c4ccc5ccccc5c4)c(-c4ccccc4)c3)nc(-c3cccc4oc5ccccc5c34)n2)cc1 ; [2H]c1cc([2H])c2oc3ccc([2H])c(-c4nc(-c5ccc(-c6c([2H])c([2H])c7c([2H])c([2H])c([2H])c([2H])c7c6[2H])c(-c6ccccc6)c5)nc(-c5ccc6ccccc6c5)n4)c3c2c1 ; [2H]c1ccc2oc3ccc([2H])c(-c4nc(-c5ccc(-c6c([2H])c([2H])c([2H])c([2H])c6[2H])cc5)nc(-c5ccc(-c6ccc7ccccc7c6)c(-c6ccccc6)c5)n4)c3c2c1]

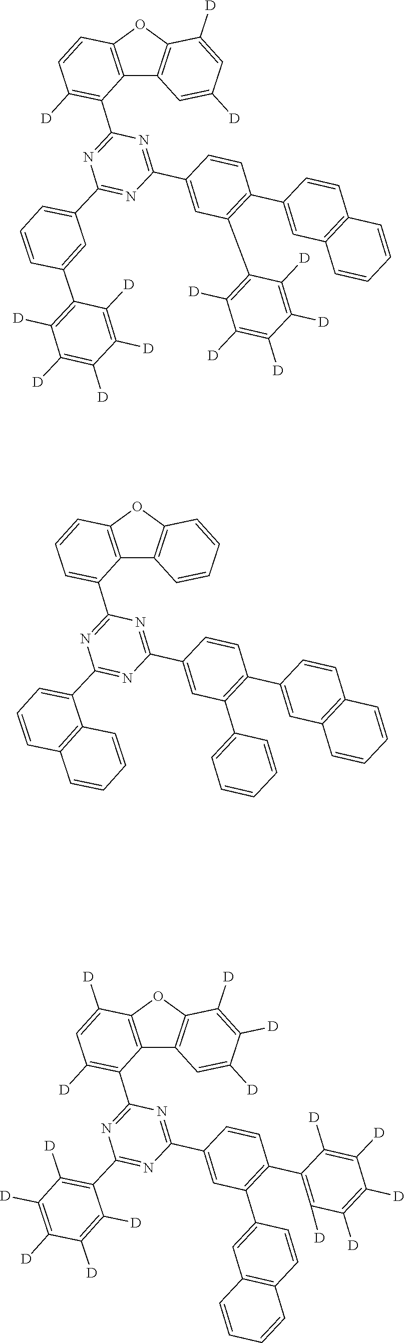 [SMILES: [2H]c1cc([2H])c2oc3ccc([2H])c(-c4nc(-c5cccc(-c6c([2H])c([2H])c([2H])c([2H])c6[2H])c5)nc(-c5ccc(-c6ccc7ccccc7c6)c(-c6c([2H])c([2H])c([2H])c([2H])c6[2H])c5)n4)c3c2c1 ; c1ccc(-c2cc(-c3nc(-c4cccc5ccccc45)nc(-c4cccc5oc6ccccc6c45)n3)ccc2-c2ccc3ccccc3c2)cc1 ; [2H]c1cc2c(oc3c([2H])cc([2H])c(-c4nc(-c5ccc(-c6c([2H])c([2H])c([2H])c([2H])c6[2H])c(-c6ccc7ccccc7c6)c5)nc(-c5c([2H])c([2H])c([2H])c([2H])c5[2H])n4)c32)c([2H])c1[2H]]

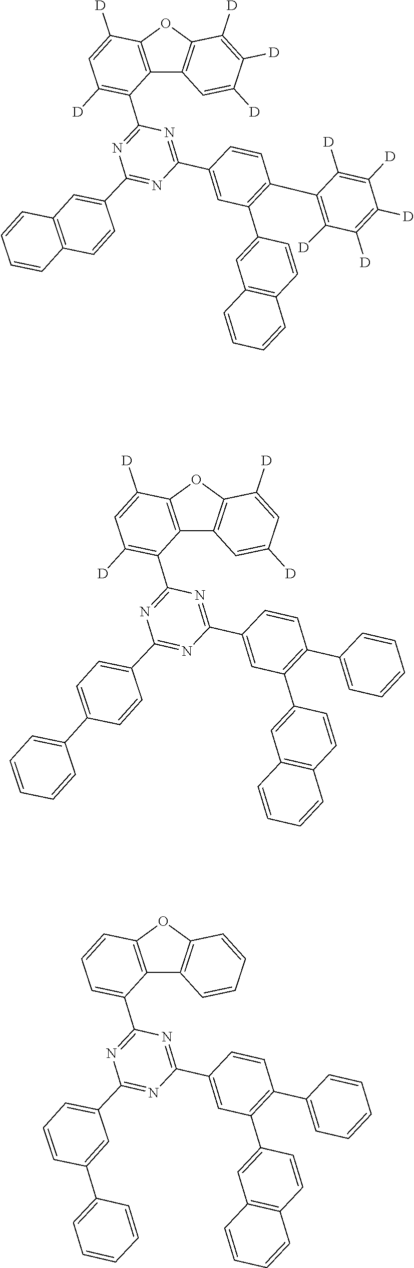 [SMILES: [2H]c1cc2c(oc3c([2H])cc([2H])c(-c4nc(-c5ccc(-c6c([2H])c([2H])c([2H])c([2H])c6[2H])c(-c6ccc7ccccc7c6)c5)nc(-c5ccc6ccccc6c5)n4)c32)c([2H])c1[2H] ; [2H]c1cc([2H])c2oc3c([2H])cc([2H])c(-c4nc(-c5ccc(-c6ccccc6)cc5)nc(-c5ccc(-c6ccccc6)c(-c6ccc7ccccc7c6)c5)n4)c3c2c1 ; c1ccc(-c2cccc(-c3nc(-c4ccc(-c5ccccc5)c(-c5ccc6ccccc6c5)c4)nc(-c4cccc5oc6ccccc6c45)n3)c2)cc1]

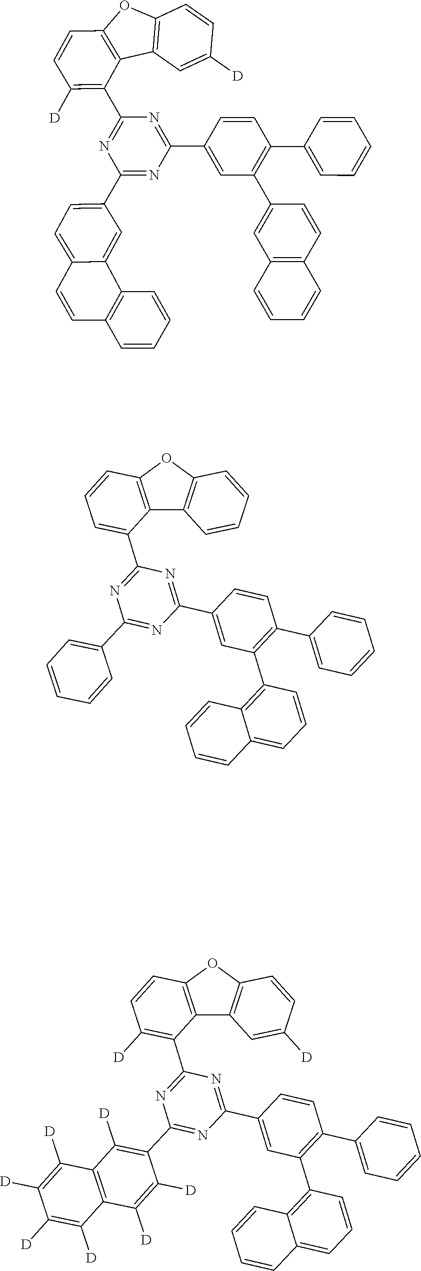 [SMILES: [2H]c1ccc2oc3ccc([2H])c(-c4nc(-c5ccc(-c6ccccc6)c(-c6ccc7ccccc7c6)c5)nc(-c5ccc6ccc7ccccc7c6c5)n4)c3c2c1 ; c1ccc(-c2nc(-c3ccc(-c4ccccc4)c(-c4cccc5ccccc45)c3)nc(-c3cccc4oc5ccccc5c34)n2)cc1 ; [2H]c1ccc2oc3ccc([2H])c(-c4nc(-c5ccc(-c6ccccc6)c(-c6cccc7ccccc67)c5)nc(-c5c([2H])c([2H])c6c([2H])c([2H])c([2H])c([2H])c6c5[2H])n4)c3c2c1]

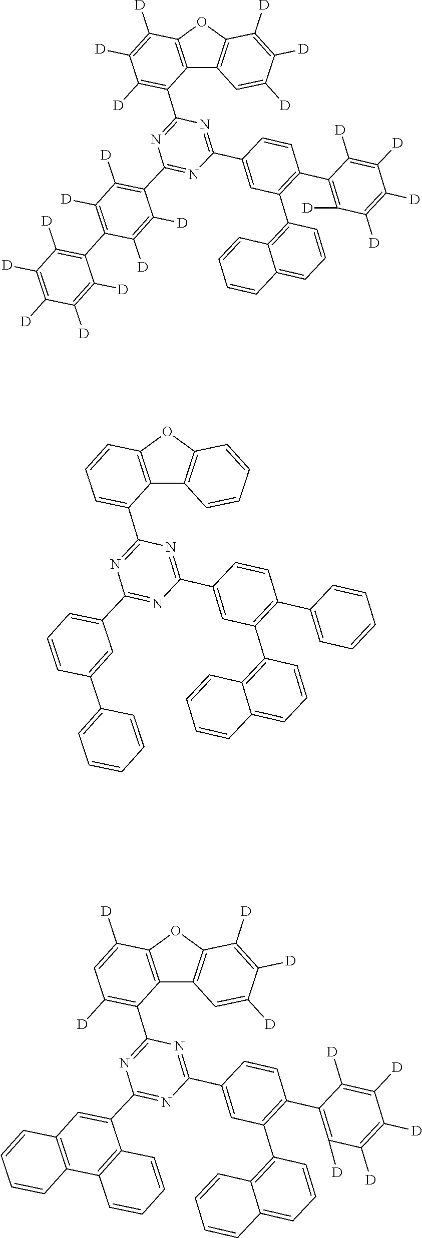 [SMILES: [2H]c1cc2c(oc3c([2H])c([2H])c([2H])c(-c4nc(-c5ccc(-c6c([2H])c([2H])c([2H])c([2H])c6[2H])c(-c6cccc7ccccc67)c5)nc(-c5c([2H])c([2H])c(-c6c([2H])c([2H])c([2H])c([2H])c6[2H])c([2H])c5[2H])n4)c32)c([2H])c1[2H] ; c1ccc(-c2cccc(-c3nc(-c4ccc(-c5ccccc5)c(-c5cccc6ccccc56)c4)nc(-c4cccc5oc6ccccc6c45)n3)c2)cc1 ; [2H]c1cc2c(oc3c([2H])cc([2H])c(-c4nc(-c5ccc(-c6c([2H])c([2H])c([2H])c([2H])c6[2H])c(-c6cccc7ccccc67)c5)nc(-c5cc6ccccc6c6ccccc56)n4)c32)c([2H])c1[2H]]

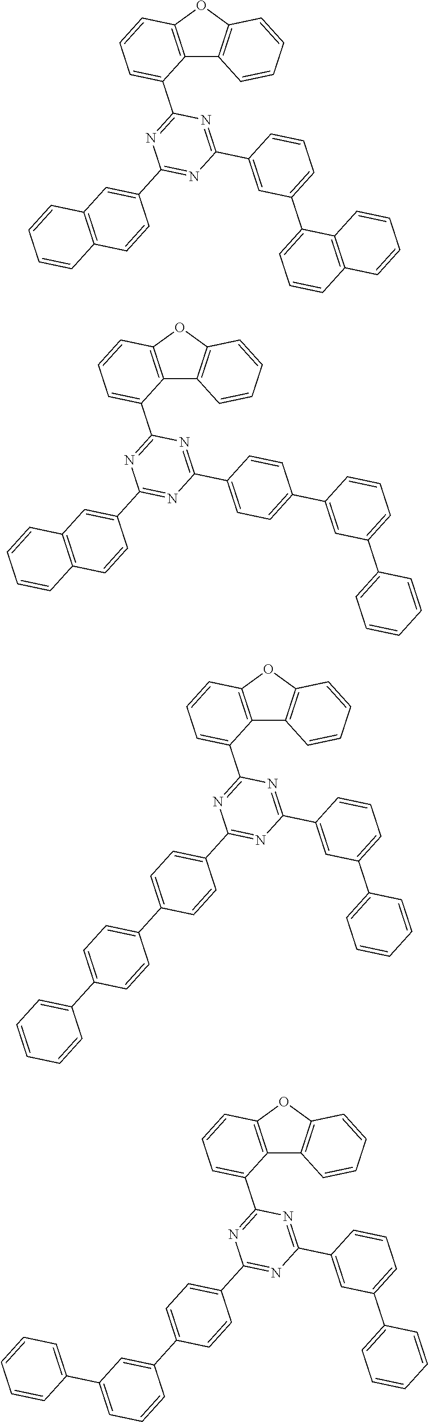 [SMILES: c1cc(-c2nc(-c3ccc4ccccc4c3)nc(-c3cccc4oc5ccccc5c34)n2)cc(-c2cccc3ccccc23)c1 ; c1ccc(-c2cccc(-c3ccc(-c4nc(-c5ccc6ccccc6c5)nc(-c5cccc6oc7ccccc7c56)n4)cc3)c2)cc1 ; c1ccc(-c2ccc(-c3ccc(-c4nc(-c5cccc(-c6ccccc6)c5)nc(-c5cccc6oc7ccccc7c56)n4)cc3)cc2)cc1 ; c1ccc(-c2cccc(-c3ccc(-c4nc(-c5cccc(-c6ccccc6)c5)nc(-c5cccc6oc7ccccc7c56)n4)cc3)c2)cc1]

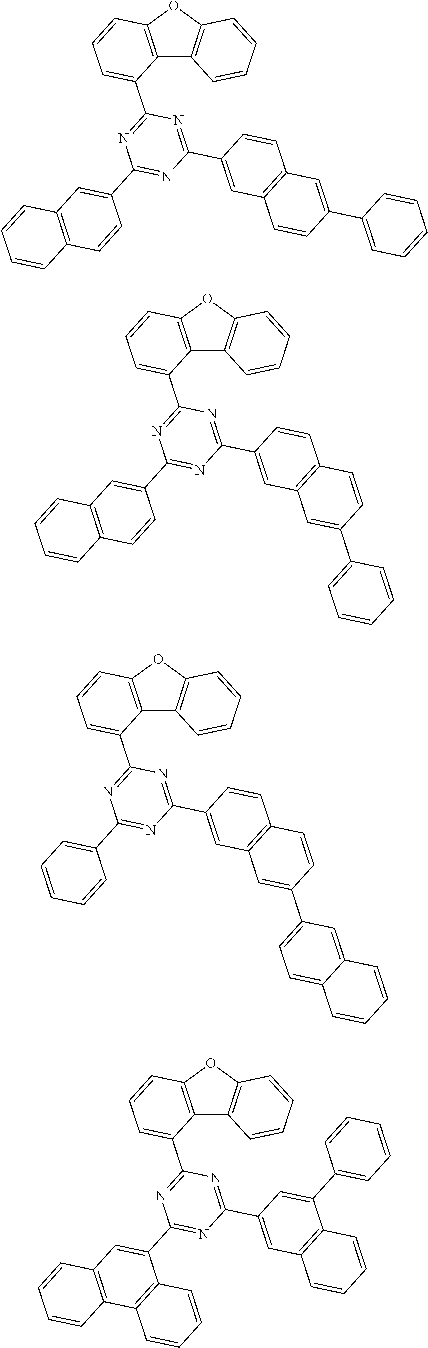 [SMILES: c1ccc(-c2ccc3cc(-c4nc(-c5ccc6ccccc6c5)nc(-c5cccc6oc7ccccc7c56)n4)ccc3c2)cc1 ; c1ccc(-c2ccc3ccc(-c4nc(-c5ccc6ccccc6c5)nc(-c5cccc6oc7ccccc7c56)n4)cc3c2)cc1 ; c1ccc(-c2nc(-c3ccc4ccc(-c5ccc6ccccc6c5)cc4c3)nc(-c3cccc4oc5ccccc5c34)n2)cc1 ; c1ccc(-c2cc(-c3nc(-c4cc5ccccc5c5ccccc45)nc(-c4cccc5oc6ccccc6c45)n3)cc3ccccc23)cc1]

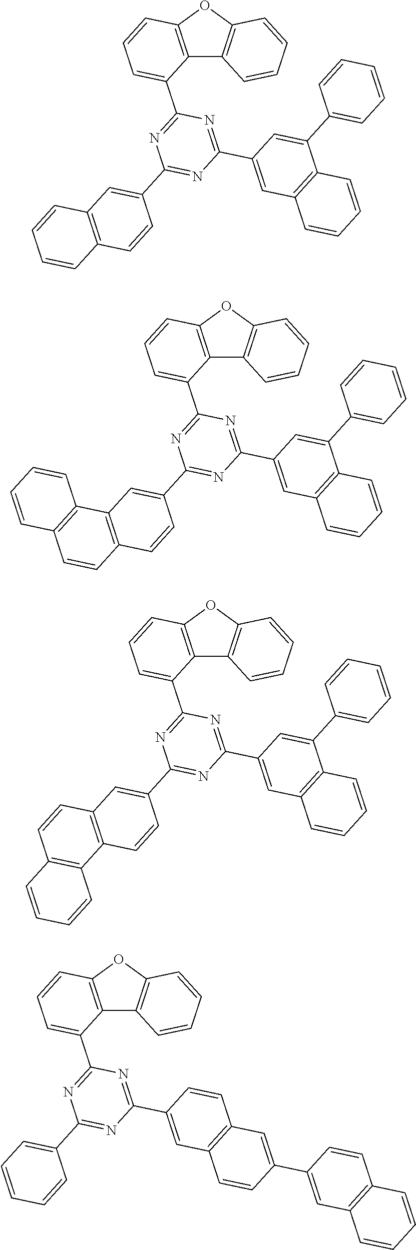 [SMILES: c1ccc(-c2cc(-c3nc(-c4ccc5ccccc5c4)nc(-c4cccc5oc6ccccc6c45)n3)cc3ccccc23)cc1 ; c1ccc(-c2cc(-c3nc(-c4ccc5ccc6ccccc6c5c4)nc(-c4cccc5oc6ccccc6c45)n3)cc3ccccc23)cc1 ; c1ccc(-c2cc(-c3nc(-c4ccc5c(ccc6ccccc65)c4)nc(-c4cccc5oc6ccccc6c45)n3)cc3ccccc23)cc1 ; c1ccc(-c2nc(-c3ccc4cc(-c5ccc6ccccc6c5)ccc4c3)nc(-c3cccc4oc5ccccc5c34)n2)cc1]

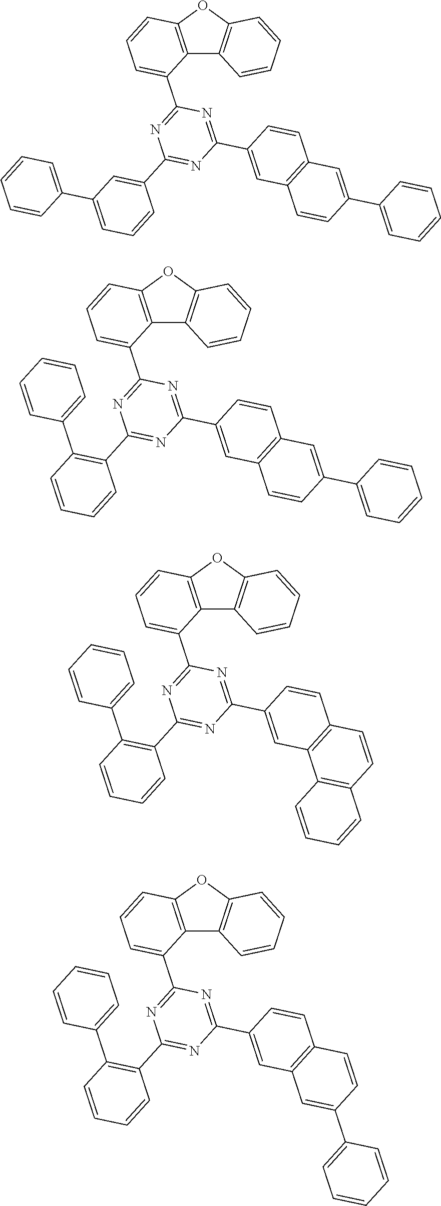 [SMILES: c1ccc(-c2cccc(-c3nc(-c4ccc5cc(-c6ccccc6)ccc5c4)nc(-c4cccc5oc6ccccc6c45)n3)c2)cc1 ; c1ccc(-c2ccc3cc(-c4nc(-c5ccccc5-c5ccccc5)nc(-c5cccc6oc7ccccc7c56)n4)ccc3c2)cc1 ; c1ccc(-c2ccccc2-c2nc(-c3ccc4ccc5ccccc5c4c3)nc(-c3cccc4oc5ccccc5c34)n2)cc1 ; c1ccc(-c2ccc3ccc(-c4nc(-c5ccccc5-c5ccccc5)nc(-c5cccc6oc7ccccc7c56)n4)cc3c2)cc1]

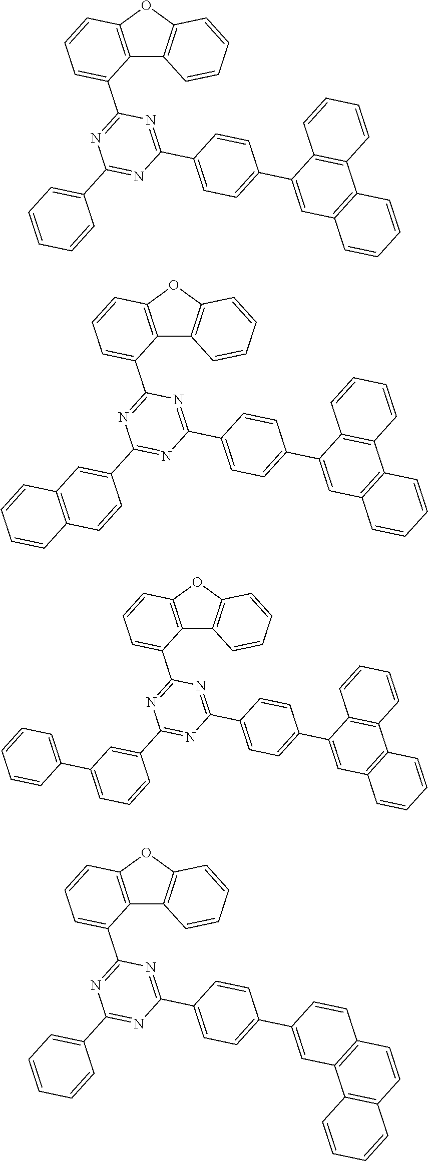 [SMILES: c1ccc(-c2nc(-c3ccc(-c4cc5ccccc5c5ccccc45)cc3)nc(-c3cccc4oc5ccccc5c34)n2)cc1 ; c1ccc2cc(-c3nc(-c4ccc(-c5cc6ccccc6c6ccccc56)cc4)nc(-c4cccc5oc6ccccc6c45)n3)ccc2c1 ; c1ccc(-c2cccc(-c3nc(-c4ccc(-c5cc6ccccc6c6ccccc56)cc4)nc(-c4cccc5oc6ccccc6c45)n3)c2)cc1 ; c1ccc(-c2nc(-c3ccc(-c4ccc5ccc6ccccc6c5c4)cc3)nc(-c3cccc4oc5ccccc5c34)n2)cc1]

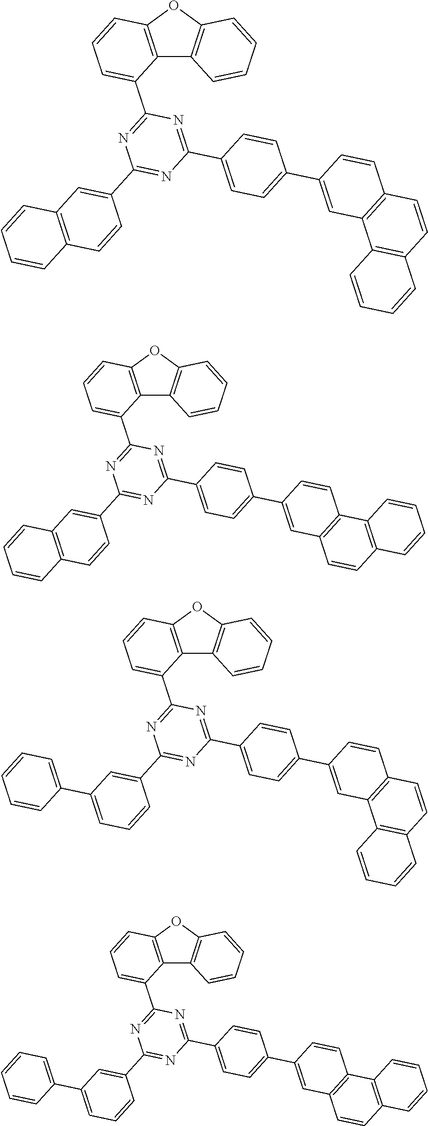 [SMILES: c1ccc2cc(-c3nc(-c4ccc(-c5ccc6ccc7ccccc7c6c5)cc4)nc(-c4cccc5oc6ccccc6c45)n3)ccc2c1 ; c1ccc2cc(-c3nc(-c4ccc(-c5ccc6c(ccc7ccccc76)c5)cc4)nc(-c4cccc5oc6ccccc6c45)n3)ccc2c1 ; c1ccc(-c2cccc(-c3nc(-c4ccc(-c5ccc6ccc7ccccc7c6c5)cc4)nc(-c4cccc5oc6ccccc6c45)n3)c2)cc1 ; c1ccc(-c2cccc(-c3nc(-c4ccc(-c5ccc6c(ccc7ccccc76)c5)cc4)nc(-c4cccc5oc6ccccc6c45)n3)c2)cc1]

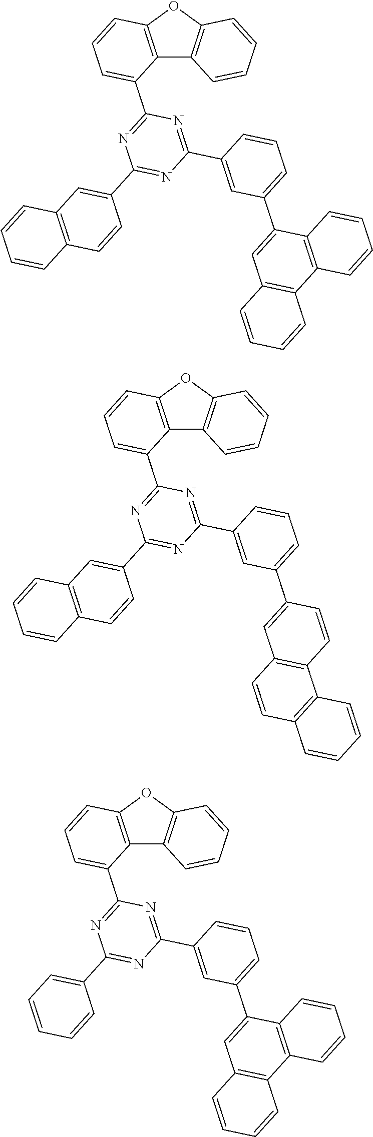 [SMILES: c1cc(-c2nc(-c3ccc4ccccc4c3)nc(-c3cccc4oc5ccccc5c34)n2)cc(-c2cc3ccccc3c3ccccc23)c1 ; c1cc(-c2ccc3c(ccc4ccccc43)c2)cc(-c2nc(-c3ccc4ccccc4c3)nc(-c3cccc4oc5ccccc5c34)n2)c1 ; c1ccc(-c2nc(-c3cccc(-c4cc5ccccc5c5ccccc45)c3)nc(-c3cccc4oc5ccccc5c34)n2)cc1]

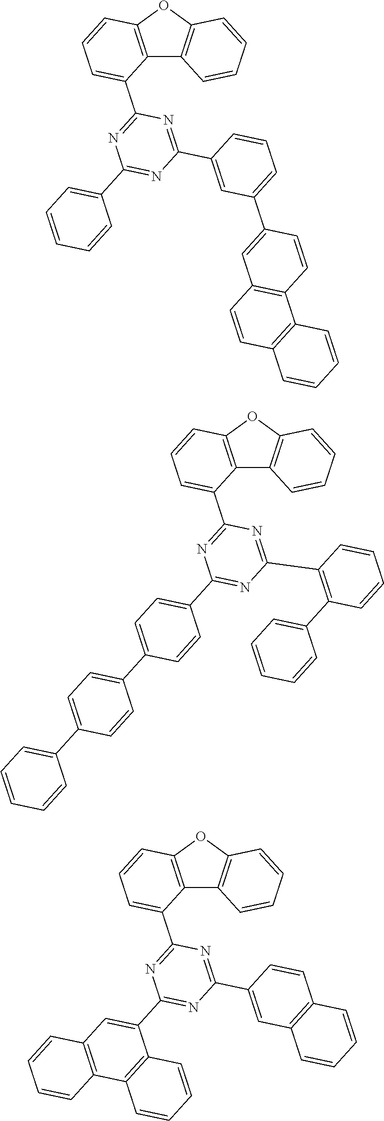

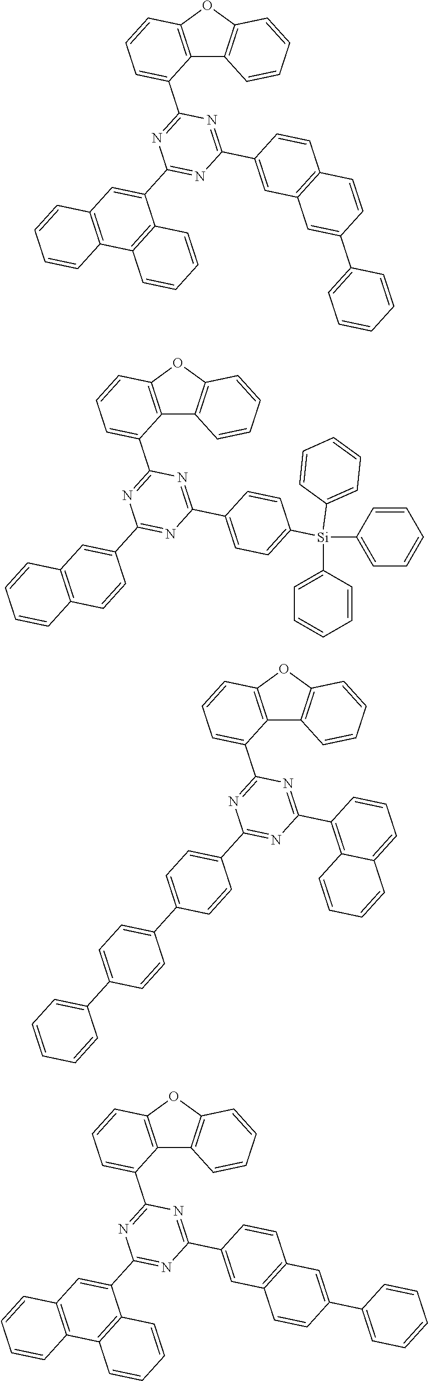 [SMILES: c1ccc(-c2ccc3ccc(-c4nc(-c5cc6ccccc6c6ccccc56)nc(-c5cccc6oc7ccccc7c56)n4)cc3c2)cc1 ; c1ccc([Si](c2ccccc2)(c2ccccc2)c2ccc(-c3nc(-c4ccc5ccccc5c4)nc(-c4cccc5oc6ccccc6c45)n3)cc2)cc1 ; c1ccc(-c2ccc(-c3ccc(-c4nc(-c5cccc6ccccc56)nc(-c5cccc6oc7ccccc7c56)n4)cc3)cc2)cc1 ; c1ccc(-c2ccc3cc(-c4nc(-c5cc6ccccc6c6ccccc56)nc(-c5cccc6oc7ccccc7c56)n4)ccc3c2)cc1]

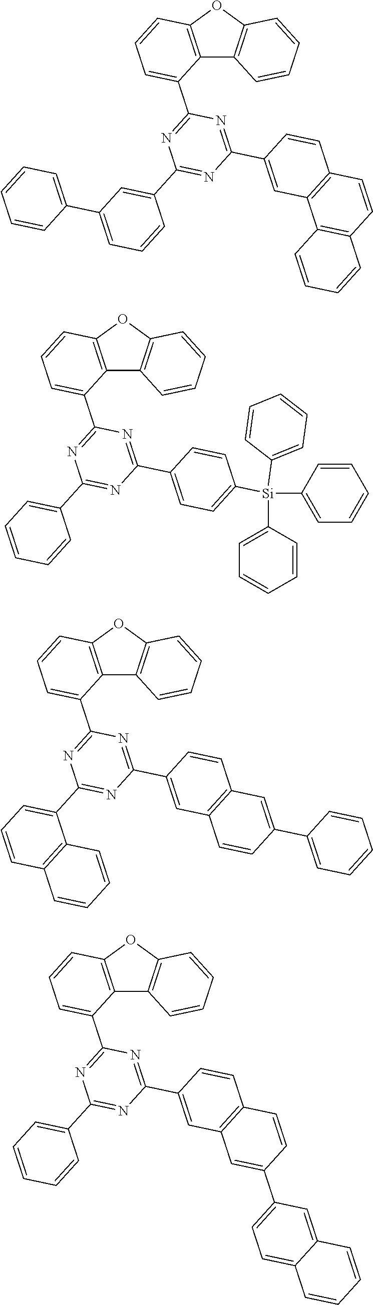 [SMILES: c1ccc(-c2cccc(-c3nc(-c4ccc5ccc6ccccc6c5c4)nc(-c4cccc5oc6ccccc6c45)n3)c2)cc1 ; c1ccc(-c2nc(-c3ccc([Si](c4ccccc4)(c4ccccc4)c4ccccc4)cc3)nc(-c3cccc4oc5ccccc5c34)n2)cc1 ; c1ccc(-c2ccc3cc(-c4nc(-c5cccc6ccccc56)nc(-c5cccc6oc7ccccc7c56)n4)ccc3c2)cc1 ; c1ccc(-c2nc(-c3ccc4ccc(-c5ccc6ccccc6c5)cc4c3)nc(-c3cccc4oc5ccccc5c34)n2)cc1]

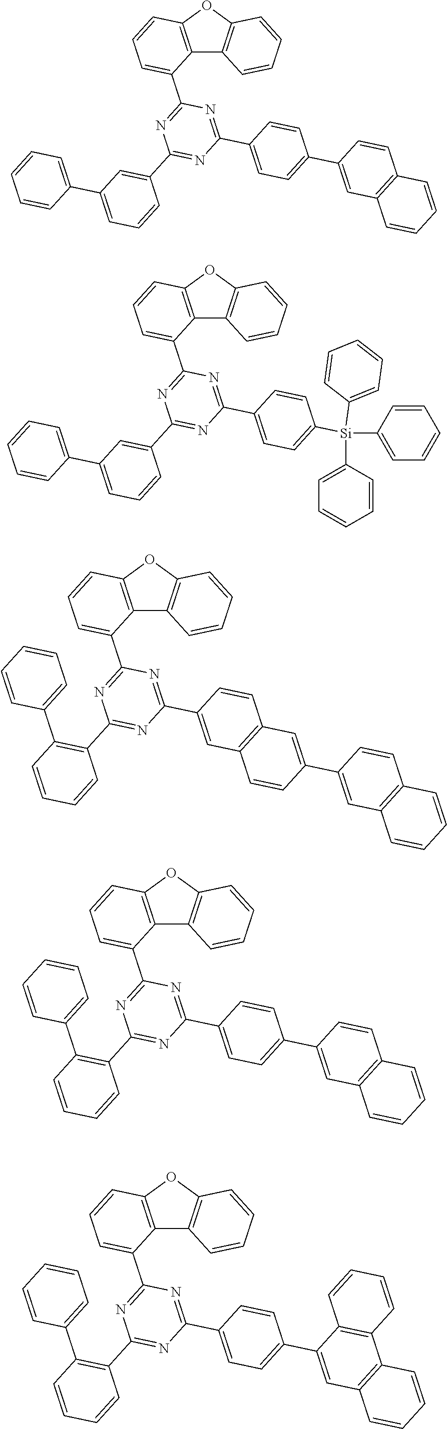 [SMILES: c1ccc(-c2cccc(-c3nc(-c4ccc(-c5ccc6ccccc6c5)cc4)nc(-c4cccc5oc6ccccc6c45)n3)c2)cc1 ; c1ccc(-c2cccc(-c3nc(-c4ccc([Si](c5ccccc5)(c5ccccc5)c5ccccc5)cc4)nc(-c4cccc5oc6ccccc6c45)n3)c2)cc1 ; c1ccc(-c2ccccc2-c2nc(-c3ccc4cc(-c5ccc6ccccc6c5)ccc4c3)nc(-c3cccc4oc5ccccc5c34)n2)cc1 ; c1ccc(-c2ccccc2-c2nc(-c3ccc(-c4ccc5ccccc5c4)cc3)nc(-c3cccc4oc5ccccc5c34)n2)cc1 ; c1ccc(-c2ccccc2-c2nc(-c3ccc(-c4cc5ccccc5c5ccccc45)cc3)nc(-c3cccc4oc5ccccc5c34)n2)cc1]

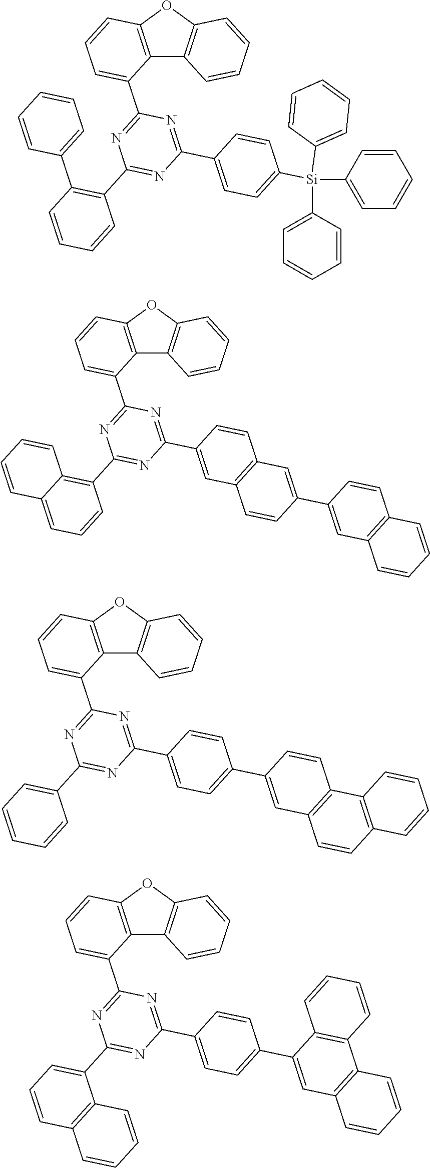 [SMILES: c1ccc(-c2ccccc2-c2nc(-c3ccc([Si](c4ccccc4)(c4ccccc4)c4ccccc4)cc3)nc(-c3cccc4oc5ccccc5c34)n2)cc1 ; c1ccc2cc(-c3ccc4cc(-c5nc(-c6cccc7ccccc67)nc(-c6cccc7oc8ccccc8c67)n5)ccc4c3)ccc2c1 ; c1ccc(-c2nc(-c3ccc(-c4ccc5c(ccc6ccccc65)c4)cc3)nc(-c3cccc4oc5ccccc5c34)n2)cc1 ; c1ccc2c(-c3nc(-c4ccc(-c5cc6ccccc6c6ccccc56)cc4)nc(-c4cccc5oc6ccccc6c45)n3)cccc2c1]

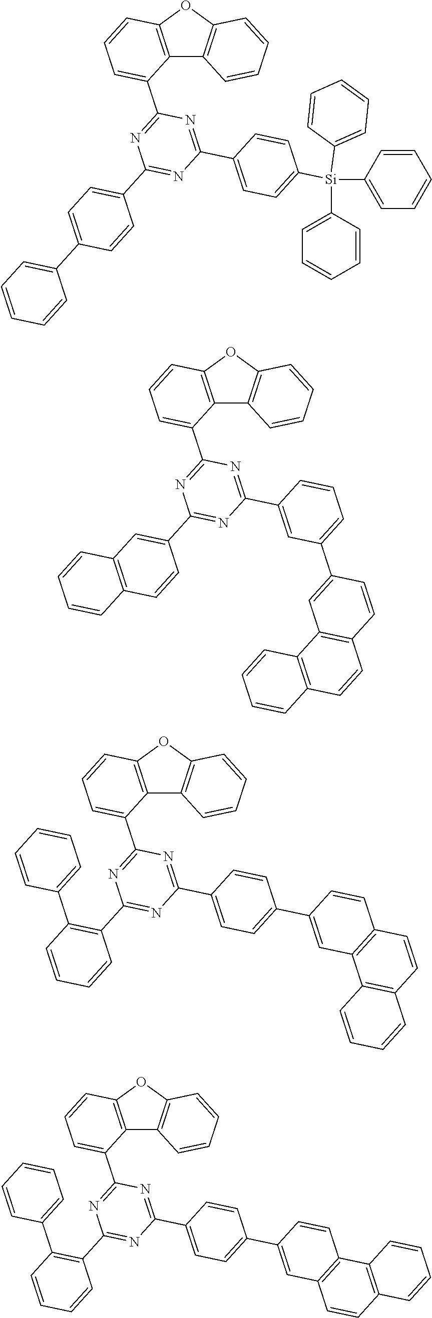 [SMILES: c1ccc(-c2ccc(-c3nc(-c4ccc([Si](c5ccccc5)(c5ccccc5)c5ccccc5)cc4)nc(-c4cccc5oc6ccccc6c45)n3)cc2)cc1 ; c1cc(-c2ccc3ccc4ccccc4c3c2)cc(-c2nc(-c3ccc4ccccc4c3)nc(-c3cccc4oc5ccccc5c34)n2)c1 ; c1ccc(-c2ccccc2-c2nc(-c3ccc(-c4ccc5ccc6ccccc6c5c4)cc3)nc(-c3cccc4oc5ccccc5c34)n2)cc1 ; c1ccc(-c2ccccc2-c2nc(-c3ccc(-c4ccc5c(ccc6ccccc65)c4)cc3)nc(-c3cccc4oc5ccccc5c34)n2)cc1]

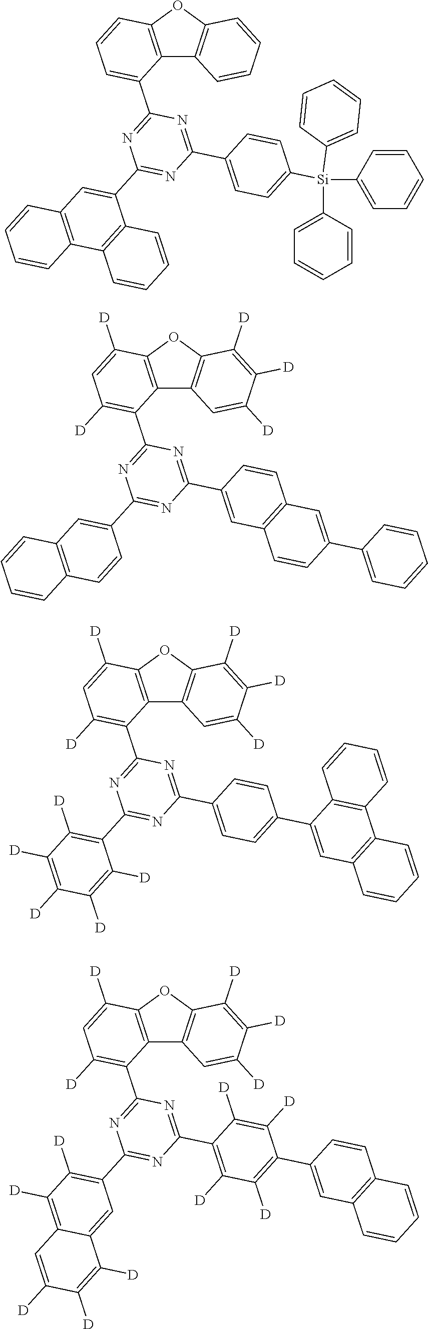

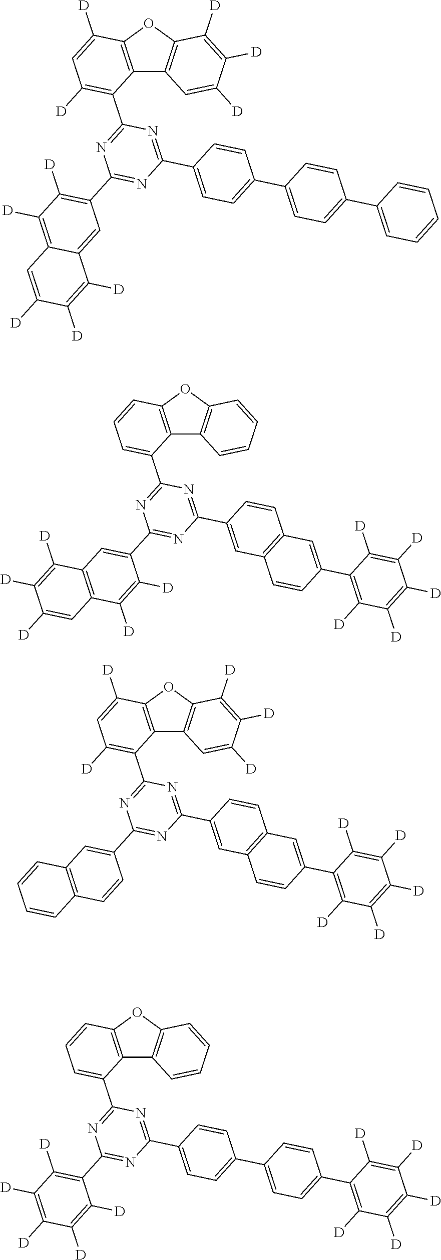

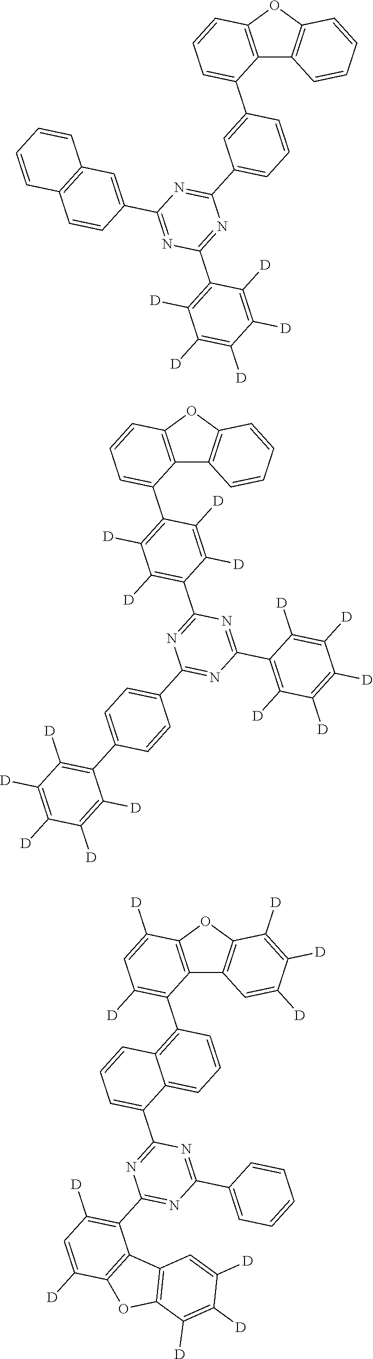 [SMILES: [2H]c1c([2H])c([2H])c(-c2nc(-c3cccc(-c4cccc5oc6ccccc6c45)c3)nc(-c3ccc4ccccc4c3)n2)c([2H])c1[2H] ; [2H]c1c([2H])c([2H])c(-c2ccc(-c3nc(-c4c([2H])c([2H])c([2H])c([2H])c4[2H])nc(-c4c([2H])c([2H])c(-c5cccc6oc7ccccc7c56)c([2H])c4[2H])n3)cc2)c([2H])c1[2H] ; [2H]c1cc2c(oc3c([2H])cc([2H])c(-c4nc(-c5ccccc5)nc(-c5cccc6c(-c7c([2H])cc([2H])c8oc9c([2H])c([2H])c([2H])cc9c78)cccc56)n4)c32)c([2H])c1[2H]]

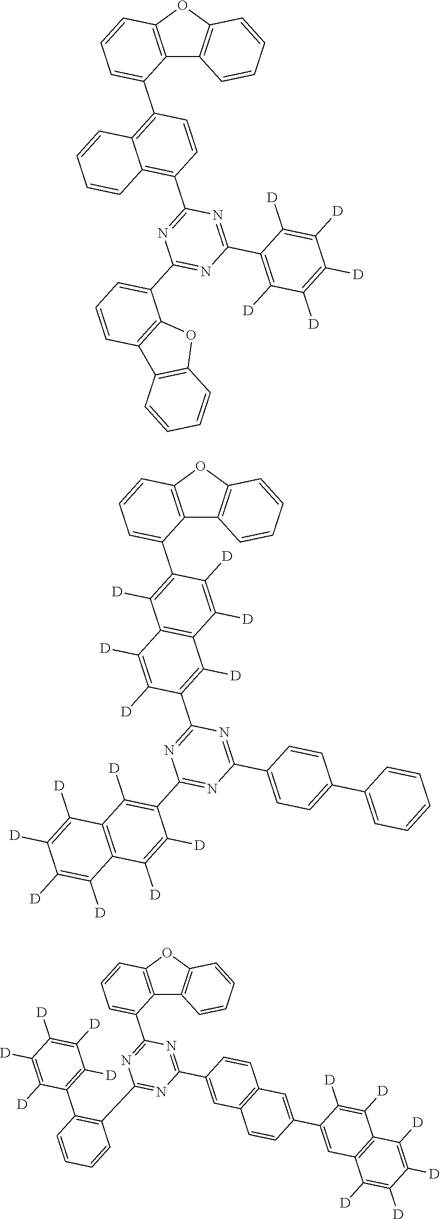

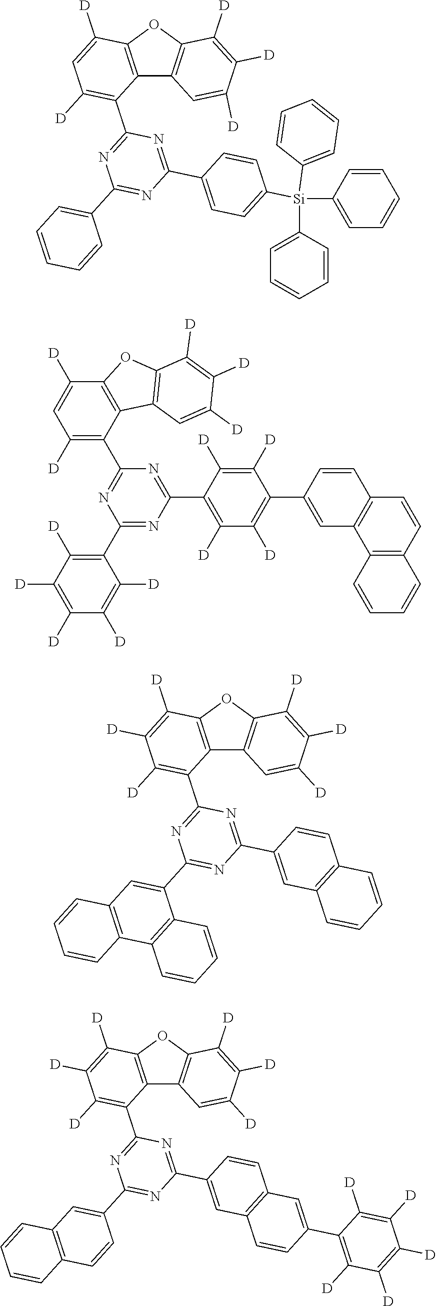

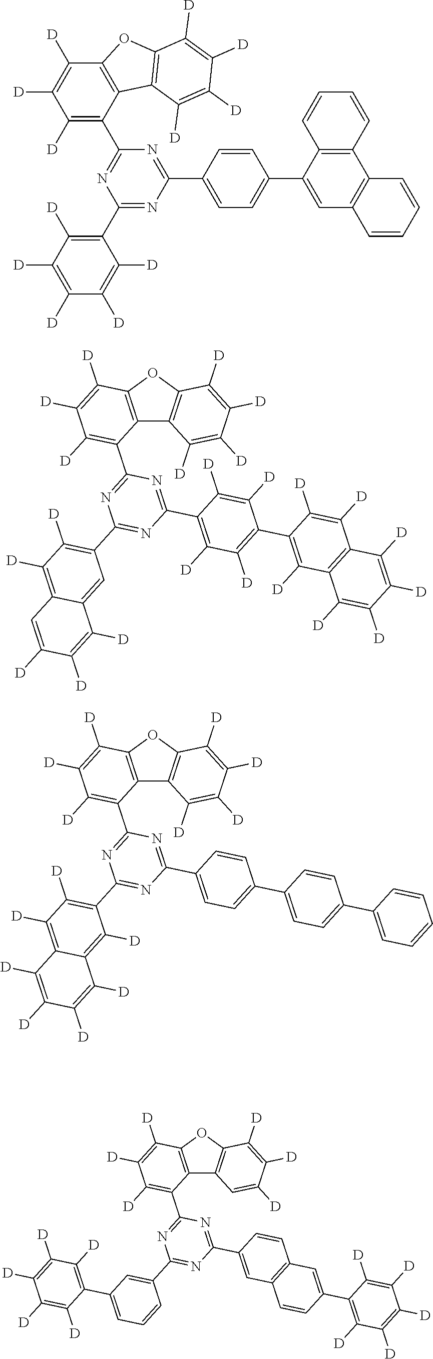

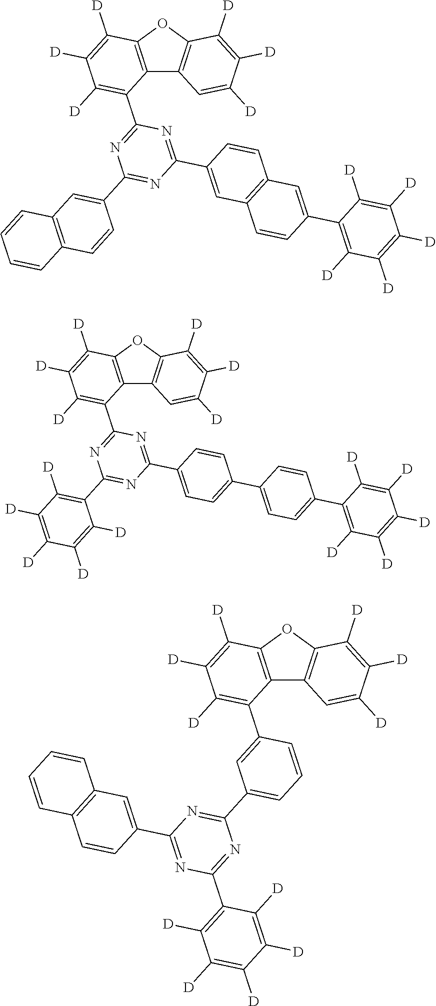 [SMILES: [2H]c1cc2c(oc3c([2H])c([2H])c([2H])c(-c4nc(-c5ccc6ccccc6c5)nc(-c5ccc6cc(-c7c([2H])c([2H])c([2H])c([2H])c7[2H])ccc6c5)n4)c32)c([2H])c1[2H] ; [2H]c1cc2c(oc3c([2H])c([2H])c([2H])c(-c4nc(-c5ccc(-c6ccc(-c7c([2H])c([2H])c([2H])c([2H])c7[2H])cc6)cc5)nc(-c5c([2H])c([2H])c([2H])c([2H])c5[2H])n4)c32)c([2H])c1[2H] ; [2H]c1cc2c(oc3c([2H])c([2H])c([2H])c(-c4cccc(-c5nc(-c6ccc7ccccc7c6)nc(-c6c([2H])c([2H])c([2H])c([2H])c6[2H])n5)c4)c32)c([2H])c1[2H]]

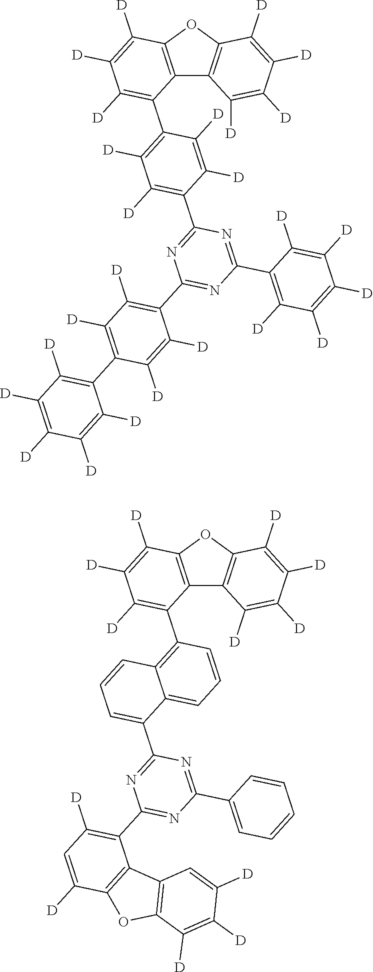 [SMILES: [2H]c1c([2H])c([2H])c(-c2nc(-c3c([2H])c([2H])c(-c4c([2H])c([2H])c([2H])c([2H])c4[2H])c([2H])c3[2H])nc(-c3c([2H])c([2H])c(-c4c([2H])c([2H])c([2H])c5oc6c([2H])c([2H])c([2H])c([2H])c6c45)c([2H])c3[2H])n2)c([2H])c1[2H] ; [2H]c1cc2c(oc3c([2H])cc([2H])c(-c4nc(-c5ccccc5)nc(-c5cccc6c(-c7c([2H])c([2H])c([2H])c8oc9c([2H])c([2H])c([2H])c([2H])c9c78)cccc56)n4)c32)c([2H])c1[2H]]

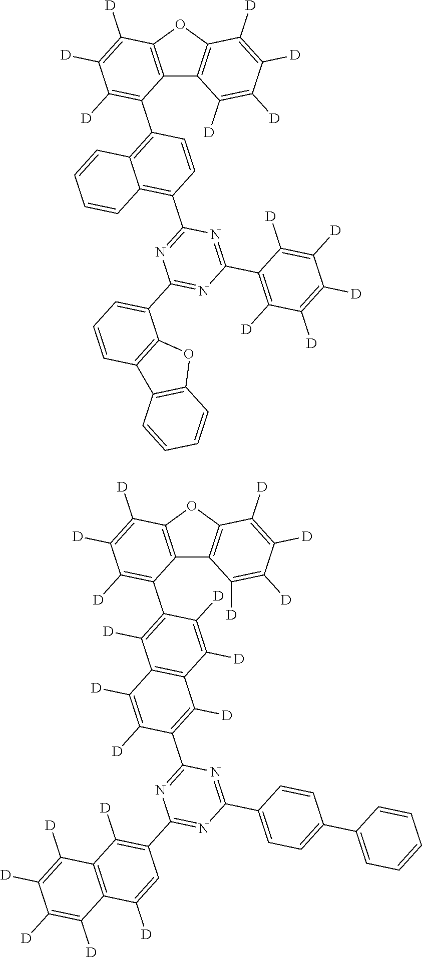 [SMILES: [2H]c1c([2H])c([2H])c(-c2nc(-c3ccc(-c4c([2H])c([2H])c([2H])c5oc6c([2H])c([2H])c([2H])c([2H])c6c45)c4ccccc34)nc(-c3cccc4c3oc3ccccc34)n2)c([2H])c1[2H] ; [2H]c1c([2H])c([2H])c2c(oc3c([2H])c([2H])c([2H])c(-c4c([2H])c([2H])c5c([2H])c(-c6nc(-c7ccc(-c8ccccc8)cc7)nc(-c7cc([2H])c8c([2H])c([2H])c([2H])c([2H])c8c7[2H])n6)c([2H])c([2H])c5c4[2H])c32)c1[2H]]

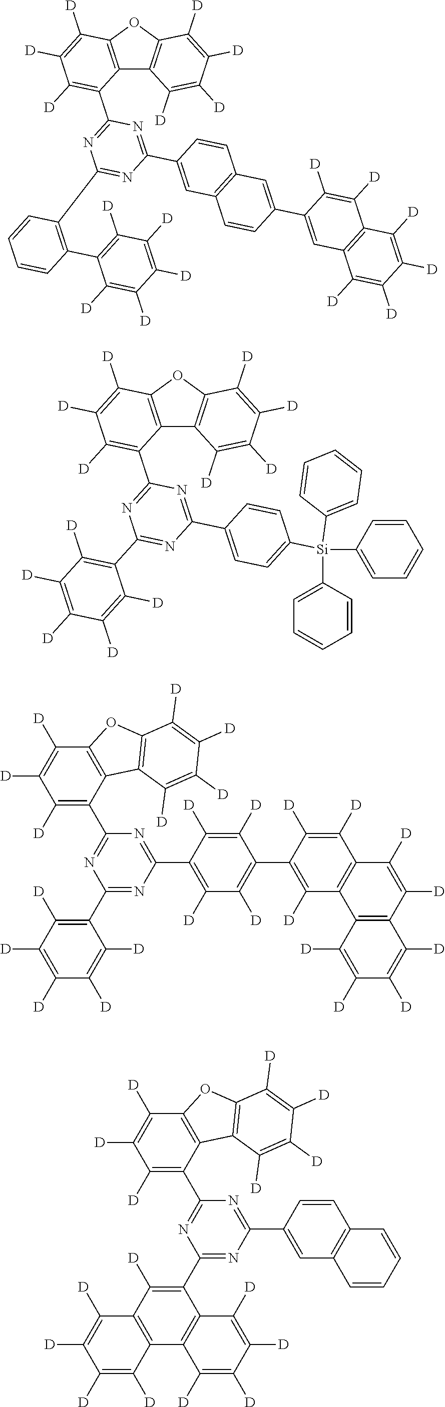

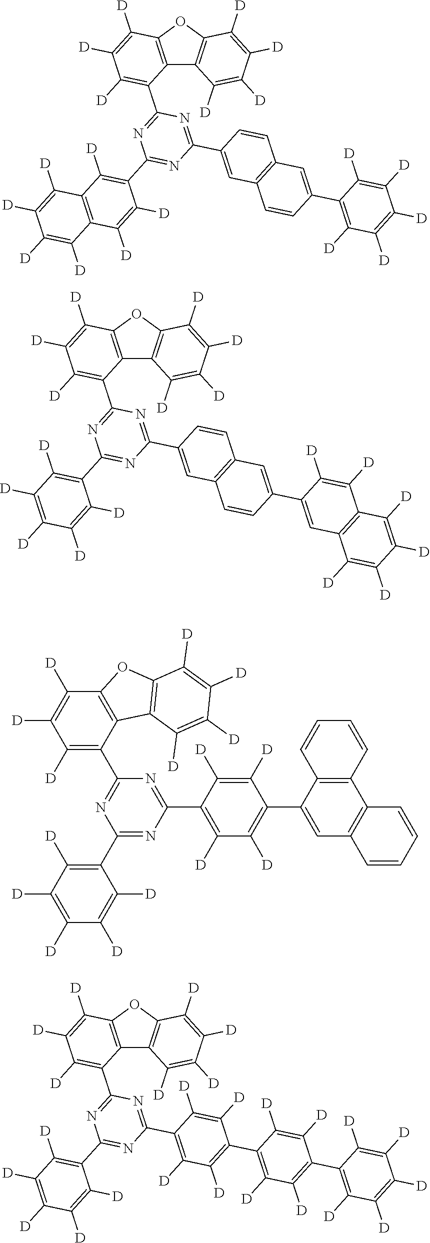

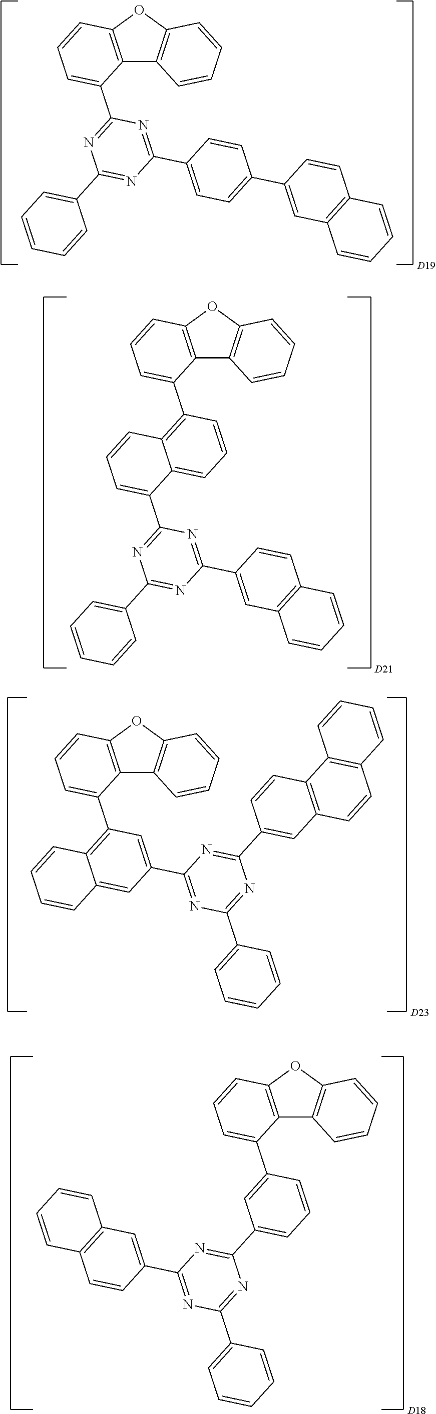

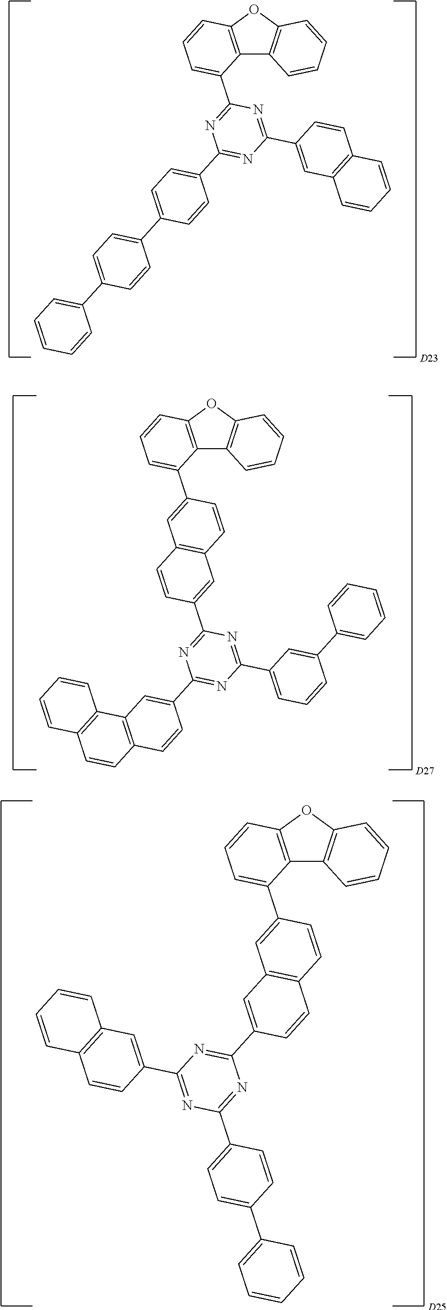

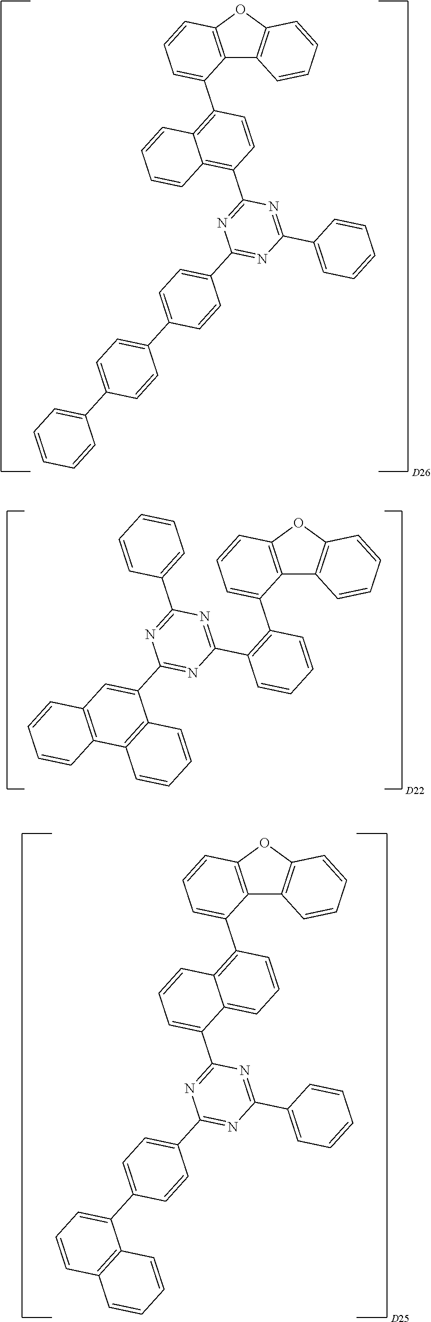

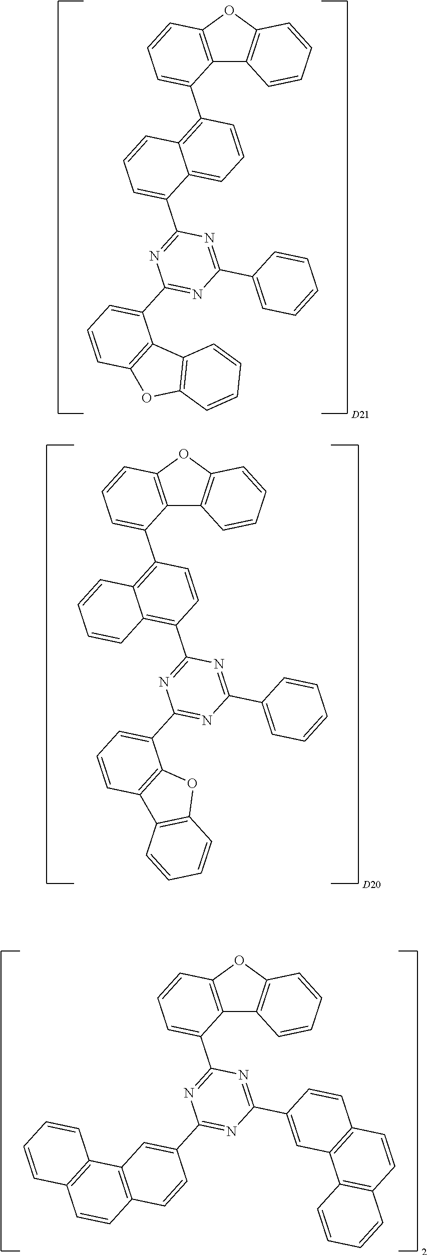

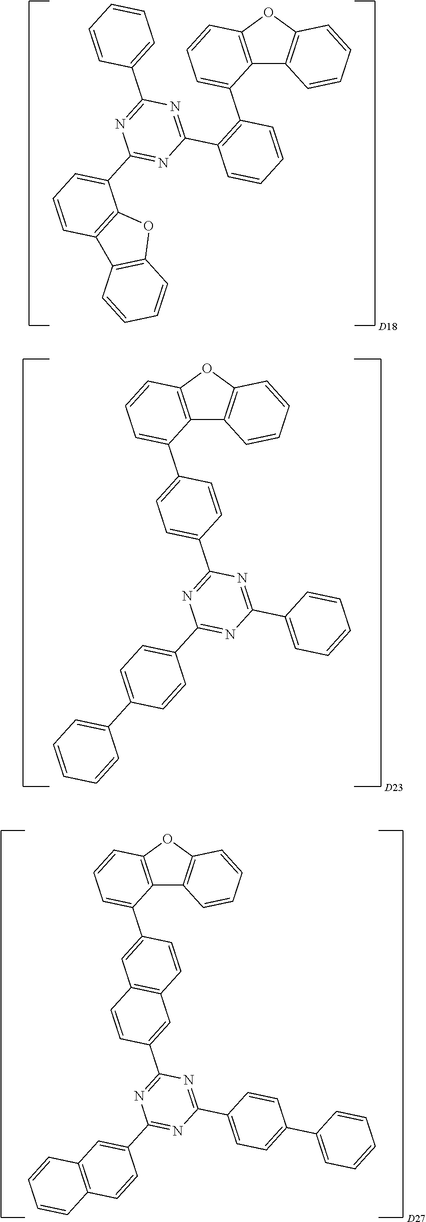

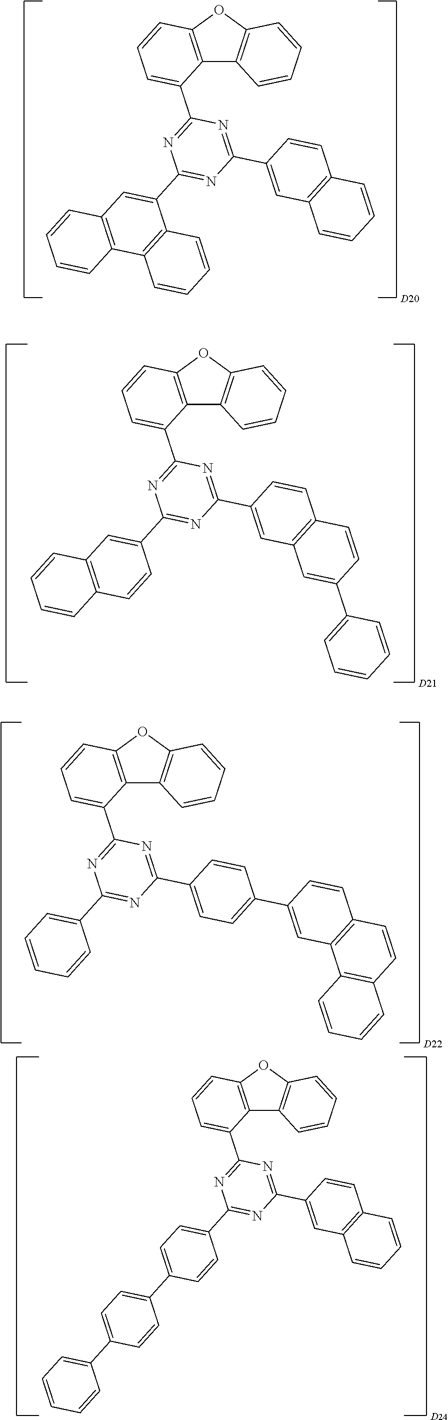

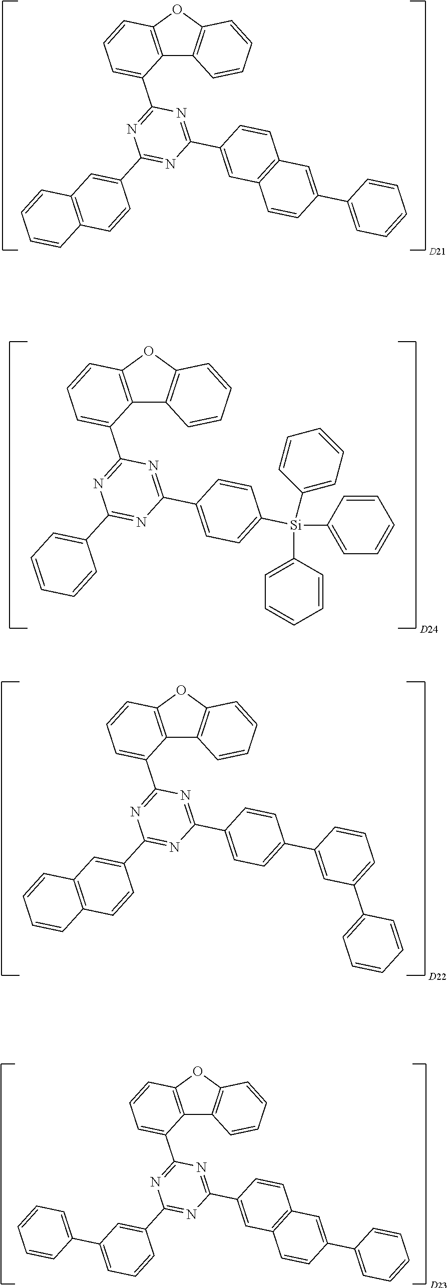

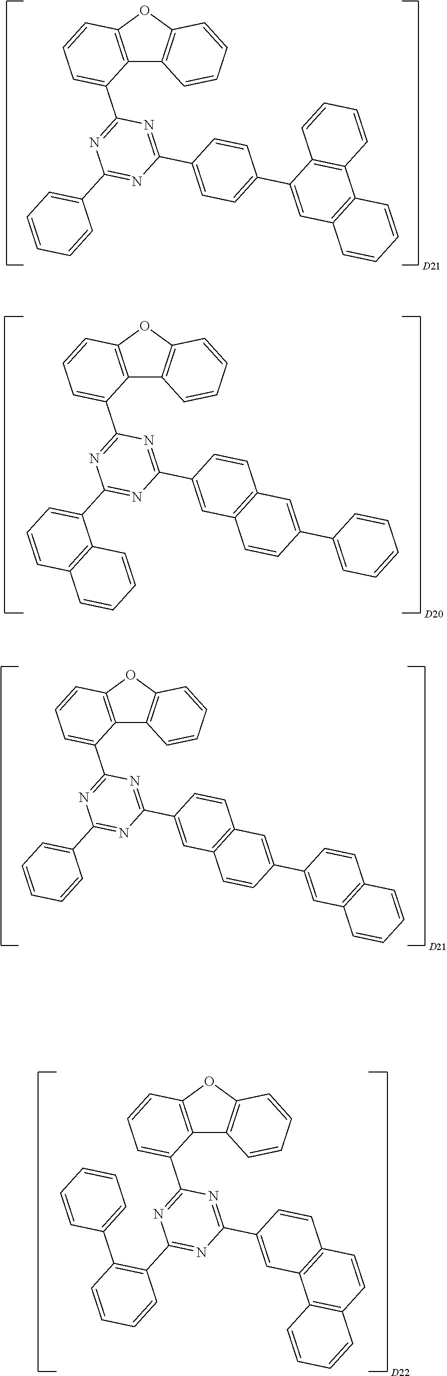

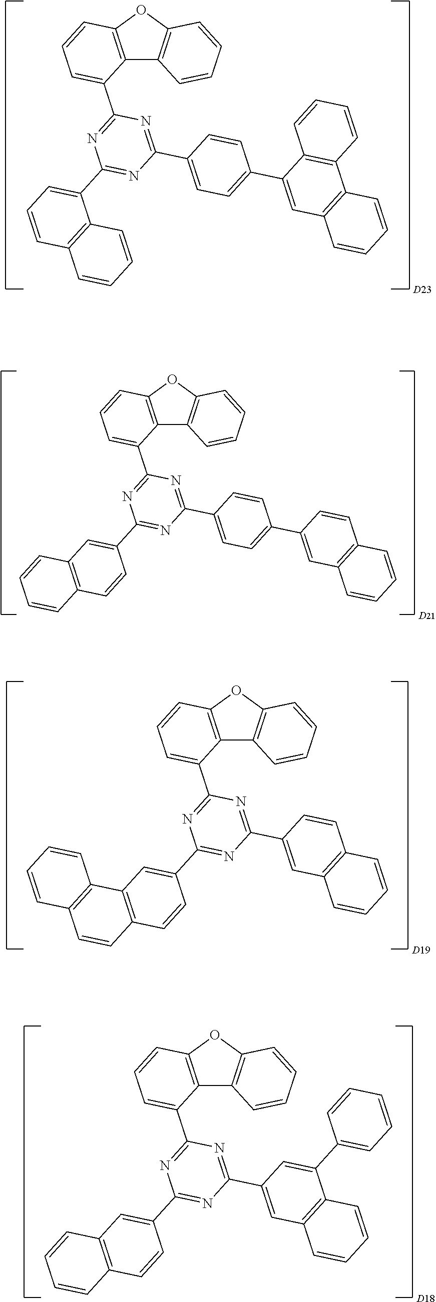

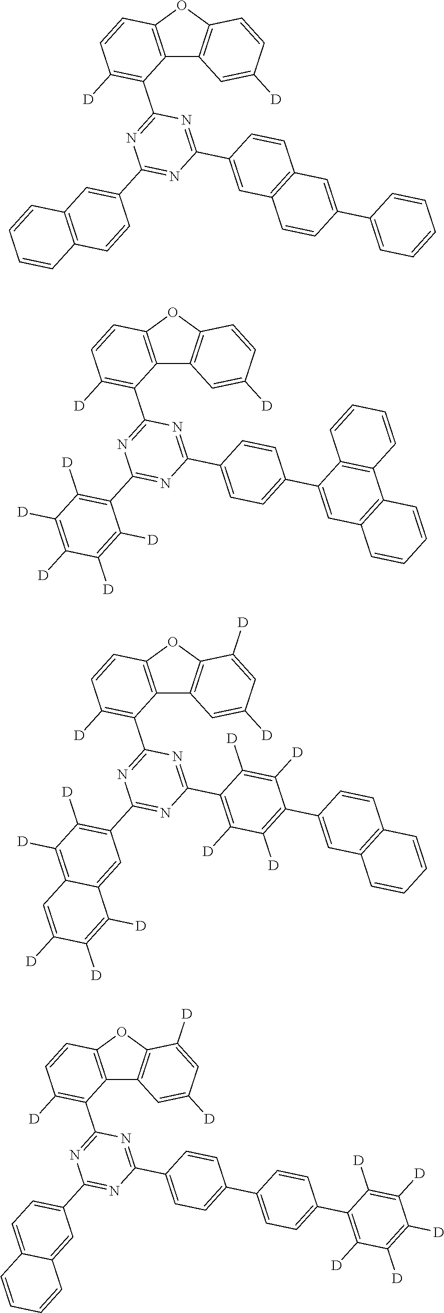 [SMILES: [2H]c1ccc2oc3ccc([2H])c(-c4nc(-c5ccc6ccccc6c5)nc(-c5ccc6cc(-c7ccccc7)ccc6c5)n4)c3c2c1 ; [2H]c1ccc2oc3ccc([2H])c(-c4nc(-c5ccc(-c6cc7ccccc7c7ccccc67)cc5)nc(-c5c([2H])c([2H])c([2H])c([2H])c5[2H])n4)c3c2c1 ; [2H]c1cc([2H])c2oc3ccc([2H])c(-c4nc(-c5cc6c([2H])c([2H])c([2H])cc6c([2H])c5[2H])nc(-c5c([2H])c([2H])c(-c6ccc7ccccc7c6)c([2H])c5[2H])n4)c3c2c1 ; [2H]c1cc([2H])c2oc3ccc([2H])c(-c4nc(-c5ccc(-c6ccc(-c7c([2H])c([2H])c([2H])c([2H])c7[2H])cc6)cc5)nc(-c5ccc6ccccc6c5)n4)c3c2c1]

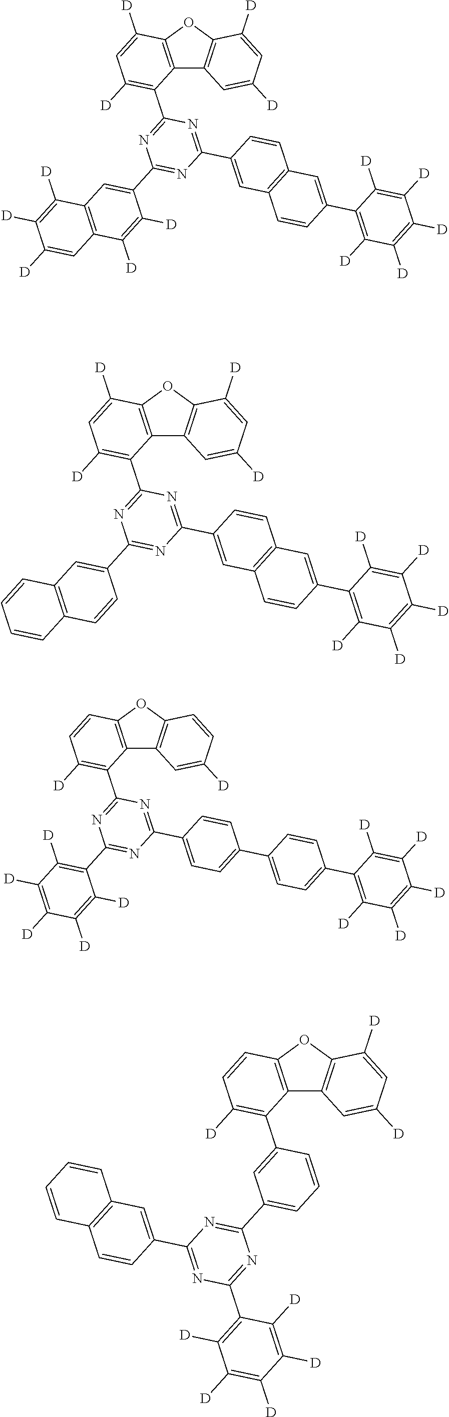

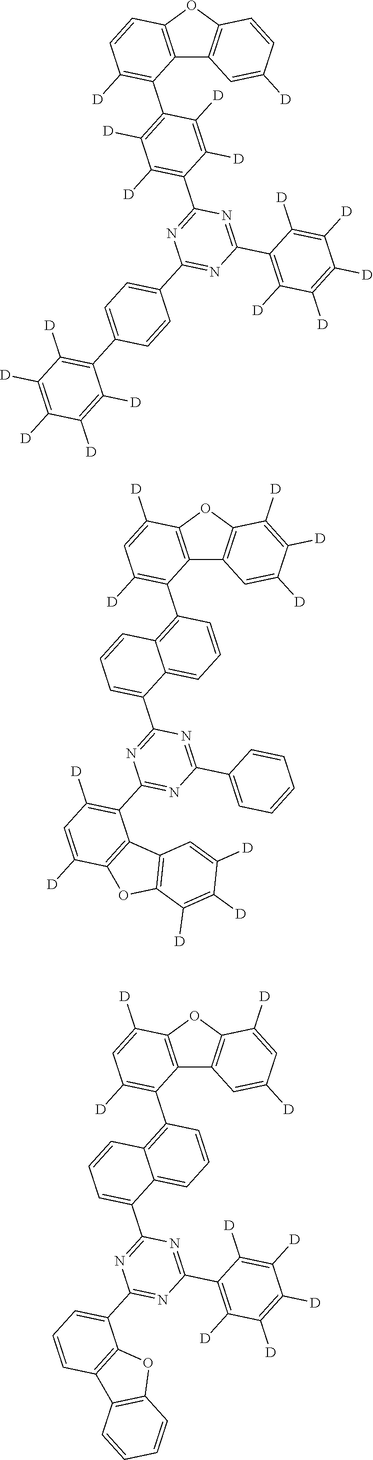 [SMILES: [2H]c1ccc2oc3ccc([2H])c(-c4c([2H])c([2H])c(-c5nc(-c6ccc(-c7c([2H])c([2H])c([2H])c([2H])c7[2H])cc6)nc(-c6c([2H])c([2H])c([2H])c([2H])c6[2H])n5)c([2H])c4[2H])c3c2c1 ; [2H]c1cc2c(oc3c([2H])cc([2H])c(-c4nc(-c5ccccc5)nc(-c5cccc6c(-c7c([2H])cc([2H])c8oc9c([2H])c([2H])c([2H])cc9c78)cccc56)n4)c32)c([2H])c1[2H] ; [2H]c1cc([2H])c2oc3c([2H])cc([2H])c(-c4cccc5c(-c6nc(-c7c([2H])c([2H])c([2H])c([2H])c7[2H])nc(-c7cccc8c7oc7ccccc78)n6)cccc45)c3c2c1]

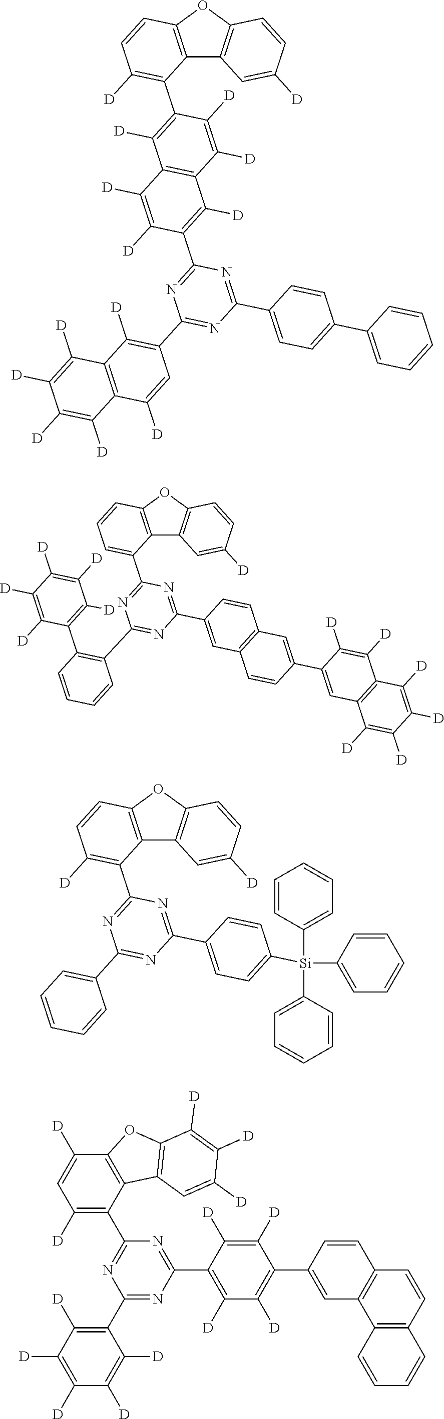

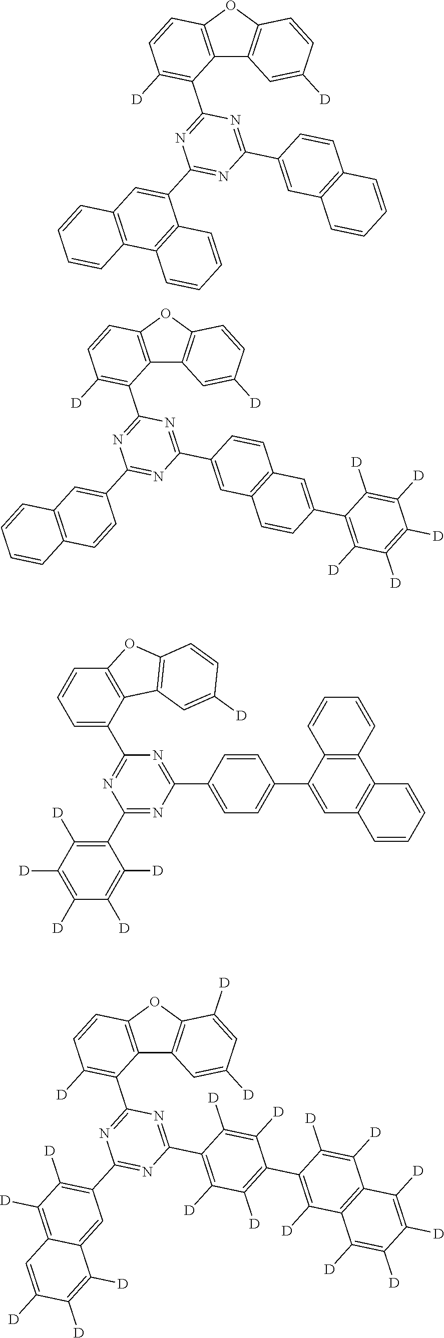

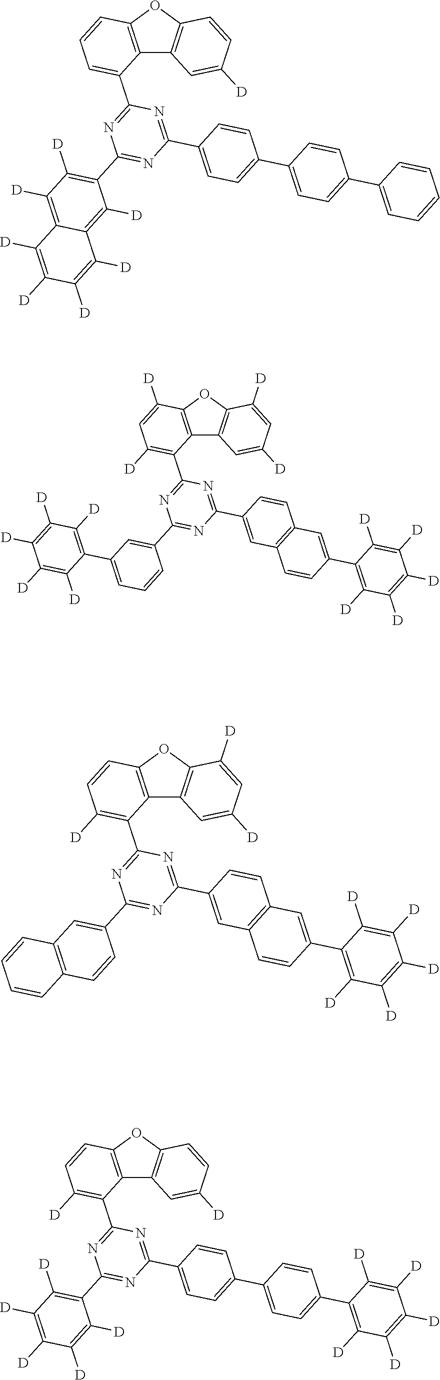

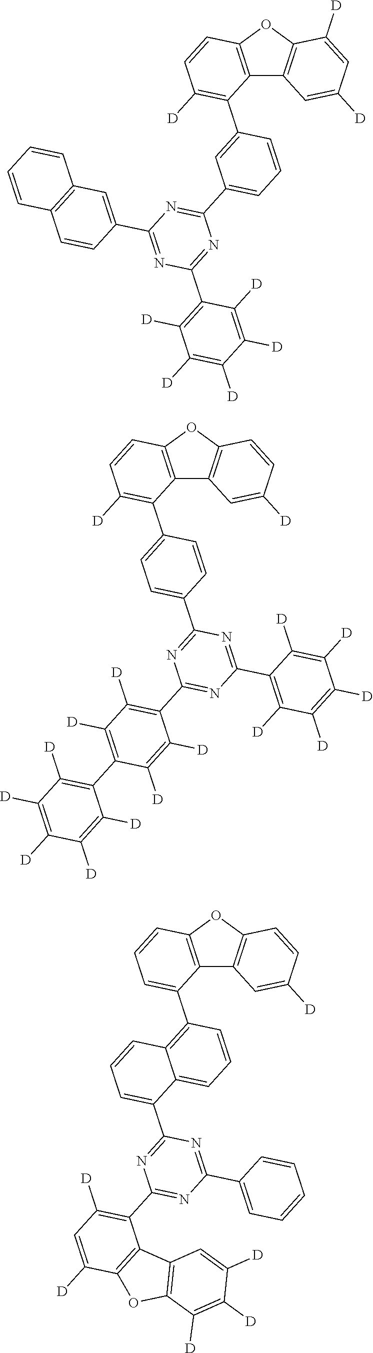 [SMILES: [2H]c1cc([2H])c2oc3ccc([2H])c(-c4cccc(-c5nc(-c6ccc7ccccc7c6)nc(-c6c([2H])c([2H])c([2H])c([2H])c6[2H])n5)c4)c3c2c1 ; [2H]c1ccc2oc3ccc([2H])c(-c4ccc(-c5nc(-c6c([2H])c([2H])c([2H])c([2H])c6[2H])nc(-c6c([2H])c([2H])c(-c7c([2H])c([2H])c([2H])c([2H])c7[2H])c([2H])c6[2H])n5)cc4)c3c2c1 ; [2H]c1ccc2oc3cccc(-c4cccc5c(-c6nc(-c7ccccc7)nc(-c7c([2H])cc([2H])c8oc9c([2H])c([2H])c([2H])cc9c78)n6)cccc45)c3c2c1]

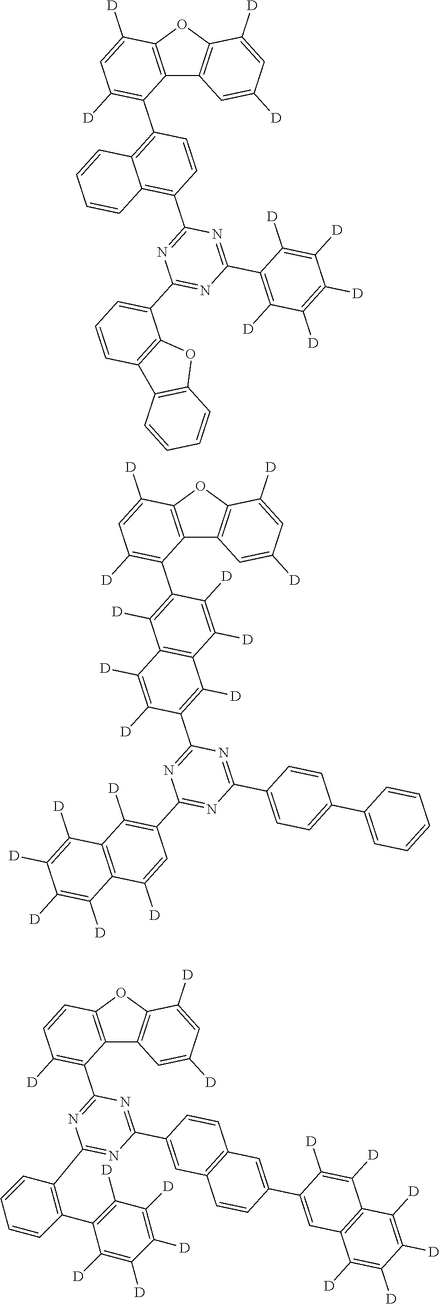

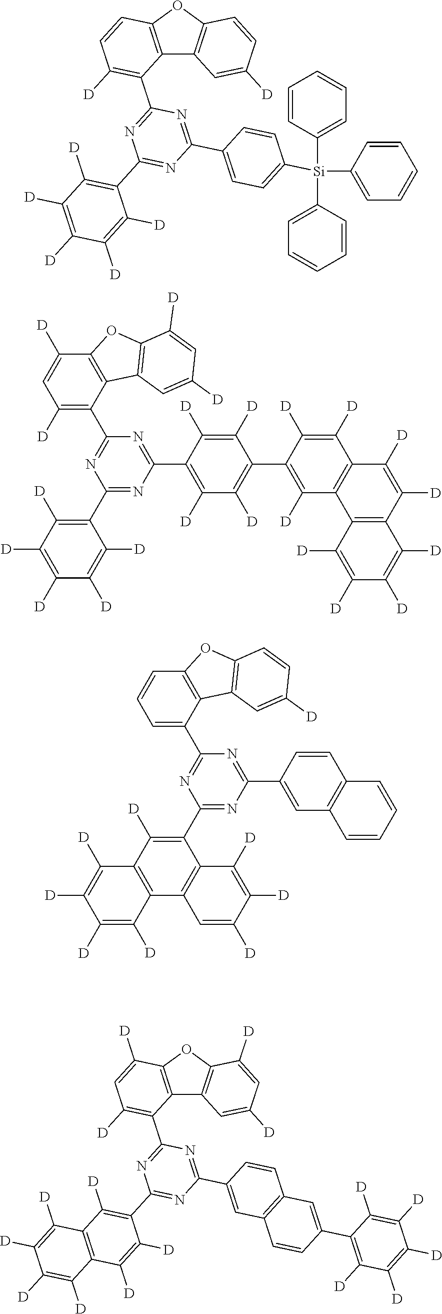

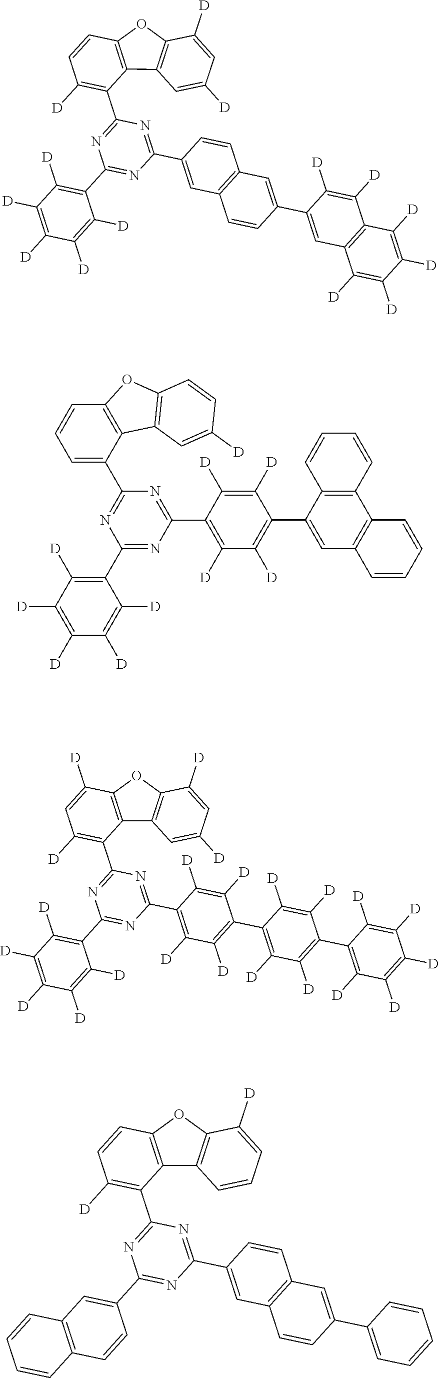

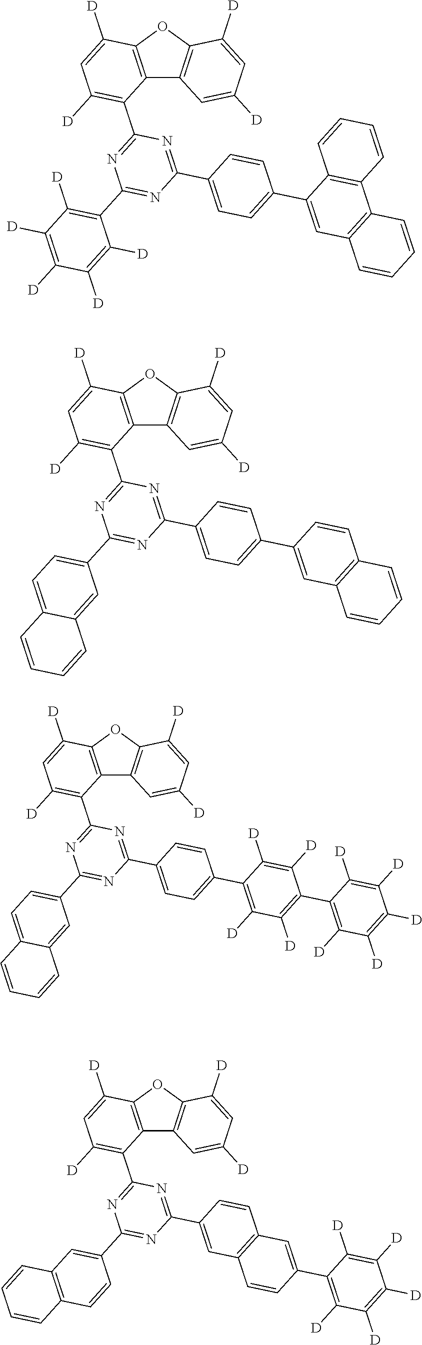

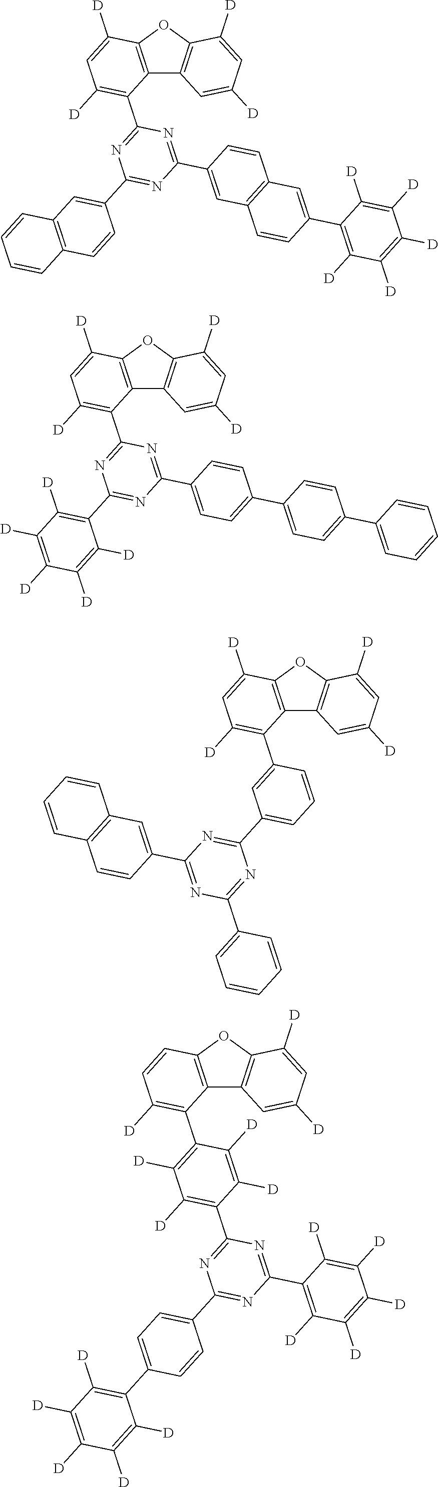

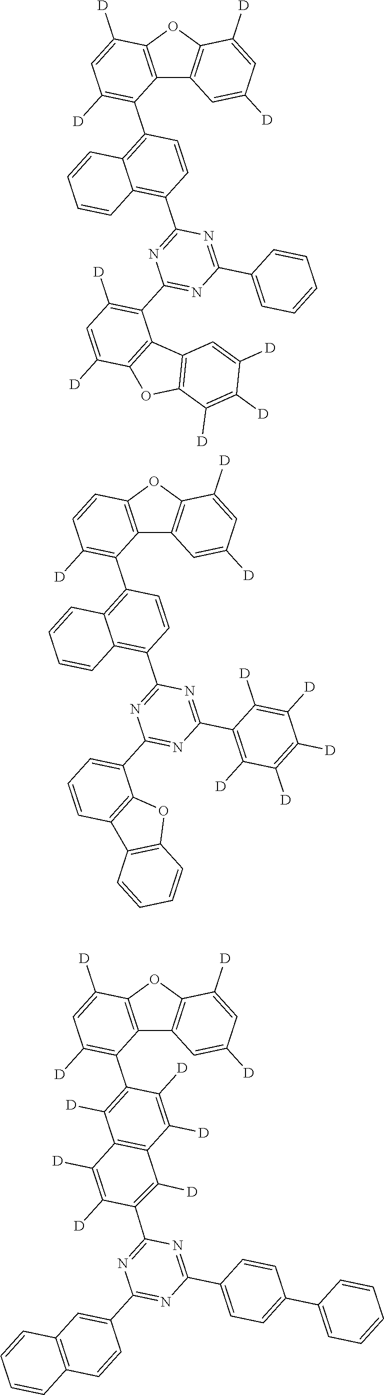

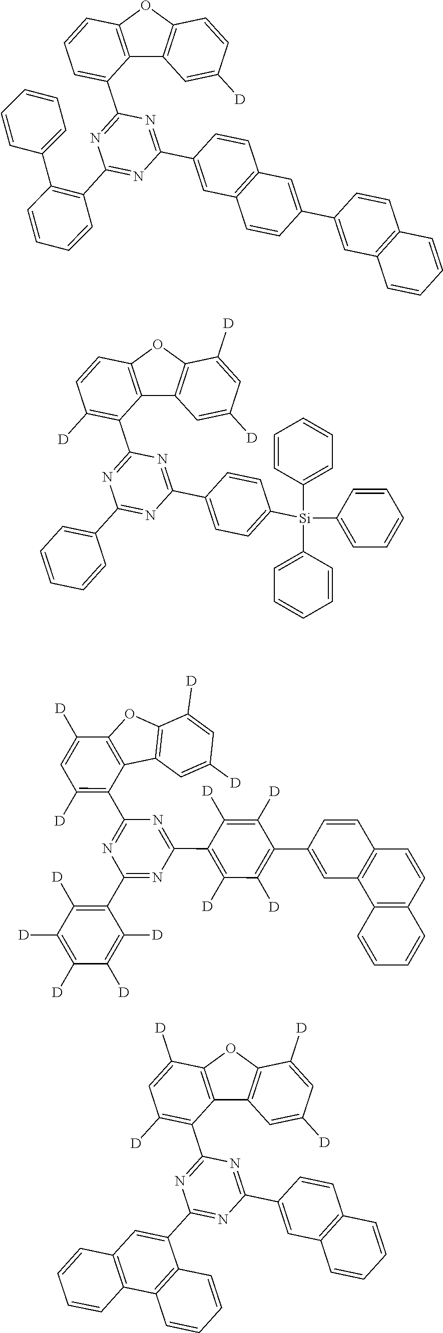 [SMILES: [2H]c1ccc2oc3cccc(-c4nc(-c5ccc6cc(-c7ccc8ccccc8c7)ccc6c5)nc(-c5ccccc5-c5ccccc5)n4)c3c2c1 ; [2H]c1cc([2H])c2oc3ccc([2H])c(-c4nc(-c5ccccc5)nc(-c5ccc([Si](c6ccccc6)(c6ccccc6)c6ccccc6)cc5)n4)c3c2c1 ; [2H]c1cc([2H])c2oc3c([2H])cc([2H])c(-c4nc(-c5c([2H])c([2H])c([2H])c([2H])c5[2H])nc(-c5c([2H])c([2H])c(-c6ccc7ccc8ccccc8c7c6)c([2H])c5[2H])n4)c3c2c1 ; [2H]c1cc([2H])c2oc3c([2H])cc([2H])c(-c4nc(-c5ccc6ccccc6c5)nc(-c5cc6ccccc6c6ccccc56)n4)c3c2c1]

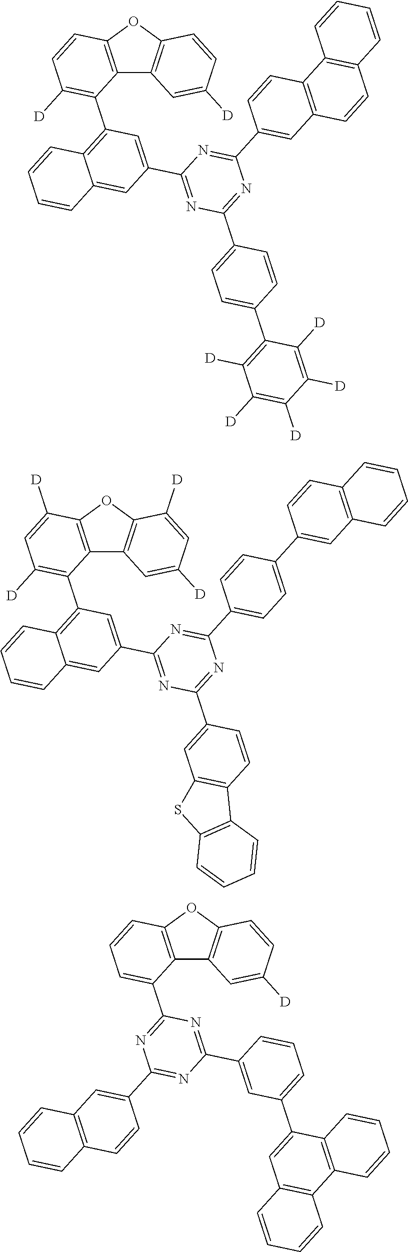

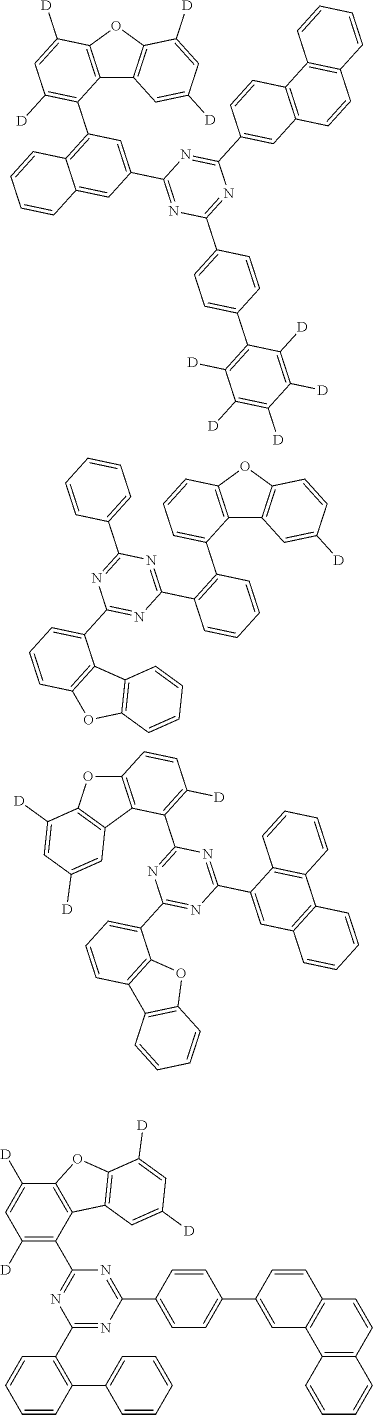

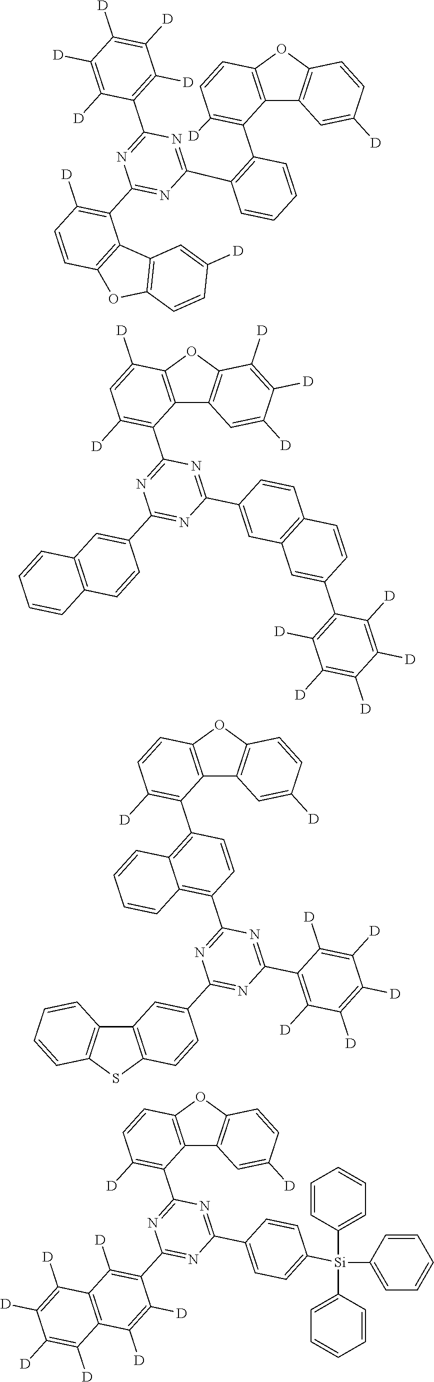

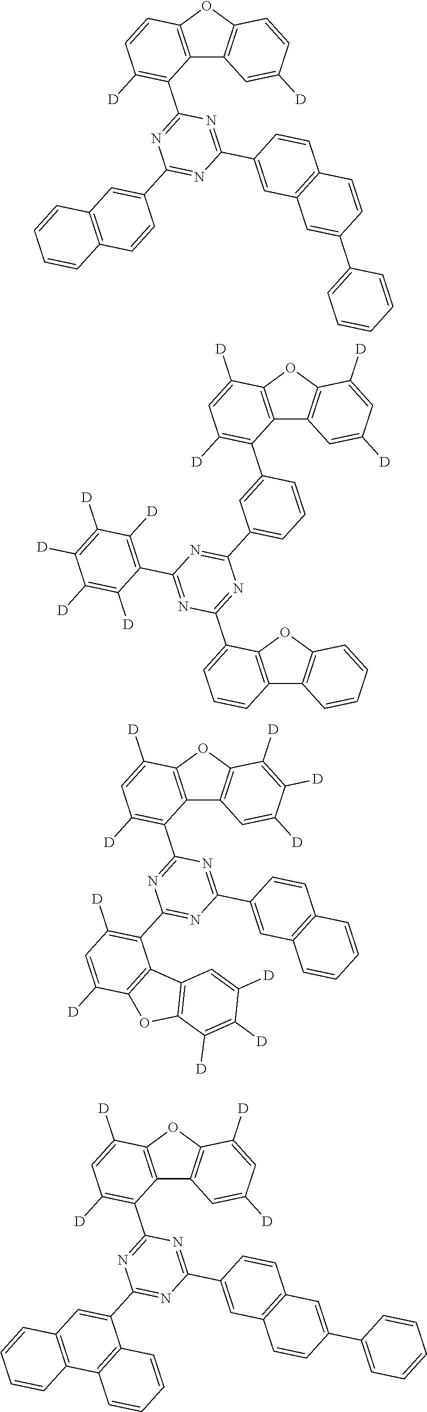

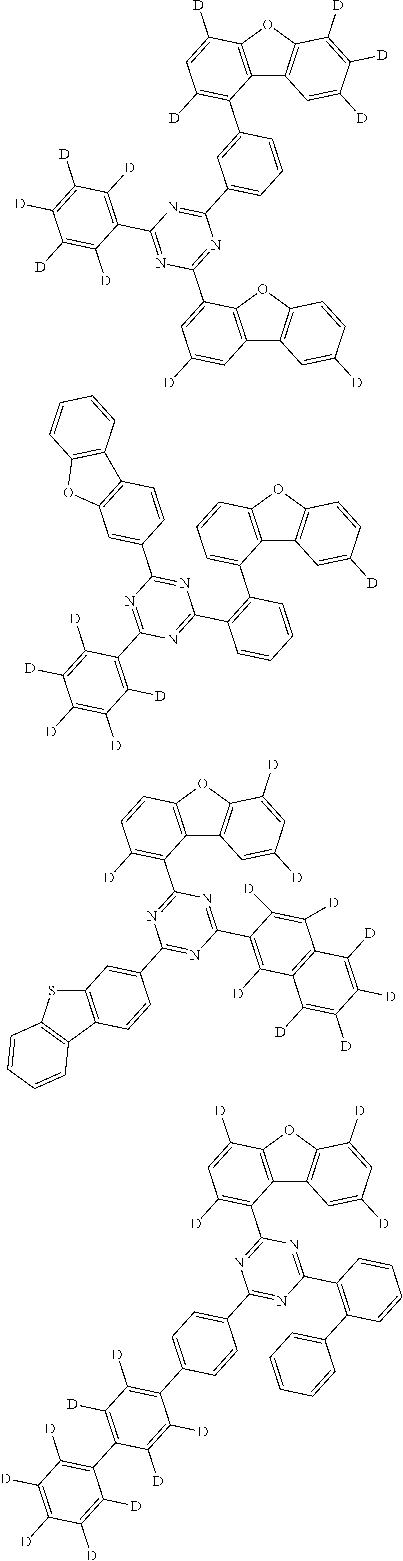

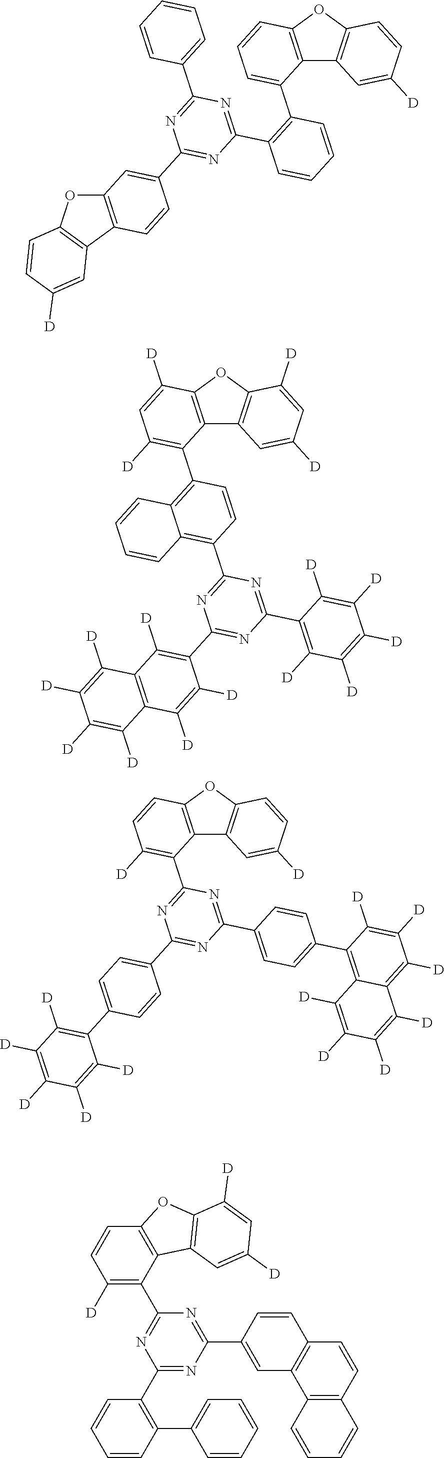

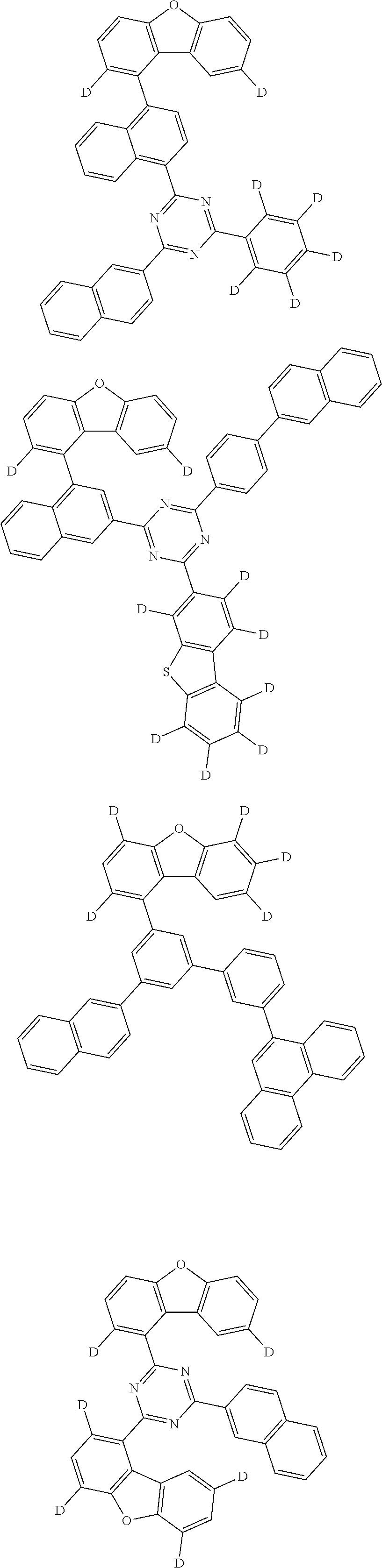 [SMILES: [2H]c1ccc2oc3ccc([2H])c(-c4ccc(-c5nc(-c6ccc7ccccc7c6)nc(-c6c([2H])c([2H])c([2H])c([2H])c6[2H])n5)c5ccccc45)c3c2c1 ; [2H]c1ccc2oc3ccc([2H])c(-c4cc(-c5nc(-c6ccc(-c7ccc8ccccc8c7)cc6)nc(-c6c([2H])c([2H])c7c(sc8c([2H])c([2H])c([2H])c([2H])c87)c6[2H])n5)cc5ccccc45)c3c2c1 ; [2H]c1cc2c(oc3c([2H])cc([2H])c(-c4cc(-c5cccc(-c6cc7ccccc7c7ccccc67)c5)cc(-c5ccc6ccccc6c5)c4)c32)c([2H])c1[2H] ; [2H]c1ccc2oc3ccc([2H])c(-c4nc(-c5ccc6ccccc6c5)nc(-c5c([2H])cc([2H])c6oc7c([2H])cc([2H])cc7c56)n4)c3c2c1]

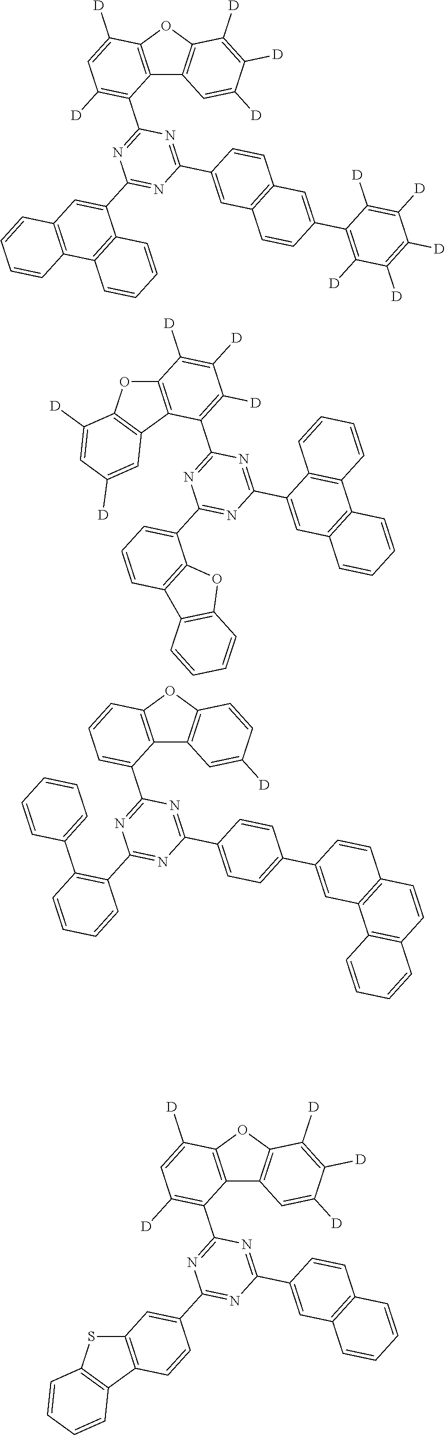

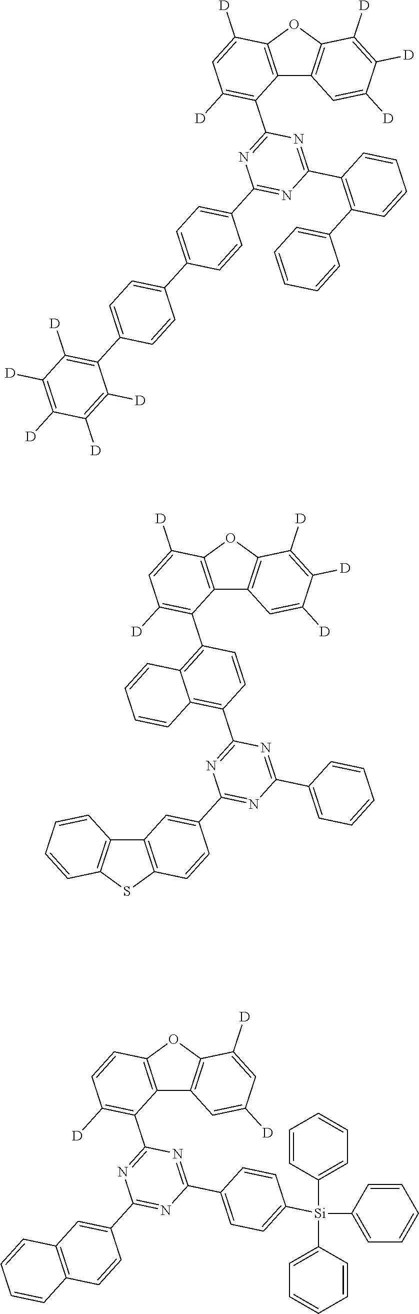 [SMILES: [2H]c1cc2c(oc3c([2H])cc([2H])c(-c4nc(-c5ccc(-c6ccc(-c7c([2H])c([2H])c([2H])c([2H])c7[2H])cc6)cc5)nc(-c5ccccc5-c5ccccc5)n4)c32)c([2H])c1[2H] ; [2H]c1cc2c(oc3c([2H])cc([2H])c(-c4ccc(-c5nc(-c6ccccc6)nc(-c6ccc7sc8ccccc8c7c6)n5)c5ccccc45)c32)c([2H])c1[2H] ; [2H]c1cc([2H])c2oc3ccc([2H])c(-c4nc(-c5ccc([Si](c6ccccc6)(c6ccccc6)c6ccccc6)cc5)nc(-c5ccc6ccccc6c5)n4)c3c2c1]

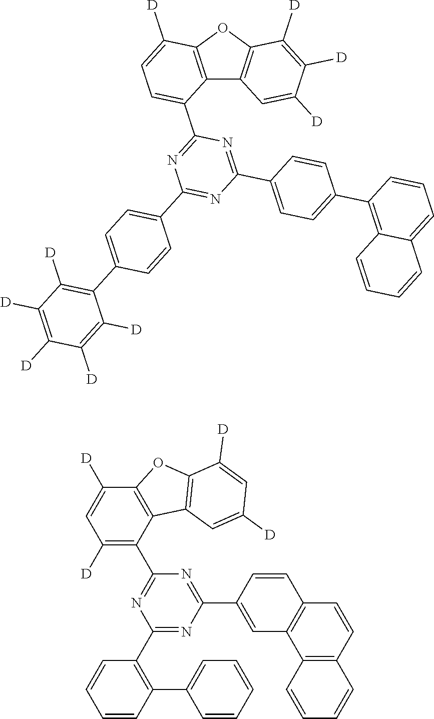 [SMILES: [2H]c1cc2c(oc3c([2H])ccc(-c4nc(-c5ccc(-c6c([2H])c([2H])c([2H])c([2H])c6[2H])cc5)nc(-c5ccc(-c6cccc7ccccc67)cc5)n4)c32)c([2H])c1[2H] ; [2H]c1cc([2H])c2oc3c([2H])cc([2H])c(-c4nc(-c5ccc6ccc7ccccc7c6c5)nc(-c5ccccc5-c5ccccc5)n4)c3c2c1]

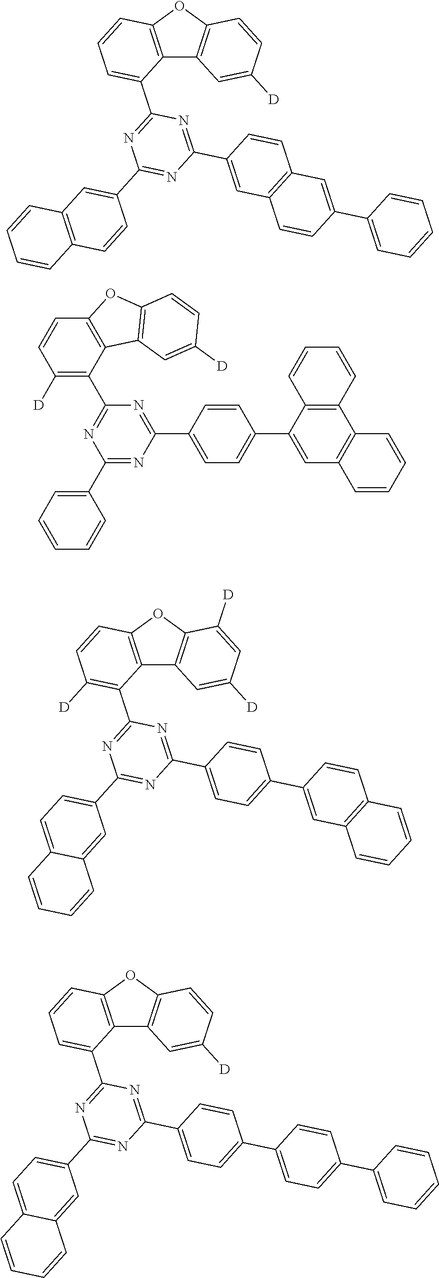

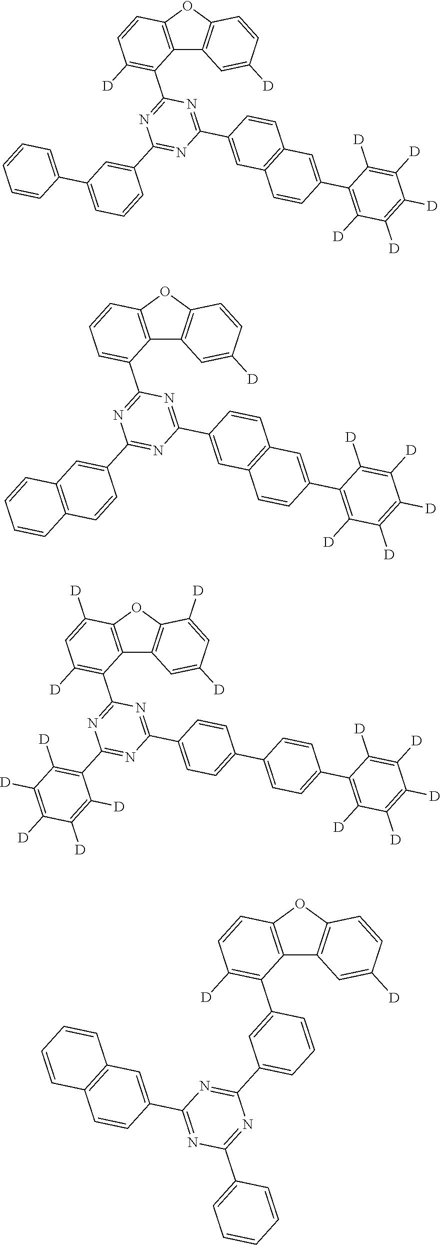 [SMILES: [2H]c1ccc2oc3ccc([2H])c(-c4nc(-c5cccc(-c6ccccc6)c5)nc(-c5ccc6cc(-c7c([2H])c([2H])c([2H])c([2H])c7[2H])ccc6c5)n4)c3c2c1 ; [2H]c1ccc2oc3cccc(-c4nc(-c5ccc6ccccc6c5)nc(-c5ccc6cc(-c7c([2H])c([2H])c([2H])c([2H])c7[2H])ccc6c5)n4)c3c2c1 ; [2H]c1cc([2H])c2oc3c([2H])cc([2H])c(-c4nc(-c5ccc(-c6ccc(-c7c([2H])c([2H])c([2H])c([2H])c7[2H])cc6)cc5)nc(-c5c([2H])c([2H])c([2H])c([2H])c5[2H])n4)c3c2c1 ; [2H]c1ccc2oc3ccc([2H])c(-c4cccc(-c5nc(-c6ccccc6)nc(-c6ccc7ccccc7c6)n5)c4)c3c2c1]

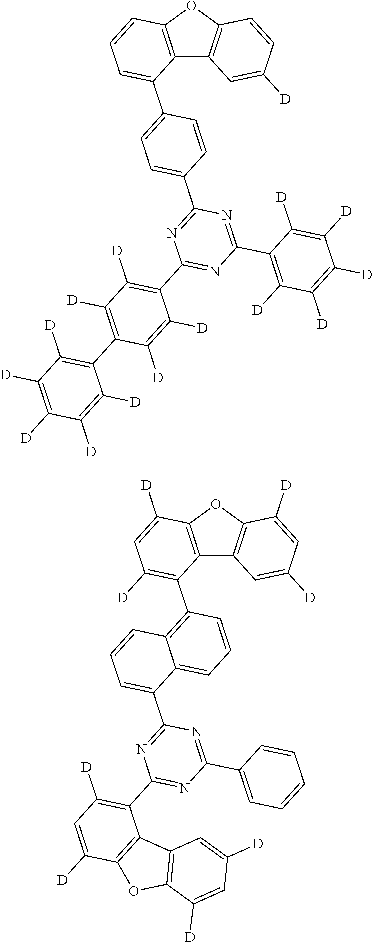 [SMILES: [2H]c1ccc2oc3cccc(-c4ccc(-c5nc(-c6c([2H])c([2H])c([2H])c([2H])c6[2H])nc(-c6c([2H])c([2H])c(-c7c([2H])c([2H])c([2H])c([2H])c7[2H])c([2H])c6[2H])n5)cc4)c3c2c1 ; [2H]c1cc([2H])c2oc3c([2H])cc([2H])c(-c4nc(-c5ccccc5)nc(-c5cccc6c(-c7c([2H])cc([2H])c8oc9c([2H])cc([2H])cc9c78)cccc56)n4)c3c2c1]

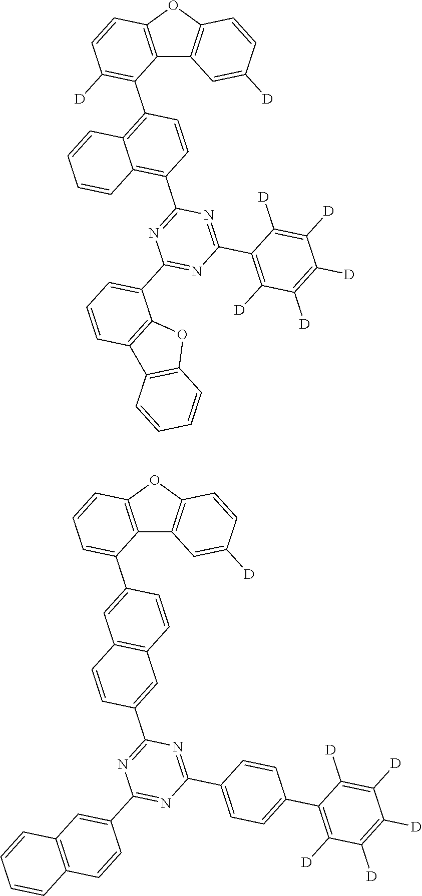 [SMILES: [2H]c1ccc2oc3ccc([2H])c(-c4ccc(-c5nc(-c6c([2H])c([2H])c([2H])c([2H])c6[2H])nc(-c6cccc7c6oc6ccccc67)n5)c5ccccc45)c3c2c1 ; [2H]c1ccc2oc3cccc(-c4ccc5cc(-c6nc(-c7ccc(-c8c([2H])c([2H])c([2H])c([2H])c8[2H])cc7)nc(-c7ccc8ccccc8c7)n6)ccc5c4)c3c2c1]

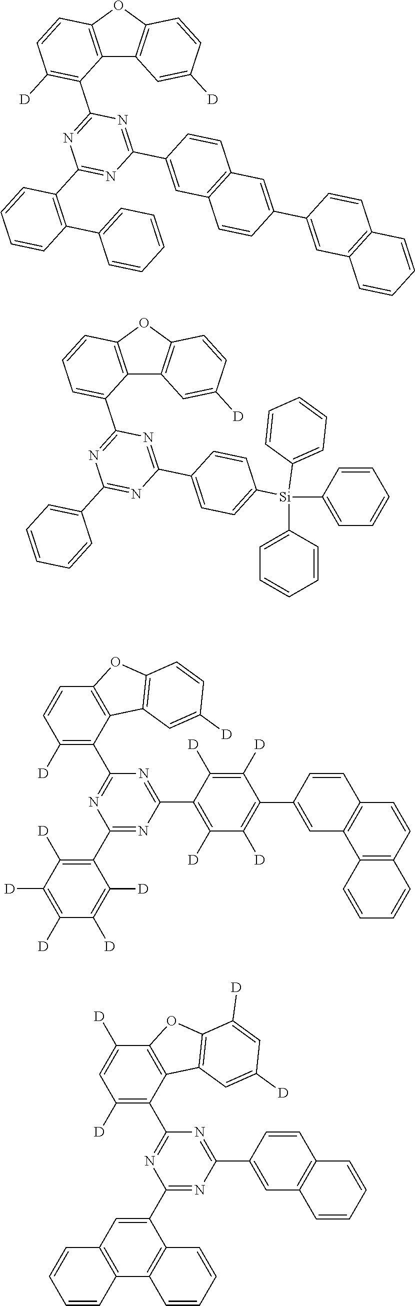 [SMILES: [2H]c1ccc2oc3ccc([2H])c(-c4nc(-c5ccc6cc(-c7ccc8ccccc8c7)ccc6c5)nc(-c5ccccc5-c5ccccc5)n4)c3c2c1 ; [2H]c1ccc2oc3cccc(-c4nc(-c5ccccc5)nc(-c5ccc([Si](c6ccccc6)(c6ccccc6)c6ccccc6)cc5)n4)c3c2c1 ; [2H]c1ccc2oc3ccc([2H])c(-c4nc(-c5c([2H])c([2H])c([2H])c([2H])c5[2H])nc(-c5c([2H])c([2H])c(-c6ccc7ccc8ccccc8c7c6)c([2H])c5[2H])n4)c3c2c1 ; [2H]c1cc([2H])c2oc3c([2H])cc([2H])c(-c4nc(-c5ccc6ccccc6c5)nc(-c5cc6ccccc6c6ccccc56)n4)c3c2c1]

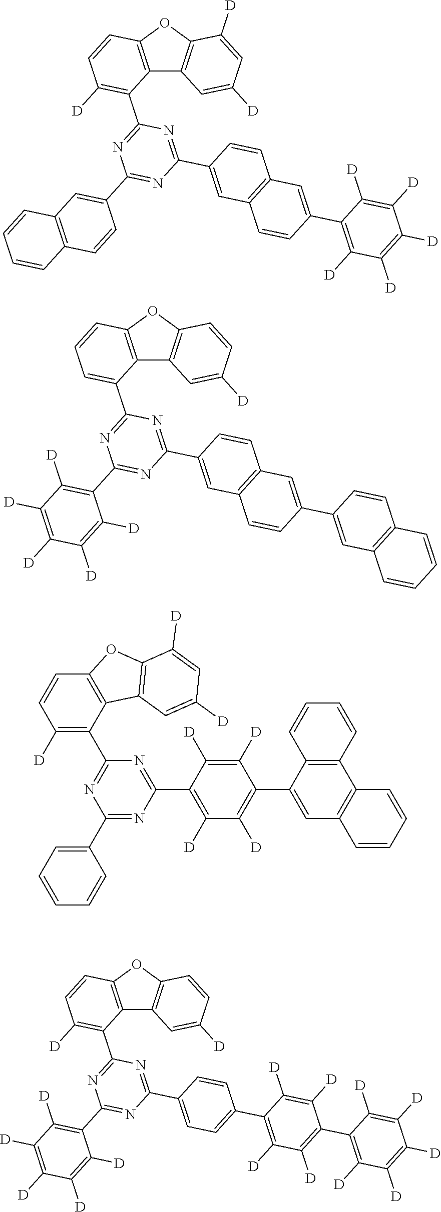

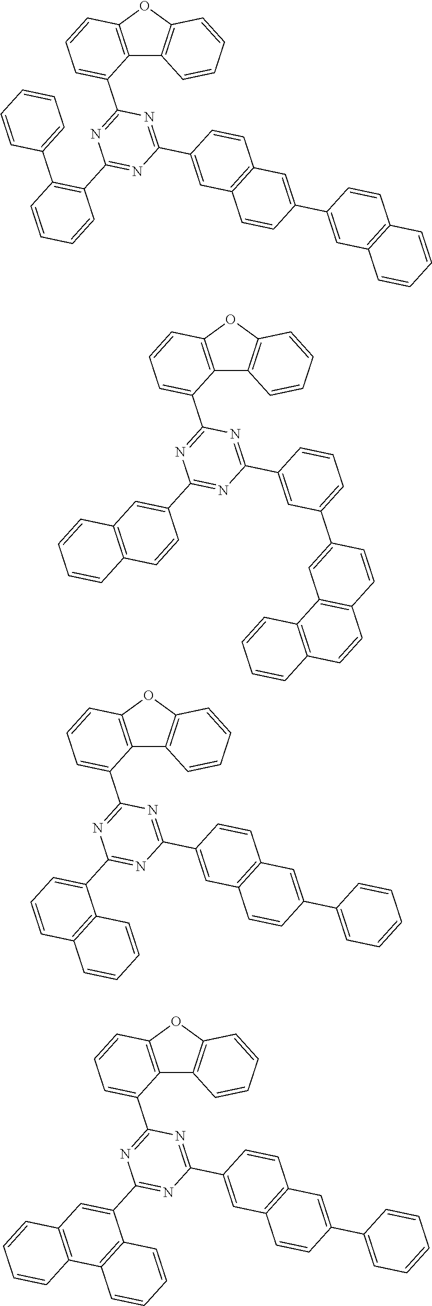 [SMILES: c1ccc(-c2ccccc2-c2nc(-c3ccc4cc(-c5ccc6ccccc6c5)ccc4c3)nc(-c3cccc4oc5ccccc5c34)n2)cc1 ; c1cc(-c2ccc3ccc4ccccc4c3c2)cc(-c2nc(-c3ccc4ccccc4c3)nc(-c3cccc4oc5ccccc5c34)n2)c1 ; c1ccc(-c2ccc3cc(-c4nc(-c5cccc6ccccc56)nc(-c5cccc6oc7ccccc7c56)n4)ccc3c2)cc1 ; c1ccc(-c2ccc3cc(-c4nc(-c5cc6ccccc6c6ccccc56)nc(-c5cccc6oc7ccccc7c56)n4)ccc3c2)cc1]

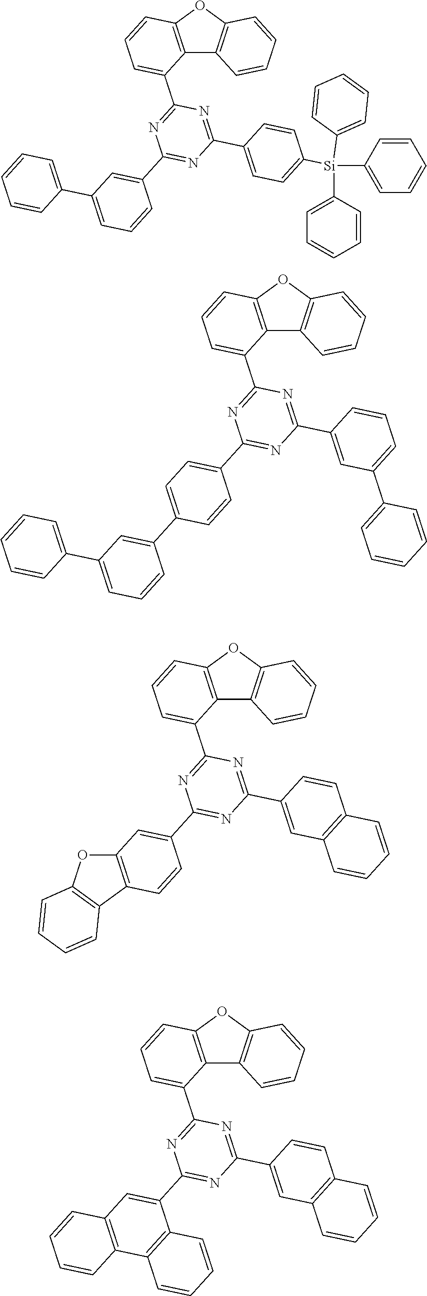

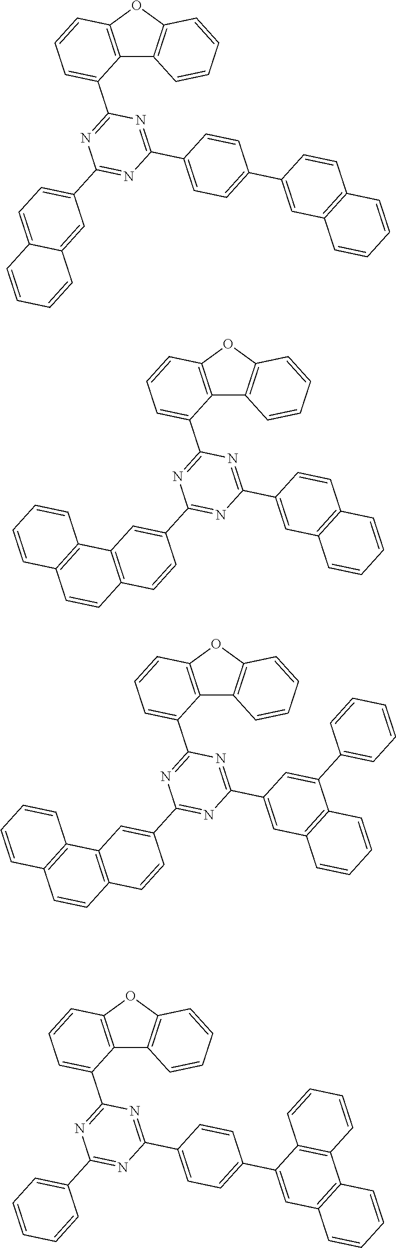 [SMILES: c1ccc2cc(-c3ccc(-c4nc(-c5ccc6ccccc6c5)nc(-c5cccc6oc7ccccc7c56)n4)cc3)ccc2c1 ; c1ccc2cc(-c3nc(-c4ccc5ccc6ccccc6c5c4)nc(-c4cccc5oc6ccccc6c45)n3)ccc2c1 ; c1ccc(-c2cc(-c3nc(-c4ccc5ccc6ccccc6c5c4)nc(-c4cccc5oc6ccccc6c45)n3)cc3ccccc23)cc1 ; c1ccc(-c2nc(-c3ccc(-c4cc5ccccc5c5ccccc45)cc3)nc(-c3cccc4oc5ccccc5c34)n2)cc1]

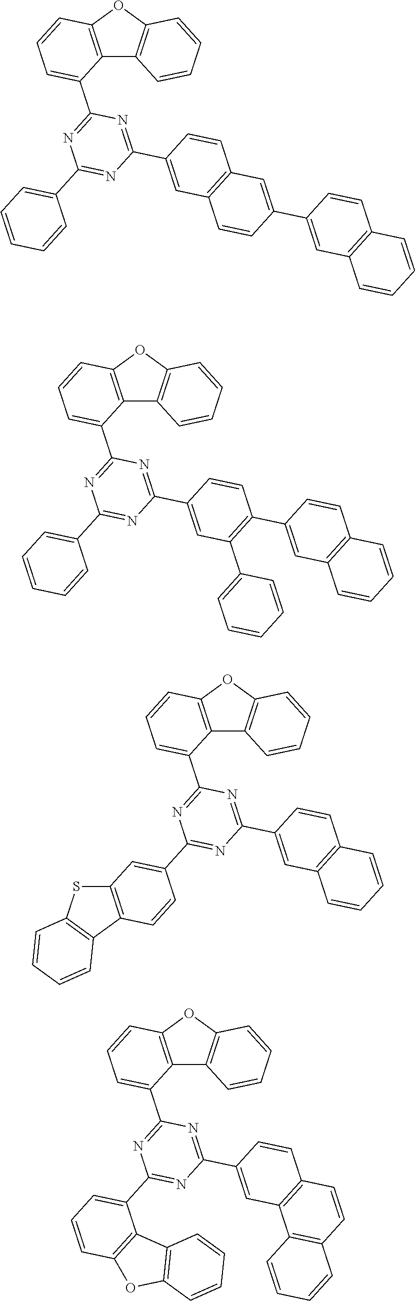 [SMILES: c1ccc(-c2nc(-c3ccc4cc(-c5ccc6ccccc6c5)ccc4c3)nc(-c3cccc4oc5ccccc5c34)n2)cc1 ; c1ccc(-c2nc(-c3ccc(-c4ccc5ccccc5c4)c(-c4ccccc4)c3)nc(-c3cccc4oc5ccccc5c34)n2)cc1 ; c1ccc2cc(-c3nc(-c4ccc5c(c4)sc4ccccc45)nc(-c4cccc5oc6ccccc6c45)n3)ccc2c1 ; c1ccc2c(c1)ccc1ccc(-c3nc(-c4cccc5oc6ccccc6c45)nc(-c4cccc5oc6ccccc6c45)n3)cc12]

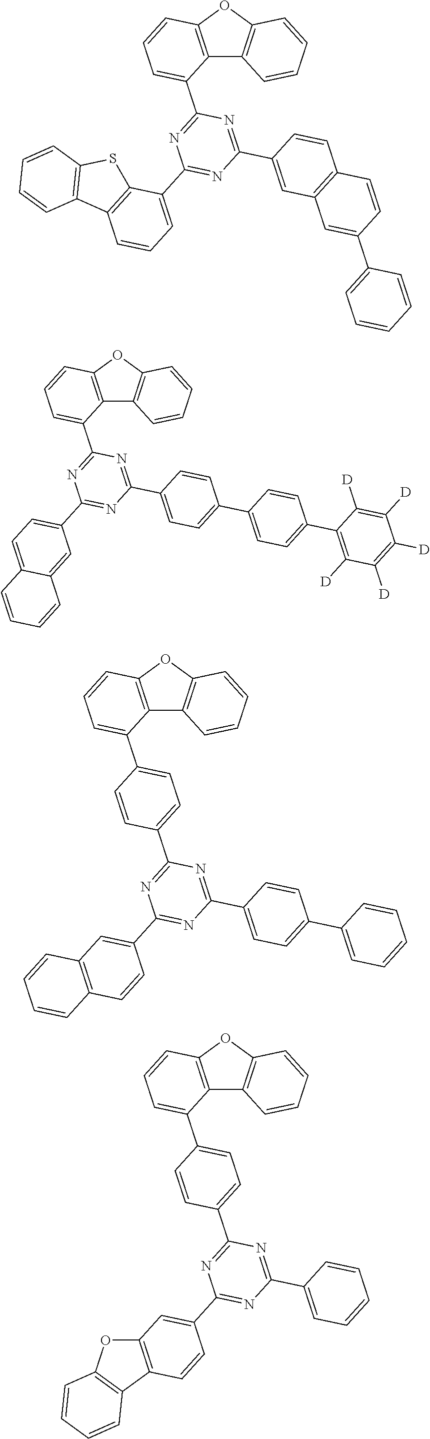 [SMILES: c1ccc(-c2ccc3ccc(-c4nc(-c5cccc6c5sc5ccccc56)nc(-c5cccc6oc7ccccc7c56)n4)cc3c2)cc1 ; [2H]c1c([2H])c([2H])c(-c2ccc(-c3ccc(-c4nc(-c5ccc6ccccc6c5)nc(-c5cccc6oc7ccccc7c56)n4)cc3)cc2)c([2H])c1[2H] ; c1ccc(-c2ccc(-c3nc(-c4ccc(-c5cccc6oc7ccccc7c56)cc4)nc(-c4ccc5ccccc5c4)n3)cc2)cc1 ; c1ccc(-c2nc(-c3ccc(-c4cccc5oc6ccccc6c45)cc3)nc(-c3ccc4c(c3)oc3ccccc34)n2)cc1]

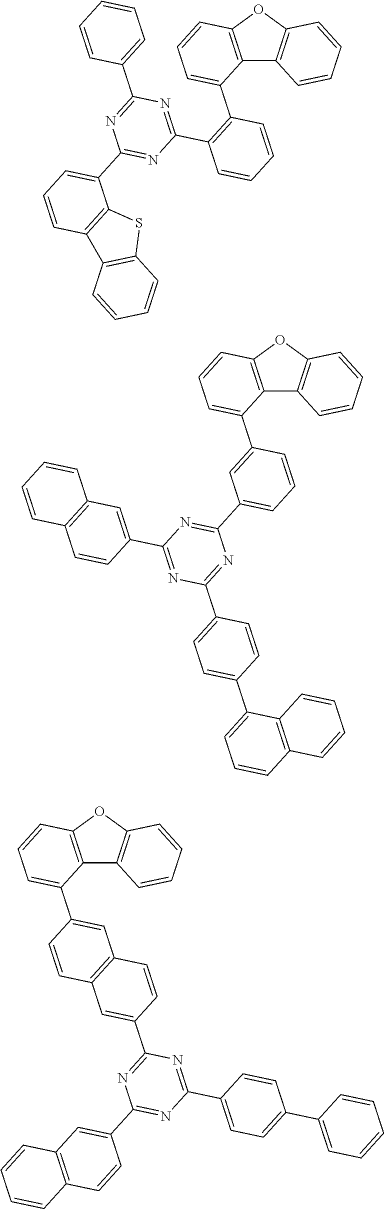 [SMILES: c1ccc(-c2nc(-c3ccccc3-c3cccc4oc5ccccc5c34)nc(-c3cccc4c3sc3ccccc34)n2)cc1 ; c1cc(-c2nc(-c3ccc(-c4cccc5ccccc45)cc3)nc(-c3ccc4ccccc4c3)n2)cc(-c2cccc3oc4ccccc4c23)c1 ; c1ccc(-c2ccc(-c3nc(-c4ccc5ccccc5c4)nc(-c4ccc5cc(-c6cccc7oc8ccccc8c67)ccc5c4)n3)cc2)cc1]

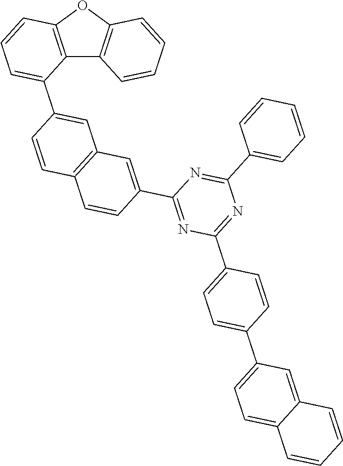 [SMILES: c1ccc(-c2nc(-c3ccc(-c4ccc5ccccc5c4)cc3)nc(-c3ccc4ccc(-c5cccc6oc7ccccc7c56)cc4c3)n2)cc1]

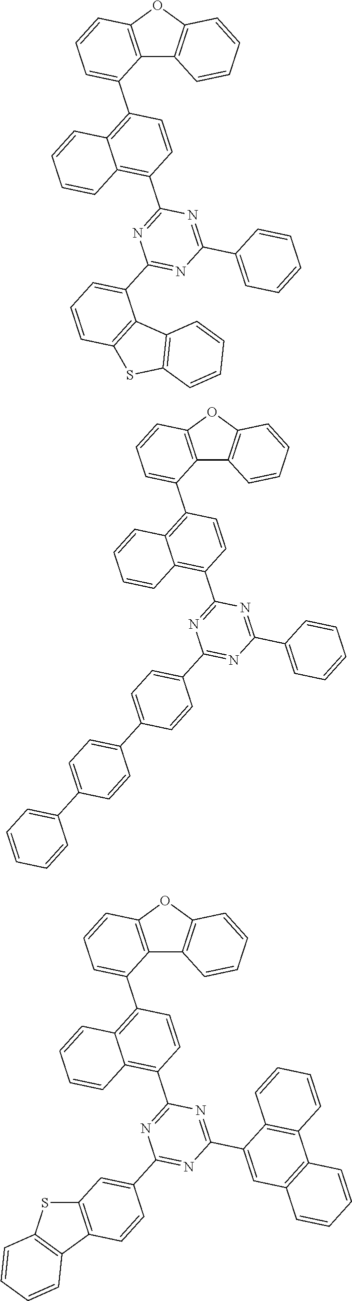

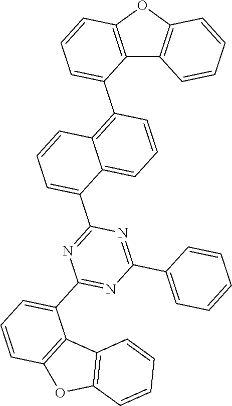 [SMILES: c1ccc(-c2nc(-c3cccc4c(-c5cccc6oc7ccccc7c56)cccc34)nc(-c3cccc4oc5ccccc5c34)n2)cc1]

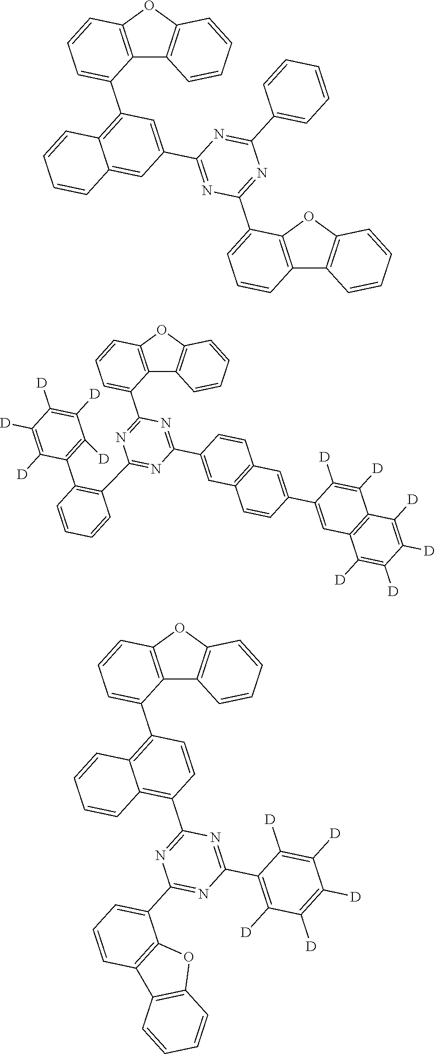 [SMILES: c1ccc(-c2nc(-c3cc(-c4cccc5oc6ccccc6c45)c4ccccc4c3)nc(-c3cccc4c3oc3ccccc34)n2)cc1 ; [2H]c1c([2H])c([2H])c(-c2ccccc2-c2nc(-c3ccc4cc(-c5cc6c([2H])c([2H])c([2H])c([2H])c6c([2H])c5[2H])ccc4c3)nc(-c3cccc4oc5ccccc5c34)n2)c([2H])c1[2H] ; [2H]c1c([2H])c([2H])c(-c2nc(-c3ccc(-c4cccc5oc6ccccc6c45)c4ccccc34)nc(-c3cccc4c3oc3ccccc34)n2)c([2H])c1[2H]]

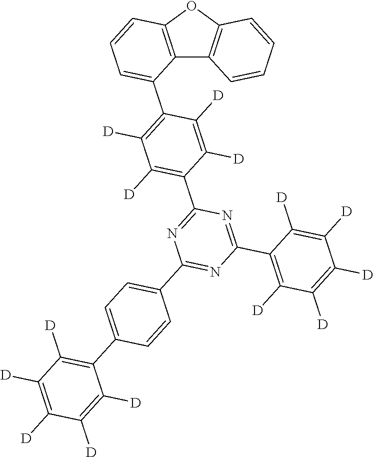 [SMILES: [2H]c1c([2H])c([2H])c(-c2ccc(-c3nc(-c4c([2H])c([2H])c([2H])c([2H])c4[2H])nc(-c4c([2H])c([2H])c(-c5cccc6oc7ccccc7c56)c([2H])c4[2H])n3)cc2)c([2H])c1[2H]]

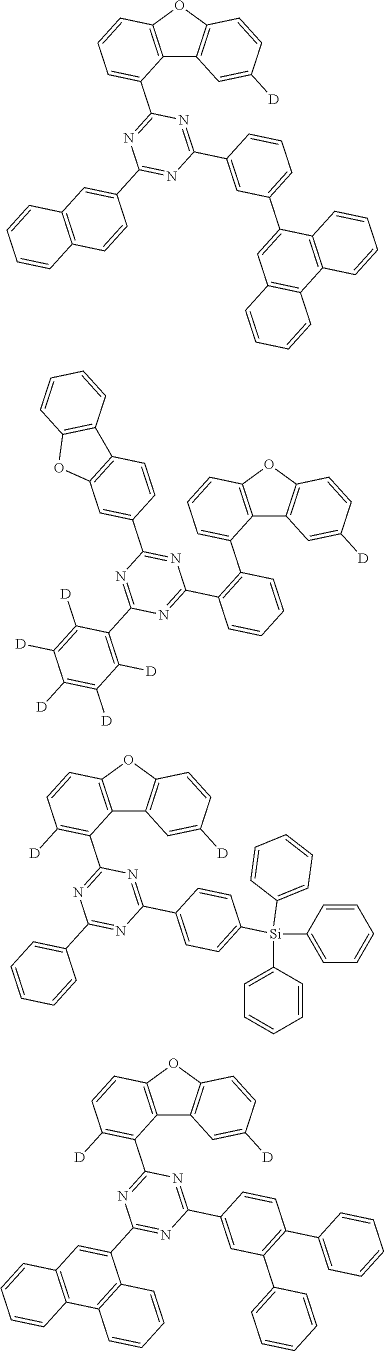

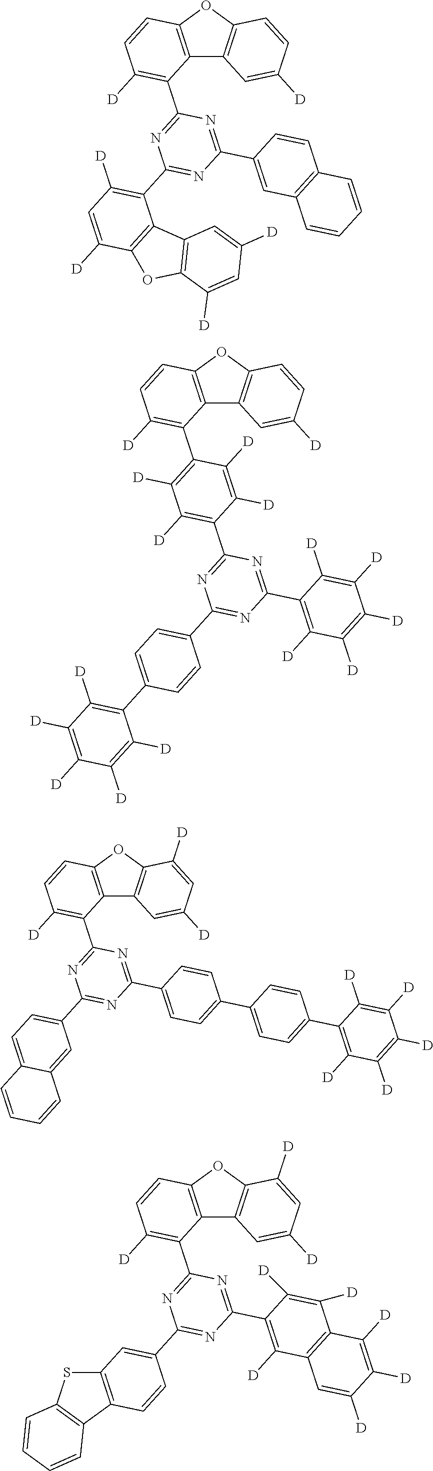

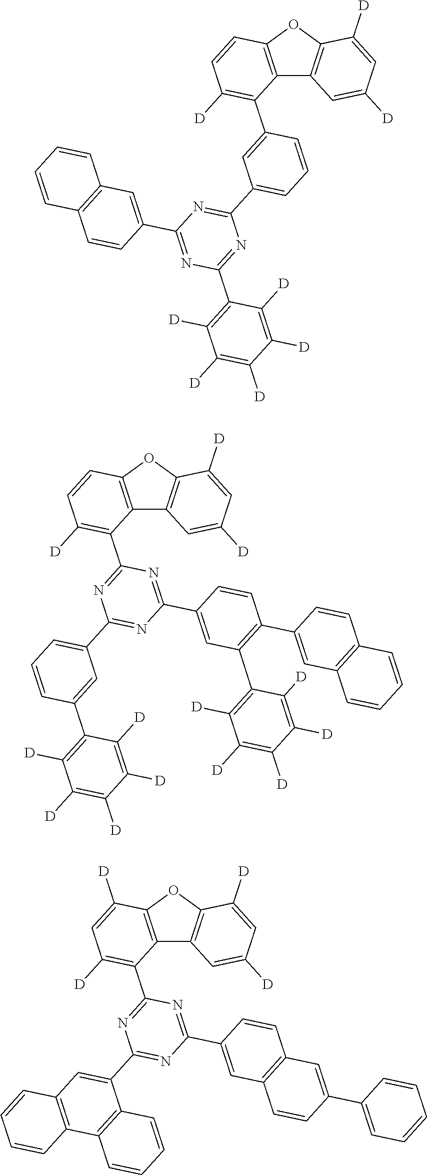

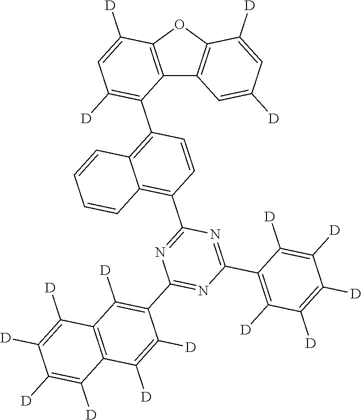 [SMILES: [2H]c1cc([2H])c2oc3c([2H])cc([2H])c(-c4ccc(-c5nc(-c6c([2H])c([2H])c([2H])c([2H])c6[2H])nc(-c6c([2H])c([2H])c7c([2H])c([2H])c([2H])c([2H])c7c6[2H])n5)c5ccccc45)c3c2c1]

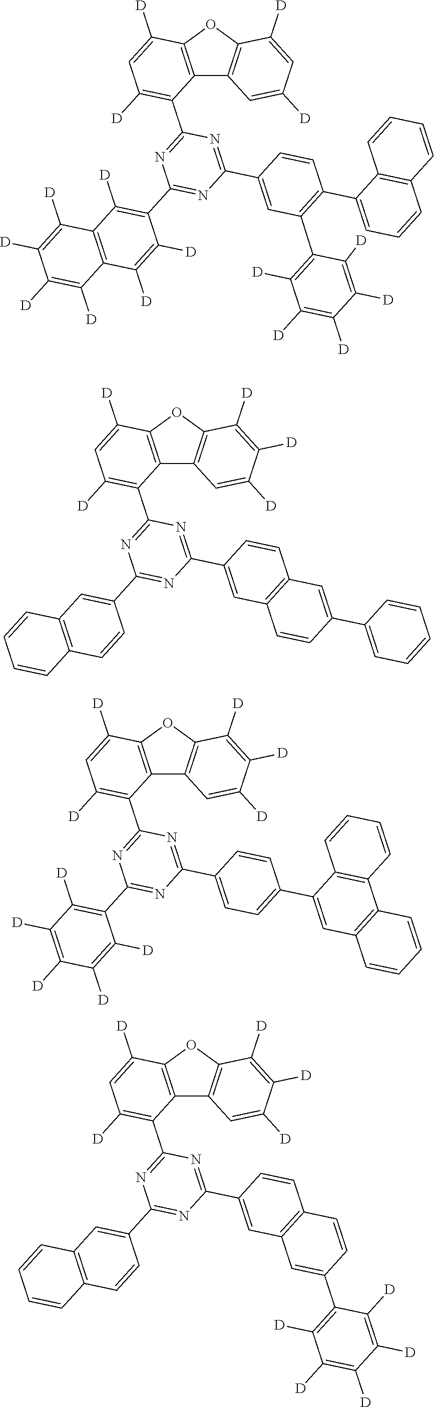

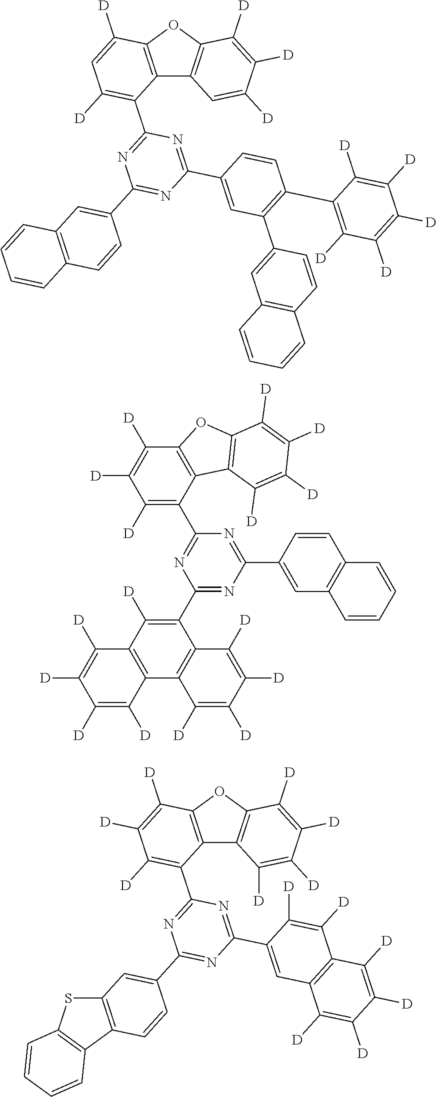

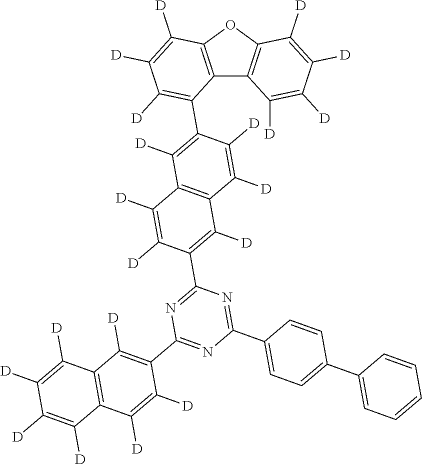 [SMILES: [2H]c1c([2H])c([2H])c2c(oc3c([2H])c([2H])c([2H])c(-c4c([2H])c([2H])c5c([2H])c(-c6nc(-c7ccc(-c8ccccc8)cc7)nc(-c7c([2H])c([2H])c8c([2H])c([2H])c([2H])c([2H])c8c7[2H])n6)c([2H])c([2H])c5c4[2H])c32)c1[2H]]

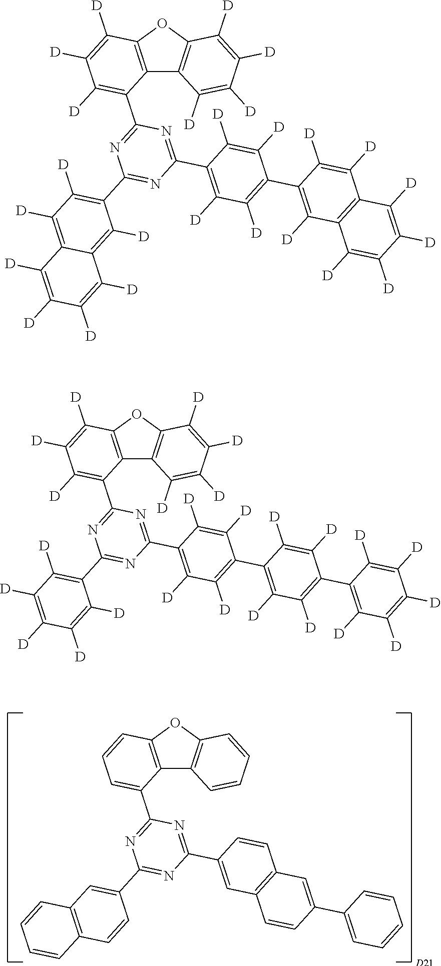

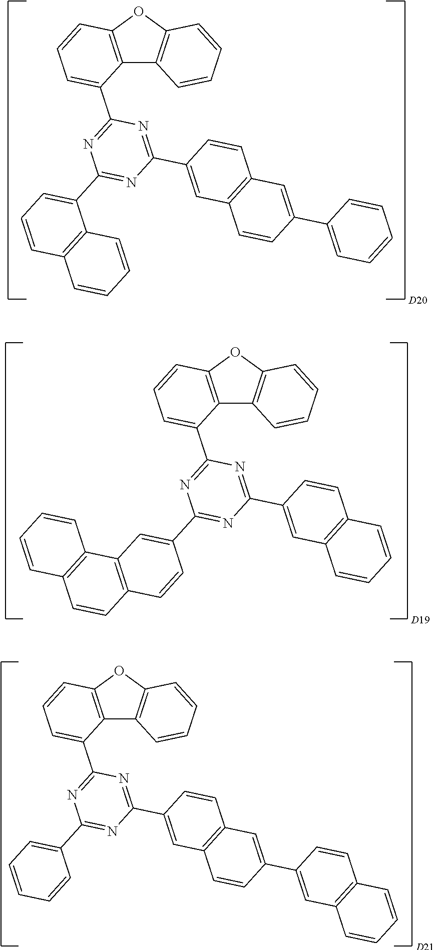

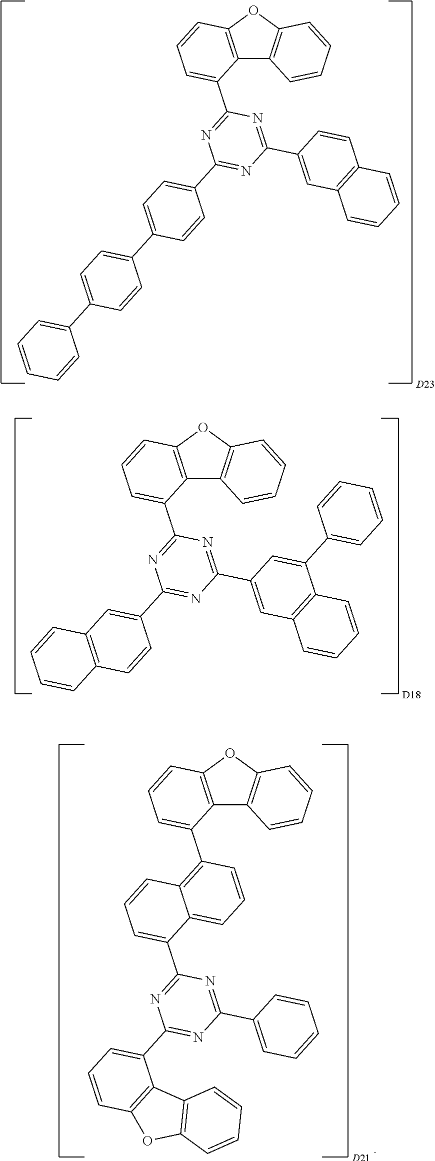

6. The organic light emitting device of claim 1, wherein:
Ar′₁ is hydrogen, deuterium, or phenyl which is unsubstituted or substituted with at least one deuterium.

7. The organic light emitting device of claim 1, wherein:
Ar′₂ and Ar′₃ are each independently phenyl, biphenylyl, terphenylyl, quaterphenylyl, naphthyl, phenyl naphthyl, naphthyl phenyl, tetrahydronaphthyl, phenanthrenyl, phenyl phenanthrenyl, triphenylenyl, dimethylfluorenyl, diphenylfluorenyl, carbazolyl, phenyl carbazolyl, dibenzofuranyl, dibenzothiophenyl, or phenyl dibenzofuranyl,
wherein the phenyl, biphenylyl, terphenylyl, quarterphenylyl, naphthyl, phenyl naphthyl, naphthyl phenyl, tetrahydronaphthyl, phenanthrenyl, phenyl phenanthrenyl, triphenylenyl, dimethyifluorenyl, diphenyifluorenyl, carbazolyl, phenyl carbazolyl, dibenzofuranyl, dibenzothiophenyl, and phenyl dibenzofuranyl are each independently unsubstituted or substituted with at least one deuterium, or at least one C₁₋₁₀ alkyl.

8. The organic light emitting device of claim 1, wherein:
L′₁ to L′₃ are each independently a single bond, phenylene, biphenylylene, naphthylene, phenyl naphthylene, phenanthrenylene, carbazolylene, phenyl carbazolylene, dibenzofuranylene, phenyl dibenzofuranylene, or dimethylfluorenylene,
wherein the phenylene, biphenylylene, naphthylene, phenyl naphthylene, phenanthrenylene, carbazolylene, phenyl carbazolylene, dibenzofuranylene, phenyl dibenzofuranylene, and dimethylfluorenylene are each independently unsubstituted or substituted with at least one deuterium.

9. The organic light emitting device of claim 1, wherein:
L′₄ is a single bond, a substituted or unsubstituted phenylene, a substituted or unsubstituted biphenylylene, or a substituted or unsubstituted naphthylene.

10. The organic light emitting device of claim 1, wherein:
the compound represented by Chemical Formula 2 is any one selected from the group consisting of the following compounds,
in the following group, D is deuterium,
n1 is an integer of 1 to 9,
n is the total number of deuterium substituted in the compound, and
each compound in the following group has a deuterium substitution rate of 50% or more: 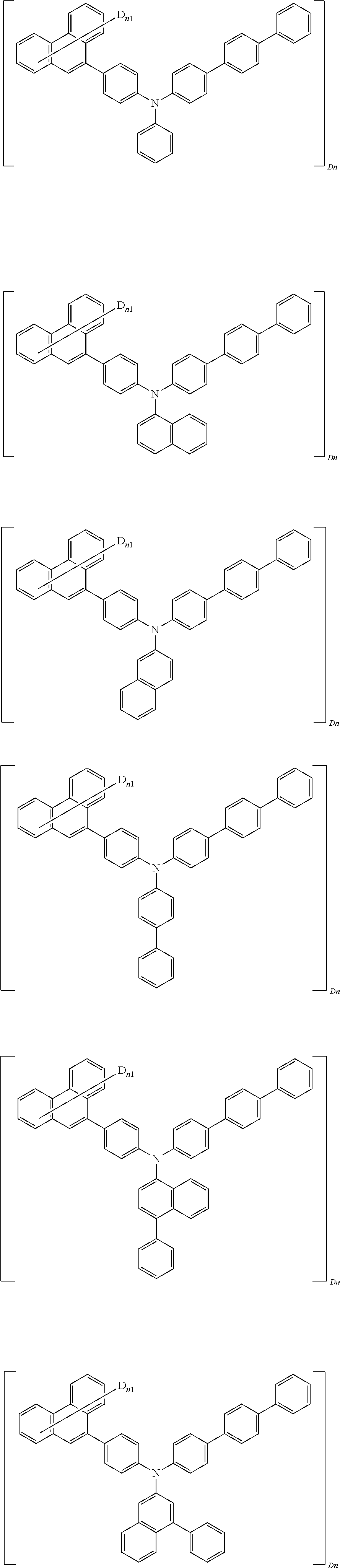 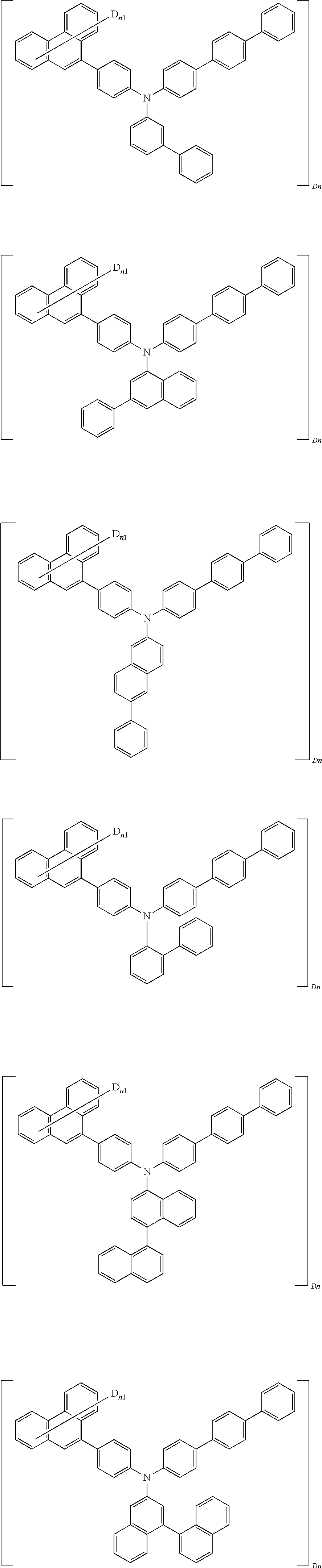 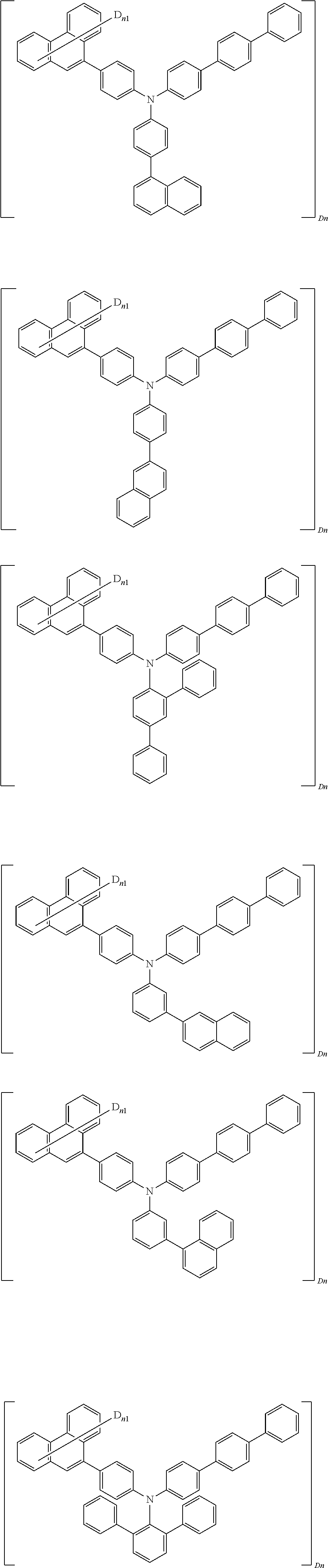 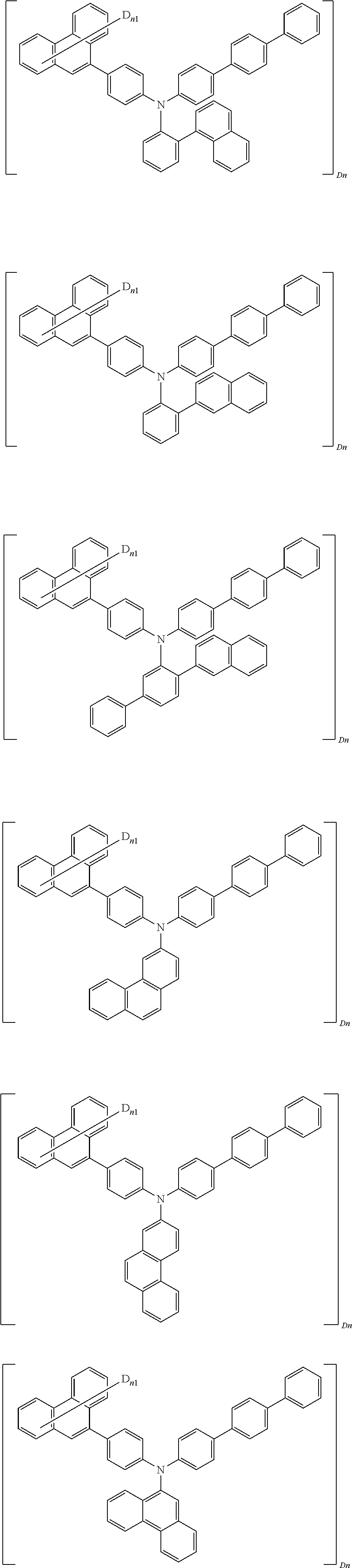 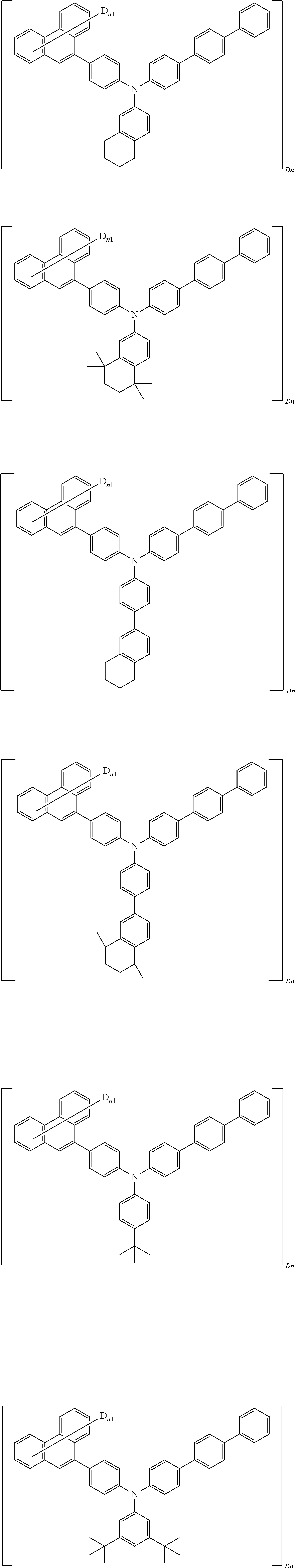 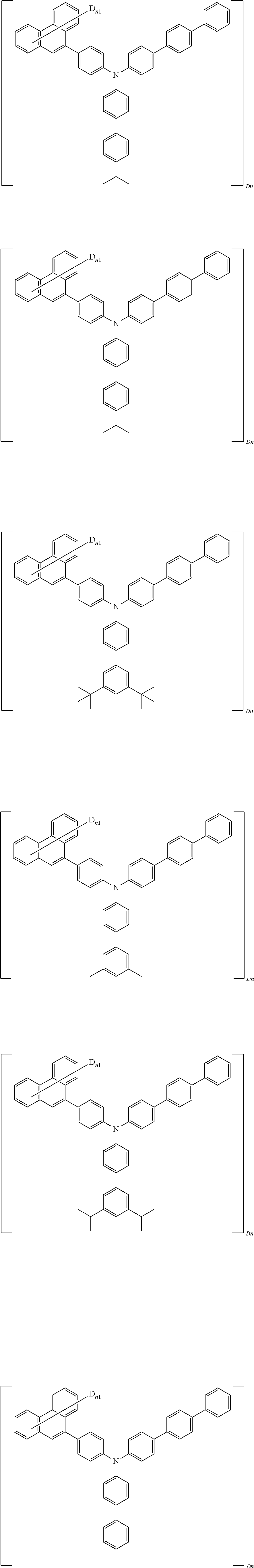 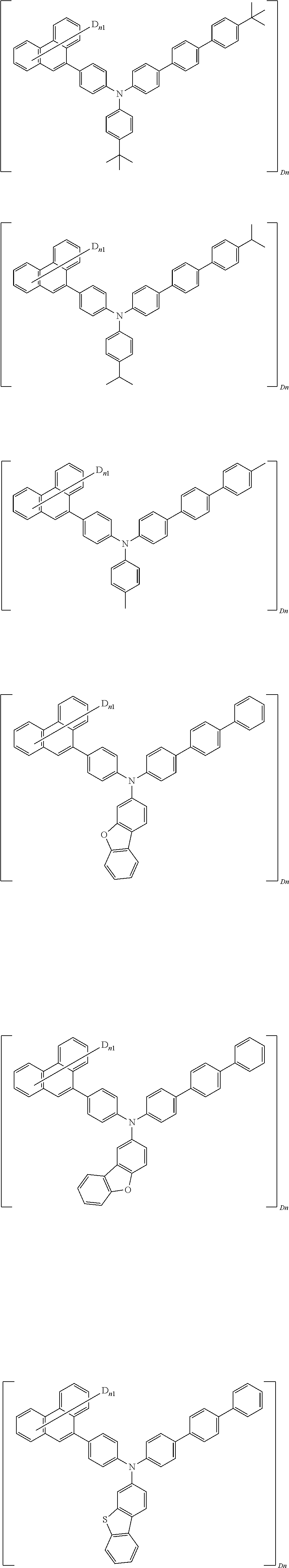 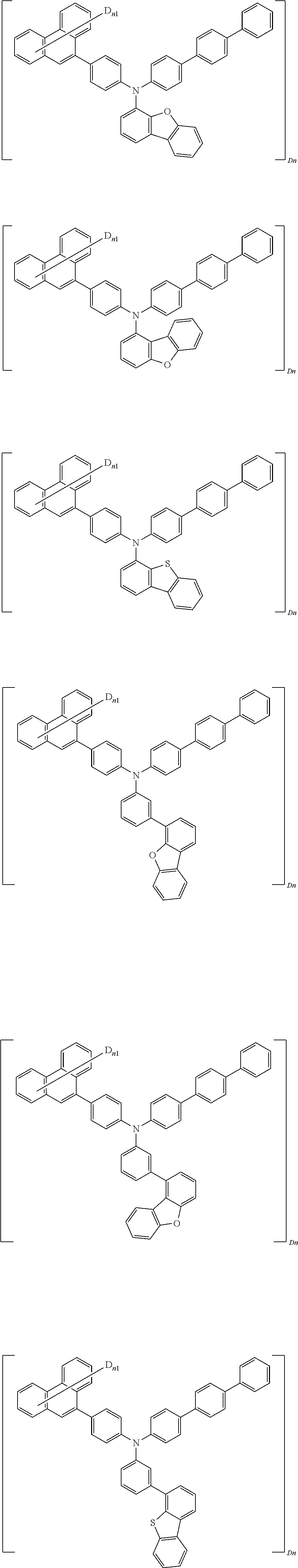 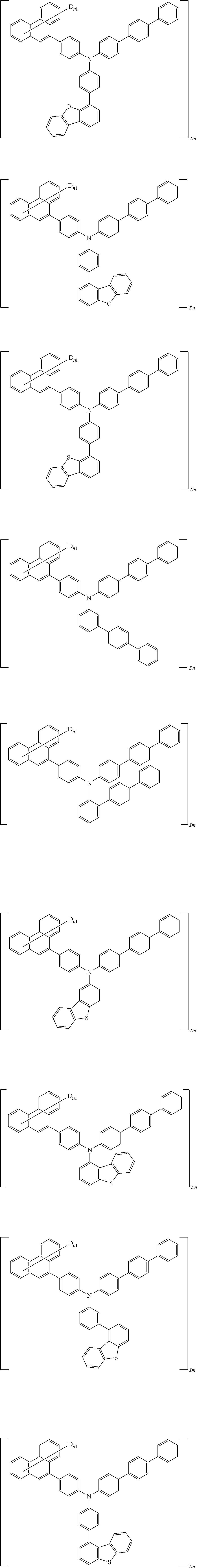 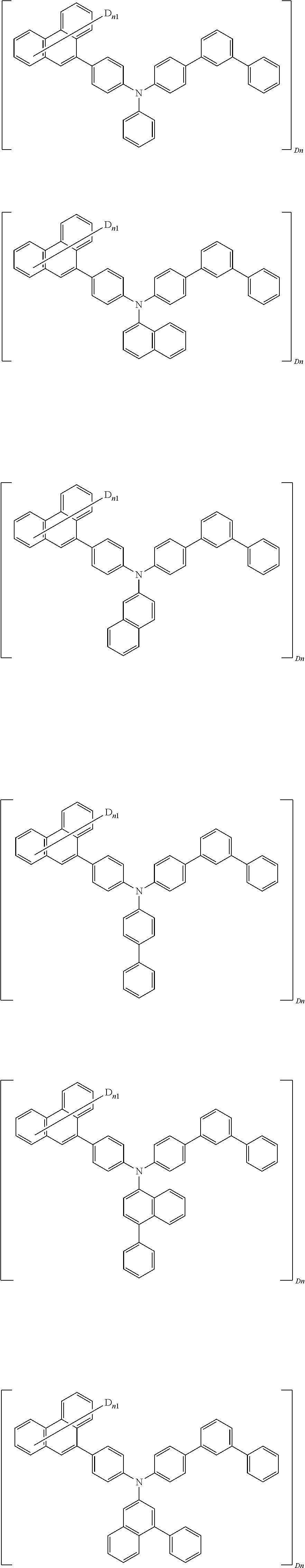 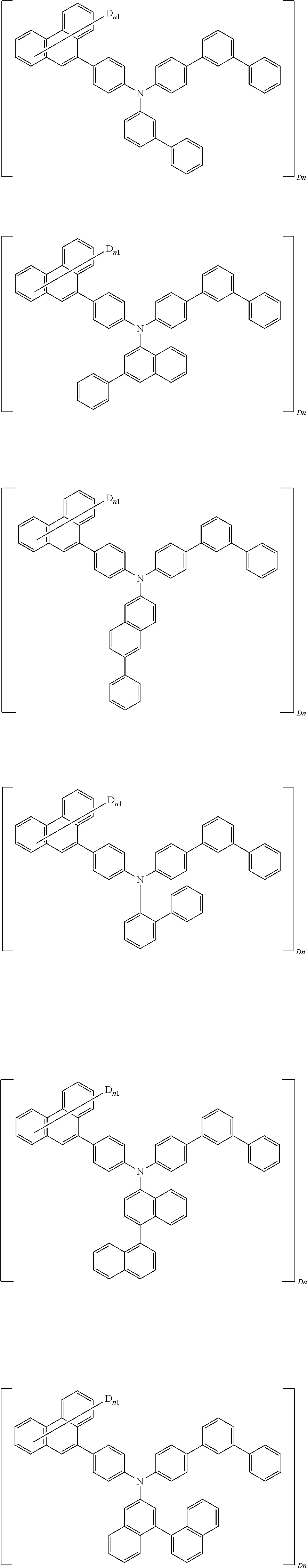 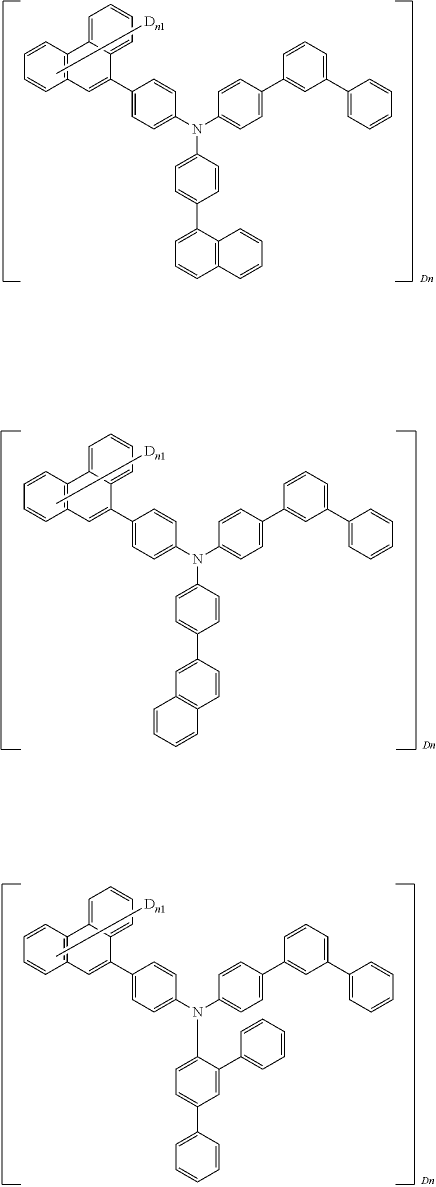 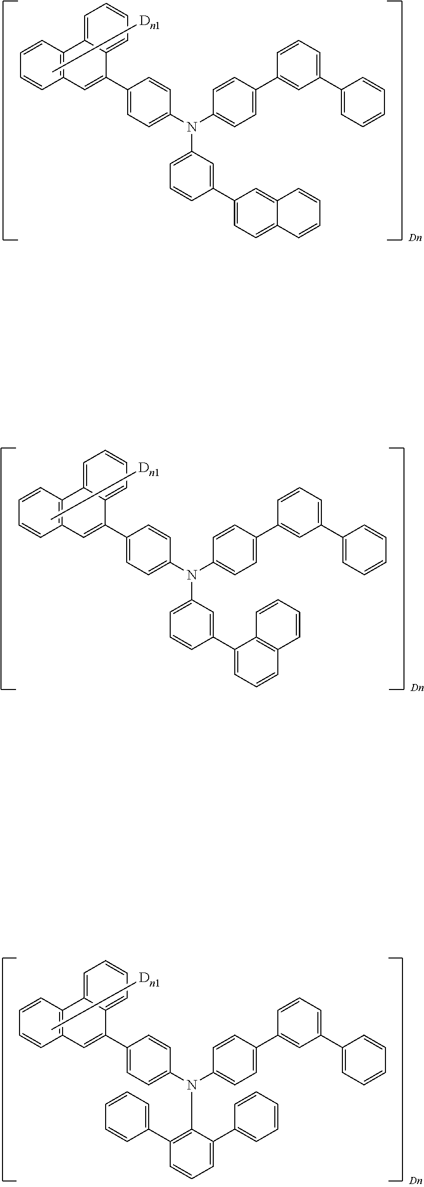 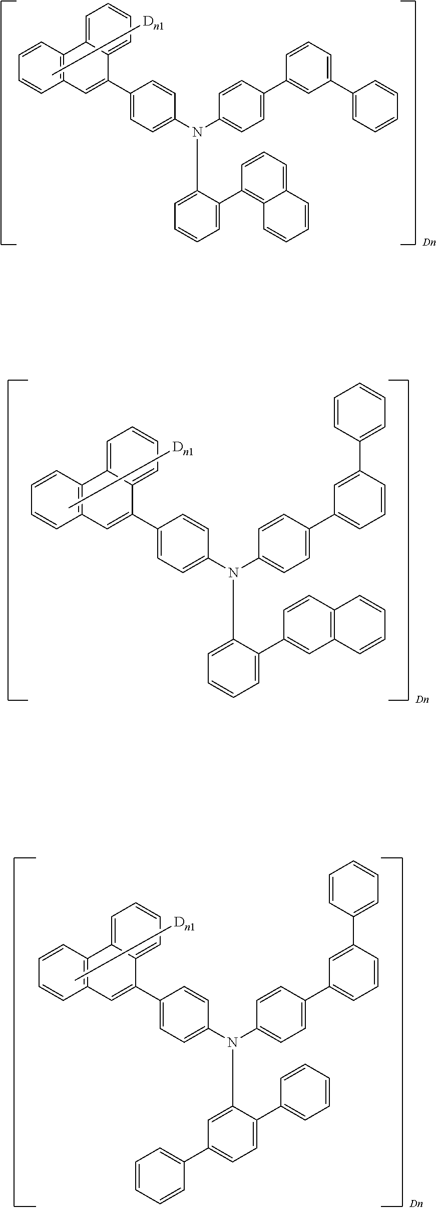 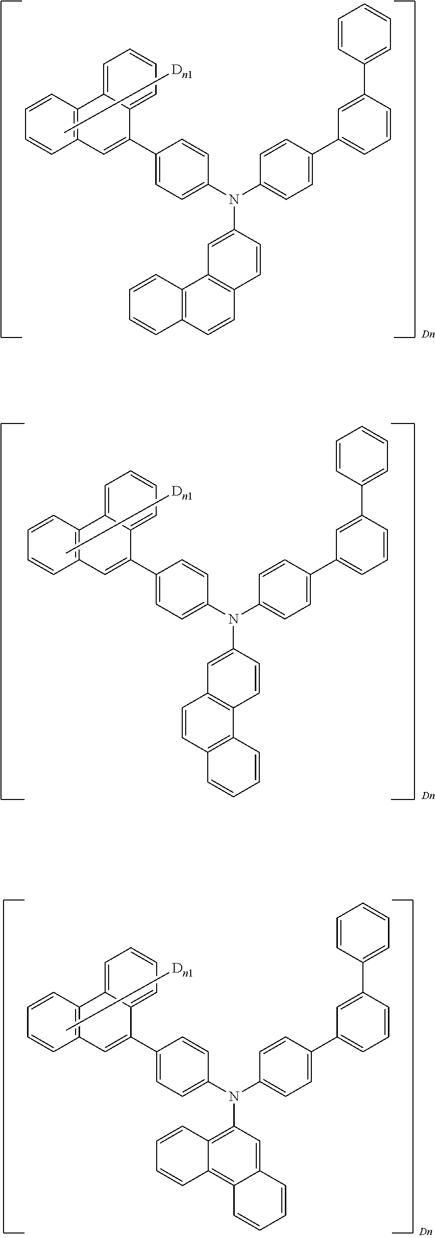 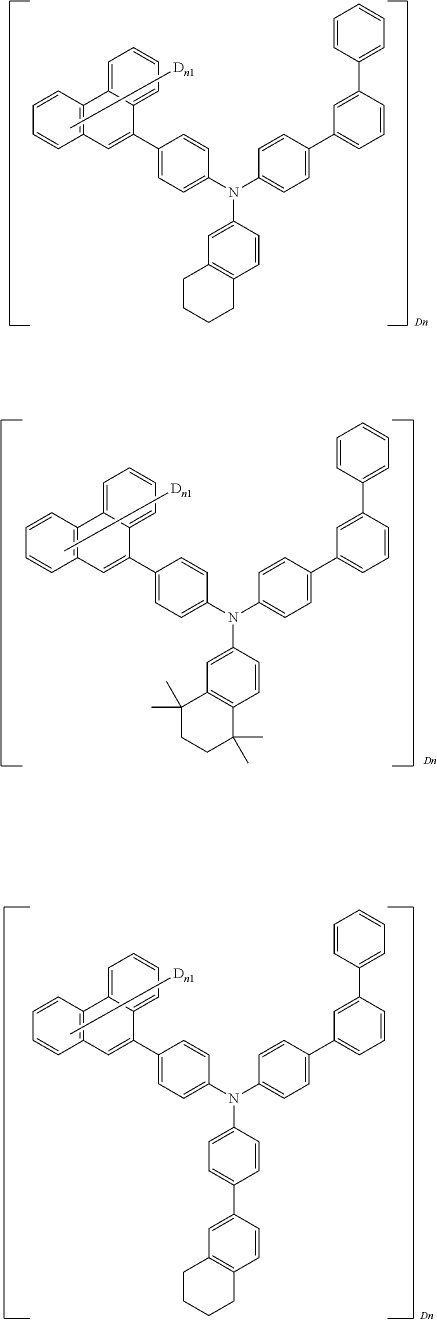 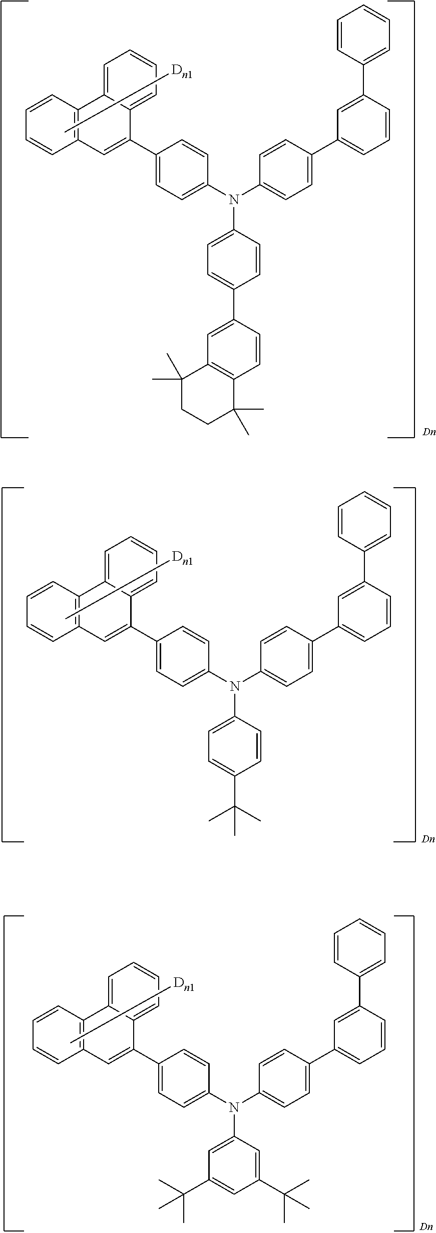 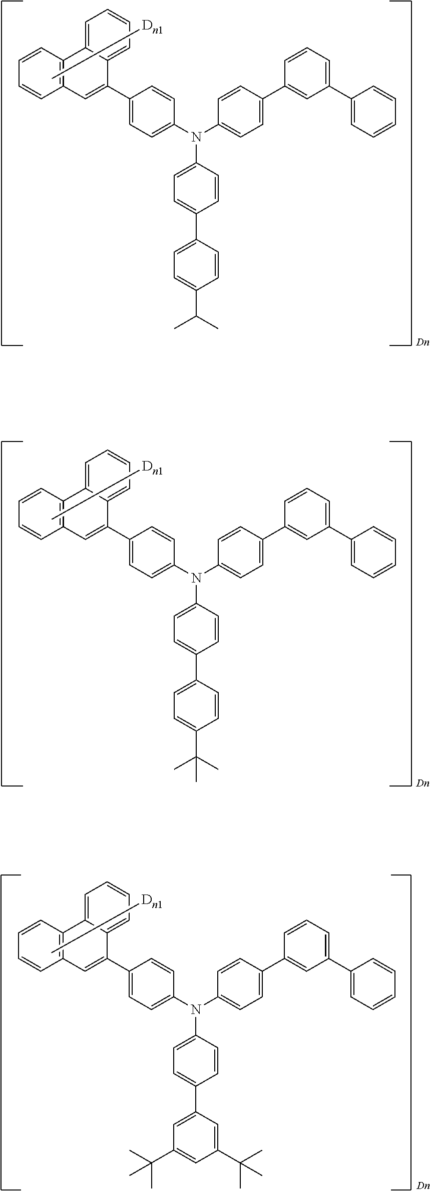 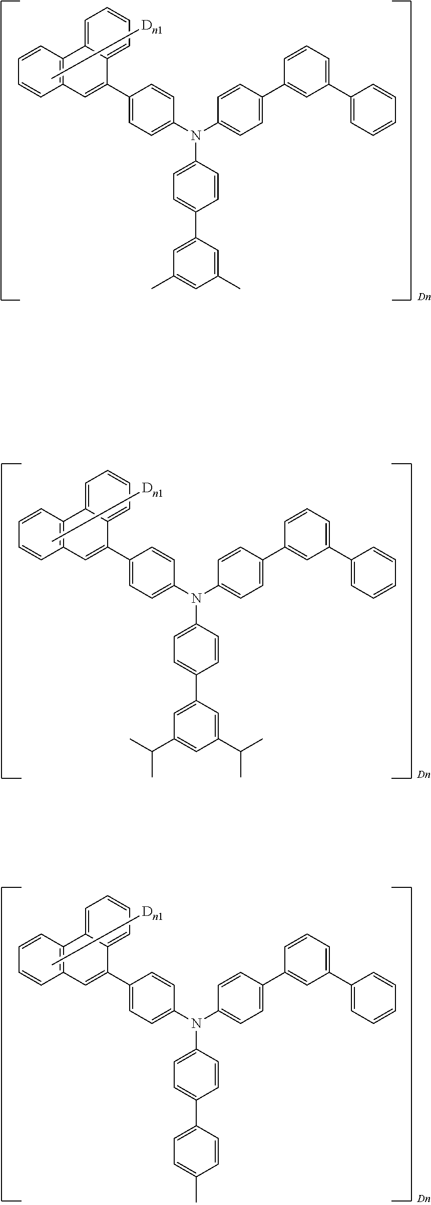 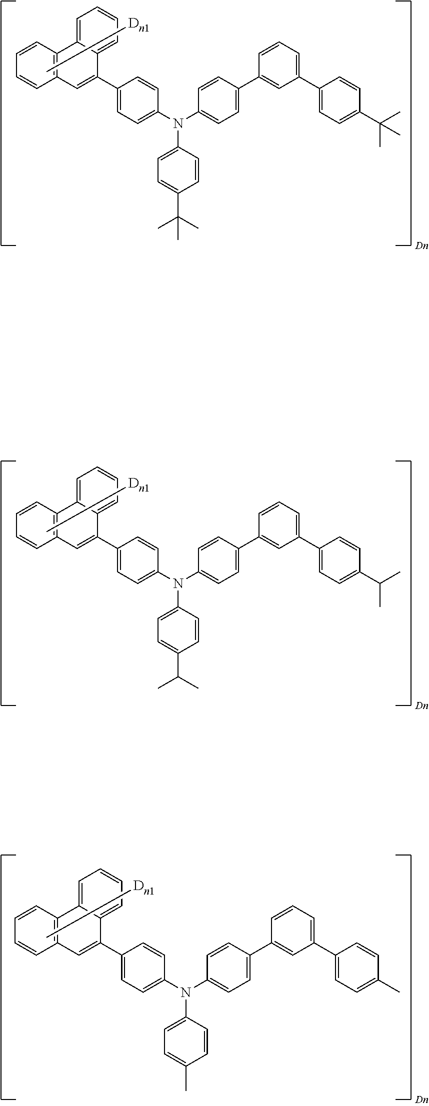 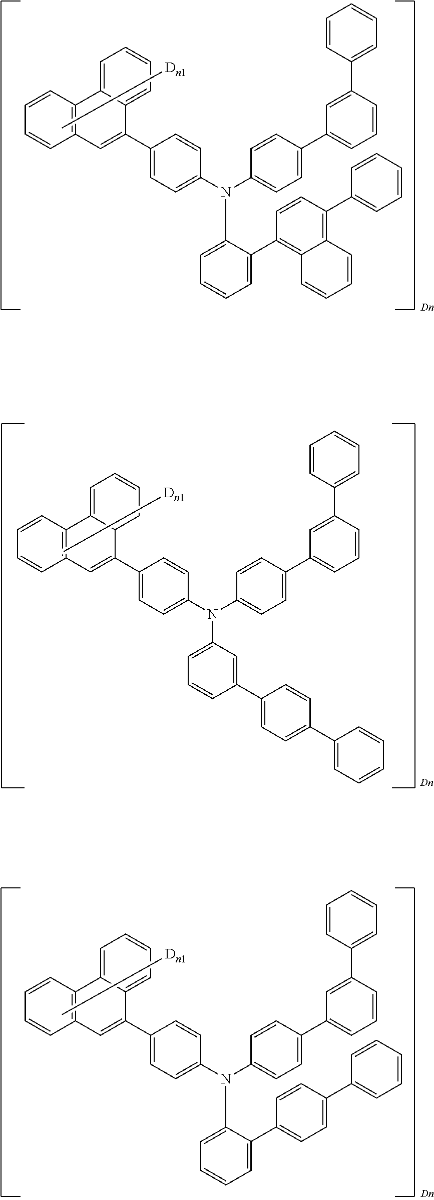 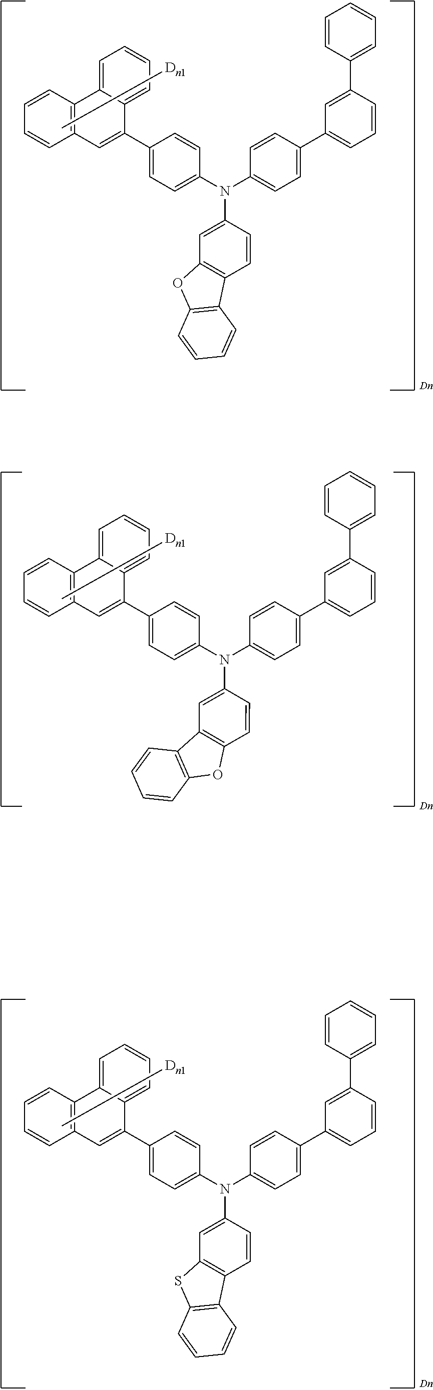 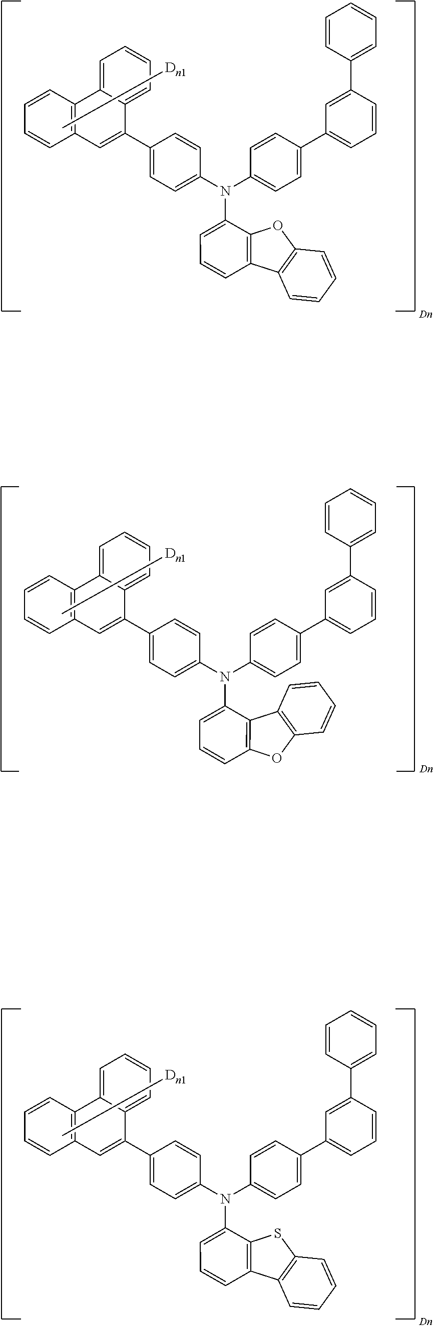 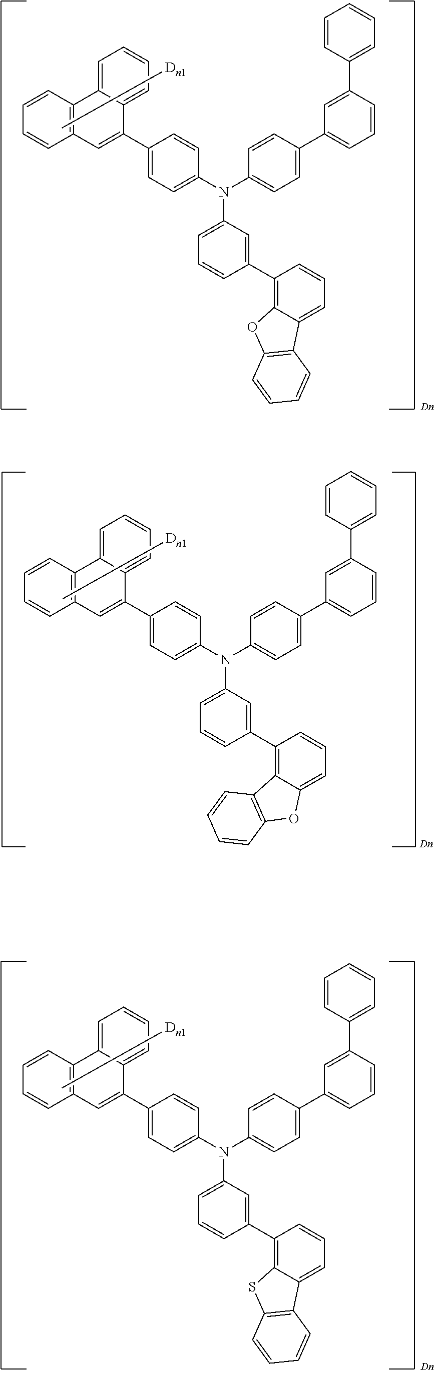 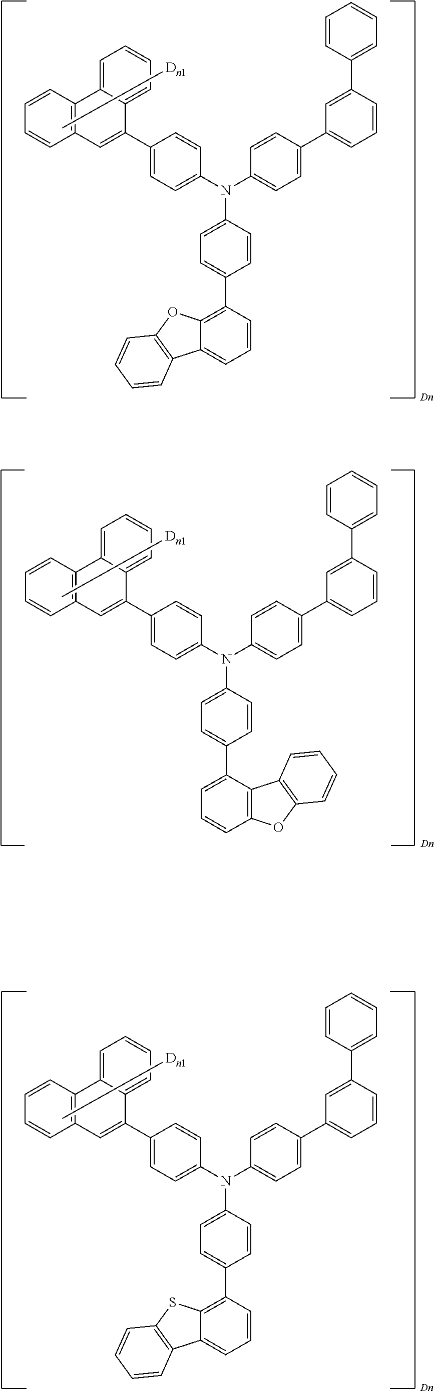 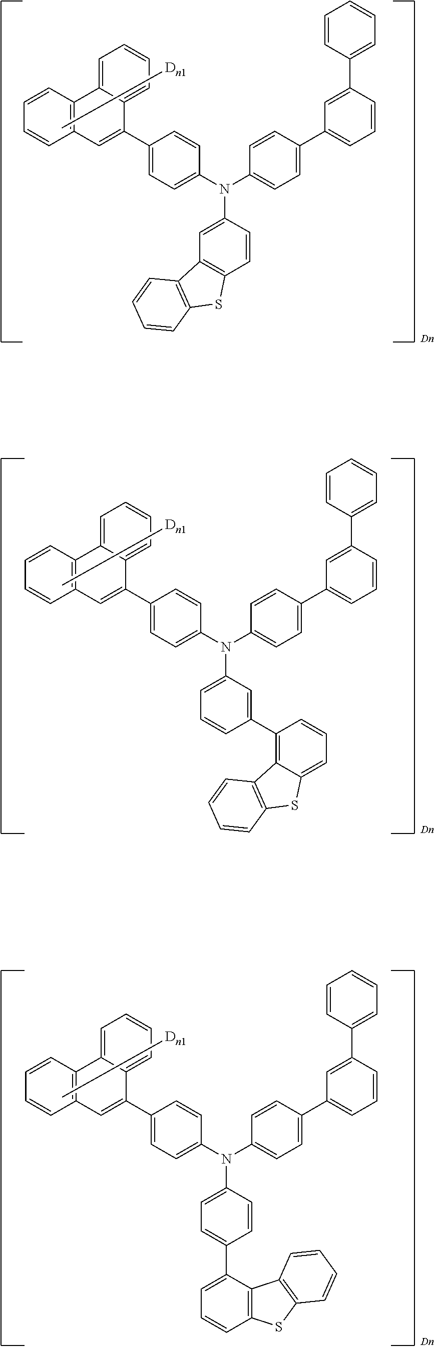 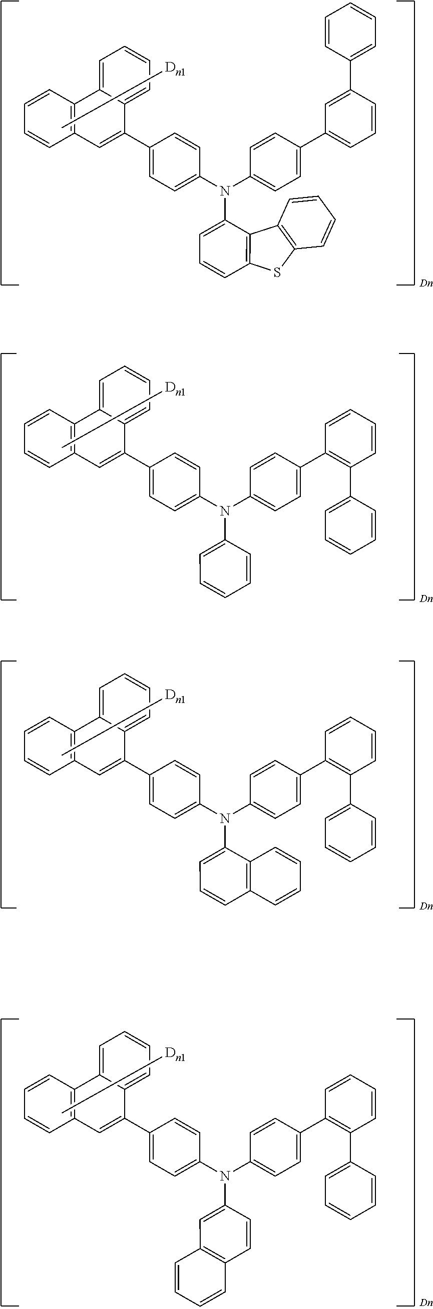 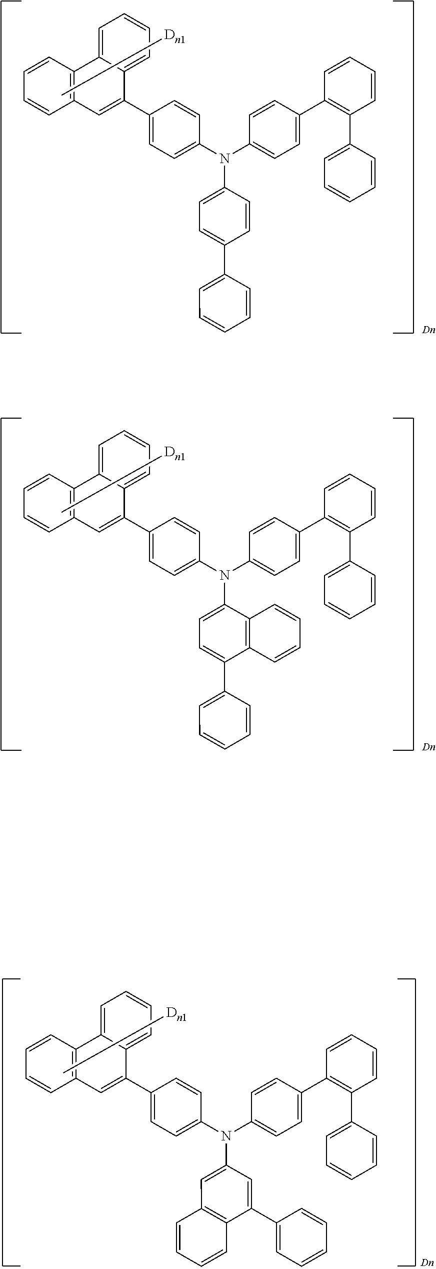 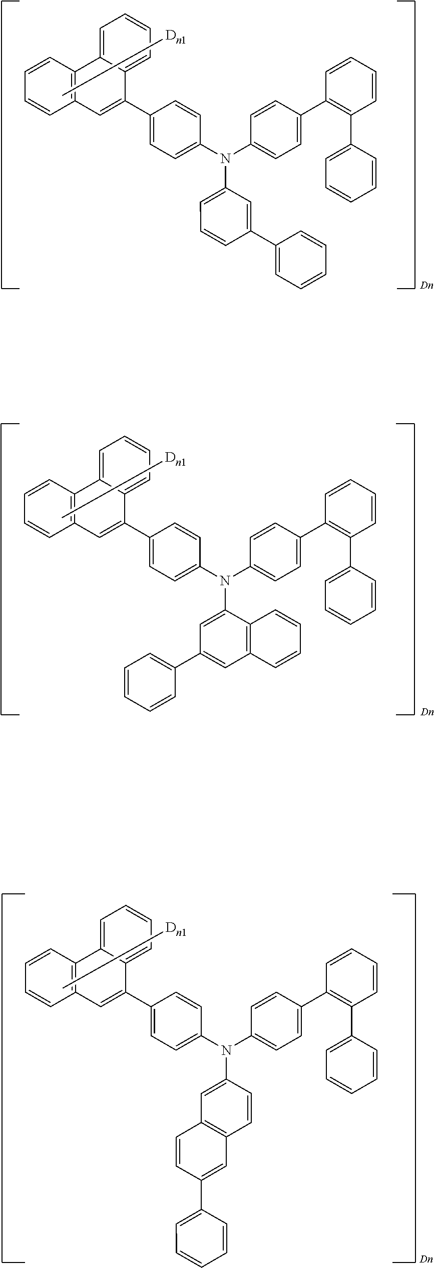 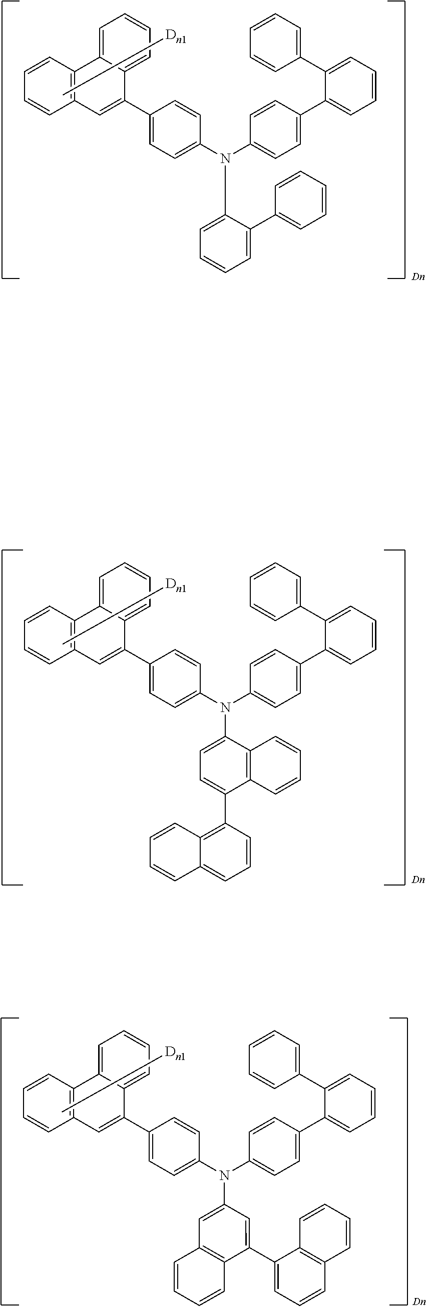 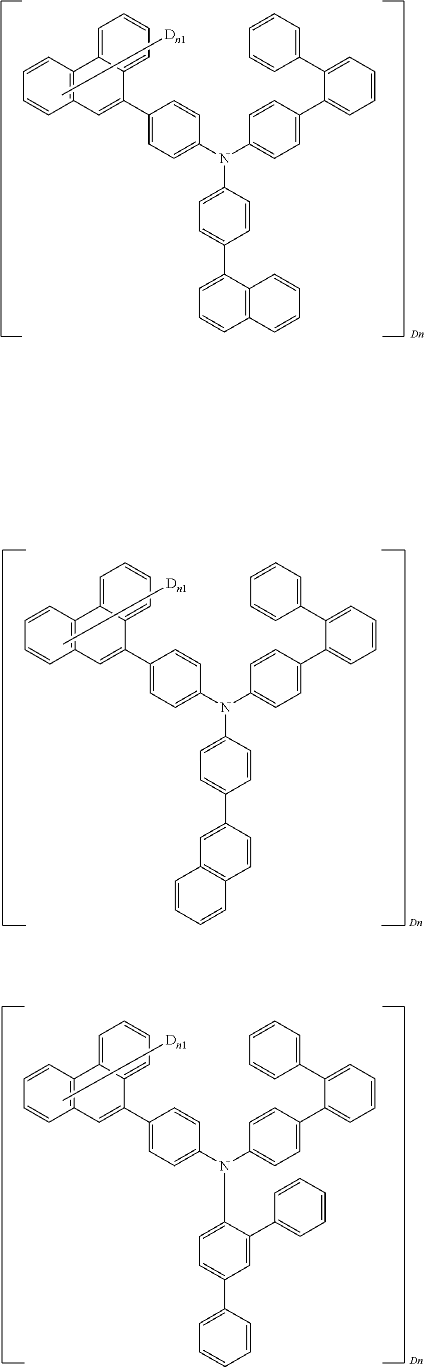 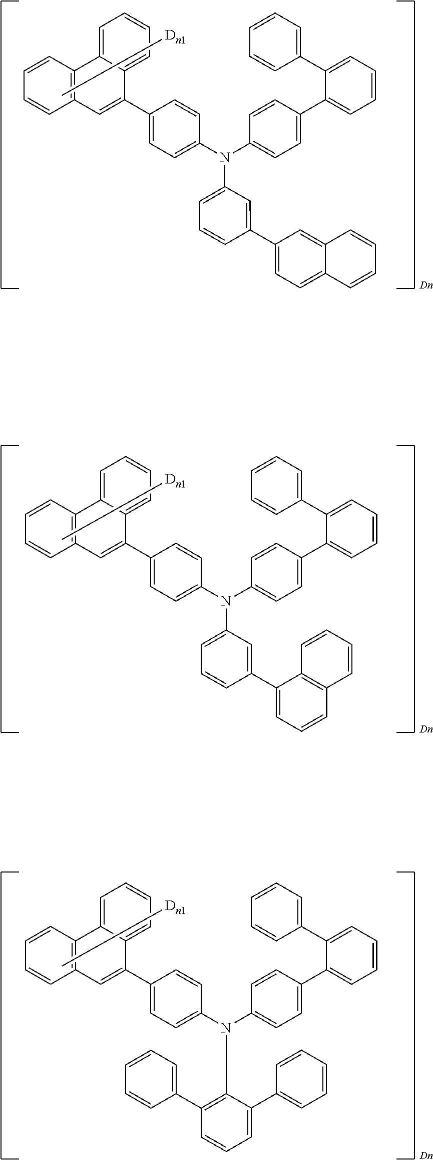 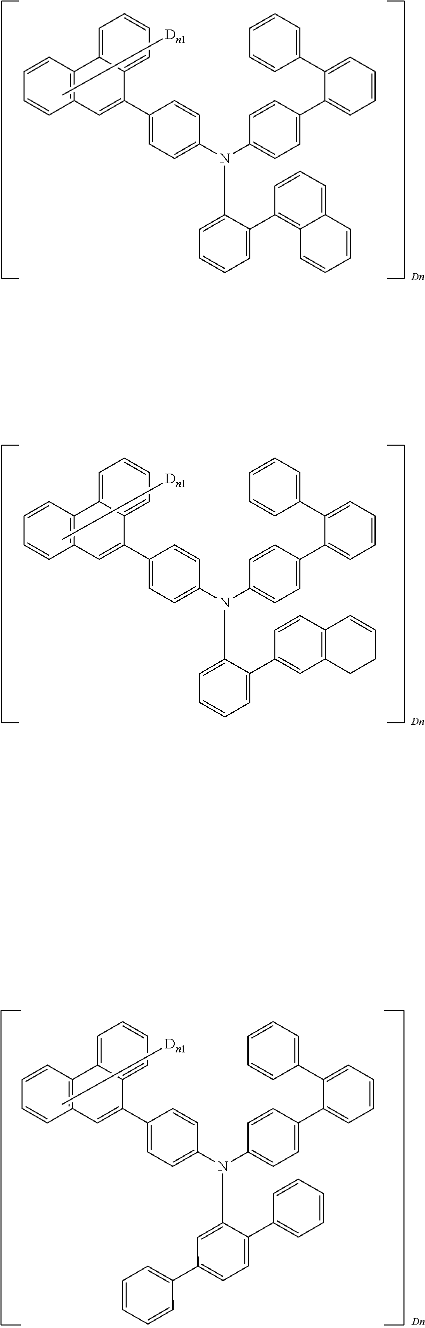 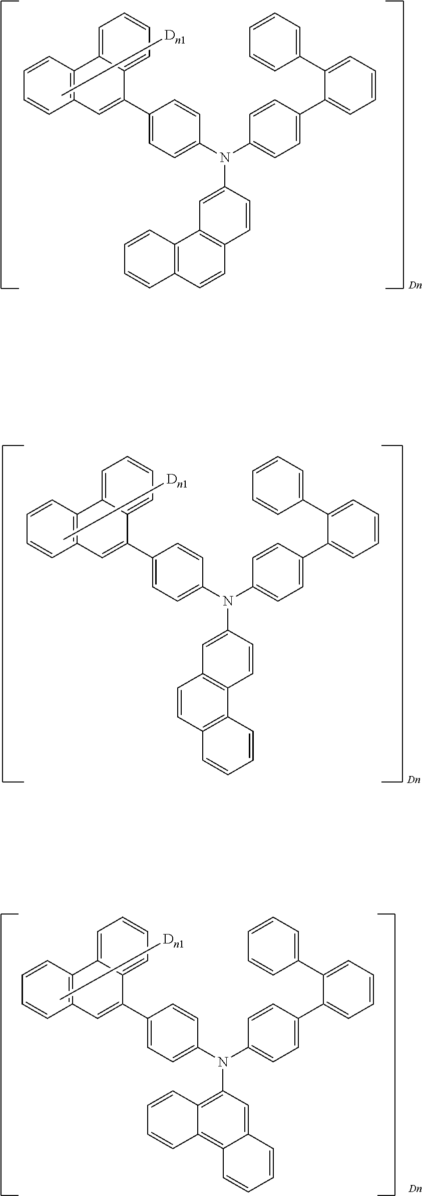 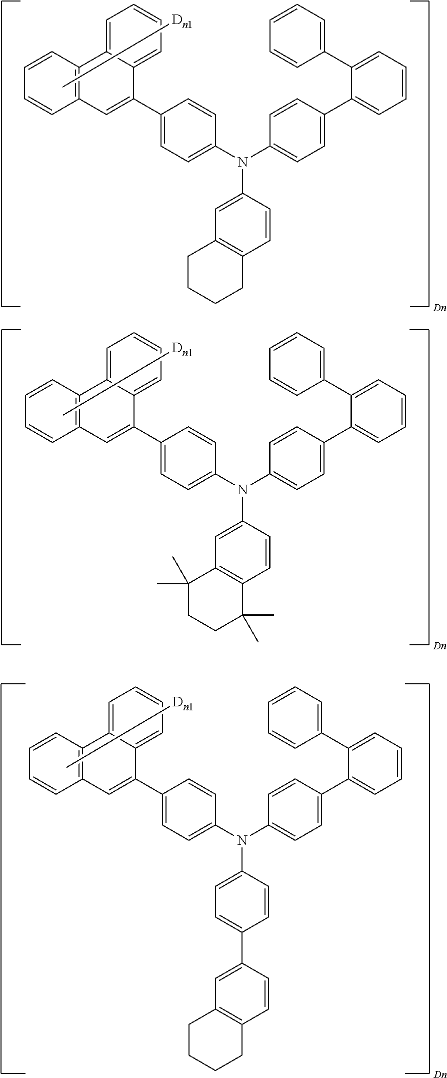 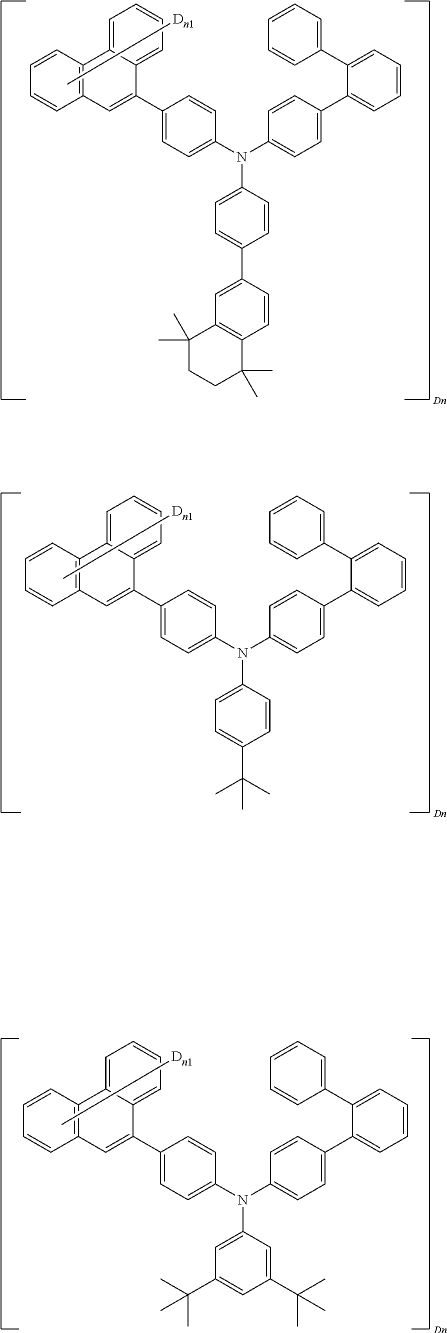 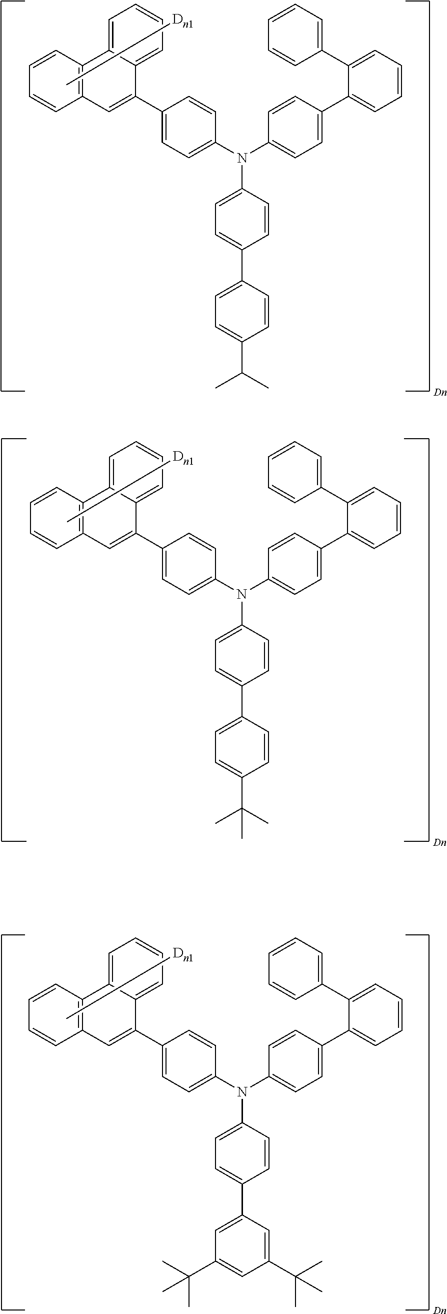 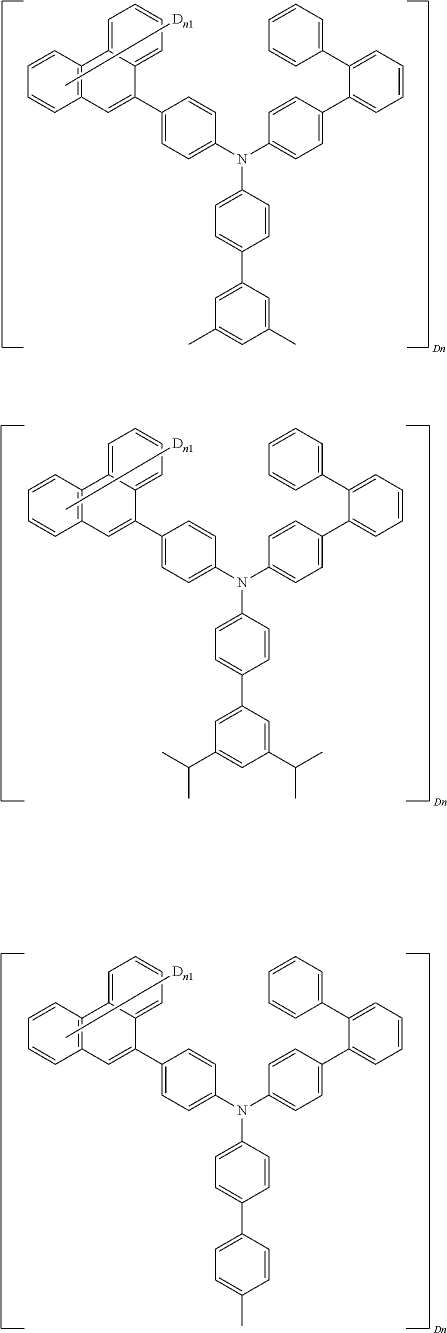 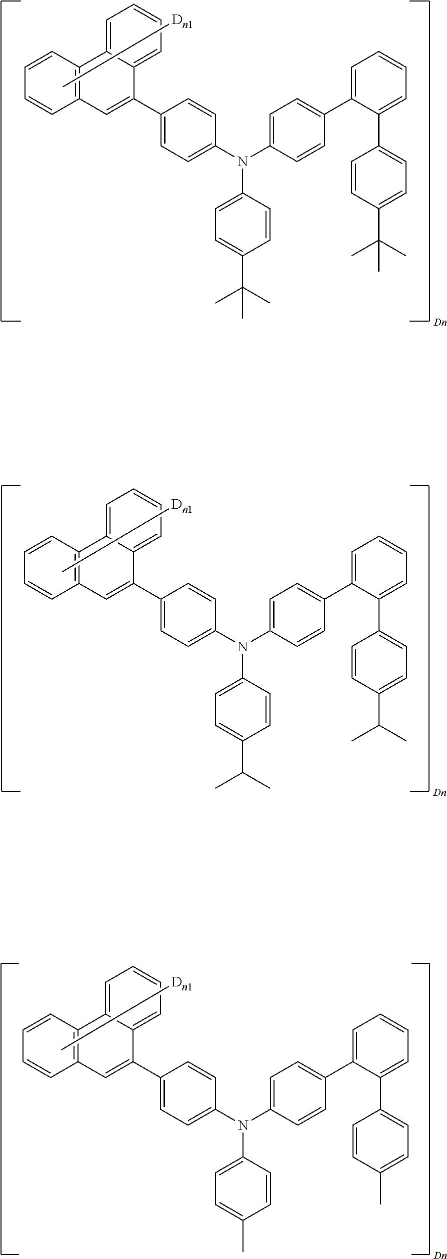 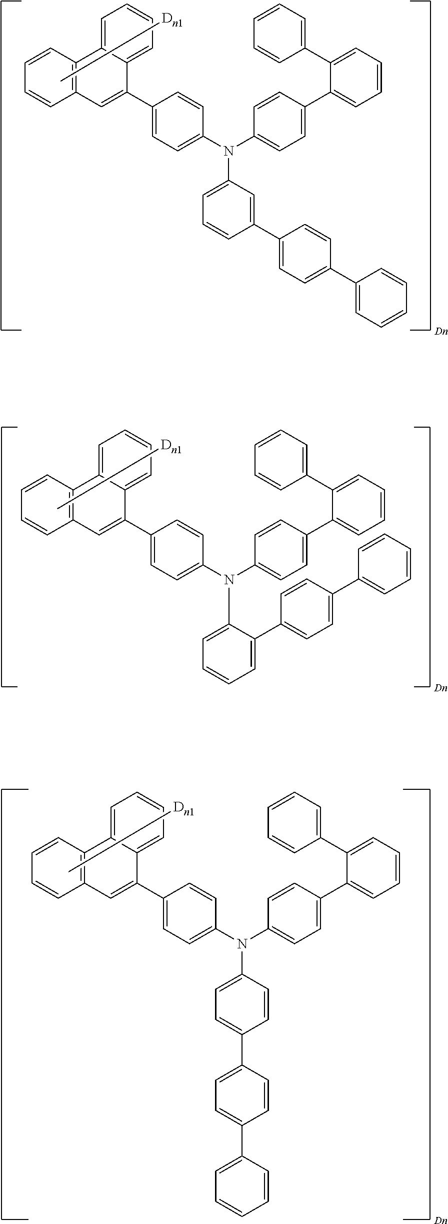 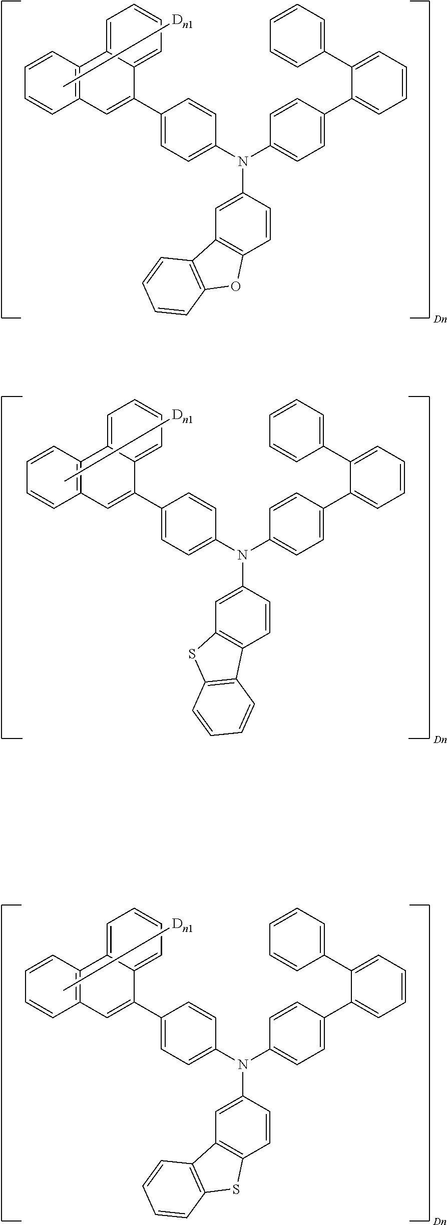 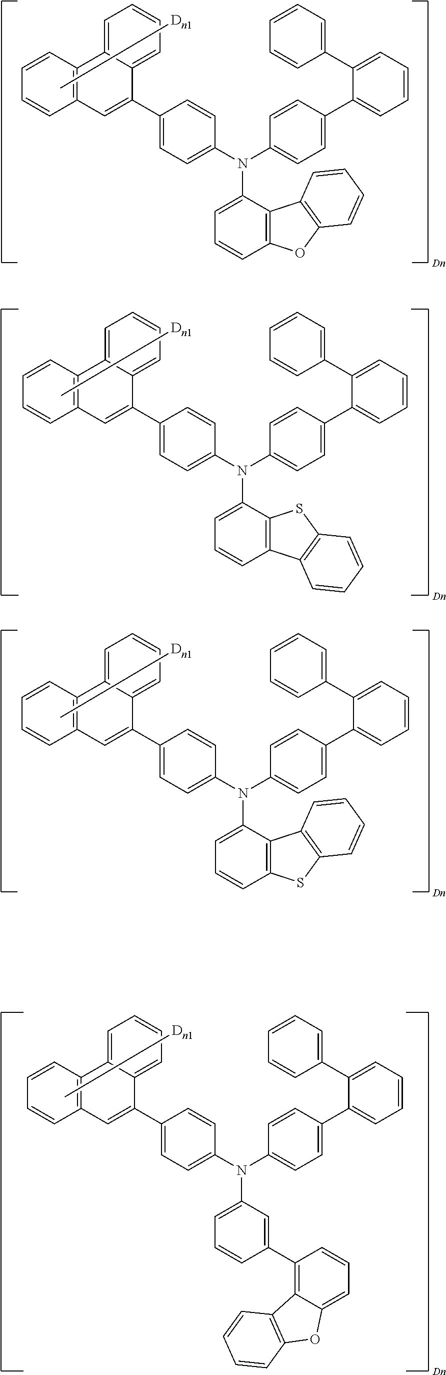 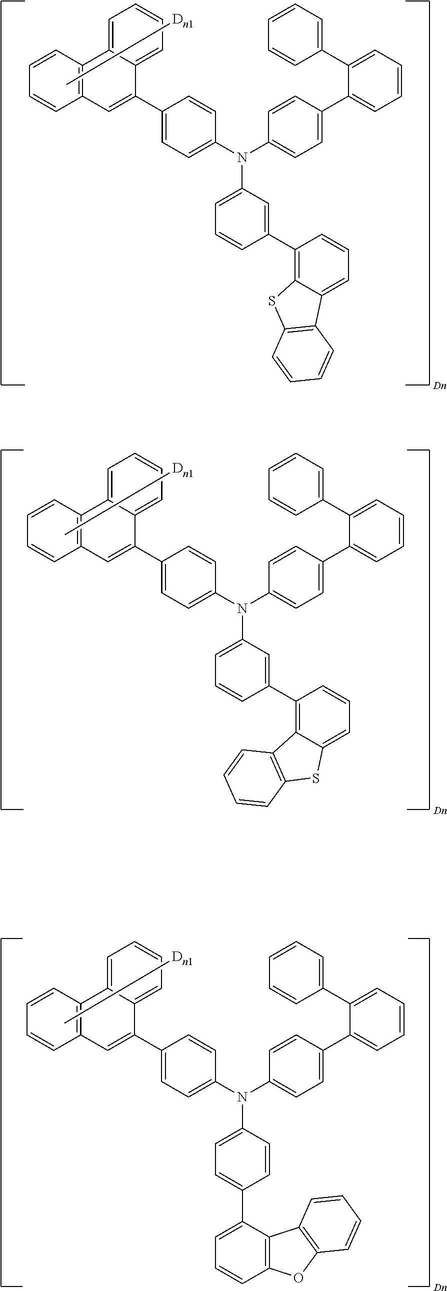 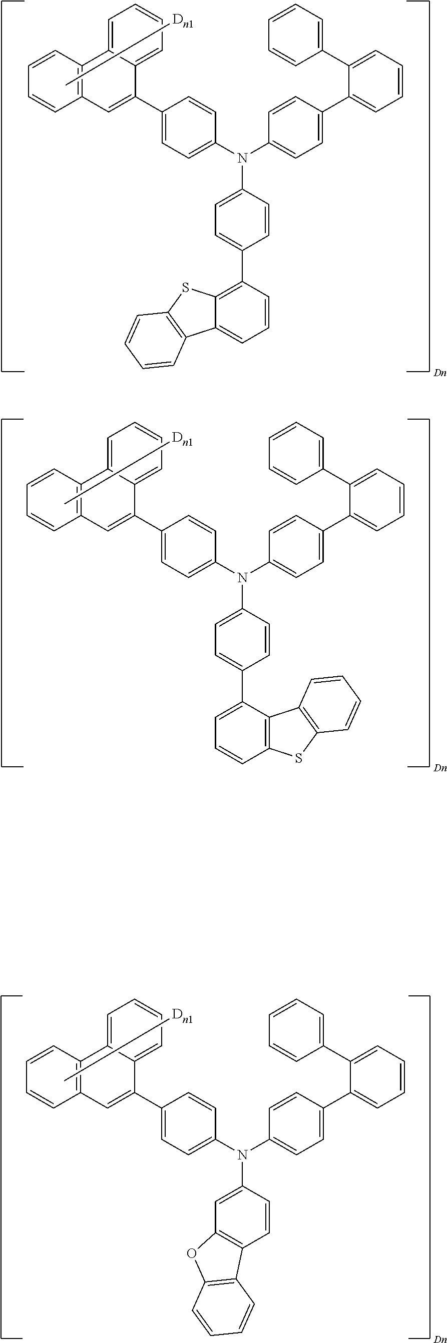 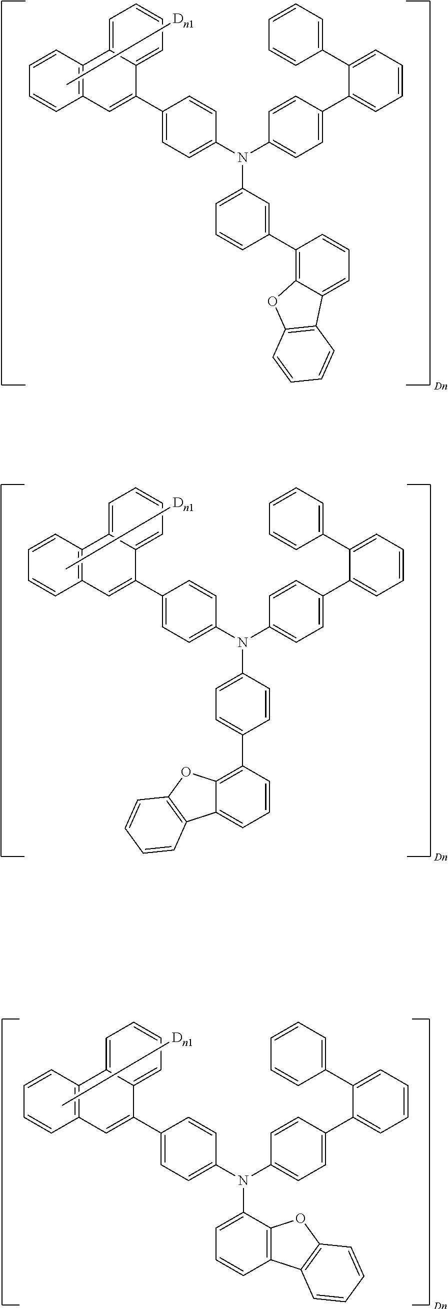 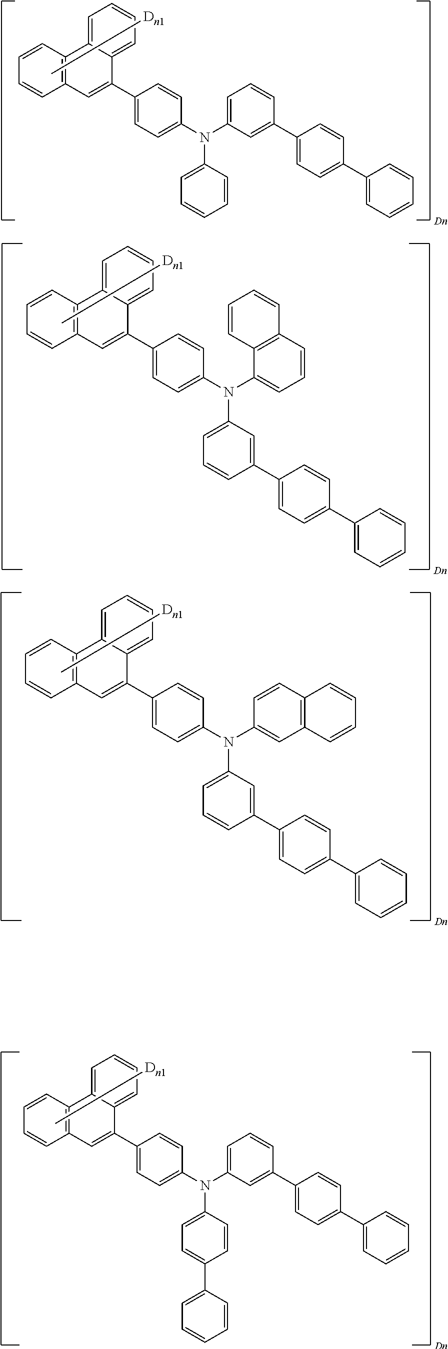 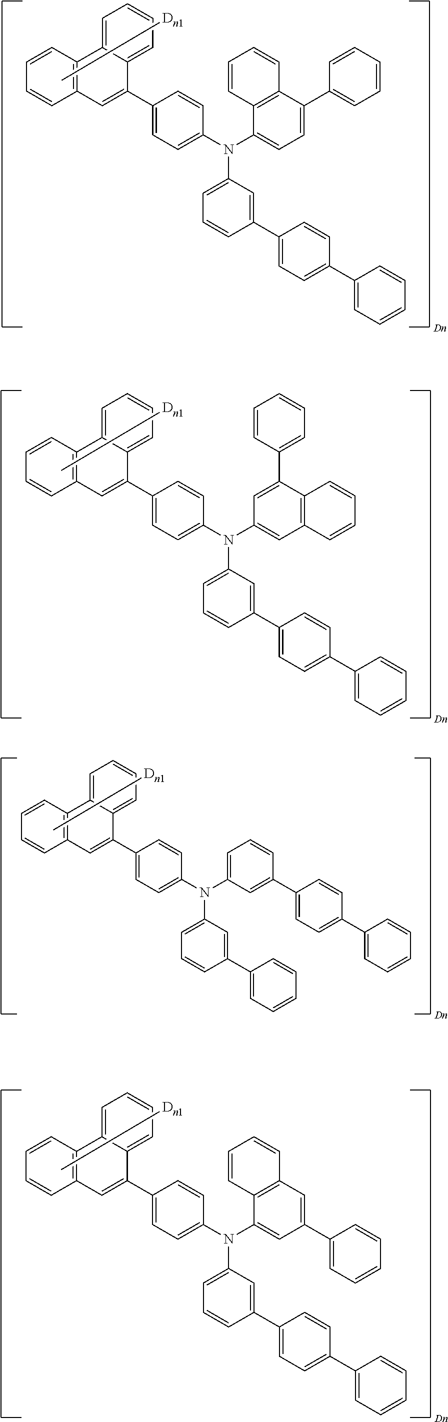 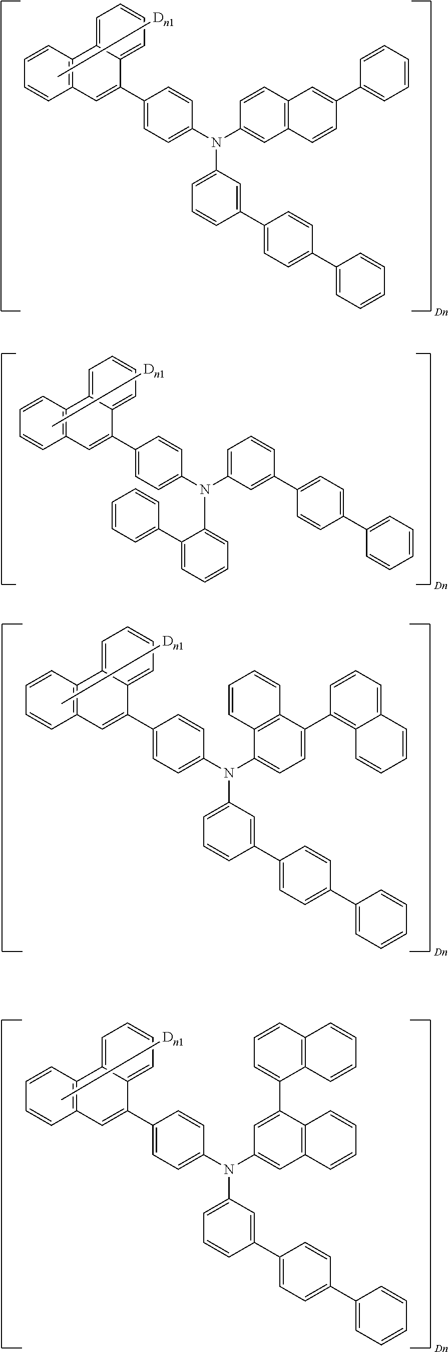 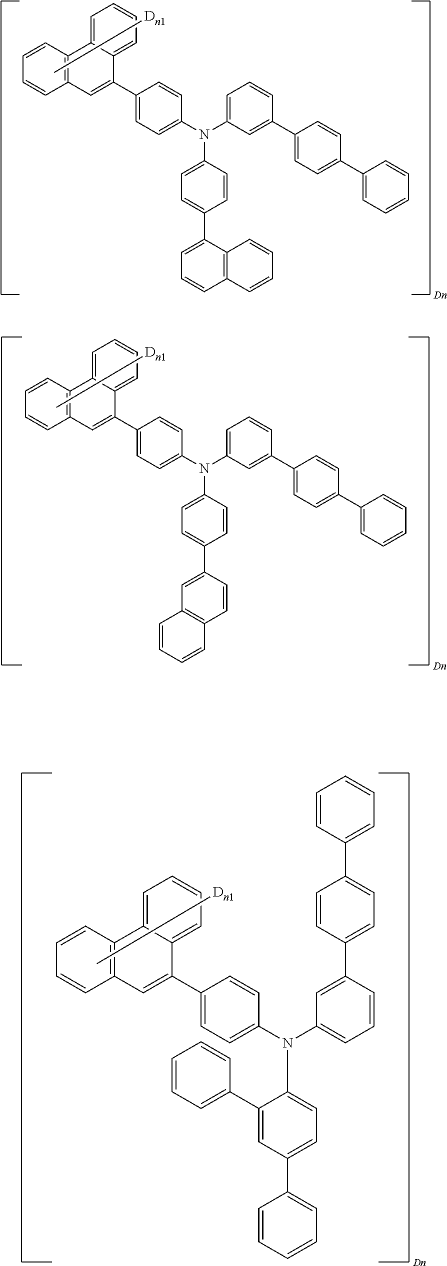 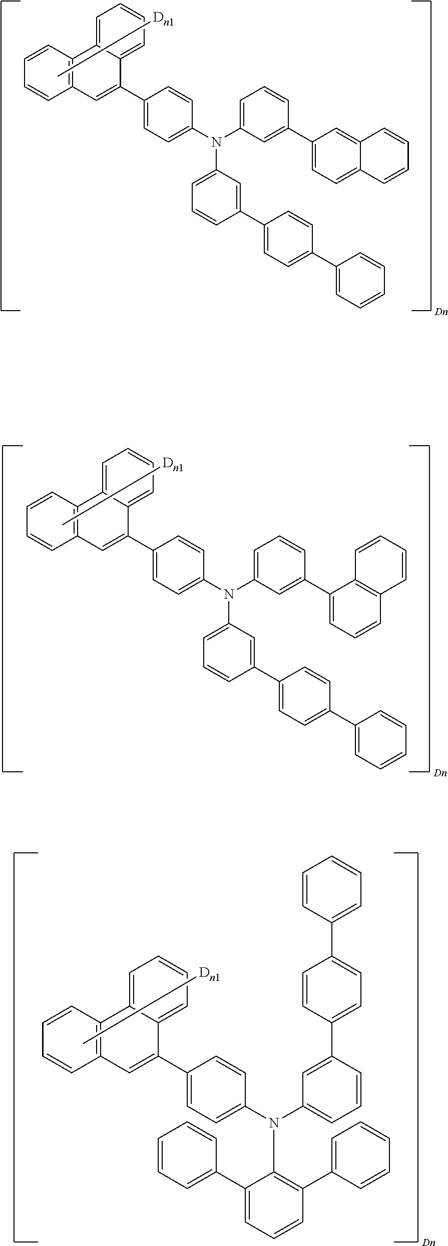 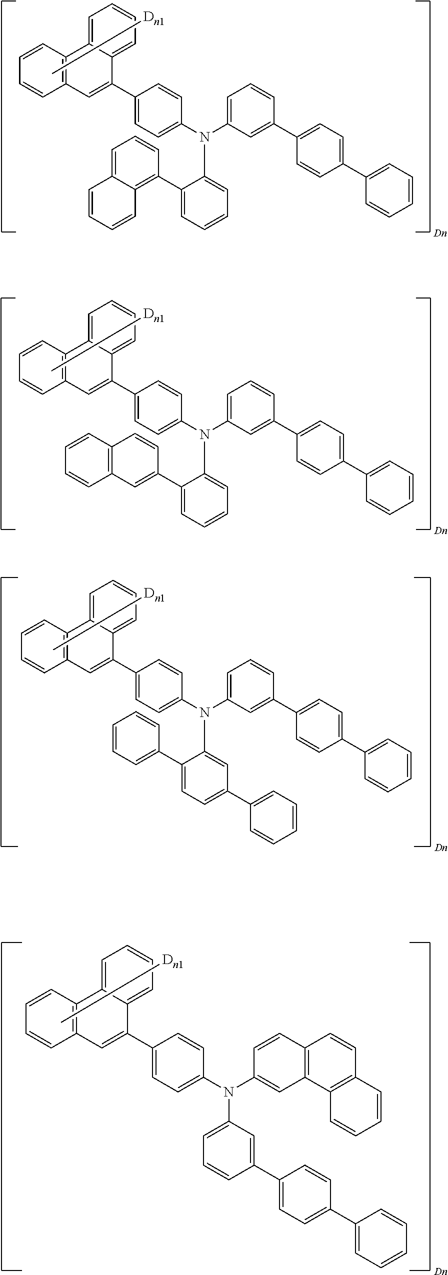 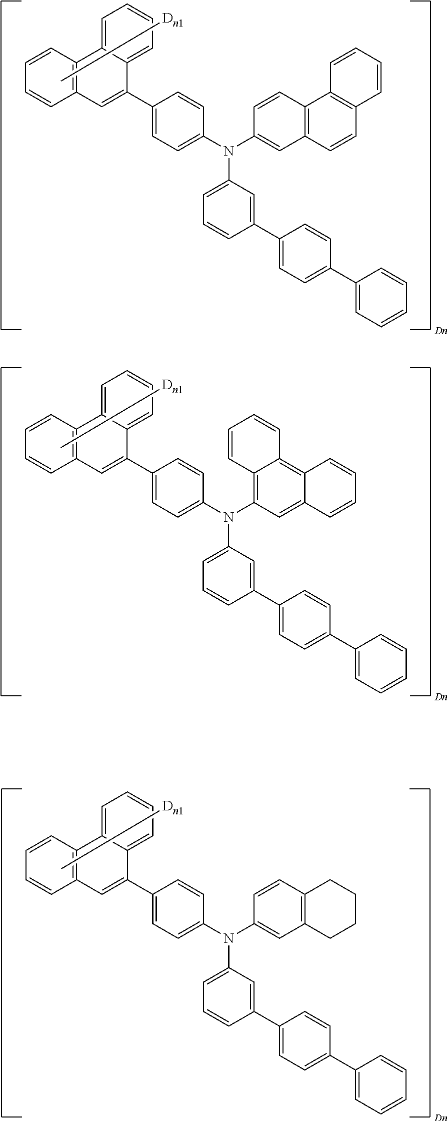 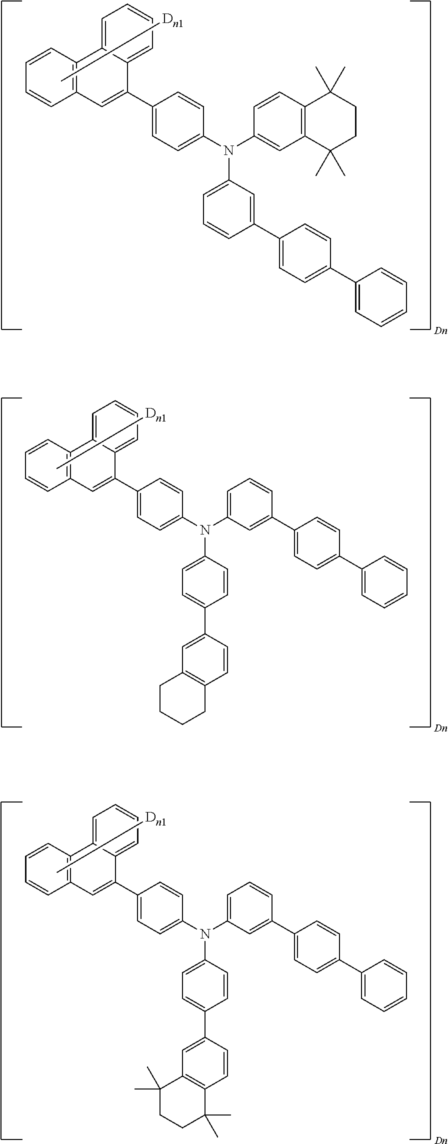 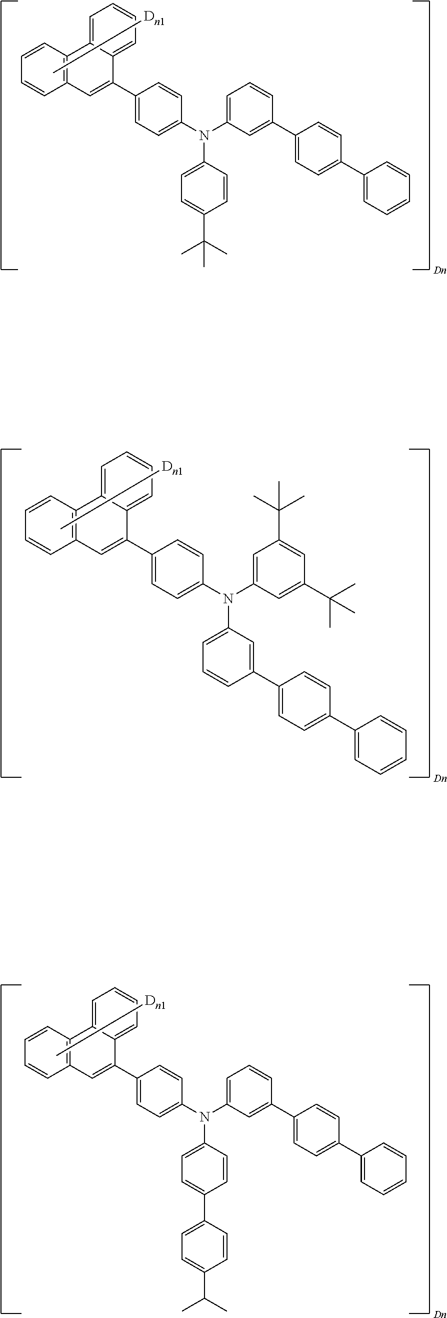 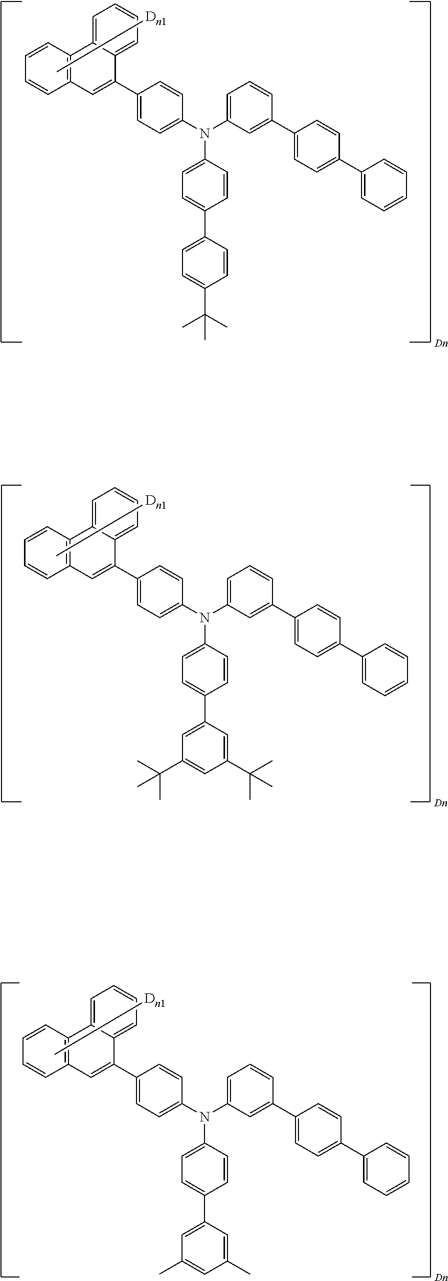 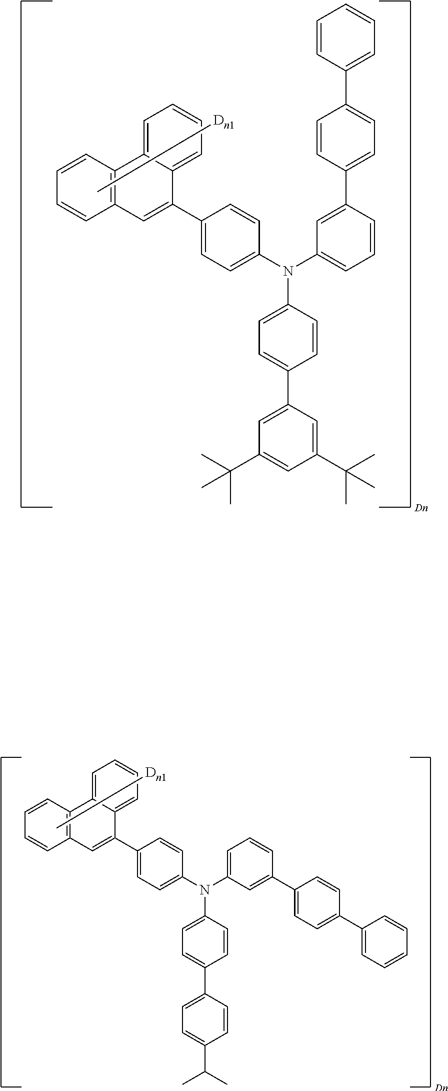 [chemical structure] 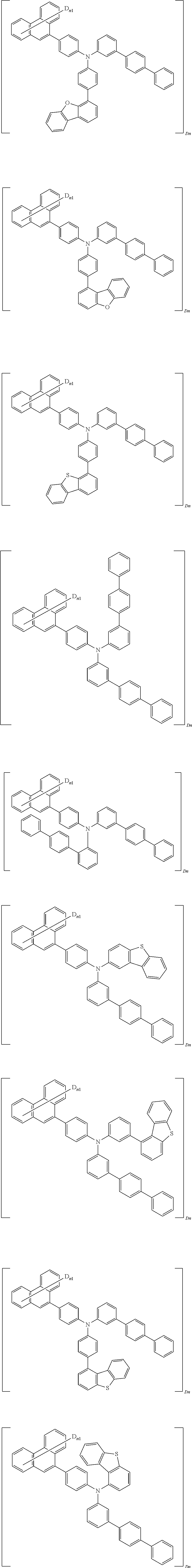 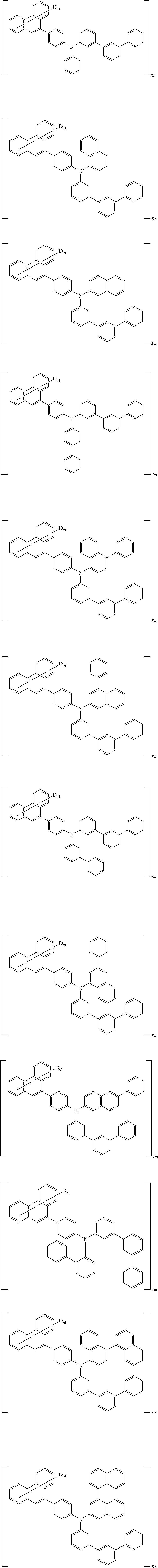 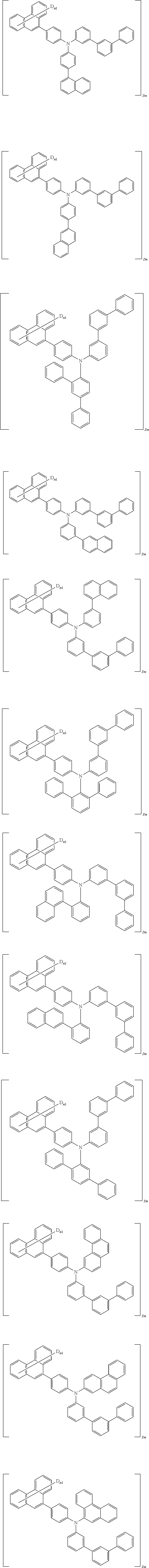 [chemical structure] 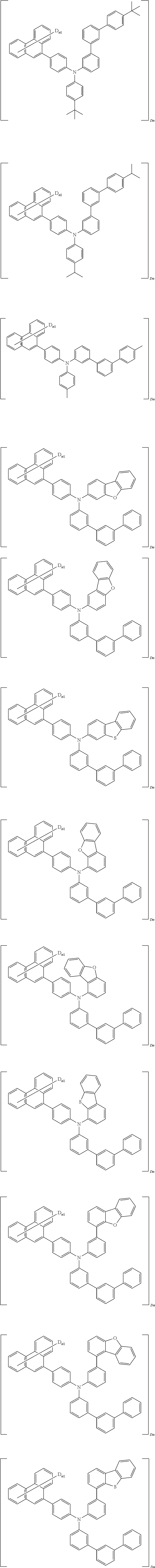 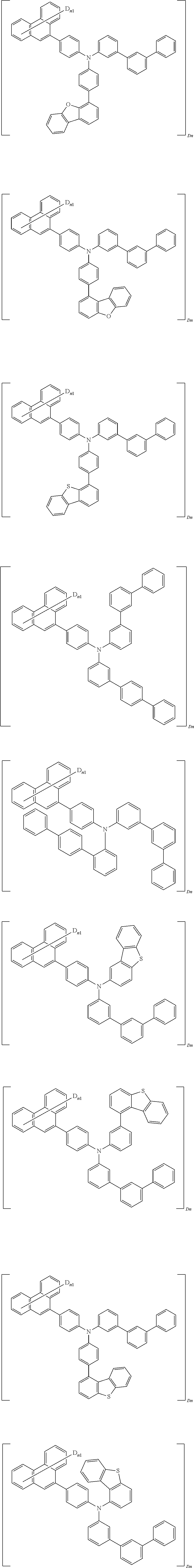 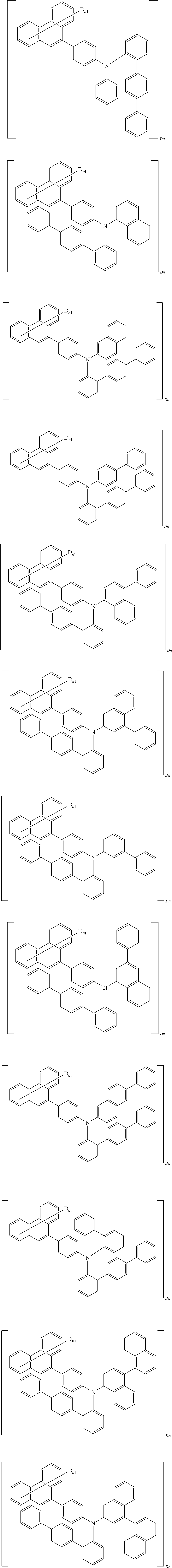 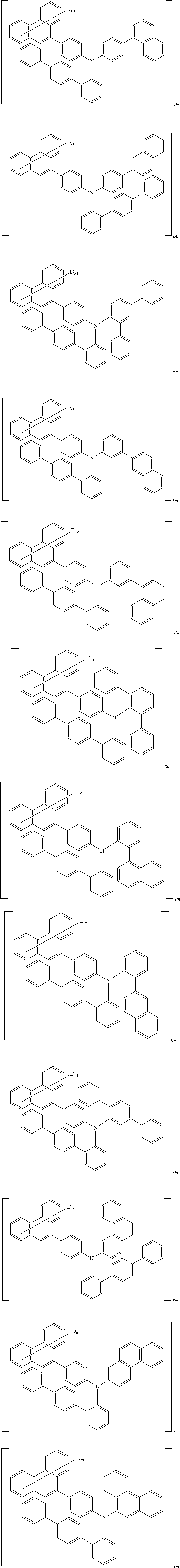 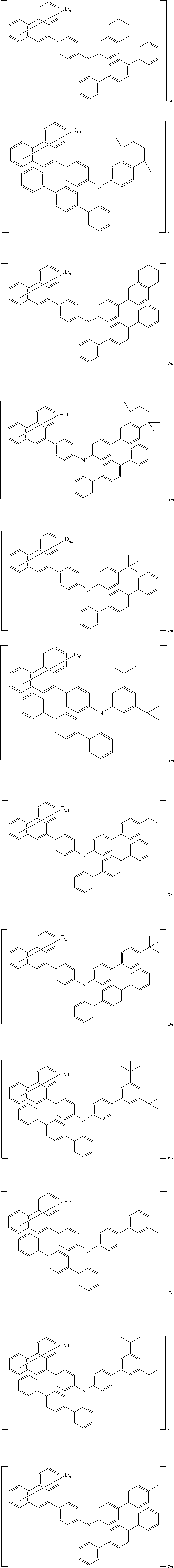 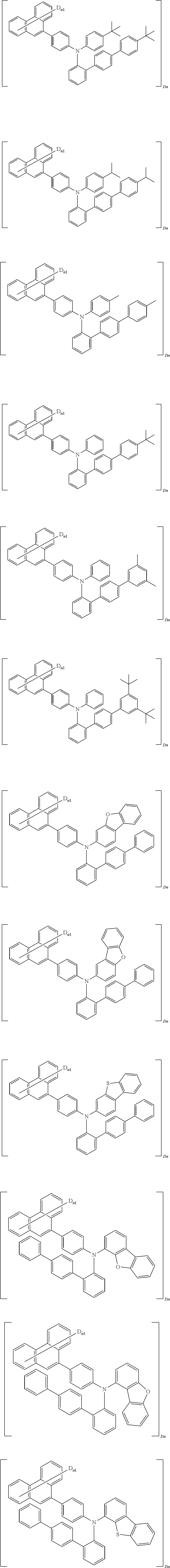 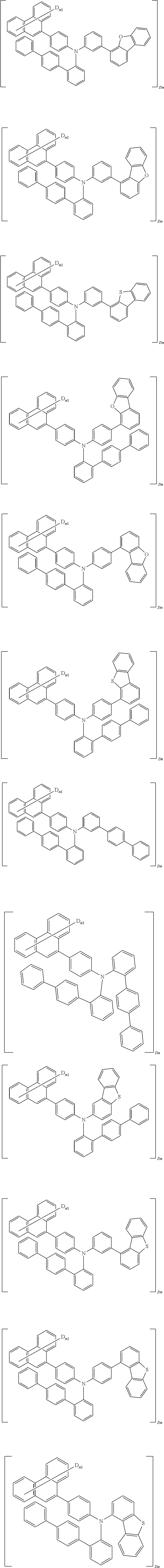 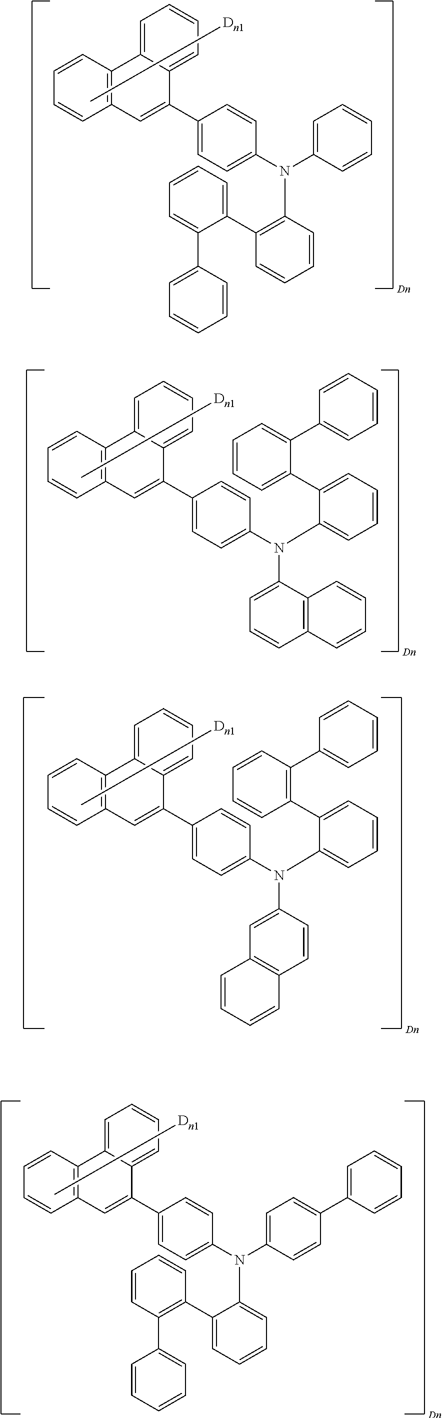 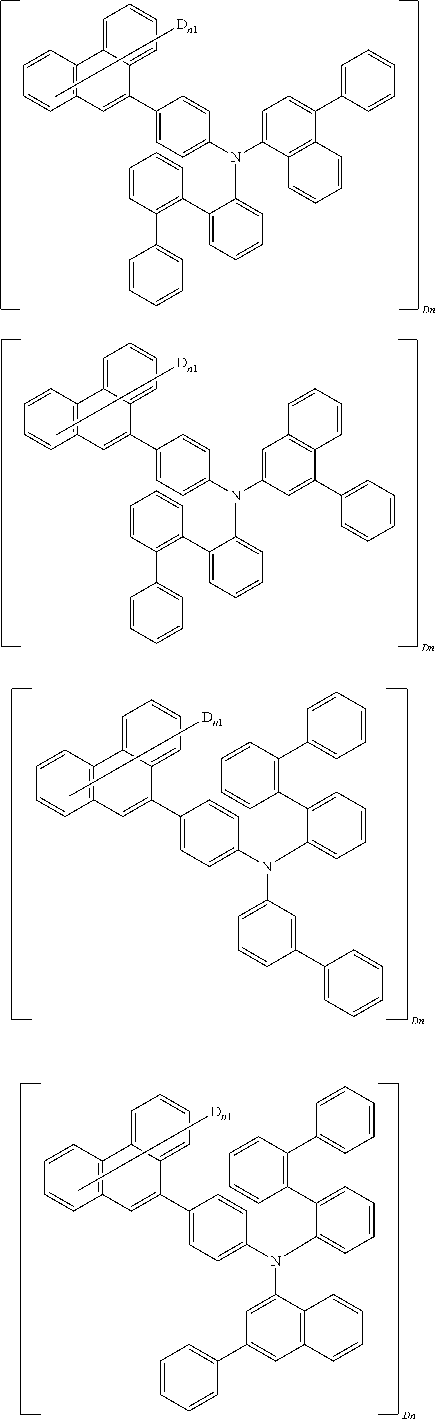 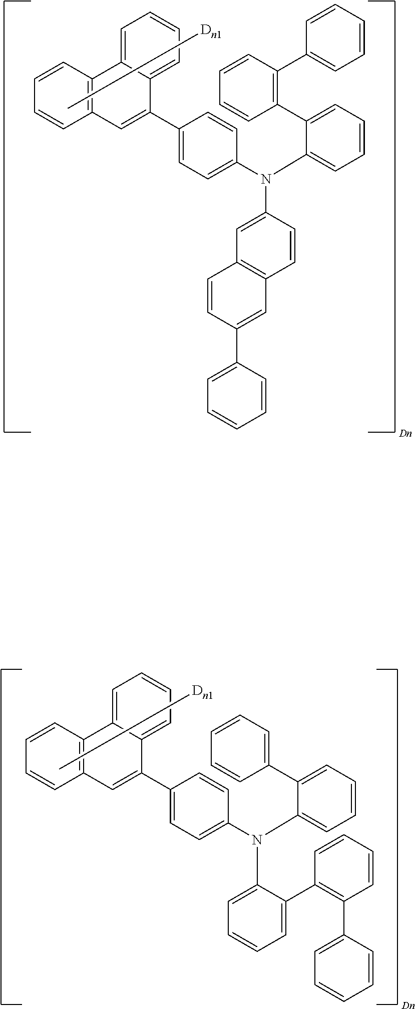 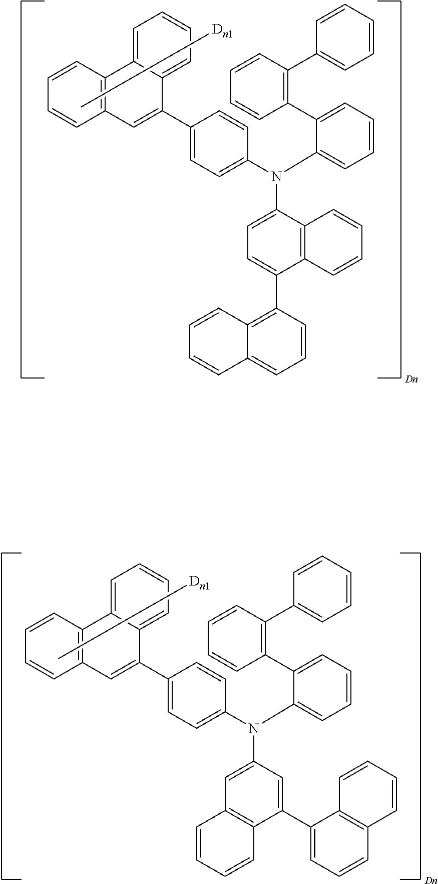 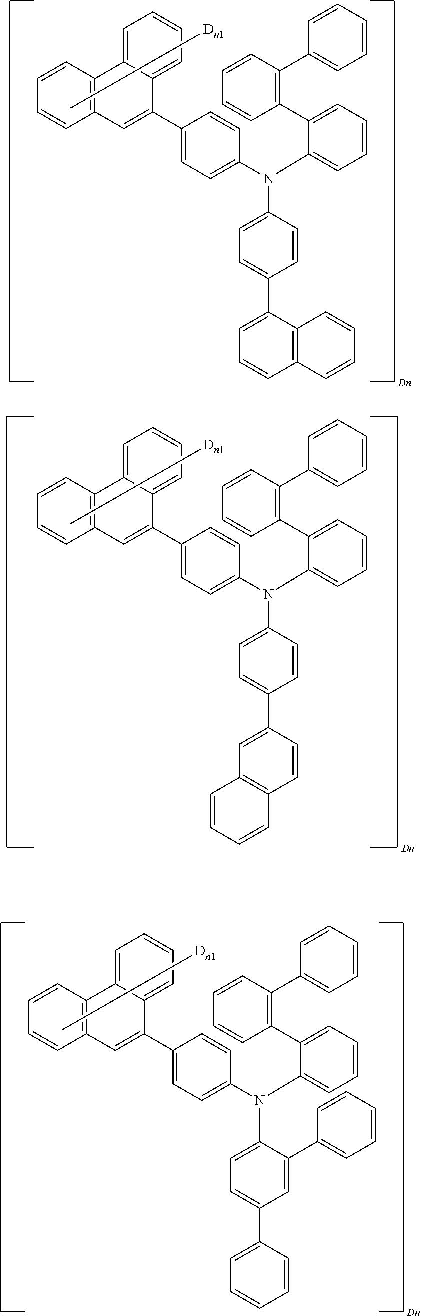 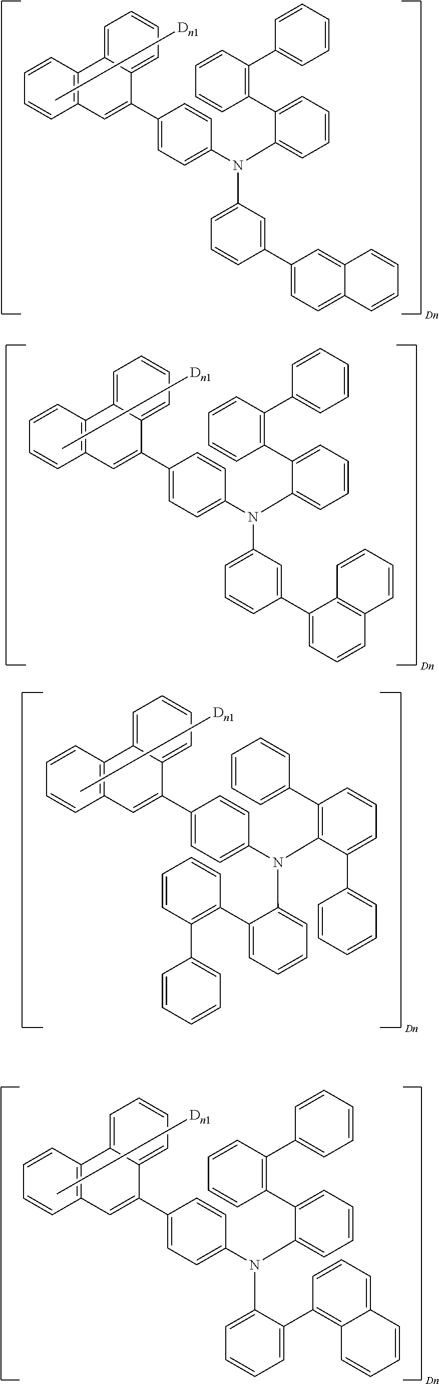 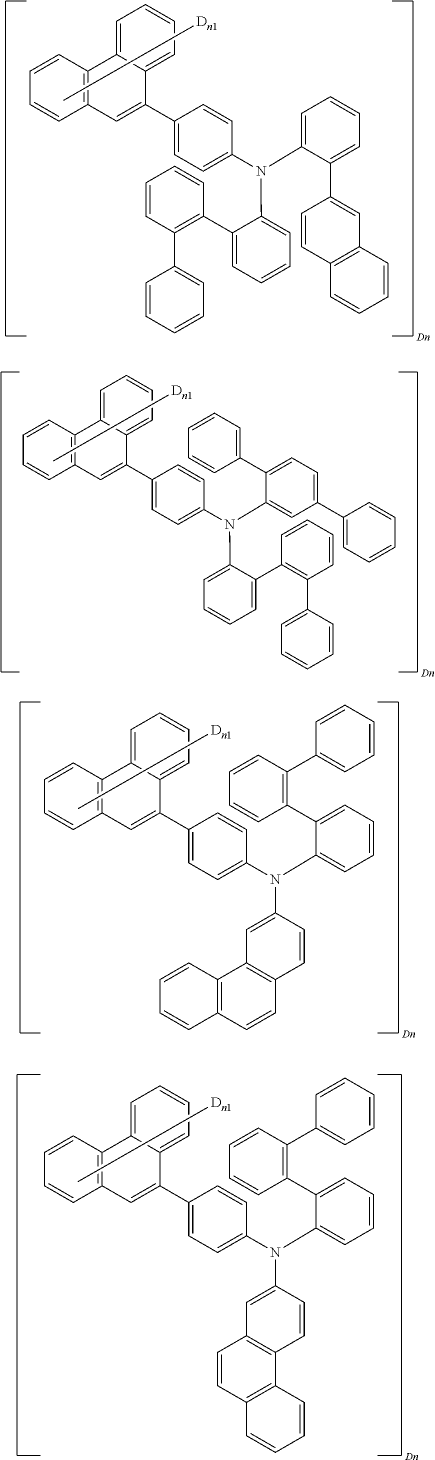 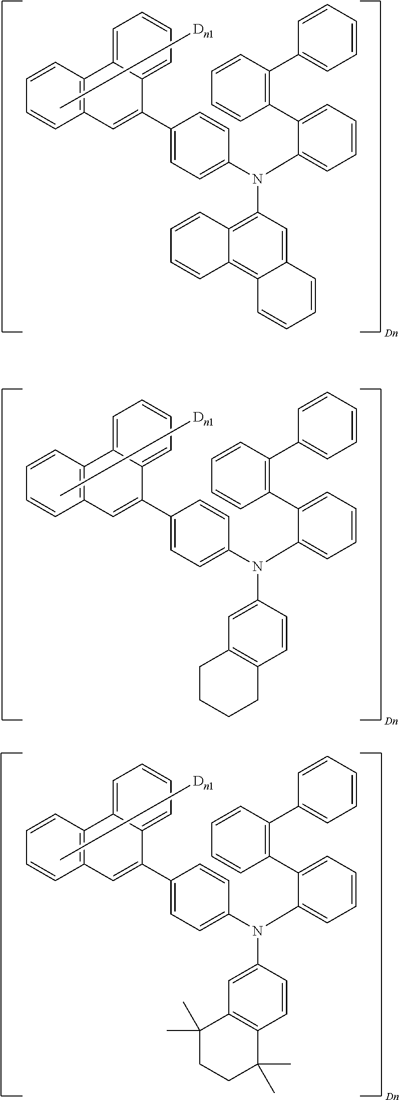 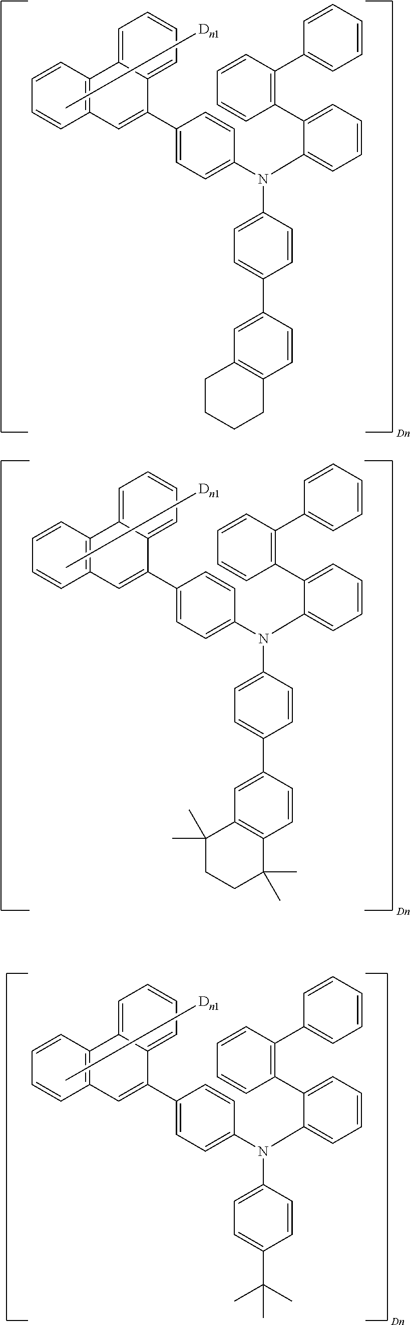 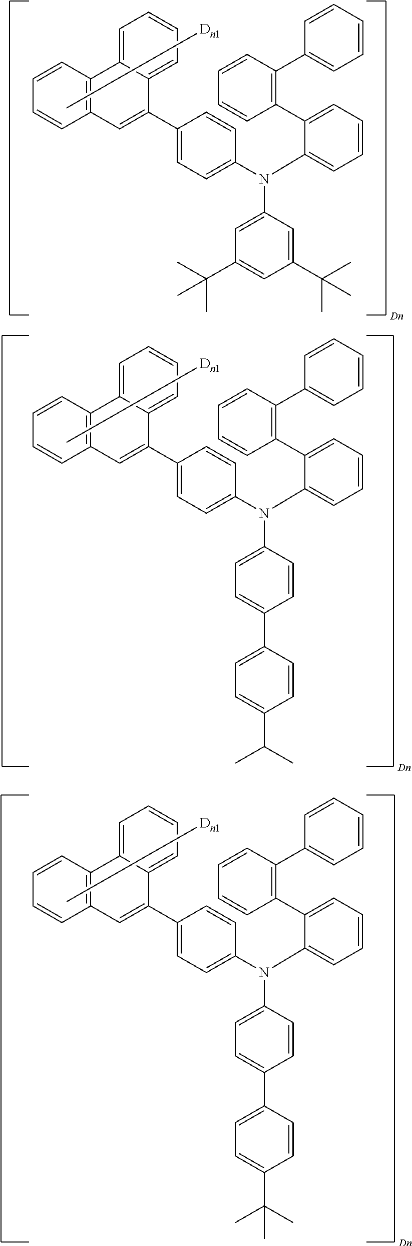 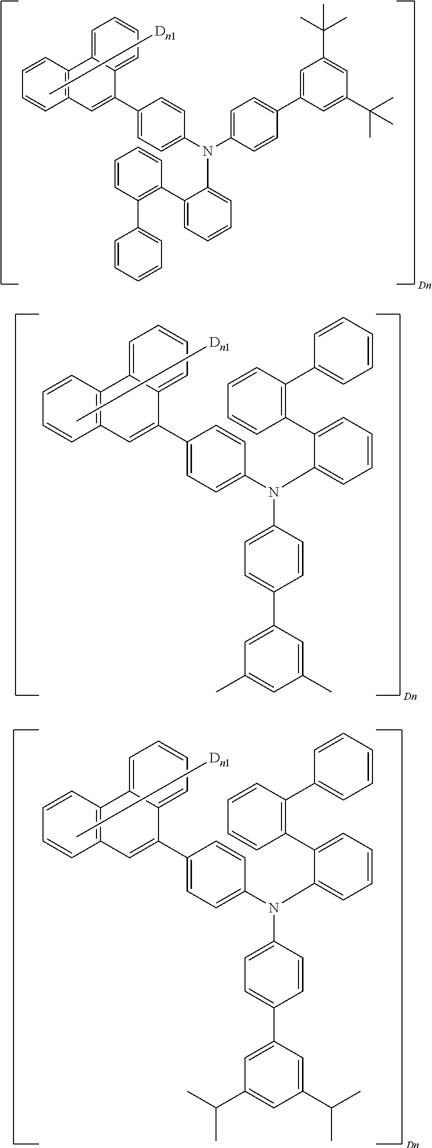 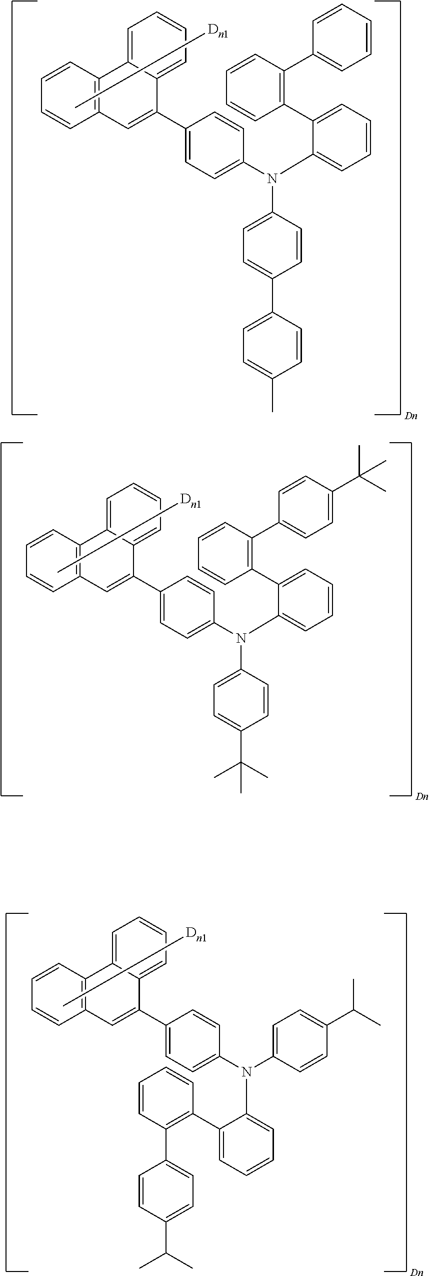 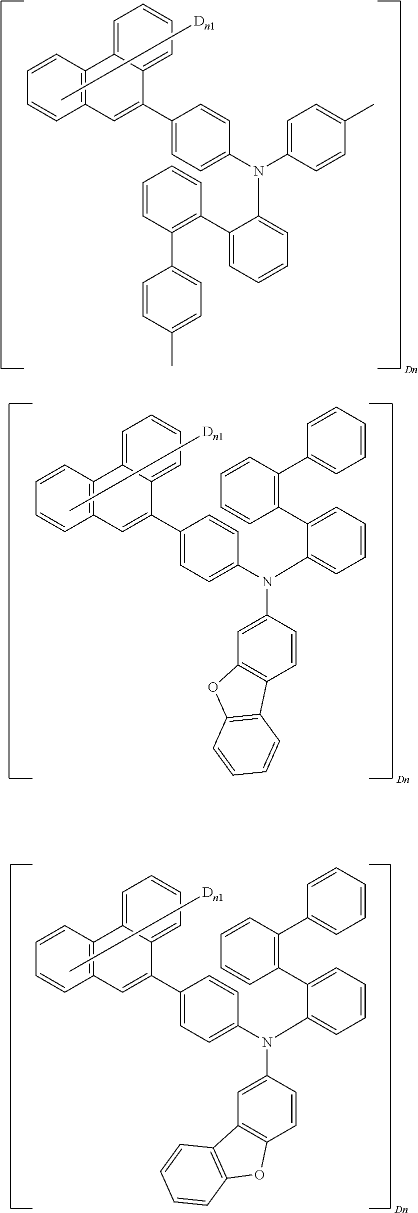 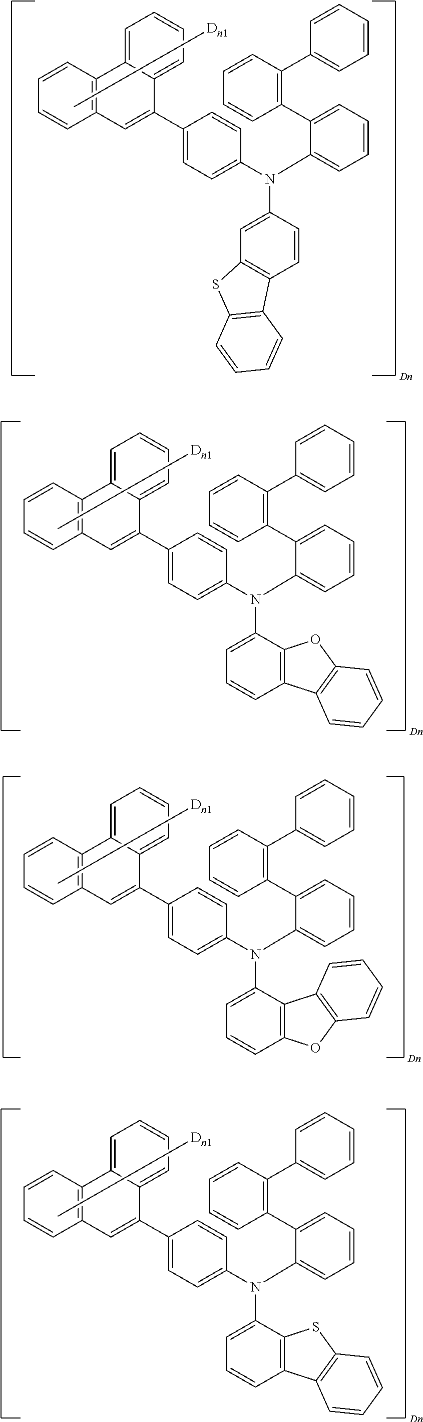 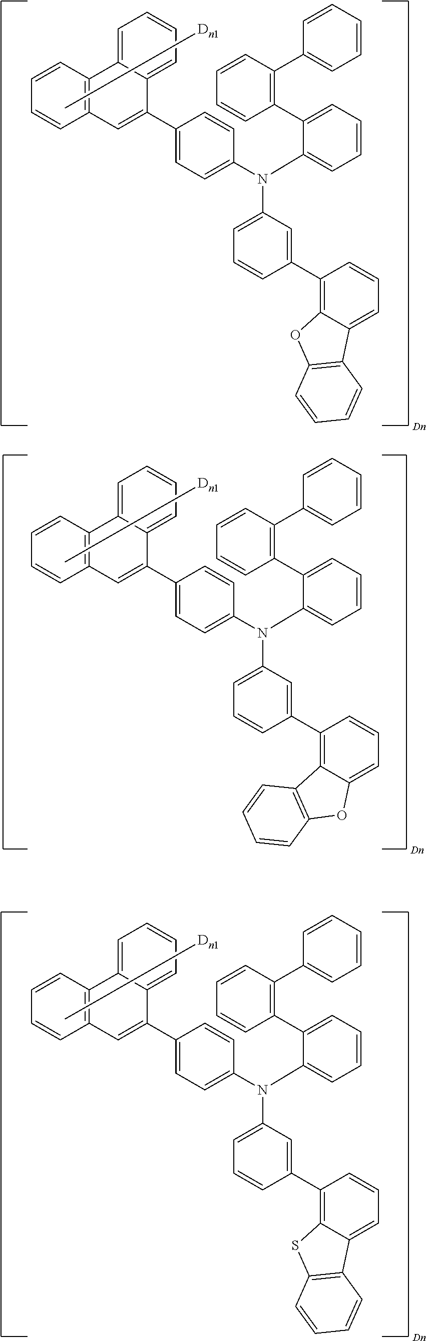 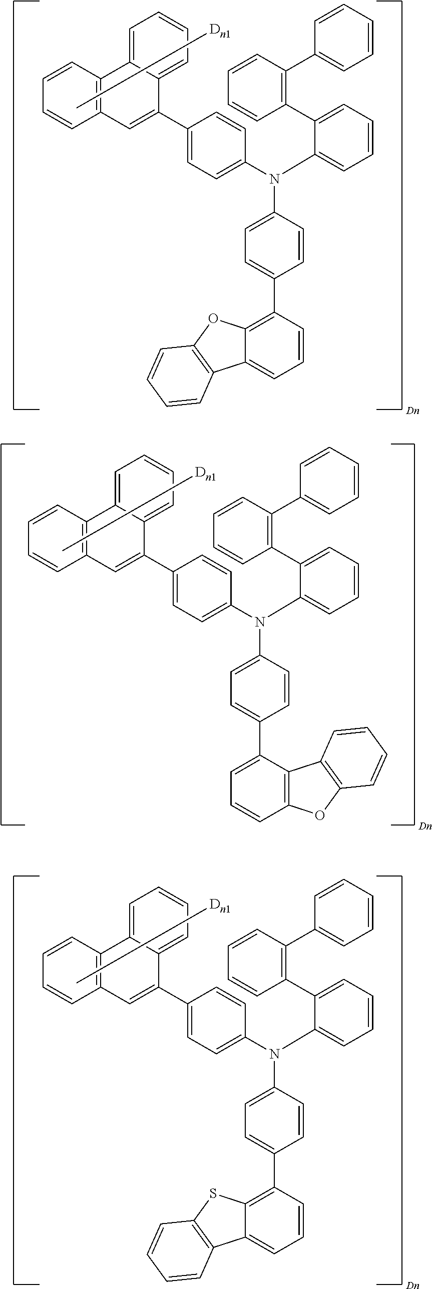 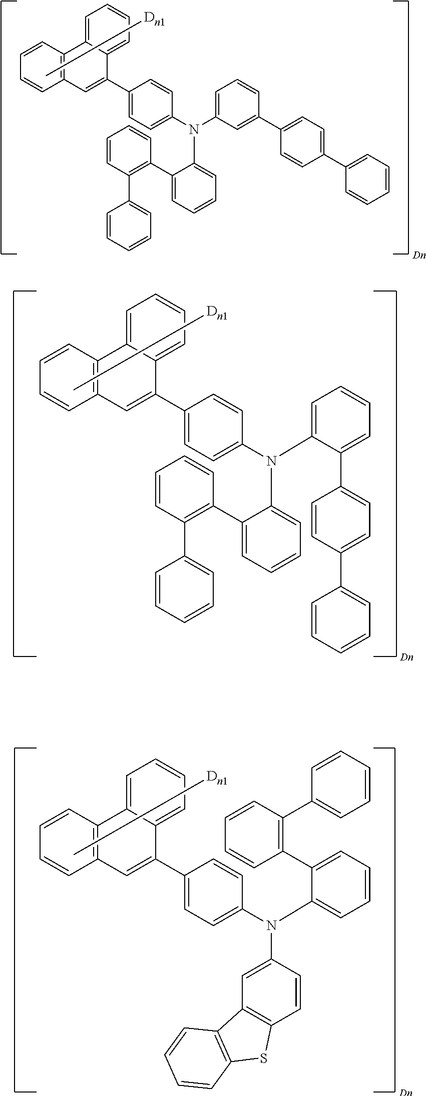 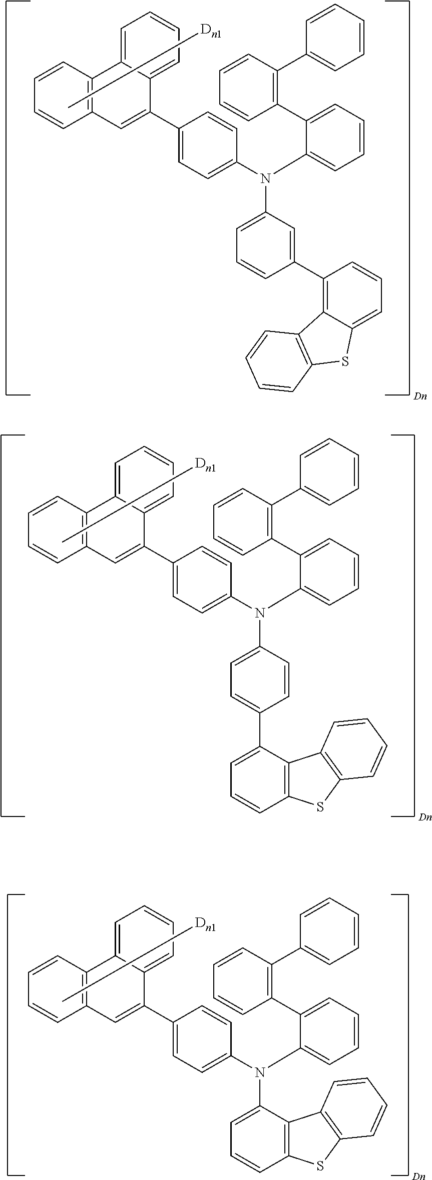 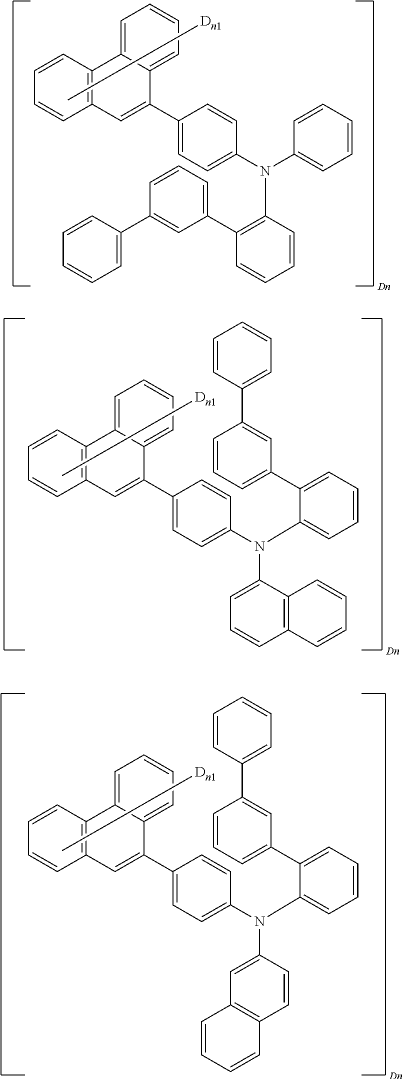 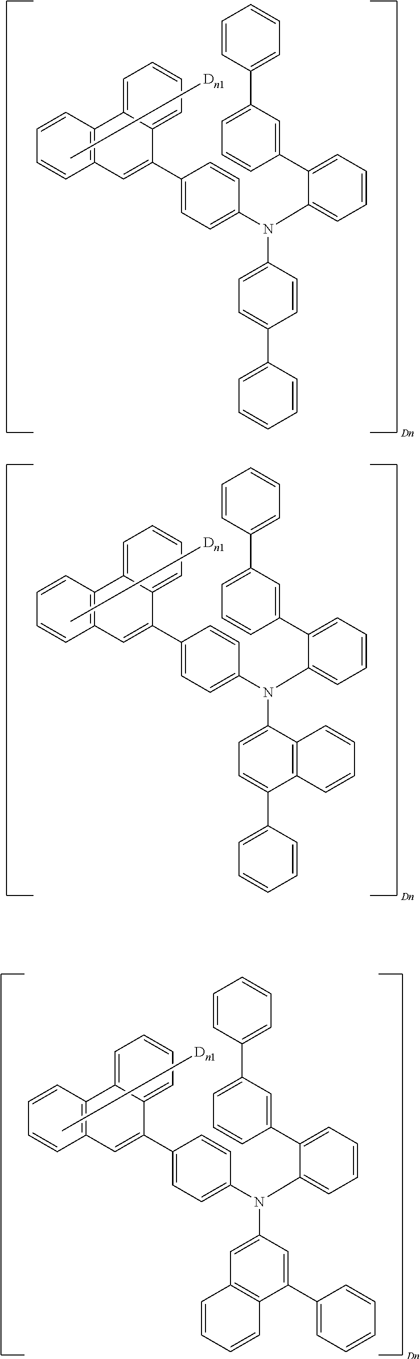 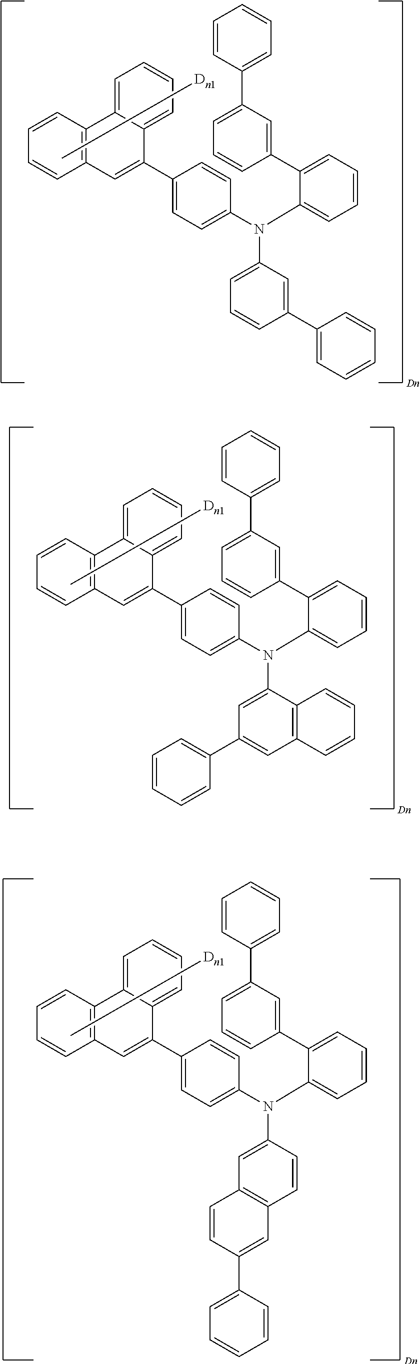 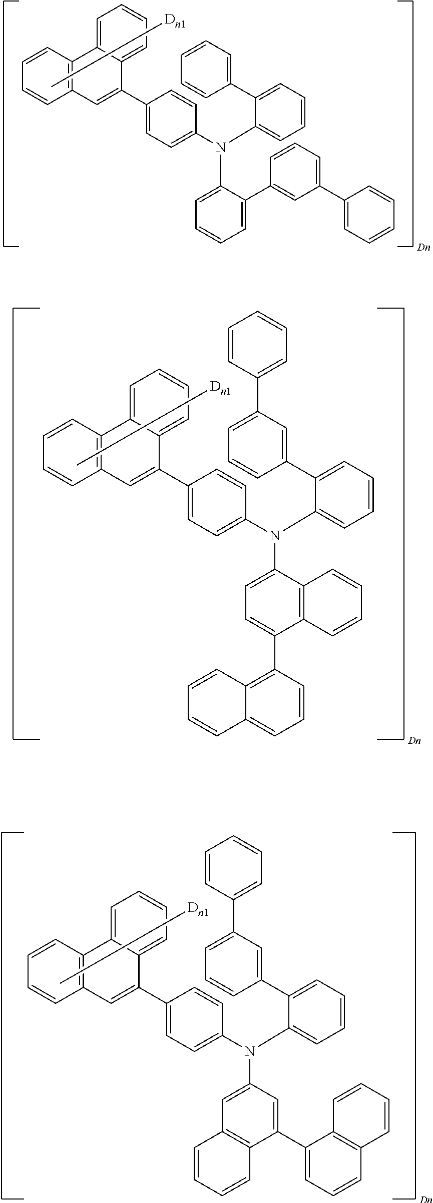 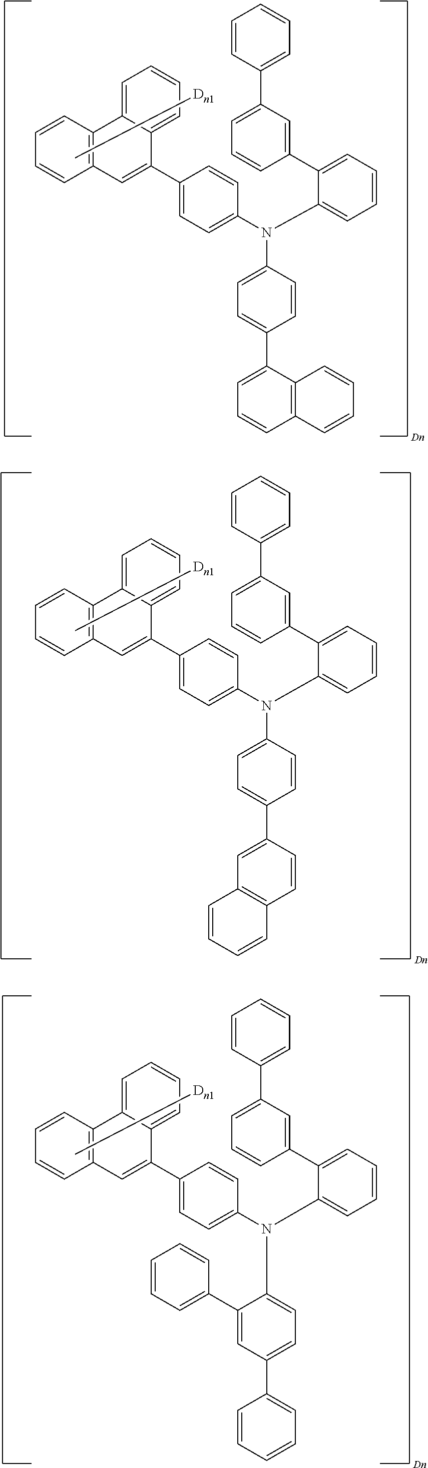 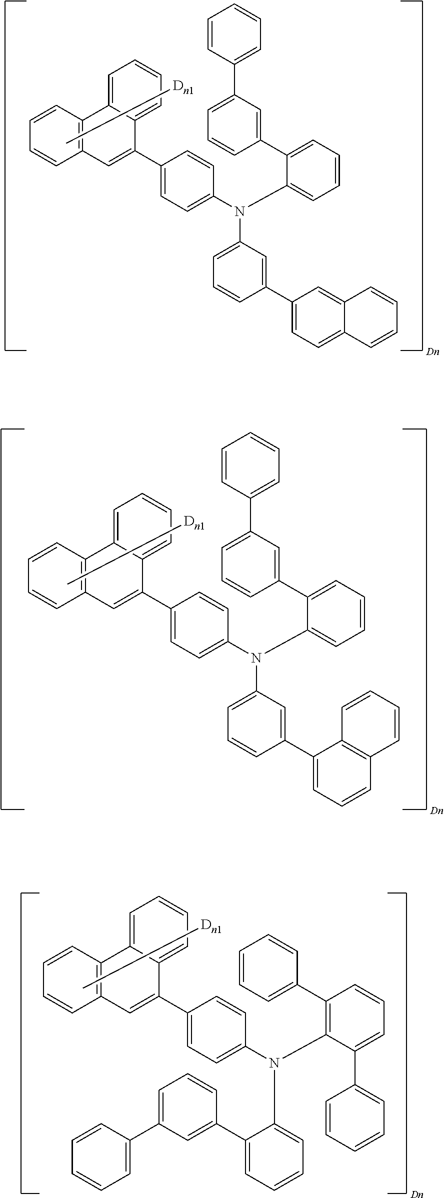 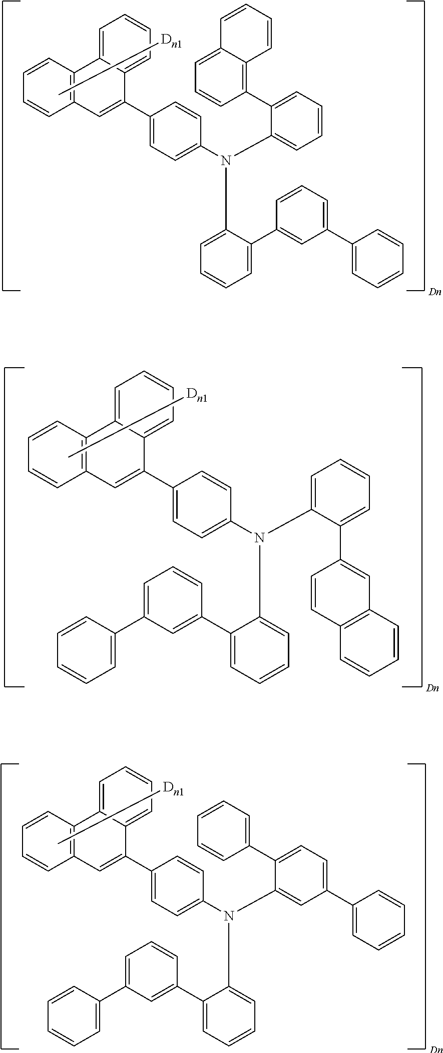 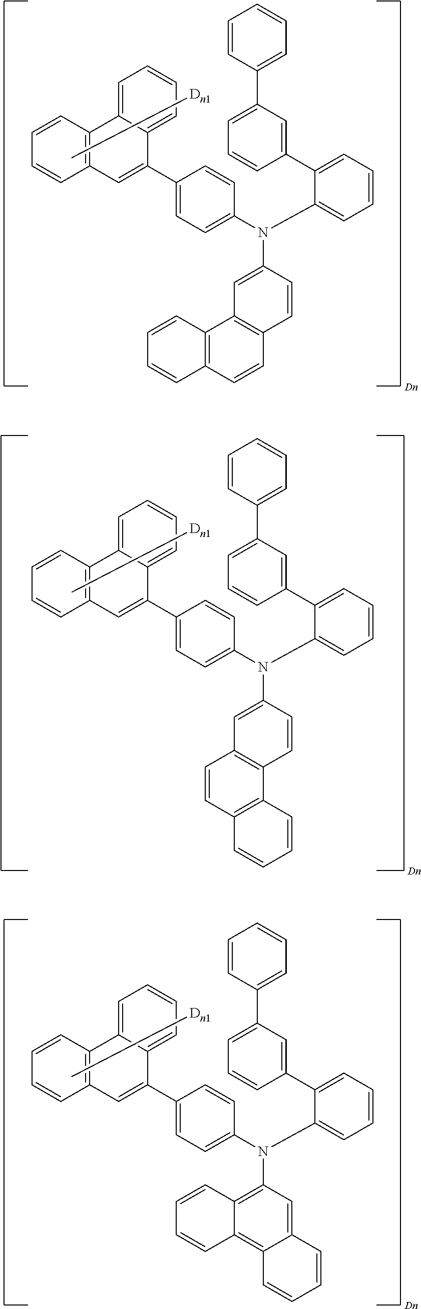 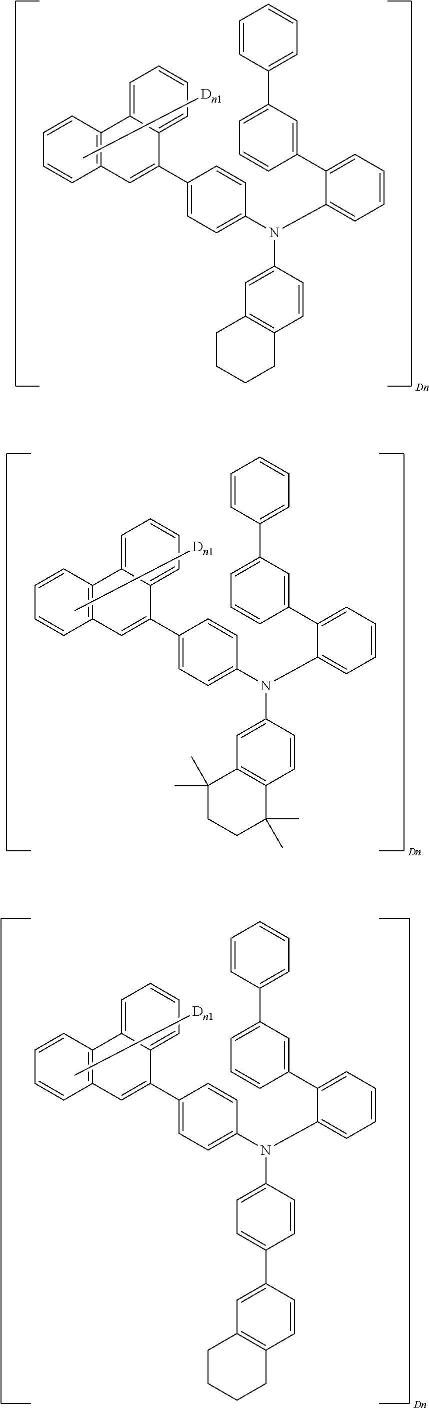 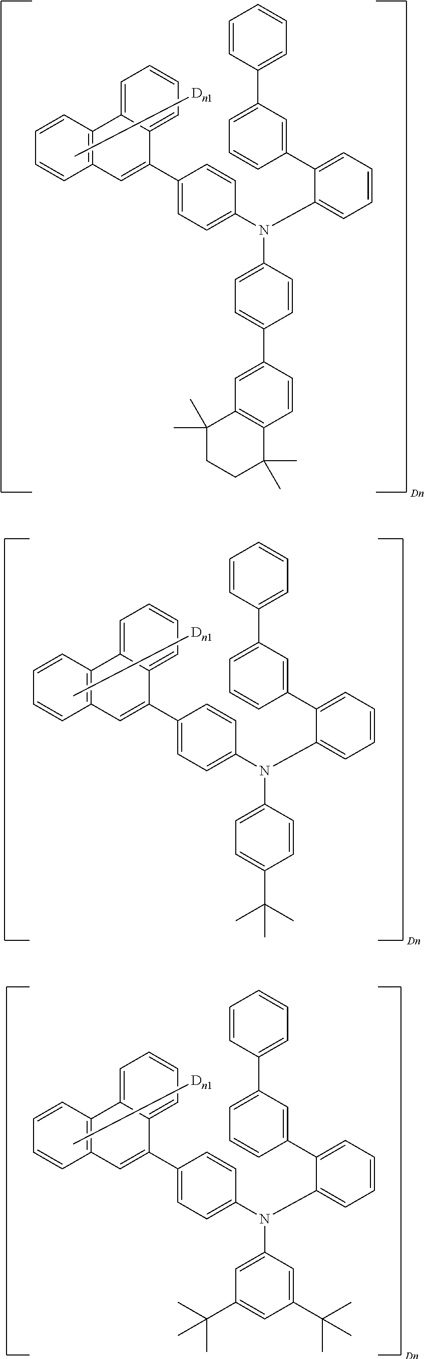 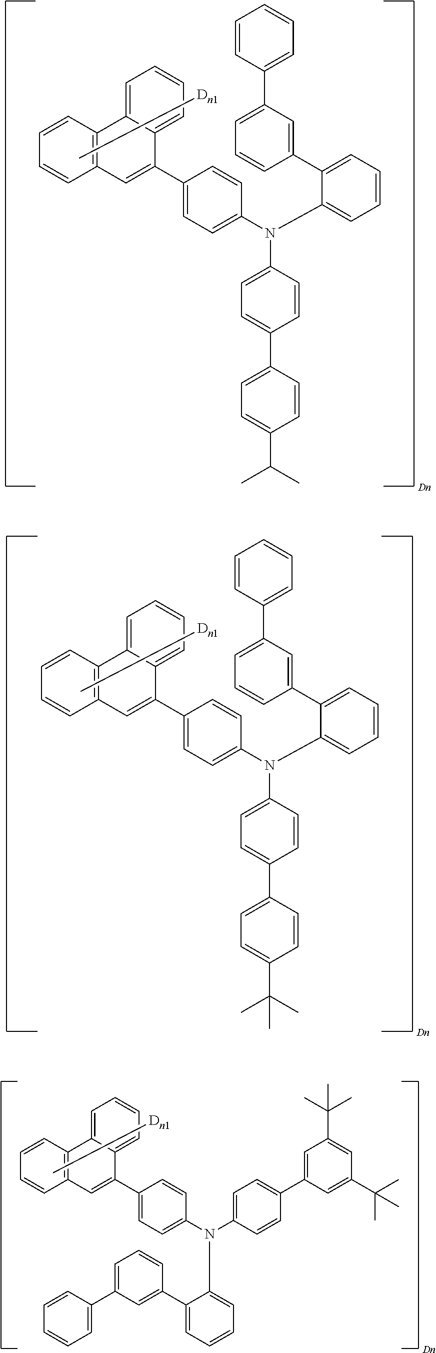 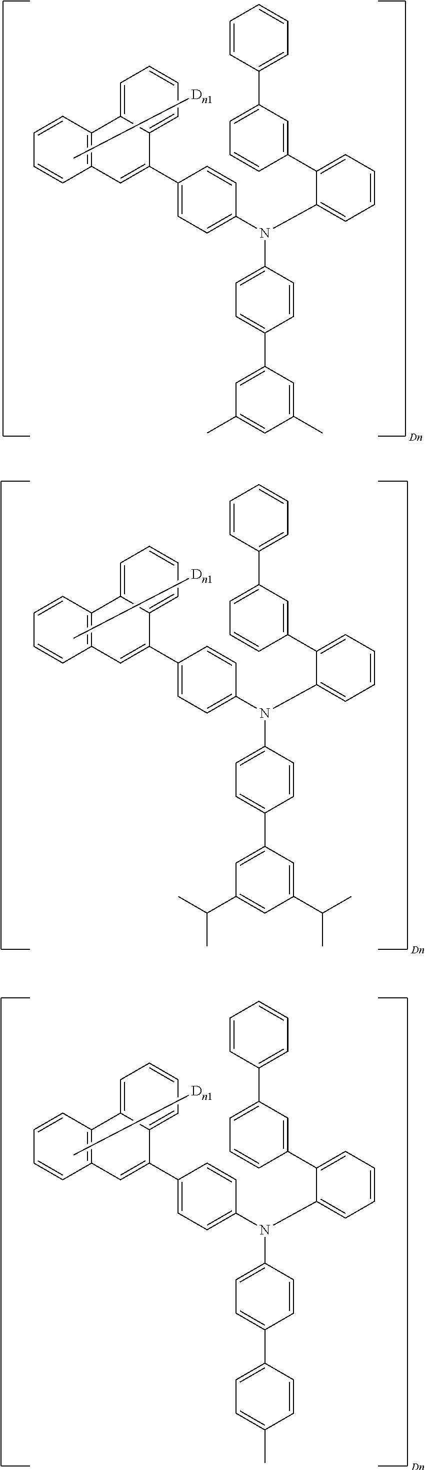 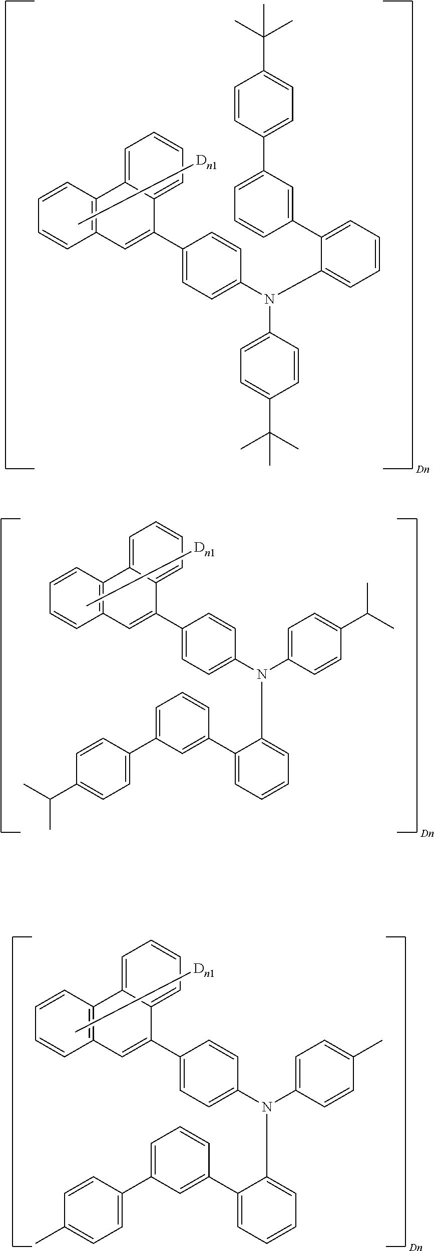 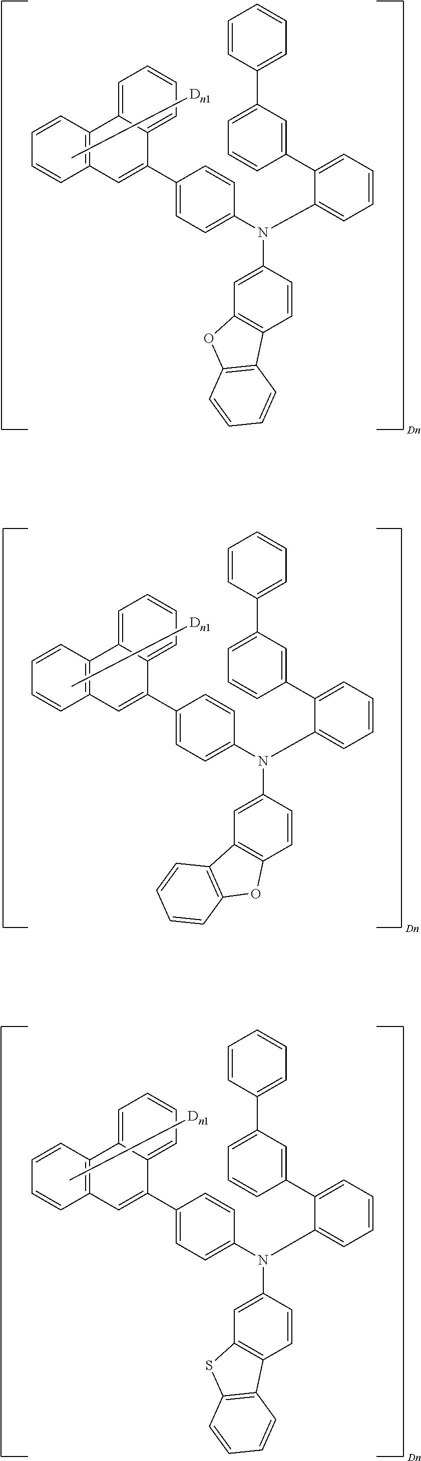 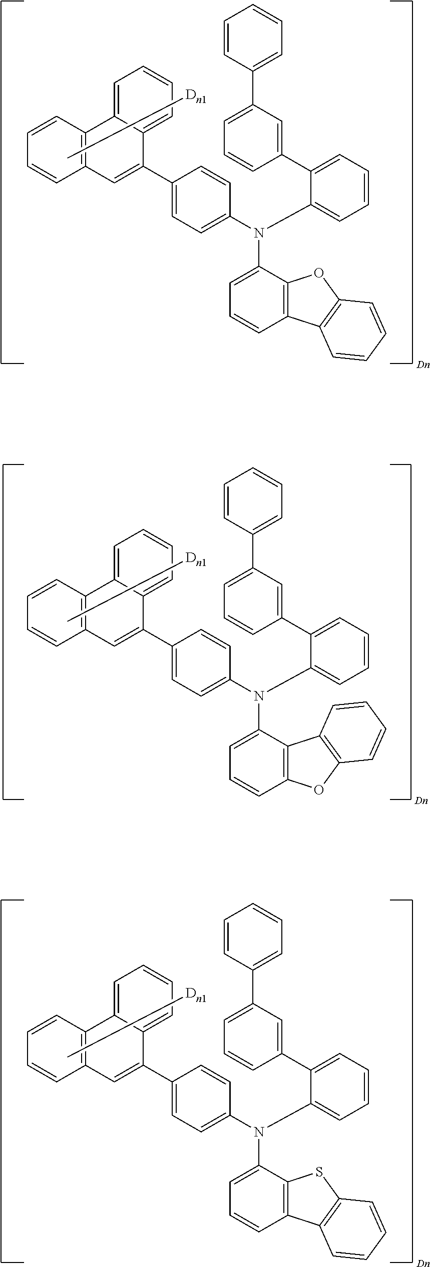 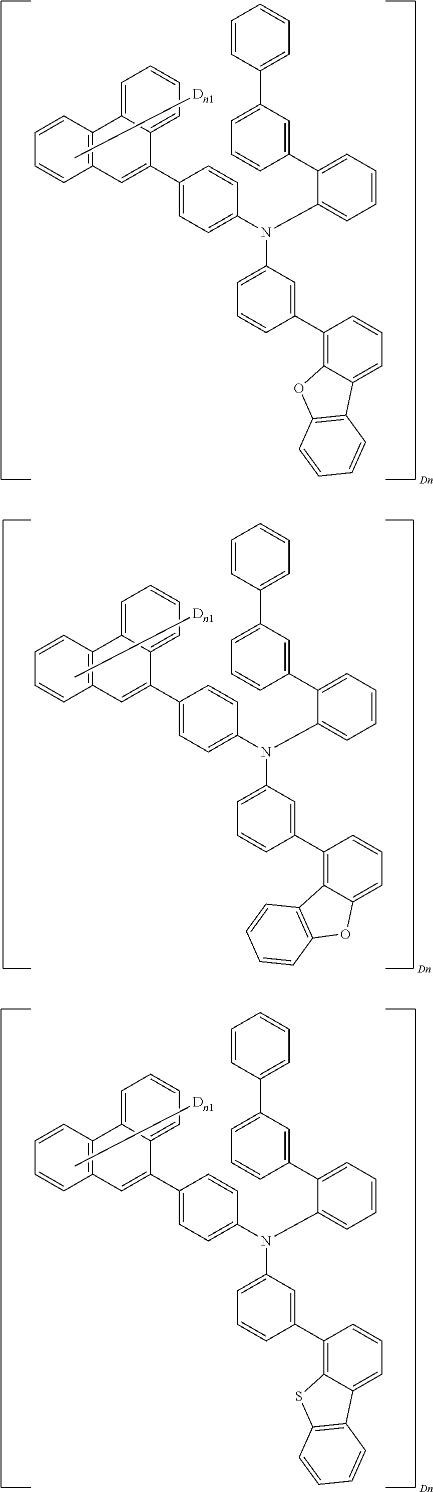 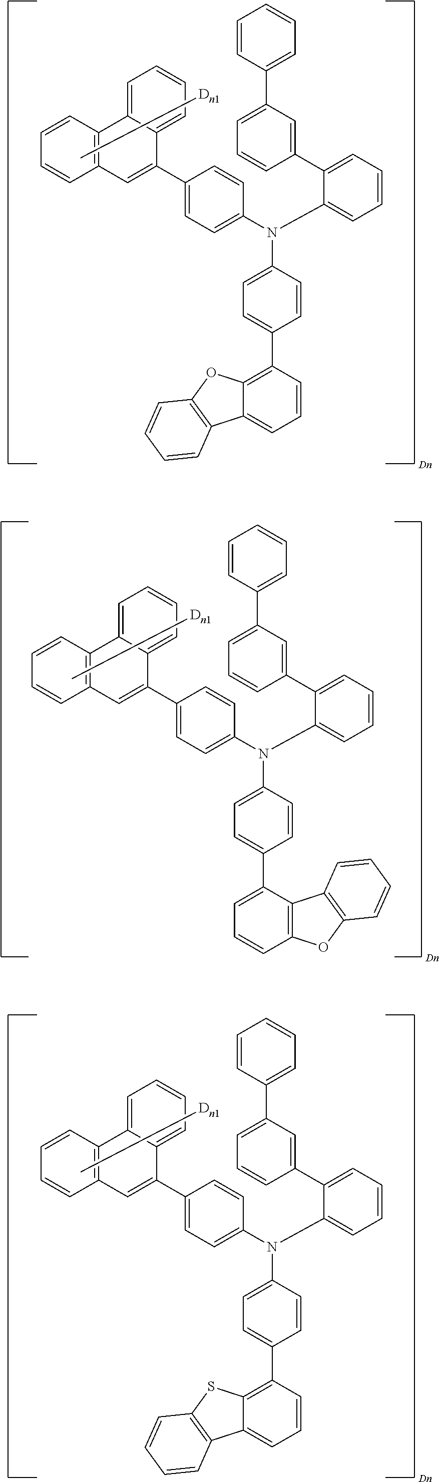 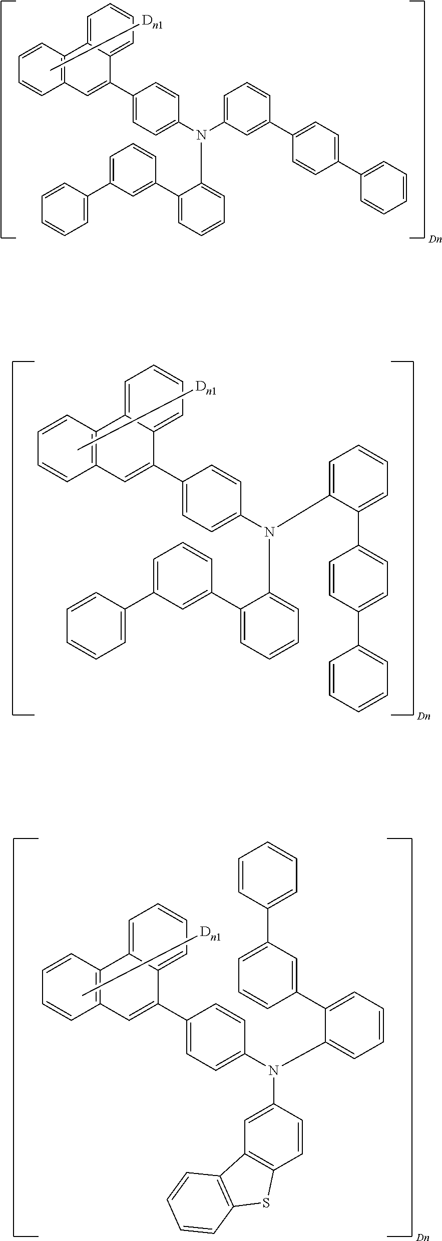 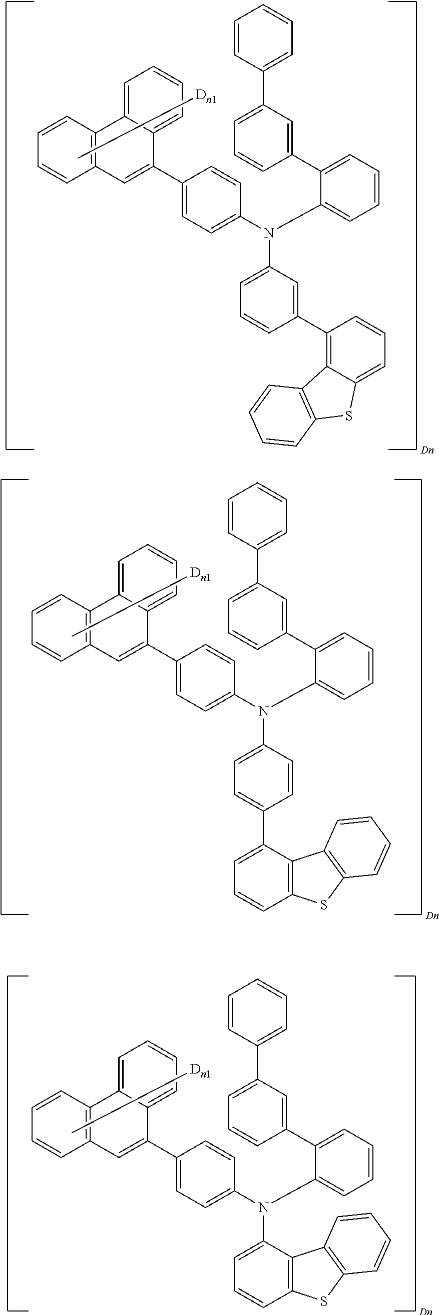 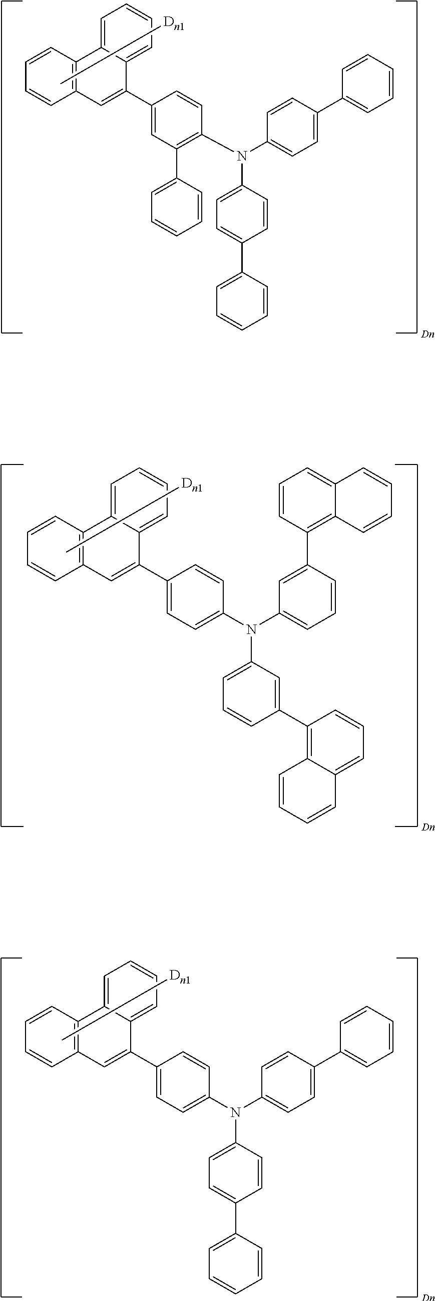 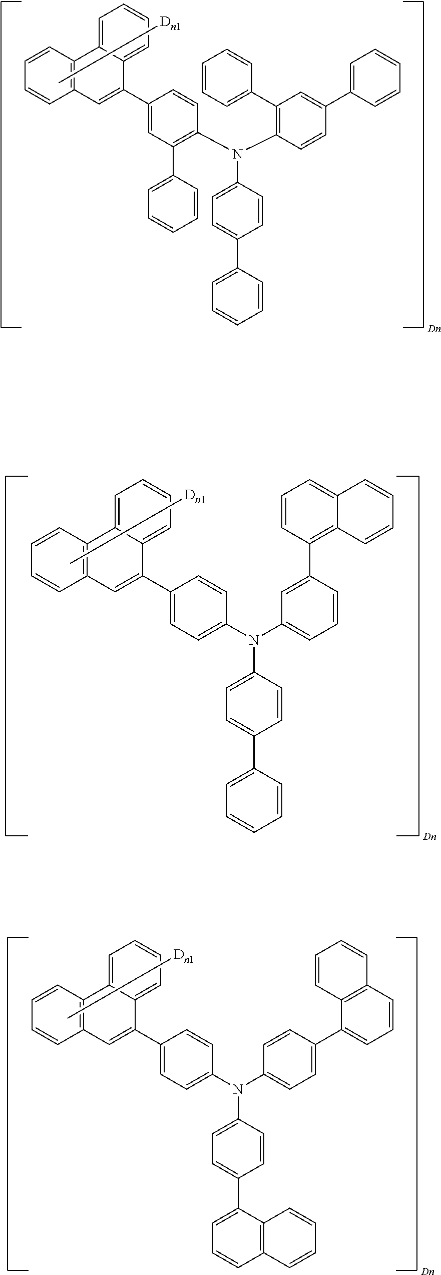 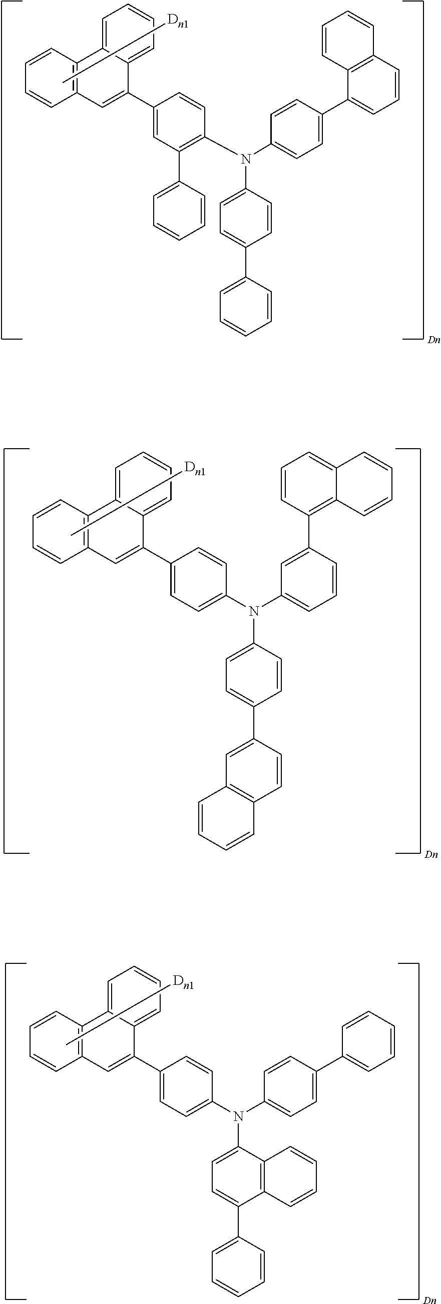 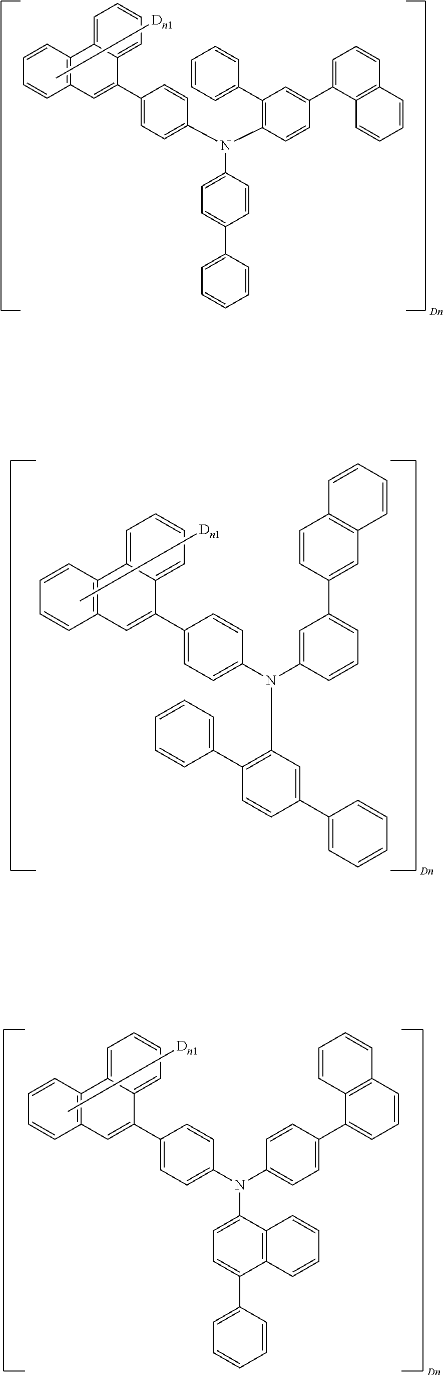 [chemical structure]
